(19) United States
(12) Patent Application Publication
(10) Pub. No.: US 2026/0049169 A1
(43) Pub. Date: Feb. 19, 2026

(54) SULFONIUM SALT TYPE MONOMER, SULFONIUM SALT TYPE QUENCHER, POLYMER, CHEMICALLY AMPLIFIED RESIST COMPOSITION, AND PATTERN FORMING METHOD

(71) Applicant: SHIN-ETSU CHEMICAL CO., LTD., Tokyo (JP)

(72) Inventor: Masahiro FUKUSHIMA, Joetsu-shi (JP)

(73) Assignee: SHIN-ETSU CHEMICAL CO., LTD., Tokyo (JP)

(21) Appl. No.: 19/293,263

(22) Filed: Aug. 7, 2025

(30) Foreign Application Priority Data
Aug. 13, 2024 (JP) 2024-134817

(51) Int. Cl. C08F 220/22; C08F 212/14; C08F 212/34; C08F 220/18; C08F 220/30; C08F 220/40; G03F 7/004; G03F 7/039

(52) U.S. Cl. CPC C08F 220/22; C08F 212/24; C08F 212/34; C08F 220/1806; C08F 220/301; C08F 220/40; G03F 7/0045; G03F 7/0392

(57) ABSTRACT

The present invention is a sulfonium salt type monomer, wherein the sulfonium salt type monomer is represented by the following general formula (a). This can provide: a sulfonium salt type monomer used as a sulfonium salt type quencher that is a material for a polymer contained in a chemically amplified resist composition that has excellent solvent solubility, high sensitivity, high contrast, and excellent lithography performance in lithography using high-energy radiation, and is resistant to pattern collapse even in fine pattern formation and has excellent etching resistance; a sulfonium salt type quencher consisting of the sulfonium salt type monomer; a polymer containing a repeating unit derived from the sulfonium salt type quencher; a chemically amplified resist composition including a base polymer containing the polymer; and a pattern forming method using the chemically amplified resist composition.

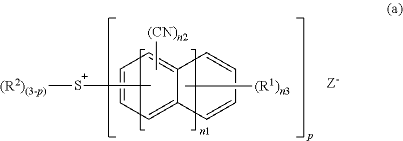

### TECHNICAL FIELD

The present invention relates to a sulfonium salt type monomer, a sulfonium salt type quencher, a polymer, a chemically amplified resist composition, and a pattern forming method.

### BACKGROUND ART

As LSIs become more highly integrated and faster, pattern rules are becoming finer at a rapid pace. In particular, the expansion of the flash memory market and the increase in memory capacity are driving miniaturization. The most advanced miniaturization technology is mass production of 65 nm node devices using ArF lithography, and preparations are underway for mass production of 45 nm node devices using next-generation ArF immersion lithography. Candidates for next-generation 32 nm node devices include immersion lithography using ultra-high NA lenses that combine a liquid with a higher refractive index than water, a high refractive index lens, and a high refractive index resist film, extreme ultraviolet (EUV) lithography with a wavelength of 13.5 nm, and double exposure (double patterning lithography) of ArF lithography, and these are being considered.

As miniaturization progresses and approaches the diffraction limit of light, the contrast of light decreases. This decrease in contrast of light causes a decrease in the resolution of hole and trench patterns and the focus margin in positive resist films.

Along with the miniaturization of patterns, line width roughness (LWR) of line patterns and dimensional uniformity (CDU) of hole patterns are becoming a problem. The effects of uneven distribution and aggregation of the base polymer and acid generator, as well as the effects of acid diffusion, have been pointed out. Furthermore, as the resist film becomes thinner, the LWR tends to increase, and the deterioration of the LWR due to the thinning of the resist film as miniaturization progresses has become a serious problem.

In resist compositions for EUV lithography, it is necessary to simultaneously achieve high sensitivity, high resolution, and low LWR. When the acid diffusion distance is shortened, the LWR becomes smaller, but the sensitivity becomes lower. For example, lowering the post-exposure bake (PEB) temperature reduces the LWR, but also lowers the sensitivity. Even if the amount of quencher added is increased, the LWR becomes smaller, but the sensitivity becomes lower. It is necessary to overcome the trade-off relationship between sensitivity and LWR.

In order to suppress acid diffusion, a resist compound containing a repeating unit derived from an onium salt of a sulfonic acid having a polymerizable unsaturated bond has been proposed (Patent Document 1). Such a so-called polymer-bonded type acid generator generates a polymer-type sulfonic acid upon exposure to light, and is therefore characterized by extremely short acid diffusion. Furthermore, sensitivity can also be improved by increasing the ratio of the acid generator. In the case of additive-type acid generators as well, increasing the amount added increases the sensitivity, but in this case, the acid diffusion distance also increases. Since acid diffuses non-uniformly, increased acid diffusion degrades LWR and CDU. It can be said that polymer type acid generators have high ability in terms of sensitivity, LWR, and CDU balance.

Since iodine atoms have a very large absorption of EUV at a wavelength of 13.5 nm, it has been confirmed that secondary electrons are generated from iodine atoms during exposure, and this is attracting attention in EUV lithography. Patent Document 2 proposes a photoacid generator in which an iodine atom is introduced into an anion, and Patent Document 3 proposes a photoacid generator containing a polymerizable group in which an iodine atom is introduced in an anion. Although it has been confirmed that this improves lithography performance to some extent, iodine atoms do not have high solubility in organic solvents, and there is a concern that they may precipitate in the solvent.

In order to further suppress acid diffusion, a resist composition has been proposed that uses as a polymer-bound type quencher a polymer containing a repeating unit derived from a sulfonium salt of a weak acid having a pKa of −0.8 or more and having a polymerizable group (Patent Documents 4 to 7). In Patent Document 4, carboxylic acids, sulfonamides, phenols, hexafluoroalcohols, etc. are listed as weak acids.

### CITATION LIST

### Patent Literature

Patent Document 1: JP4425776B2
Patent Document 2: JP6720926B2
Patent Document 3: JP6973274B2
Patent Document 4: W02019/167737A1
Patent Document 5: W02022/264845A1
Patent Document 6: JP2022115072A
Patent Document 7: JP7433394B1

### SUMMARY OF INVENTION

### Technical Problem

In a chemically amplified resist composition using an acid catalyst, there is a need to develop a resist composition that has even higher sensitivity, can improve LWR of line pattern and CDU of hole pattern, and also has excellent etching resistance after pattern formation.

The present invention has been made in view of the above circumstances. The purpose of the present invention is to provide a sulfonium salt type monomer used as a sulfonium salt type quencher that is a material for a polymer contained in a chemically amplified resist composition that has excellent solvent solubility, high sensitivity, high contrast, and excellent lithography performance in lithography using high-energy radiation, and is resistant to pattern collapse even in fine pattern formation and has excellent etching resistance; a sulfonium salt type quencher consisting of the sulfonium salt type monomer; a polymer containing a repeating unit derived from the sulfonium salt type quencher; a chemically amplified resist composition including a base polymer containing the polymer; and a pattern forming method using the chemically amplified resist composition.

### Solution to Problem

In order to solve the problems, the present invention provides a sulfonium salt type monomer, wherein the sulfonium salt type monomer is represented by the following general formula (a),

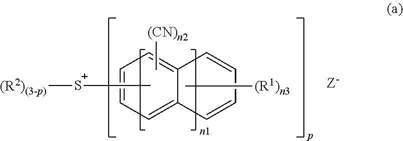

wherein “p” is 1, 2, or 3; n1 is 0 or 1; n2 is 1 or 2; n3 is an integer from 0 to 6; however, when n1 is 0, 1≤n≤2+n3≤5, and when n1 is 1, 1≤n2+n3≤7;
   R¹ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when n3 is 2 to 6, each R¹ may be the same or they may be different from each other, and two R¹ may be bonded to each other to form a ring together with the carbon atom to which they are bonded;
   R² is a halogen atom, or a hydrocarbyl group having 1 to 30 carbon atoms and optionally containing a heteroatom; when “p” is 1, two R² may be the same or they may be different from each other; furthermore, two of the three substituents bonded to S⁺ may be bonded to each other to form a ring together with the sulfur atom to which they are bonded; and
   Z⁻ is a carboxylate anion having an aromatic vinyl structure and an iodine atom.

Such a sulfonium salt type monomer can be used as a sulfonium salt type quencher, and a chemically amplified resist composition comprising a base polymer that includes a polymer containing a repeating unit derived from a sulfonium salt type quencher will have excellent solvent solubility, high sensitivity, high contrast, and excellent lithography performance in photolithography using high-energy radiation, and also will be resistant to pattern collapse even in fine pattern formation and have excellent etching resistance.

Furthermore, in the present invention, the sulfonium salt type monomer is preferably represented by the following general formula (a1),

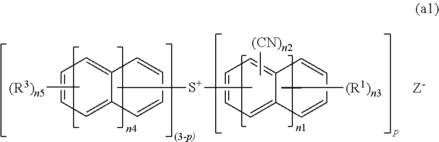

wherein “p”, n1 to n3, R¹, and Z⁻ are as defined above;
n4 is 0 or 1; n5 is an integer from 0 to 5;
   R³ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; and when n5 is 2 to 5, each R³ may be the same or they may be different from each other, and two R³ may be bonded to each other to form a ring together with the carbon atom to which they are bonded.

The sulfonium salt monomer of the present invention preferably has such a structure.

Furthermore, in the present invention, the Z⁻ is preferably an anion represented by the following general formula (Z),

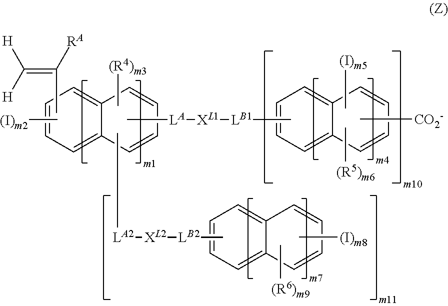

wherein m1 is 0 or 1; m2 is an integer from 0 to 4; m3 is an integer from 0 to 3; m4 is 0 or 1; m5 is an integer from 0 to 4; m6 is an integer from 0 to 3; m7 is 0 or 1; m8 is an integer from 0 to 4; m9 is an integer from 0 to 3; m10 is 0 or 1; m11 is 0 or 1; however, when m1 is 0, 0≤m2+m3+m11≤4, and when m1 is 1, 0≤m2+m3+m11≤6; when m4 is 0, 0≤m5+m6≤4, and when m4 is 1, 0≤m5+m6≤6; when m7 is 0, 0≤m8+m9≤5, and when m7 is 1, 0≤m8+m9≤7; furthermore, 1≤m2+m5+m8 4;
R^{A} is a hydrogen atom, a fluorine atom, a methyl group, or a trifluoromethyl group;
R⁴, R⁵, and R⁶ are a halogen atom other than an iodine atom, a nitro group, a cyano group, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when m3 is 2 or 3, each R⁴ may be the same or they may be different from each other, and two R⁴ may be bonded to each other to form a ring together with the carbon atoms to which they are bonded; when m6 is 2 or 3, each R⁵ may be the same or they may be different from each other, and two R⁵ may be bonded to each other to form a ring together with the carbon atoms to which they are bonded; when m9 is 2 or 3, each R⁶ may be the same or they may be different from each other, and two R⁶ may be bonded to each other to form a ring together with the carbon atoms to which they are bonded;
L^{A1}, L^{A2}, L^{B1}, and L^{B2} are each independently a single bond, an ether bond, a carbonyl group, an ester bond, a sulfonate ester bond, an amide bond, a sulfonamide bond, a carbonate bond, or a carbamate bond; and
X^{L1} and X^{L2} are each independently a single bond, or a hydrocarbylene group having 1 to 40 carbon atoms and optionally containing a heteroatom.

The sulfonium salt type monomer of the present invention preferably has such an anion.

Furthermore, the present invention also provides a sulfonium salt type quencher, wherein the sulfonium salt type quencher is comprised of the sulfonium salt type monomer described above.

Such a sulfonium salt type quencher, the amplified resist composition comprising a base polymer that includes a polymer containing a repeating unit derived from it will have excellent solvent solubility, high sensitivity, high contrast, and excellent lithography performance in photolithography using high-energy radiation, and will also be resistant to pattern collapse even in fine pattern formation and have excellent etching resistance.

The present invention also provides a polymer, wherein the polymer contains a repeating unit derived from the sulfonium salt type quencher described above.

Such a polymer, a chemically amplified resist composition comprising a base polymer containing it will have excellent solvent solubility, high sensitivity, high contrast, and excellent lithography performance in photolithography using high-energy radiation, and will also be resistant to pattern collapse even in fine pattern formation and have excellent etching resistance.

In addition, in the present invention, the polymer preferably further contains a repeating unit represented by either or both of the following general formulae (b1) and (b2),

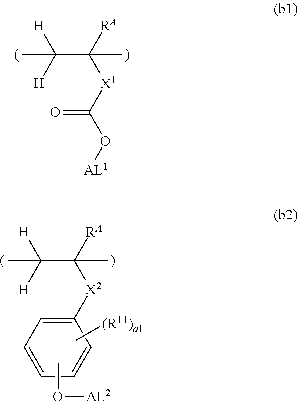

wherein R^{A} is each independently a hydrogen atom, a fluorine atom, a methyl group, or a trifluoromethyl group;
X¹ is a single bond, a phenylene group, a naphthylene group, *—C(═O)—OX¹¹—, or *—C(═O)—NH—X¹¹, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; X¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring;
X² is a single bond, *—C(═O)—O—, or *—C(═O)—NH—;
* indicates a bond to a carbon atom in the main chain;
R¹¹ is a halogen atom, a cyano group, a hydroxy group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom; when a1 is 2 or more, each R¹¹ may be the same or they may be different from each other;
AL¹ and AL² are each independently an acid-labile group; and
a1 is an integer from 0 to 4.

In addition, in the present invention, the polymer preferably further contains a repeating unit represented by the following general formula (b3),

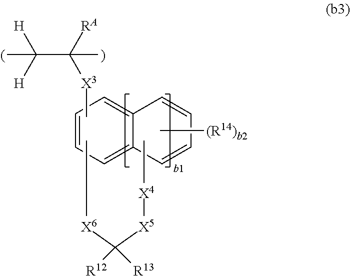

wherein b1 is 0 or 1; b2 is an integer from 0 to 3 when b1 is 0, and is an integer from 0 to 5 when b1 is 1;
   R^{A} is a hydrogen atom, a fluorine atom, a methyl group, or a trifluoromethyl group;
   X³ is a single bond, *—C(═O)—O—, or *—C(═O)—NH—; * indicates a bond to a carbon atom in the main chain;
   R¹² and R¹³ are each independently a hydrogen atom, or a hydrocarbyl group having 1 to 20 carbon atoms and optionally containing a heteroatom; furthermore, R¹² and R¹³ may be bonded to each other to form a ring together with the carbon atom to which they are bonded;
   R¹⁴ is a halogen atom, a hydroxy group, a cyano group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbyloxycarbonyl group having 2 to 20 carbon atoms and optionally containing a heteroatom, a hydrocarbylthio group having 1 to 20 carbon atoms and optionally containing a heteroatom, or —N(R^{14A})(R^{14B}); R^{14A} and R^{14B} are each independently a hydrogen atom or a hydrocarbyl group having 1 to 6 carbon atoms; when b2 is 2 or more, each R¹⁴ may be the same or they may be different from each other, and a plurality of R¹⁴ may be bonded to each other to form a ring together with the carbon atoms of the aromatic ring to which they are bonded;
   X⁴ is a single bond, an aliphatic hydrocarbylene group having 1 to 4 carbon atoms, a carbonyl group, a sulfonyl group, or a group obtained by combining these; and
   X⁵ and X⁶ are each independently an oxygen atom or a sulfur atom; however, X⁴ and X⁶ are bonded to adjacent carbon atoms of an aromatic ring.

In addition, in the present invention, the polymer preferably further contains a repeating unit represented by the following general formula (c),

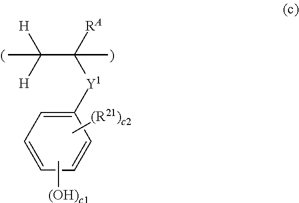

wherein R^{A} is a hydrogen atom, a fluorine atom, a methyl group, or a trifluoromethyl group;
Y¹ is a single bond, *—C(═O)—O—, or *—C(═O)—NH—; * indicates a bond to a carbon atom in the main chain;
R²¹ is a halogen atom, a carboxy group, a nitro group, a cyano group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom;
c1 is an integer from 1 to 4; and c2 is an integer from 0 to 3; however, 1≤c1+c2≤5.

In addition, in the present invention, the polymer preferably further contains a repeating unit derived from an onium salt type monomer containing a fluorosulfonate anion having a polymerizable group and at least one iodine atom, and a sulfonium cation.

In addition, in the present invention, the polymer preferably further contains a repeating unit represented by the following general formula (e),

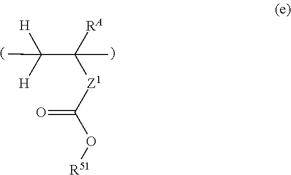

wherein R^{A} is a hydrogen atom, a fluorine atom, a methyl group, or a trifluoromethyl group;
   Z¹ is a single bond, a phenylene group, a naphthylene group, *—C(═O)—O—Z¹¹—, or *—C(═O)—NH—Z¹¹—, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; * indicates a bond to a carbon atom in the main chain; Z¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring; and
   R⁵¹ is a hydrogen atom, or a group having 1 to 20 carbon atoms containing at least one structure selected from a hydroxy group other than a phenolic hydroxy group, a cyano group, a carbonyl group, a carboxy group, an ether bond, an ester bond, a sulfonate ester bond, a carbonate bond, a lactone ring, a sultone ring, and a carboxylic anhydride (—C(═O)—O—C(═O)—).

The polymer of the present invention preferably has such a repeating unit.

The present invention also provides a chemically amplified resist composition contains a base polymer containing the above-described base polymer (A).

Such a chemically amplified resist composition will have excellent solvent solubility, high sensitivity, high contrast, and excellent lithography performance in photolithography using high-energy radiation, and will also have resistance to pattern collapse even in fine pattern formation and have excellent etching resistance.

Furthermore, in the present invention, the chemically amplified resist composition preferably further contains one or more types selected from an organic solvent (B), a quencher (C) other than the sulfonium salt type quencher, an acid generator (D), and a surfactant (E).

The chemically amplified resist composition of the present invention may contain these additives.

The present invention also provides a pattern forming method, wherein the pattern forming method contains a step of forming a resist film on a substrate using the chemically amplified resist composition described above, a step of exposing the resist film to high-energy radiation, and a step of developing the exposed resist film using a developer.

Such a pattern forming method can provide a pattern forming method using a chemically amplified resist composition that has excellent solvent solubility, high sensitivity, high contrast, and excellent lithography performance in photolithography using high-energy radiation, and is also resistant to pattern collapse even in fine pattern formation and has excellent etching resistance.

In this case, as the high-energy radiation, using an ArF excimer laser light with a wavelength of 193 nm, a KrF excimer laser light with a wavelength of 248 nm, an electron beam, or an extreme ultraviolet ray with a wavelength of 3 to 15 nm is preferable.

These can be used as the high-energy radiation.

### Advantageous Effects of Invention

A resist film obtained from a chemically amplified resist composition containing a polymer including a repeating unit derived from a sulfonium salt type quencher consisting of the sulfonium salt type monomer represented by the general formula (a) has good solvent solubility, and is characterized by low acid diffusion due to the large atomic weight of the iodine atom. This makes it possible to prevent a decrease in resolution due to blurring caused by acid diffusion, and improve LWR and CDU. In addition, since the absorption of EUV with a wavelength of 13.5 nm by iodine atoms is very large, secondary electrons are generated from the iodine atoms during exposure, resulting in high sensitivity. Furthermore, the cyano group contained in the cation is a strong electron withdrawing group, and when this group binds to the aromatic ring of the sulfonium cation, it lowers the LUMO in frontier molecular orbital theory, making it easier to accept secondary electrons, and thereby promoting the decomposition of the sulfonium cation. In addition, since the nitrogen atom of the cyano group has a lone electron pair, it can also be expected to function as an acid diffusion inhibitor group by interacting with the protons of the generated acid. On the other hand, a carboxylate anion is relatively highly basic and can effectively trap the acid generated from strong acids. This makes it possible to develop chemically amplified resist compositions that have high sensitivity while also having improved LWR and CDU. In addition, aromatic rings act as good etching resistance groups, making them suitable for forming fine patterns. In particular, in photolithography using high-energy radiation such as KrF excimer laser light, ArF excimer laser light, electron beams (EBs), and EUV, the chemically amplified resist composition has excellent solvent solubility, high sensitivity, high contrast, and excellent lithography performance such as exposure tolerance (EL), LWR, CDU, and depth of focus (DOF), and is also resistant to pattern collapse even in fine pattern formation and has excellent etching resistance.

### DESCRIPTION OF EMBODIMENTS

As described above, there has been a demand for the development of a sulfonium salt type monomer used as a sulfonium salt type quencher that is a material for a polymer contained in a chemically amplified resist composition that has excellent solvent solubility, high sensitivity, high contrast, and excellent lithography performance in lithography using high-energy radiation, and is resistant to pattern collapse even in fine pattern formation and has excellent etching resistance; a sulfonium salt type quencher consisting of the sulfonium salt type monomer; a polymer containing a repeating unit derived from the sulfonium salt type quencher; a chemically amplified resist composition including a base polymer containing the polymer; and a pattern forming method using the chemically amplified resist composition.

As a result of intensive studies to achieve the above objective, the present inventors found that by using, as a polymer-bonded type quencher, a polymer contains a repeating unit derived from a sulfonium salt, which contains a carboxylate anion having a styrene or vinylnaphthalene structure as a polymerizable group and an iodine atom, and contains a sulfonium cation having a cyano group, it is possible to obtain a chemically amplified resist composition that has excellent solvent solubility, high sensitivity, improved lithography performance such as EL, LWR, CDU, DOF, etc., high contrast, high resolution, and excellent etching resistance. Consequently, they completed the present invention.

That is, the present invention is a sulfonium salt type monomer, wherein the sulfonium salt type monomer is represented by the following general formula (a),

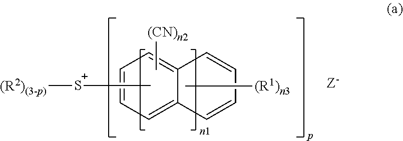

wherein “p” is 1, 2, or 3; n1 is 0 or 1; n2 is 1 or 2; n3 is an integer from 0 to 6; however, when n1 is 0, 1≤n2+n3≤5, and when n1 is 1, 1≤n2+n3≤7;
R¹ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when n3 is 2 to 6, each R¹ may be the same or they may be different from each other, and two R¹ may be bonded to each other to form a ring together with the carbon atoms to which they are bonded;
R² is a halogen atom, or a hydrocarbyl group having 1 to 30 carbon atoms and optionally containing a heteroatom; when “p” is 1, two R² may be the same or they may be different from each other; furthermore, two of the three substituents bonded to S⁺ may be bonded to each other to form a ring together with the sulfur atom to which they are bonded; and
Z⁻ is a carboxylate anion having an aromatic vinyl structure and an iodine atom.

Hereinafter, the present invention will be described in detail, but the present invention is not limited thereto.

### [Sulfonium Salt Type Monomer]

The sulfonium salt type monomer of the present invention is represented by the following general formula (a).

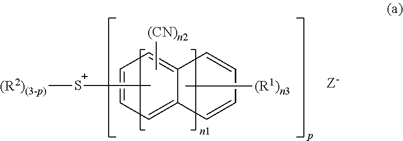

In the formula, “p” is 1, 2, or 3; n1 is 0 or 1; n2 is 1 or 2; n3 is an integer from 0 to 6; however, when n1 is 0, 1≤n2+n3≤5, and when n1 is 1, 1≤n2+n3≤7;
R¹ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when n3 is 2 to 6, each R¹ may be the same or they may be different from each other, and two R¹ may be bonded to each other to form a ring together with the carbon atoms to which they are bonded;
R² is a halogen atom, or a hydrocarbyl group having 1 to 30 carbon atoms and optionally containing a heteroatom; when “p” is 1, two R² may be the same or they may be different from each other; furthermore, two of the three substituents bonded to S⁺ may be bonded to each other to form a ring together with the sulfur atom to which they are bonded; and
Z⁻ is a carboxylate anion having an aromatic vinyl structure and an iodine atom.

In the general formula (a), “p” is 1, 2, or 3.

In the general formula (a), n1 is 0 or 1. When n1 is 0, the structure is a benzene ring, and when n1 is 1, the structure is a naphthalene ring; however, from the viewpoint of solvent solubility, n1 is preferably 0, giving a benzene ring. n2 is 1 or 2. n2 is preferably 1 from the viewpoint of raw material procurement. n3 is an integer from 0 to 6. n3 is preferably 0, 1, or 2 from the viewpoint of raw material procurement. However, when n1 is 0, 1≤n2+n3≤5, and when n1 is 1, 1≤n2+n3≤7.

In the general formula (a), R¹ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. Examples of the halogen atom include a fluorine atom, a chlorine atom, a bromine atom, and an iodine atom. The hydrocarbyl group and the hydrocarbyl moiety of the hydrocarbyloxy group and the hydrocarbylthio group may be saturated or unsaturated, and may be linear, branched, or cyclic. Specific examples include alkyl groups having 1 to 20 carbon atoms such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyl group, an n-decyl group, an undecyl group, a dodecyl group, a tridecyl group, a tetradecyl group, a pentadecyl group, a heptadecyl group, a octadecyl group, a nonadecyl group, and an icosyl group; cyclic saturated hydrocarbyl groups having 3 to 20 carbon atoms such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms such as a vinyl group, a 1-propenyl group, 2-propenyl group, a butenyl group, and a hexenyl group; cyclic unsaturated hydrocarbyl groups having 3 to 20 carbon atoms such as a cyclohexenyl group; aryl groups having 6 to 20 carbon atoms such as a phenyl group and a naphthyl group; aralkyl groups having 7 to 20 carbon atoms such as benzyl group, a 1-phenylethyl group, and a 2-phenylethyl group; and groups obtained by combining these groups. Among these, aryl groups are preferred. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic acid anhydride (—C(═O)—O—C(═O)—), a haloalkyl group, etc. When n3 is 2 to 6, each R¹ may be the same or they may be different from each other. In addition, when n3 is 2 to 6, a plurality of R¹ may be bonded to each other to form a ring together with the carbon atom to which they are bonded. As the ring, a ring having 5 to 8 carbon atoms is preferable.

In the general formula (a), R² is a halogen atom, or a hydrocarbyl group having 1 to 30 carbon atoms and optionally containing aa heteroatom. when “p” is 1, two R² may be the same or they may be different from each other.

Specific examples of the halogen atom represented by R² are a fluorine atom, a chlorine atom, a bromine atom, and an iodine atom.

The hydrocarbyl group represented by R² may be saturated or unsaturated, and may be linear, branched, or cyclic. Specific examples thereof include alkyl groups having 1 to 30 carbon atoms, such as a methyl group, an ethyl group, an n-propyl group, an isopropyl group, an n-butyl group, an isobutyl group, a sec-butyl group, and a tert-butyl group; cyclic saturated hydrocarbyl groups having 3 to 30 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 30 carbon atoms, such as a vinyl group, a 1-propenyl group, a 2-propenyl group, a butenyl group, and a hexenyl group; cyclic unsaturated hydrocarbyl groups having 3 to 30 carbon atoms, such as a cyclohexenyl group; aryl groups having 6 to 30 carbon atoms, such as a phenyl group, a naphthyl group, and a thienyl group; aralkyl groups having 7 to 30 carbon atoms, such as a benzyl group, a 1-phenylethyl group, and a 2-phenylethyl group; and groups obtained by combining these groups, with aryl groups being preferable. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester group, a sulfonate ester bond, a carbonate bond, a lactone ring, a sultone ring, a carboxylic anhydride (—C(═O)—O—C(═O)—), a haloalkyl group, etc.

Also, two of the three substituents bonded to S⁺ may be bonded to each other to form a ring with the sulfur atom to which they are bonded. In this case, specific examples of the ring structure include those represented by the following formulae.

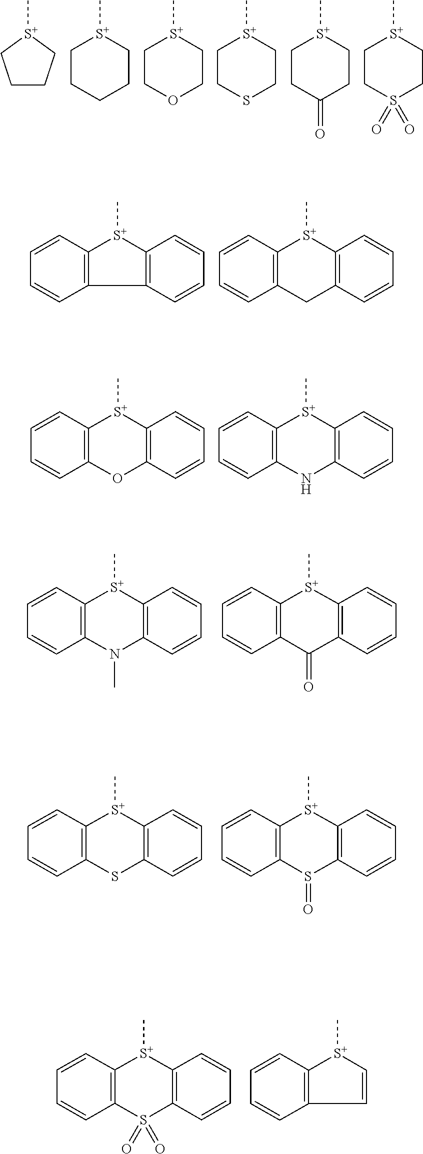

In the formulae, the dashed lines represent bonds.

Furthermore, in the present invention, the sulfonium salt type monomer is preferably represented by the following general formula (a1).

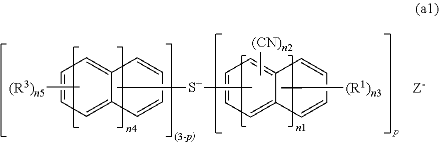

In the formula, “p”, n1 to n3, R¹, and Z⁻ are the same as above;
n4 is 0 or 1; n5 is an integer from 0 to 5;
R³ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; and when n5 is 2 to 5, each R³ may be the same or they may be different from each other, and two R³ may be bonded to each other to form a ring together with the carbon atoms to which they are bonded.

In the general formula (a1), n4 is 0 or 1. When n4 is 0, the structure is a benzene ring, and when n4 is 1, the structure is a naphthalene ring; however, from the viewpoint of solvent solubility, n4 is preferably 0, giving a benzene ring. n5 is an integer from 0 to 5. From the viewpoint of raw material procurement, n5 is preferably 0, 1 or 2.

In the general formula (a1), R³ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. The hydrocarbyl group and the hydrocarbyl moiety of the hydrocarbyloxy group and the hydrocarbylthio group may be saturated or unsaturated and may be linear, branched, or cyclic. Specific examples thereof include, but are not limited to, ones similar to those exemplified as the hydrocarbyl group represented by R¹. when n5 is 2 to 5, each R³ may be the same or they may be different from each other, and two R³ may be bonded to each other to form a ring together with the carbon atom to which they are bonded. Note that, the maximum number of carbon atoms in the group bonded to S⁺ containing R³ is 30.

Examples of the cation of the sulfonium salt type monomer represented by the general formula (a1) include, but are not limited to, those shown below.

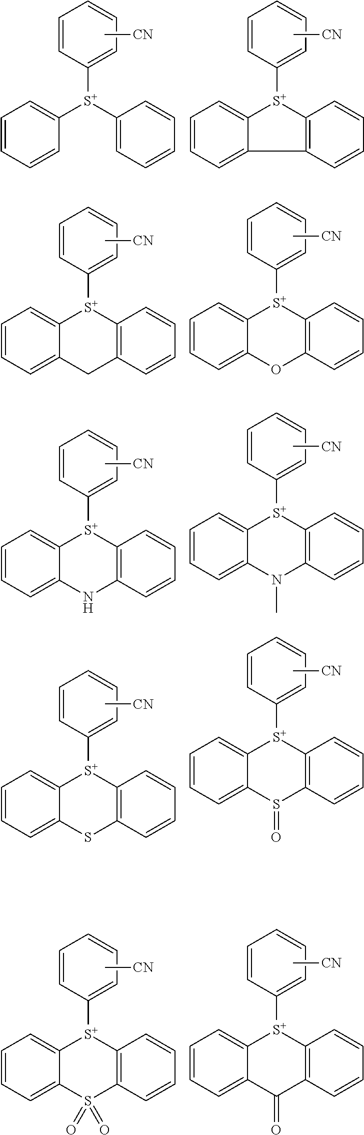

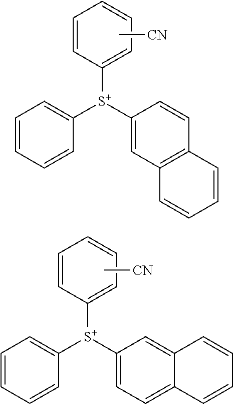

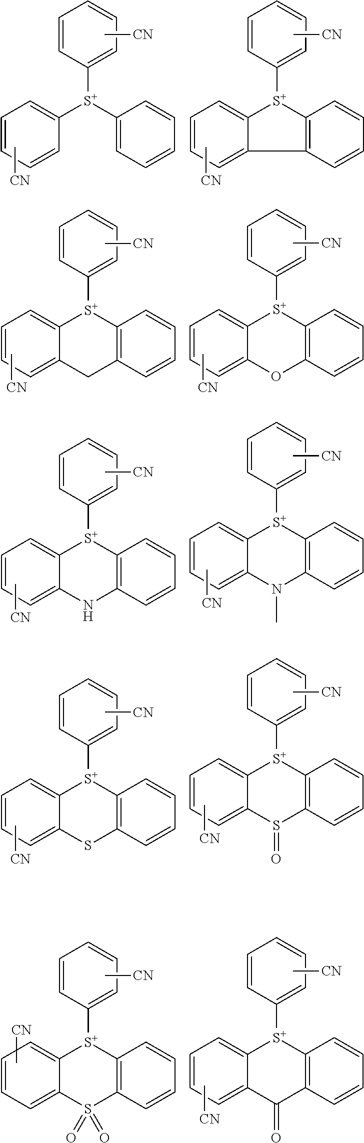

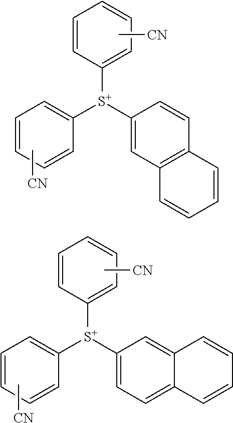

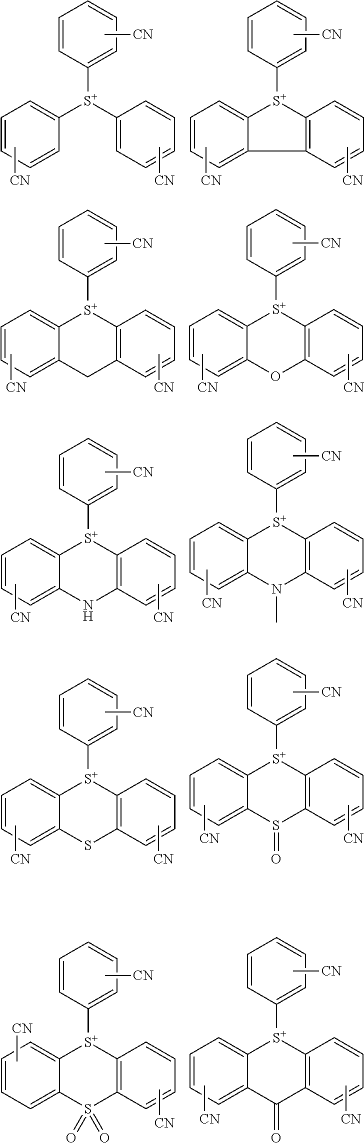

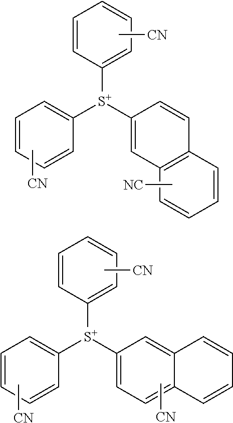

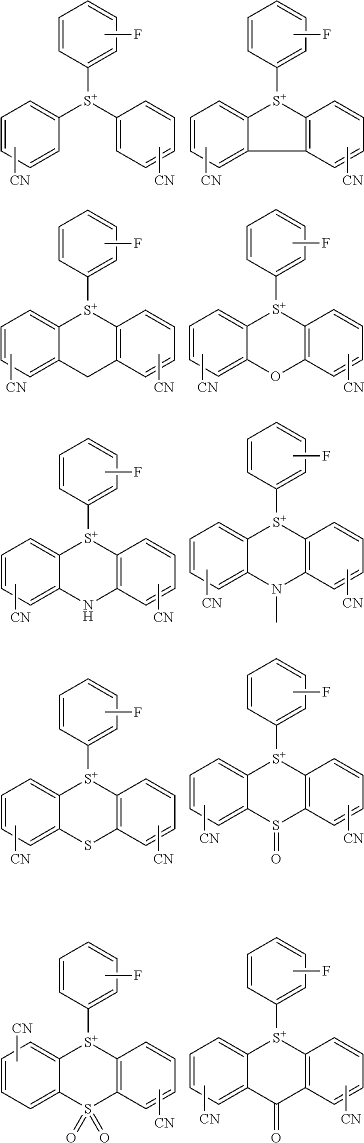

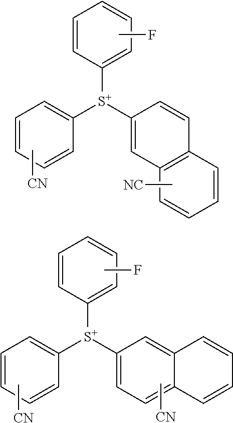

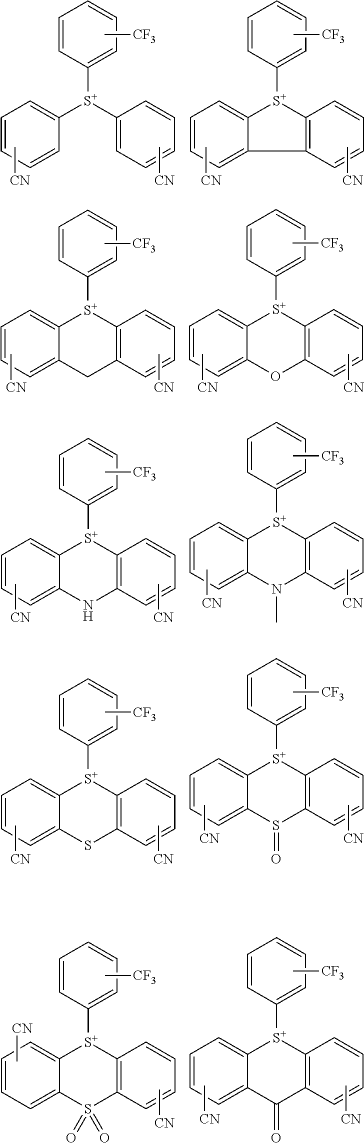

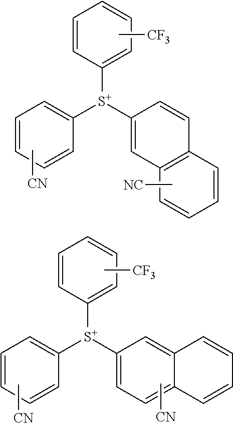

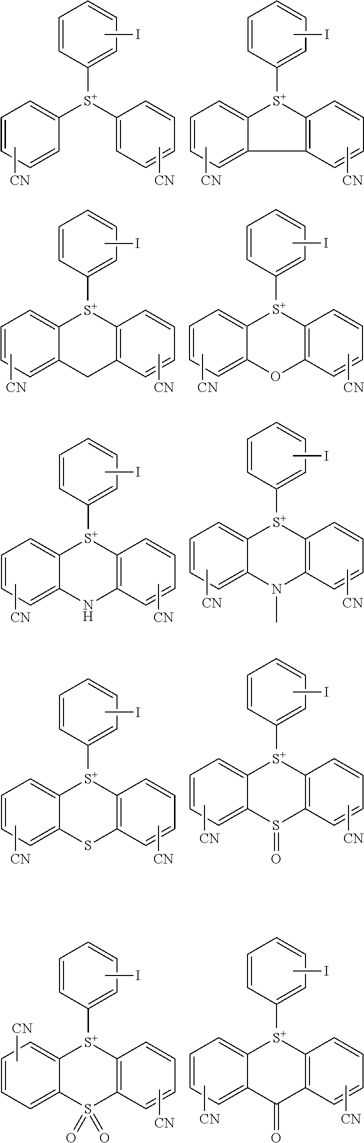

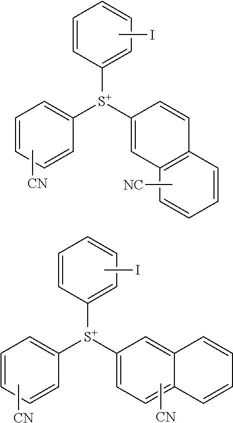

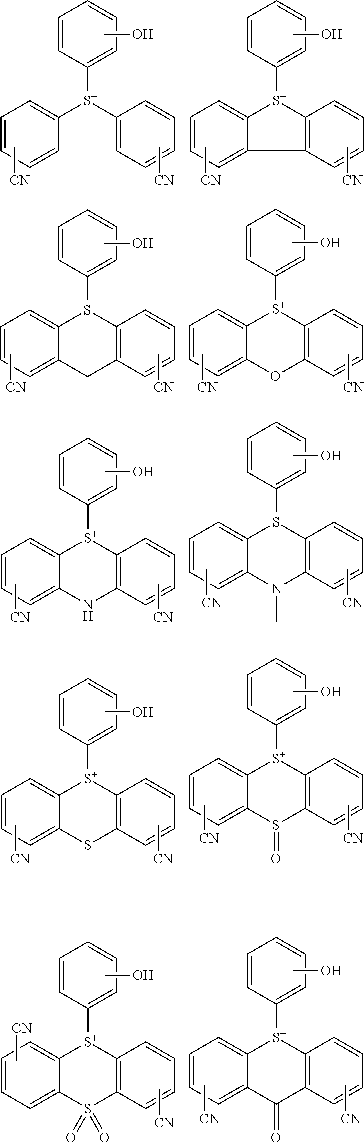

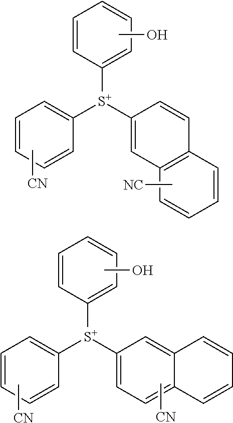

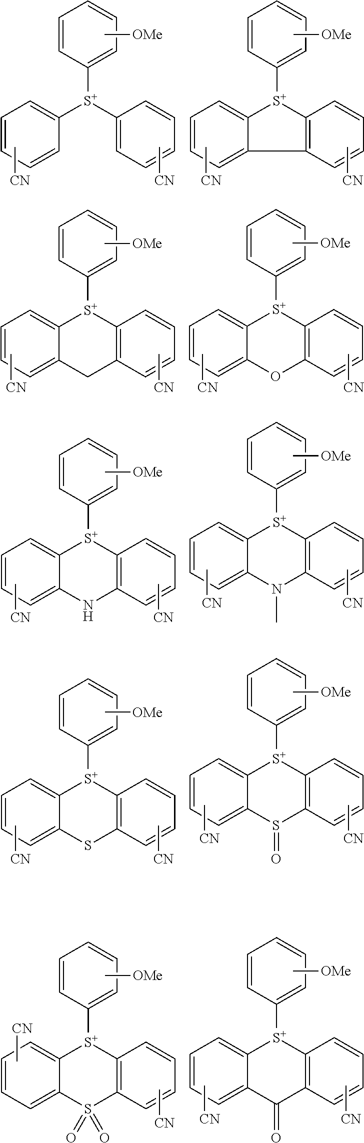

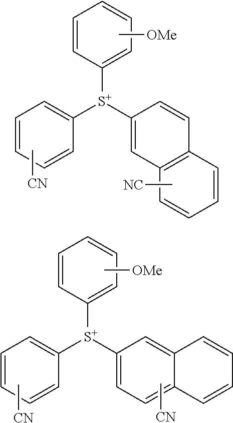

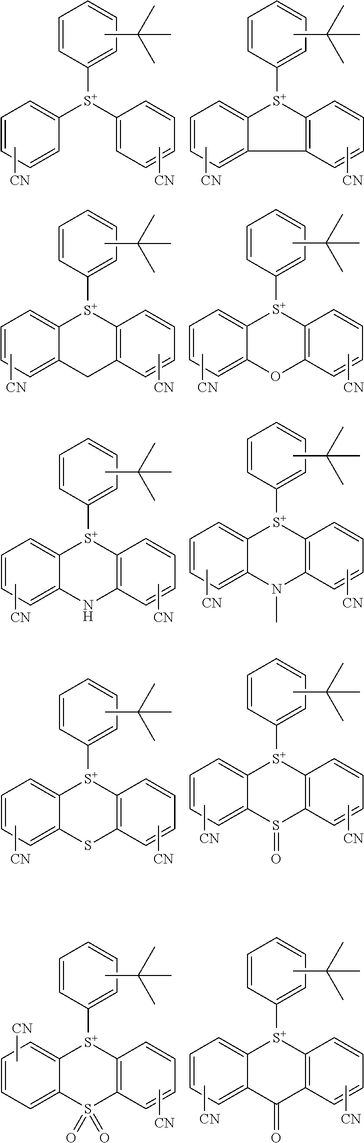

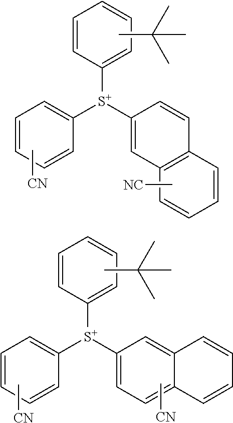

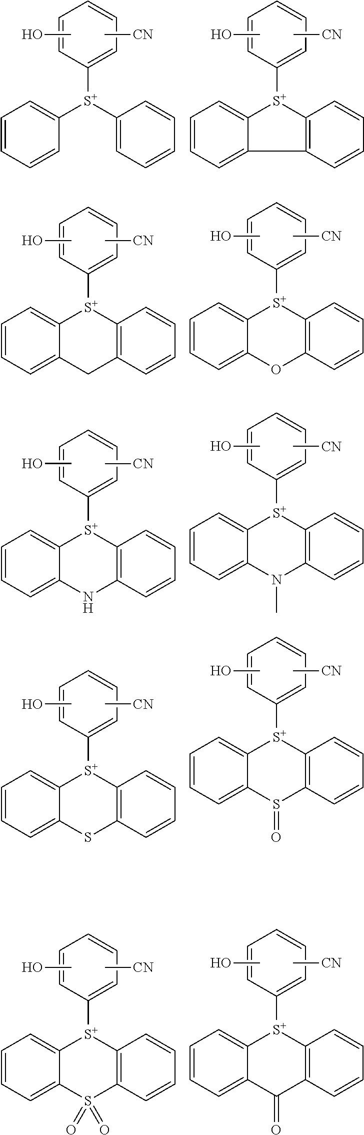

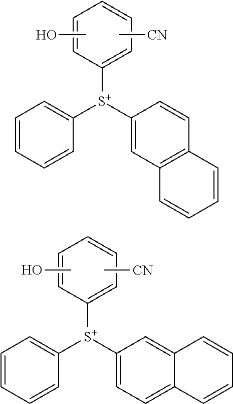

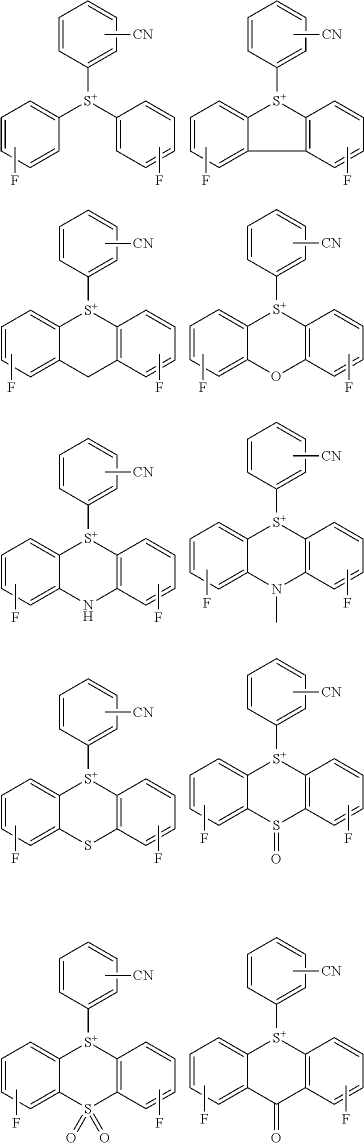

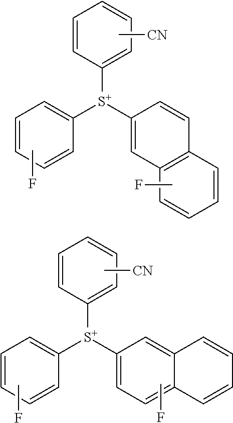

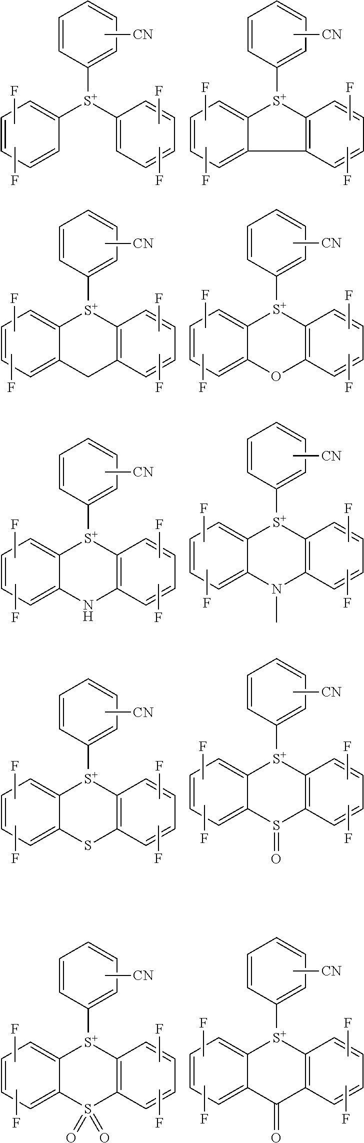

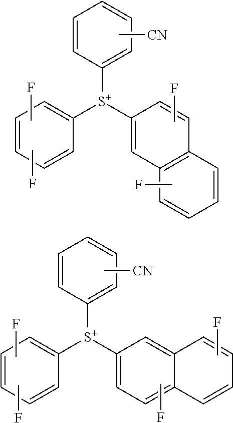

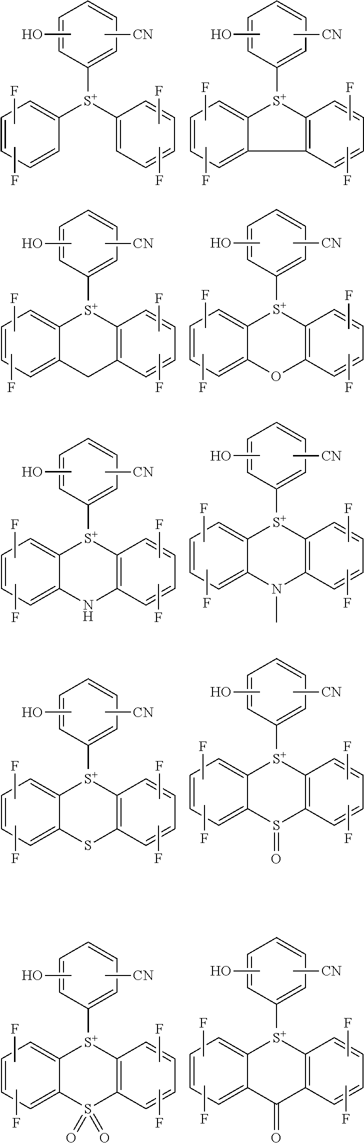

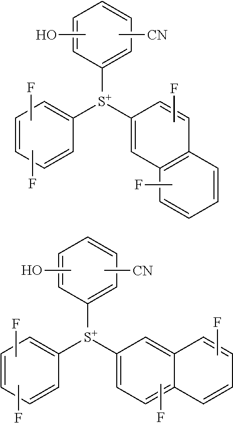

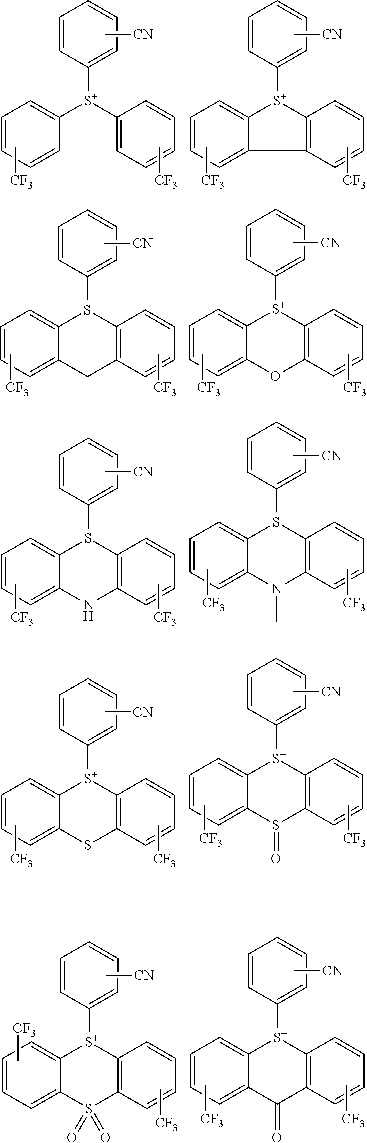

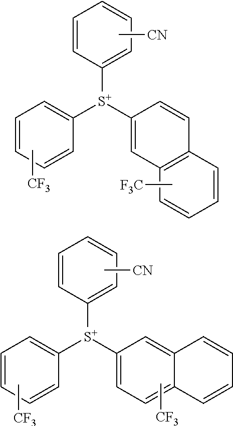

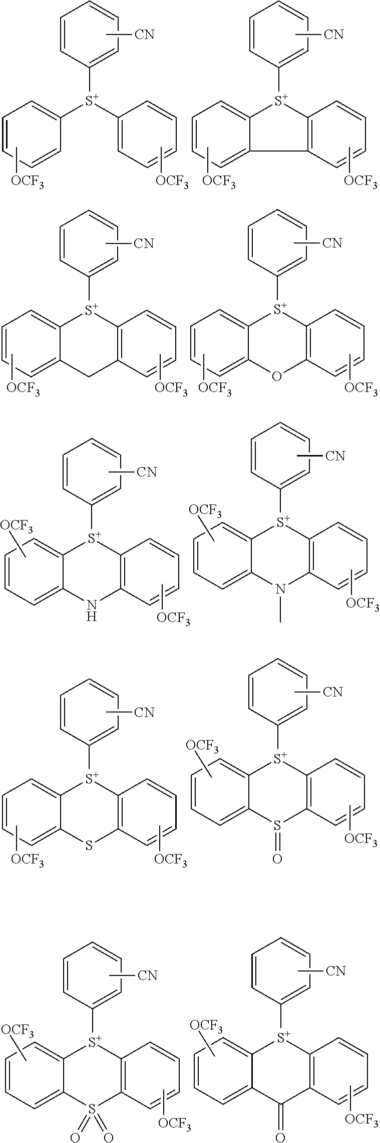

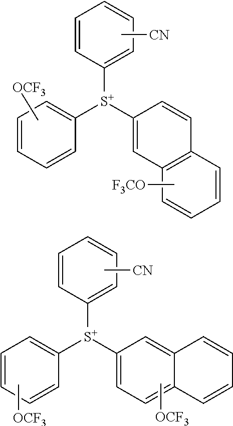

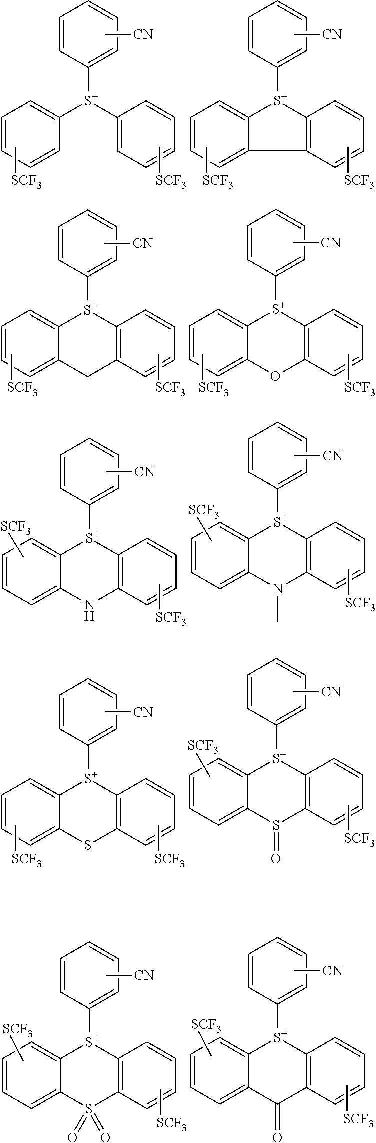

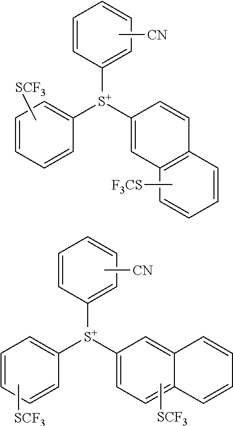

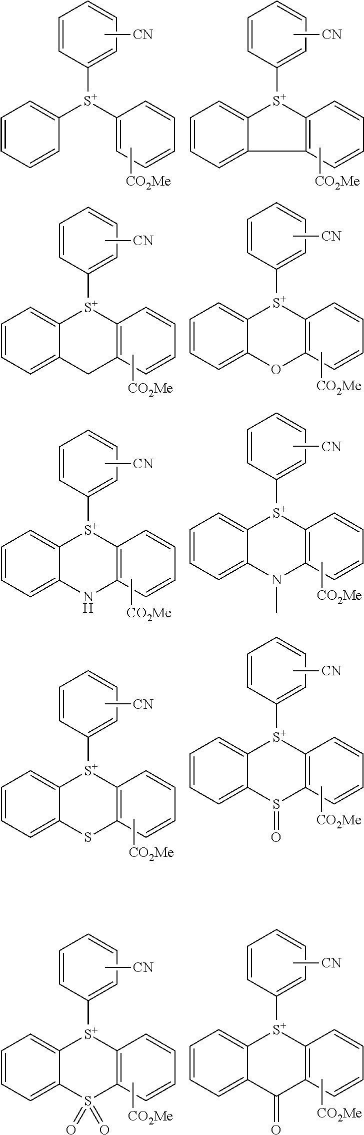

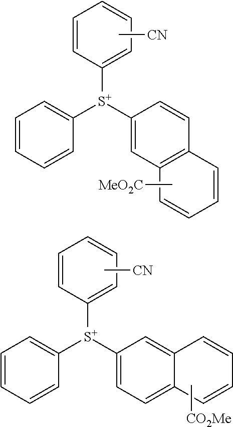

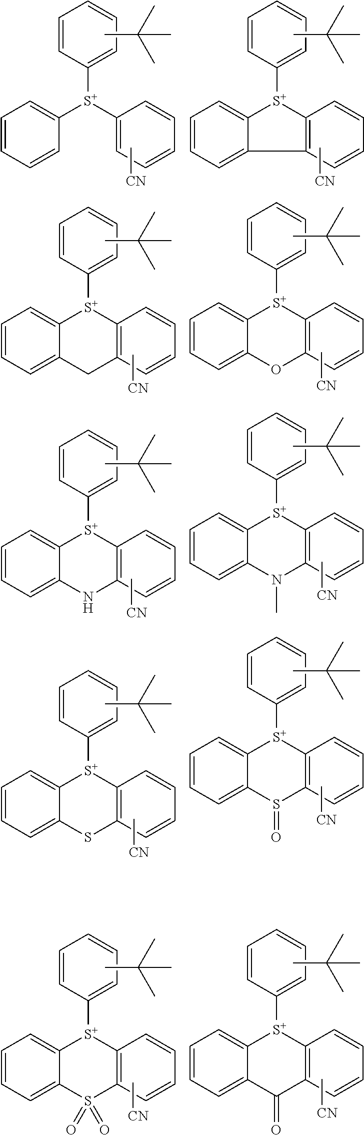

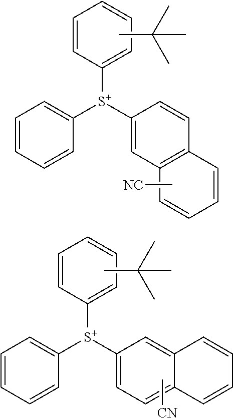

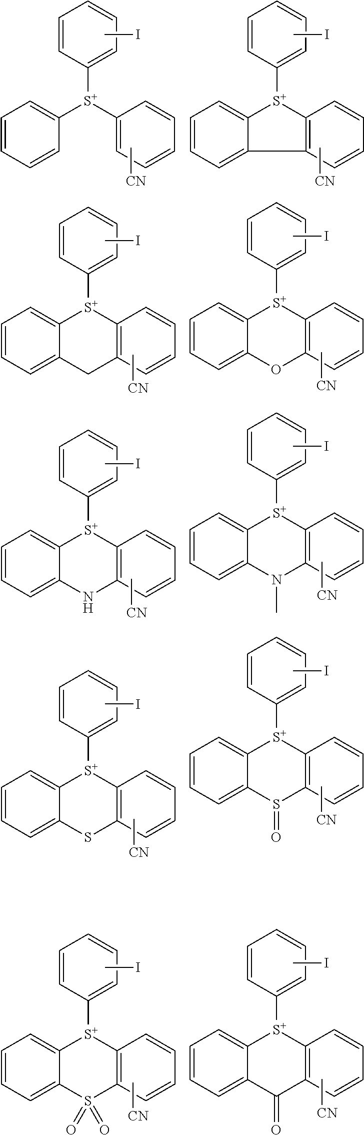

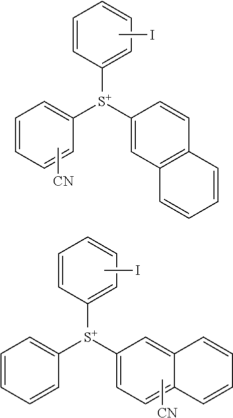

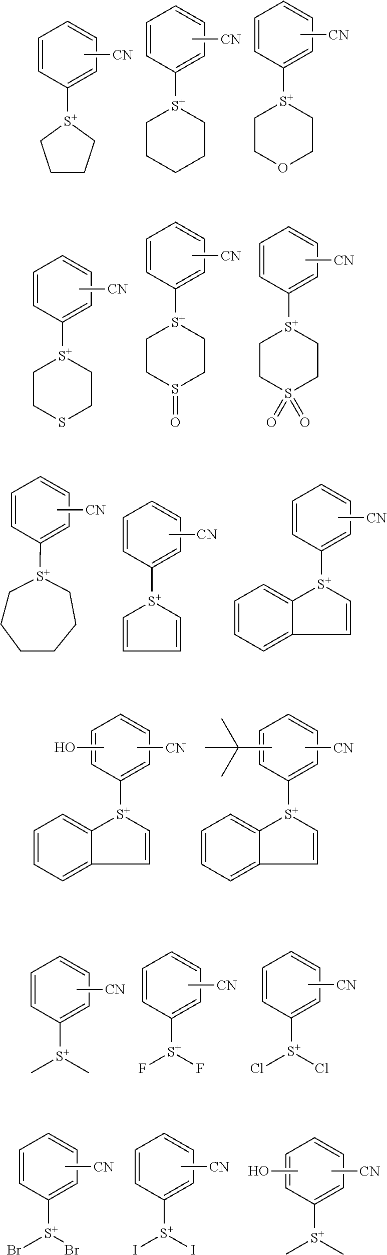

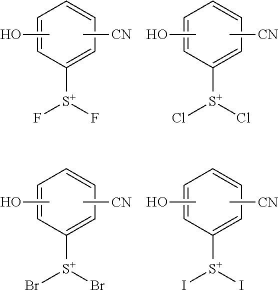

In the general formulae (a) and (a1), Z⁻ is a carboxylate anion having an aromatic vinyl structure and an iodine atom. The Z⁻ is preferably an anion represented by the following general formula (Z).

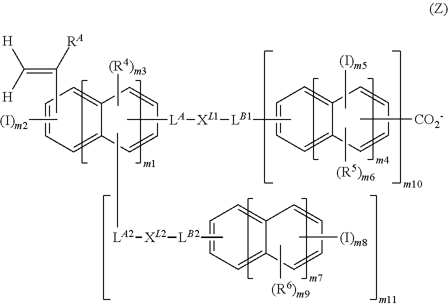

In the formula, m1 is 0 or 1; m2 is an integer from 0 to 4; m3 is an integer from 0 to 3; m4 is 0 or 1; m5 is an integer from 0 to 4; m6 is an integer from 0 to 3; m7 is 0 or 1; m8 is an integer from 0 to 4; m9 is an integer from 0 to 3; m10 is 0 or 1; m11 is 0 or 1; however, when m1 is 0, 0≤m2+m3+m11≤4, and when m1 is 1, 0≤m2+m3+m11≤6; when m4 is 0, 0≤m5+m6≤4, and when m4 is 1, 0≤m5+m6≤6; when m7 is 0, 0≤m8+m9≤5, and when m7 is 1, 0≤m8+m9≤7; furthermore, 1≤m2+m5+m8≤4;
R^{A} is a hydrogen atom, a fluorine atom, a methyl group, or a trifluoromethyl group;
R⁴, R⁵, and R⁶ are a halogen atom other than an iodine atom, a nitro group, a cyano group, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when m3 is 2 or 3, each R⁴ may be the same or they may be different from each other, and two R⁴ may be bonded to each other to form a ring together with the carbon atoms to which they are bonded; when m6 is 2 or 3, each R⁵ may be the same or they may be different from each other, and two R⁵ may be bonded to each other to form a ring together with the carbon atoms to which they are bonded; when m9 is 2 or 3, each R⁶ may be the same or they may be different from each other, and two R⁶ may be bonded to each other to form a ring together with the carbon atoms to which they are bonded;
L^{A1}, L^{A2}, L^{B1}, and L^{B2} are each independently a single bond, an ether bond, a carbonyl group, an ester bond, a sulfonate ester bond, an amide bond, a sulfonamide bond, a carbonate bond, or a carbamate bond; and
X^{L1} and X^{L2} are each independently a single bond, or a hydrocarbylene group having 1 to 40 carbon atoms and optionally containing a heteroatom.

In the general formula (Z), m1 is 0 or 1. When m1 is 0, the structure is a benzene ring, and when m1 is 1, the structure is a naphthalene ring; however, from the viewpoint of solvent solubility, m1 is preferably 0, giving a benzene ring. m2 is an integer from 0 to 4. From the viewpoint of raw material procurement, m2 is preferably 0, 1, 2, or 3, more preferably 0, 1, or 2, and further preferably 0 or 1. m3 is an integer from 0 to 3.

In the general formula (Z), m4 is 0 or 1. When m4 is 0, the structure is a benzene ring, and when m4 is 1, the structure is a naphthalene ring; however, from the viewpoint of solvent solubility, m4 is preferably 0, giving a benzene ring. m5 is an integer from 0 to 4. From the viewpoint of raw material procurement, m5 is preferably 0, 1, 2, or 3, and more preferably 0, 1, or 2. m6 is an integer from 0 to 3.

In the general formula (Z), m7 is 0 or 1. When m7 is 0, the structure is a benzene ring, and when m7 is 1, the structure is a naphthalene ring; however, from the viewpoint of solvent solubility, m7 is preferably 0, giving a benzene ring. m8 is an integer from 0 to 4. From the viewpoint of raw material procurement, m8 is preferably 1, 2, or 3, and more preferably 1 or 2. m9 is an integer from 0 to 3.

In the general formula (Z), m10 is 0 or 1. m11 is 0 or 1.

However, when m1 is 0, 0≤m2+m3+m11≤4, and when m1 is 1, 0≤m2+m3+m11≤6; when m4 is 0, 0≤m5+m6≤4, and when m4 is 1, 0≤m5+m6≤6; when m7 is 0, 0≤m8+m9≤5, and when m7 is 1, 0≤m8+m9≤7. In addition, regarding the number of iodine atoms in the anion, the larger the number of iodine atoms in the anion structure, the higher the absorption especially for EUV, but since there is a concern that solvent solubility will be poor and precipitation will occur in the resist composition, it is preferable that 1≤m2+m5+m8≤4.

In the general formula (Z), R^{A} is a hydrogen atom, a fluorine atom, a methyl group, or a trifluoromethyl group. Among these, a hydrogen atom or a methyl group is preferable, and a hydrogen atom is more preferable.

In the general formula (Z), R⁴ is a halogen atom other than an iodine atom, a nitro group, a cyano group, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. The halogen atom other than an iodine atom is preferably a fluorine atom, a chlorine atom, or a bromine atom, and more preferably a fluorine atom. The hydrocarbyl group and the hydrocarbyl moiety of the hydrocarbyloxy group and the hydrocarbylthio group may be saturated or unsaturated, and may be linear, branched, or cyclic. Specific examples thereof include alkyl groups having 1 to 20 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyls group, an n-decyl group, an undecyl group, a dodecyl group, a tridecyl group, a tetradecyl group, a pentadecyl group, a heptadecyl group, an octadecyl group, a nonadecyl group, and an icosyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, an allyl group, a propenyl group, a butenyl group, and a hexenyl group; cyclic unsaturated hydrocarbyl groups having 3 to 20 carbon atoms, such as a cyclohexenyl group; aryl groups having 6 to 20 carbon atoms, such as a phenyl group and a naphthyl group; aralkyl groups having 7 to 20 carbon atoms, such as a benzyl group, a 1-phenylethyl group, and a 2-phenylethyl group; and groups obtained by combining these groups. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc. When m3 is 2 or 3, each R⁴ may be the same or they may be different from each other.

Also, when m3 is 2 or 3, two R⁴ may be bonded to each other to form a ring together with the carbon atoms of the aromatic ring to which they are bonded. Specific examples of the ring formed in this case include a cyclopropane ring, a cyclobutane ring, a cyclopentane ring, a cyclohexane ring, a norbornane ring, an adamantane ring, etc. Furthermore, some or all of the hydrogen atoms of the ring may be substituted with a group containing a heteroatom such as an oxygen atom, a sulfur atom, a nitrogen atom, or a halogen atom, and some of the —CH₂— of the ring may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

In the general formula (Z), R⁵ is a halogen atom other than an iodine atom, a nitro group, a cyano group, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. Specific examples of the halogen atom other than an iodine atom include a fluorine atom, a chlorine atom, and a bromine atom. The hydrocarbyl group and the hydrocarbyl moiety of the hydrocarbyloxy group and the hydrocarbylthio group may be saturated or unsaturated, and may be linear, branched, or cyclic. Specific examples of these include, but are not limited to, ones similar to those exemplified as the hydrocarbyl group represented by R⁴. When m6 is 2 or 3, each R⁵ may be the same or they may be different from each other.

Also, when m6 is 2 or 3, two R⁵ may be bonded to each other to form a ring together with the carbon atom to which they are bonded. As the ring, a ring having 5 to 8 carbon atoms is preferable.

In the general formula (Z), R⁶ is a halogen atom other than an iodine atom, a nitro group, a cyano group, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. Specific examples of the halogen atom other than an iodine atom include a fluorine atom, a chlorine atom, and a bromine atom. The hydrocarbyl group and the hydrocarbyl moiety of the hydrocarbyloxy group and the hydrocarbylthio group may be saturated or unsaturated, and may be linear, branched, or cyclic. Specific examples of these include, but are not limited to, ones similar to those exemplified as the hydrocarbyl group represented by R⁴. When m9 is 2 or 3, each R⁶ may be the same or they may be different from each other.

Also, when m9 is 2 or 3, two R⁶ may be bonded to each other to form a ring together with the carbon atom to which they are bonded. As the ring, a ring having 5 to 8 carbon atoms is preferable.

In the general formula (Z), L^{A1}, L^{A2}, L^{B1}, and L^{B2} are each independently a single bond, an ether bond, a carbonyl group, an ester bond, a sulfonate ester bond, an amide bond, a sulfonamide bond, a carbonate bond, or a carbamate bond. Among these, L^{A1} is preferably a single bond, an ether bond, an ester bond, or a sulfonate ester bond, and more preferably an ether bond, an ester bond, or a sulfonate ester bond. L^{A2} is preferably a single bond, an ether bond, an ester bond, an amide bond, a sulfonamide bond, or a sulfonate ester bond, and more preferably an ester bond or a sulfonate ester bond. L^{B1} is preferably a single bond, an ether bond, an ester bond, an amide bond, or a sulfonate ester bond, and more preferably a single bond, an ether bond, or an ester bond. L^{B2} is preferably a single bond, an ether bond, an ester bond, an amide bond, or a sulfonate ester bond, and more preferably a single bond, an ether bond, or an ester bond.

When m11 is 1, L^{A1} and L^{A2} are preferably bonded to adjacent carbon atoms of an aromatic ring. In this case, the substituent containing the fluorosulfonate anion structure and the substituent containing an aromatic ring substituted with an iodine atom are located in closer spatial positions, so that it is expected to be more highly sensitive.

In the general formula (Z), X^{L1} and X^{L2} are each independently a single bond or a hydrocarbylene group having 1 to 40 carbon atoms and optionally containing a heteroatom. The hydrocarbylene group may be linear, branched, or cyclic, and specific examples thereof include an alkanediyl group, a cyclic saturated hydrocarbylene group, an arylene group, etc. Specific examples of the heteroatom include an oxygen atom, a nitrogen atom, and a sulfur atom.

Specific examples of the hydrocarbylene group having 1 to 40 carbon atoms represented by X^{L1} and X^{L2} include, but are not limited to, those shown below. In the following formulae, * represents a bond to L^{A1} and L^{B1}, or L^{A2} and L^{B2}.

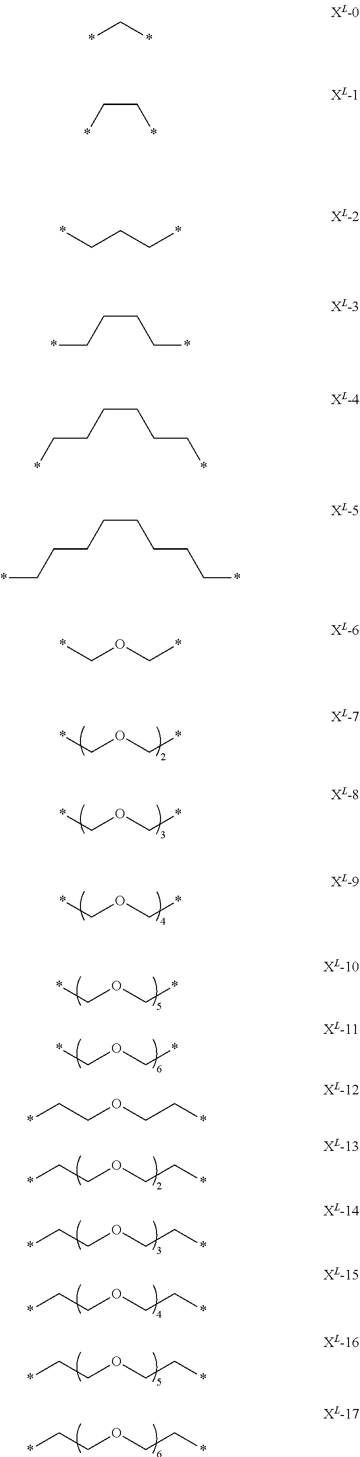

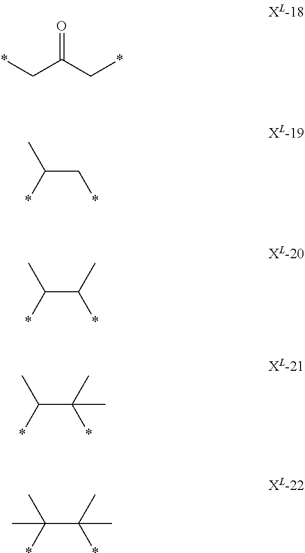

Among these, X^{L}-0 to X^{L}-22, X^{L}-29 to X^{L}-34, and X^{L}-47 to X^{L}-58 are preferable.

The anion of the onium salt monomer represented by the general formula (a) preferably does not contain a salicylic acid structure. Specific examples of the anion include, but are not limited to, those shown below. In the following formulae, R^{A} is as defined above, and Me is a methyl group. In addition, the bonding positions of the various substituents on the aromatic ring may be interchanged across the aromatic ring.

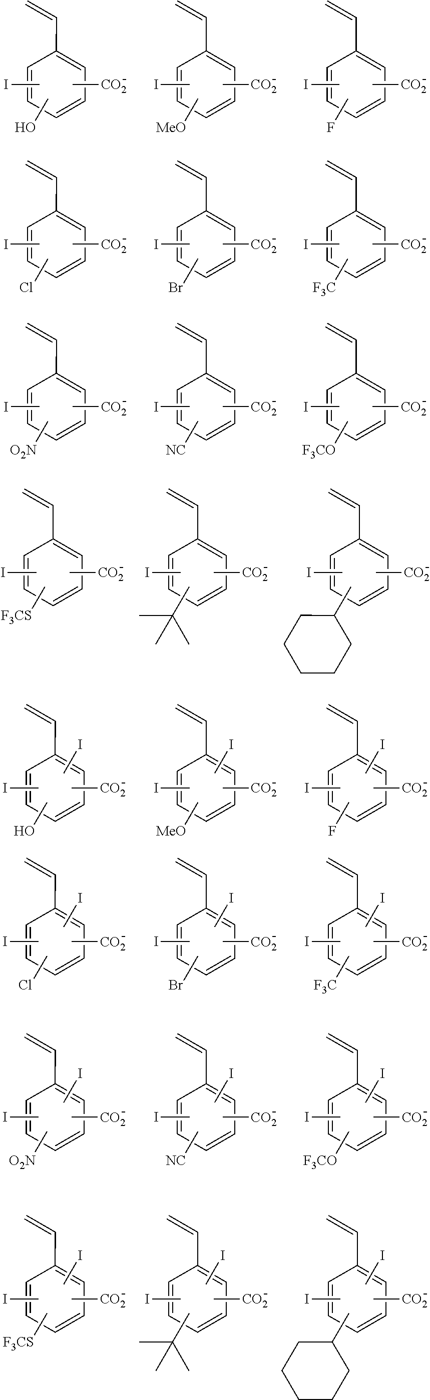

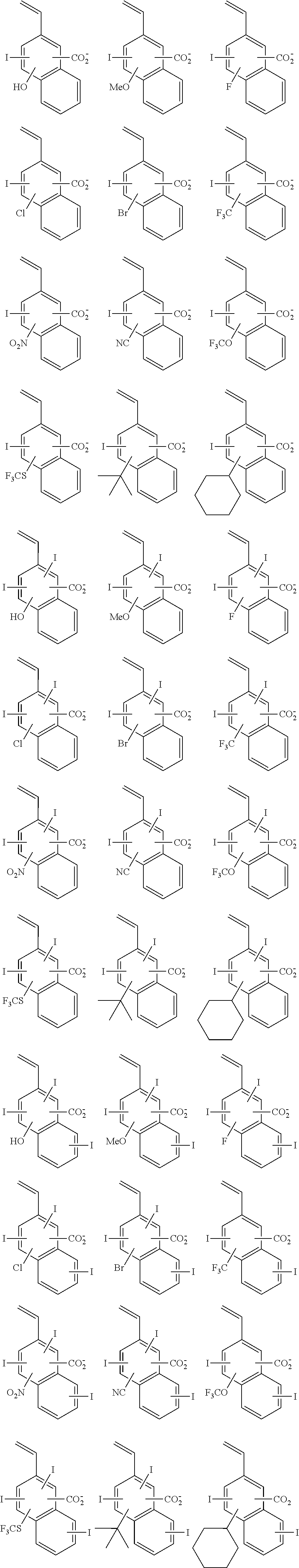

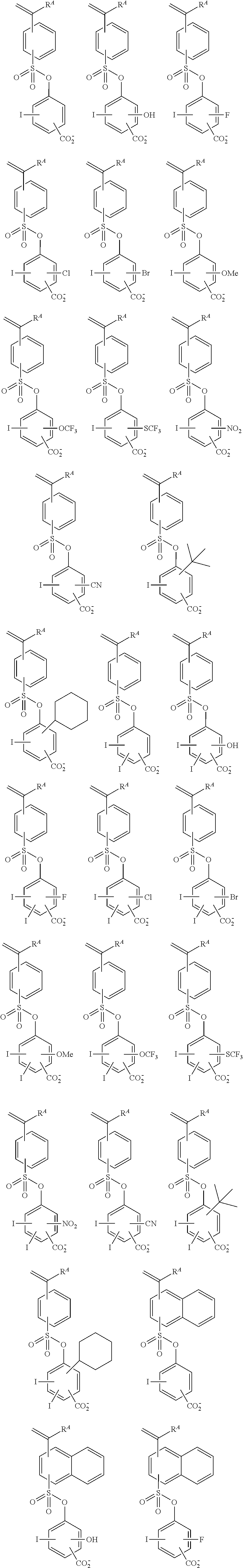

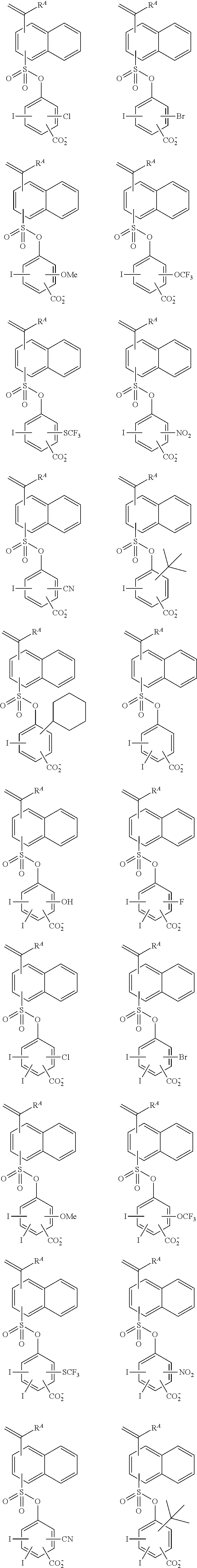

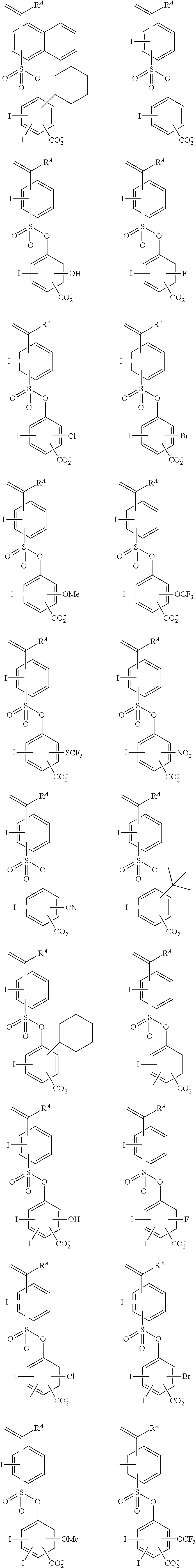

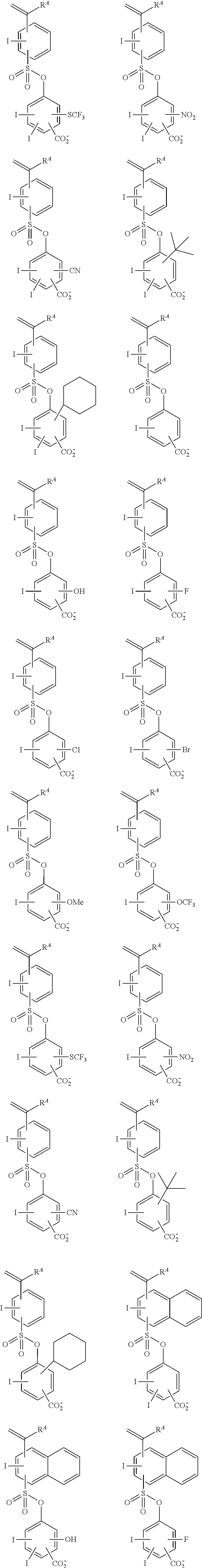

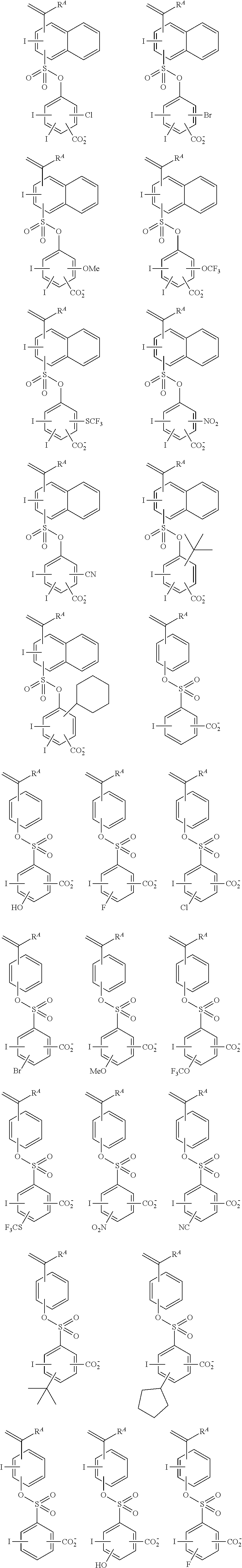

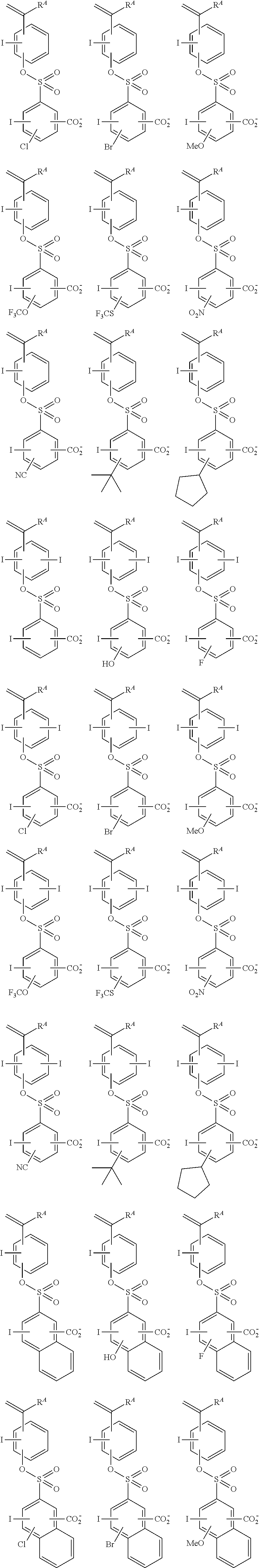

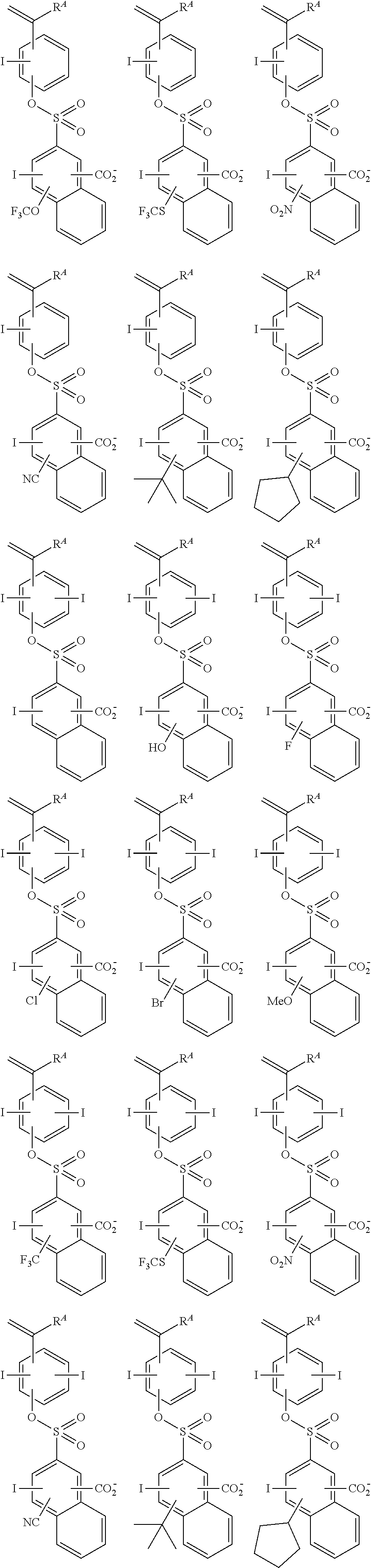

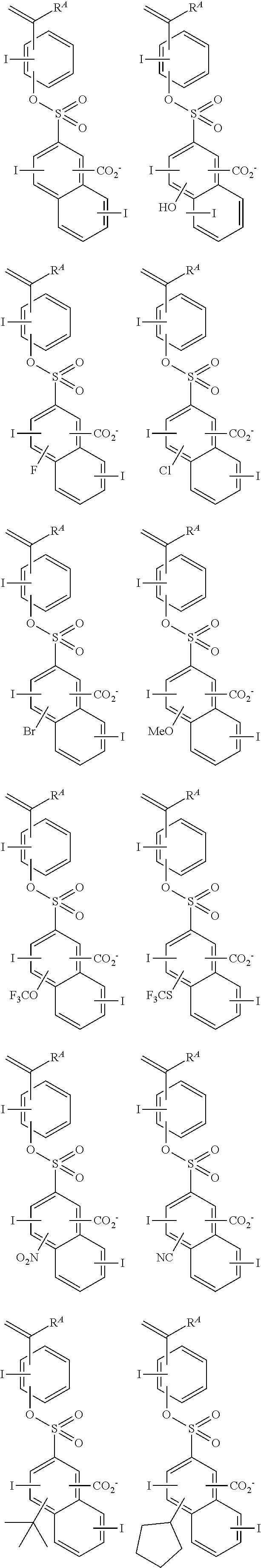

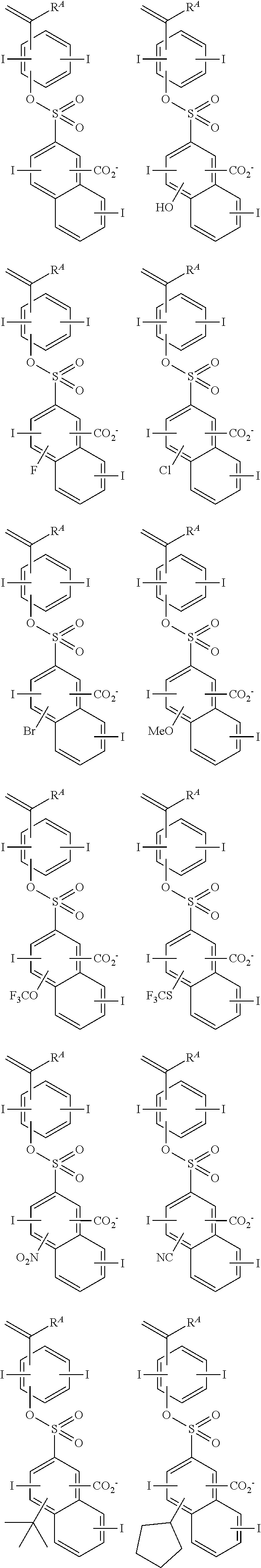

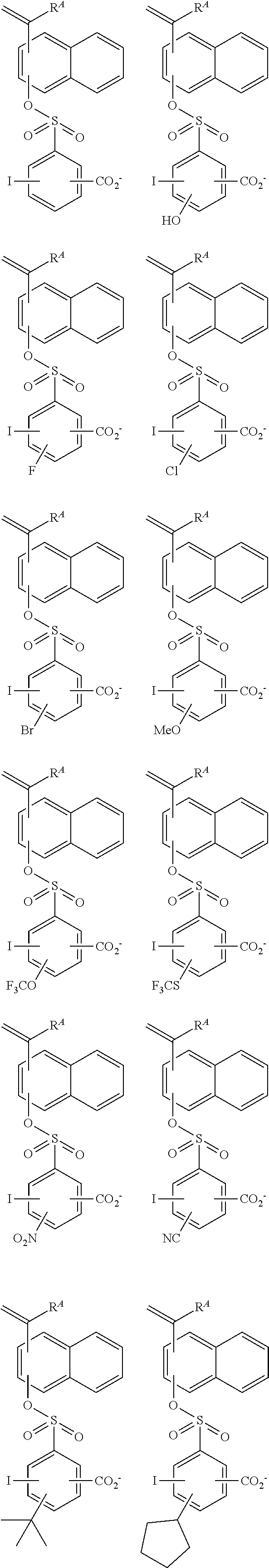

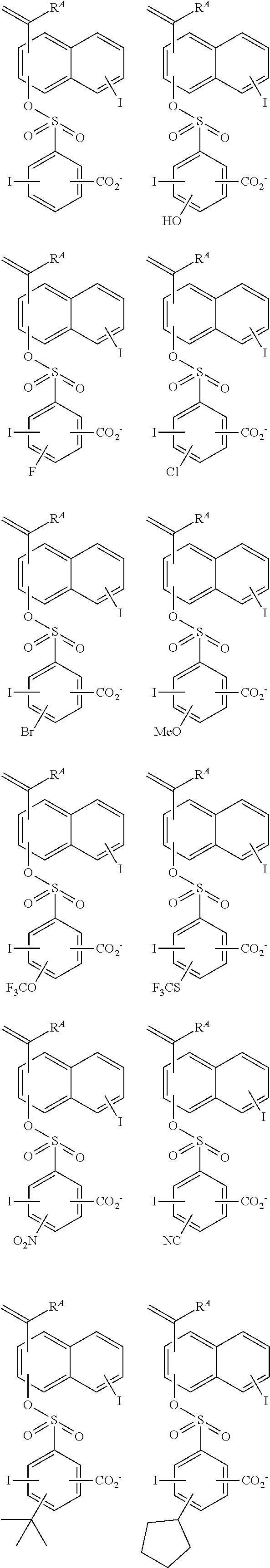

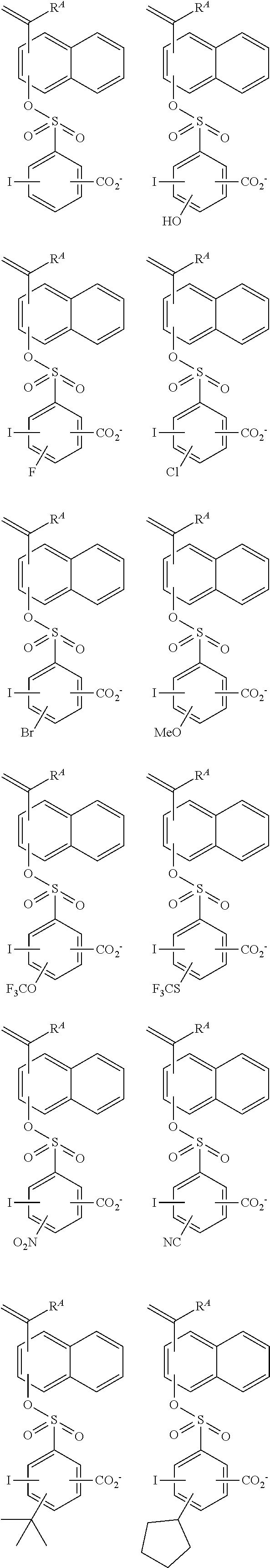

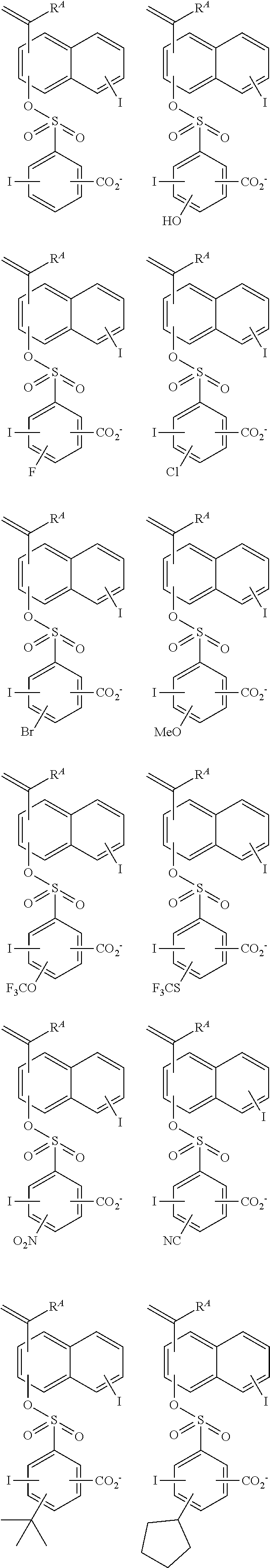

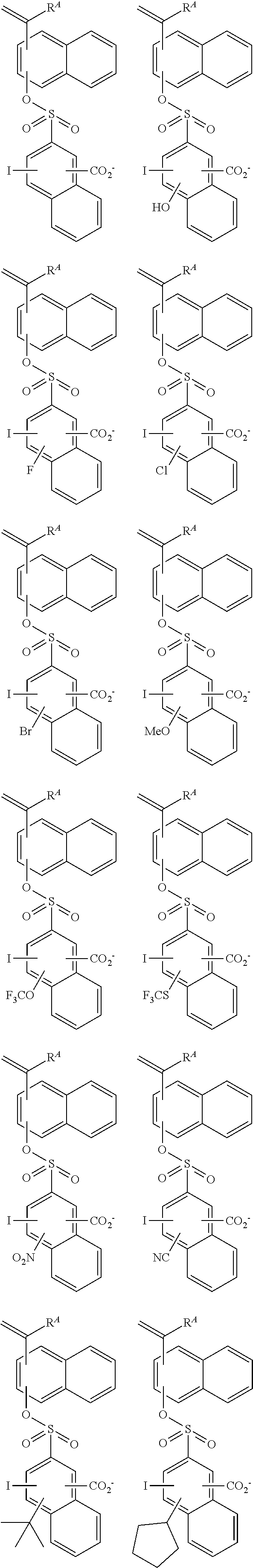

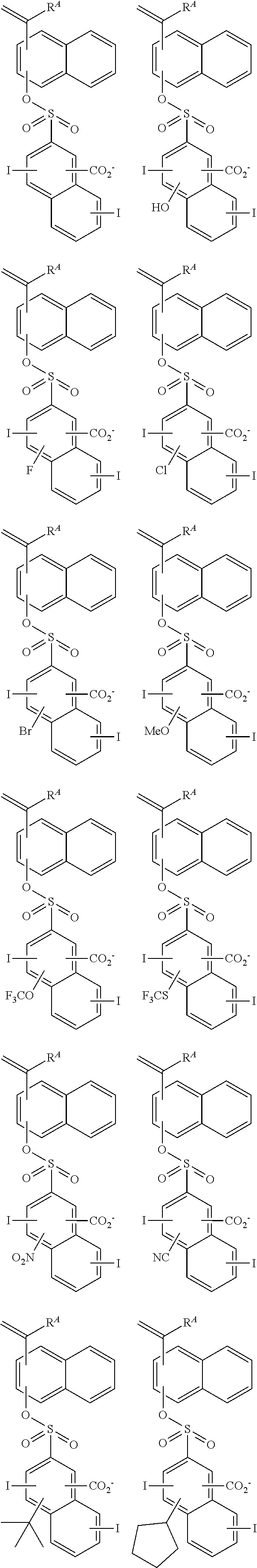

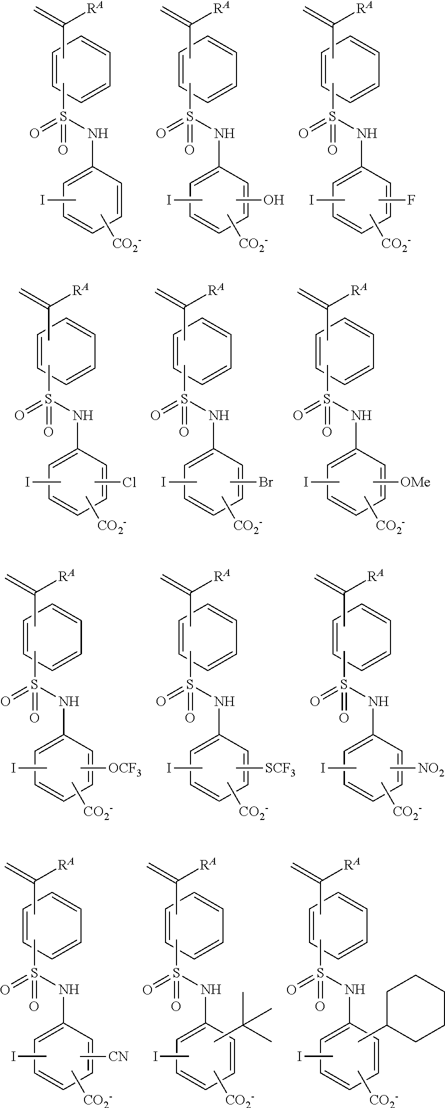

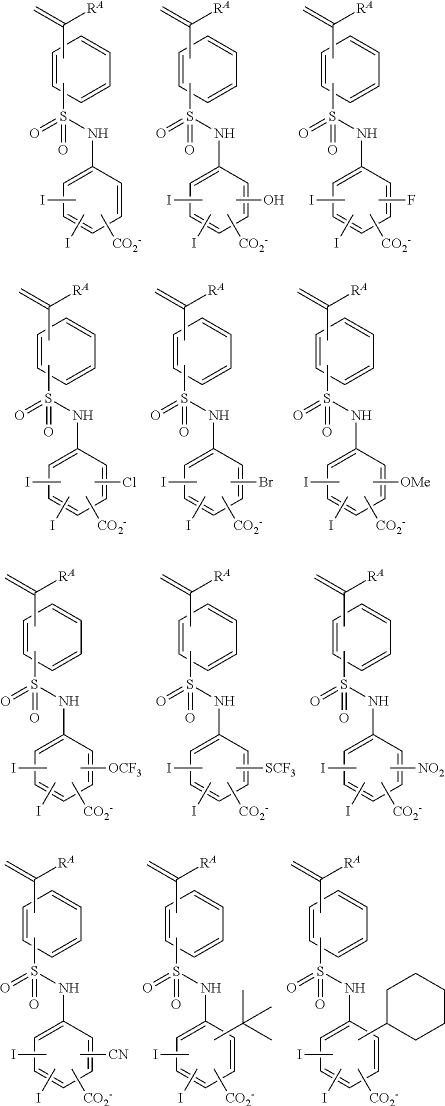

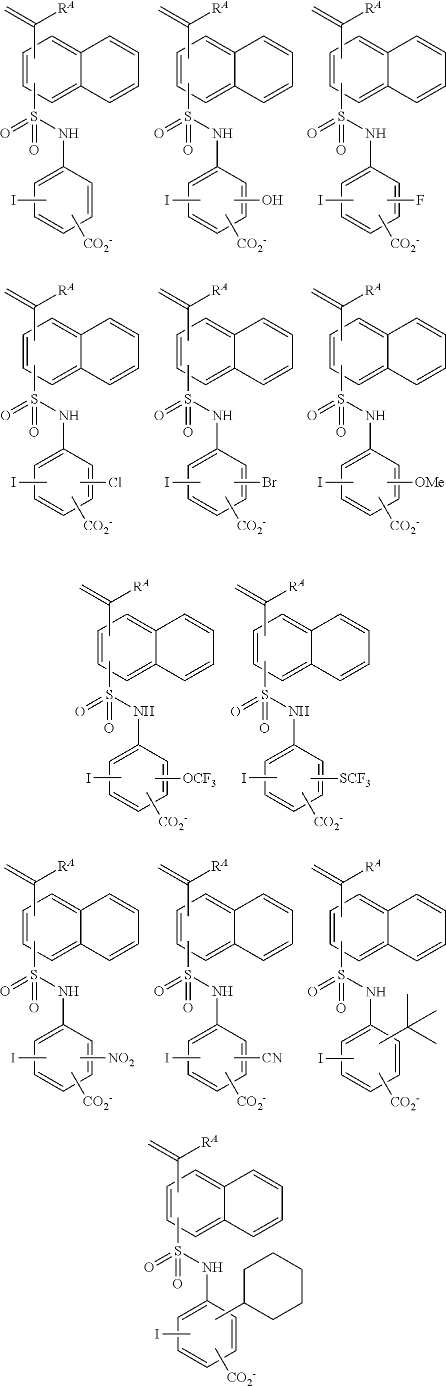

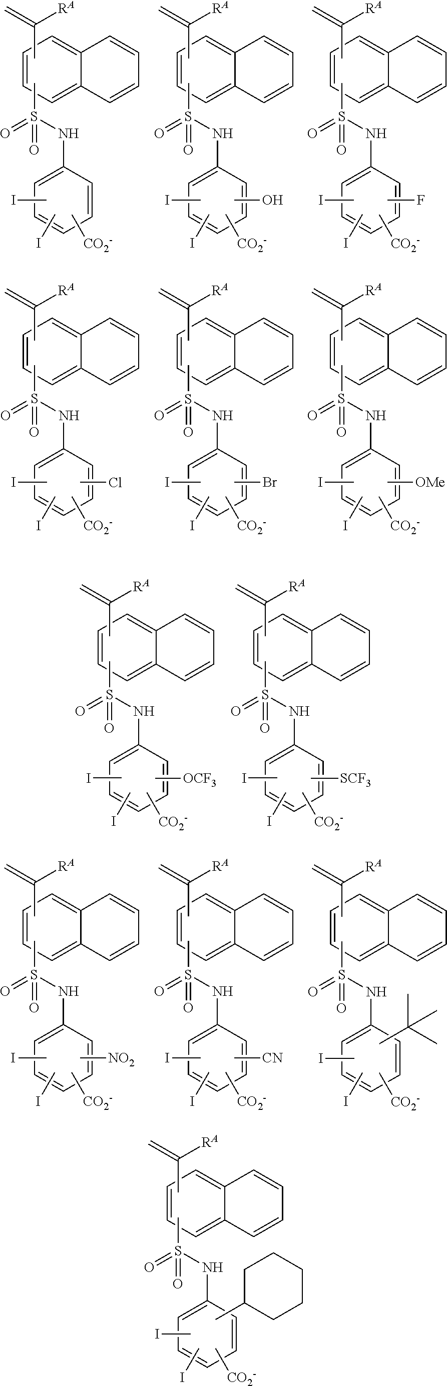

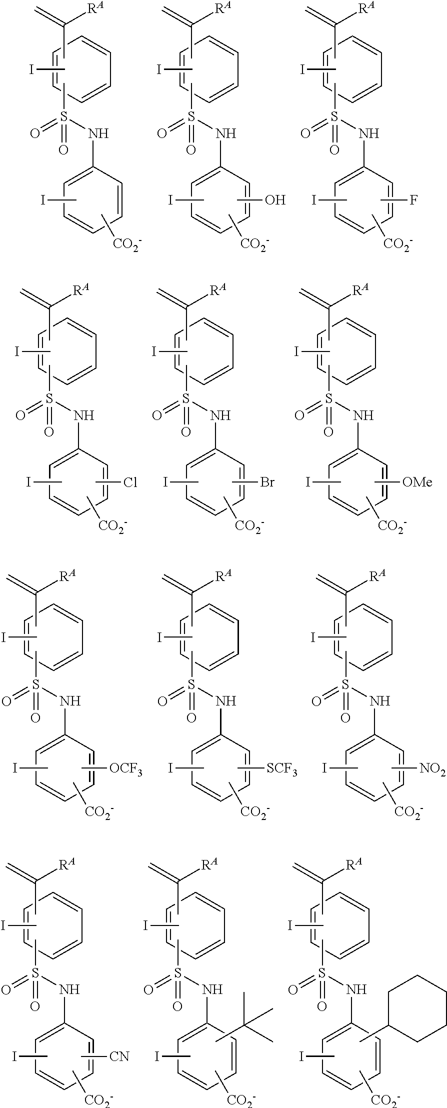

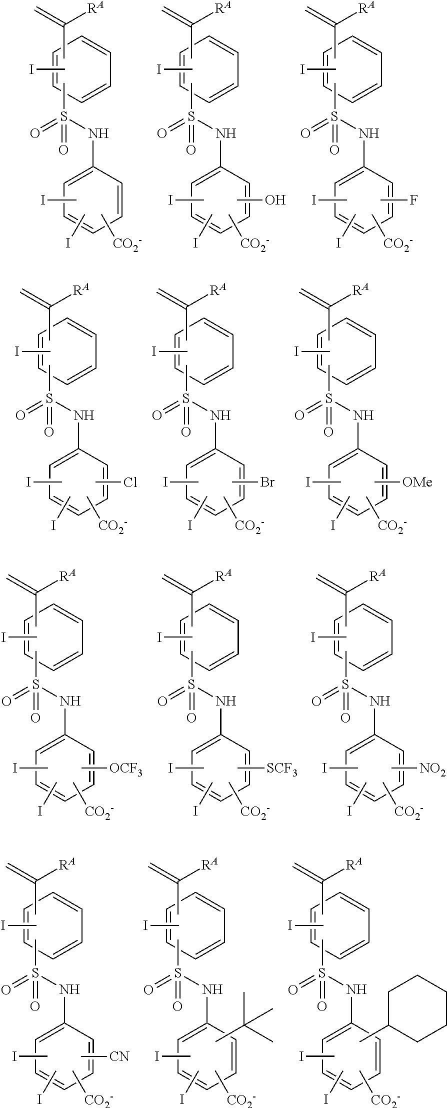

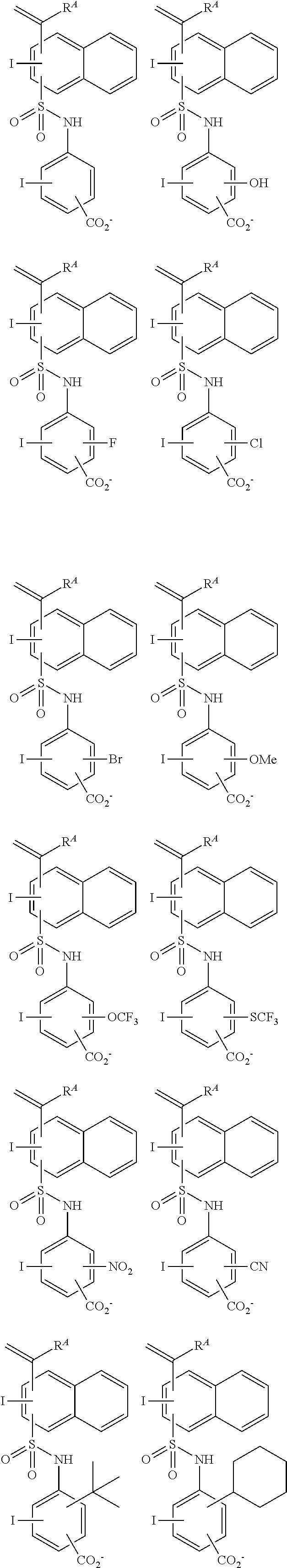

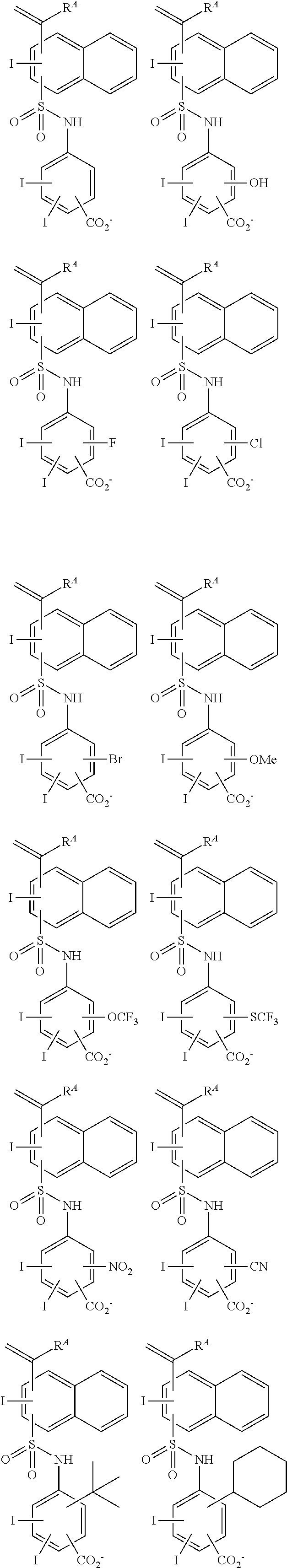

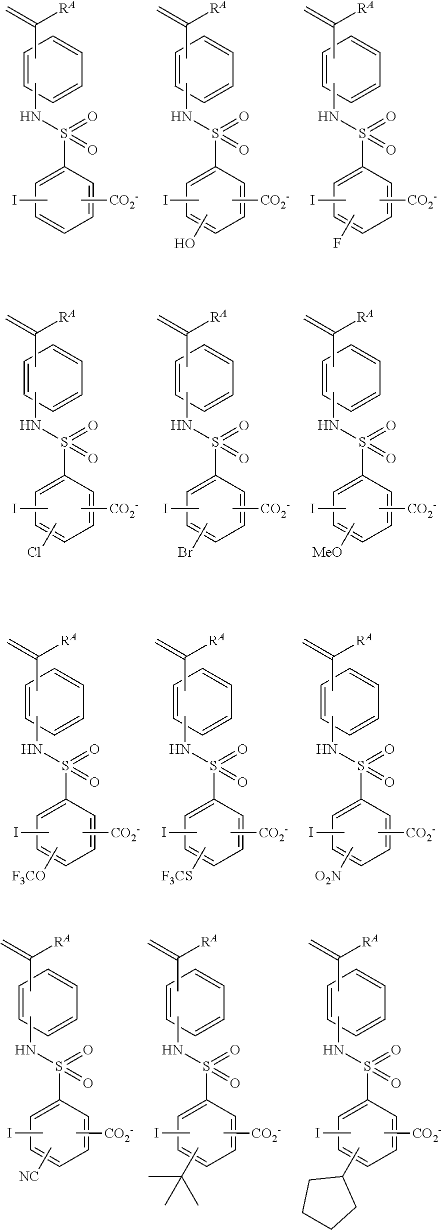

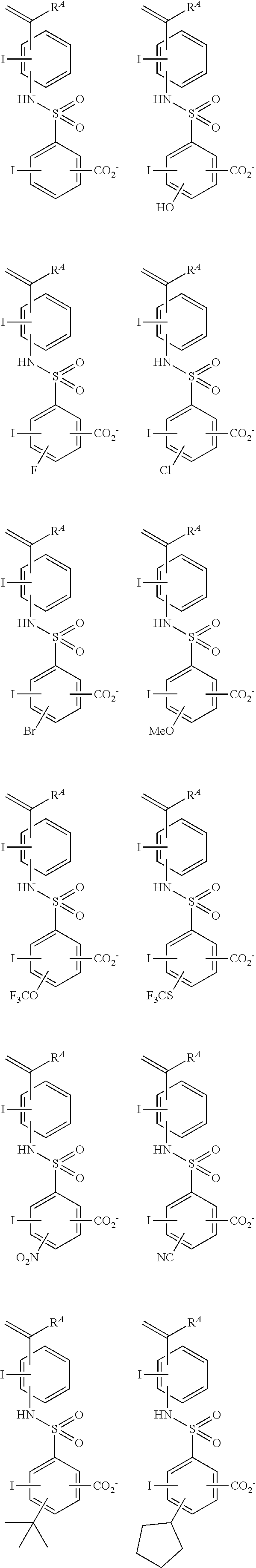

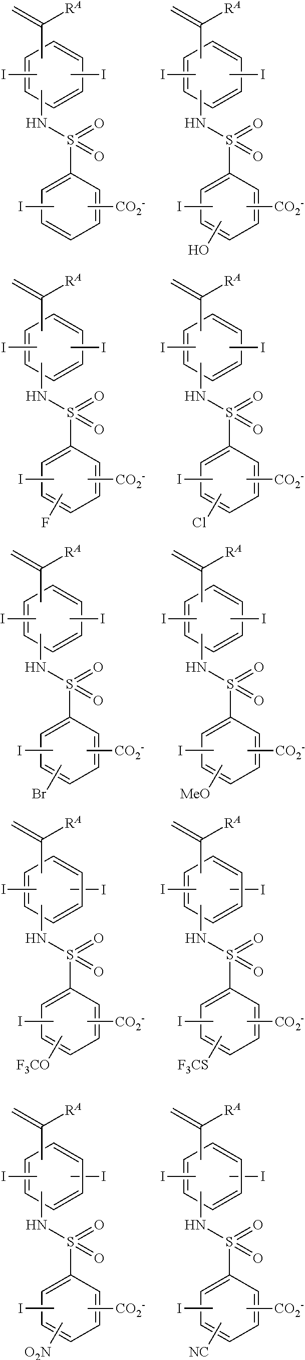

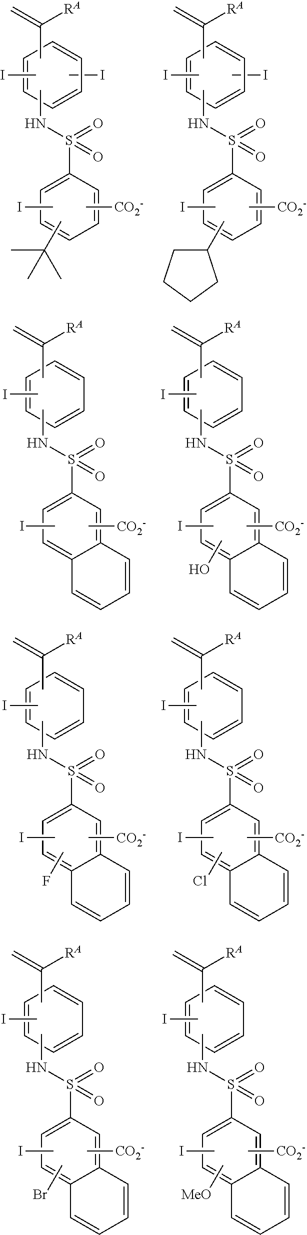

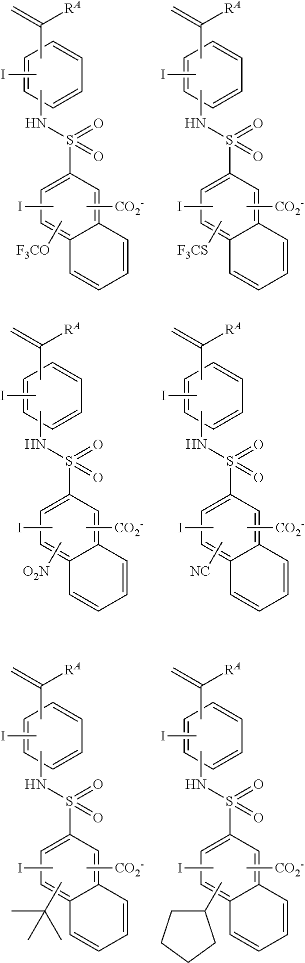

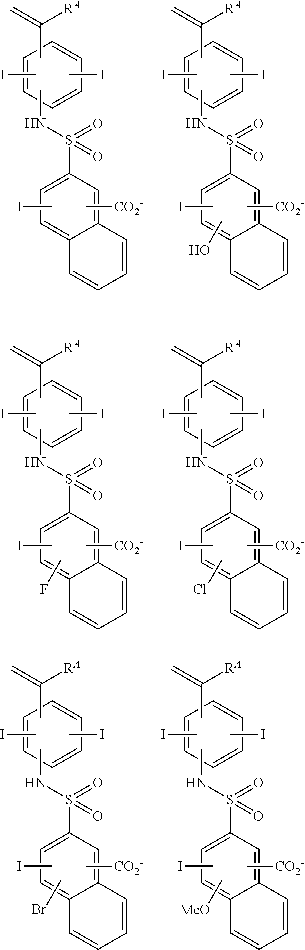

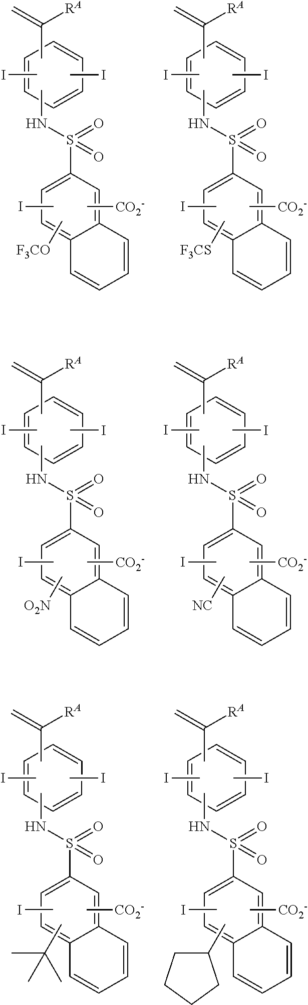

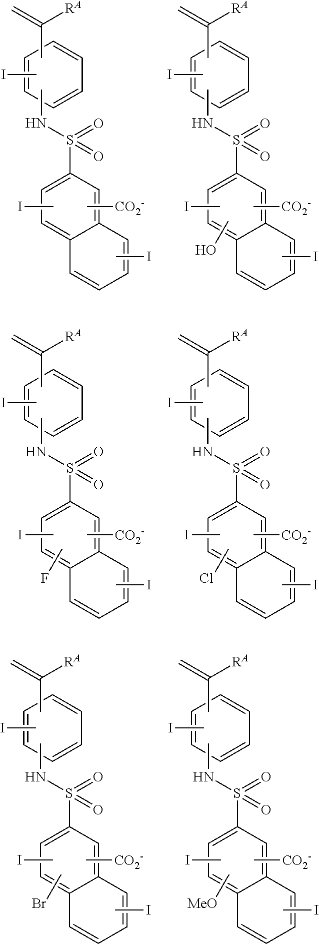

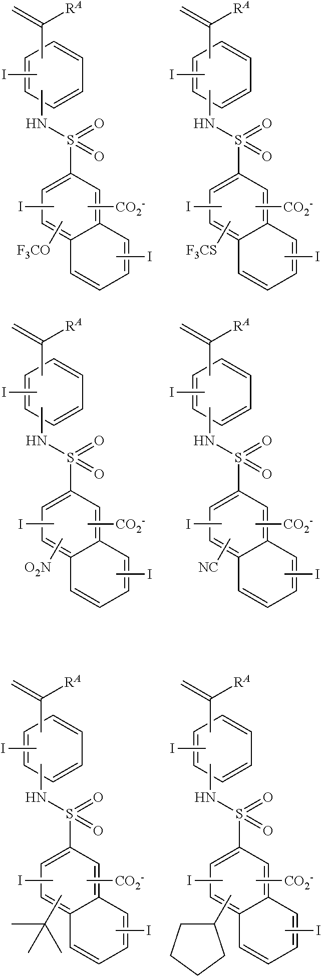

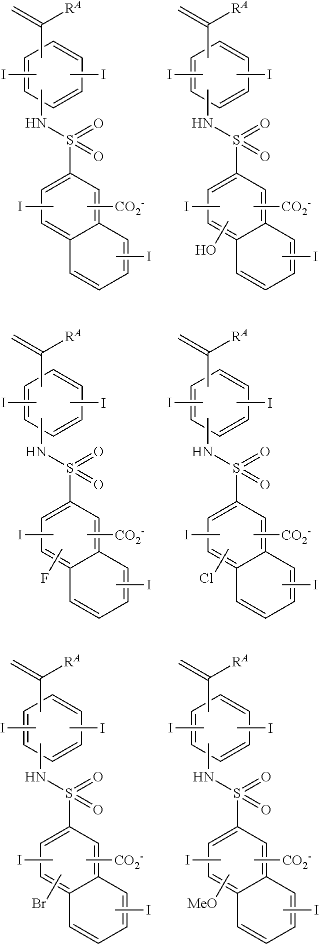

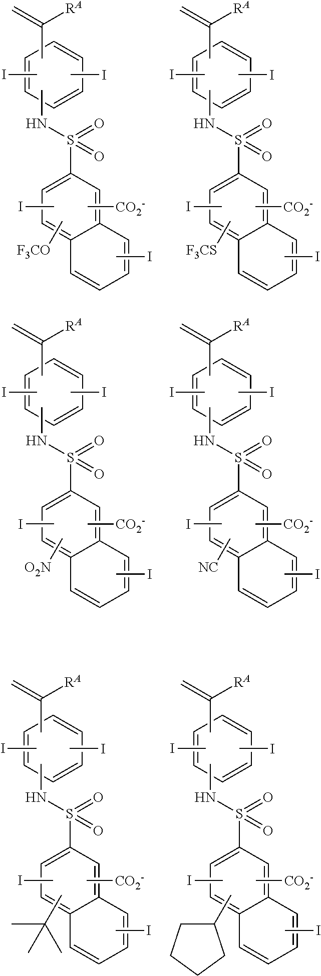

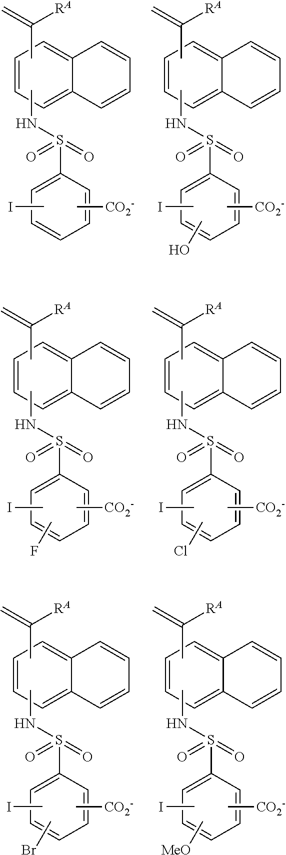

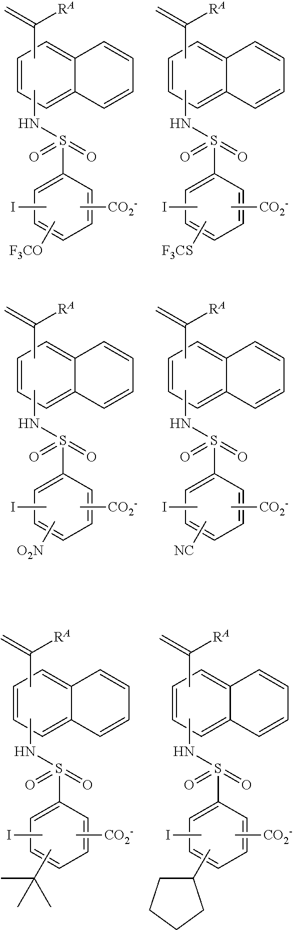

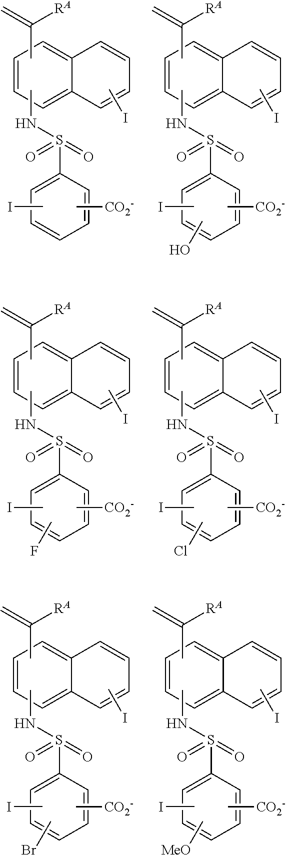

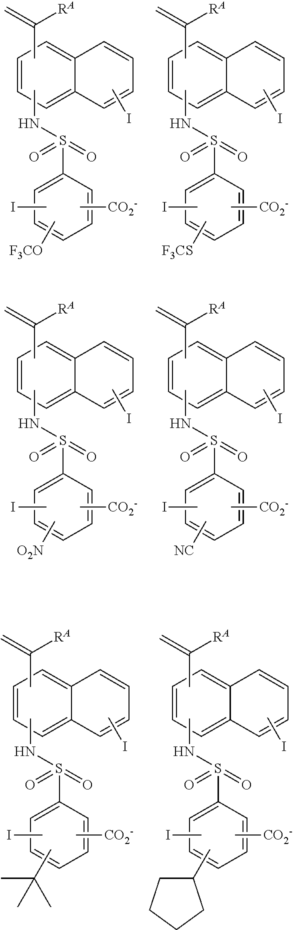

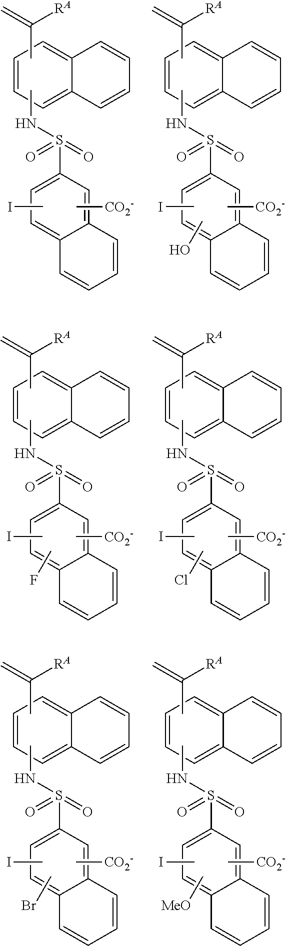

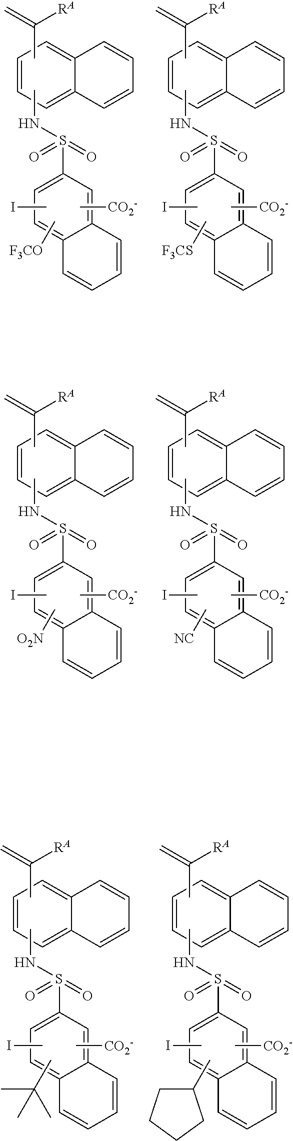

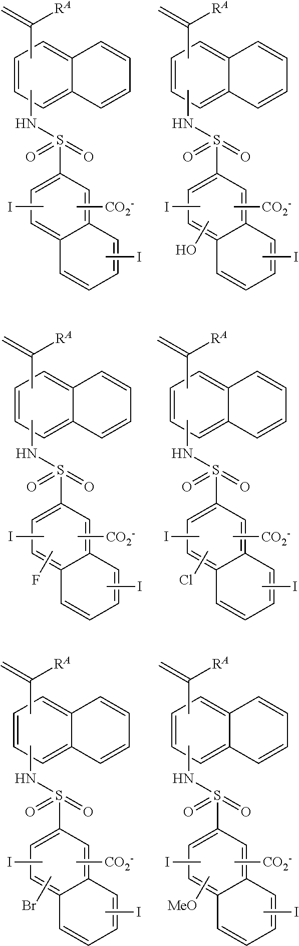

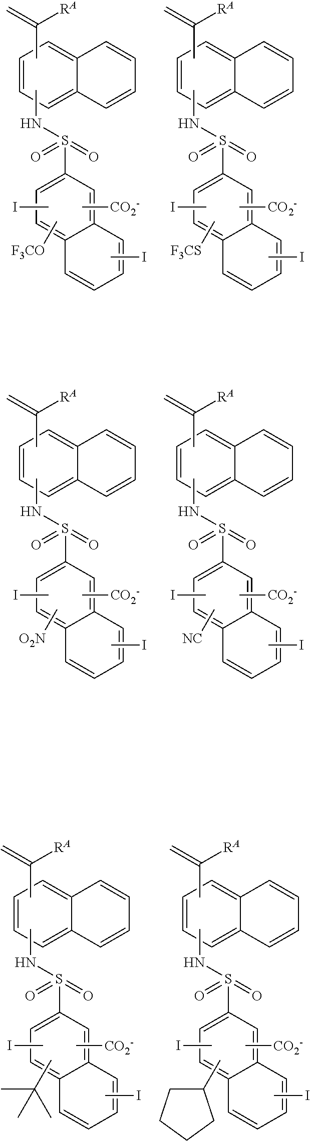

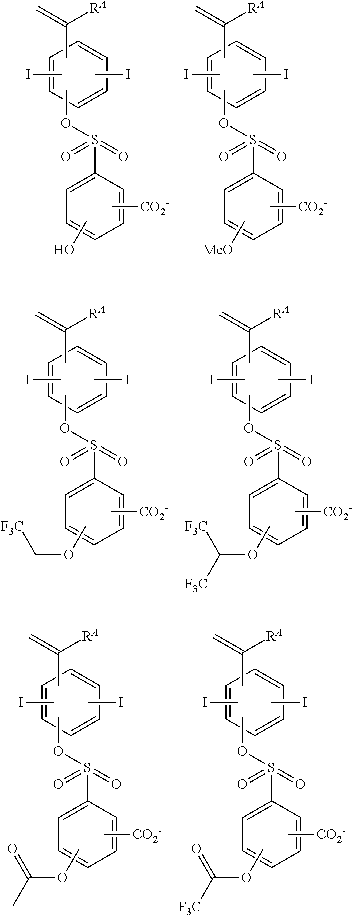

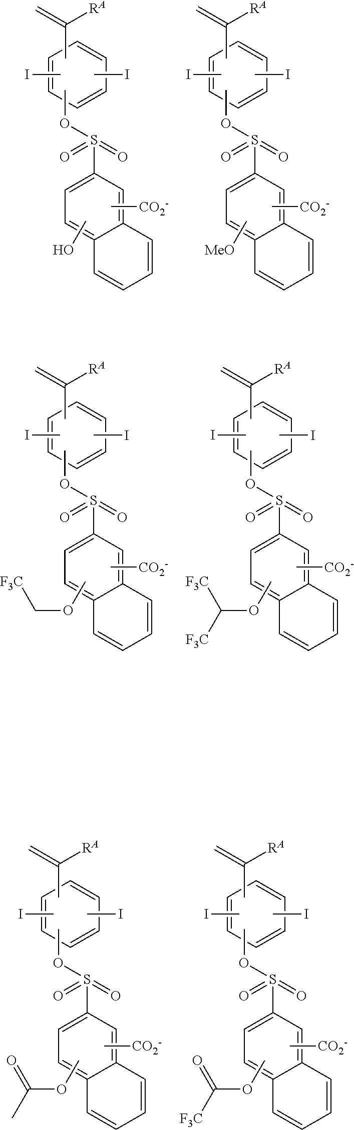

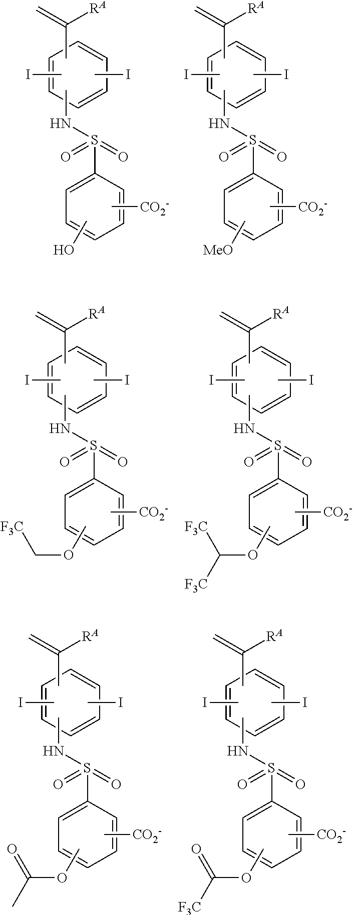

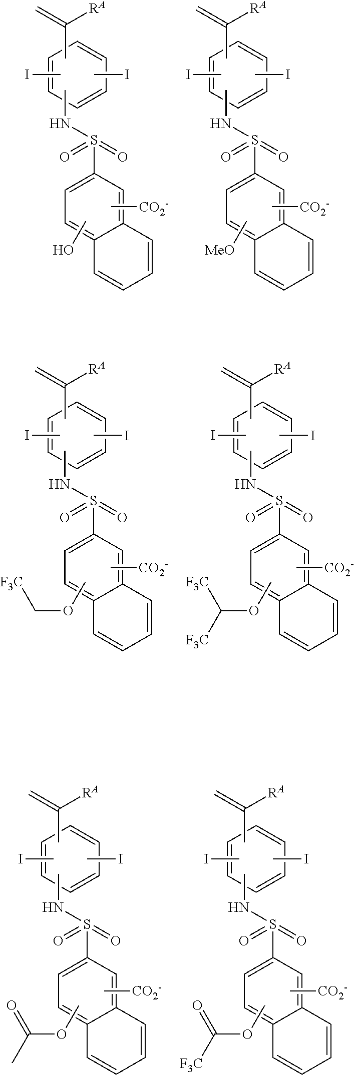

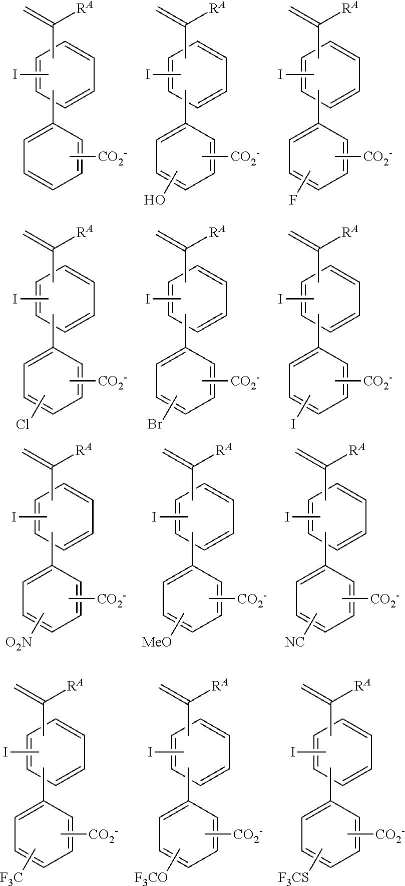

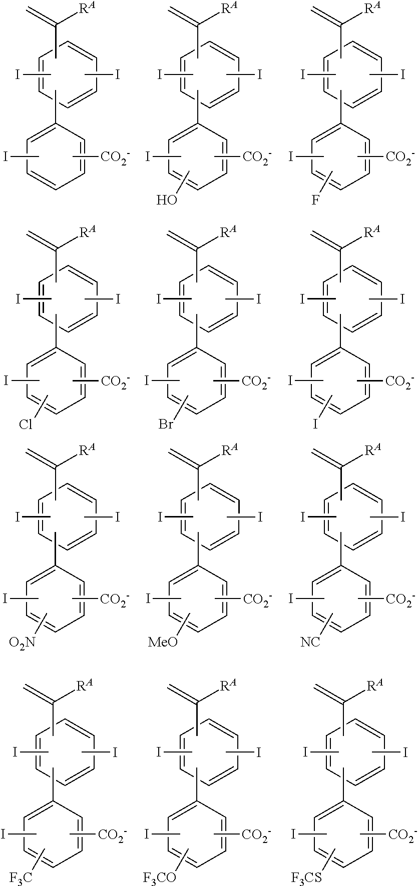

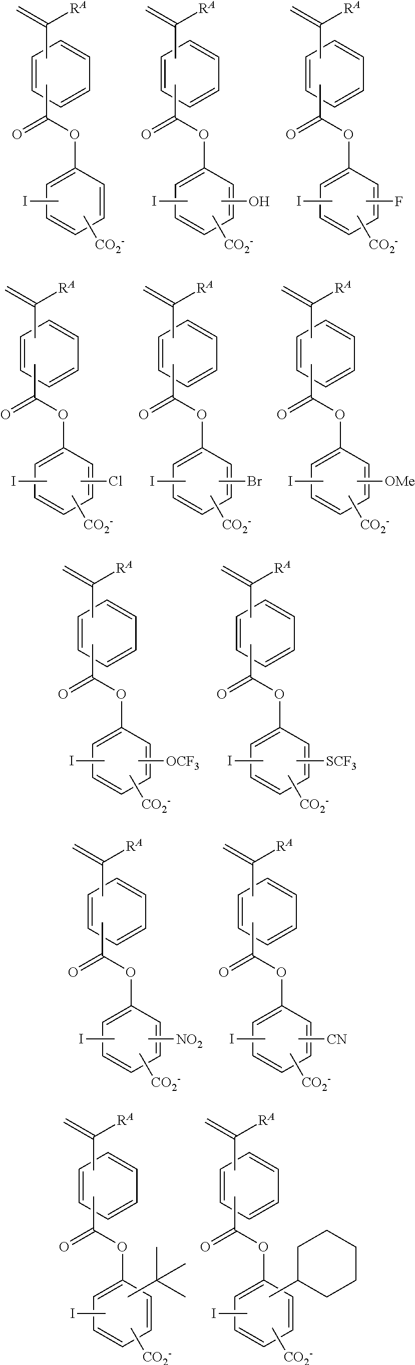

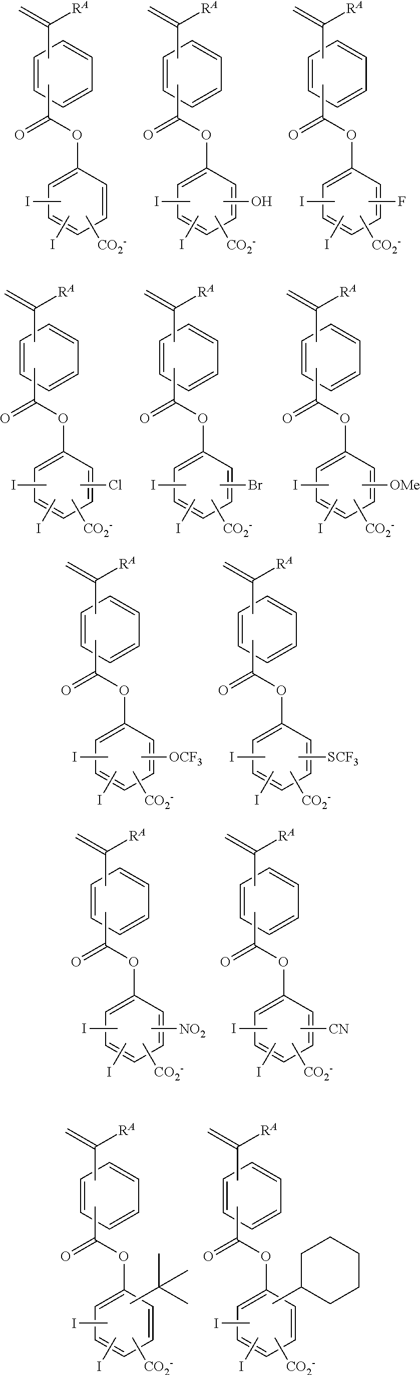

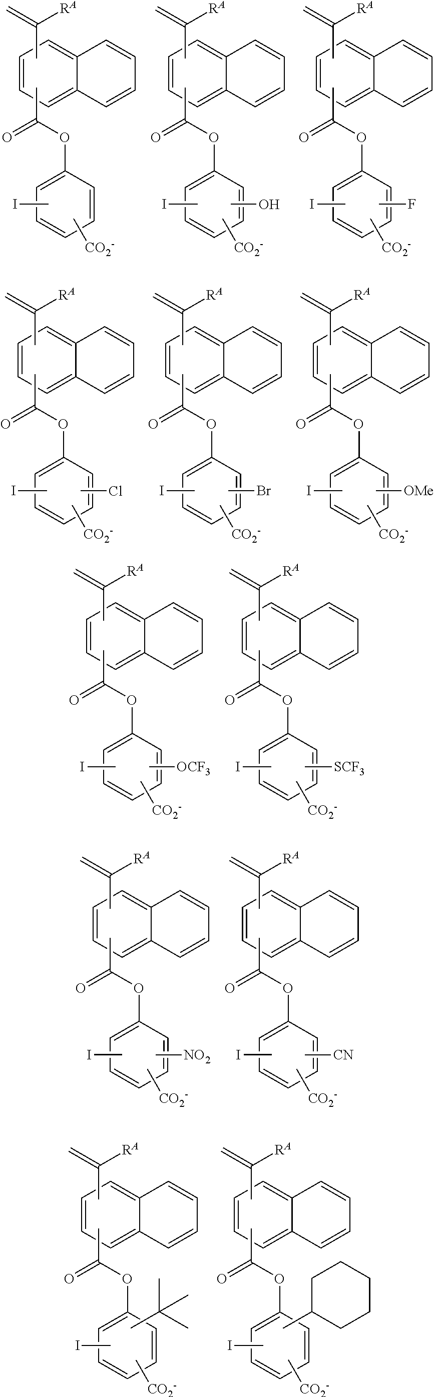

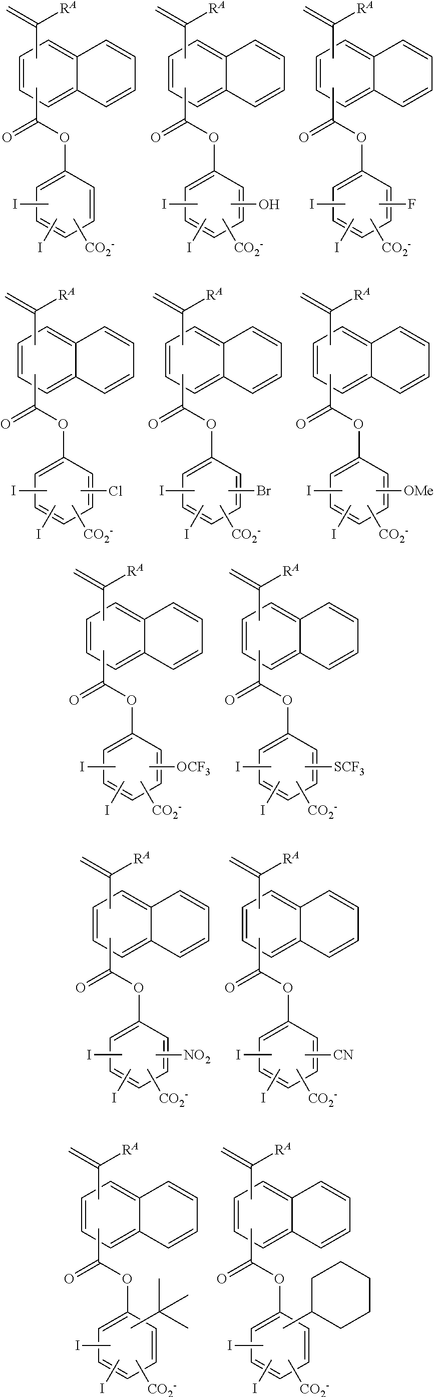

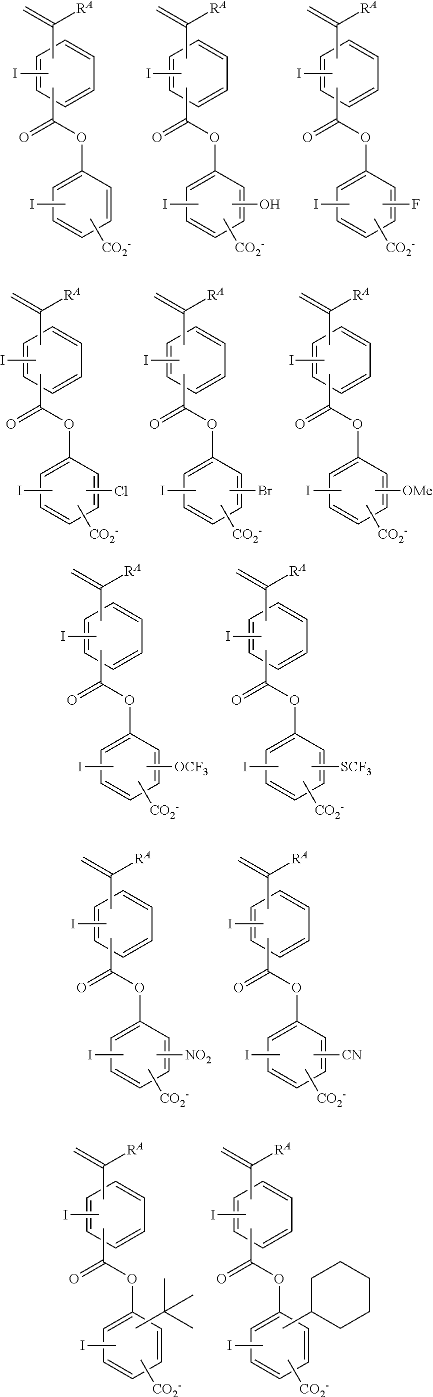

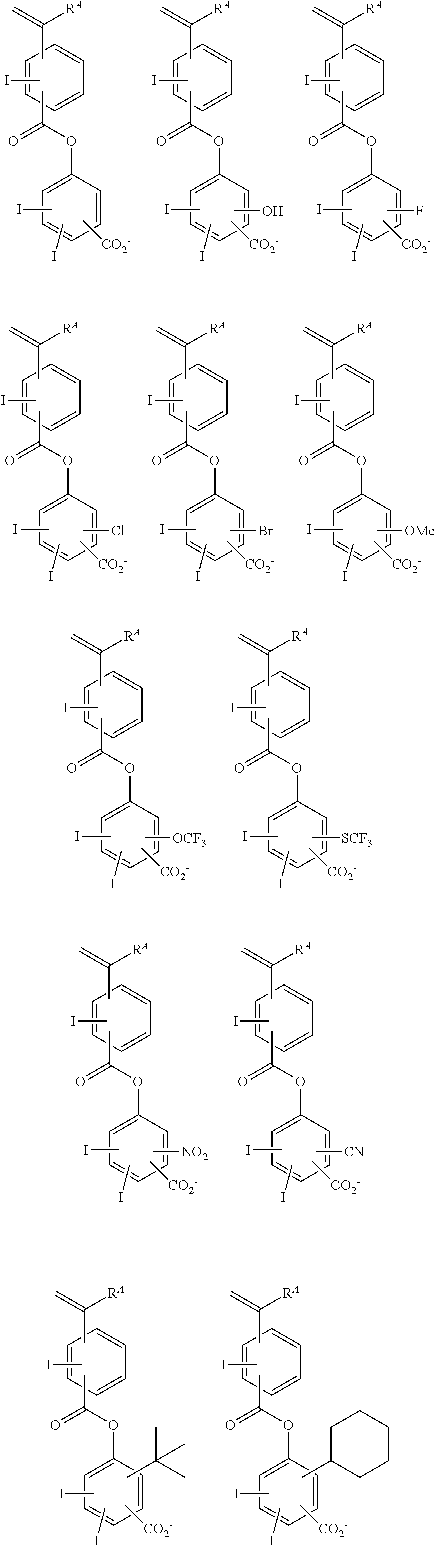

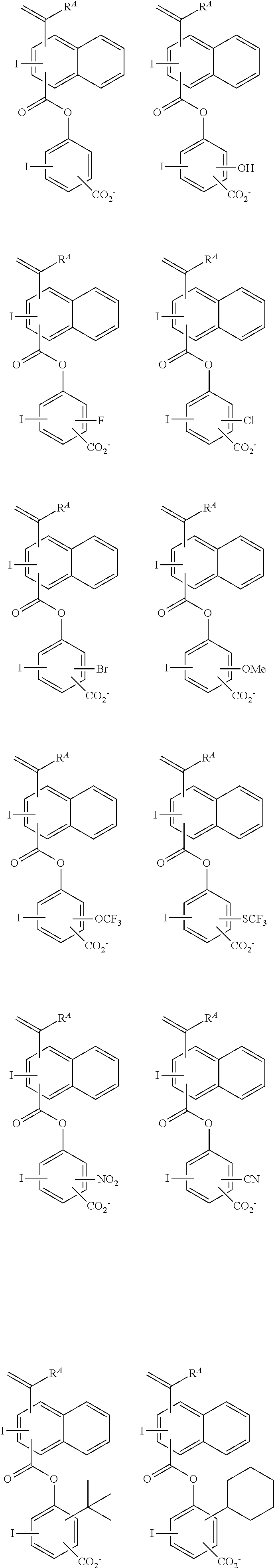

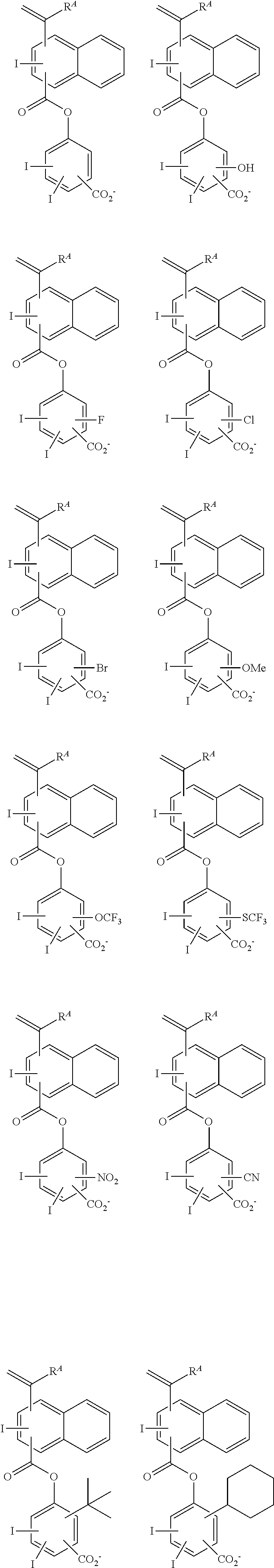

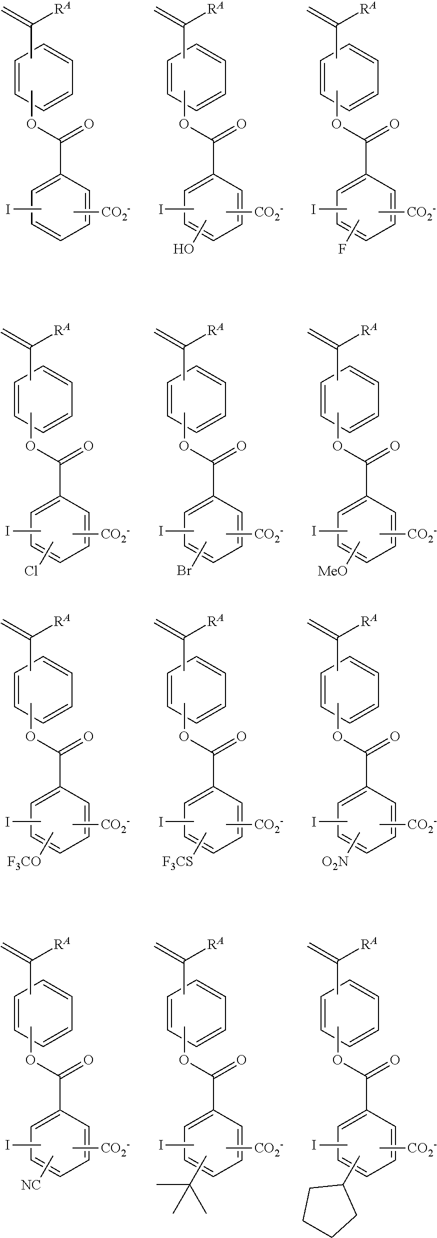

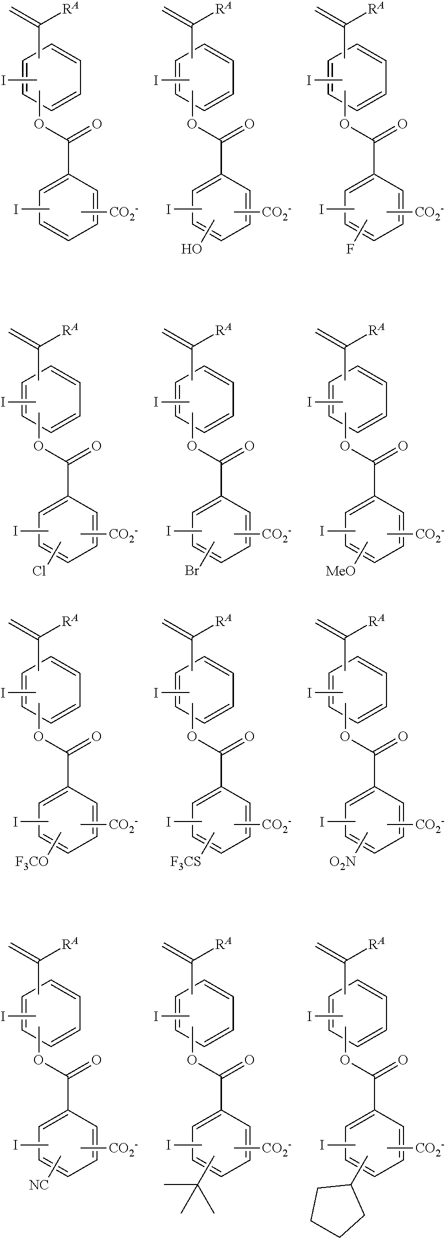

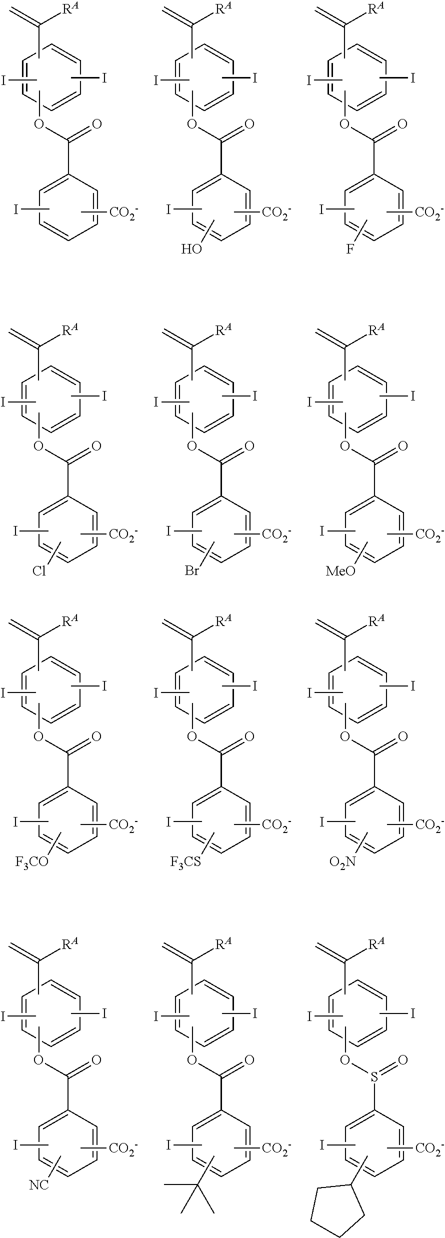

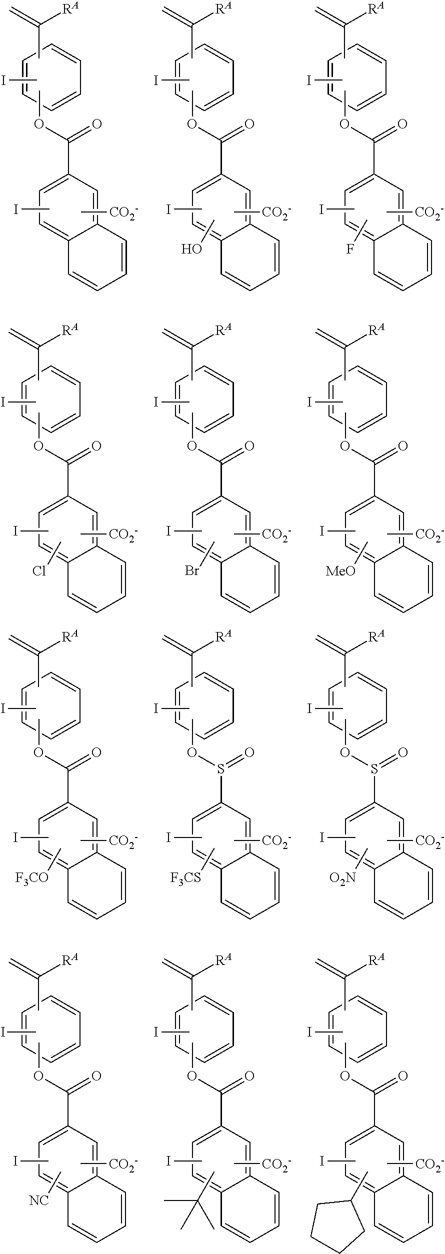

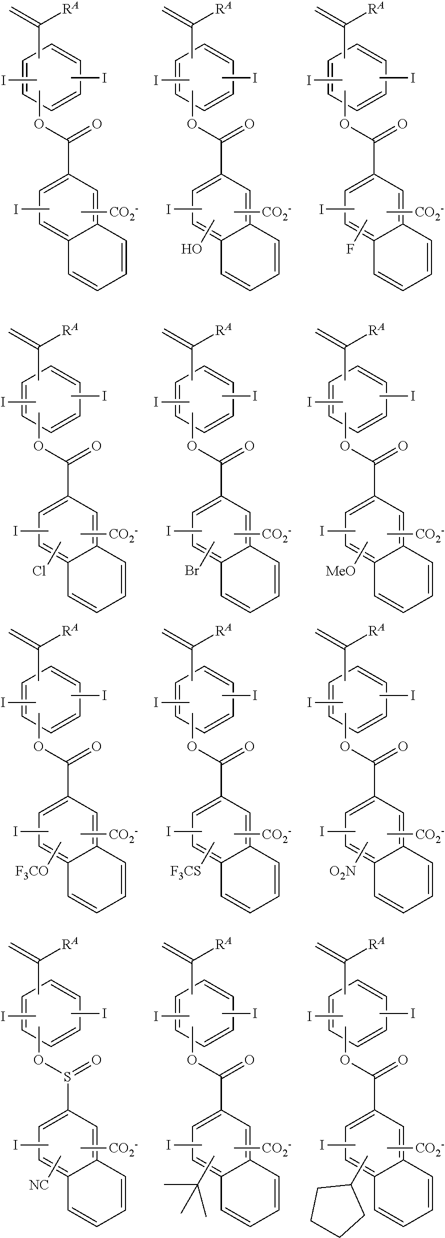

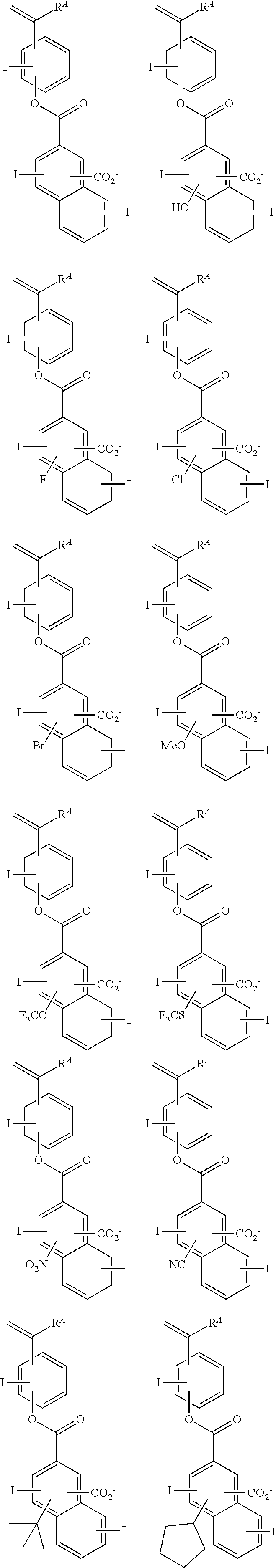

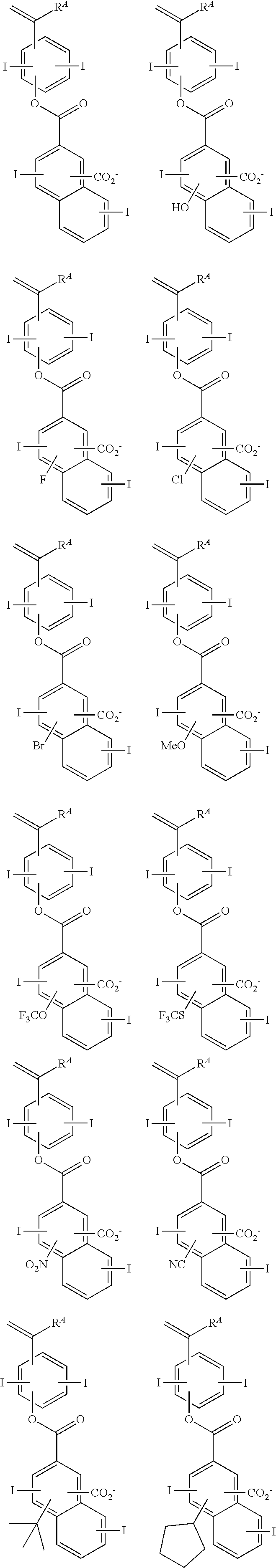

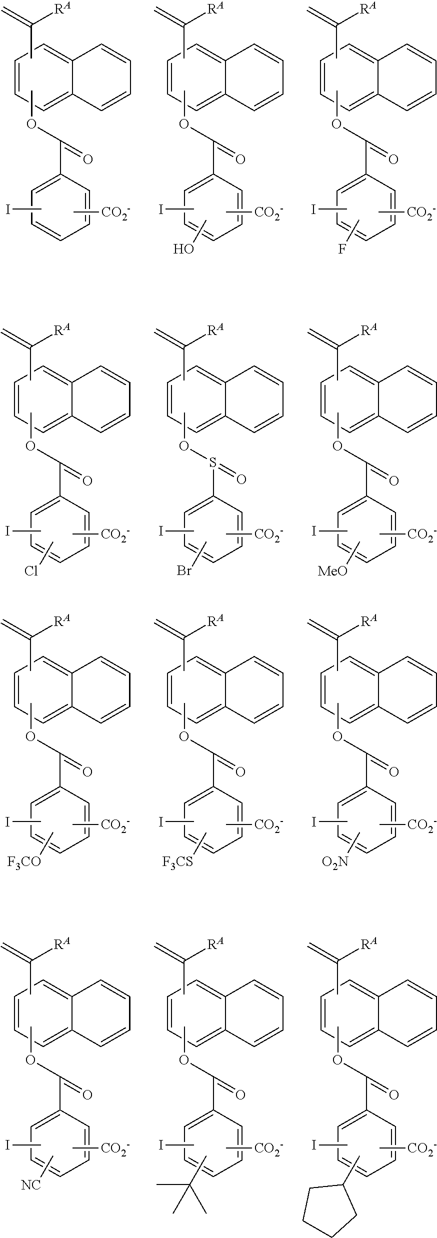

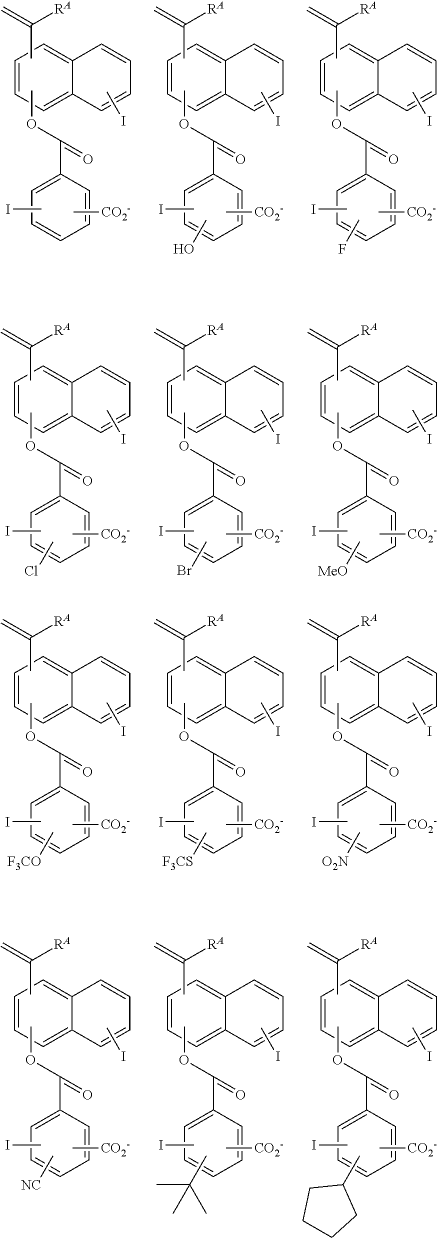

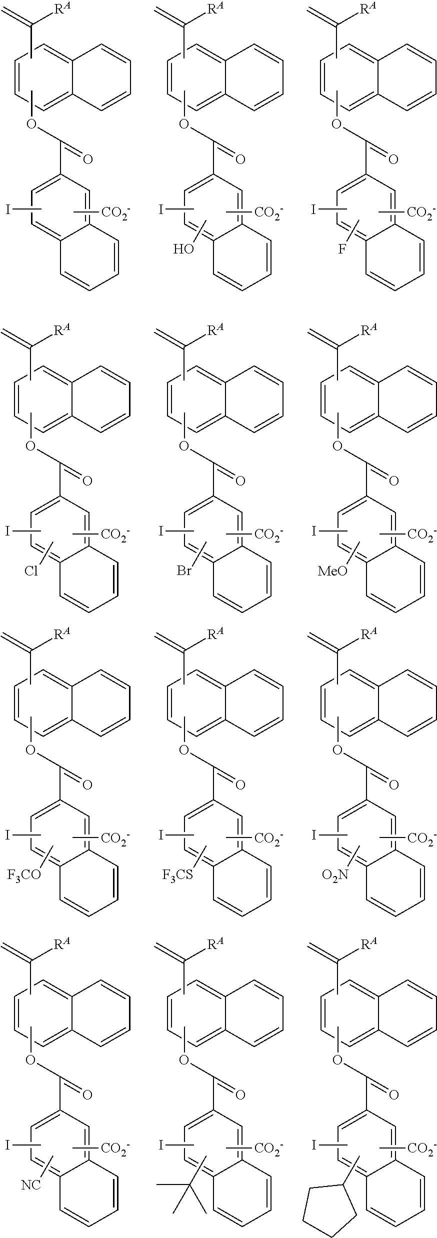

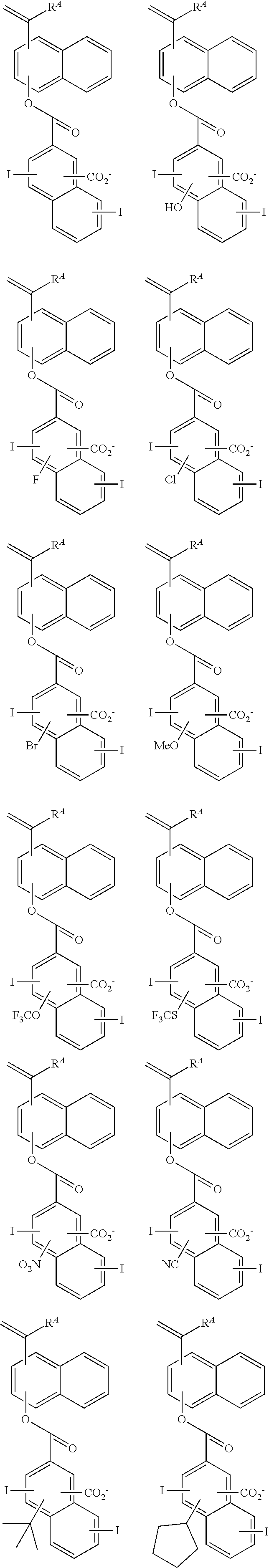

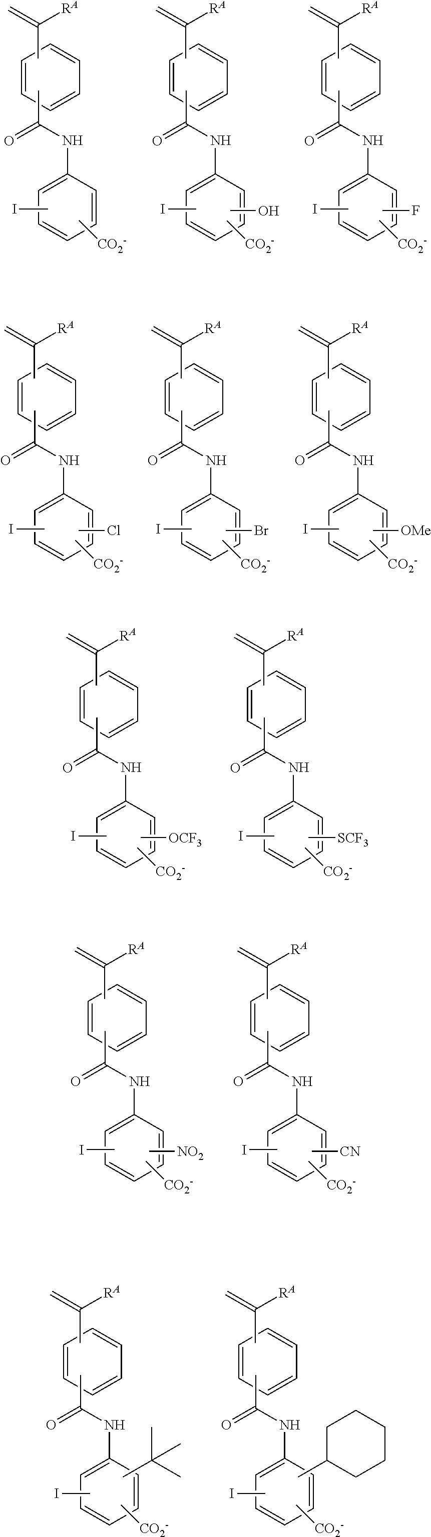

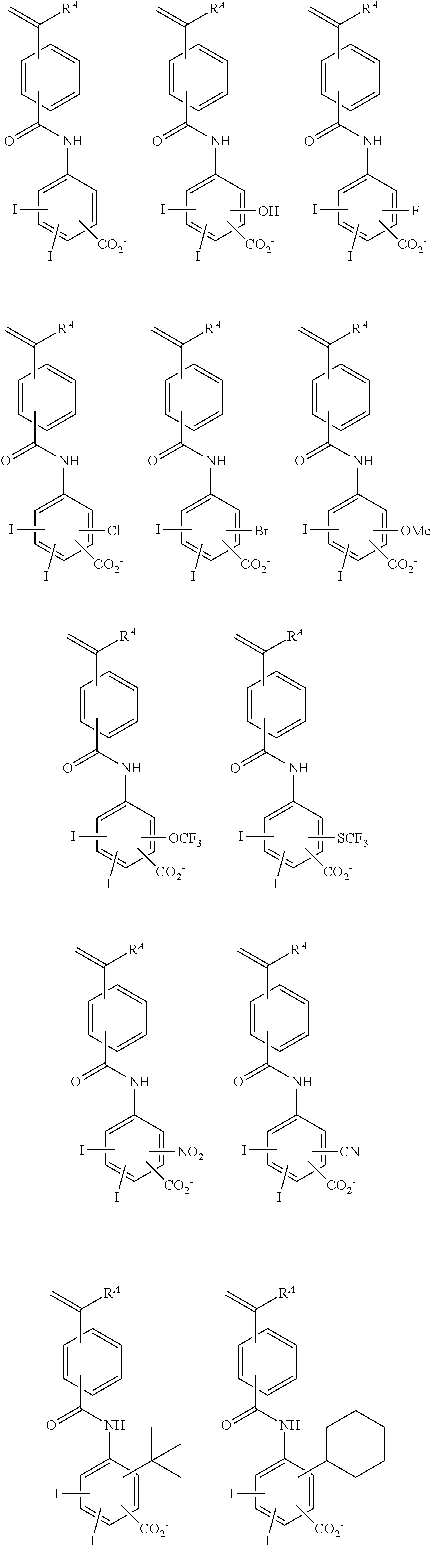

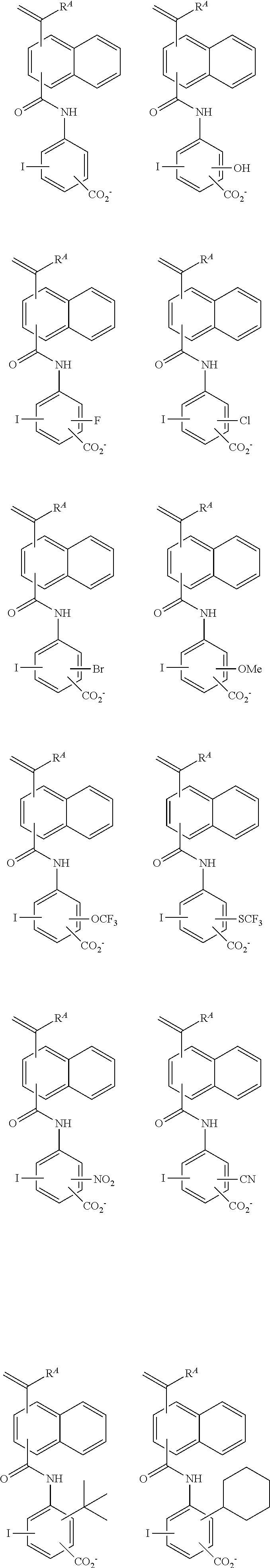

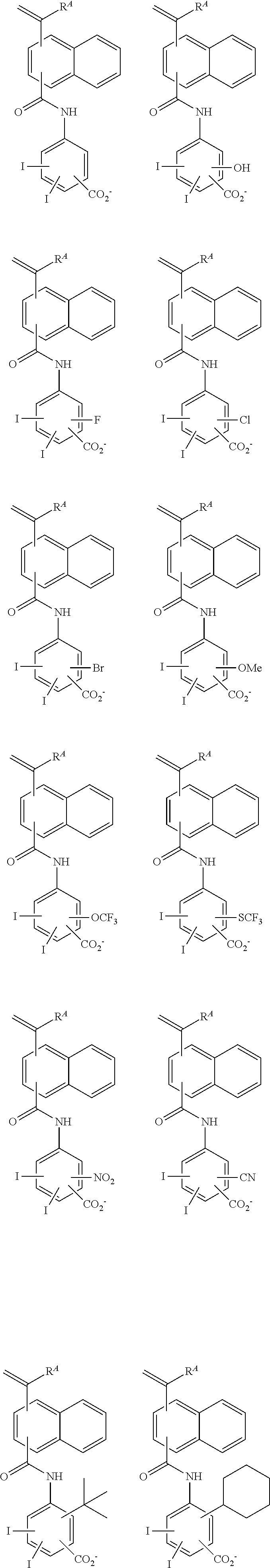

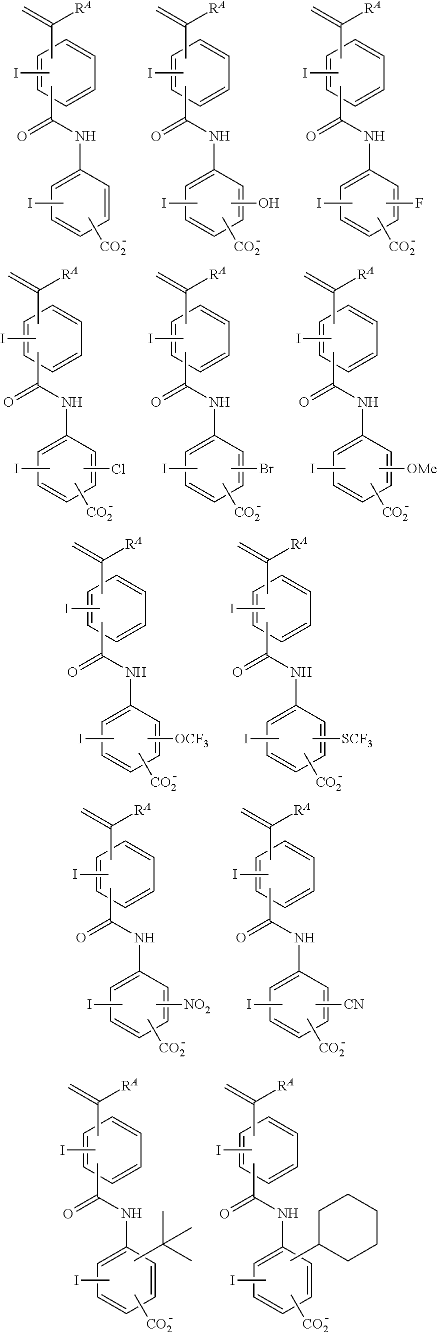

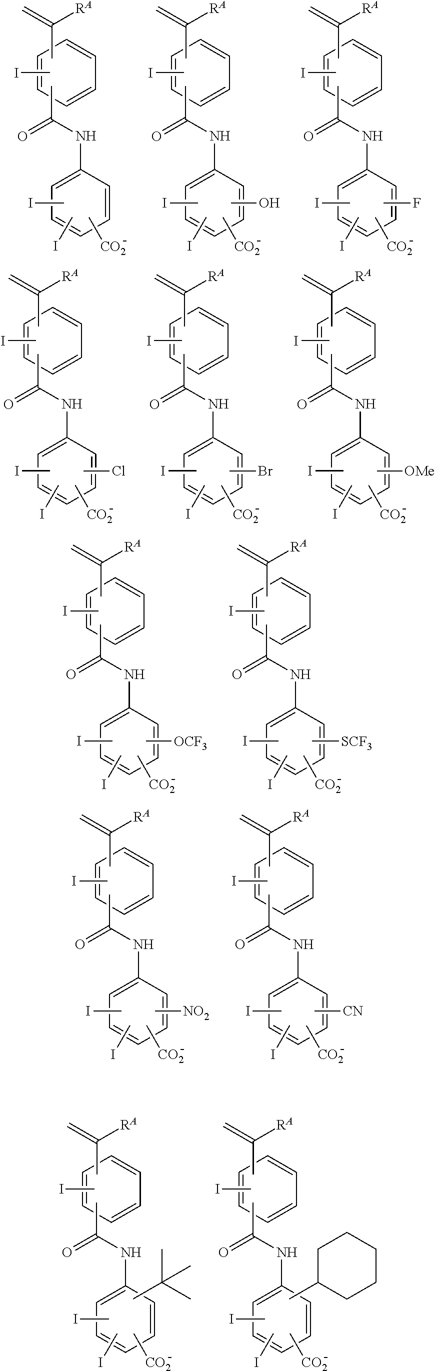

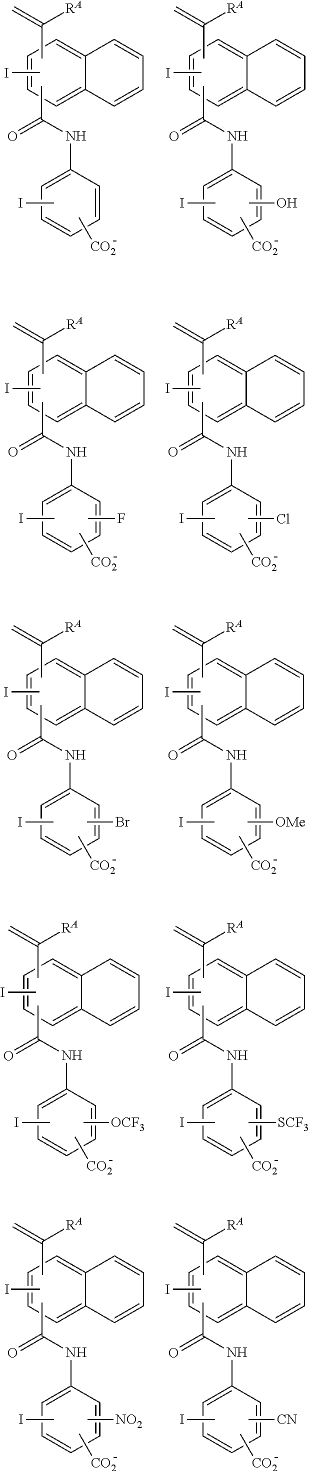

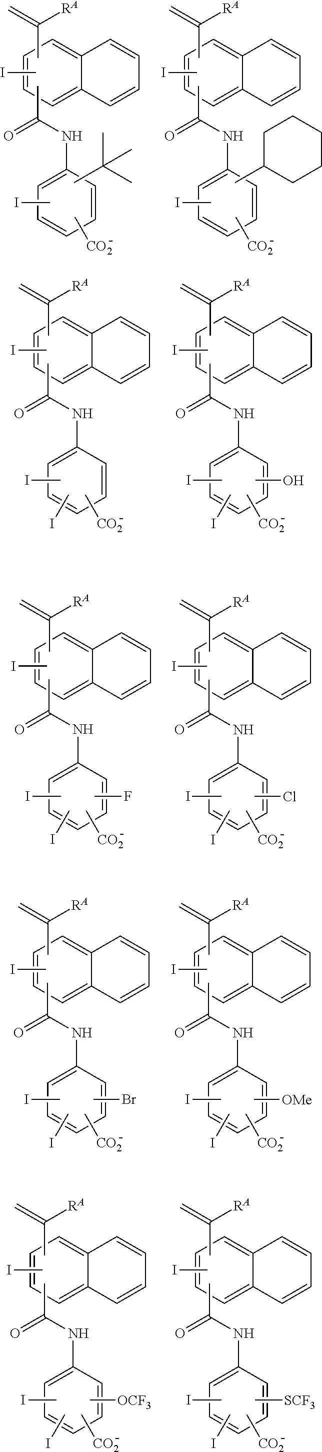

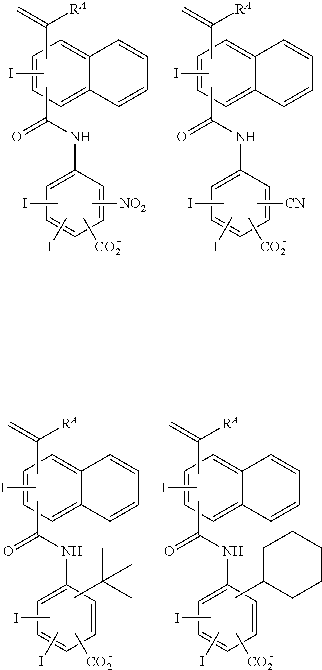

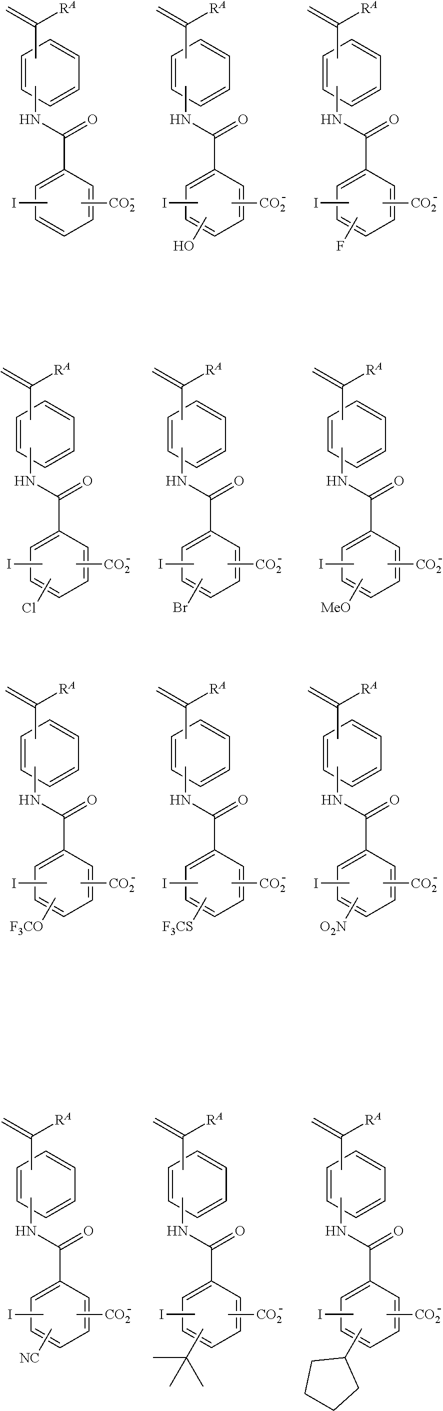

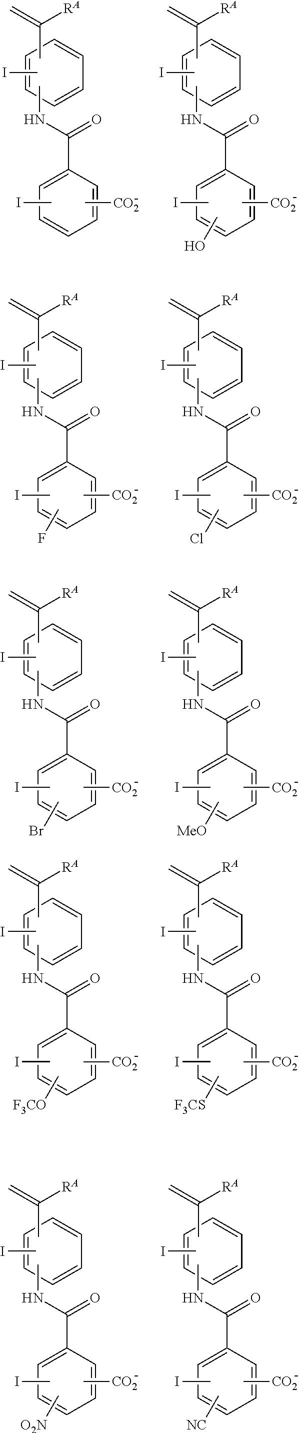

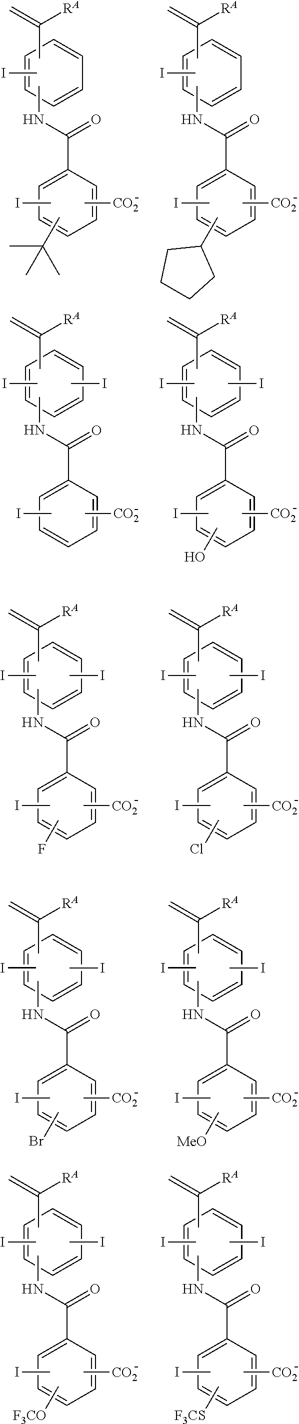

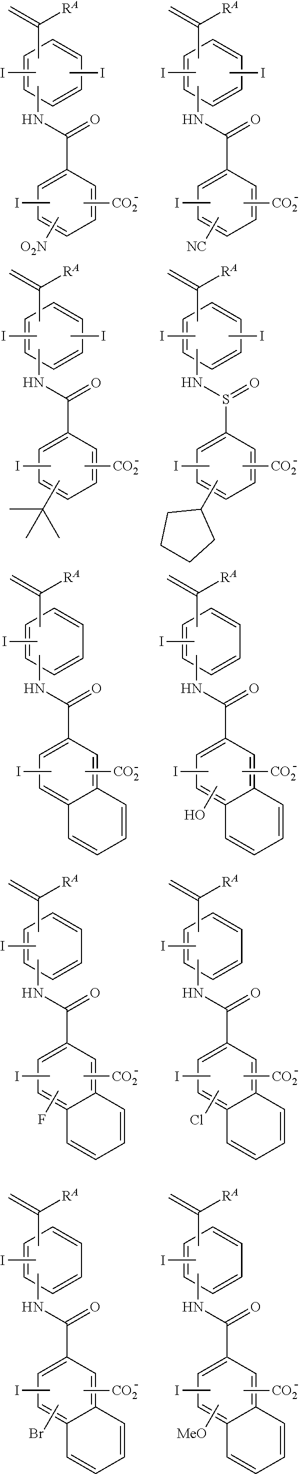

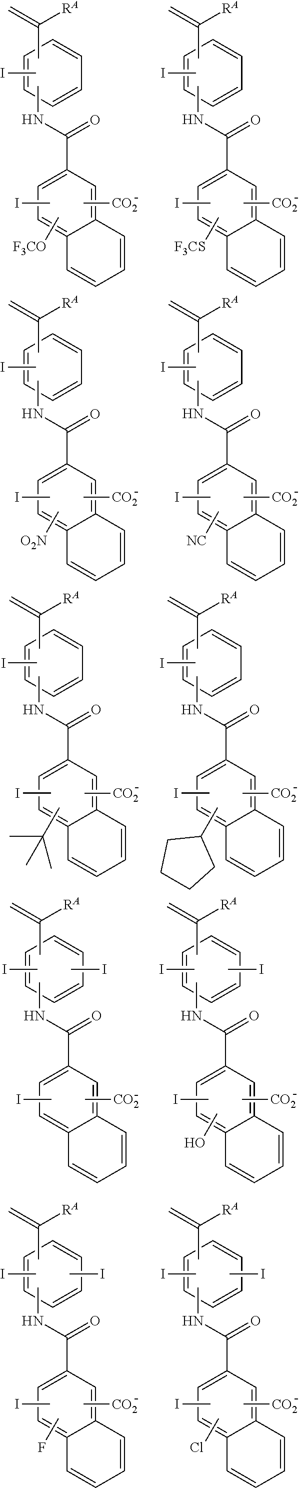

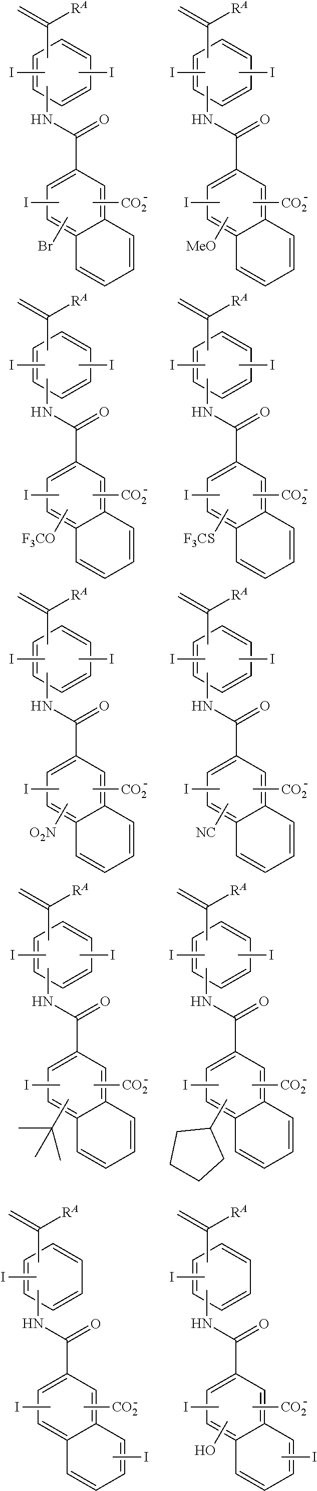

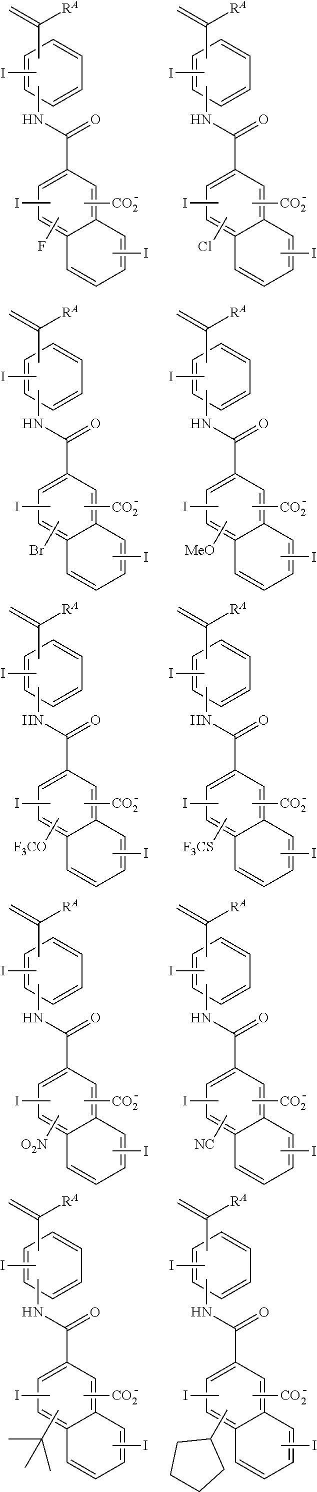

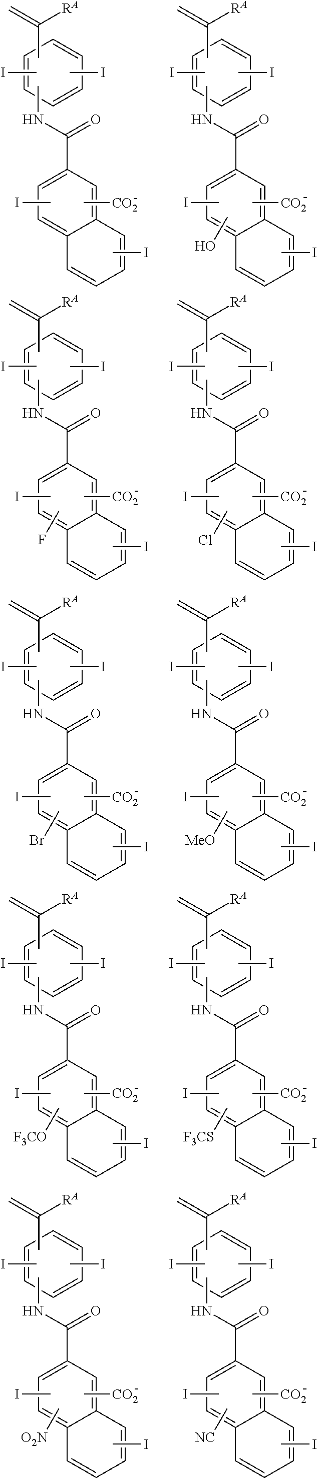

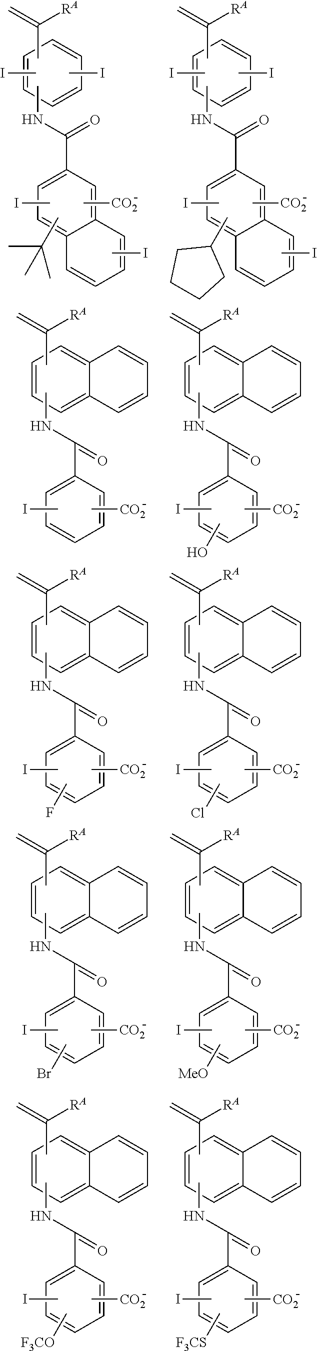

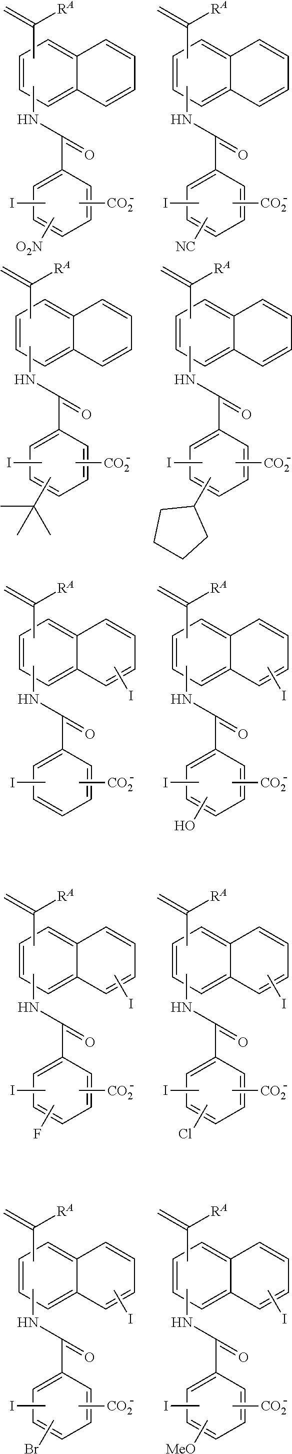

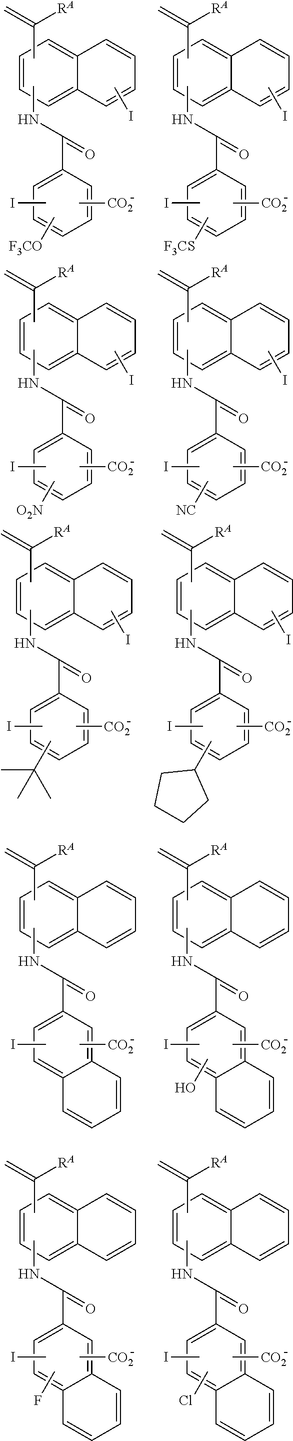

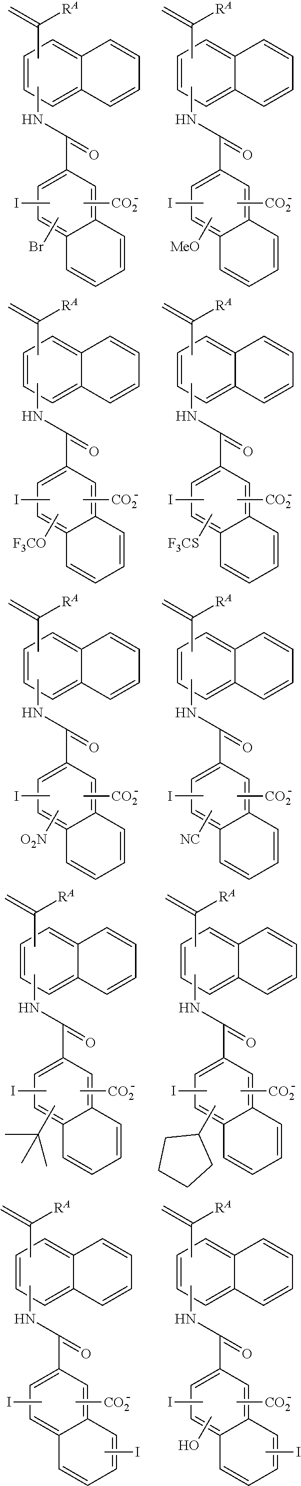

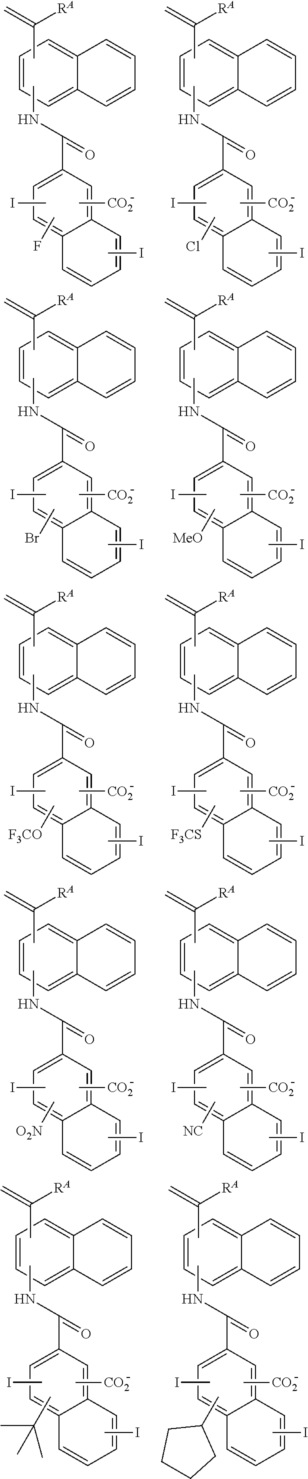

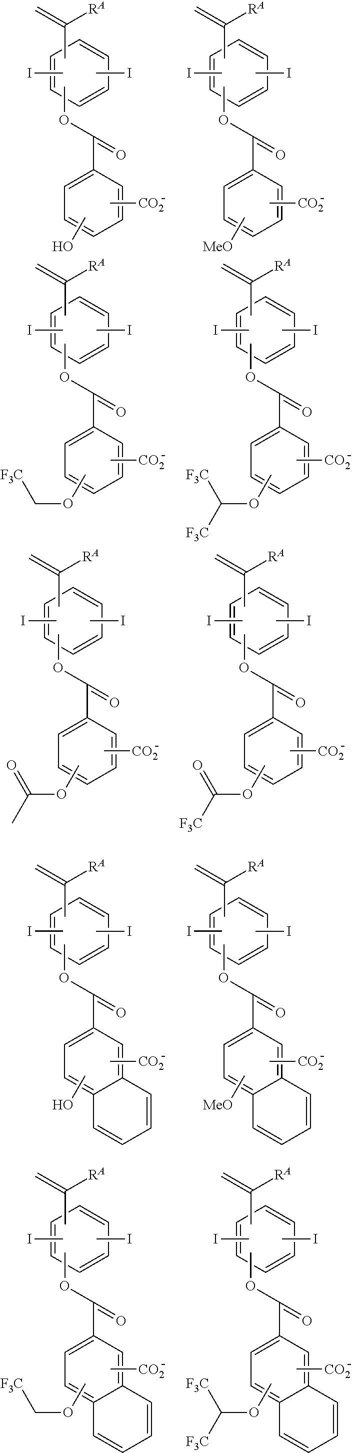

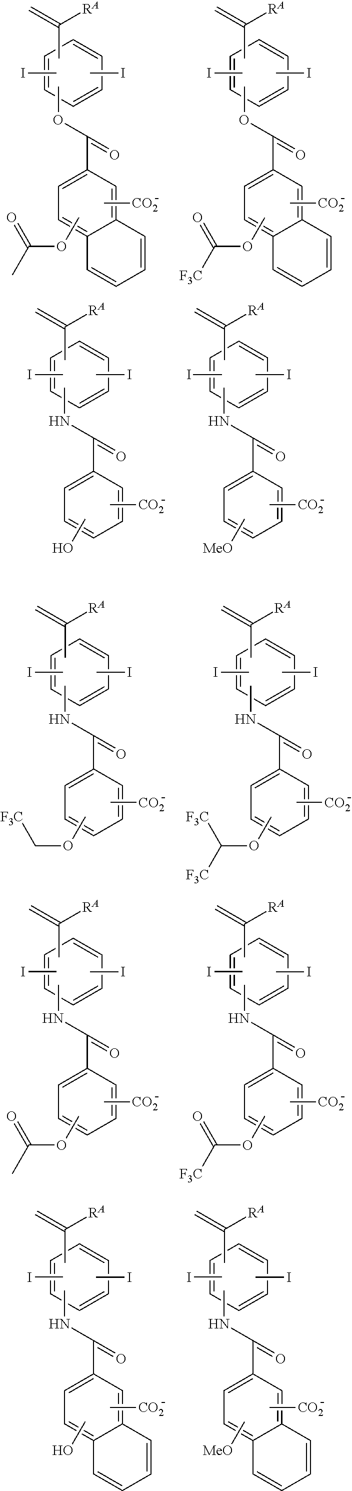

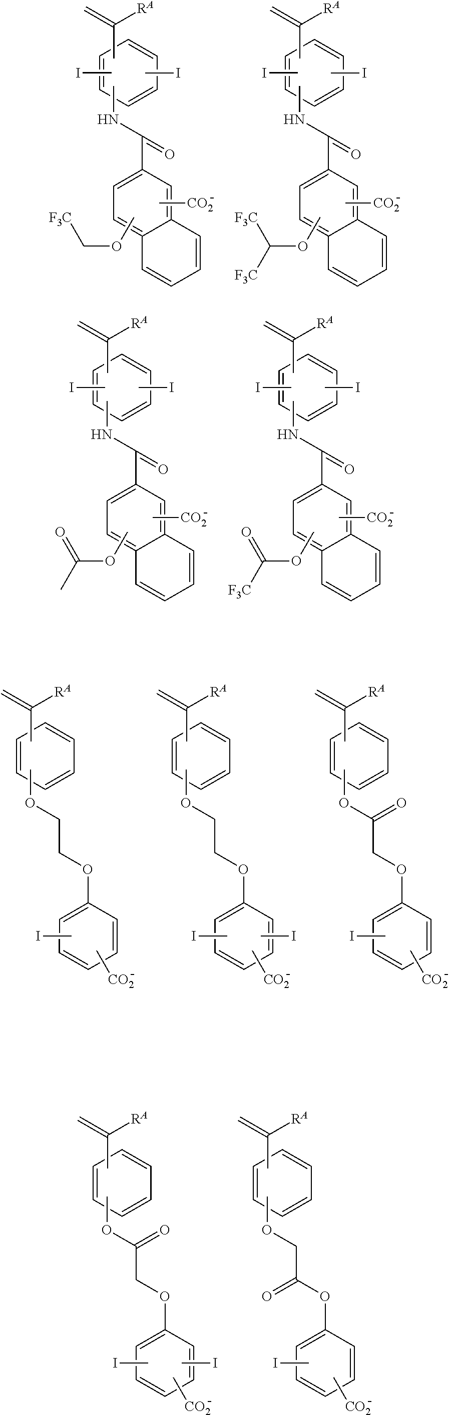

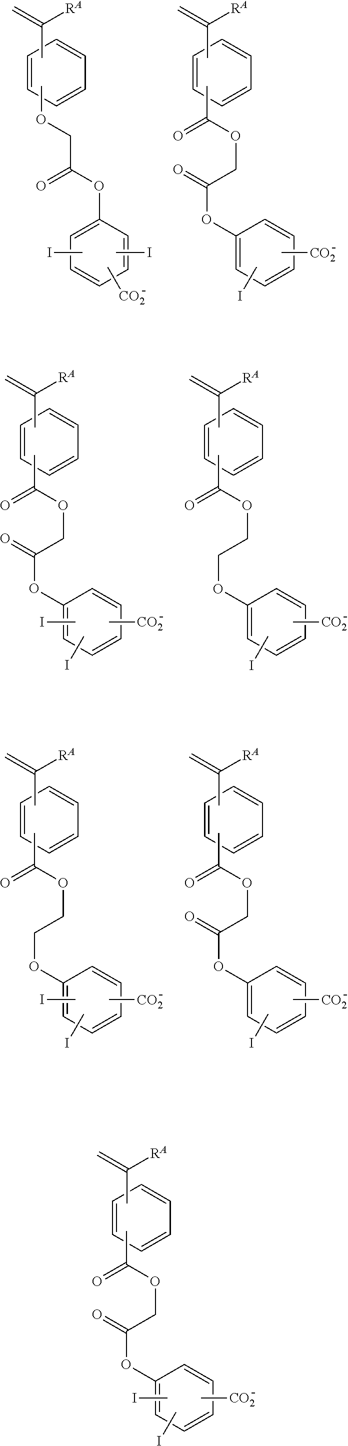

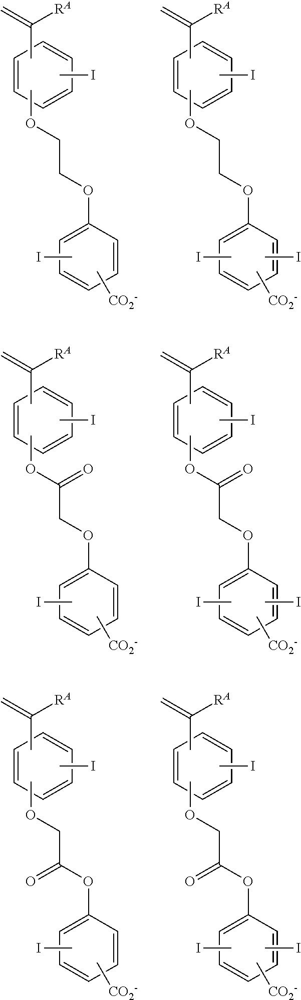

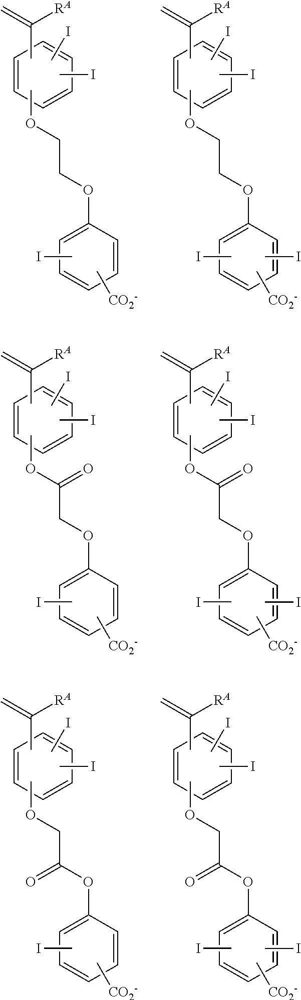

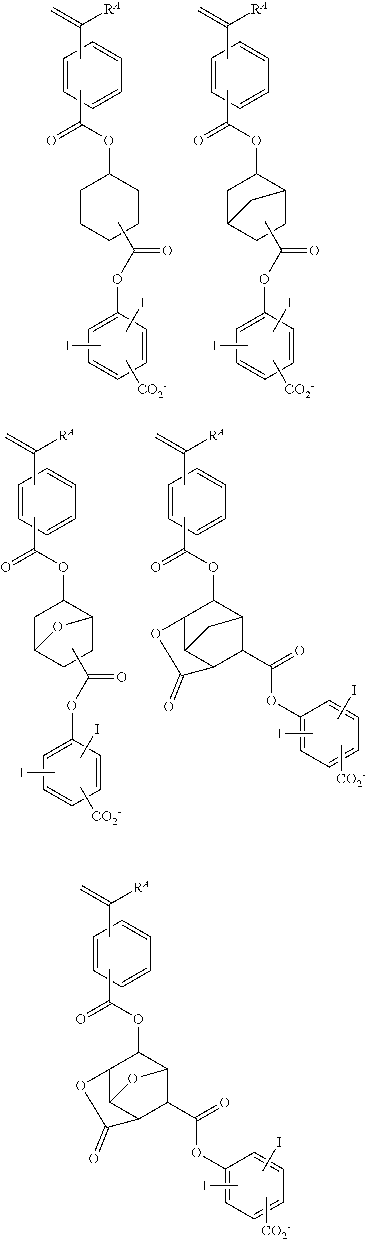

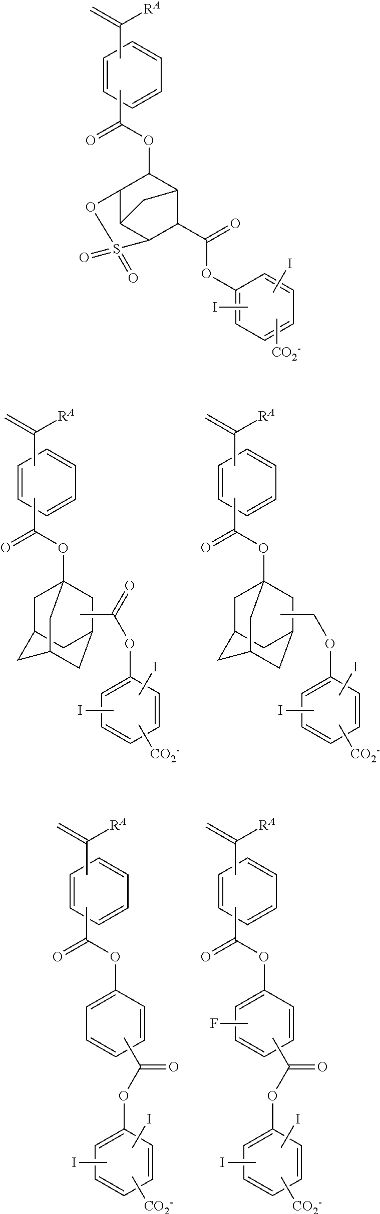

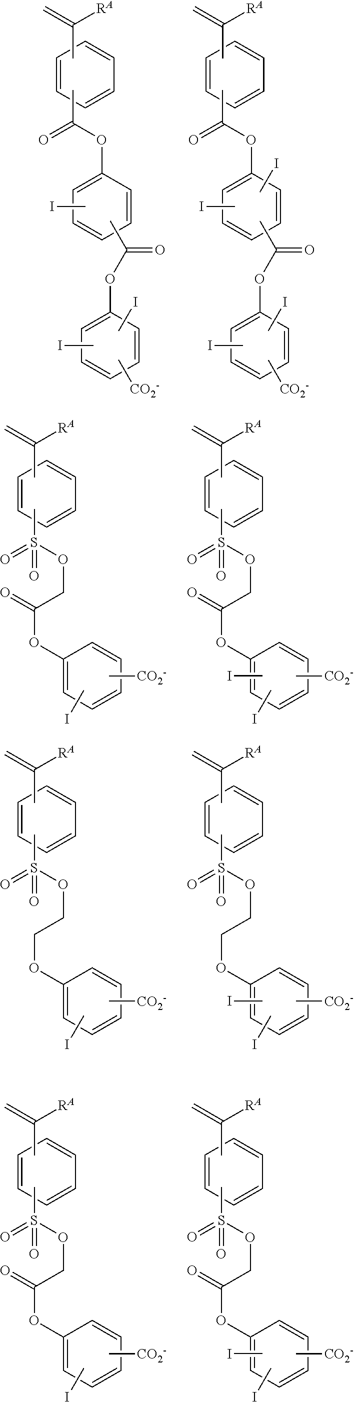

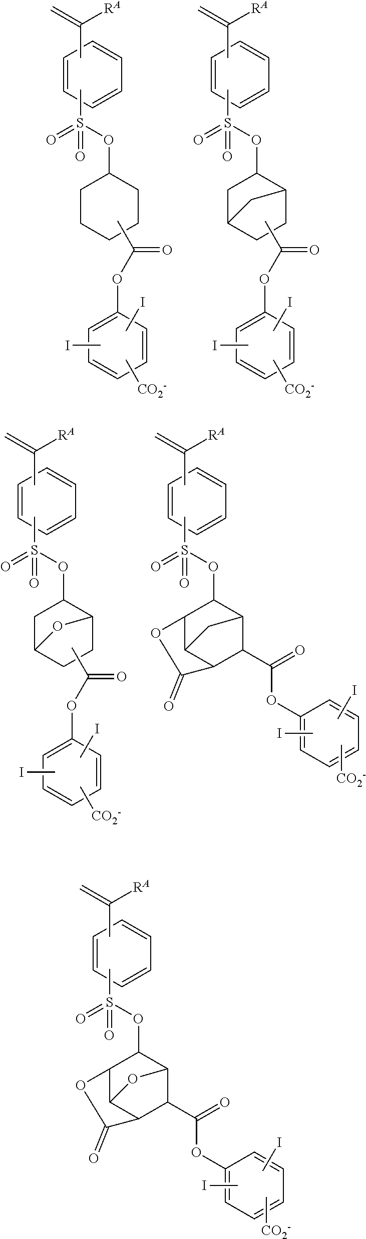

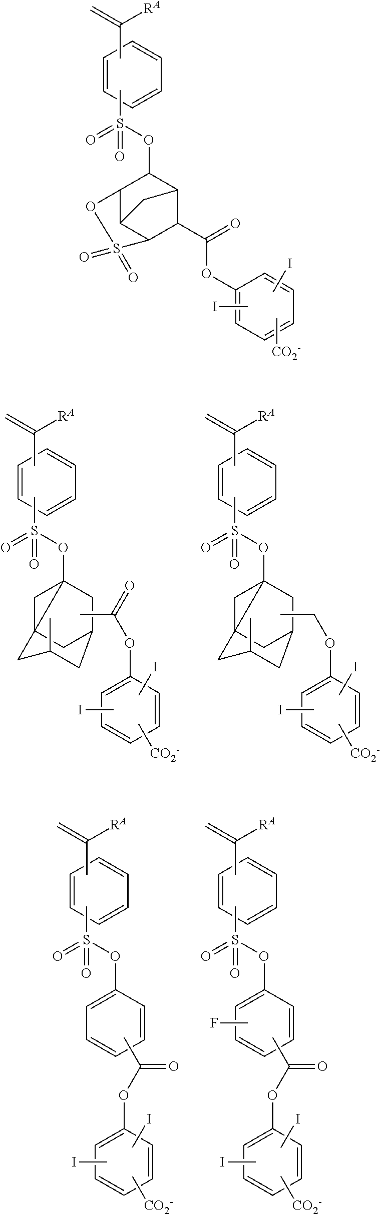

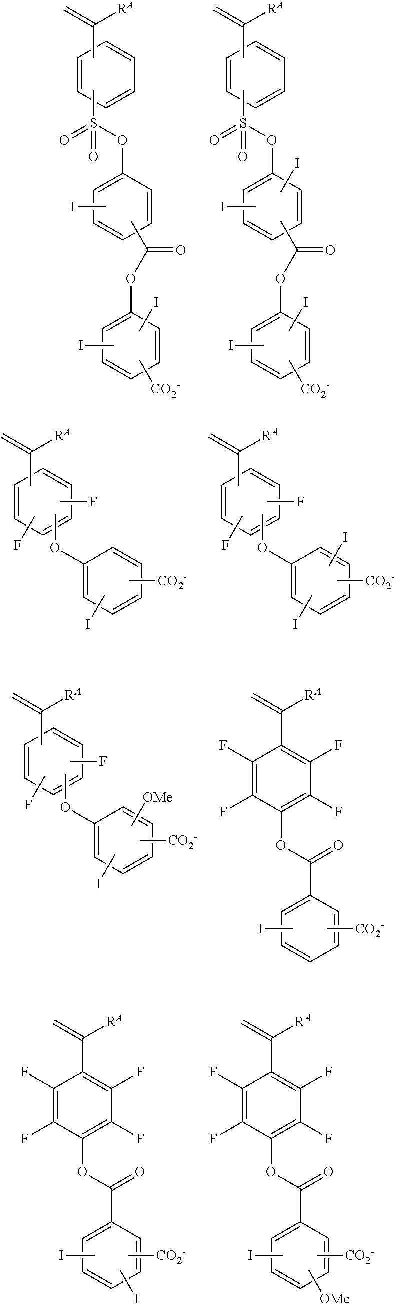

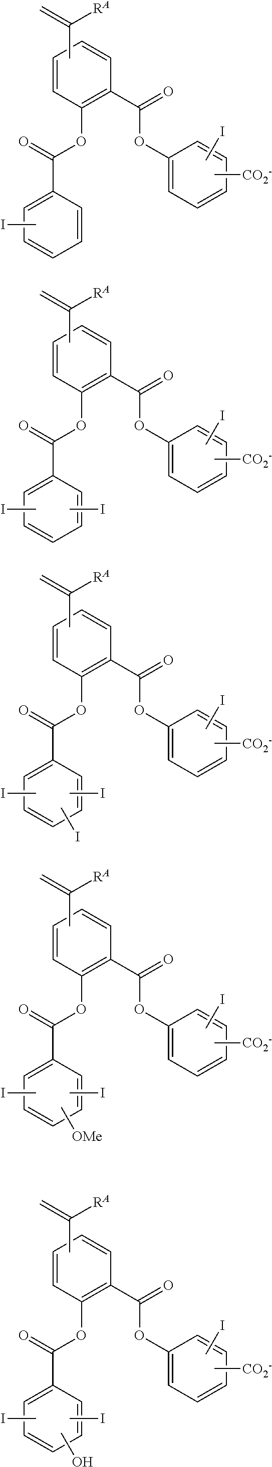

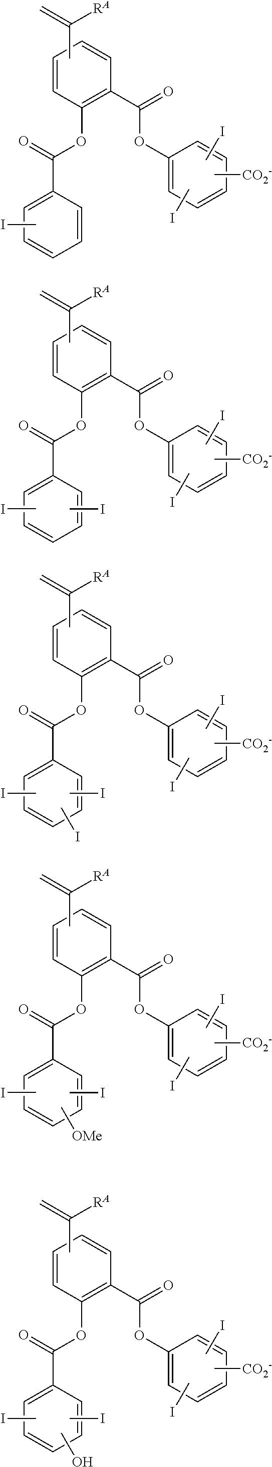

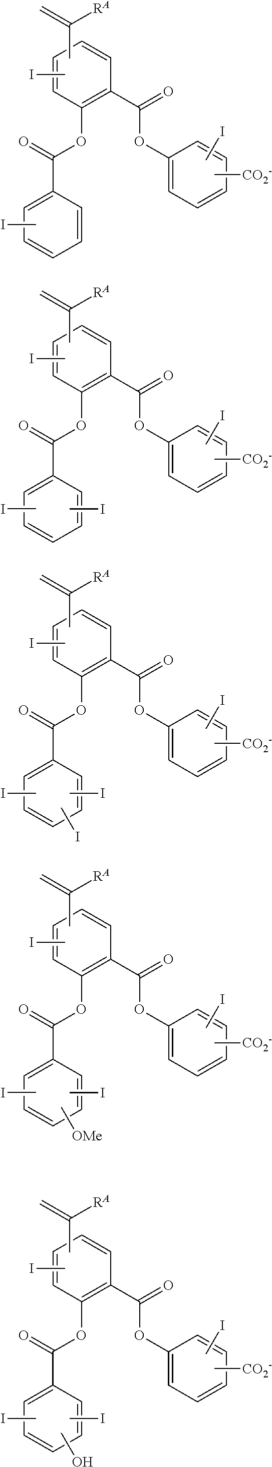

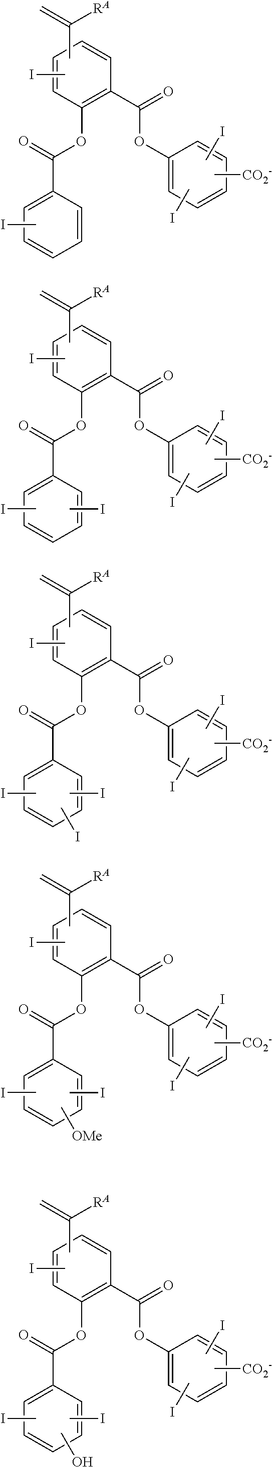

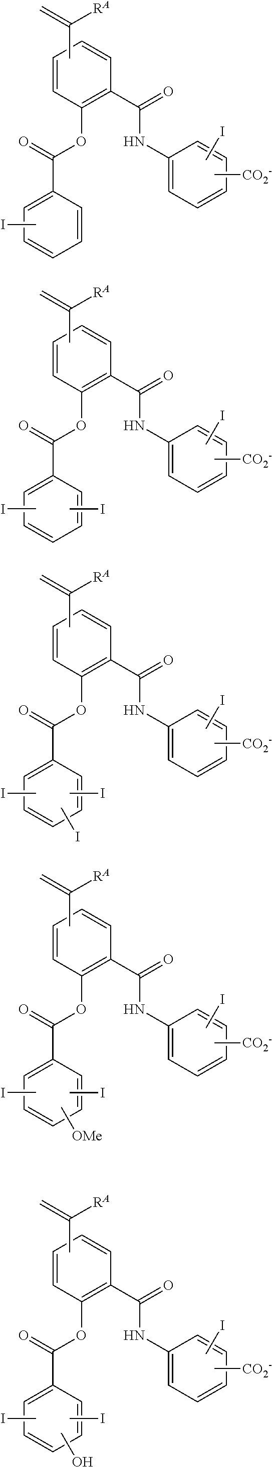

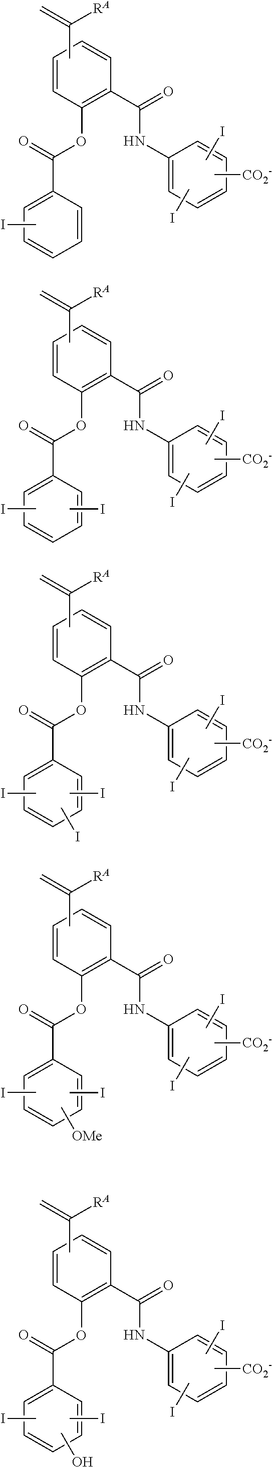

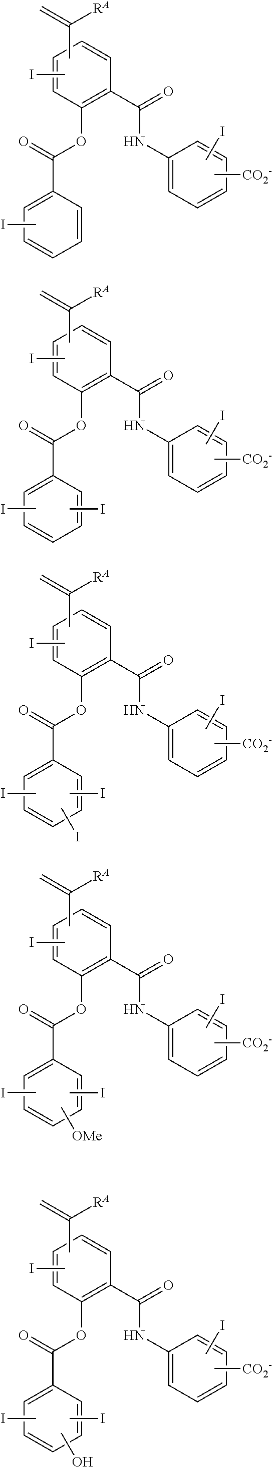

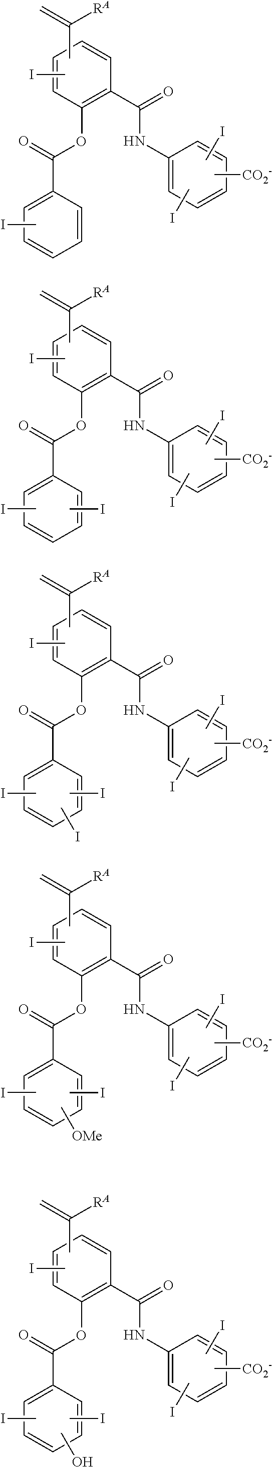

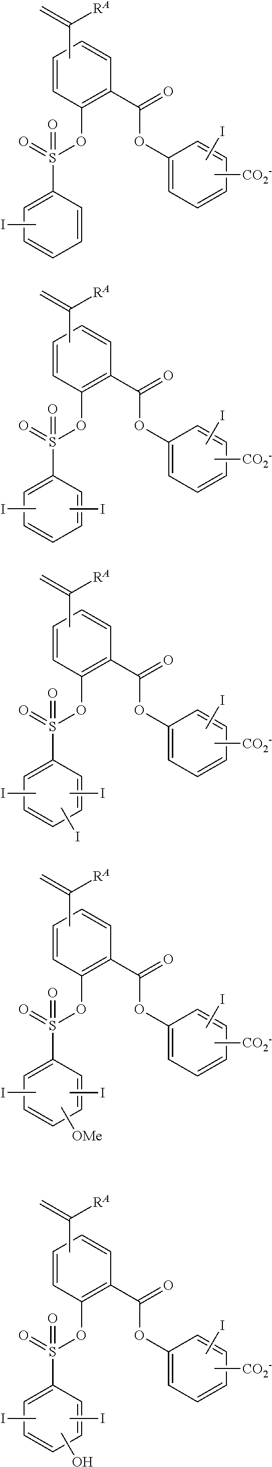

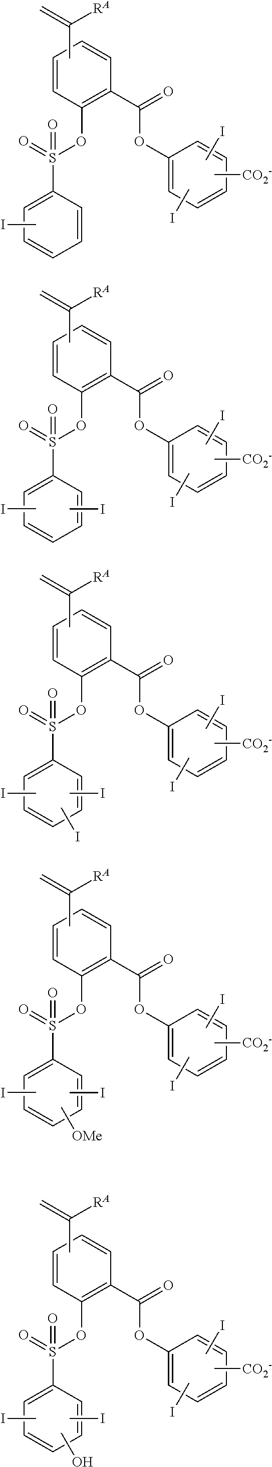

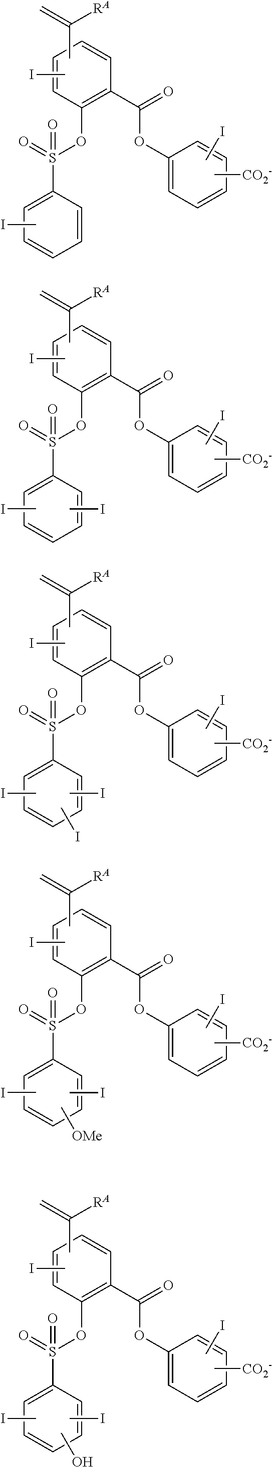

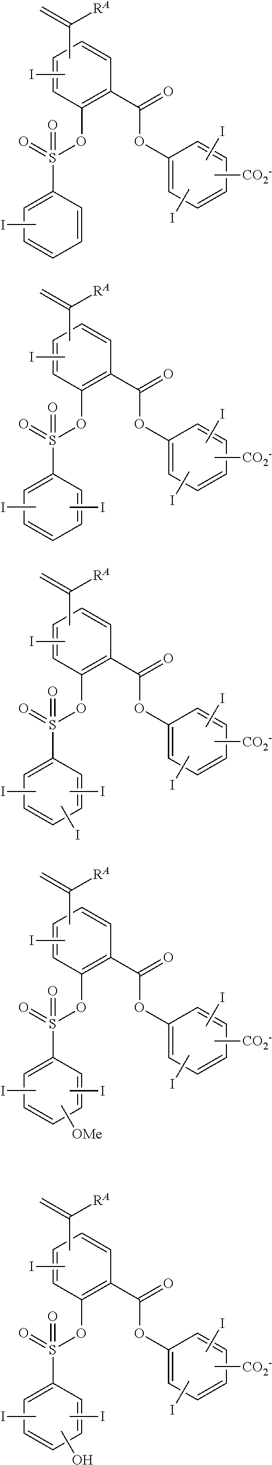

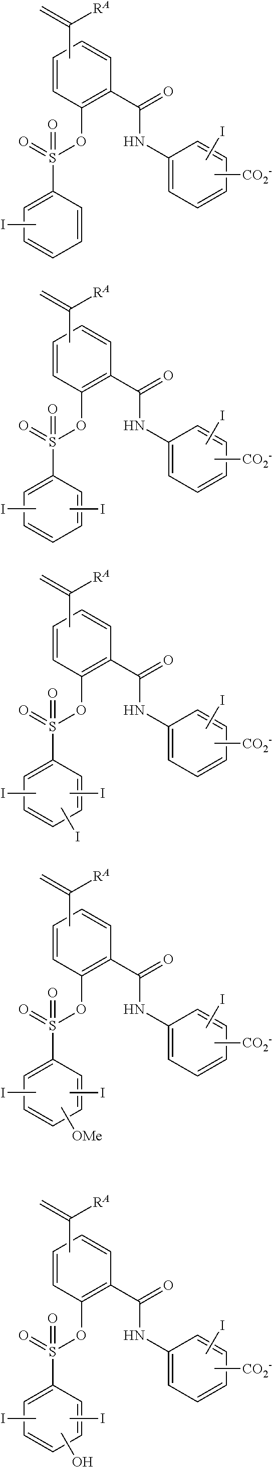

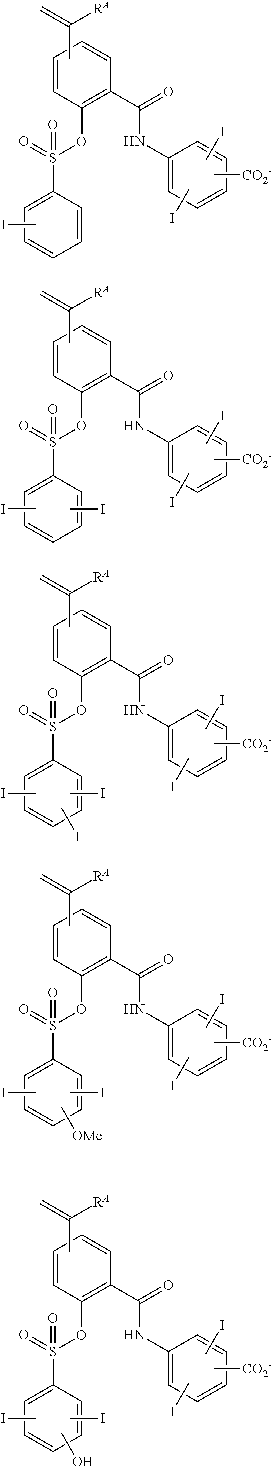

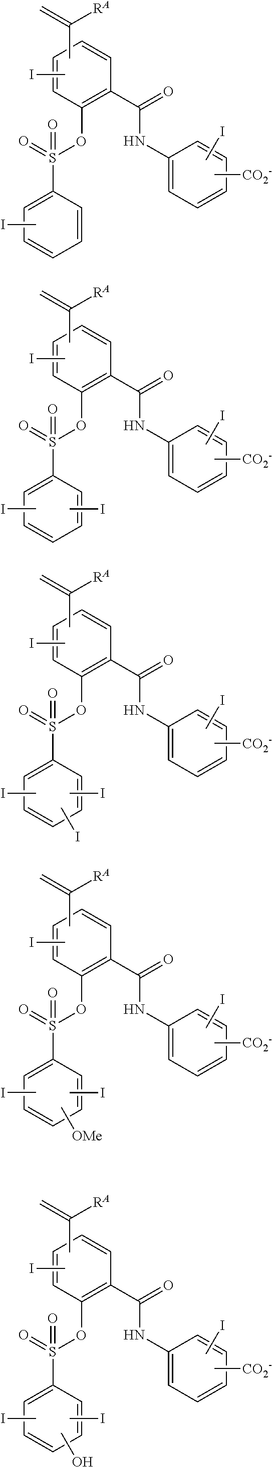

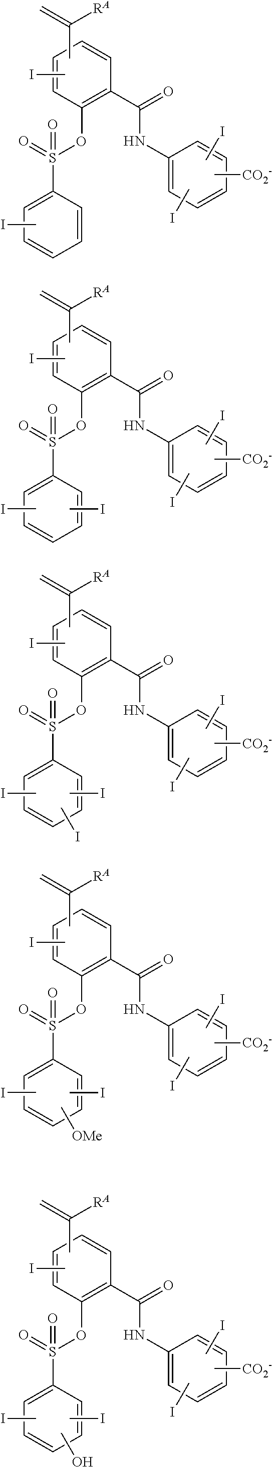

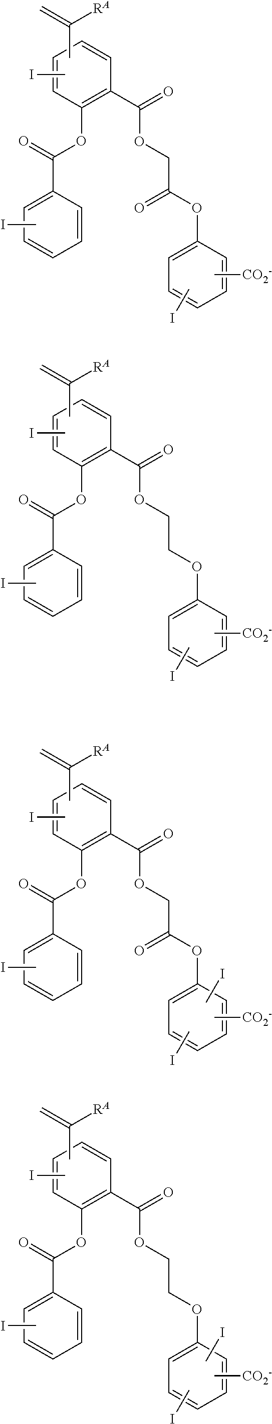

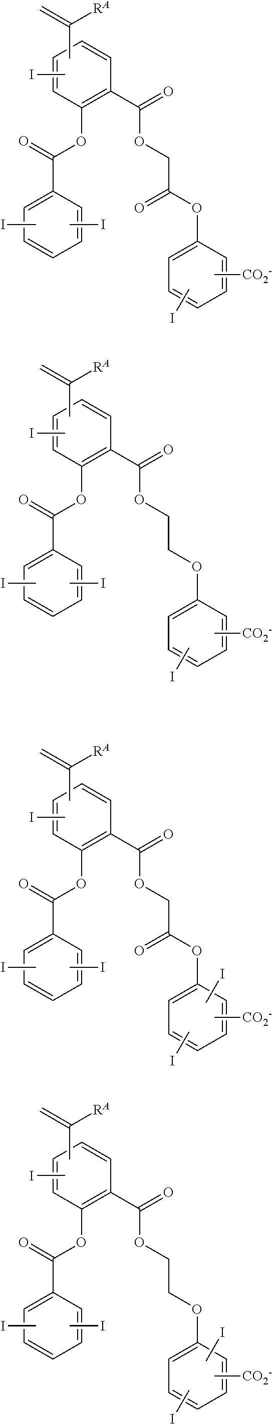

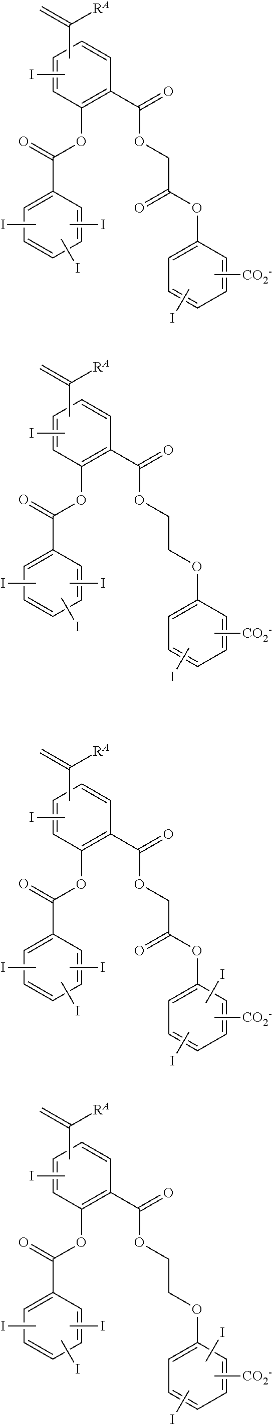

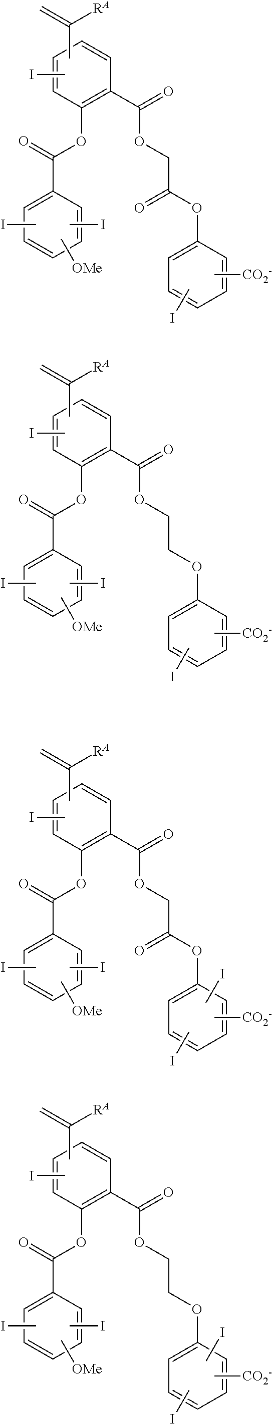

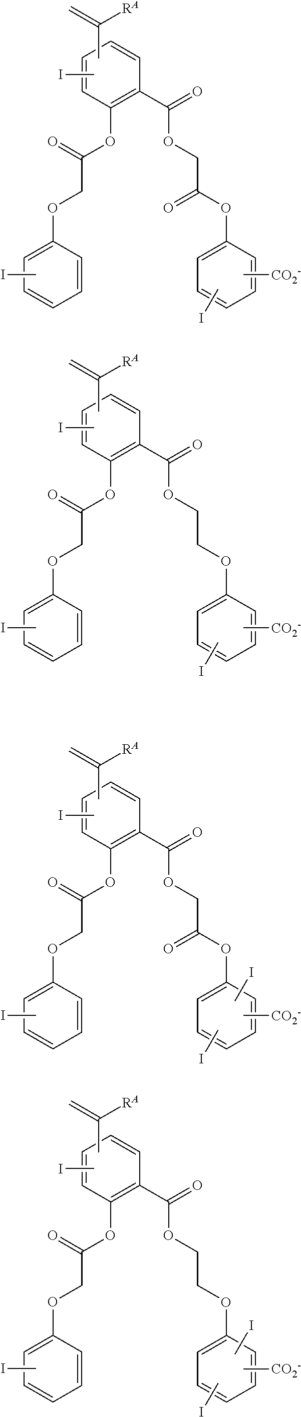

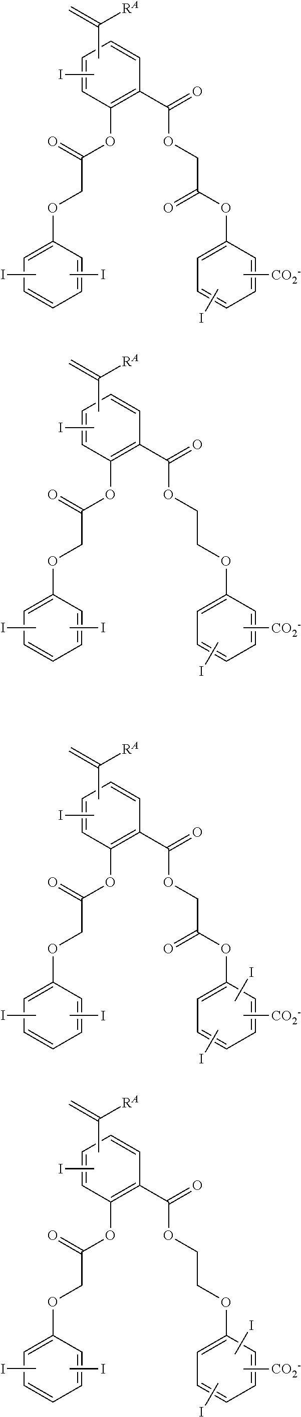

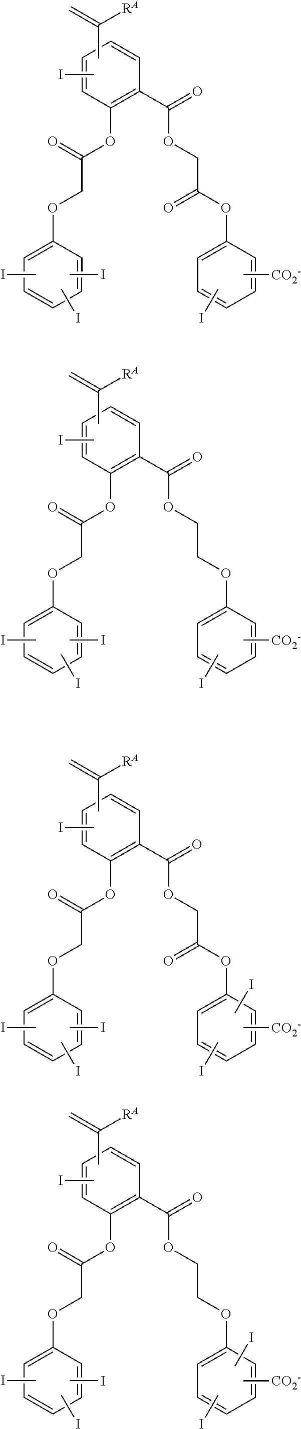

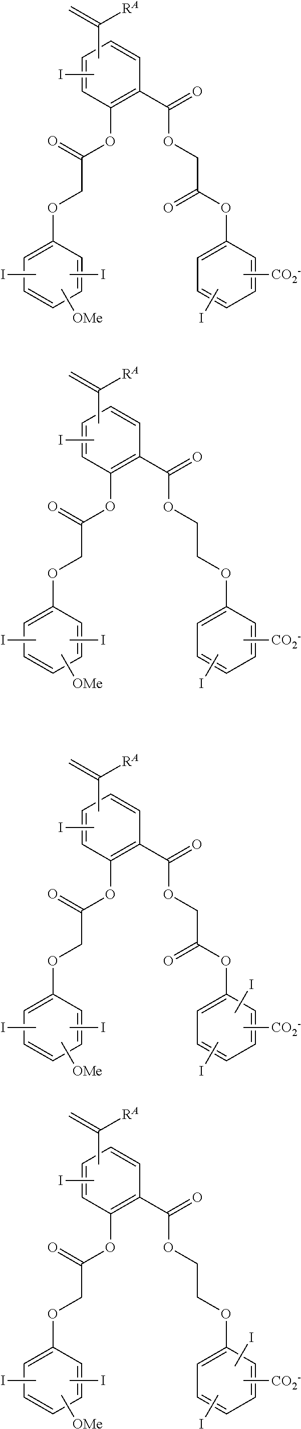

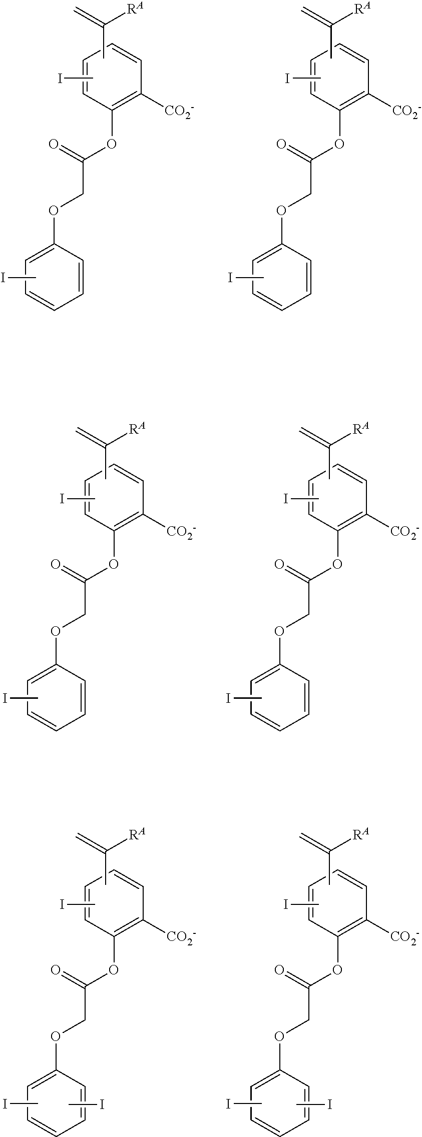

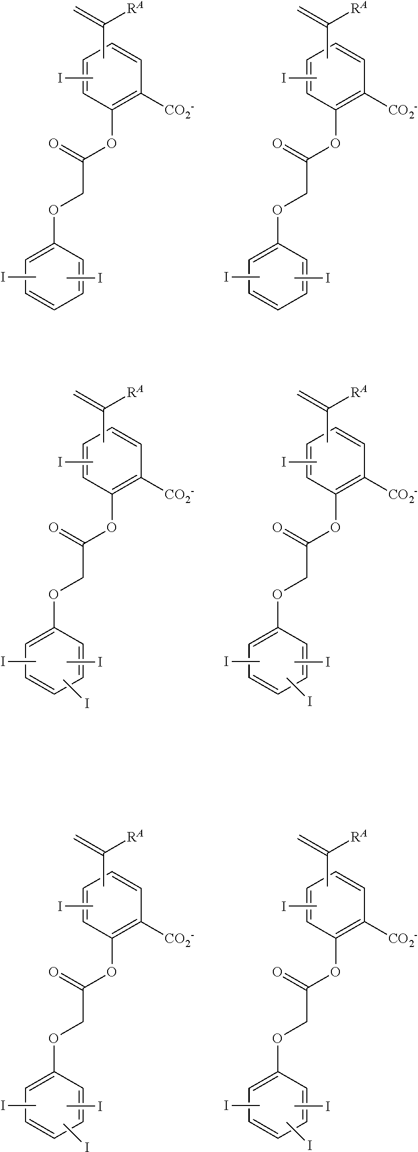

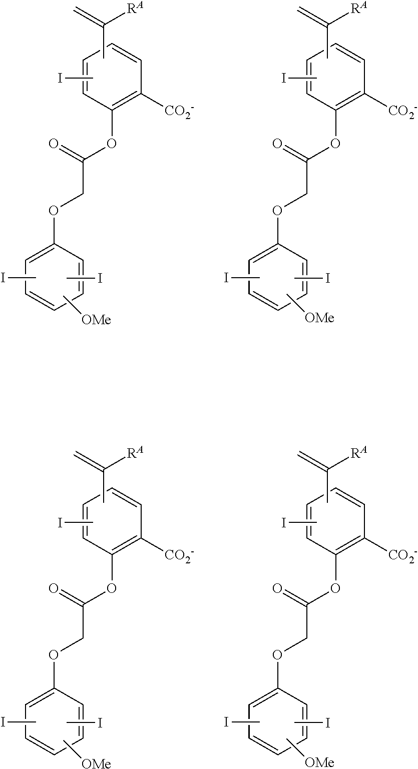

Other specific examples of the anion of the onium salt type monomer represented by the general formula (a) include, but are not limited to, those described in paragraphs [0049], [0054] to [0056], and [0062] to [0064] of JP7433394B1.

Specific examples of the sulfonium salt type monomer of the present invention include any combination of the anions and cations mentioned above.

The sulfonium salt type monomer of the present invention can be synthesized by a known method. Specifically, the method described in paragraphs [0402] to [0405] of JP7433394B1 can be included, but the synthesis method is not limited thereto.

### [Sulfonium Salt Type Quencher]

Furthermore, the present invention also provides a sulfonium salt type quencher, wherein the sulfonium salt type quencher is comprised of the sulfonium salt type monomer described above.

### [Polymer]

The polymer of the present invention contains a repeating unit derived from the sulfonium salt type monomer represented by the general formula (a) (hereinafter, also referred to as repeating unit-a). That is, the present invention provides a polymer wherein the polymer contains a repeating unit derived from the sulfonium salt type quencher described above.

The polymer of the present invention is a polymer-bonded type quencher that functions as a quencher in a chemically amplified resist composition and also as a base polymer. The structural feature of the polymer of the present invention is that it contains a repeating unit having a benzene or naphthalene structure directly bonded to the main chain, and has a salt structure containing a carboxylate anion having an iodine atom and a sulfonium cation having a cyano group, which is derived from the sulfonium salt type quencher consisting of the sulfonium salt type monomer of the present invention. Iodine atoms have extremely high absorption of EUV with a wavelength of 13.5 nm, so secondary electrons are generated during exposure, and the energy of the secondary electrons is transferred to the acid generator, promoting decomposition, and thereby increasing sensitivity. A polymerizable group consisting of stylene or a vinyl naphtalene structure is more rigid compared to methacrylic acid ester, etc., and the glass transition temperature (Tg) of the polymer is improved. It is believed that the aromatic rings in the base polymers or between the base polymers interact with each other (n-n stacking effect), so that the base polymers are regularly arranged, and resistance to pattern collapse in a developer is exhibited even during fine pattern formation. In addition, by having an aromatic ring directly bonded to the main chain, excellent etching resistance is exhibited even in the etching process after fine pattern formation. In addition, the cyano group is a strong electron withdrawing group, and when this group binds to an aromatic ring of a triaryl sulfonium cation, it lowers the LUMO in frontier molecular orbital theory, making it easier to accept secondary electrons, and thereby promoting the decomposition of the sulfonium cation. In addition, since the nitrogen atom of the cyano group has a lone electron pair, it can also be expected to function as an acid diffusion inhibitor group by interacting with the protons of the generated acid. Carboxylate anions are relatively highly basic and can effectively trap the acid generated from strong acids. Due to these synergistic effects, LWR and CDU are improved while being highly sensitive, enabling the formation of patterns that are resistant to pattern collapse, so it is particularly suitable as a material for chemically amplified positive type resist compositions.

The polymer further may include a repeating unit represented by the following formula (b1)(hereinafter also referred to as repeating unit-b1) and/or a repeating unit represented by the following formula (b2) (hereinafter also referred to as repeating unit-b2). That is, the polymer preferably further contains a repeating unit represented by either or both of the following general formulae (b1) and (b2).

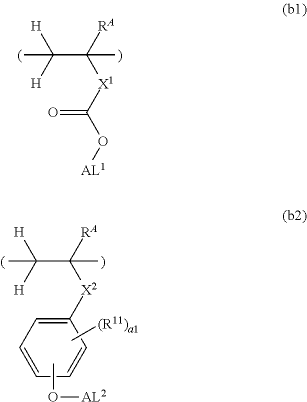

In the formulae, R^{A} is each independently a hydrogen atom, a fluorine atom, a methyl group, or a trifluoromethyl group;
X¹ is a single bond, a phenylene group, a naphthylene group, *—C(═O)—OX¹¹—, or *—C(═O)—NH—X¹¹, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; X¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring;
X² is a single bond, *—C(═O)—O—, or *—C(═O)—NH—;
* indicates a bond to a carbon atom in the main chain;
R¹¹ is a halogen atom, a cyano group, a hydroxy group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom; when a1 is 2 or more, each R¹¹ may be the same or they may be different from each other;
AL¹ and AL² are each independently an acid-labile group; and
a1 is an integer from 0 to 4.

In the general formulae (b1) and (b2), R^{A} is each independently a hydrogen atom, a fluorine atom, a methyl group, or a trifluoromethyl group.

In the general formula (b1), X¹ is a single bond, a phenylene group, a naphthylene group, *—C(═O)—OX¹¹—, or *—C(═O)—NH—X¹—, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom. X¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring. * indicates a bond to a carbon atom in the main chain.

In the general formula (b2), X² is a single bond, *—C(═O)—O—, or *—C(═O)—NH—. * indicates a bond to a carbon atom in the main chain. R¹¹ is a halogen atom, a cyano group, a hydroxy group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom. a1 is an integer from 0 to 4, and preferably 0 or 1; when a1 is 2 or more, each R¹¹ may be the same or they may be different from each other.

In the general formulae (b1) and (b2), AL¹ and AL² are each independently an acid-labile group. Specific examples of the acid-labile group include, but are not limited to, those described in JP2013-080033A and JP2013-083821A.

Typically, specific examples of the acid-labile group include those represented by the following formulae (AL-1) to (AL-3).

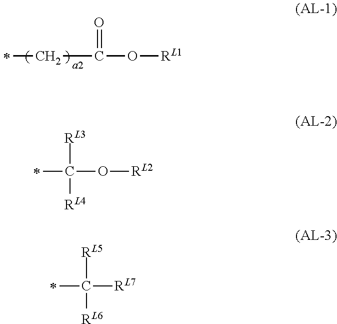

In the formulae, * represents a bonding point.

In the general formulae (AL-1) and (AL-2), R^{L1} and R^{L2} are each independently a hydrocarbyl group having 1 to 40 carbon atoms, and optionally containing a heteroatom such as an oxygen atom, a sulfur atom, a nitrogen atom, a fluorine atom, or an iodine atom. The hydrocarbyl group may be saturated or unsaturated and may be linear, branched, or cyclic. The hydrocarbyl group preferably has 1 to 20 carbon atoms.

In the general formula (AL-1), a2 is an integer from 0 to 10, and preferably an integer from 1 to 5.

In the general formula (AL-2), R^{L3} and R^{L4} are each independently a hydrogen atom or a hydrocarbyl group having 1 to 20 carbon atoms, and optionally containing a heteroatom such as an oxygen atom, a sulfur atom, a nitrogen atom, a fluorine atom, or an iodine atom. The hydrocarbyl group may be saturated or unsaturated and may be linear, branched, or cyclic. Also, any two of R^{L2}, R^{L3}, and R^{L4} may be bonded to each other to form a ring having 3 to 20 carbon atoms together with the carbon atom or the carbon atom and the oxygen atom to which they are bonded. As the ring, a ring having 4 to 16 carbon atoms is preferable, and an alicyclic ring is particularly preferable.

In the general formula (AL-3), R^{L5}, R^{L6}, and R^{L7} are each independently a hydrocarbyl group having 1 to 20 carbon atoms, and optionally containing a heteroatom such as an oxygen atom, a sulfur atom, a nitrogen atom, a fluorine atom, or an iodine atom. The hydrocarbyl group may be saturated or unsaturated and may be linear, branched, or cyclic. Also, any two of R^{L2}, R^{L3}, and R^{L4} may be bonded to each other to form a ring having 3 to 20 carbon atoms together with the carbon atom to which they are bonded. As the ring, a ring having 4 to 16 carbon atoms is preferable, and an alicyclic ring is particularly preferable.

Specific examples of the repeating unit-b1 include, but are not limited to, those shown below. In the following formulae, R^{A} and AL¹ are as defined above.

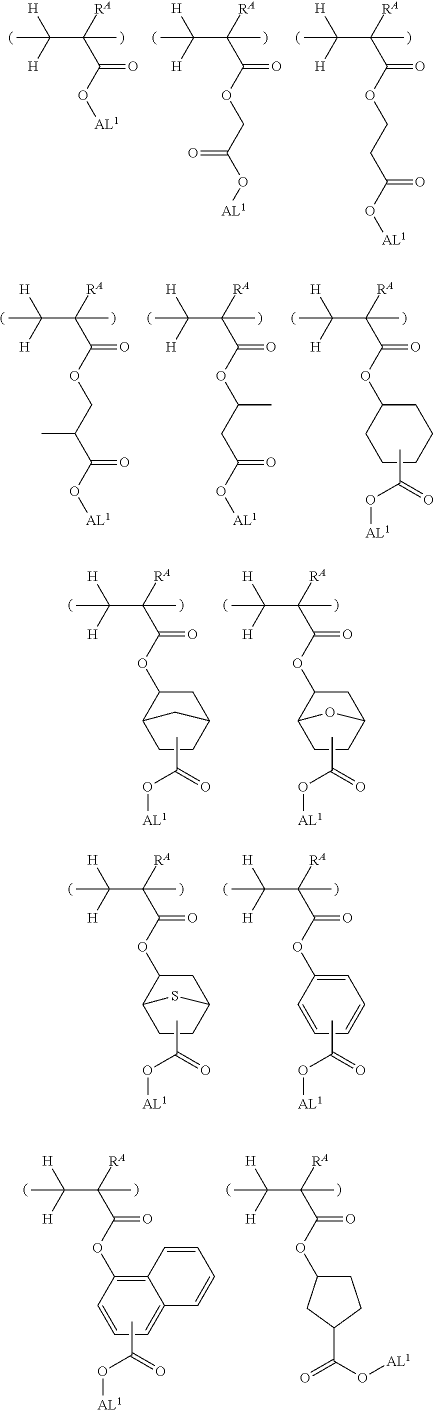

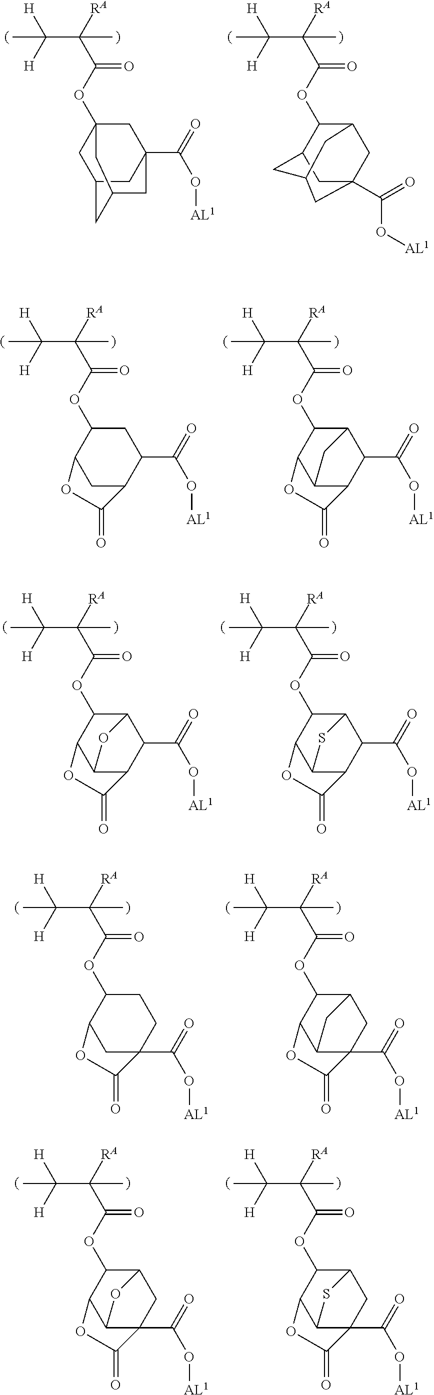

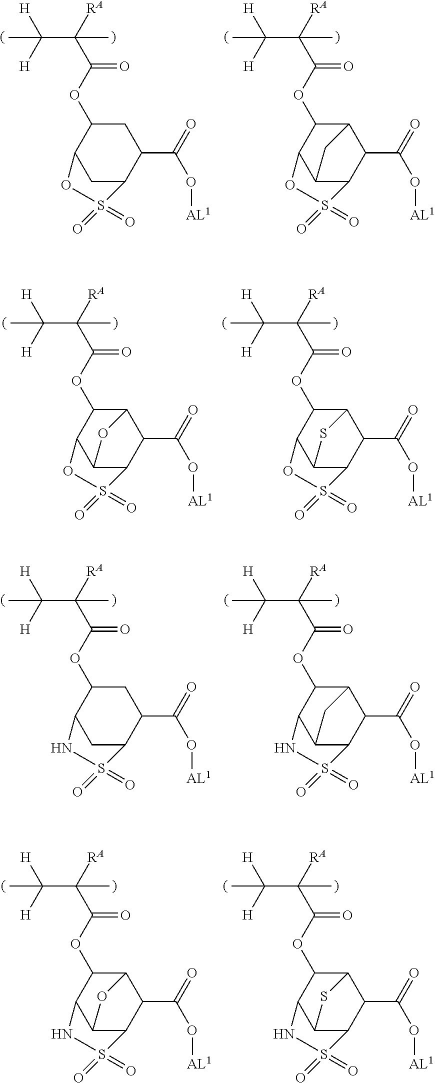

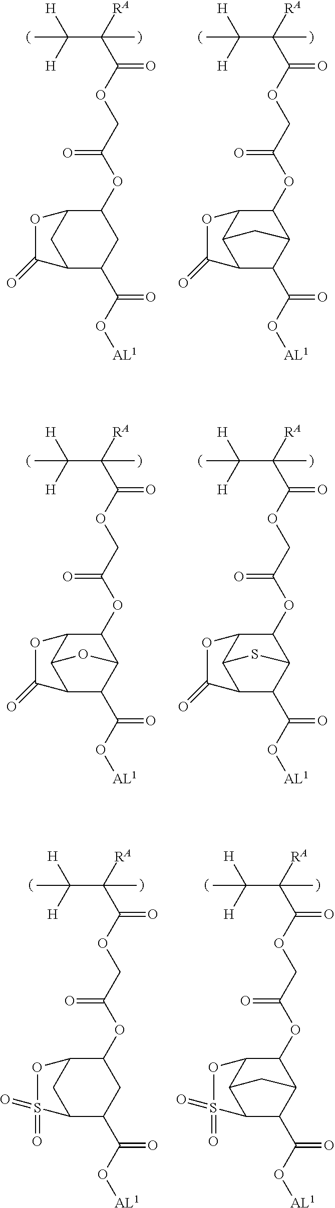

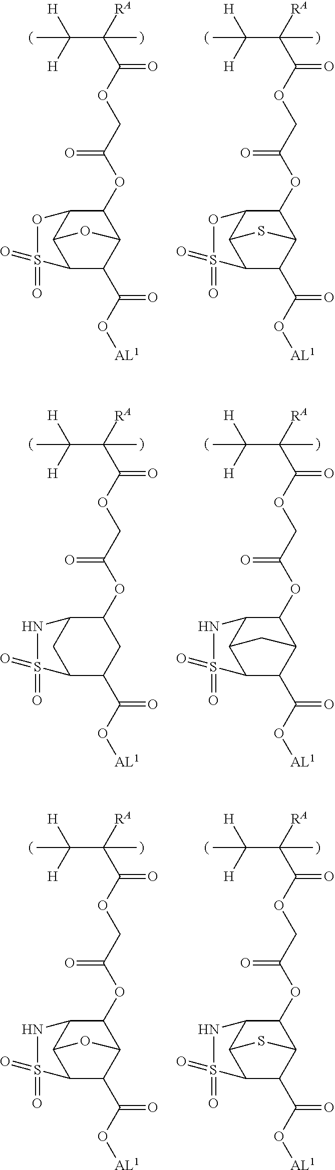

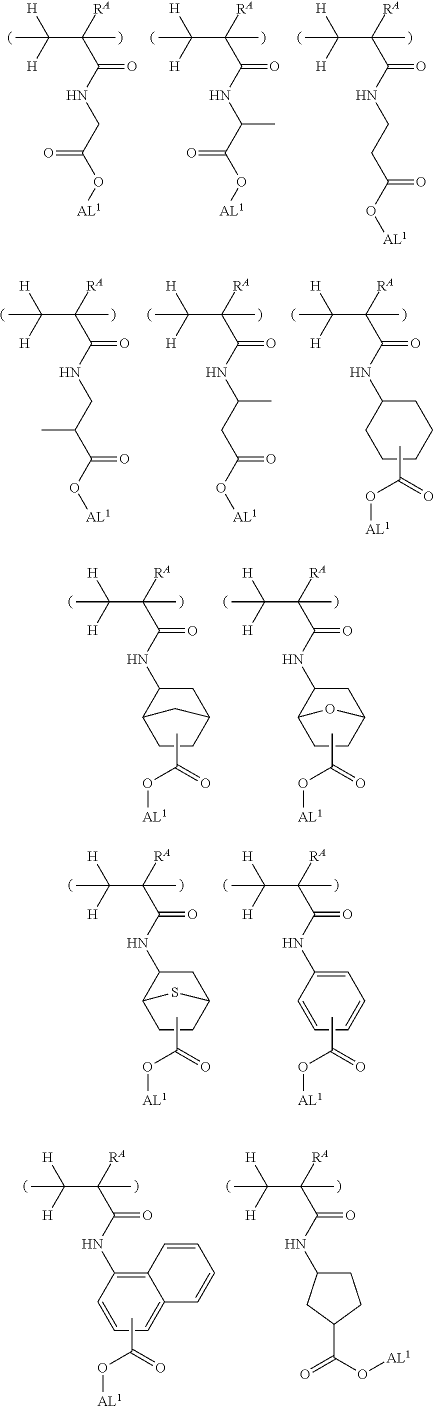

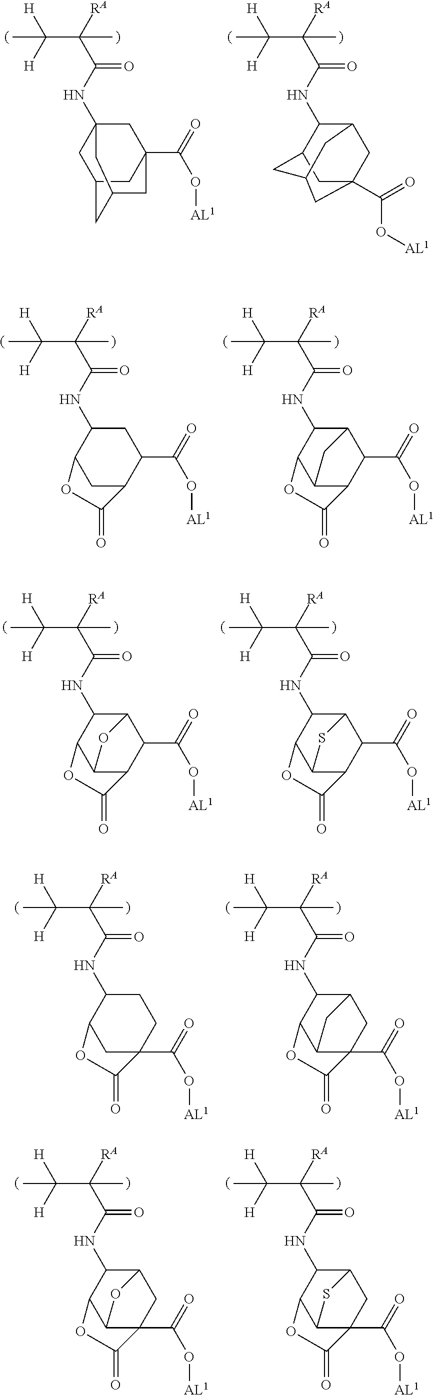

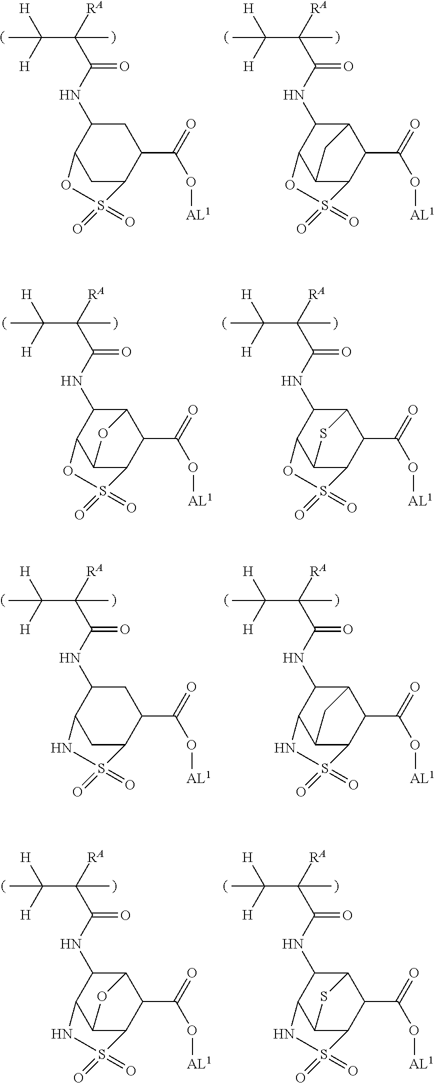

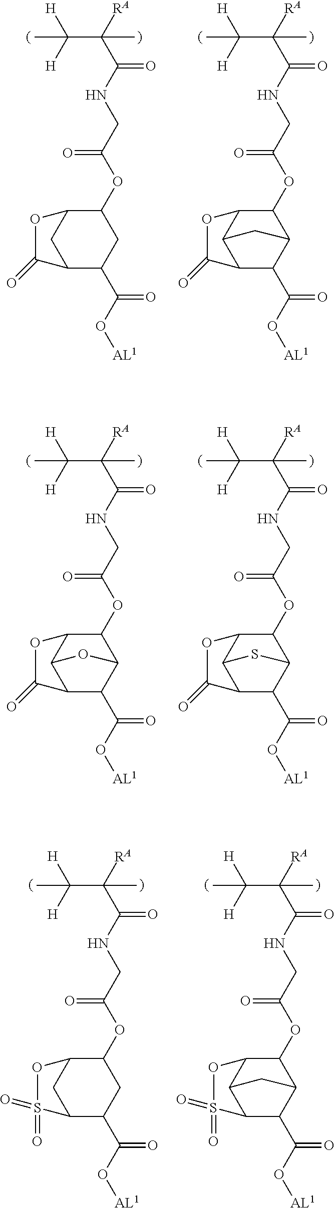

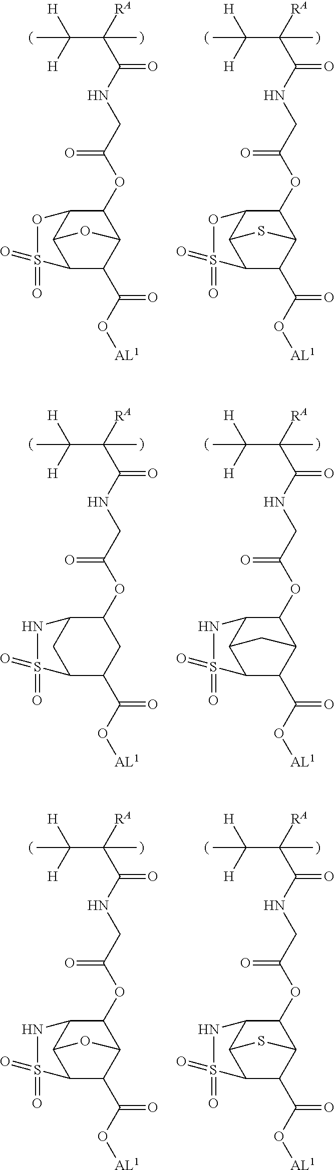

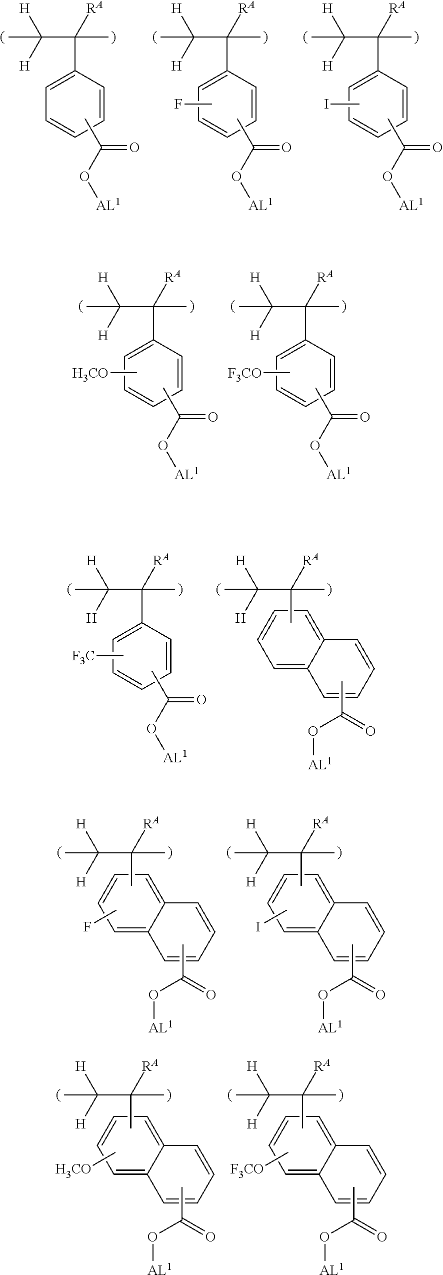

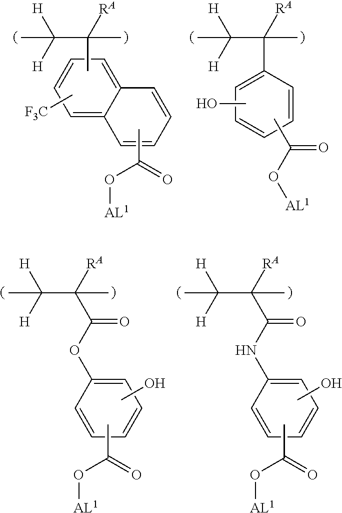

Specific examples of the repeating unit-b2 include, but are not limited to, those shown below. In the following formulae, R^{A} and AL² are as defined above.

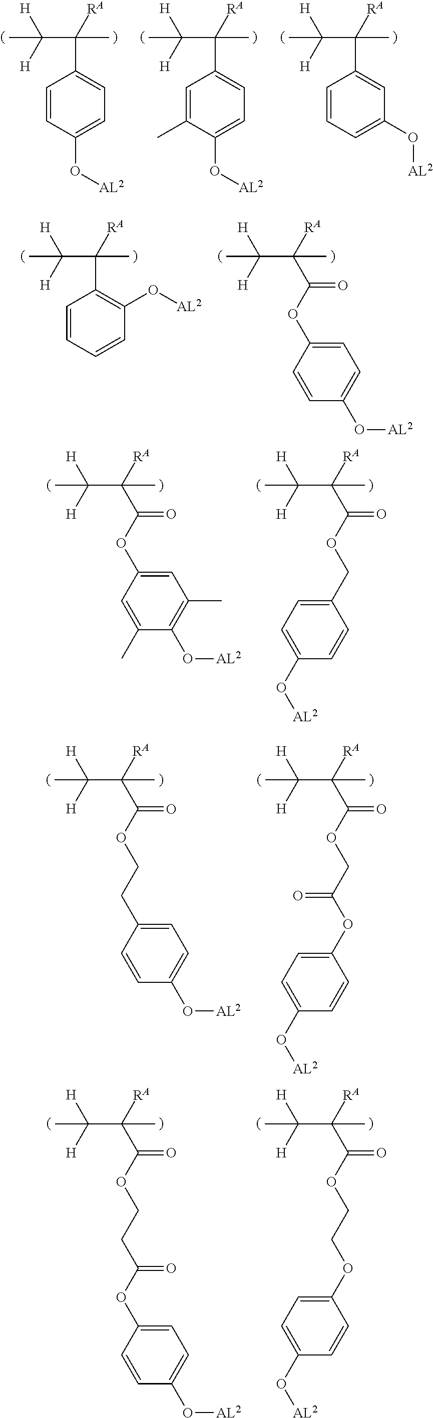

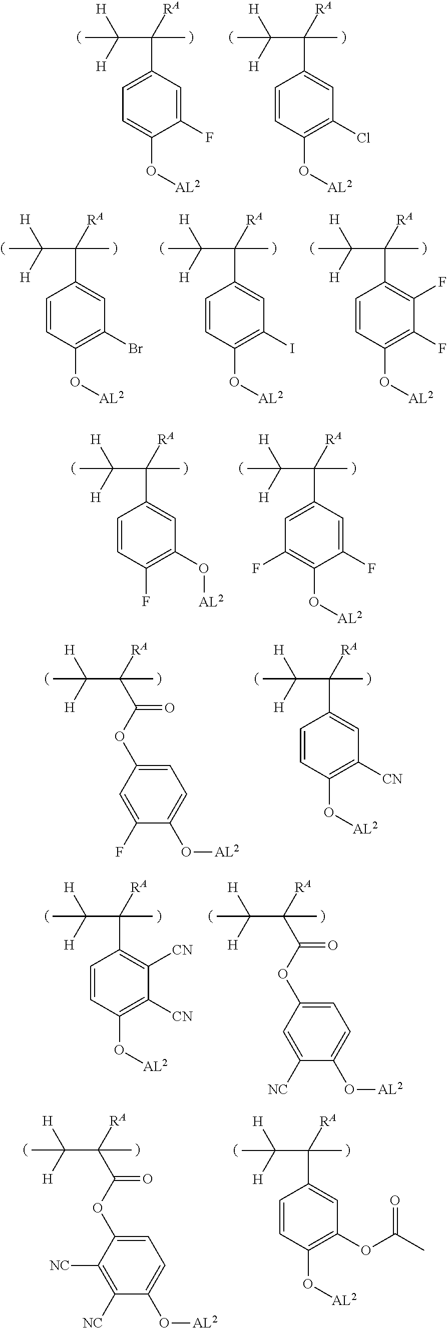

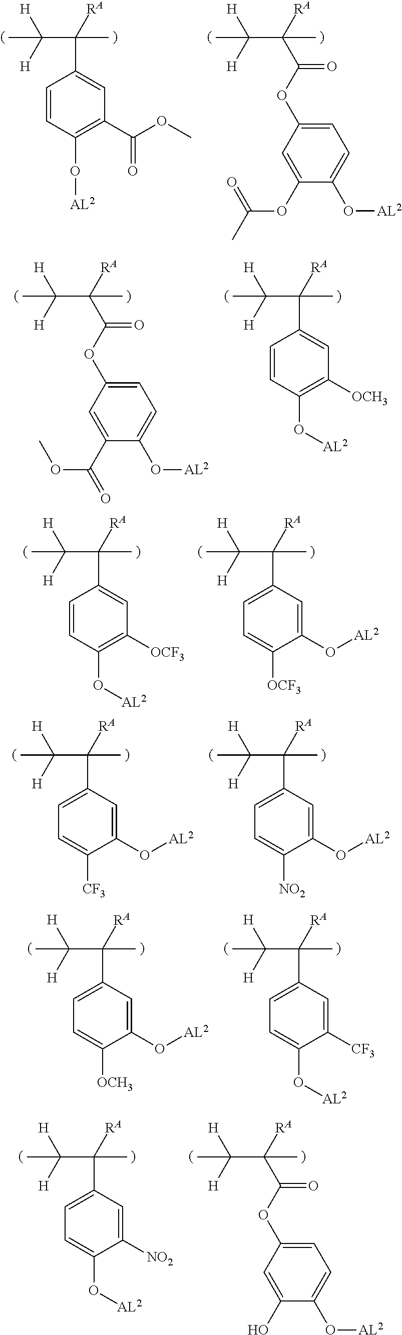

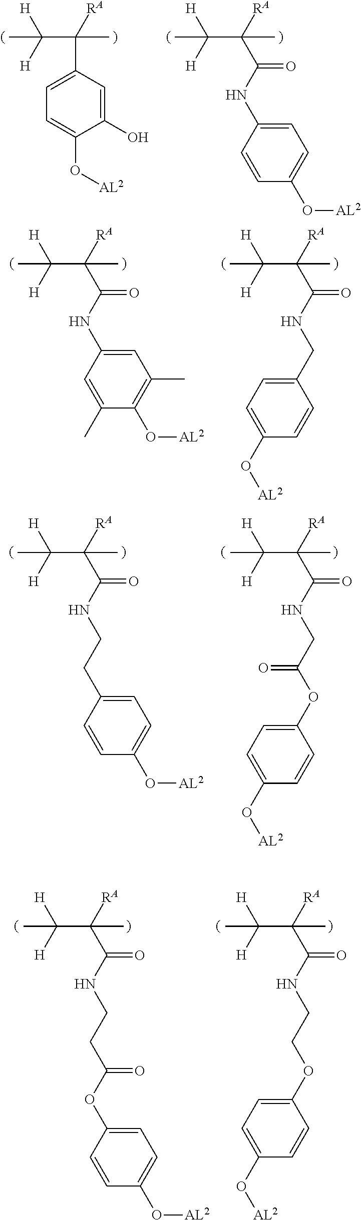

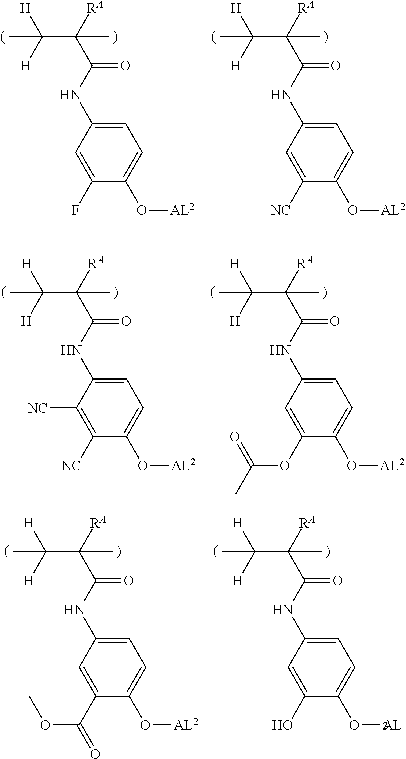

The polymer further may include a repeating unit represented by the following general formula (b3) (hereinafter also referred to as repeating unit-b3).

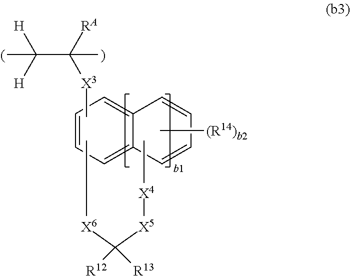

In the formula, b1 is 0 or 1; b2 is an integer from 0 to 3 when b1 is 0, and is an integer from 0 to 5 when b1 is 1;
R^{A} is a hydrogen atom, a fluorine atom, a methyl group, or a trifluoromethyl group;
X³ is a single bond, *—C(═O)—O—, or *—C(═O)—NH—; * indicates a bond to a carbon atom in the main chain;
R¹² and R¹³ are each independently a hydrogen atom, or a hydrocarbyl group having 1 to 20 carbon atoms and optionally containing a heteroatom; furthermore, R¹² and R¹³ may be bonded to each other to form a ring together with the carbon atom to which they are bonded;
R¹⁴ is a halogen atom, a hydroxy group, a cyano group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbyloxycarbonyl group having 2 to 20 carbon atoms and optionally containing a heteroatom, a hydrocarbylthio group having 1 to 20 carbon atoms and optionally containing a heteroatom, or —N(R^{14A})(R^{14B}); R^{14A} and R^{14B} are each independently a hydrogen atom or a hydrocarbyl group having 1 to 6 carbon atoms; when b2 is 2 or more, each R¹⁴ may be the same or they may be different from each other, and a plurality of R¹⁴ may be bonded to each other to form a ring together with the carbon atoms of the aromatic ring to which they are bonded;
X⁴ is a single bond, an aliphatic hydrocarbylene group having 1 to 4 carbon atoms, a carbonyl group, a sulfonyl group, or a group obtained by combining these; and
X⁵ and X⁶ are each independently an oxygen atom or a sulfur atom; however, X⁴ and X⁶ are bonded to adjacent carbon atoms of an aromatic ring.

In the general formula (b3), b1 is 0 or 1. When b1 is 0, the structure is a benzene ring, and when b1 is 1, the structure is a naphthalene ring; however, from the viewpoint of solvent solubility, b1 is preferably 0, giving a benzene ring. b2 is an integer from 0 to 3 when b1 is 0, and is an integer from 0 to 5 when b1 is 1. From the viewpoint of raw material procurement, b2 is preferably an integer from 0 to 3, and more preferably 0, 1 or 2.

In the general formula (b3), R^{A} is a hydrogen atom, a fluorine atom, a methyl group, or a trifluoromethyl group. Among these, a hydrogen atom or a methyl group is preferable, and a hydrogen atom is more preferable.

In the general formula (b3), X³ is a single bond, *—C(═O)—O—, or *—C(═O)—NH—. * indicates a bond to a carbon atom in the main chain. Among these, a single bond or *—C(═O)—O— is preferable, and a single bond is more preferable.

In the general formula (b3), R¹² and R¹³ are each independently a hydrogen atom or a hydrocarbyl group having 1 to 20 carbon atoms and optionally containing a heteroatom. The hydrocarbyl group may be saturated or unsaturated and may be linear, branched, or cyclic. Specific examples thereof include alkyl groups having 1 to 20 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyl group, an n-decyl group, an undecyl group, a dodecyl group, a tridecyl group, a tetradecyl group, a pentadecyl group, a heptadecyl group, an octadecyl group, a nonadecyl group, and an icosyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, an allyl group, a propenyl group, a butenyl group, and a hexenyl group; cyclic unsaturated hydrocarbyl groups having 3 to 20 carbon atoms, such as a cyclohexenyl group; aryl groups having 6 to 20 carbon atoms, such as a phenyl group and a naphthyl group; aralkyl groups having 7 to 20 carbon atoms, such as a benzyl group, a 1-phenylethyl group, and a 2-phenylethyl group; and groups obtained by combining these groups. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

Also, R¹² and R¹³ may be bonded to each other to form a ring together with the carbon atom to which they are bonded. Specific examples of the ring formed in this case include a cyclopropane ring, a cyclobutane ring, a cyclopentane ring, a cyclohexane ring, a norbornane ring, an adamantane ring, etc. Furthermore, some or all of the hydrogen atoms of the ring may be substituted with a group containing a heteroatom such as an oxygen atom, a sulfur atom, a nitrogen atom, or a halogen atom, and some of the —CH₂— of the ring may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

In the general formula (b3), R¹⁴ is a halogen atom, a hydroxy group, a cyano group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbyloxycarbonyl group having 2 to 20 carbon atoms and optionally containing a heteroatom, a hydrocarbylthio group having 1 to 20 carbon atoms and optionally containing a heteroatom, or —N(R^{14A})(R^{14B}). R^{14A} and R^{14B} are each independently a hydrogen atom or a hydrocarbyl group having 1 to 6 carbon atoms. The halogen atom is preferably a fluorine atom, a chlorine atom, a bromine atom, or an iodine atom, and more preferably a fluorine atom or an iodine atom. The hydrocarbyl group and the hydrocarbyl moiety of the hydrocarbyloxy group, the hydrocarboxycarbonyl group, and the hydrocarbylthio group may be saturated or unsaturated, and may be linear, branched, or cyclic. Specific examples of these include, but are not limited to, ones similar to those exemplified as the hydrocarbyl group represented by R¹² and R¹³. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc. When b2 is 2 or more, each R¹⁴ may be the same or they may be different from each other.

Also, when b2 is 2 or more, a plurality of R¹⁴ may be bonded to each other to form a ring together with the carbon atoms of the aromatic ring to which they are bonded. Specific examples of the ring formed in this case include a cyclopropane ring, a cyclobutane ring, a cyclopentane ring, a cyclohexane ring, a norbornane ring, an adamantane ring, etc. Furthermore, some or all of the hydrogen atoms of the ring may be substituted with a group containing a heteroatom such as an oxygen atom, a sulfur atom, a nitrogen atom, or a halogen atom, and some of the —CH₂— of the ring may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

In the general formula (b3), X⁴ is a single bond, an aliphatic hydrocarbylene group having 1 to 4 carbon atoms, a carbonyl group, a sulfonyl group, or a group obtained by combining these. Among these, from the viewpoint of raw material procurement, a single bond, a carbonyl group, or a sulfonyl group is preferable, and from the viewpoint of the polar group generated after the reaction, a single bond or a carbonyl group is more preferable.

In the general formula (b3), X⁵ and X⁶ are each independently an oxygen atom or a sulfur atom. However, X⁴ and X⁶ are bonded to adjacent carbon atoms of an aromatic ring. X⁵ and X⁶ may be the same or they may be different from each other, but from the viewpoint of reactivity, X⁵ and X⁶ are preferably both oxygen atoms.

Specific examples of the repeating unit-b3 include, but are not limited to, those shown below. In the following formulae, R^{A} is as defined above, and Me is a methyl group. In addition, the bonding positions of various substituents on the aromatic ring may be interchanged.

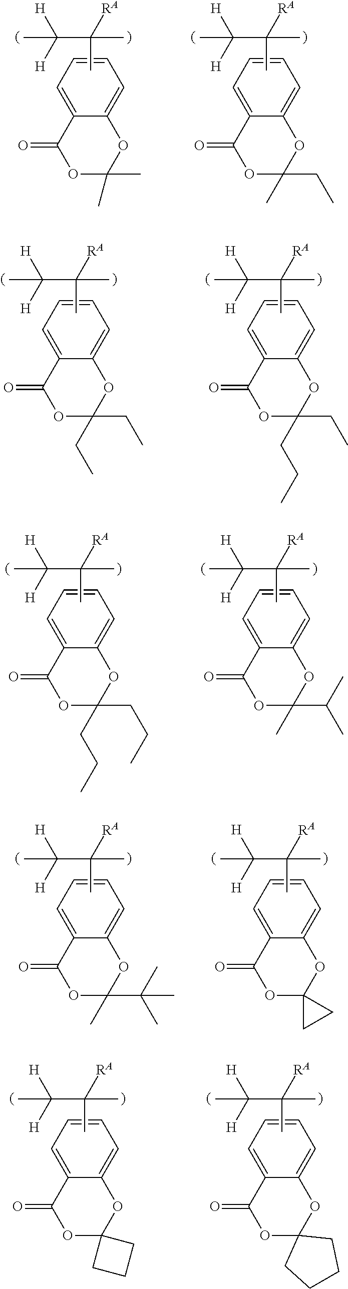

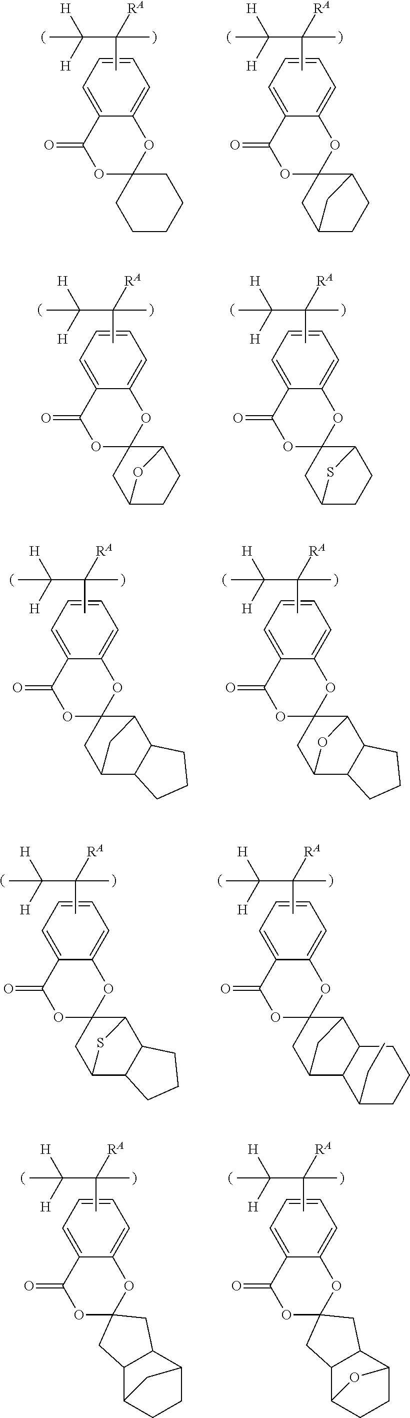

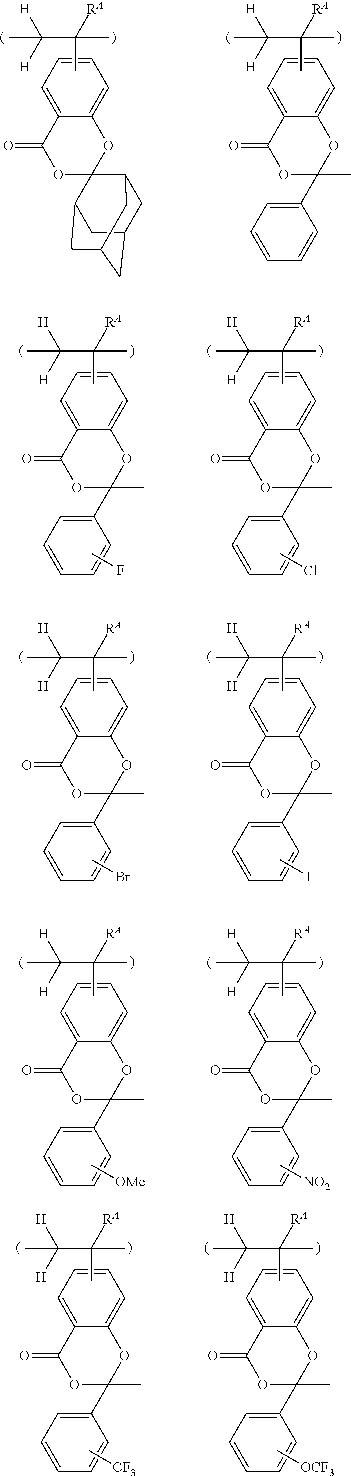

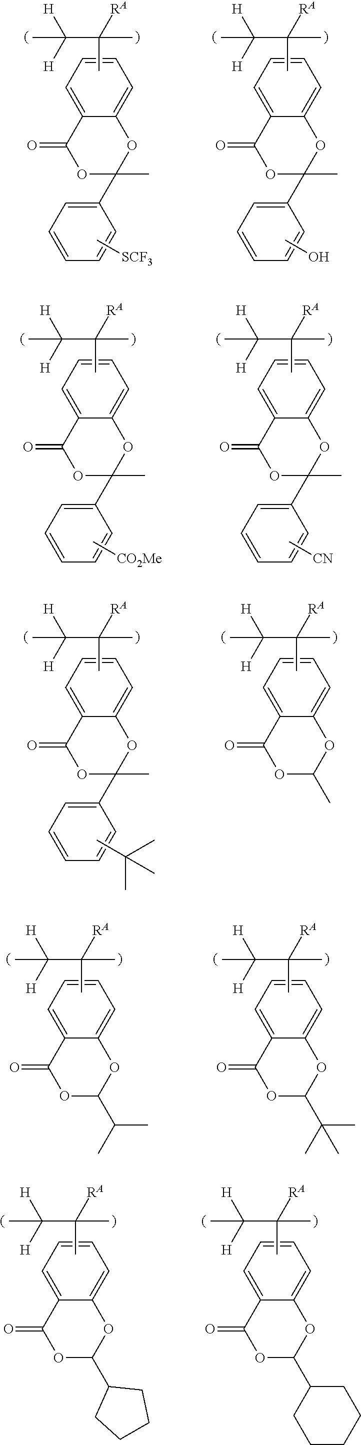

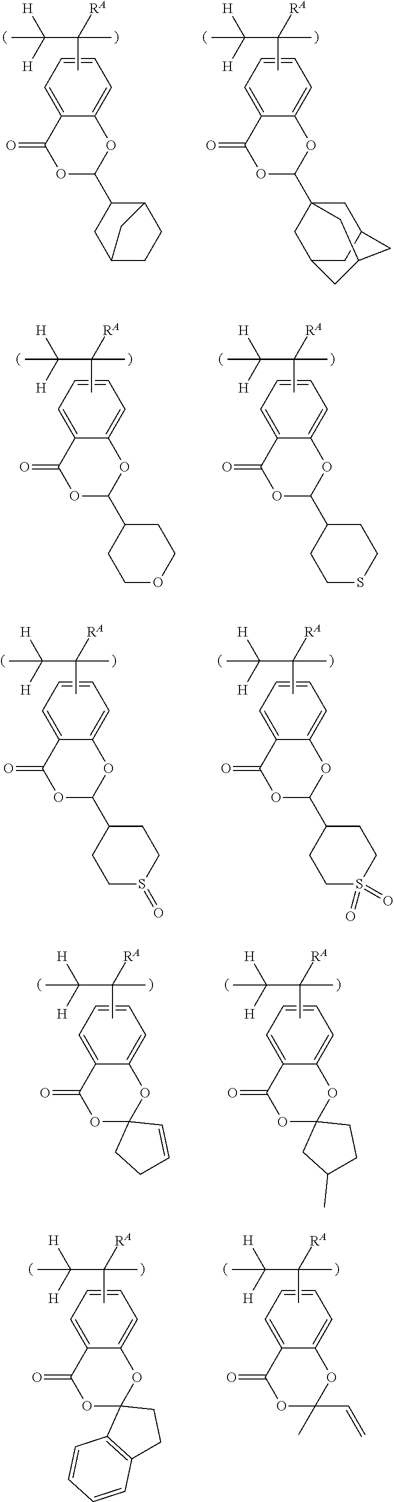

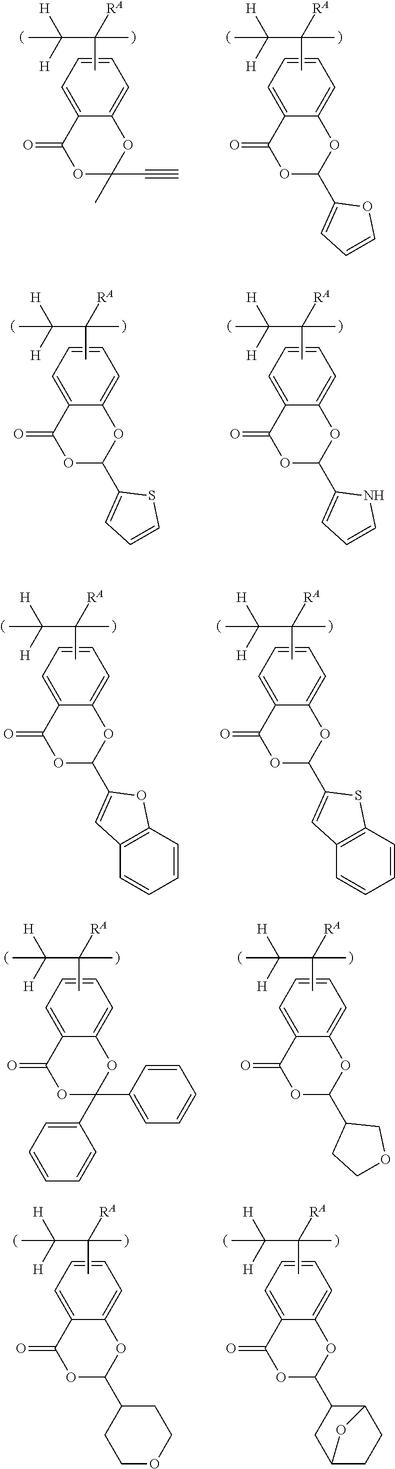

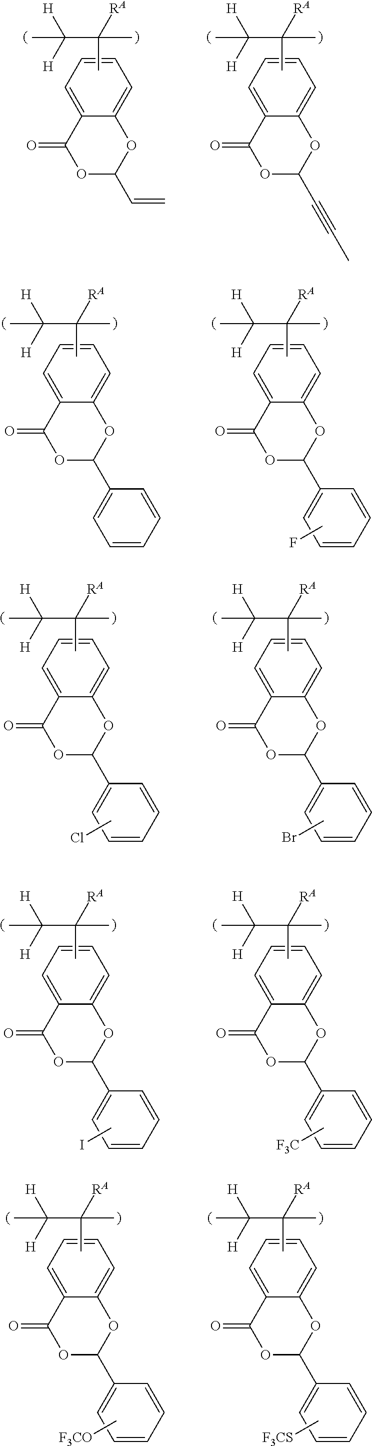

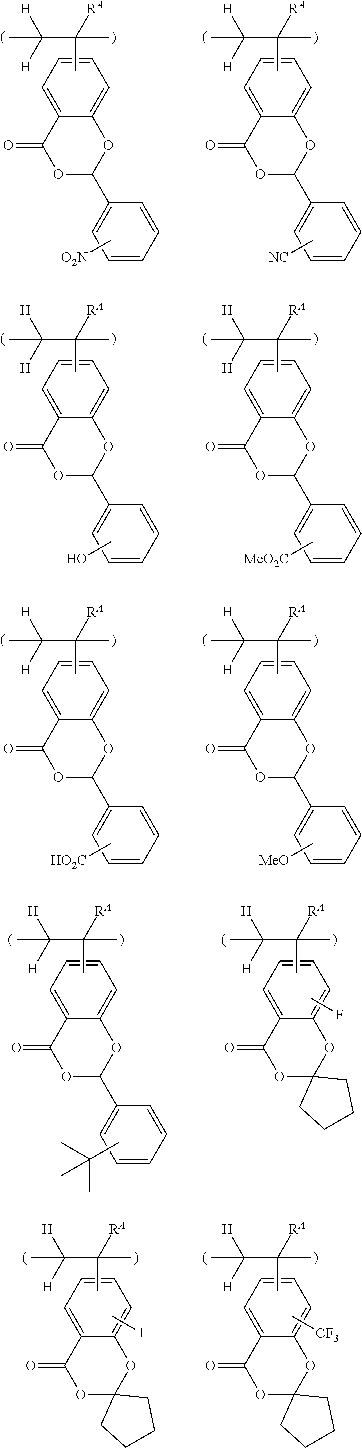

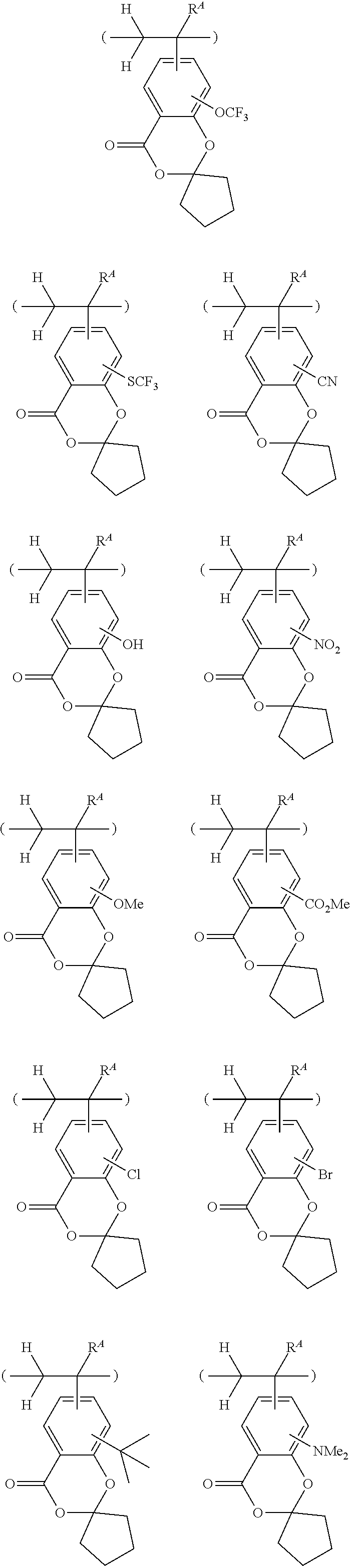

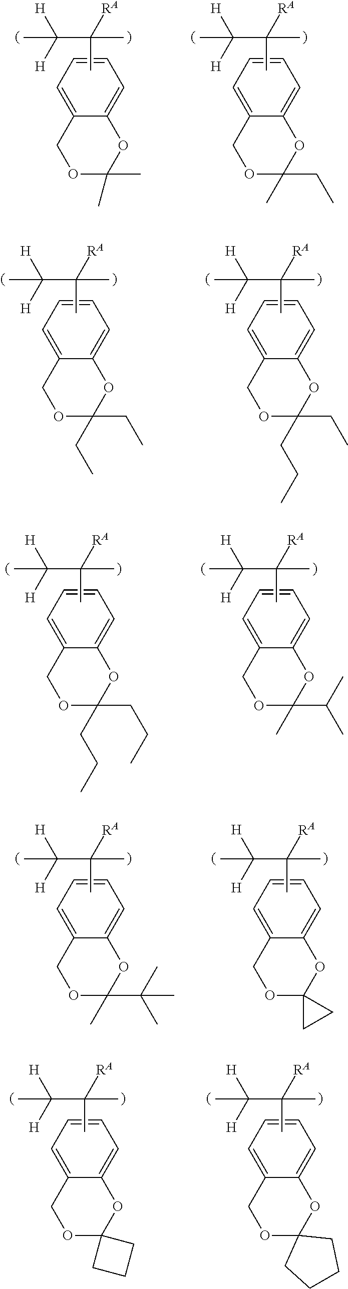

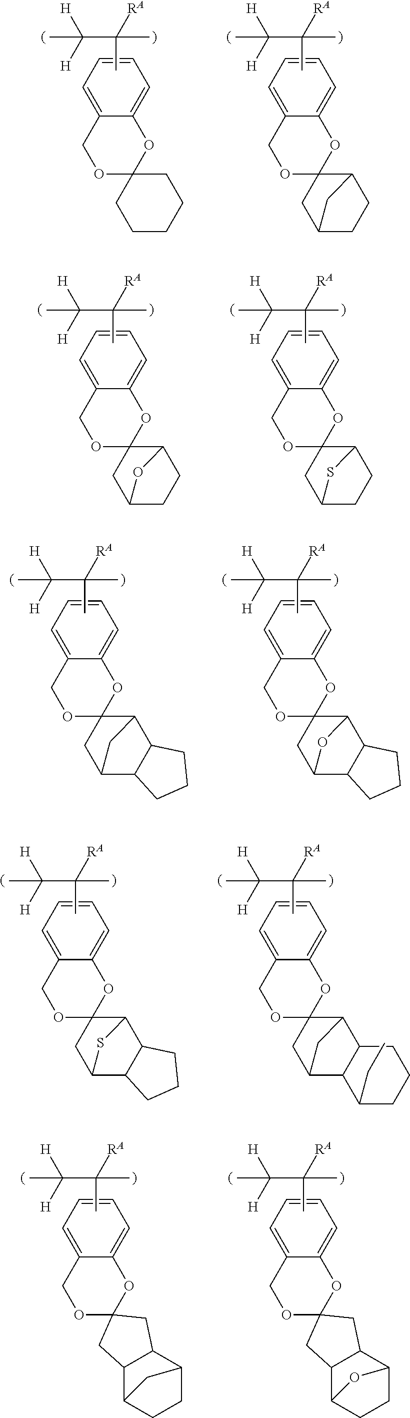

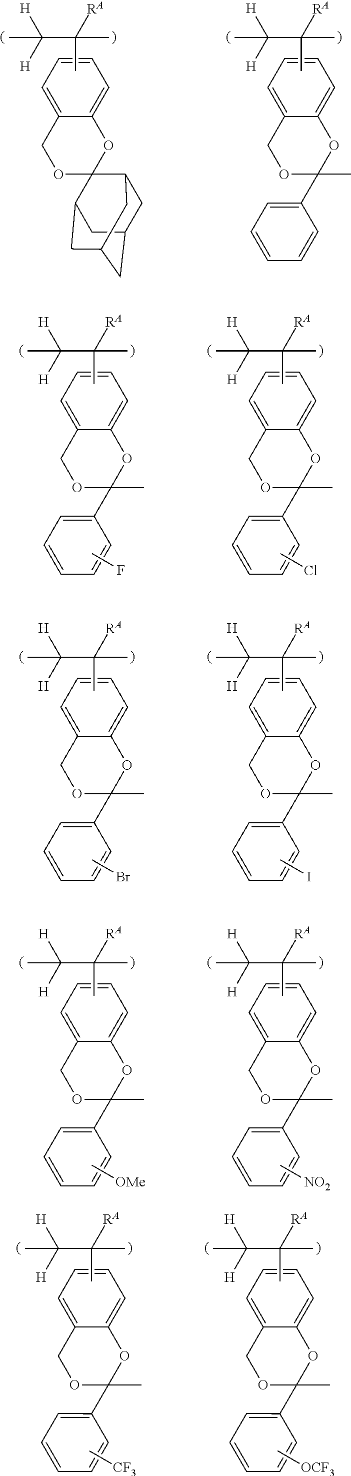

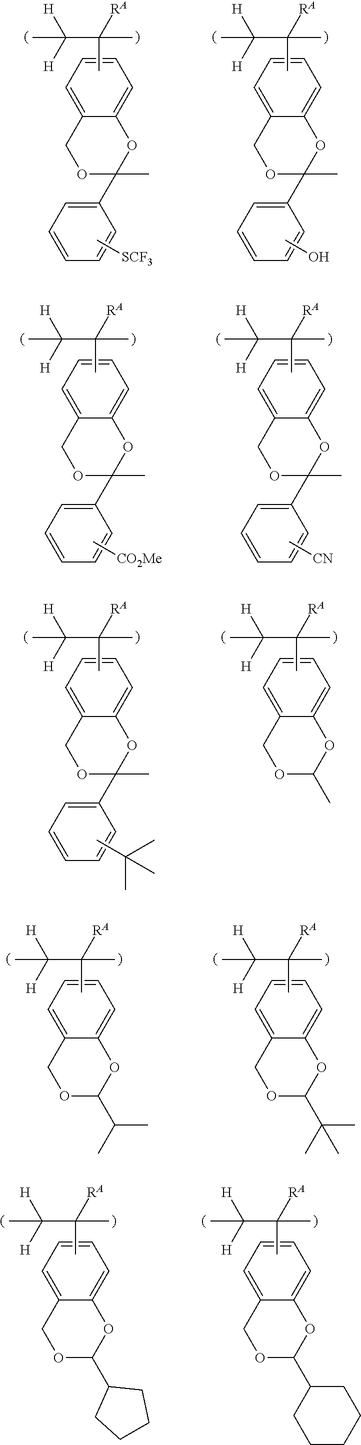

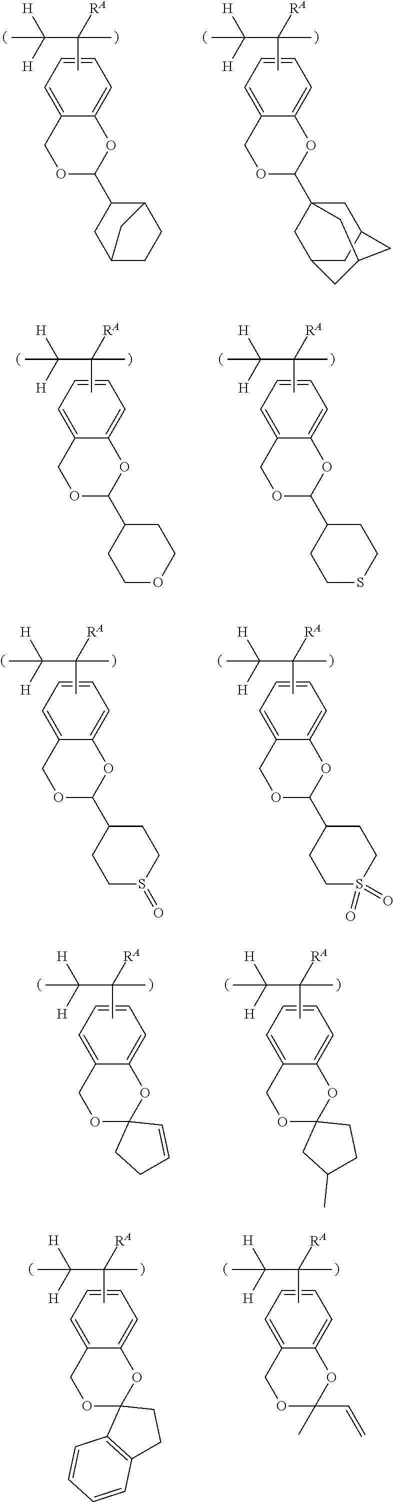

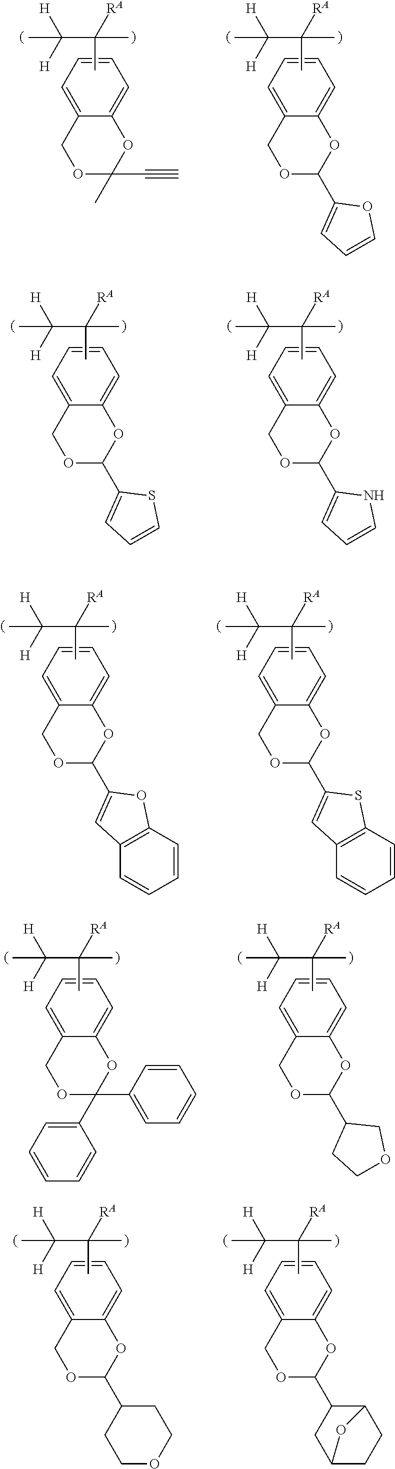

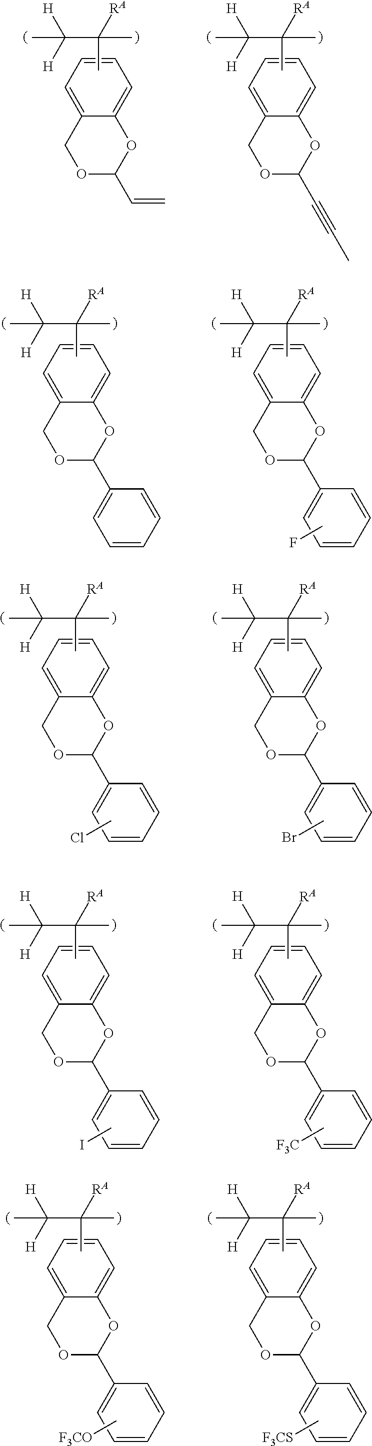

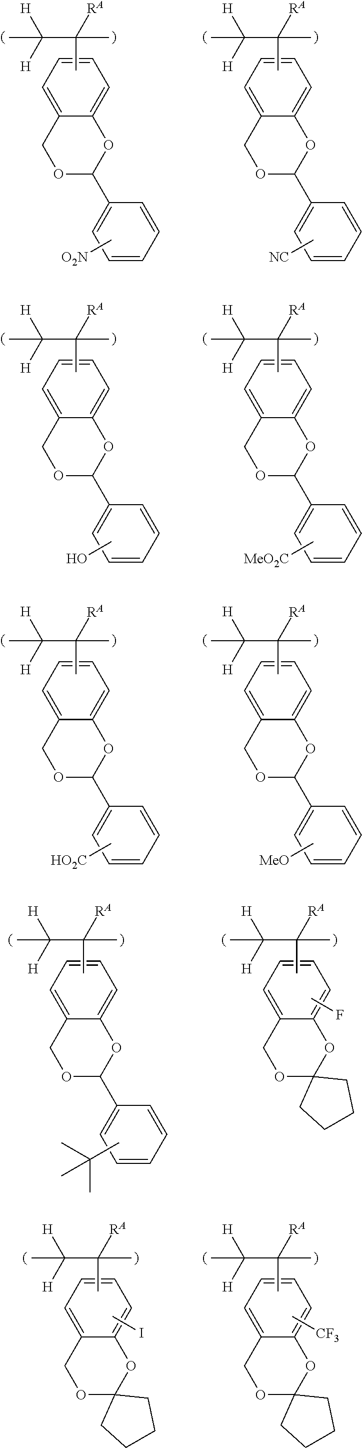

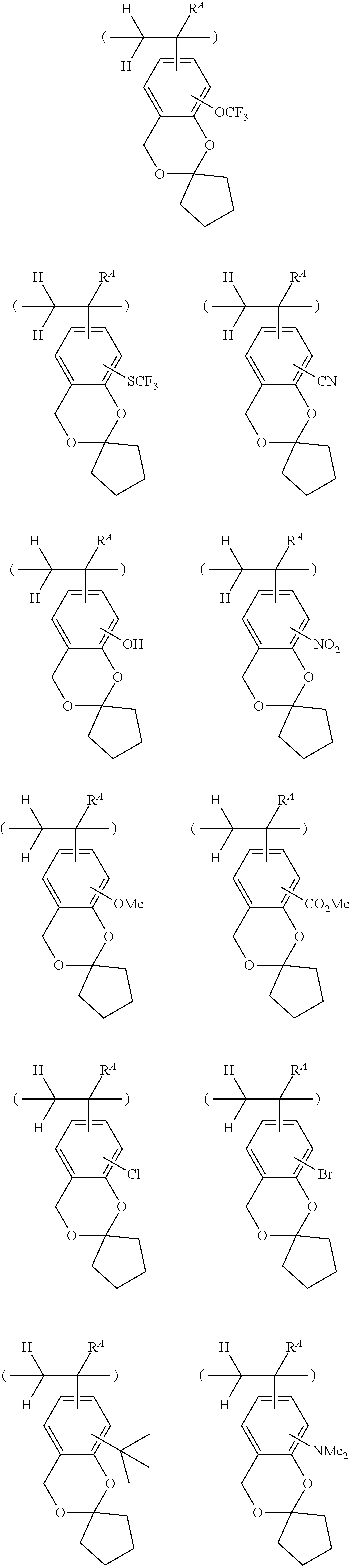

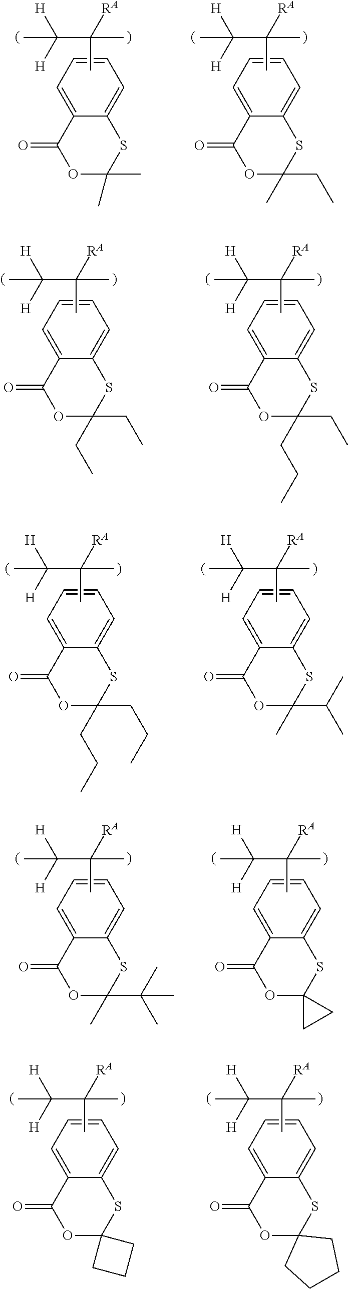

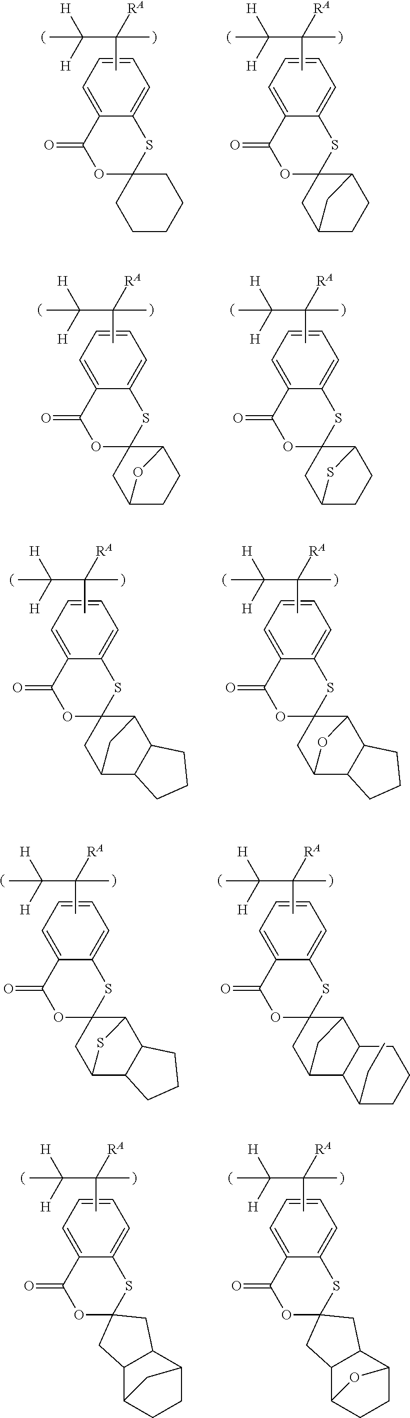

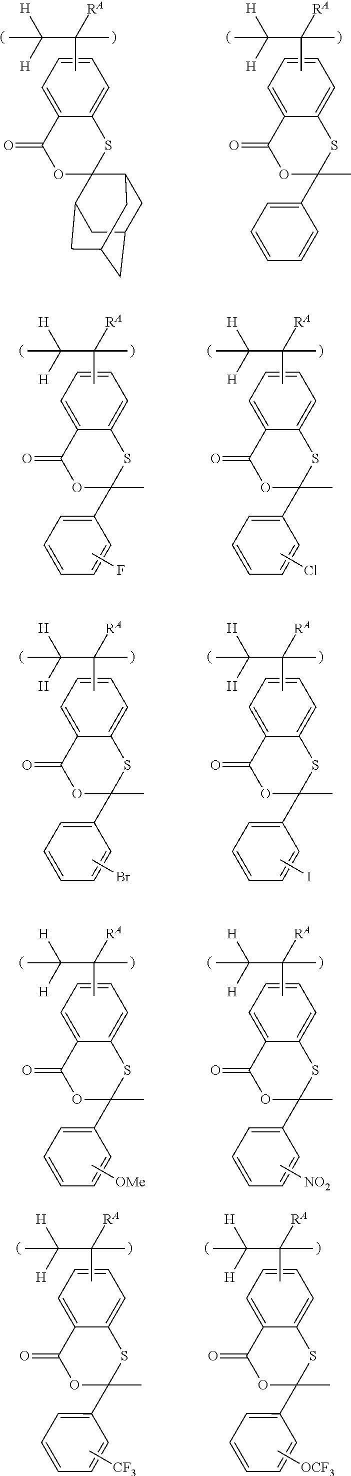

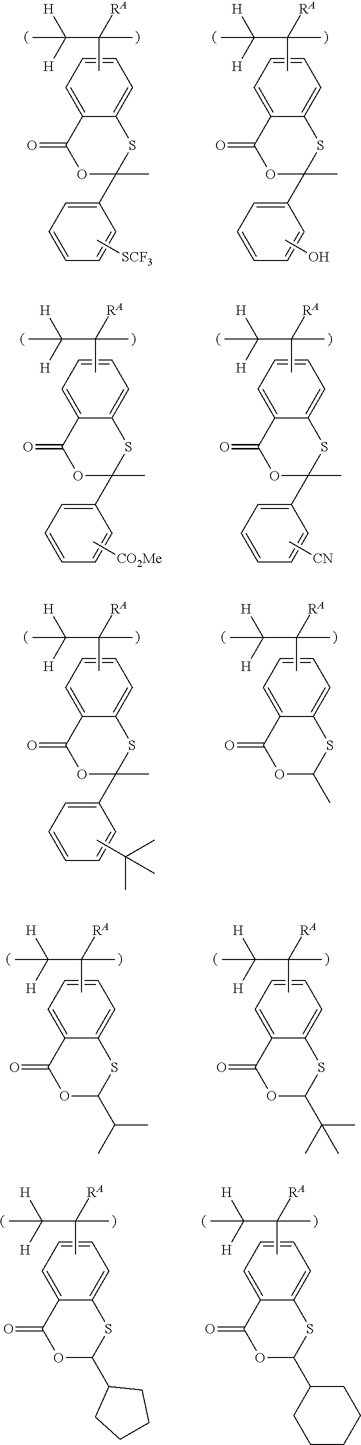

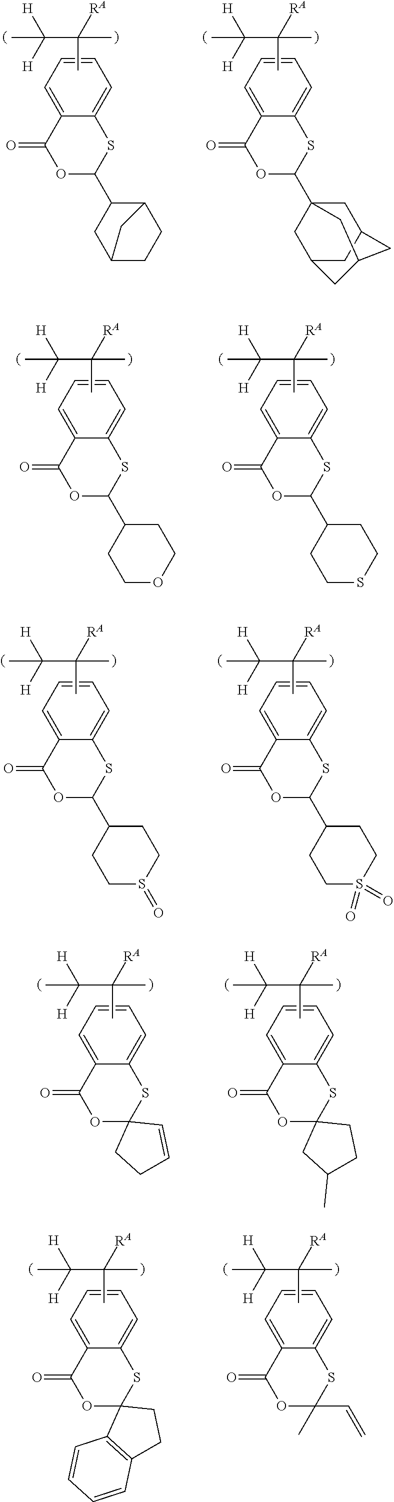

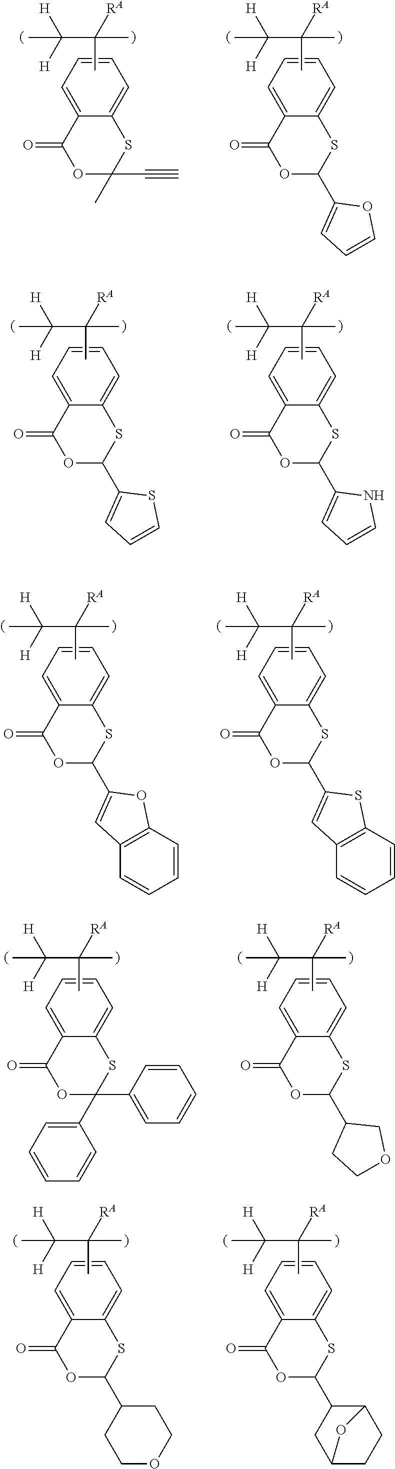

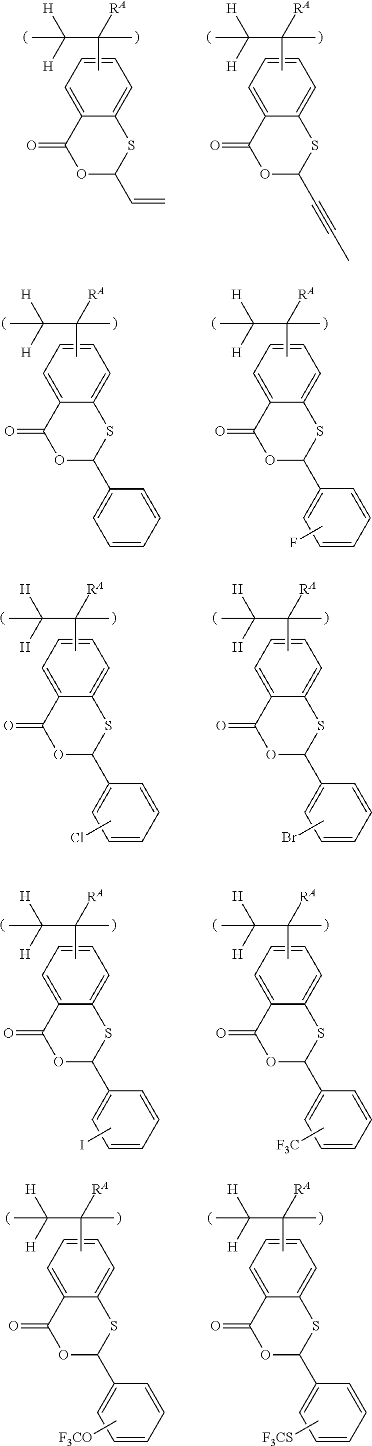

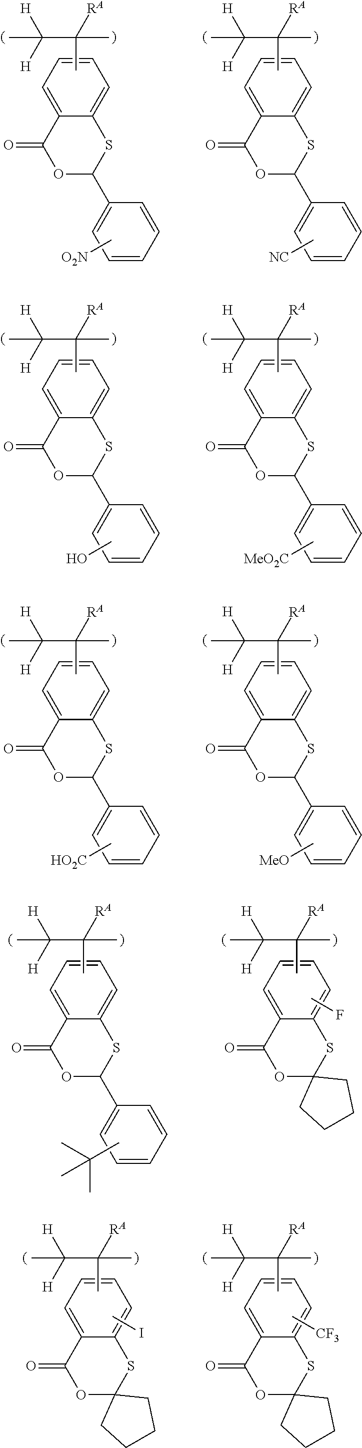

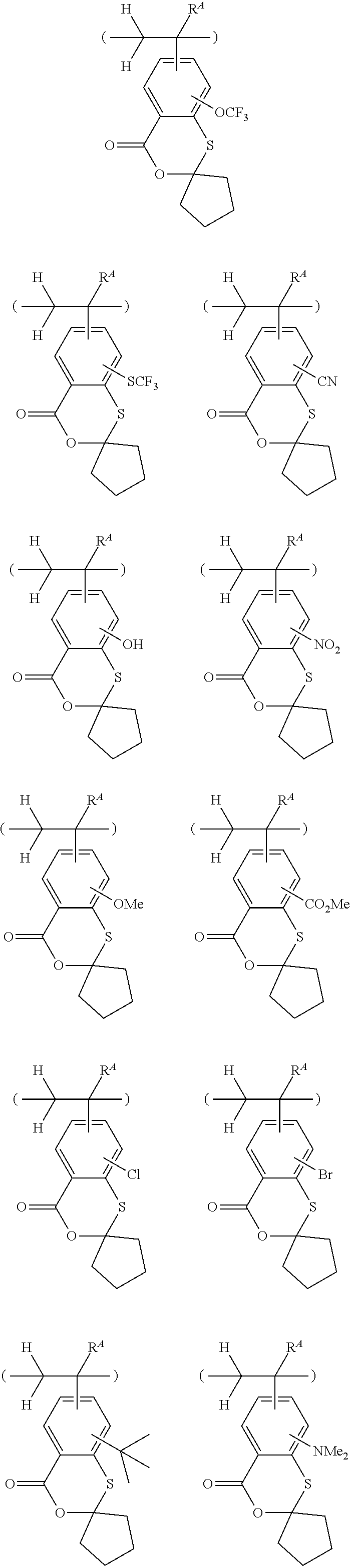

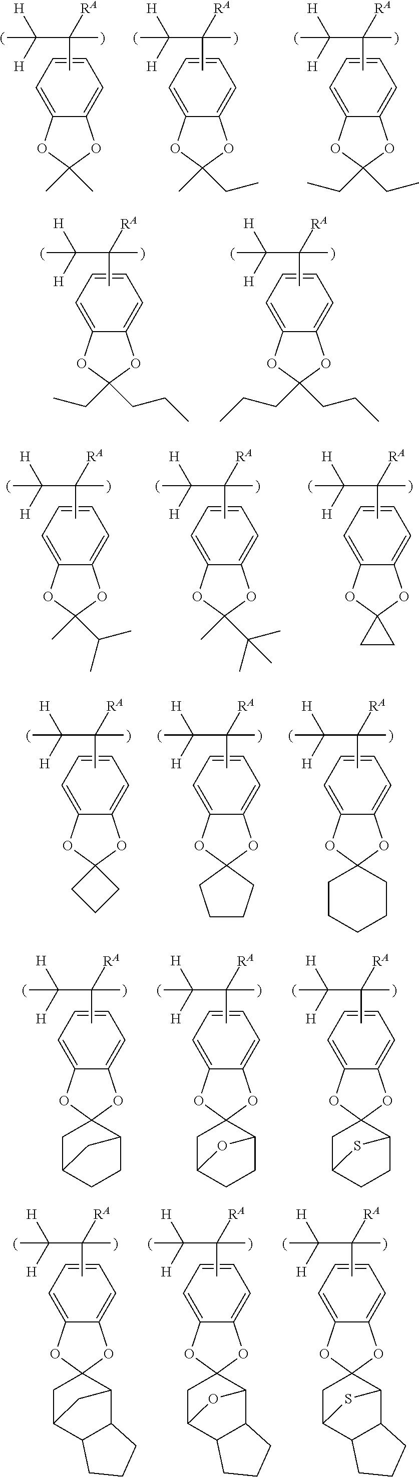

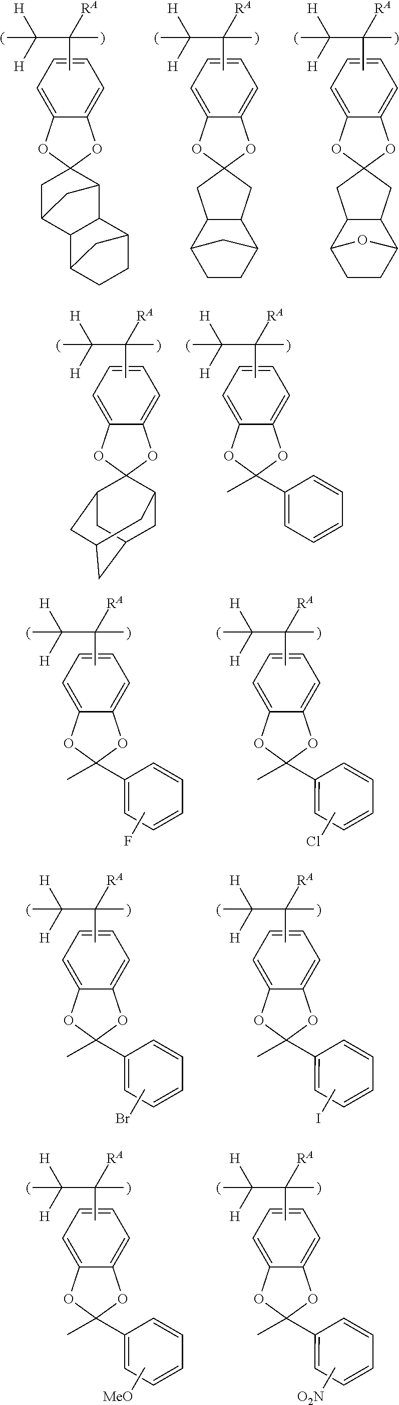

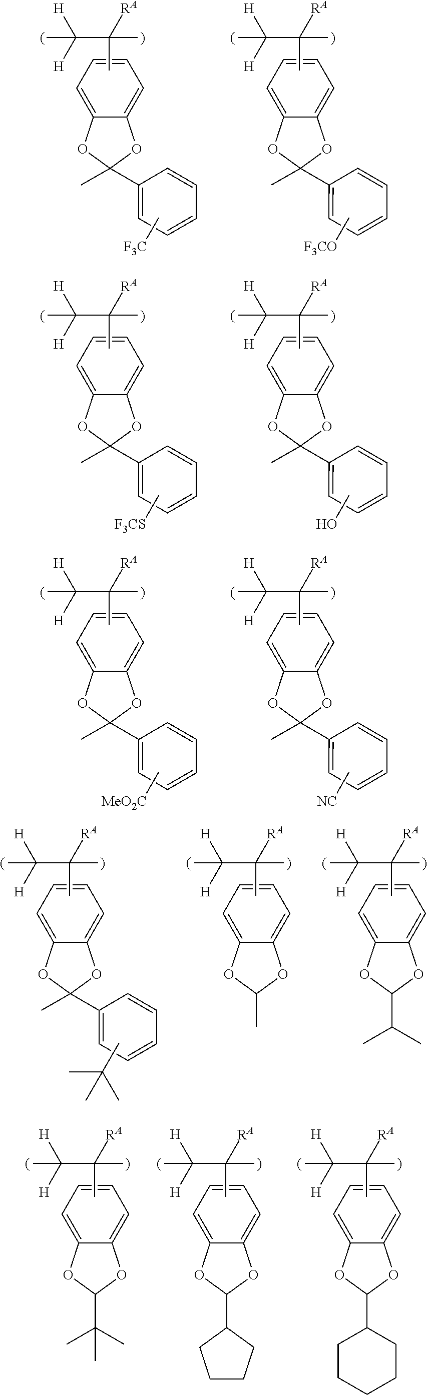

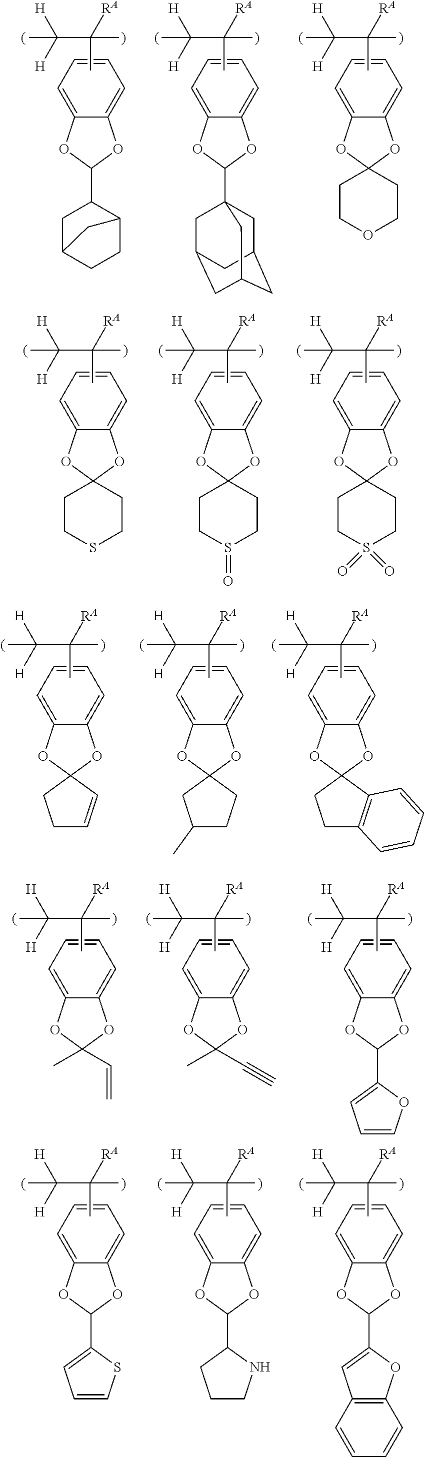

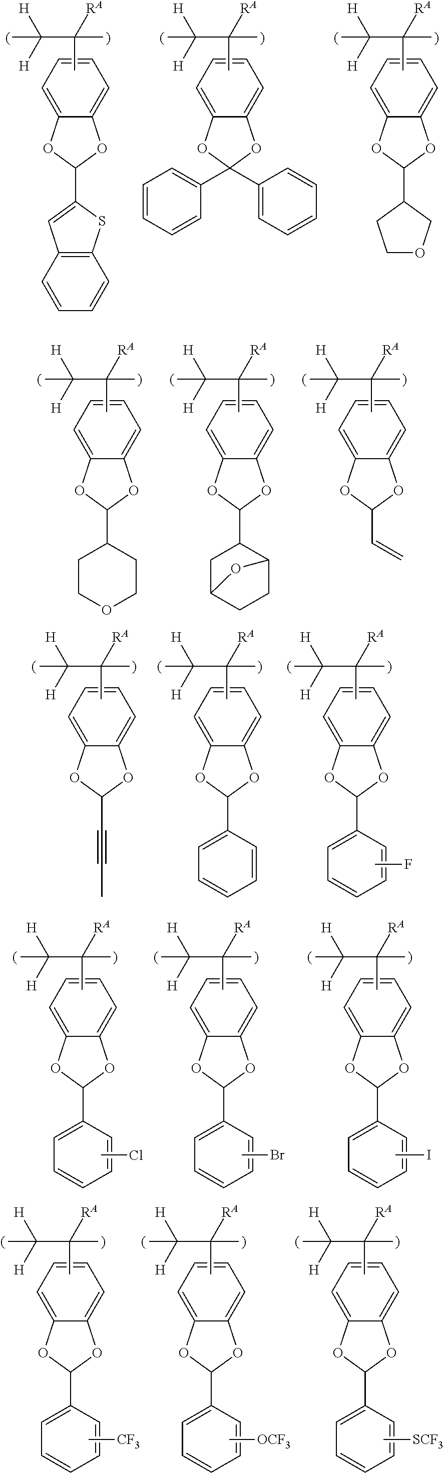

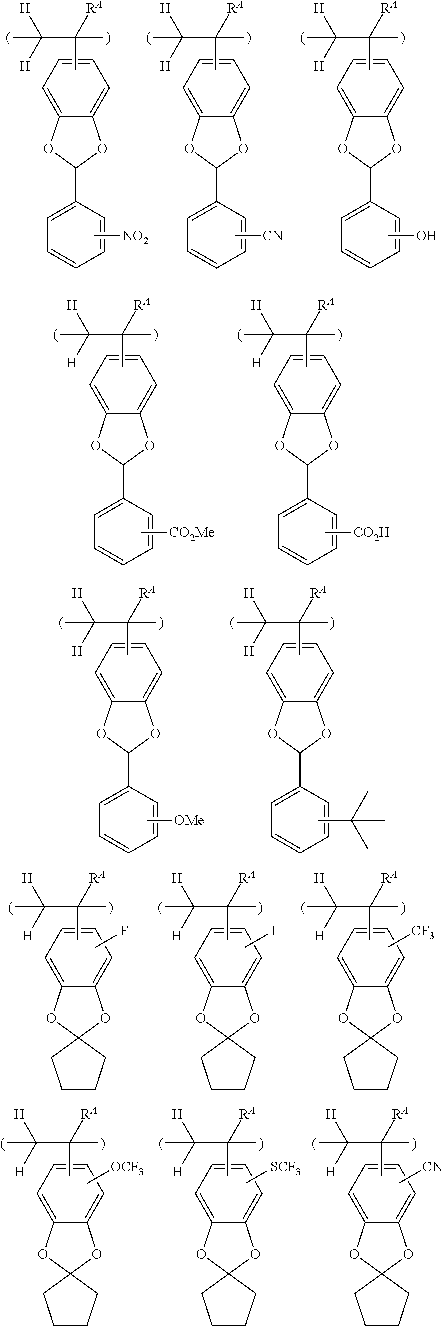

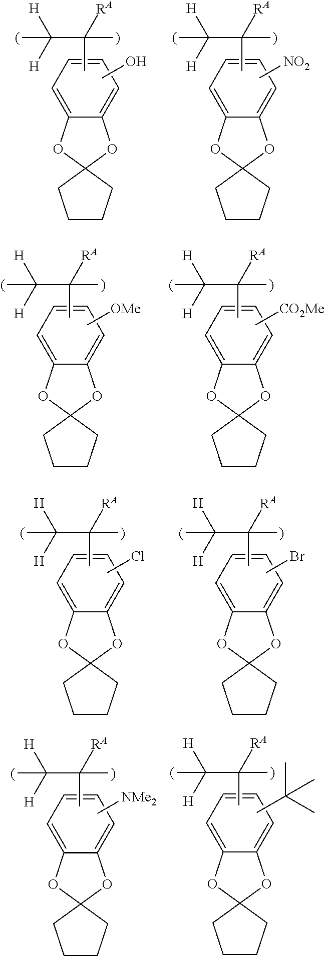

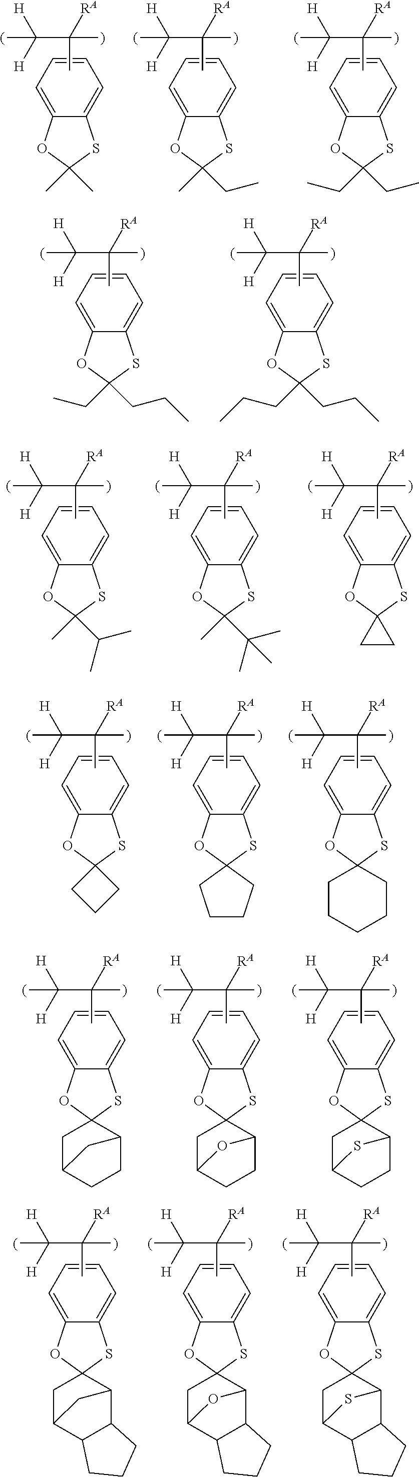

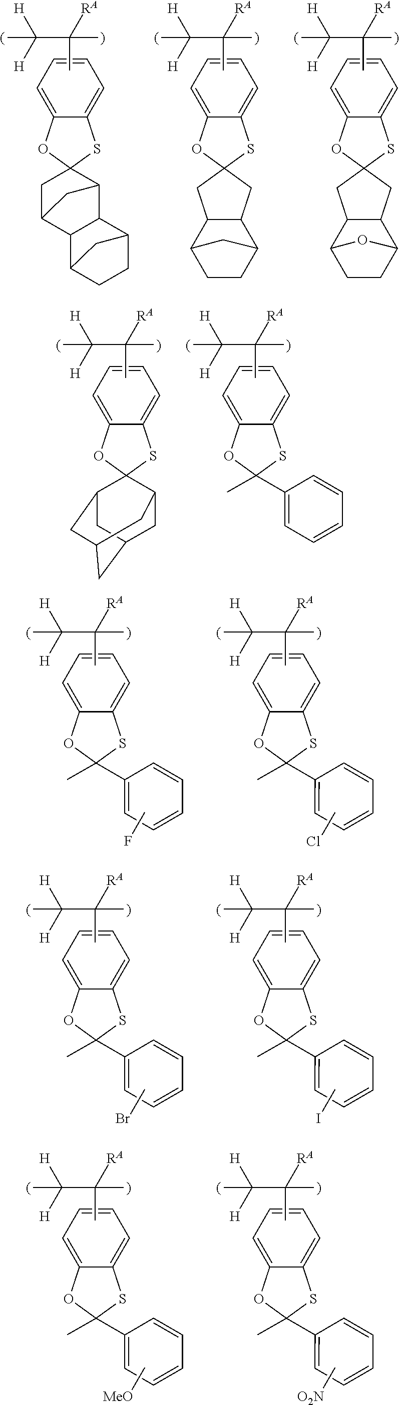

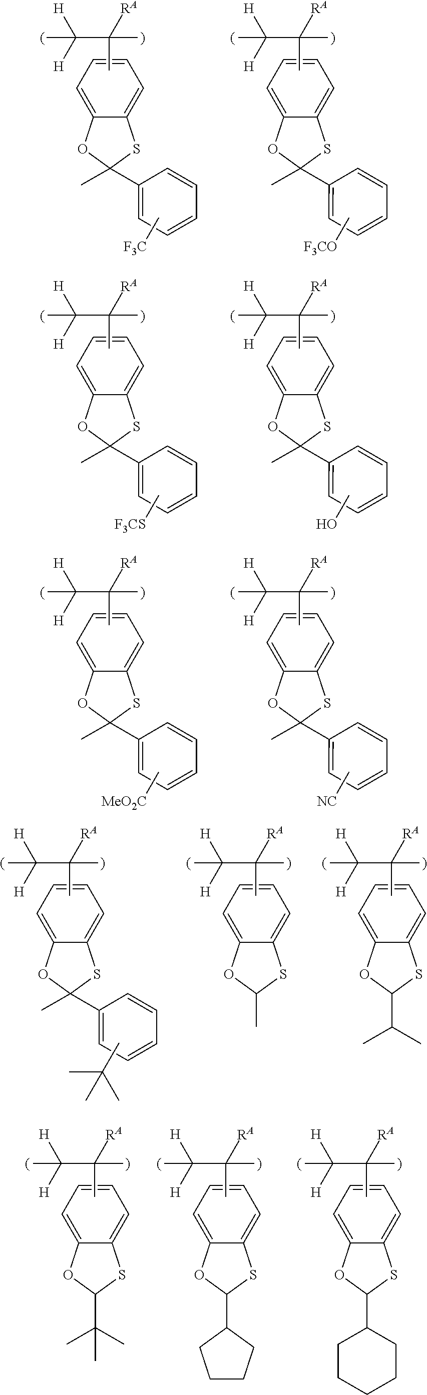

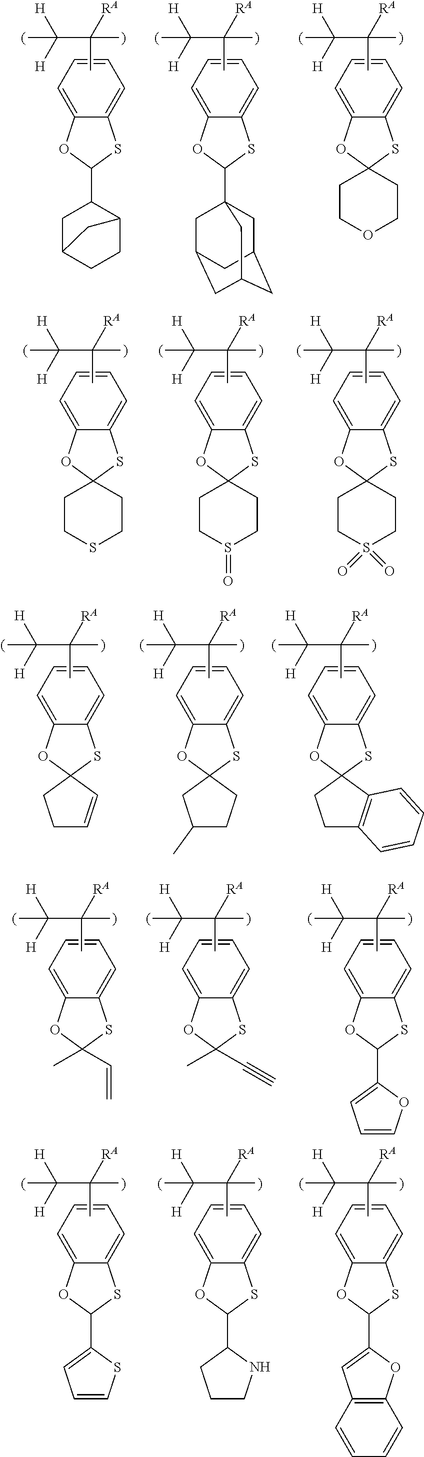

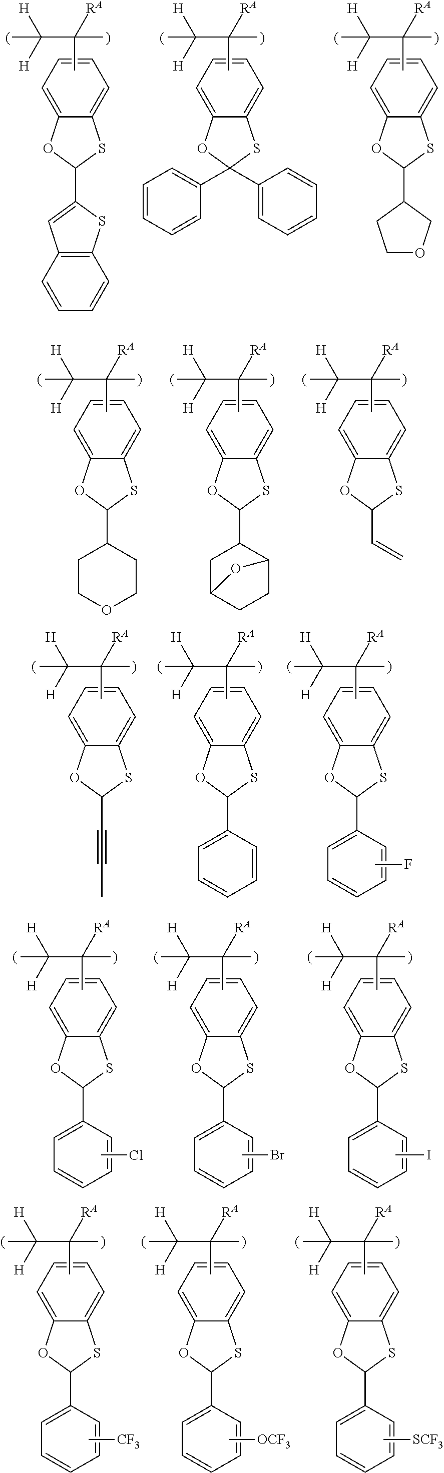

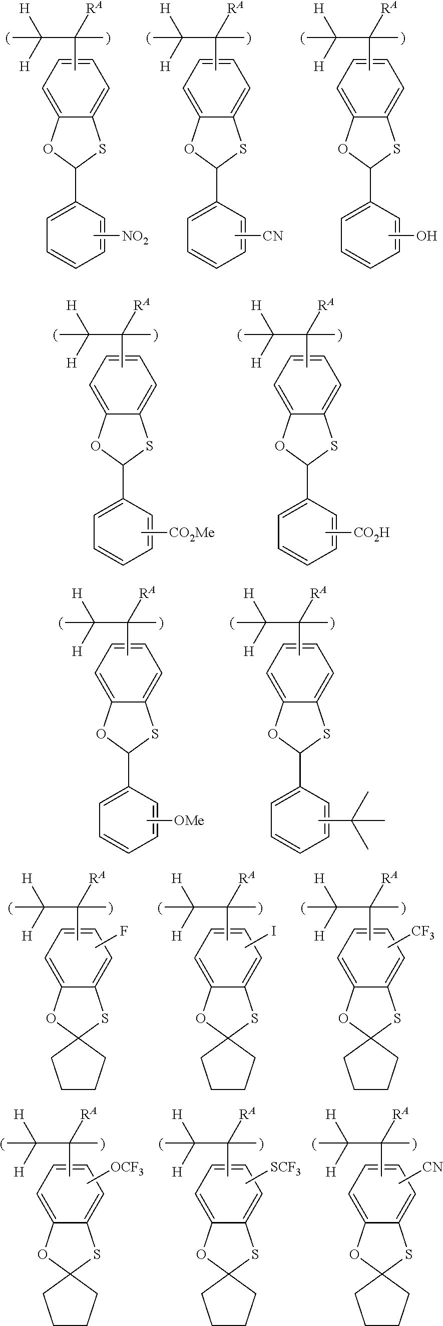

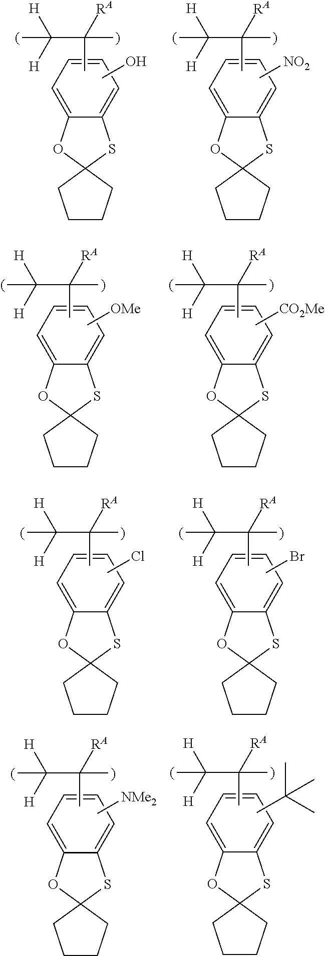

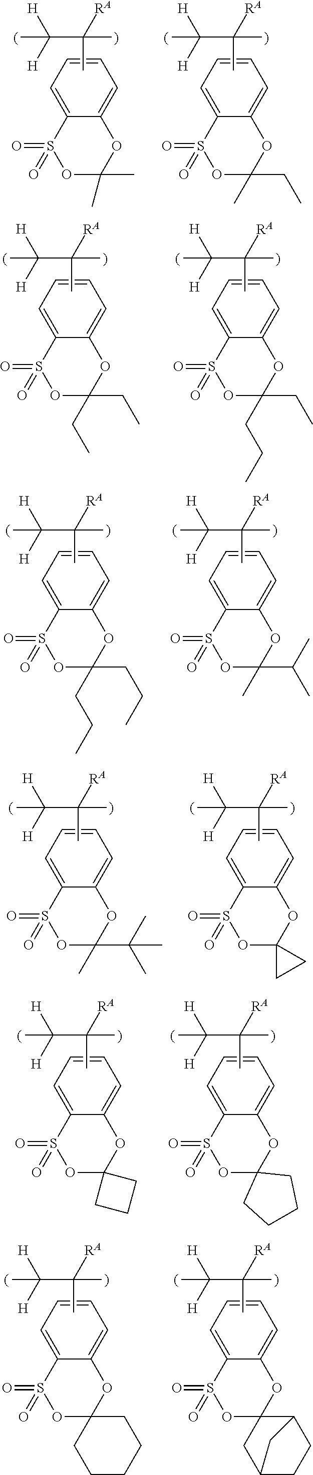

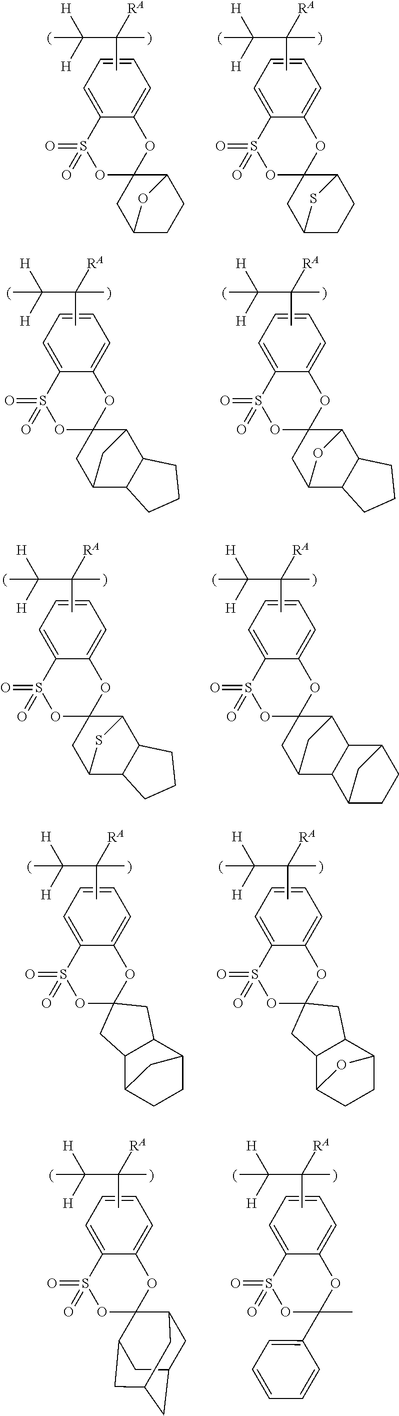

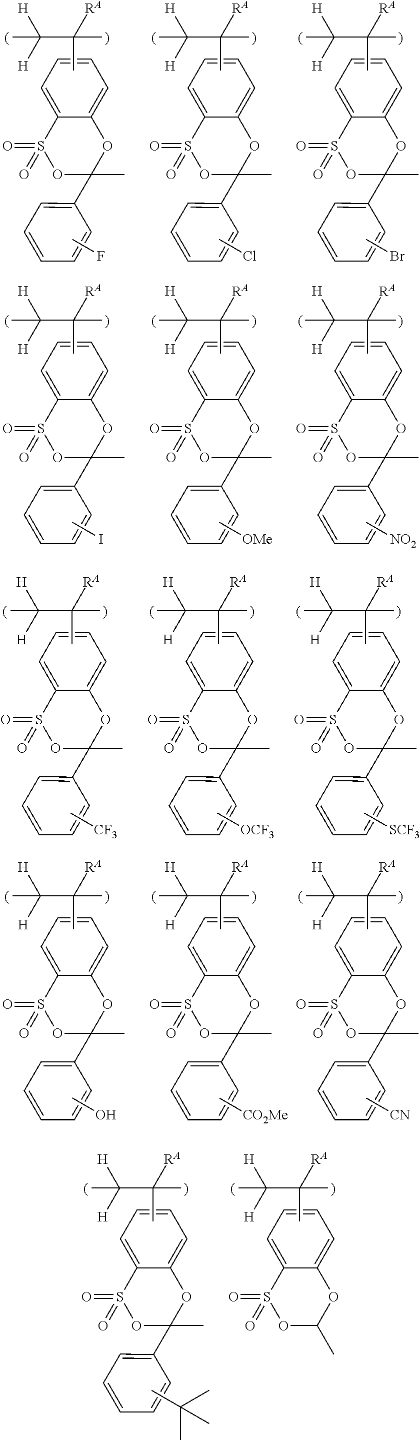

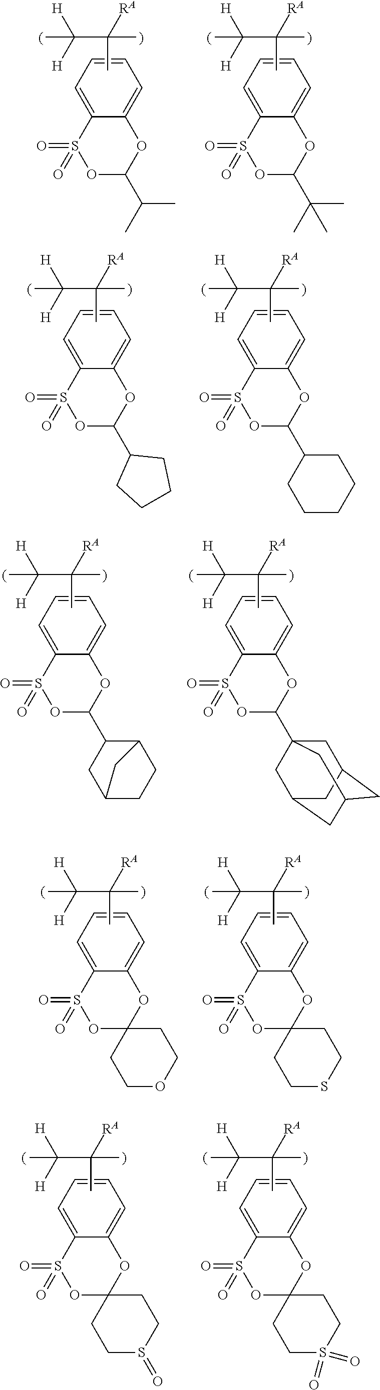

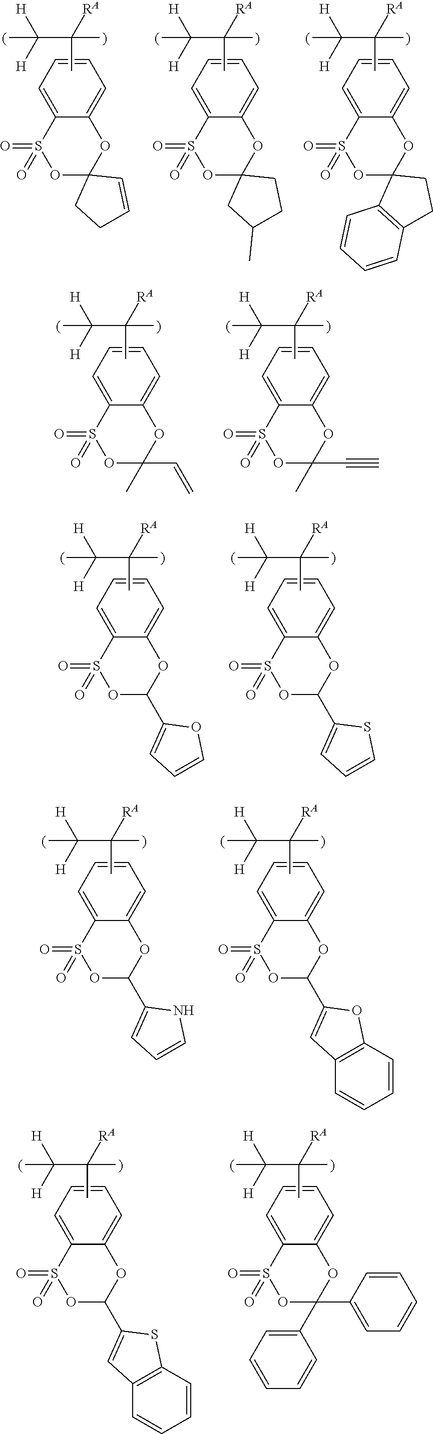

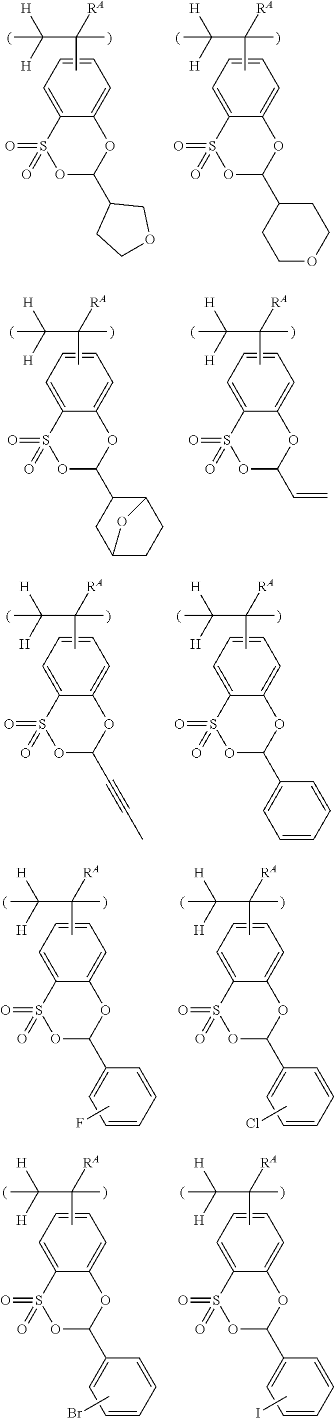

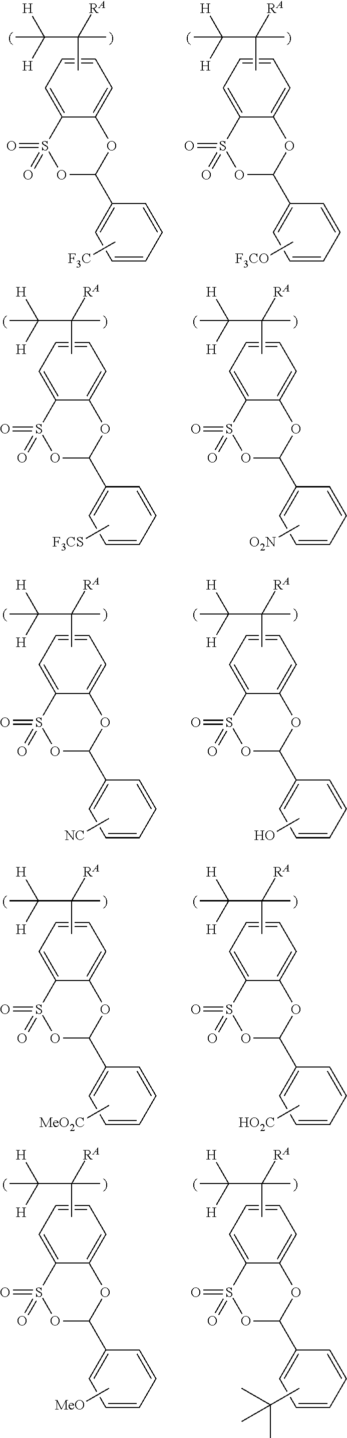

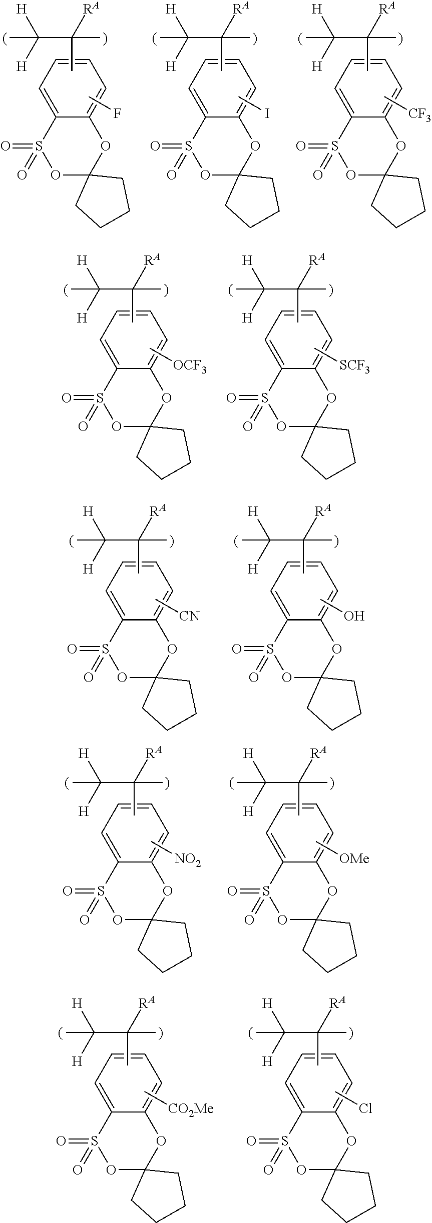

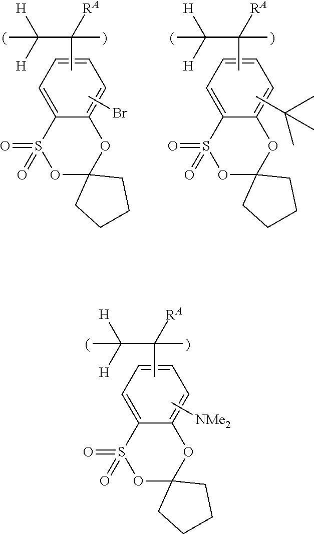

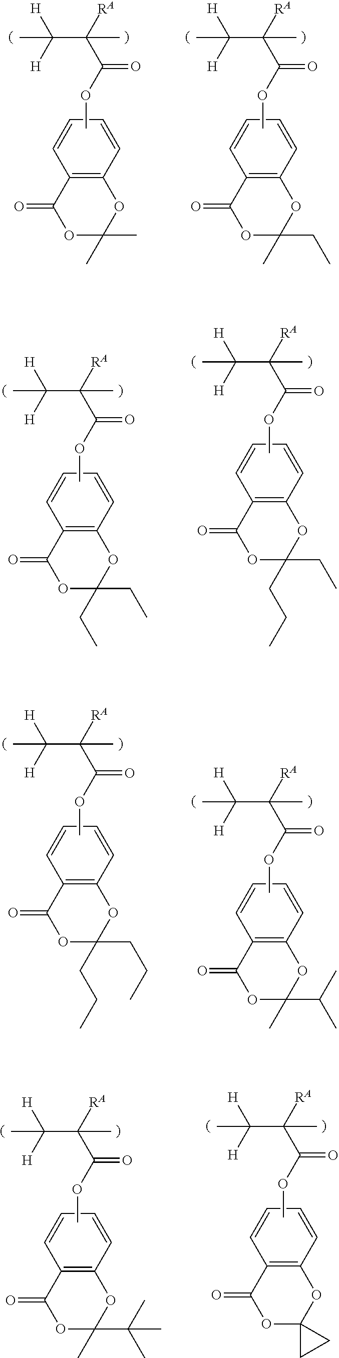

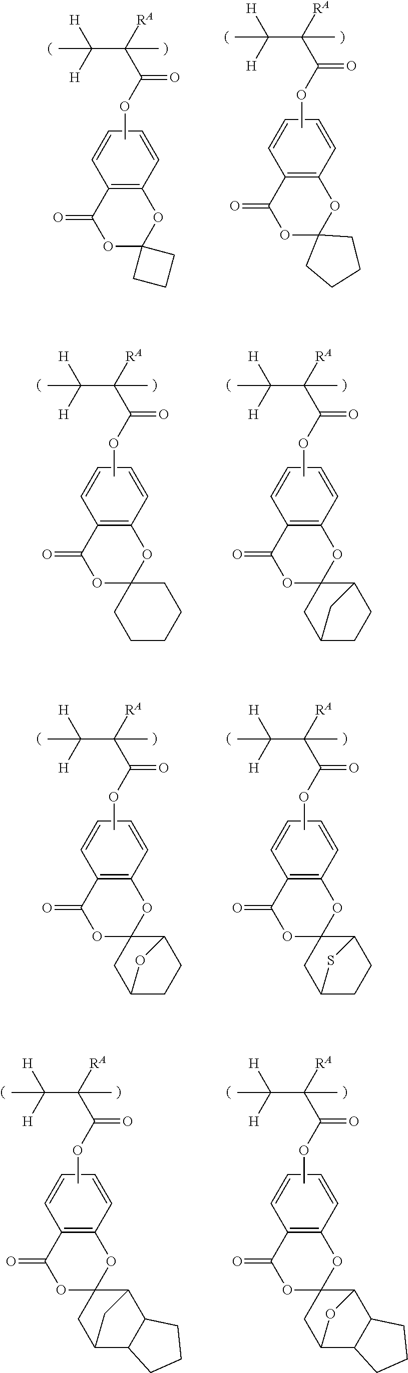

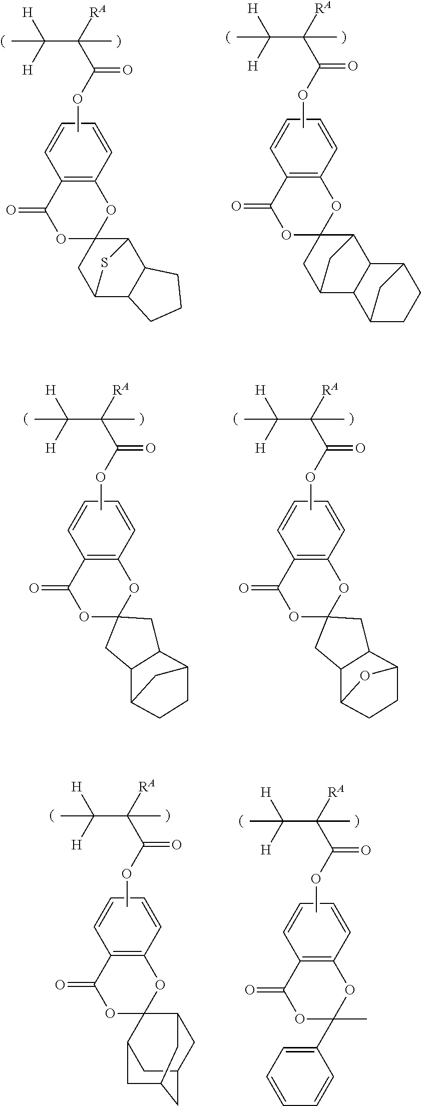

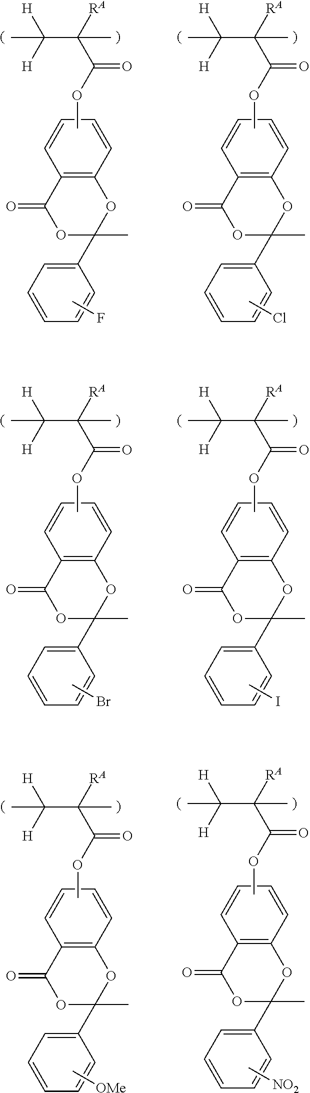

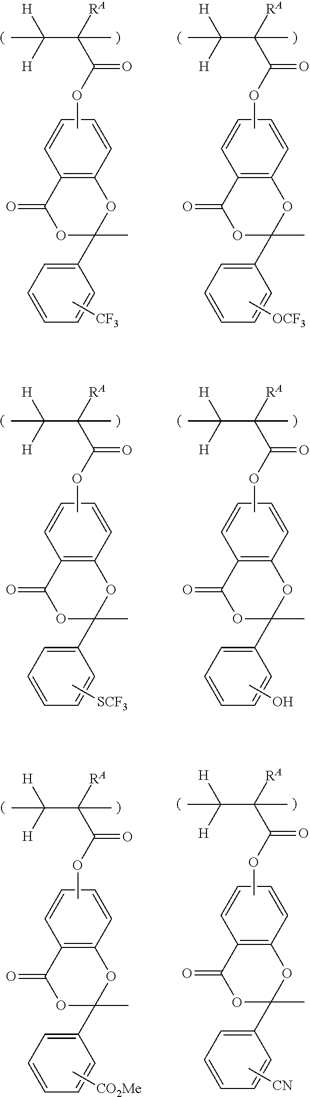

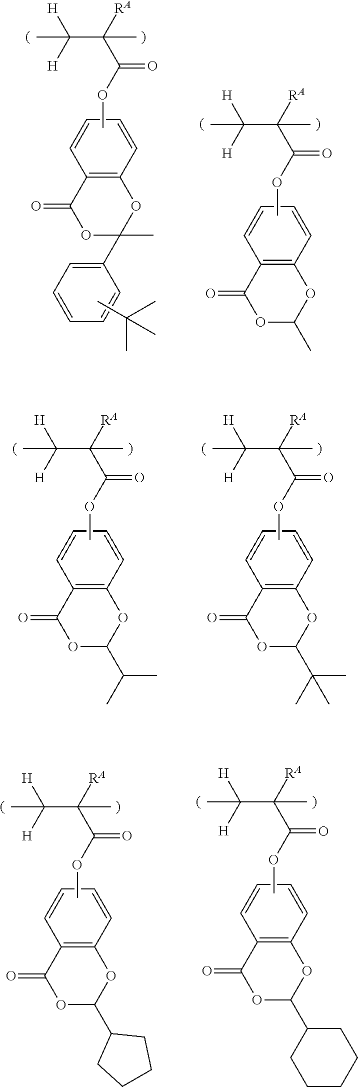

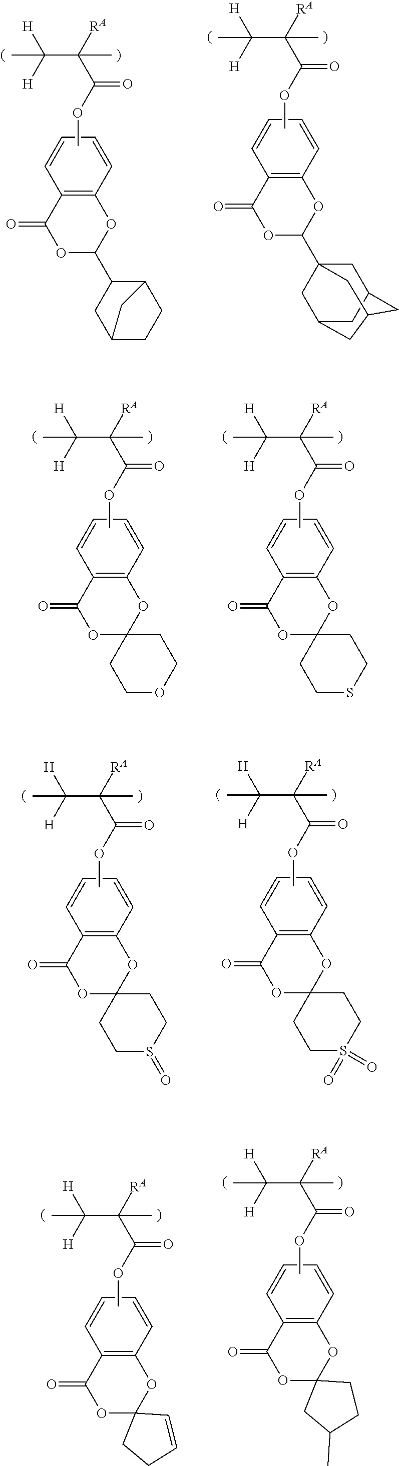

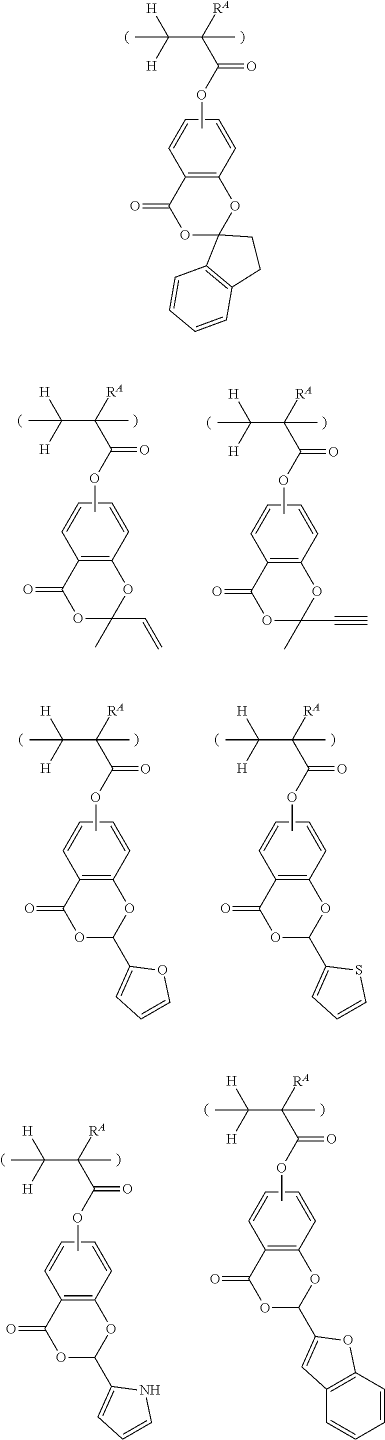

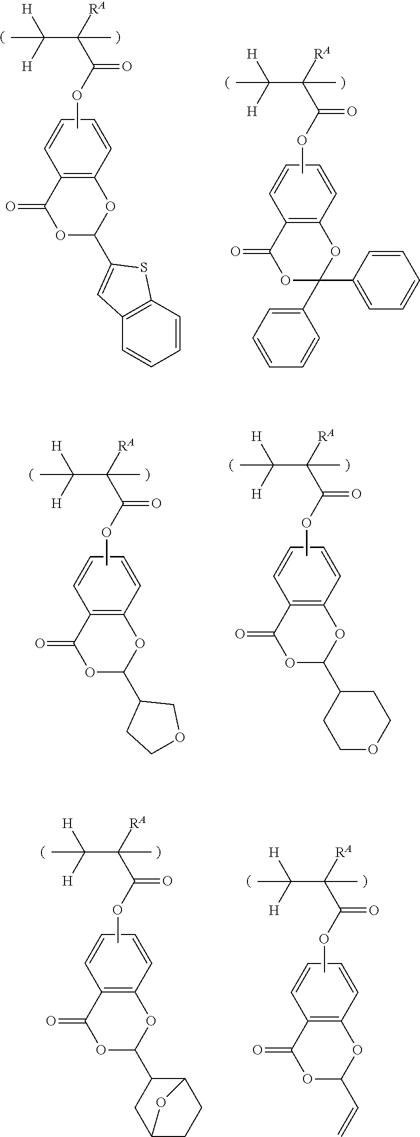

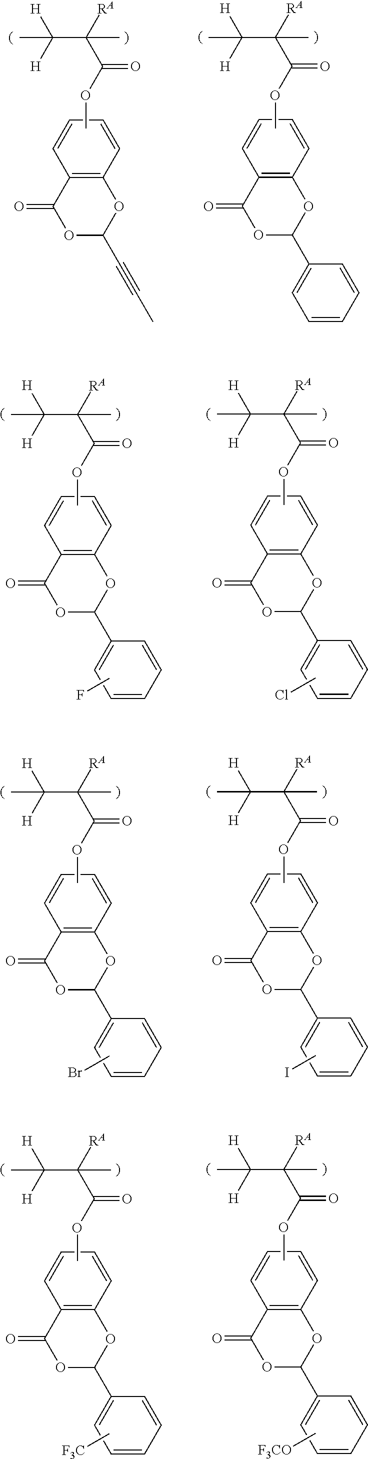

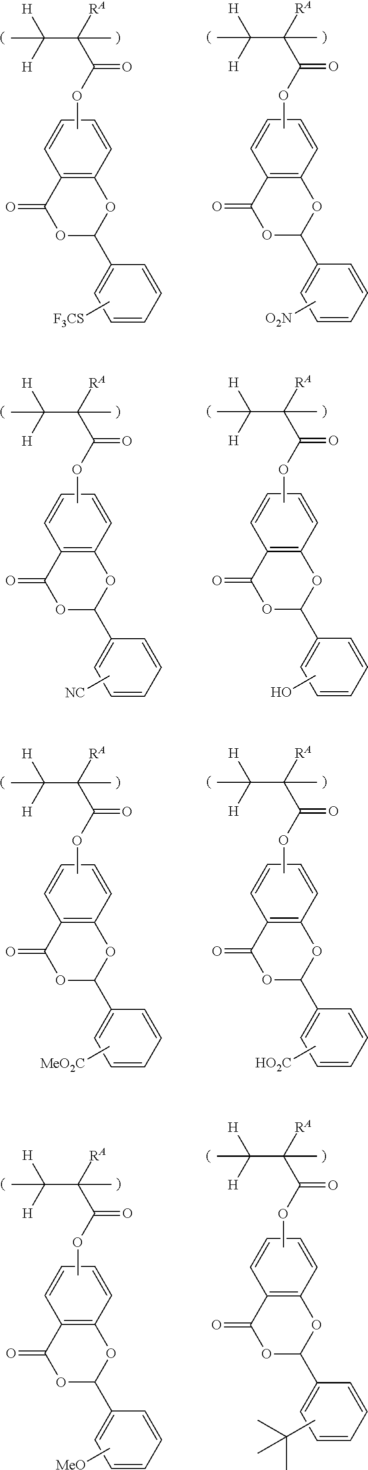

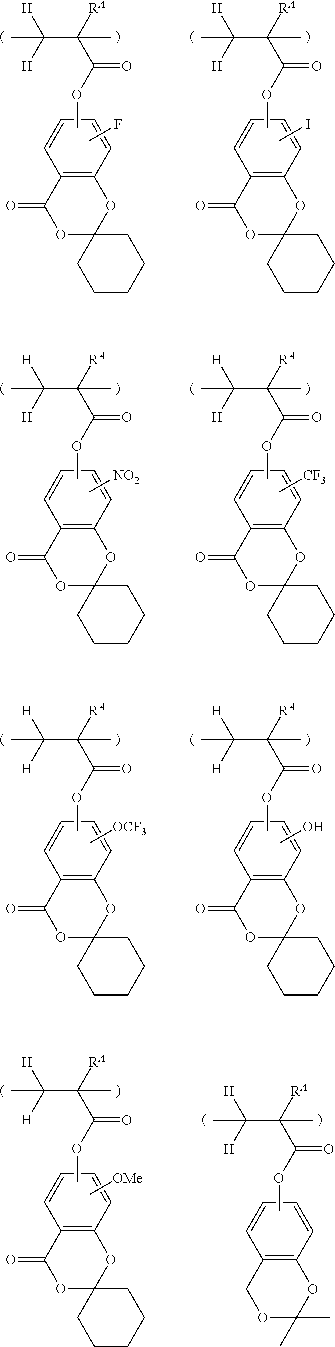

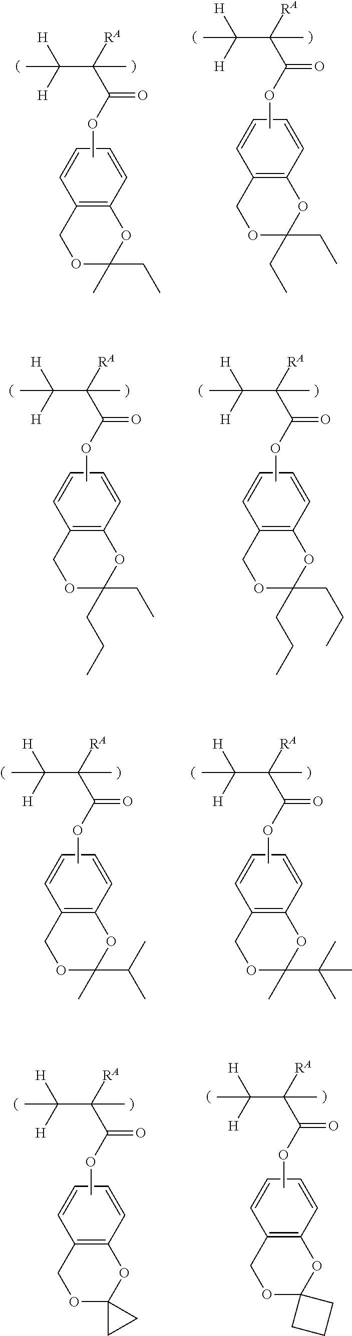

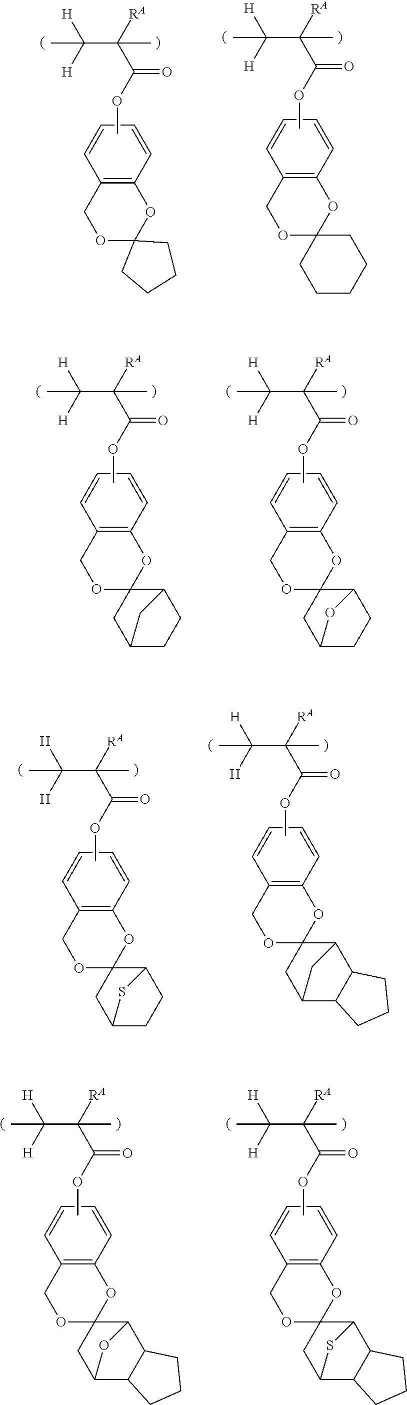

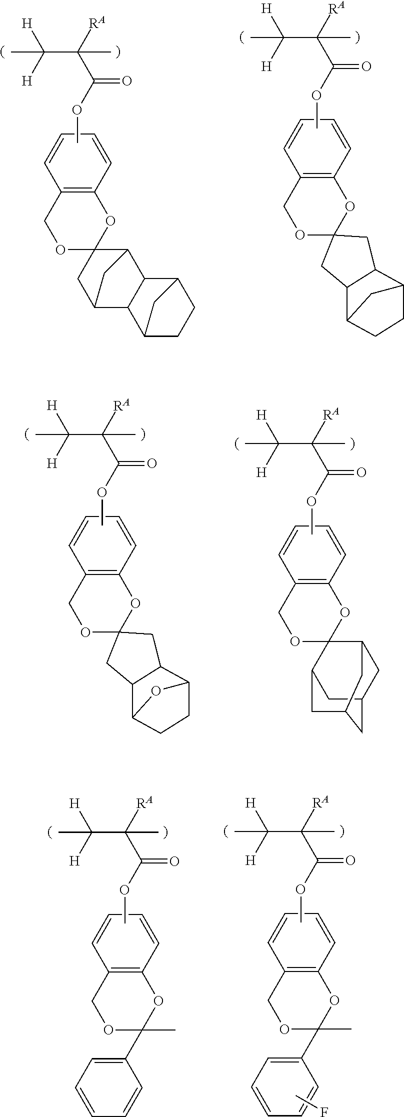

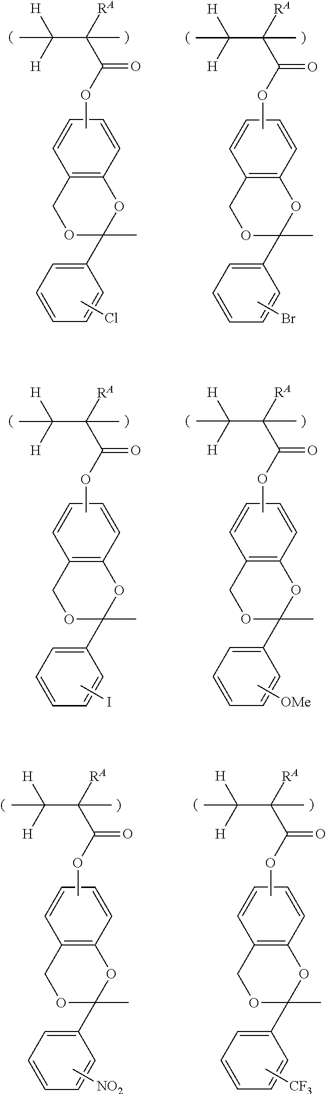

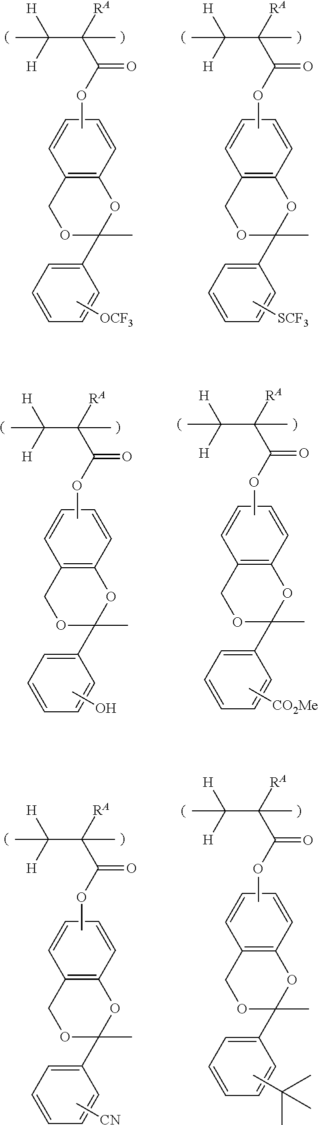

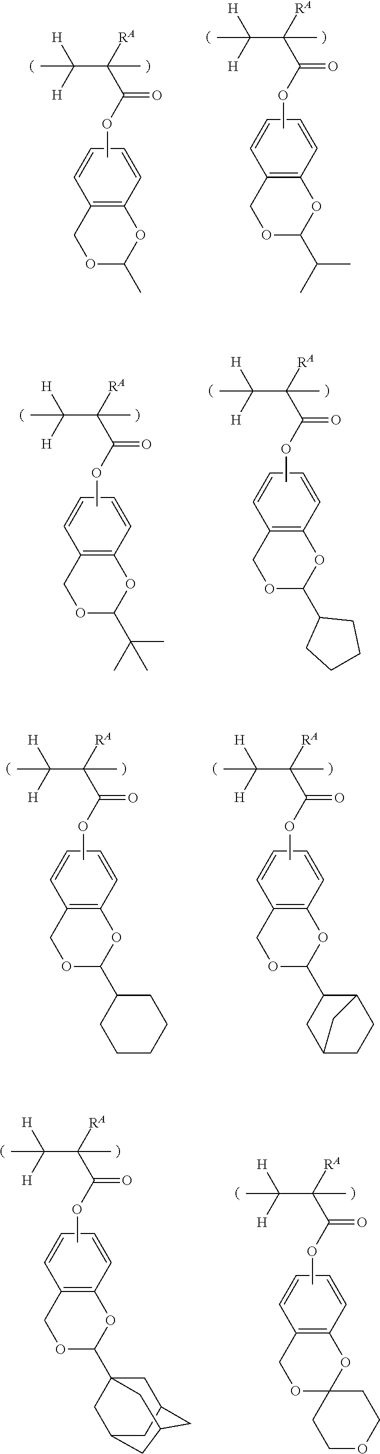

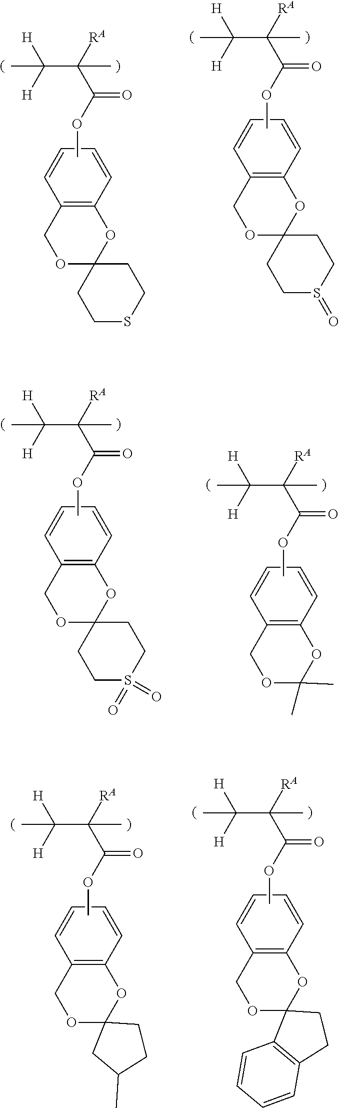

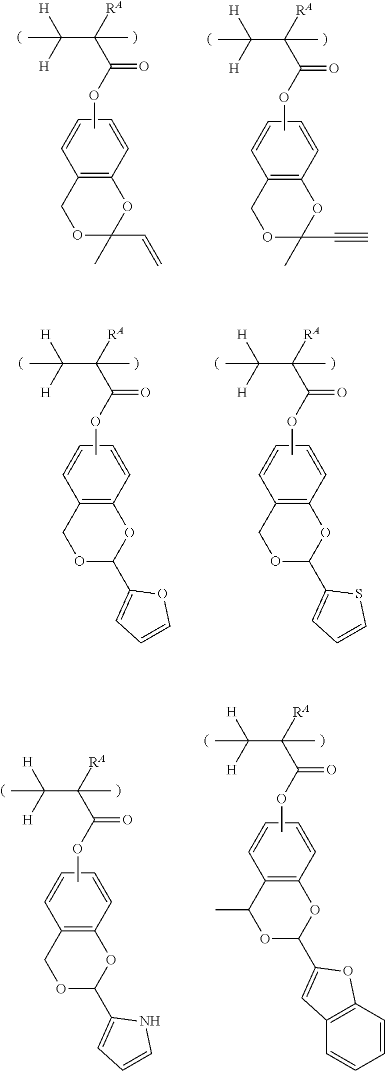

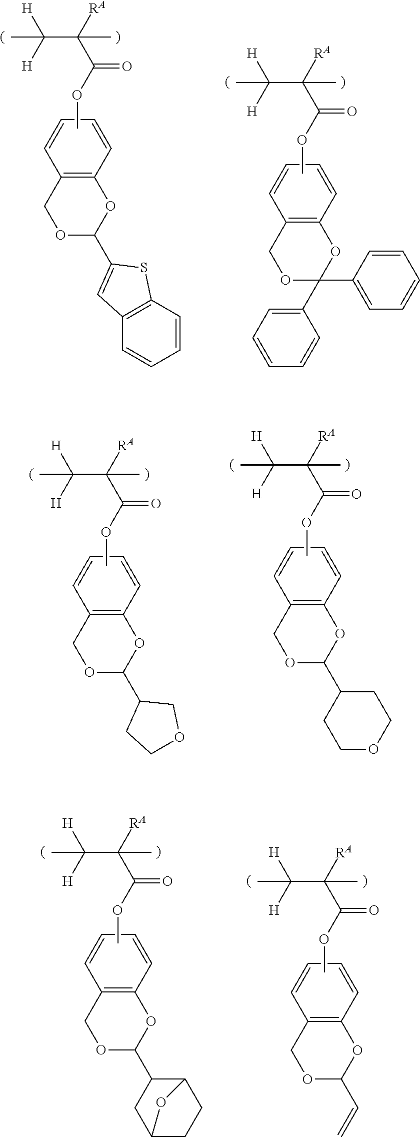

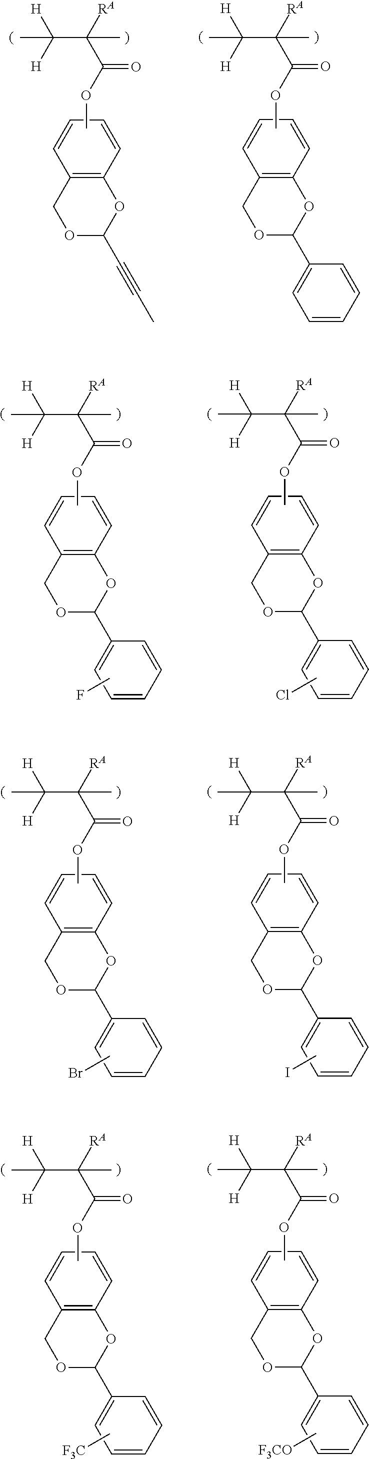

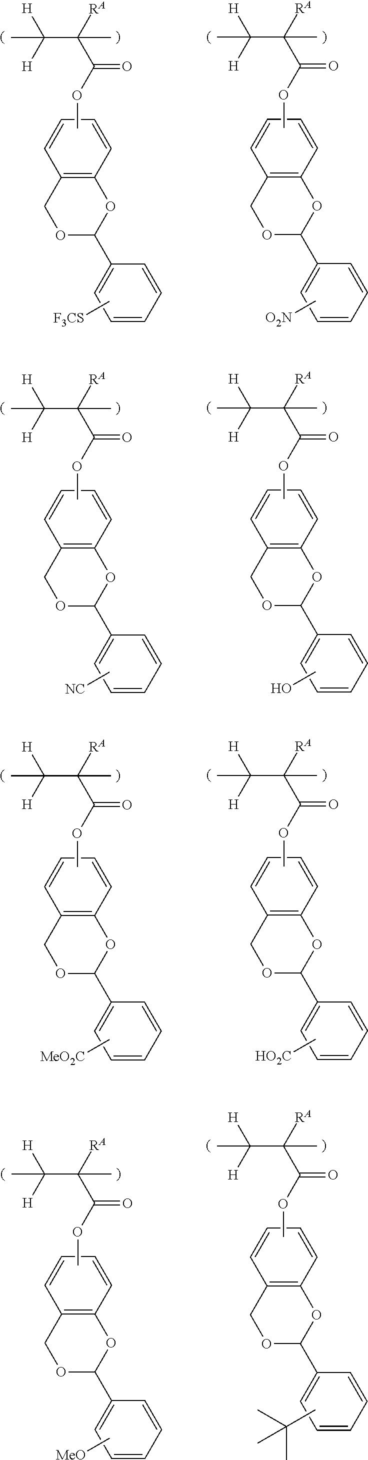

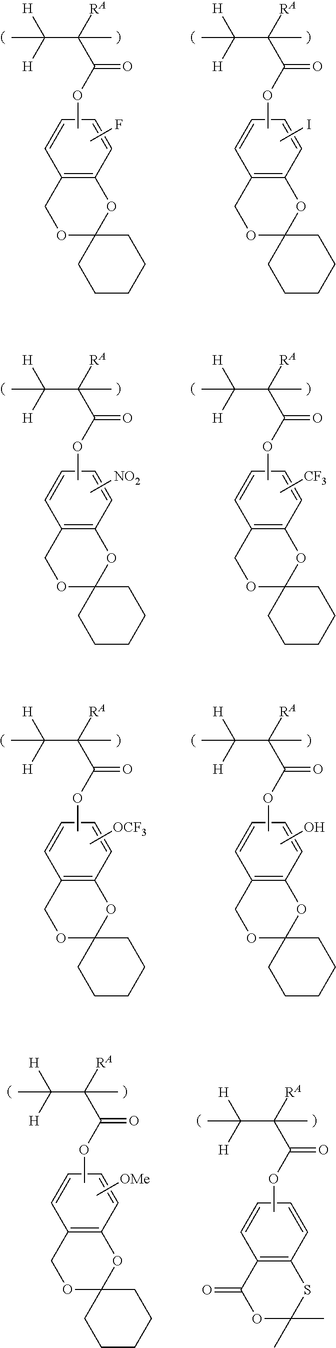

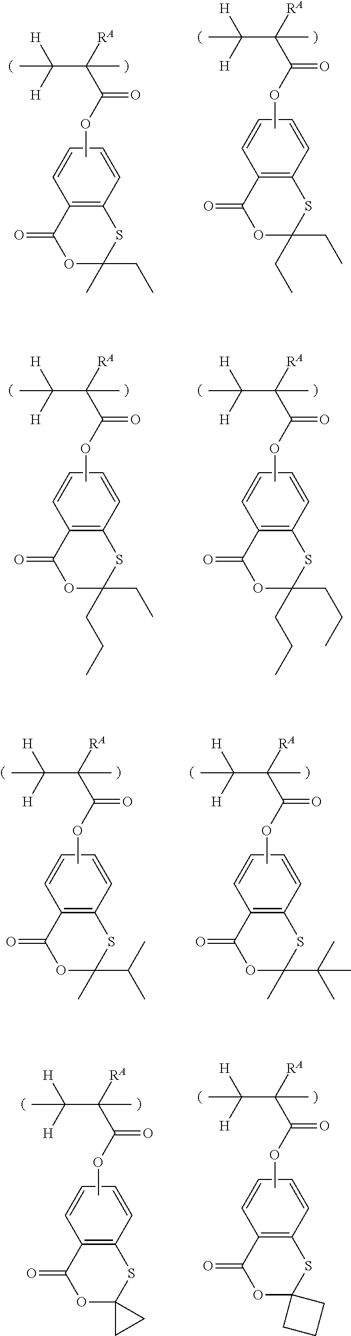

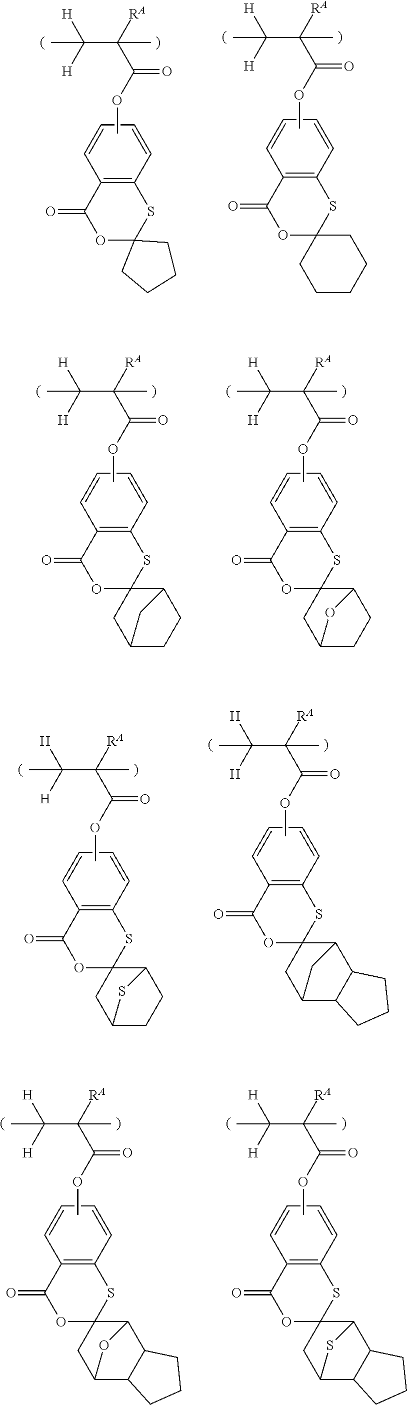

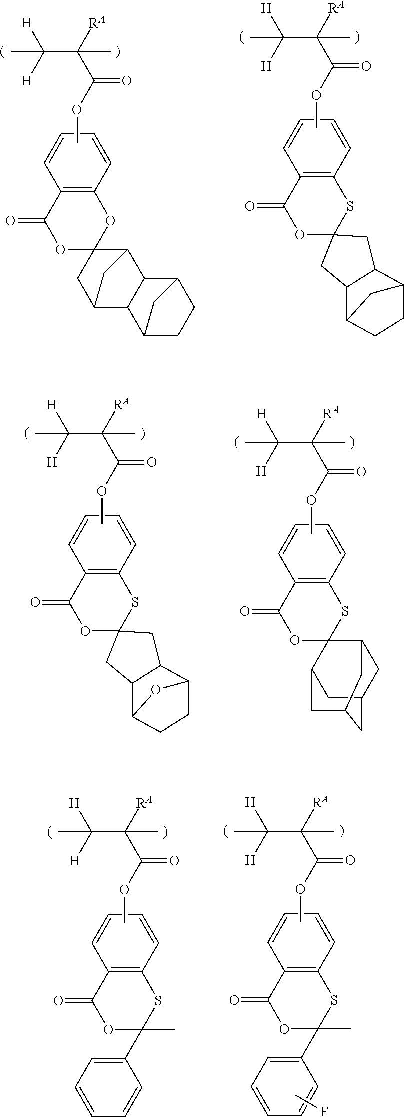

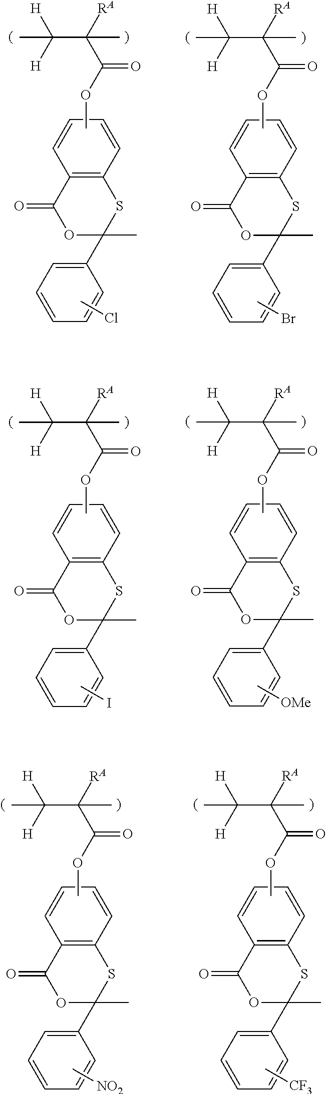

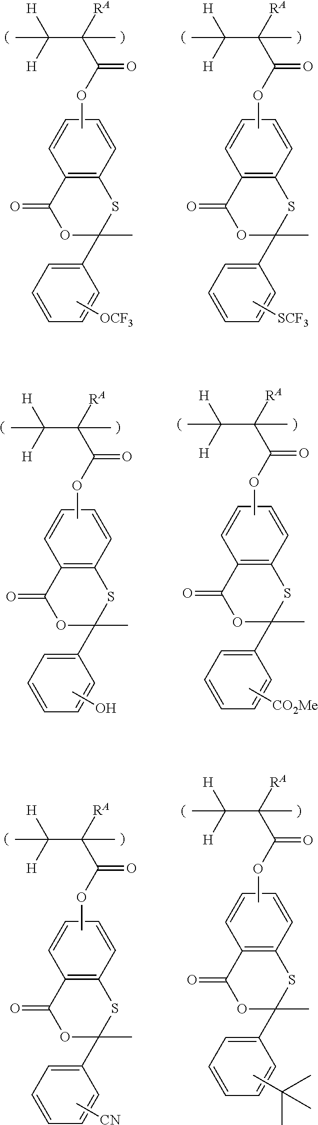

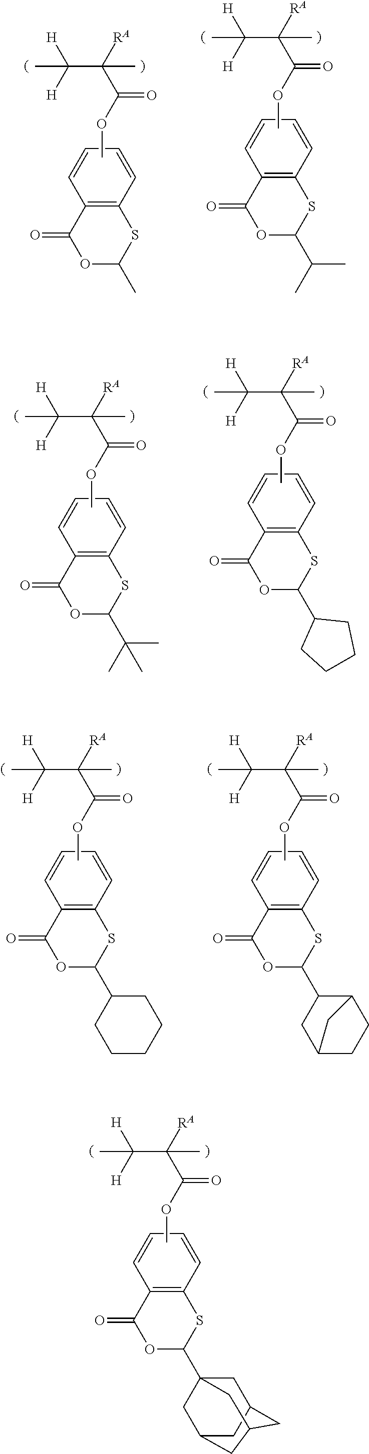

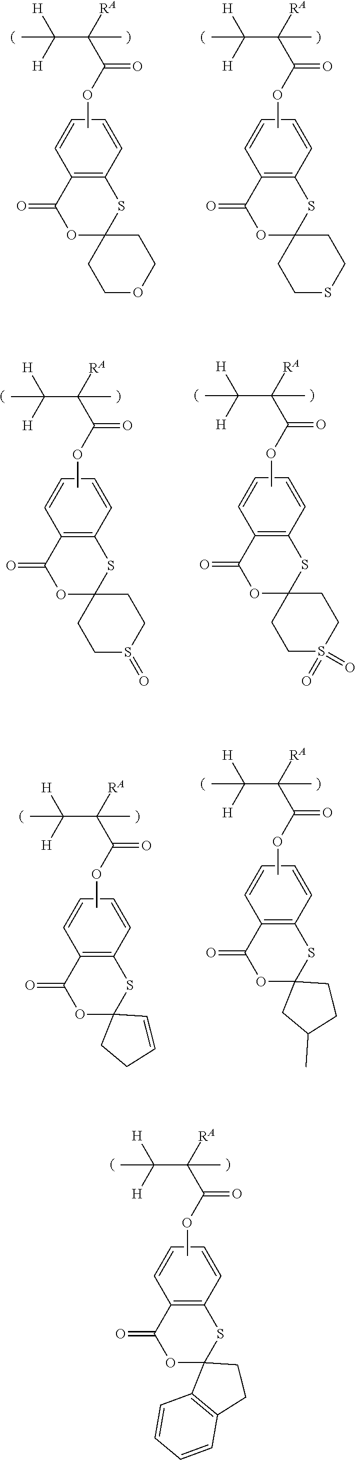

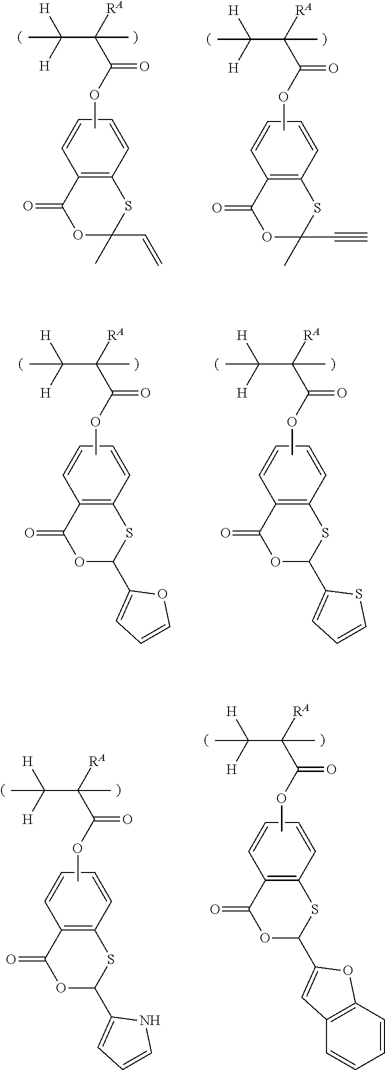

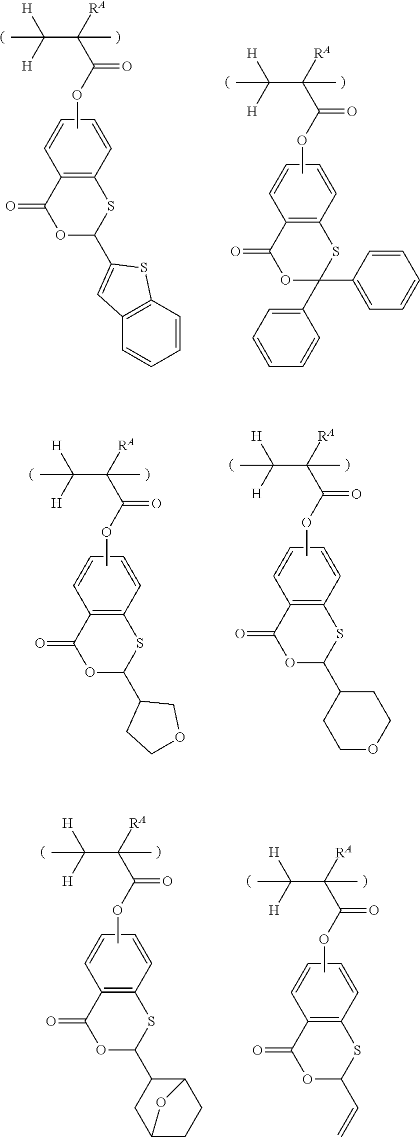

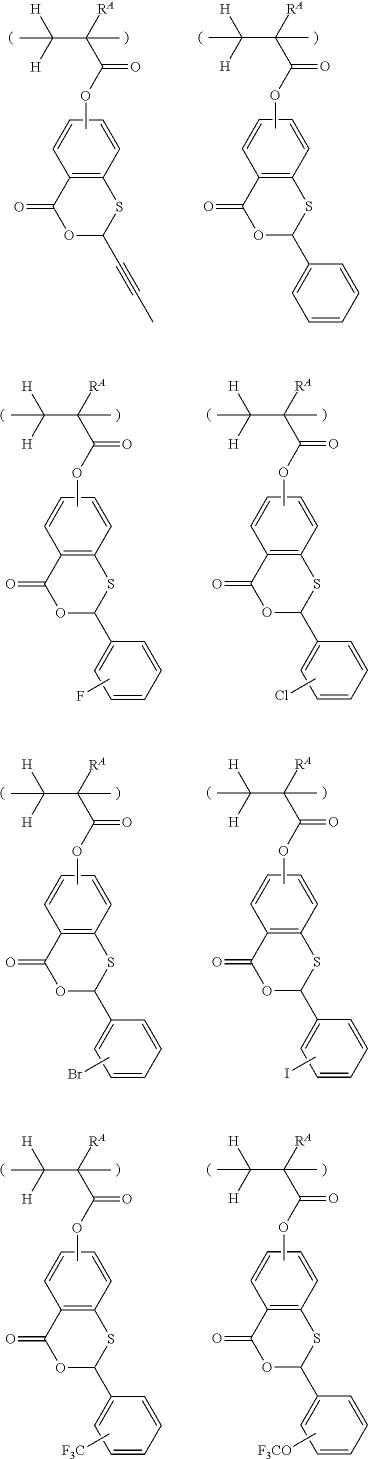

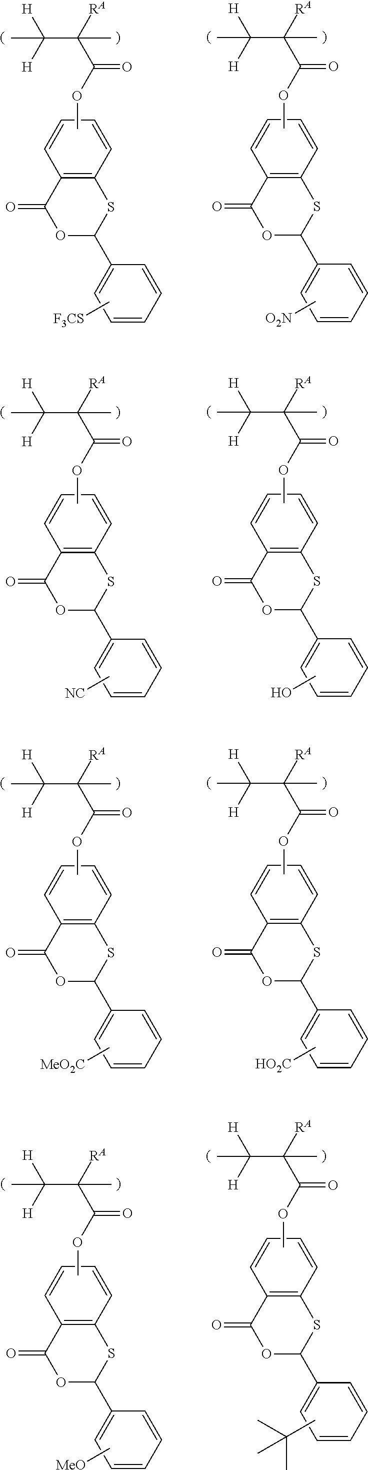

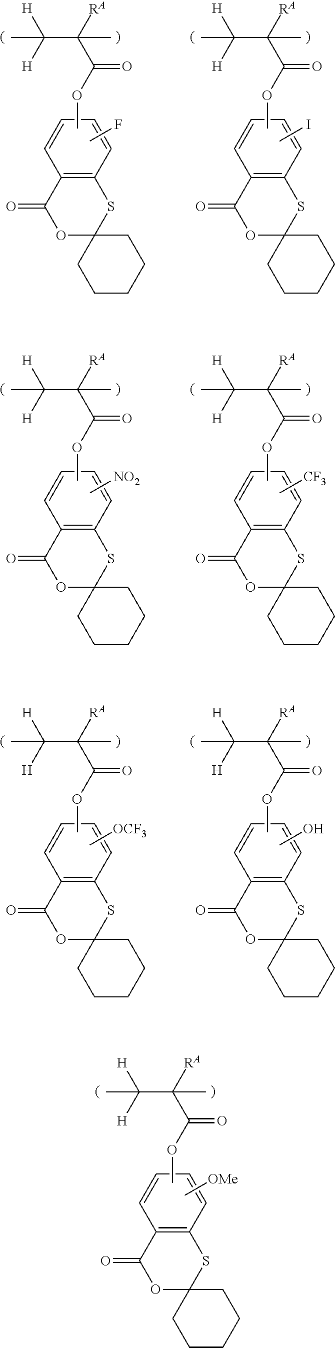

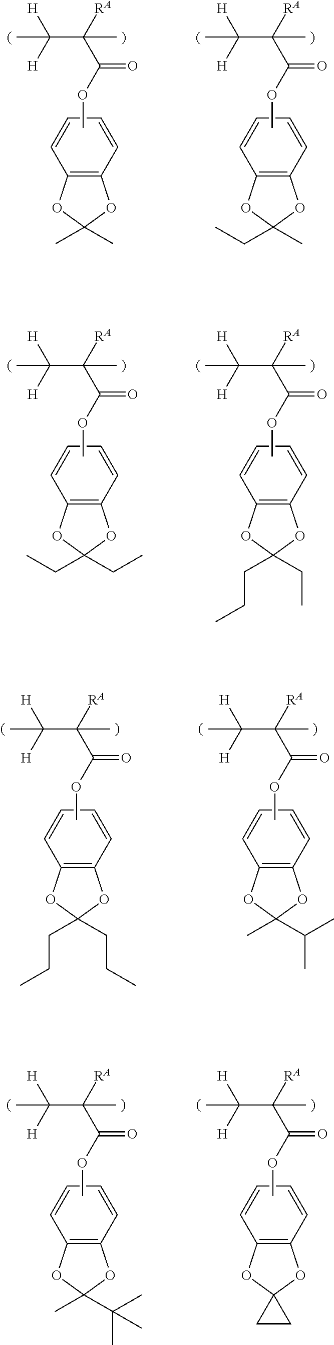

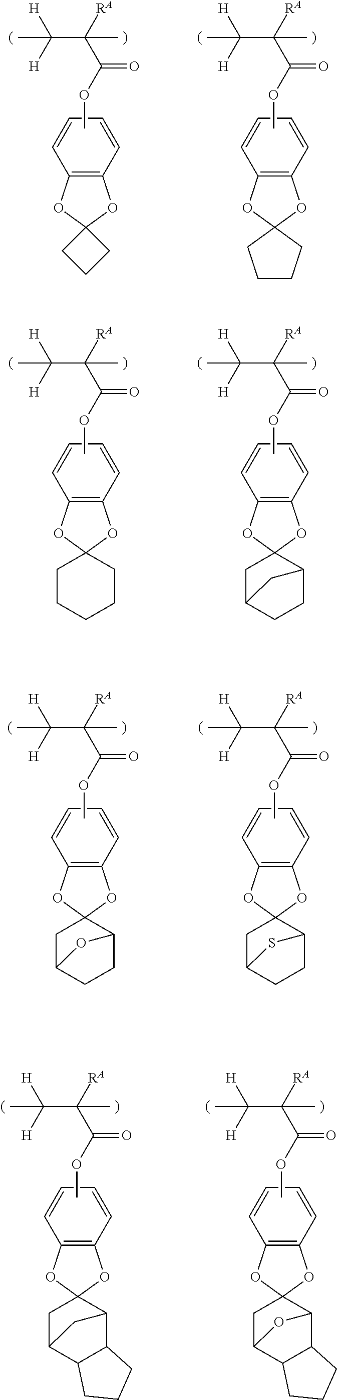

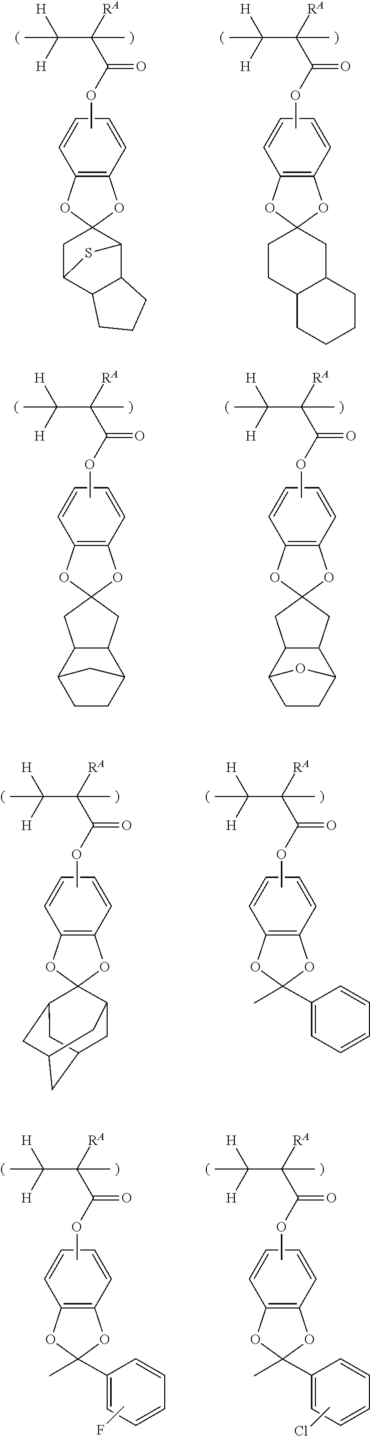

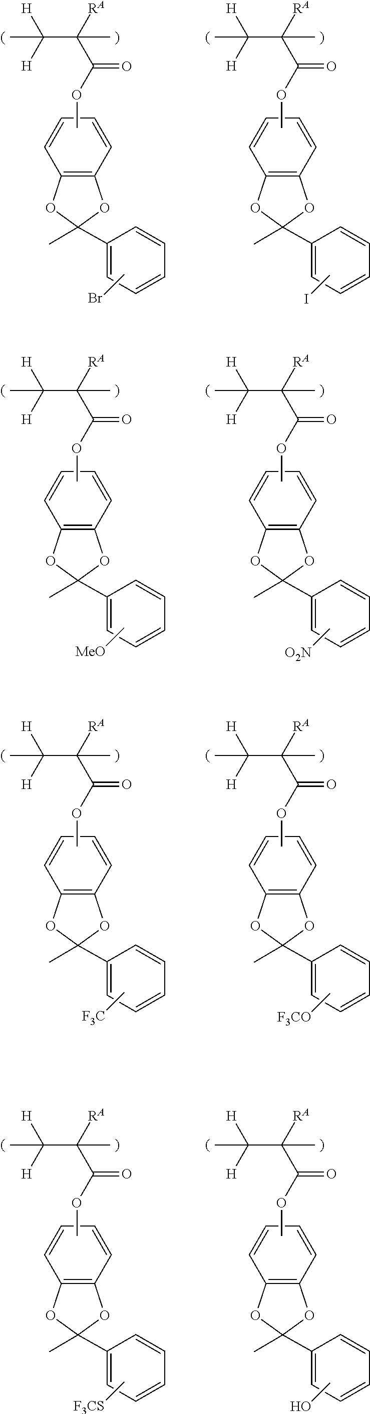

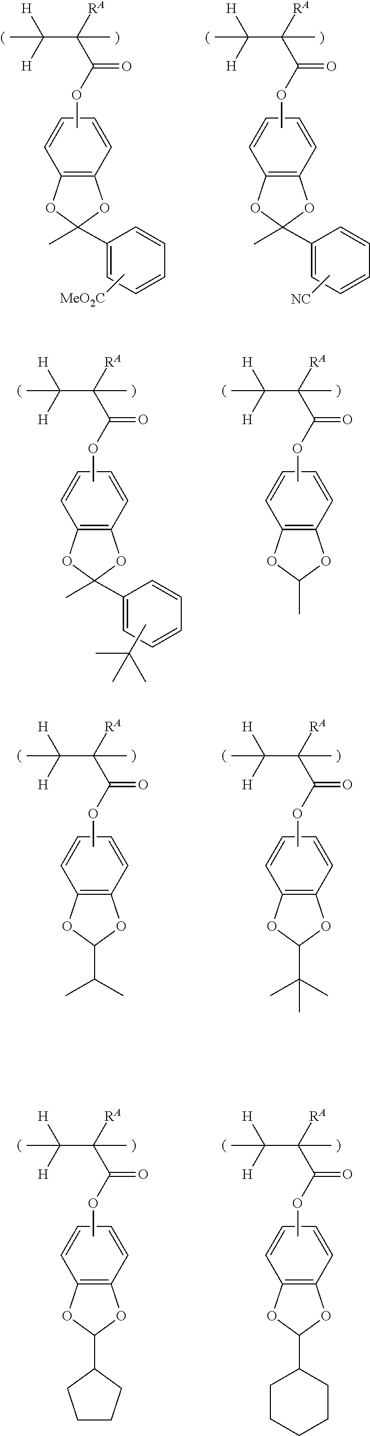

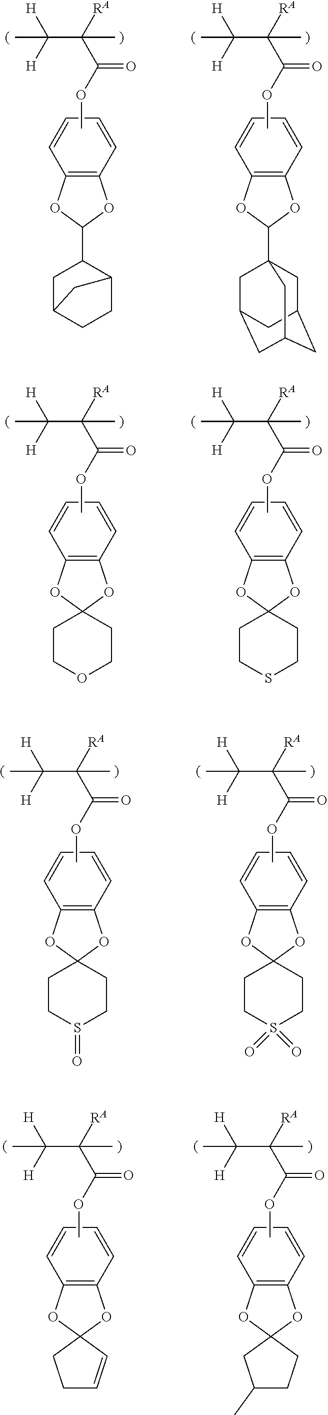

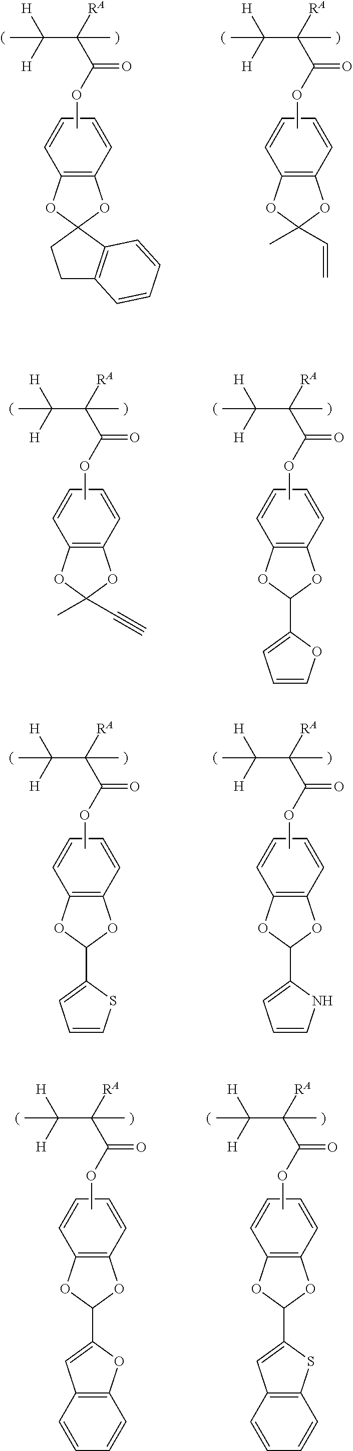

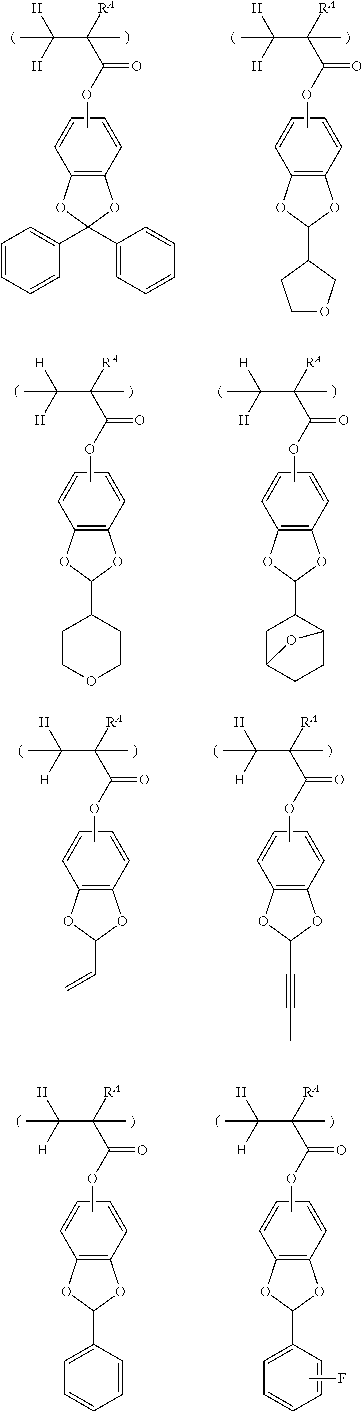

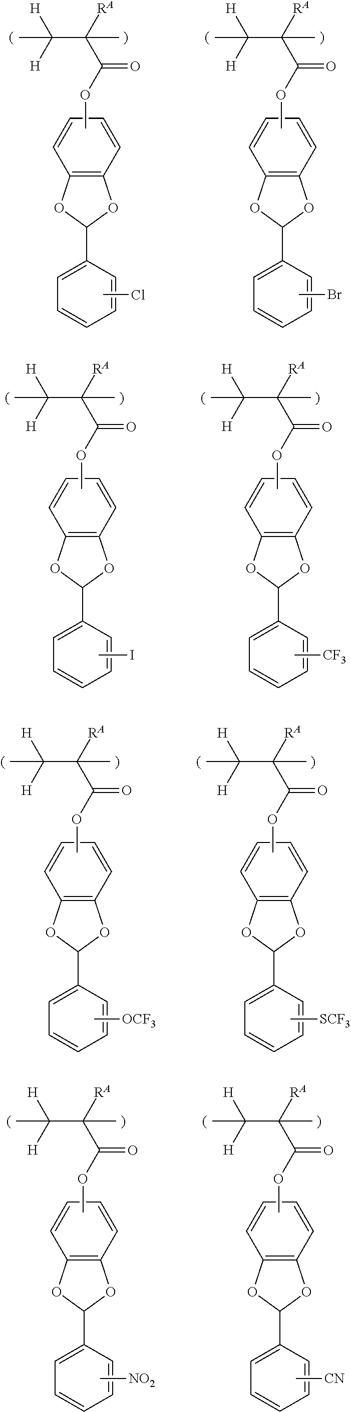

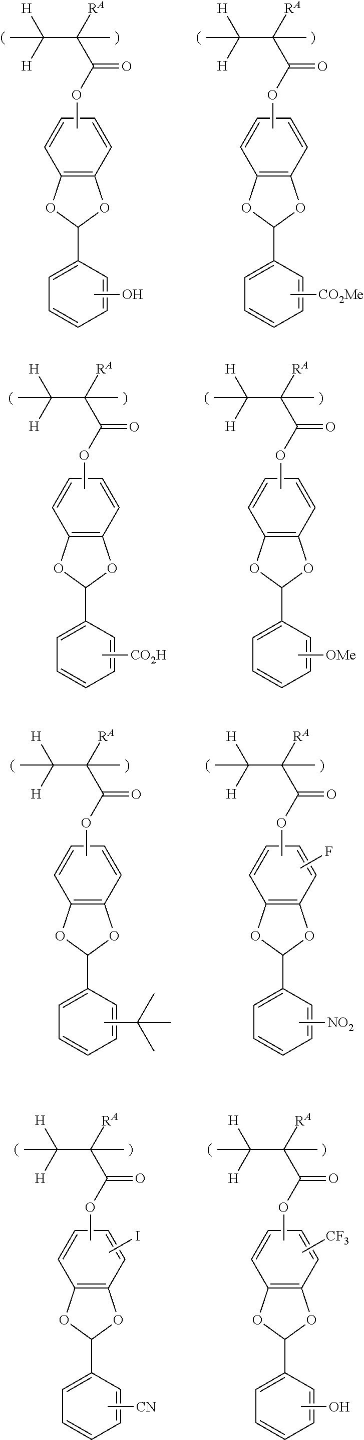

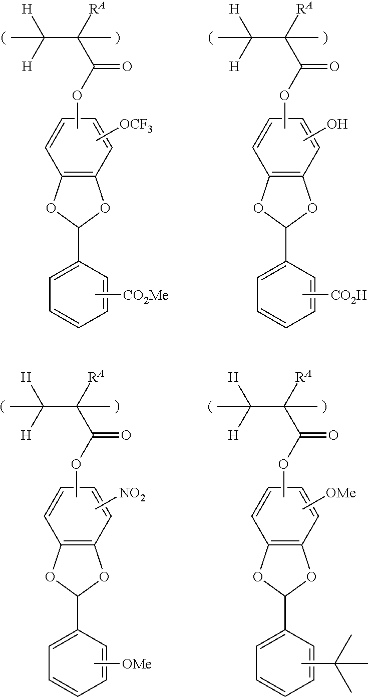

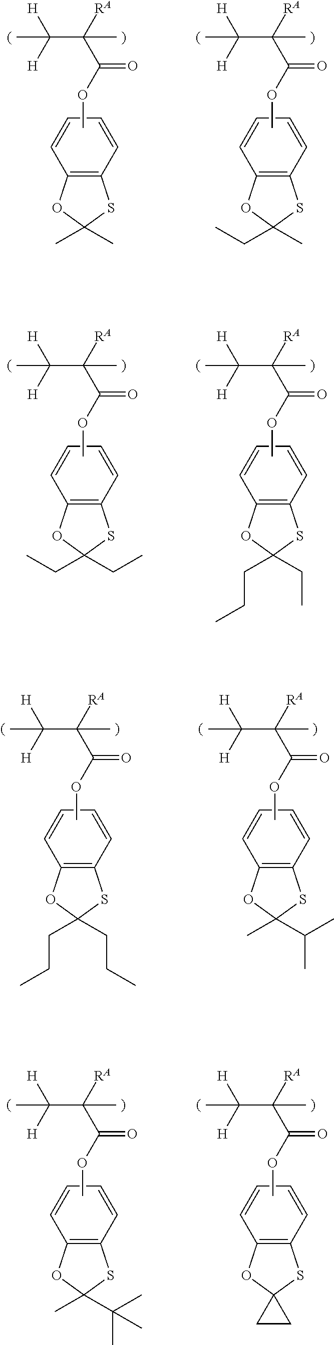

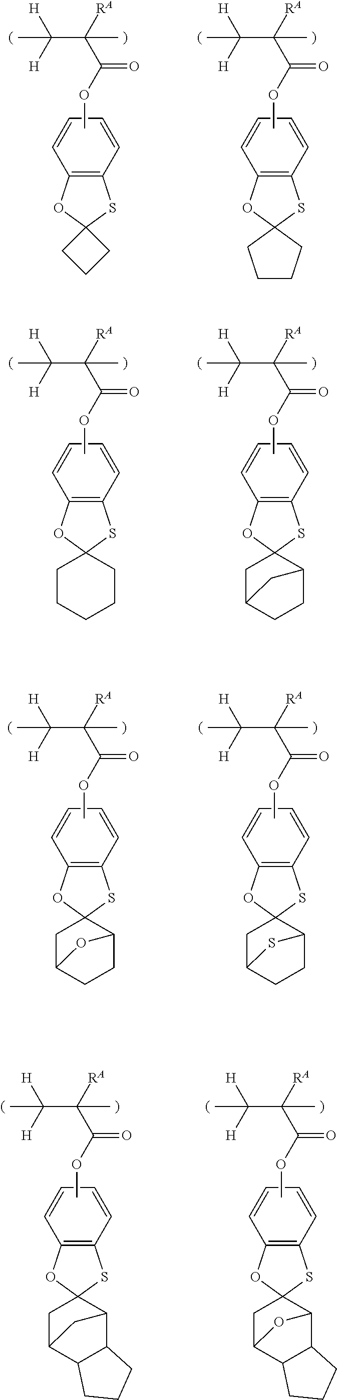

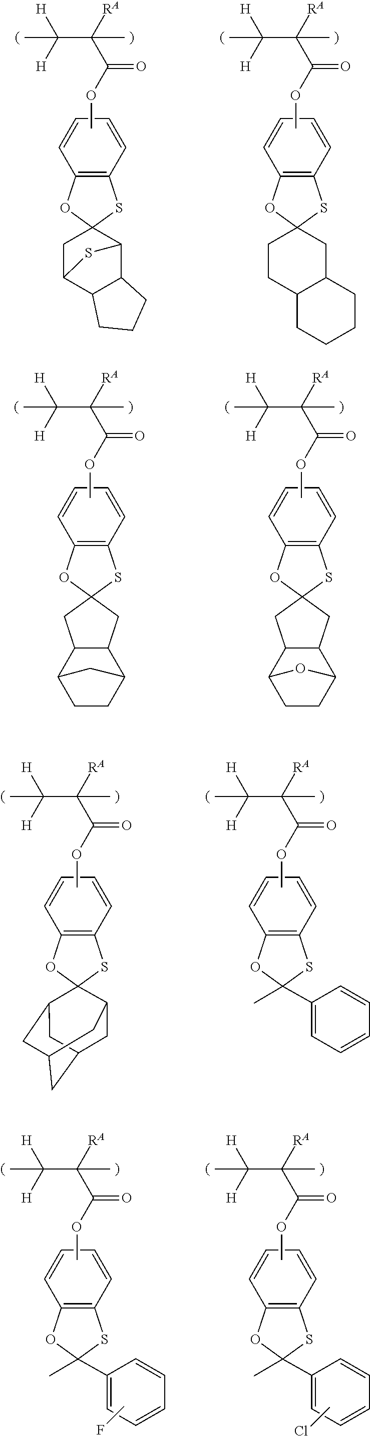

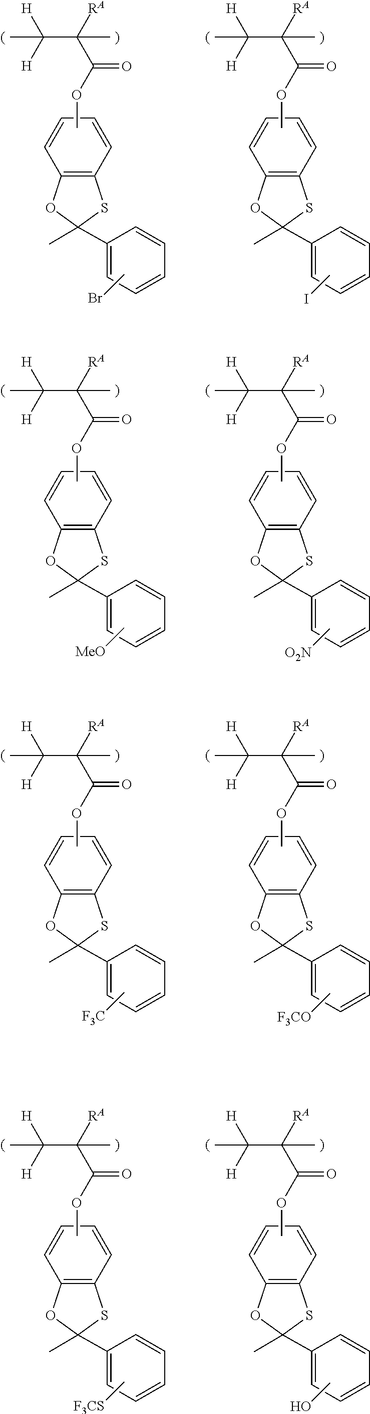

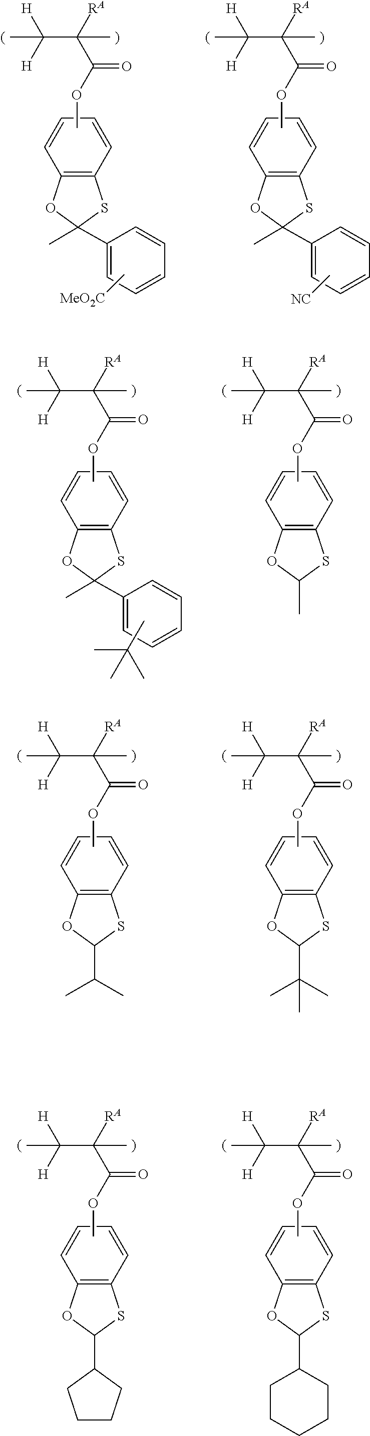

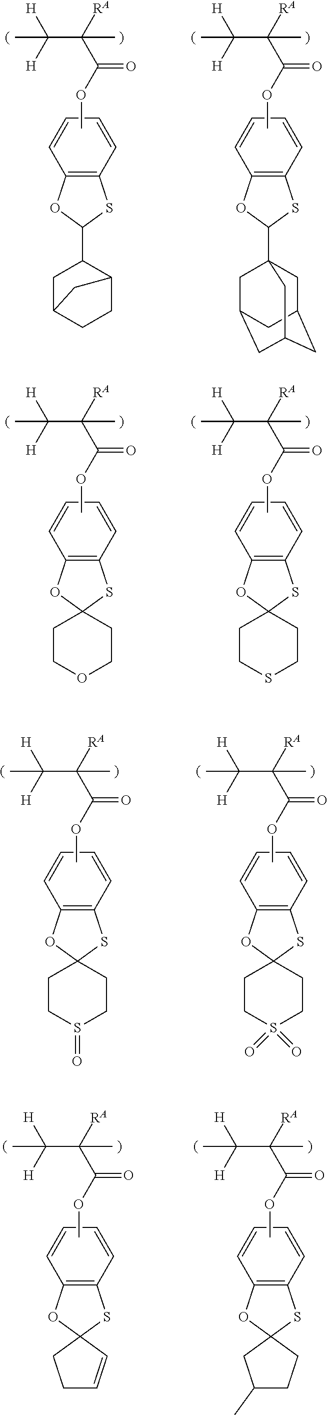

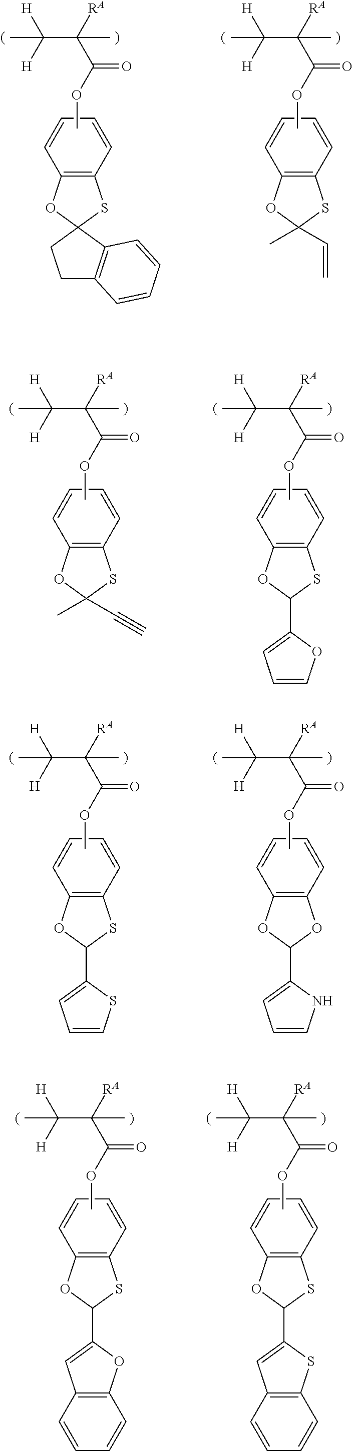

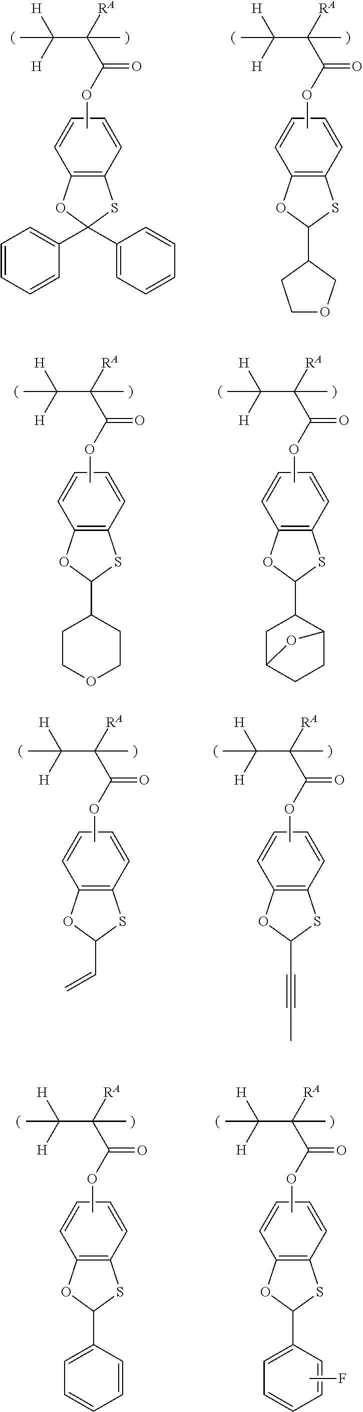

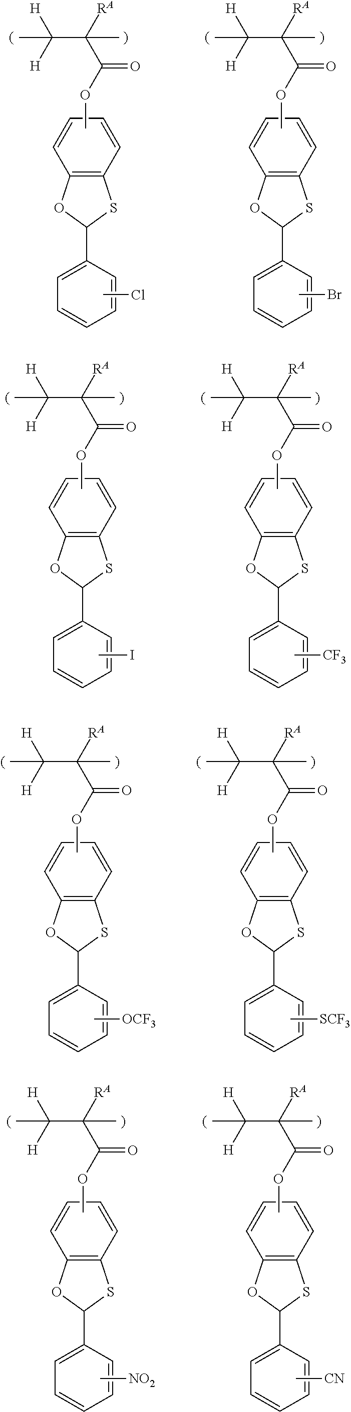

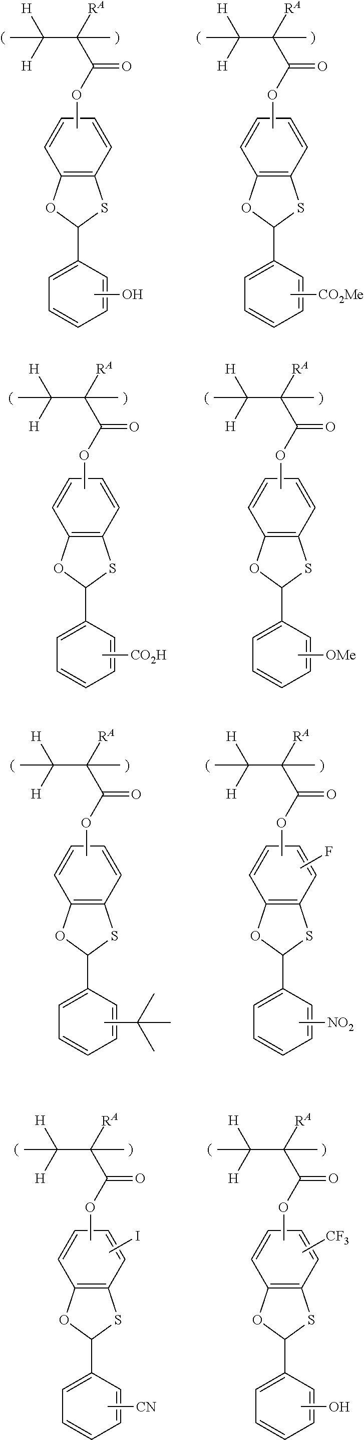

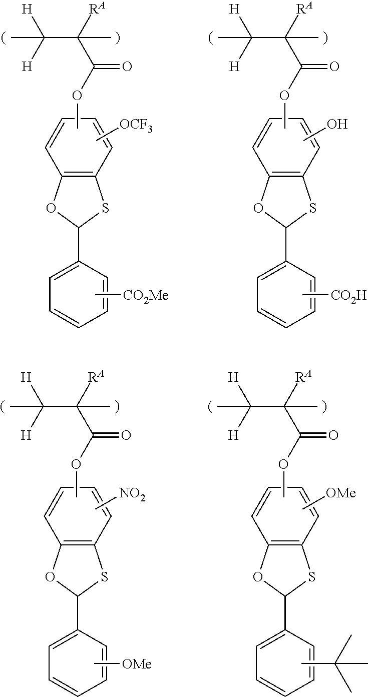

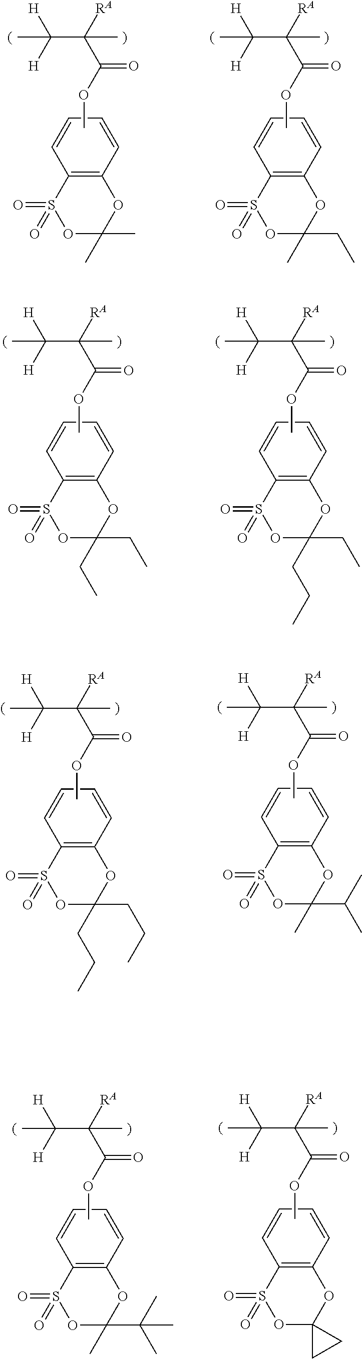

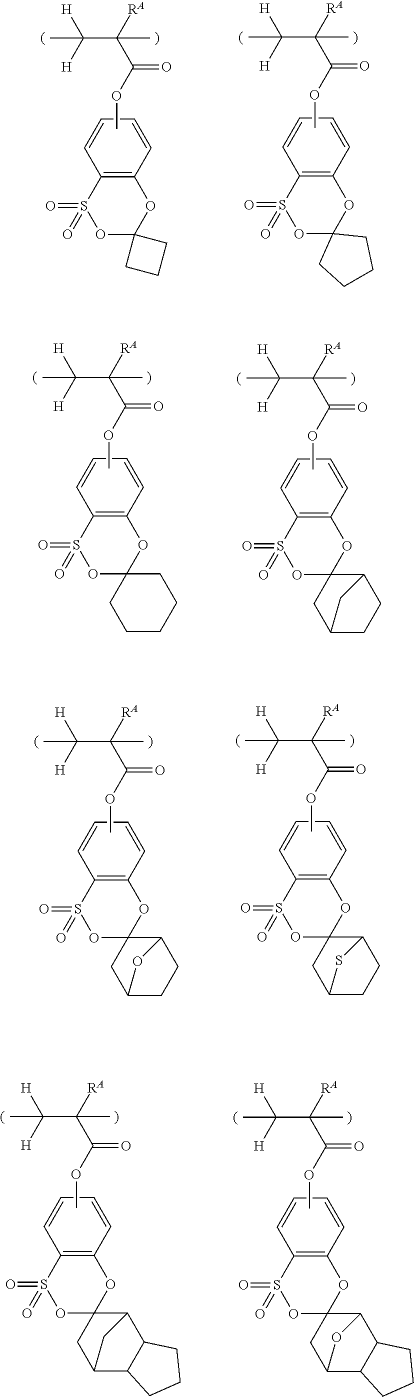

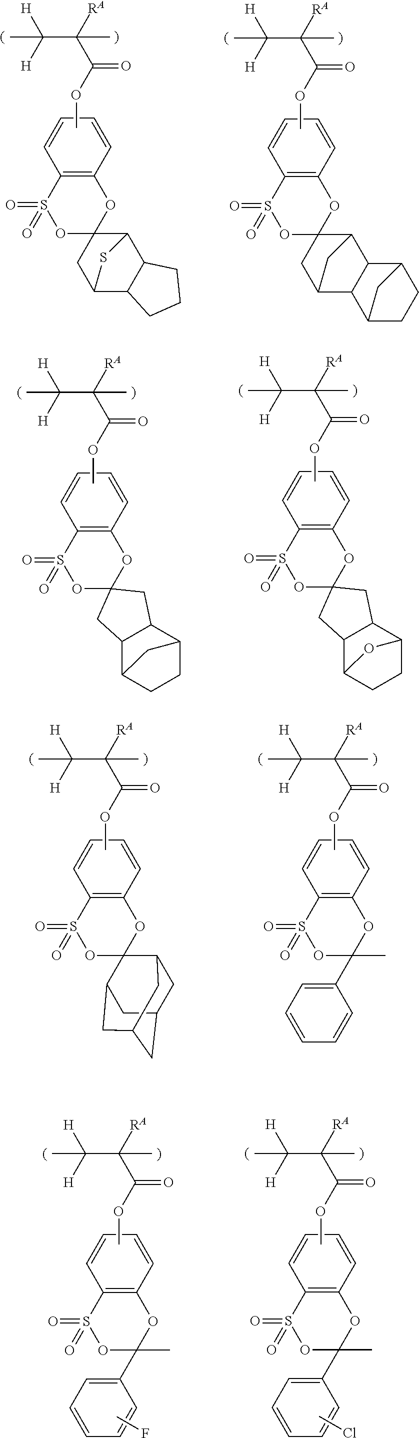

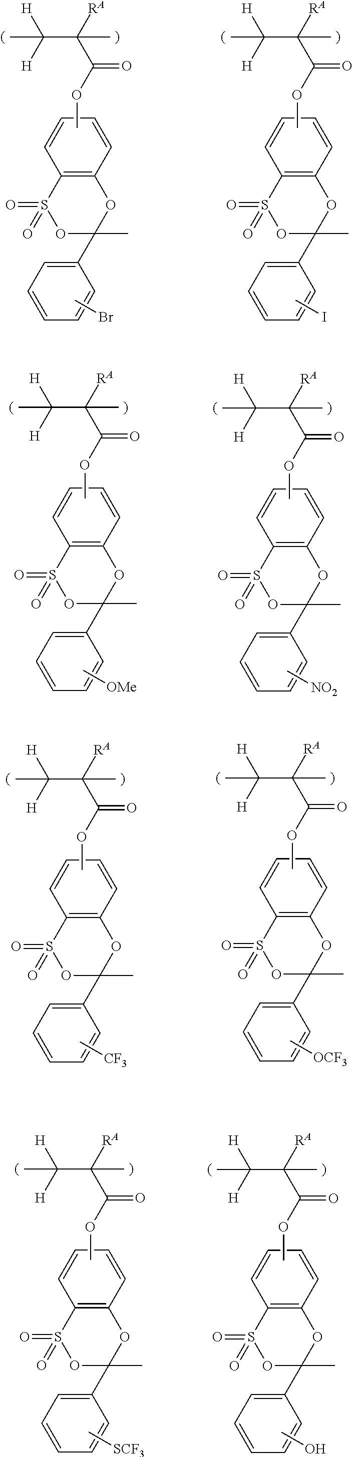

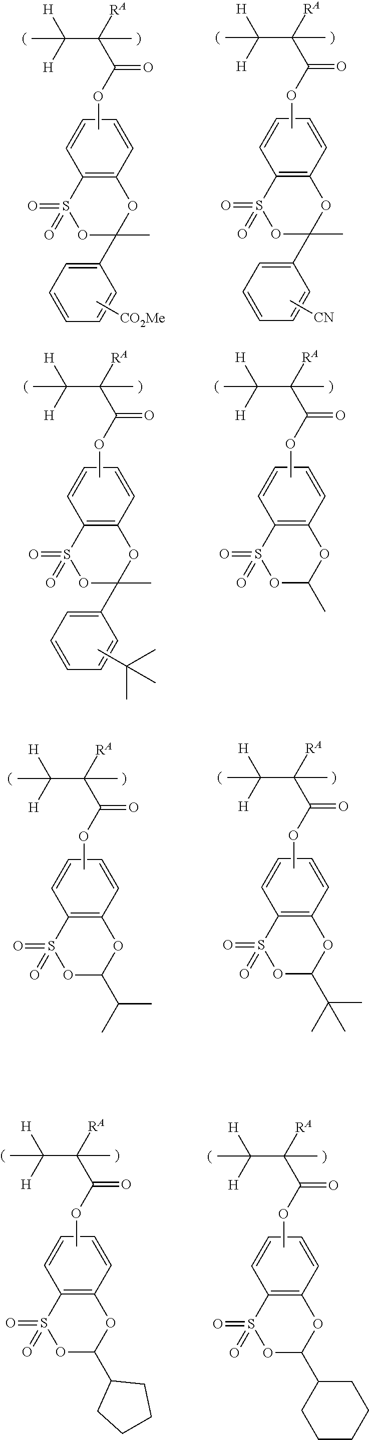

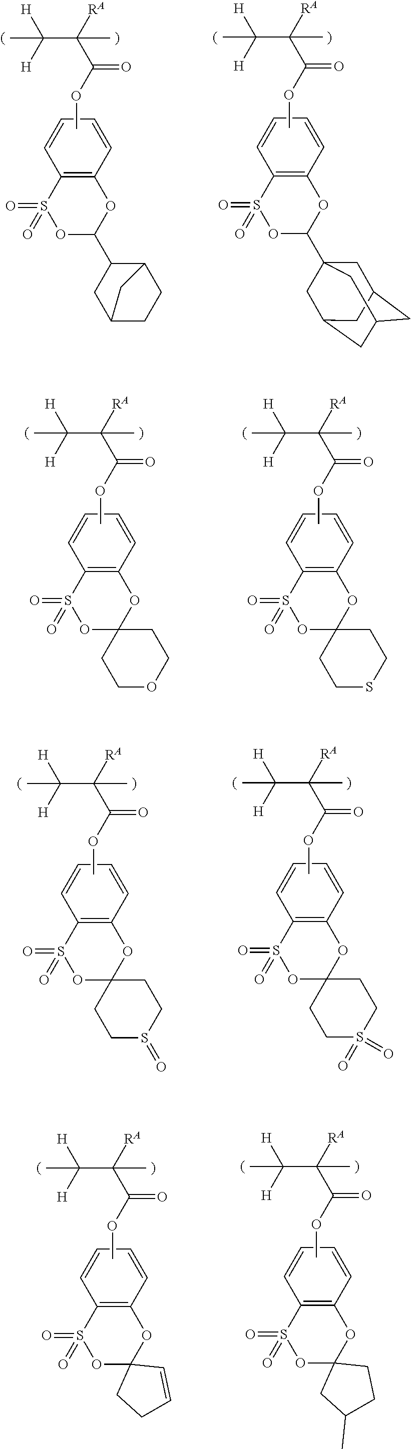

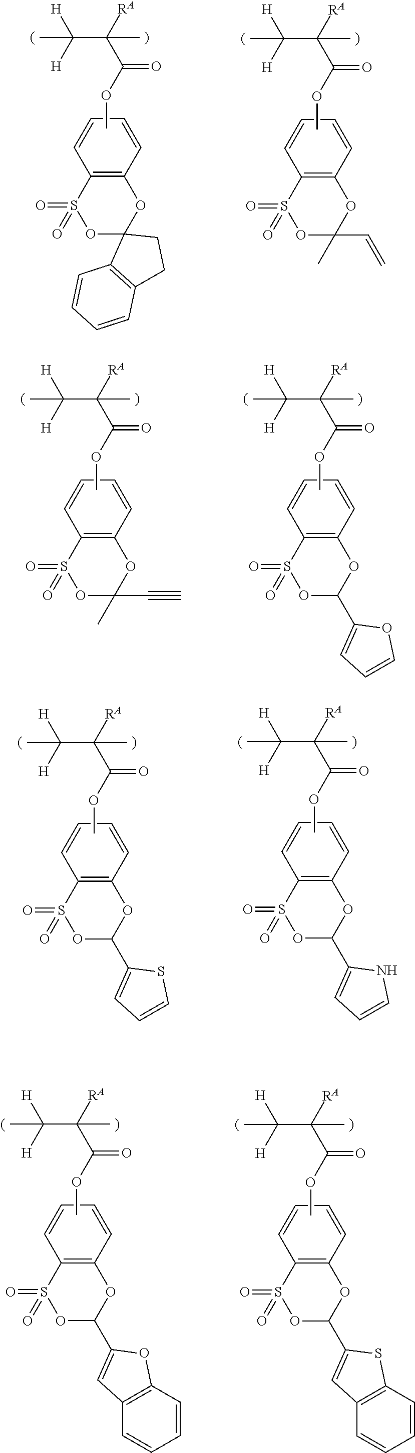

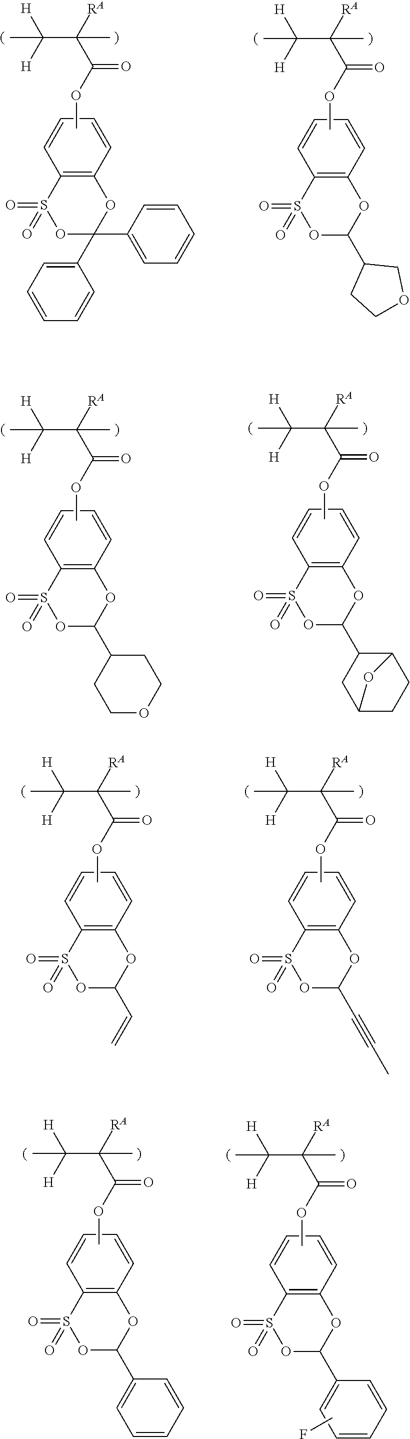

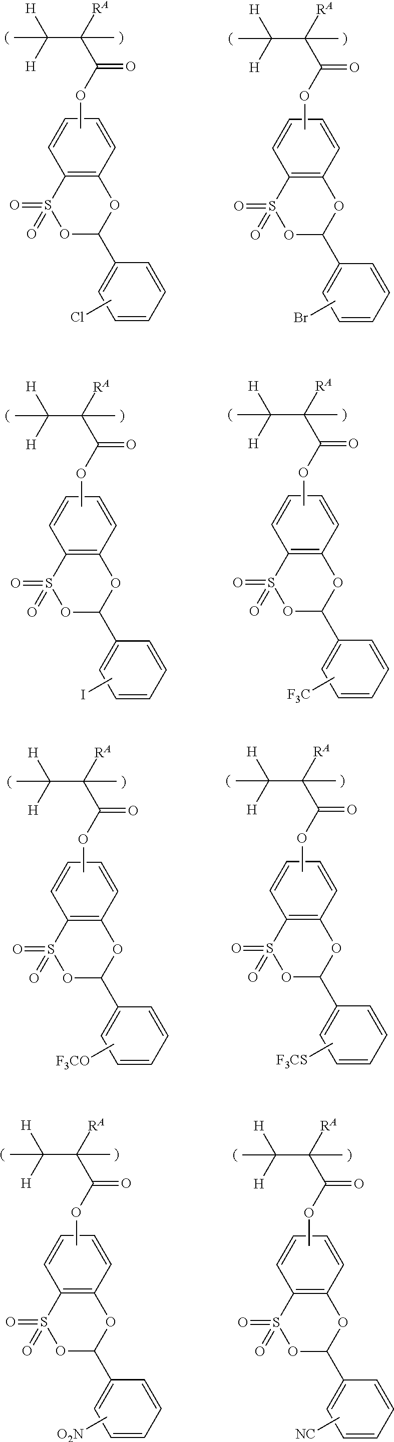

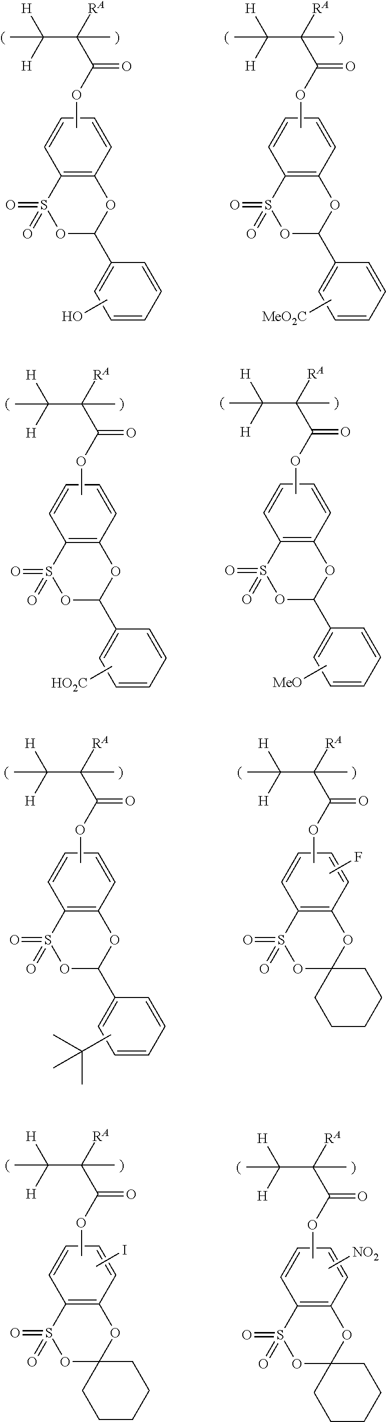

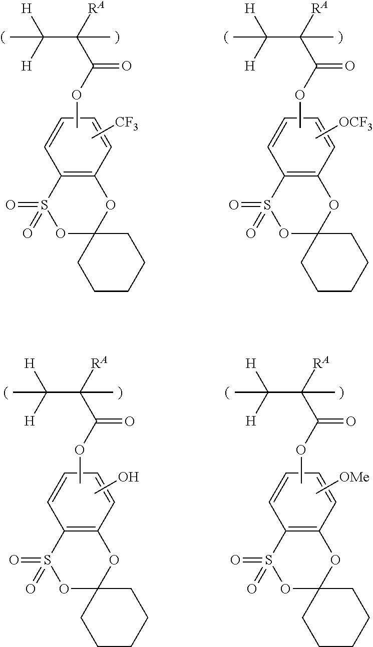

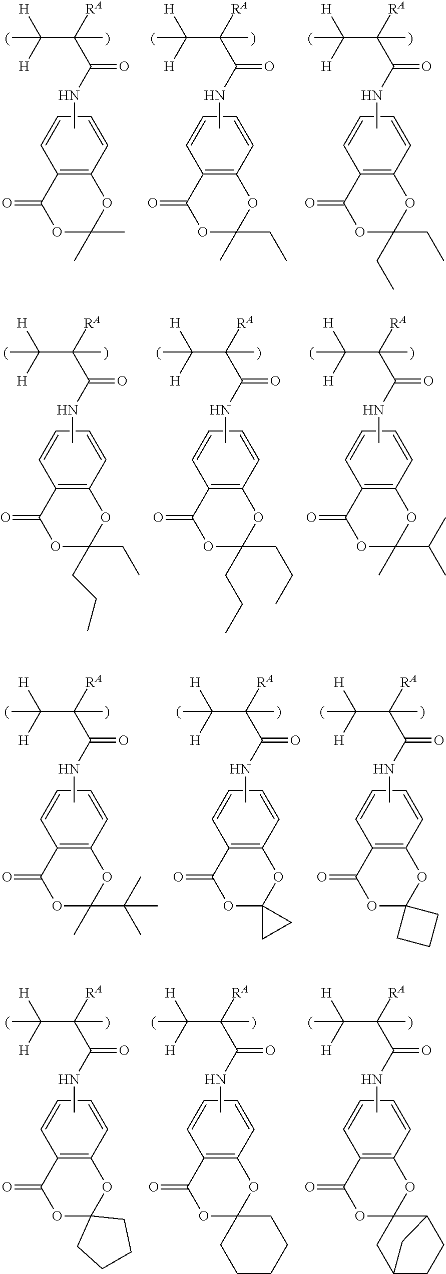

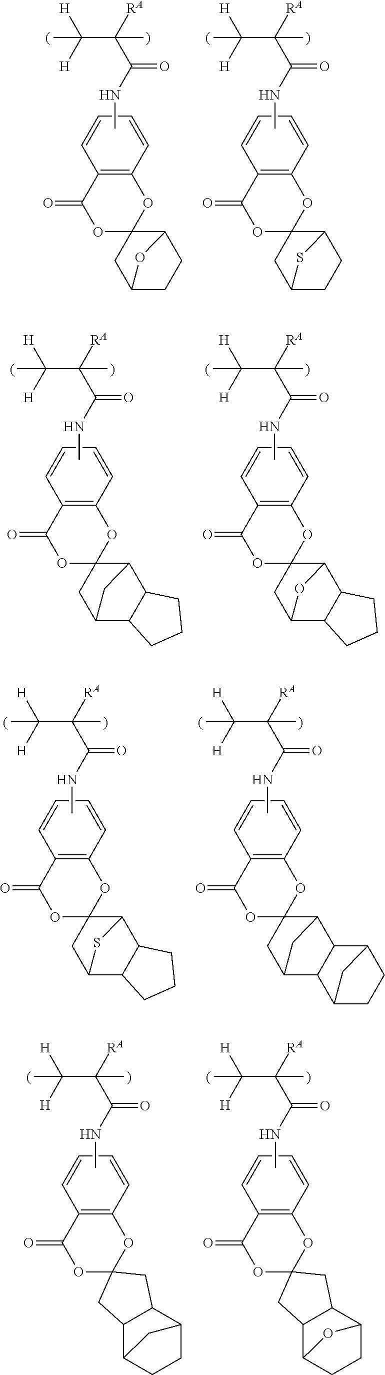

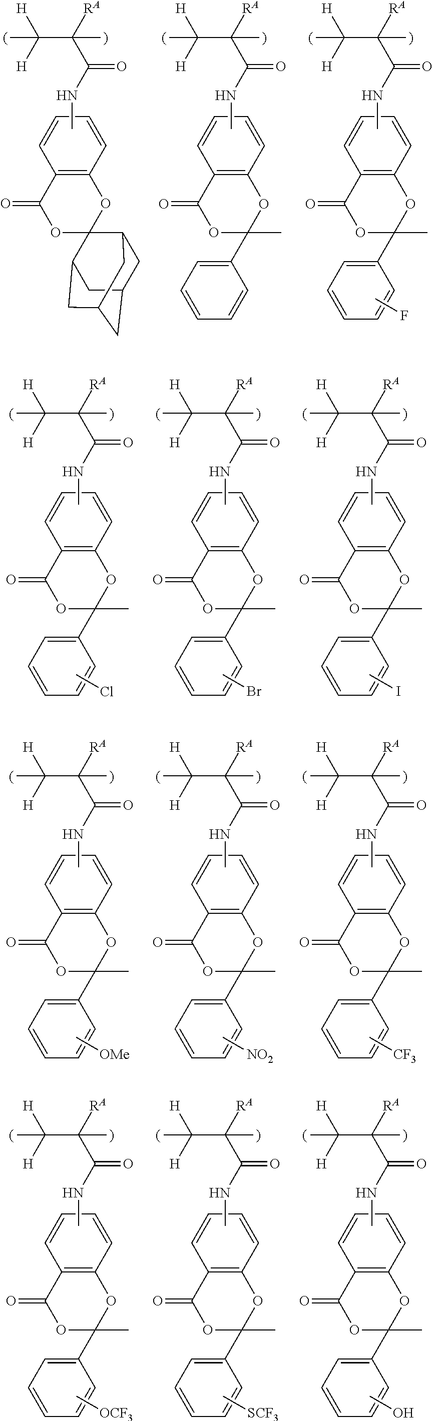

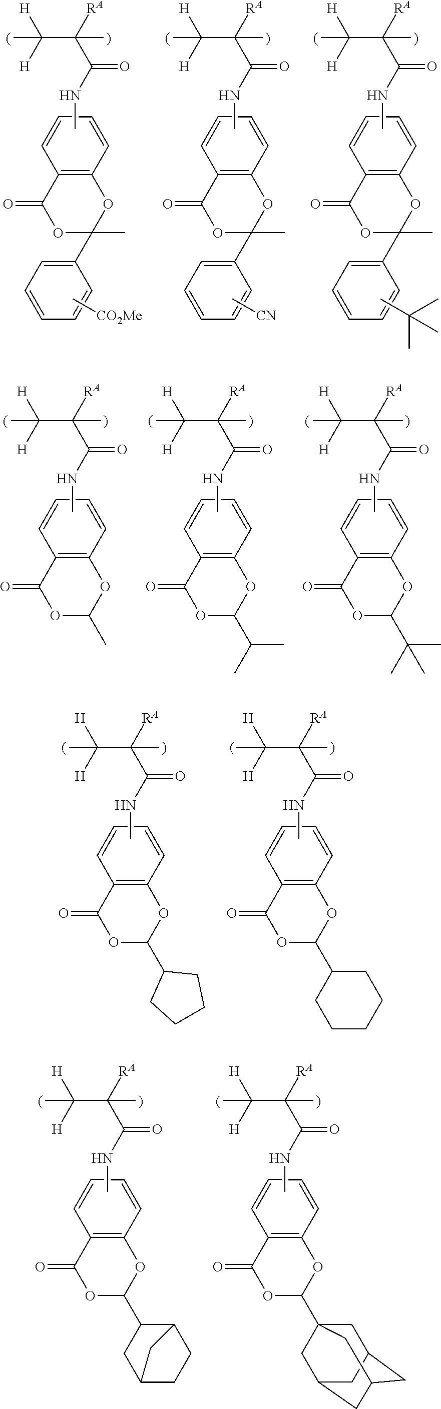

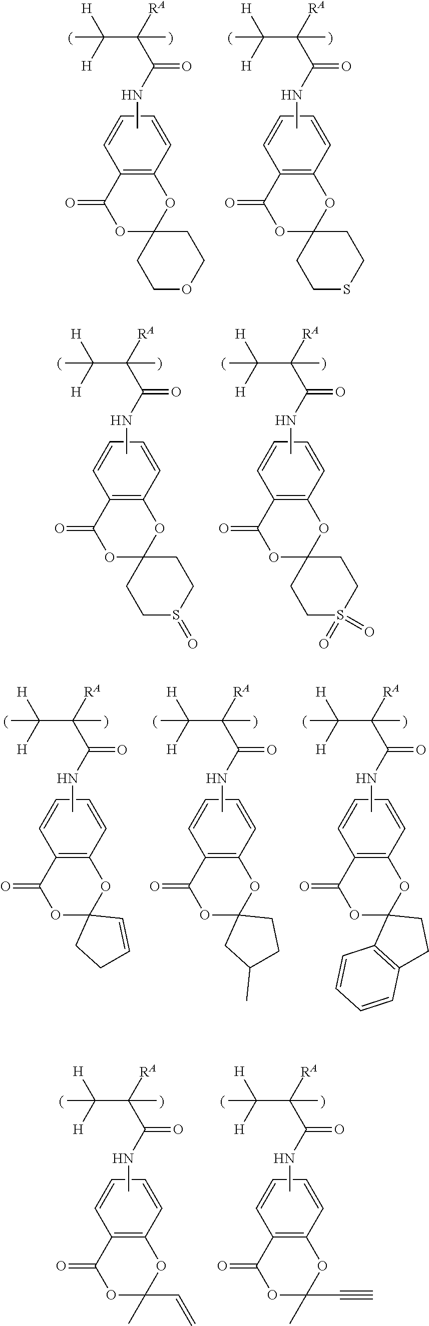

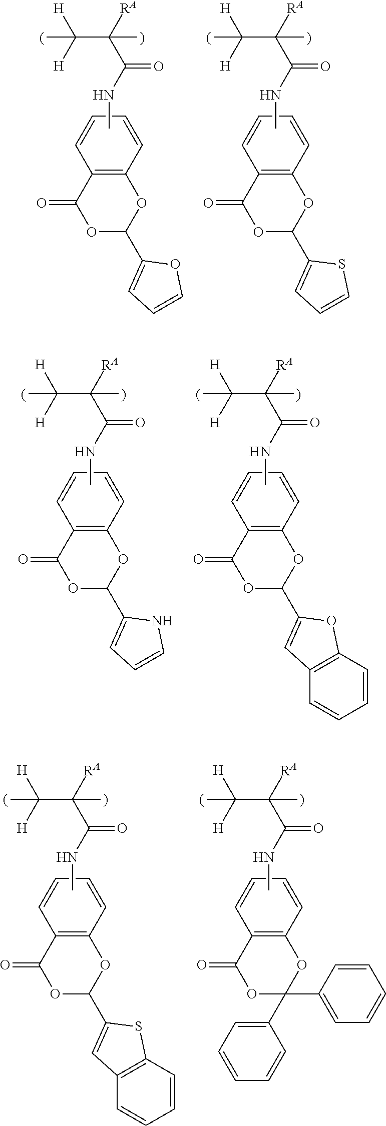

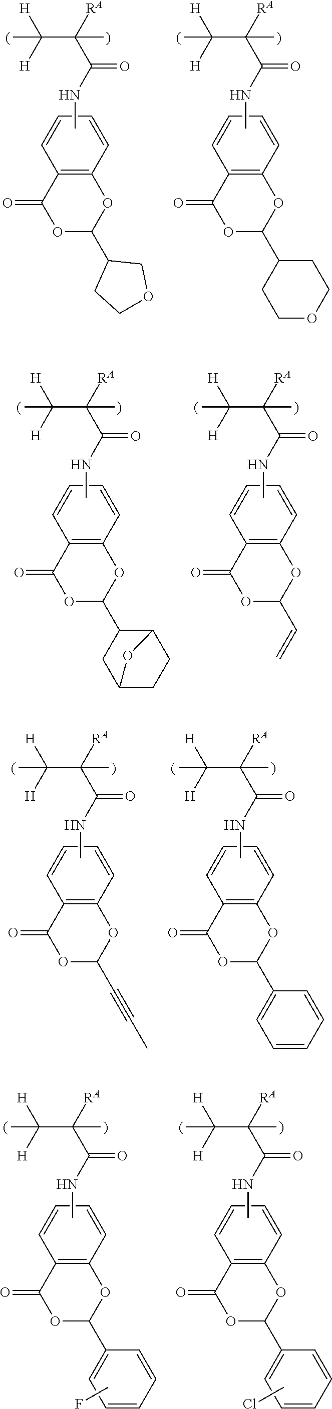

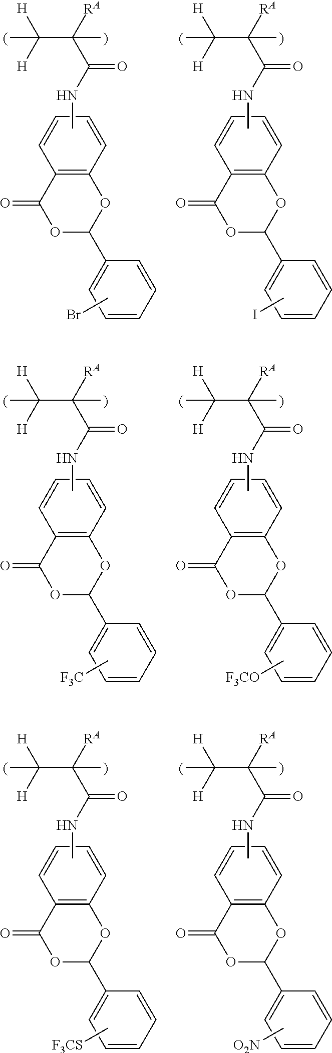

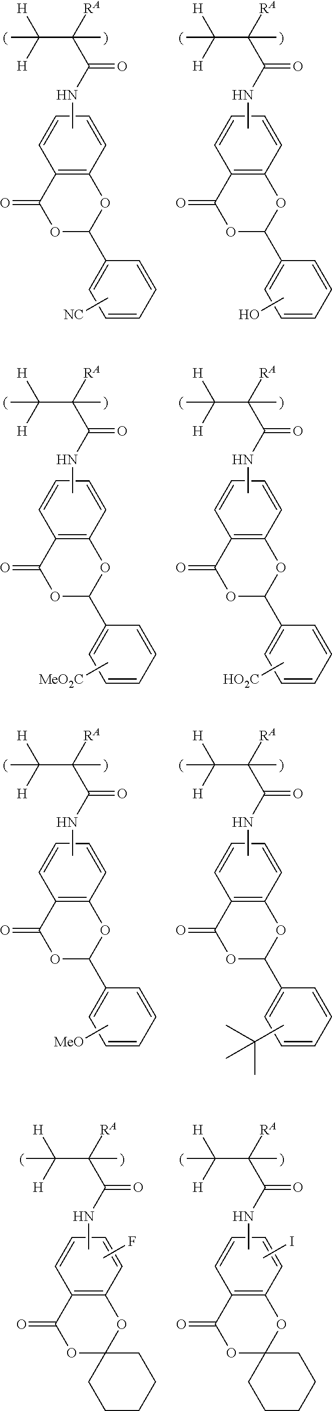

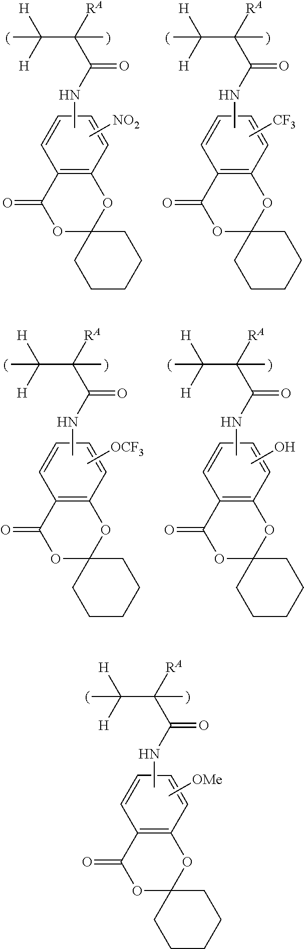

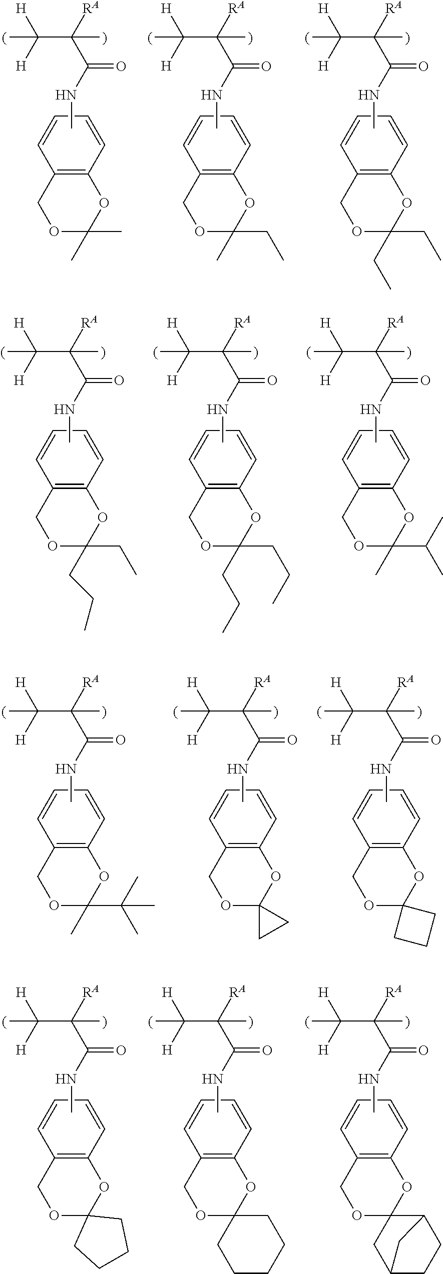

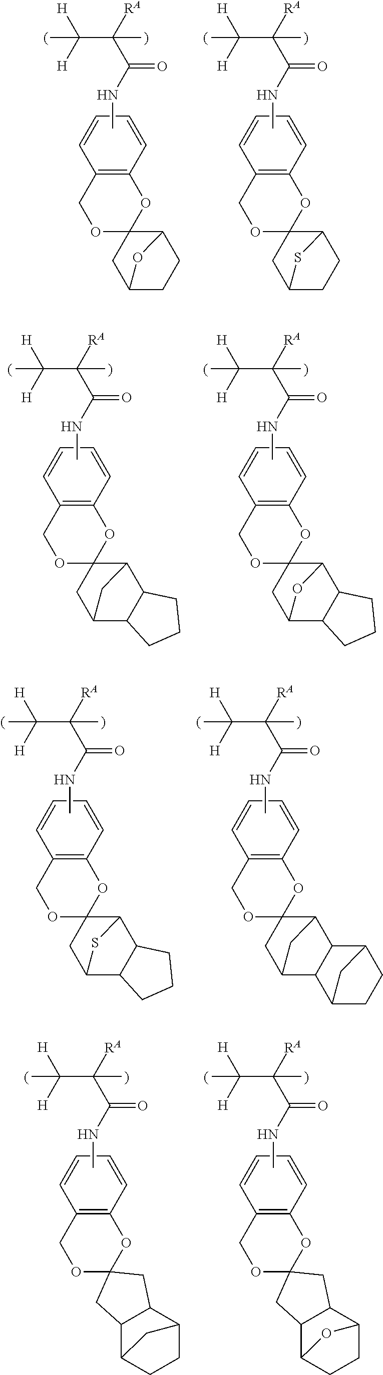

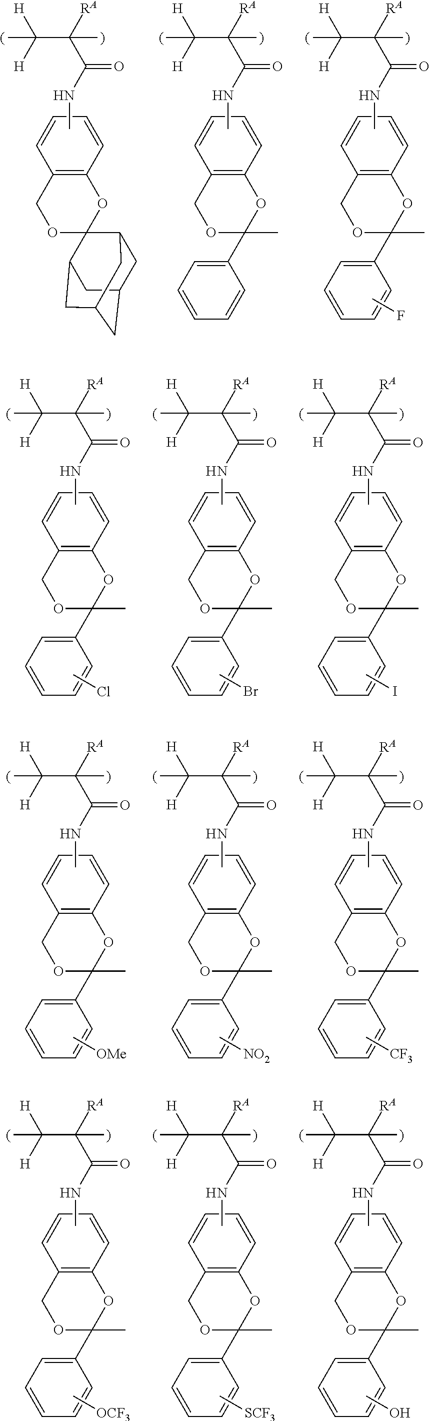

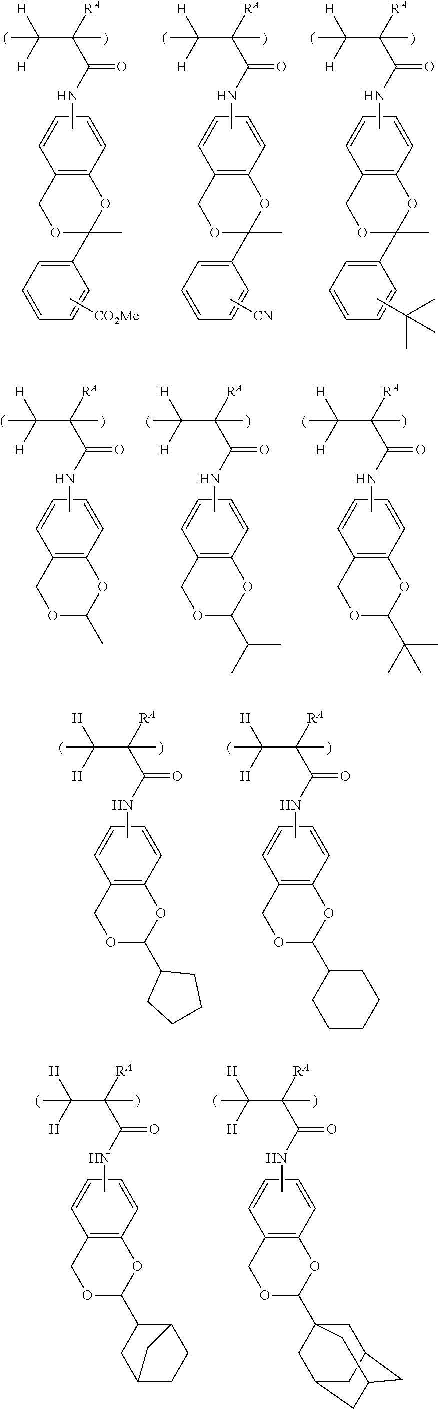

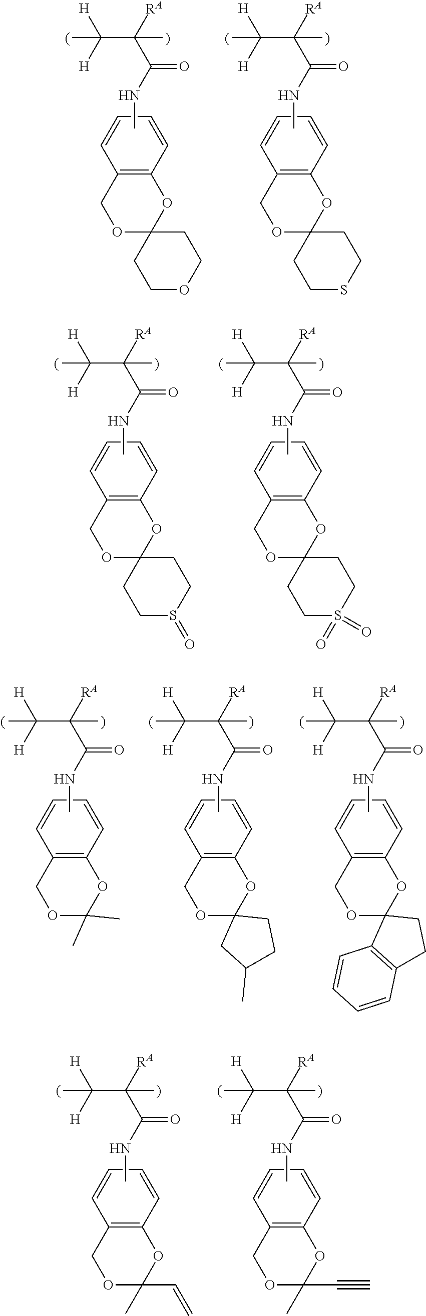

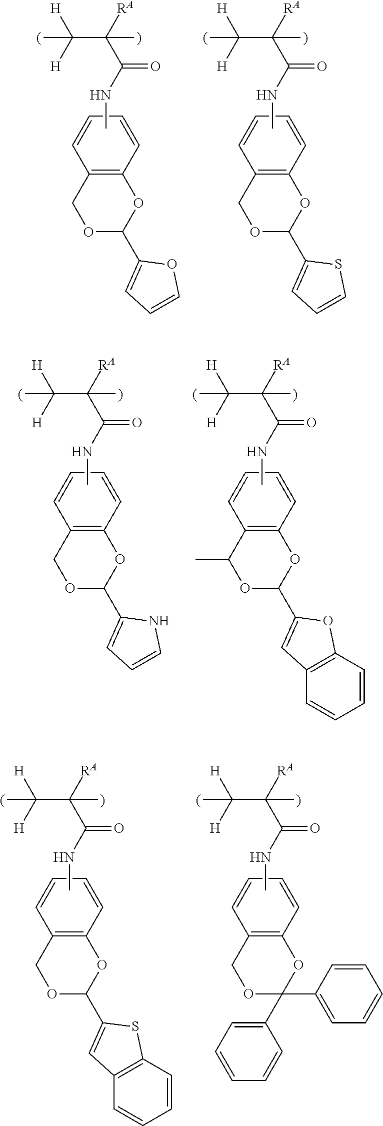

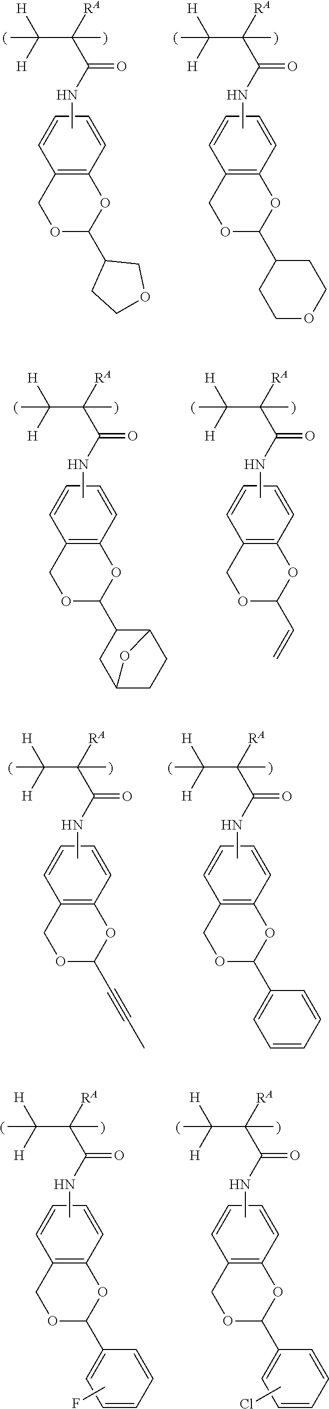

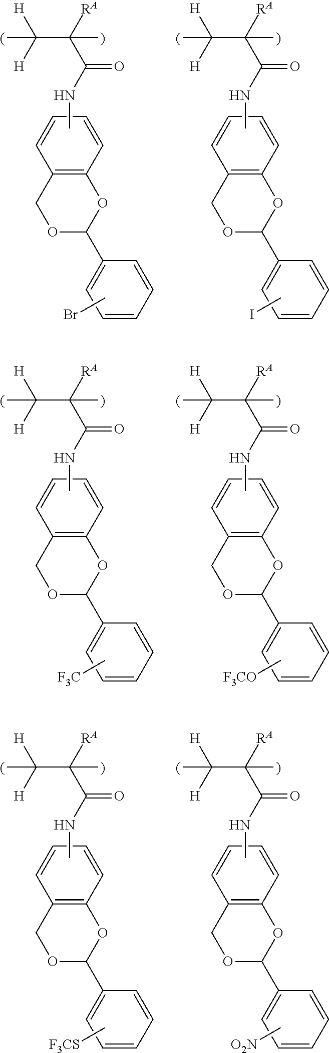

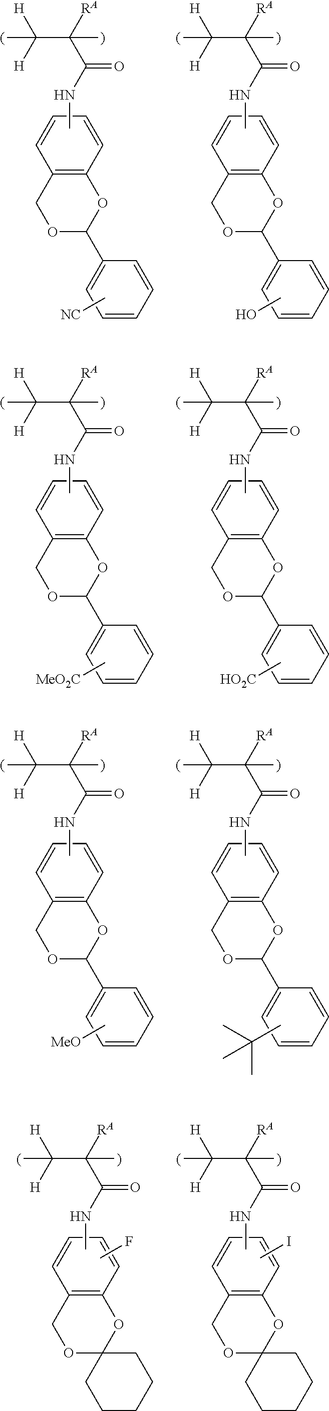

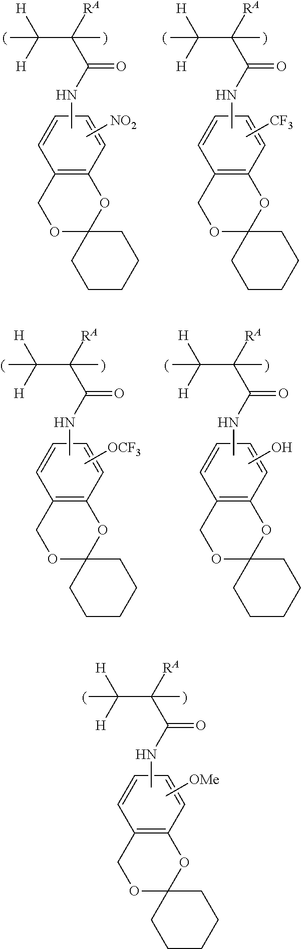

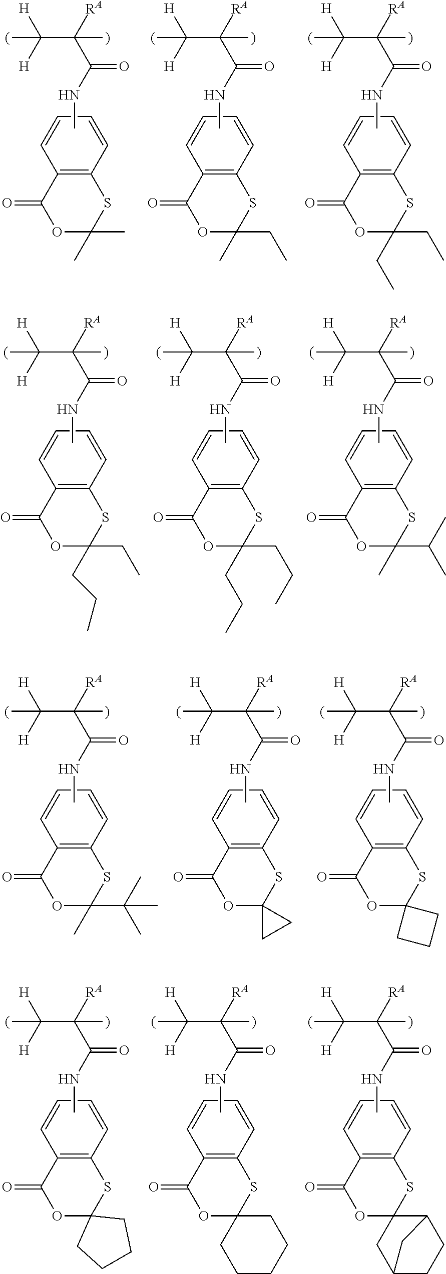

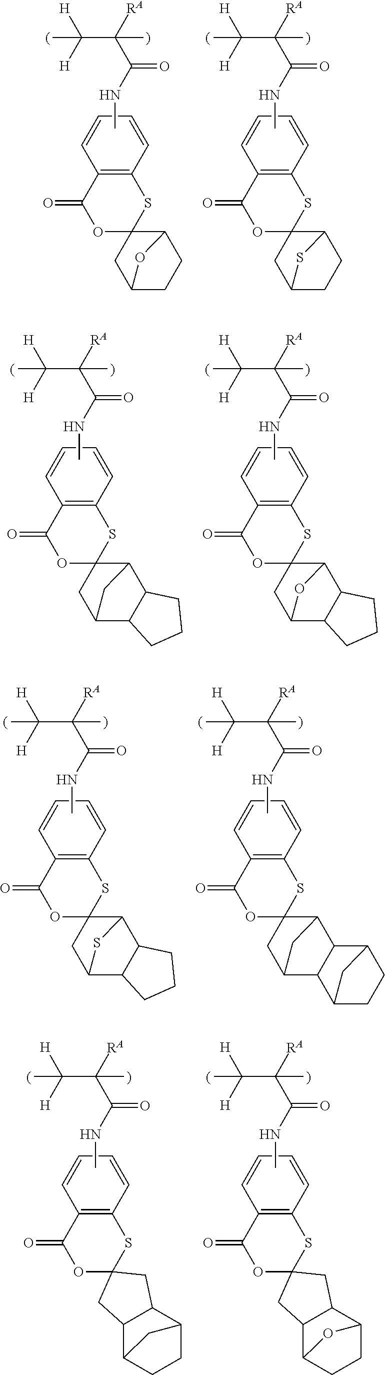

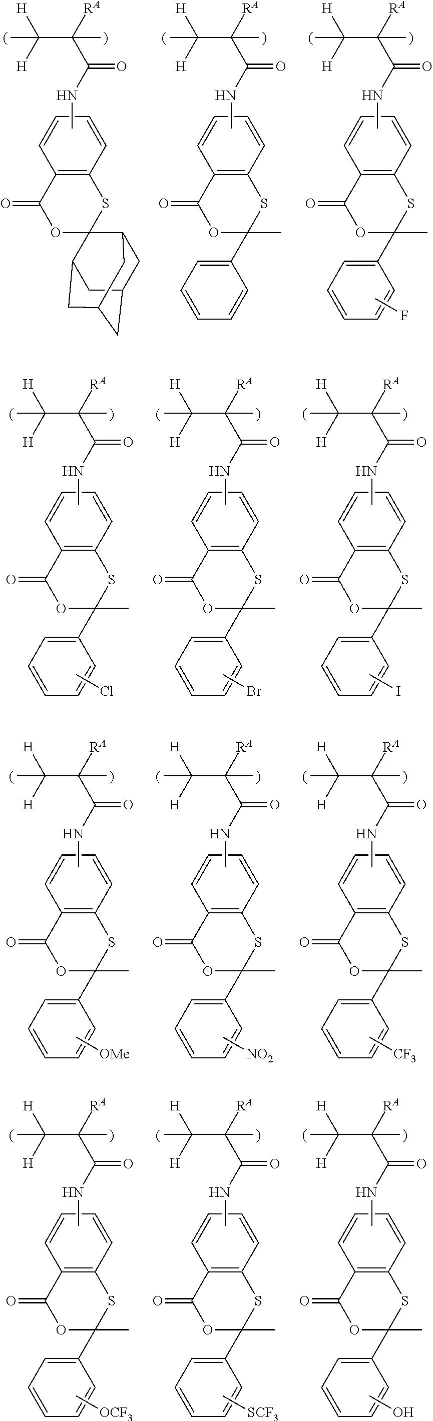

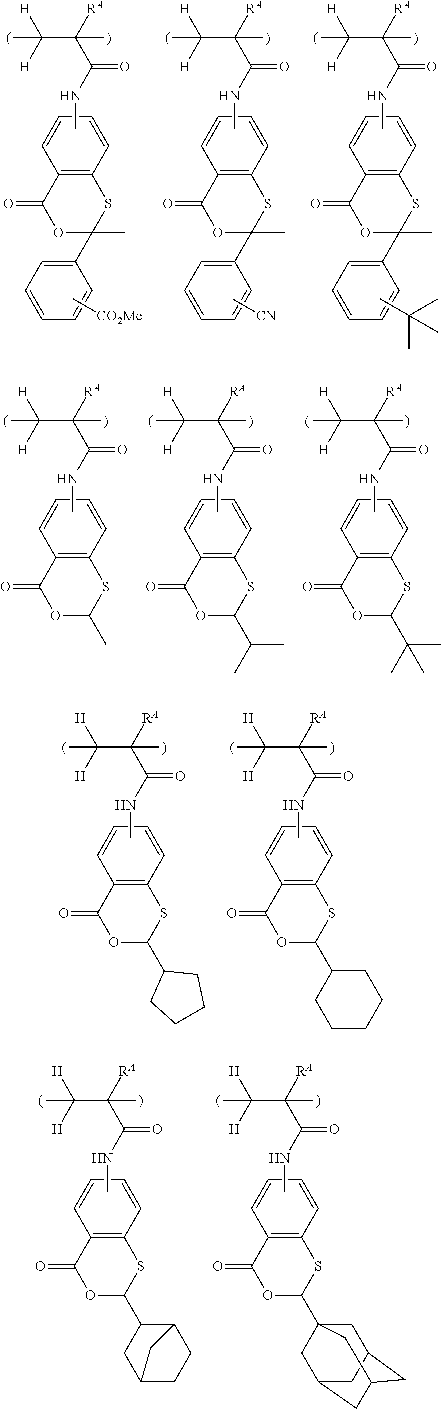

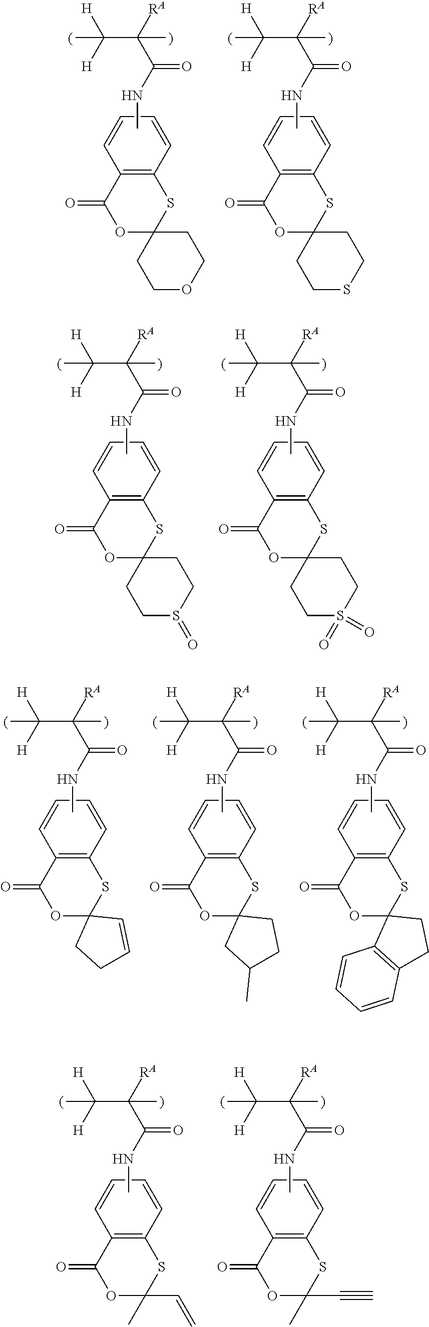

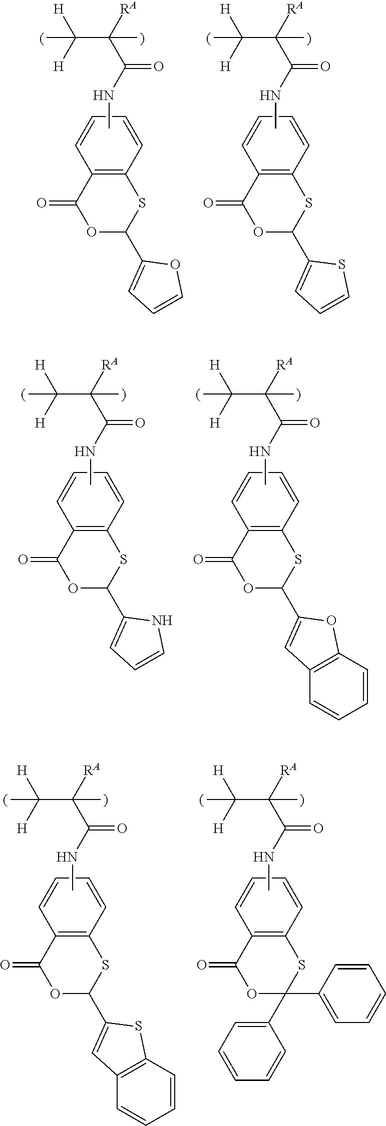

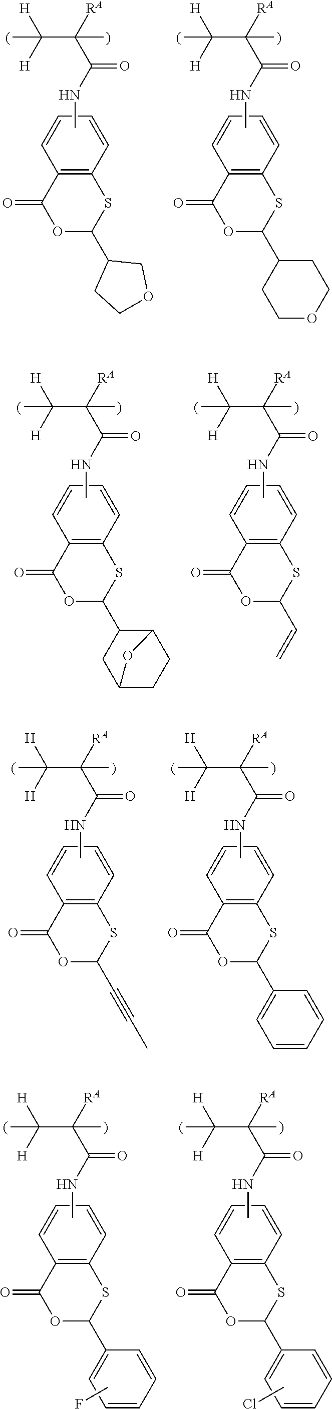

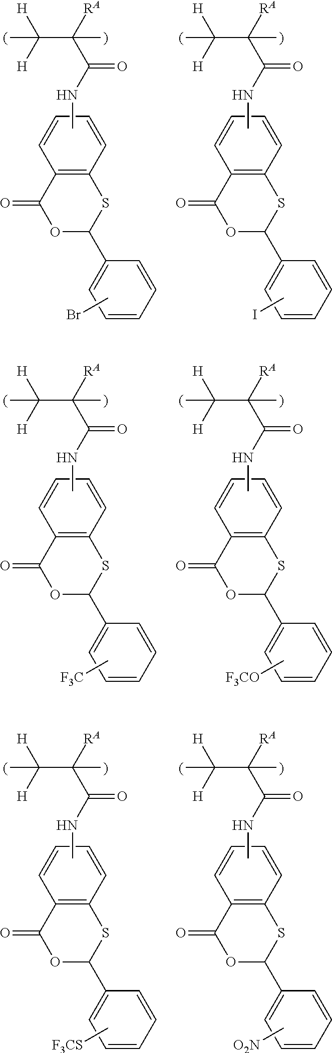

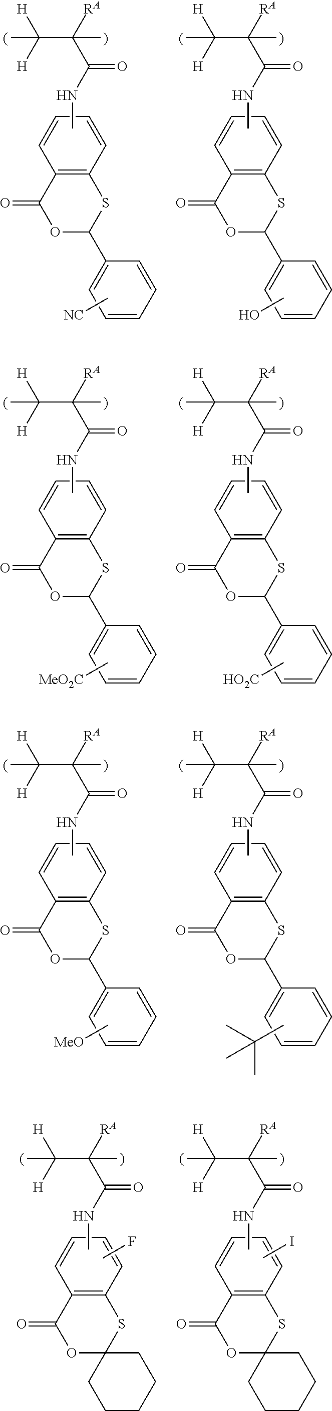

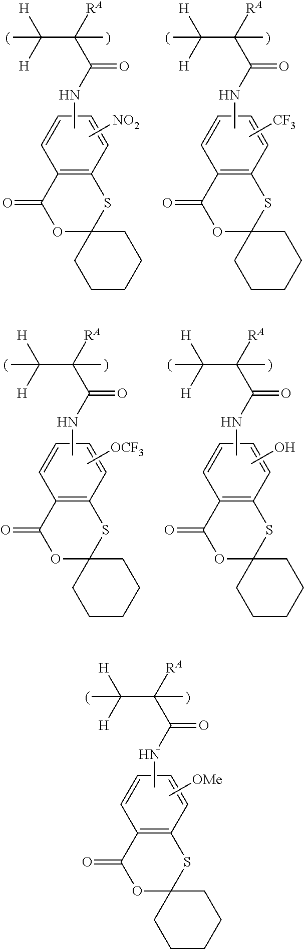

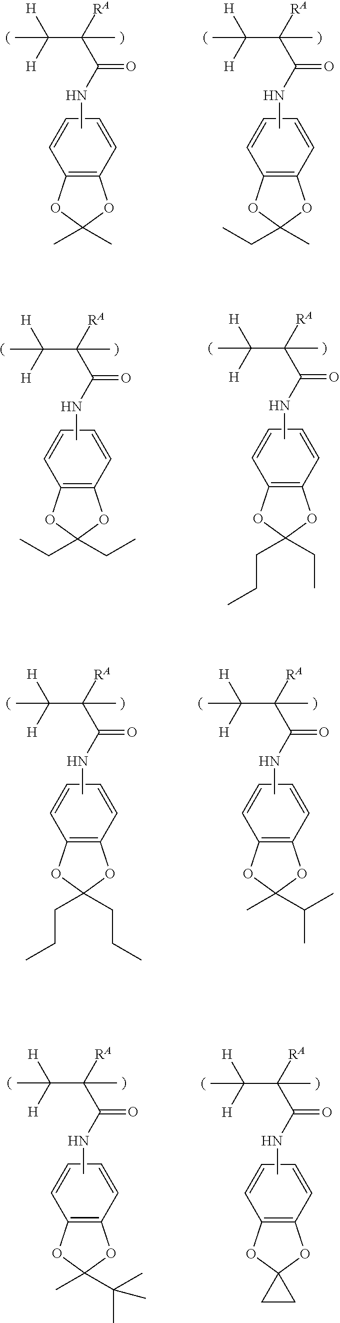

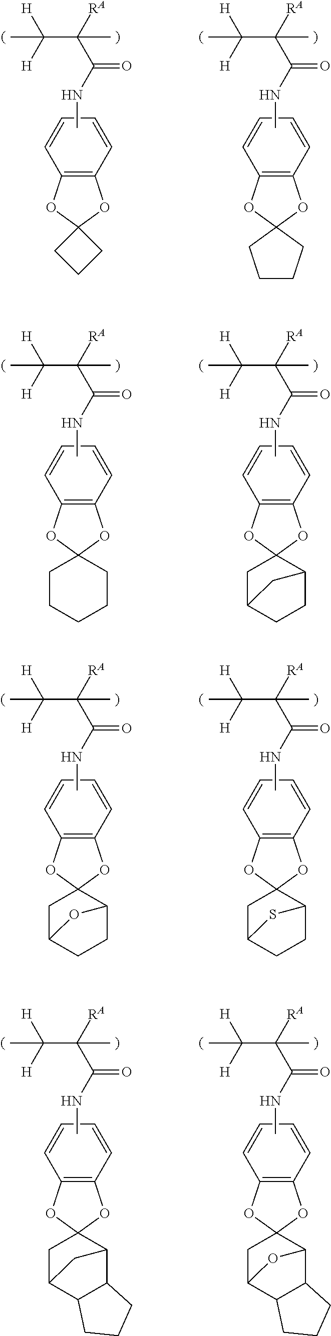

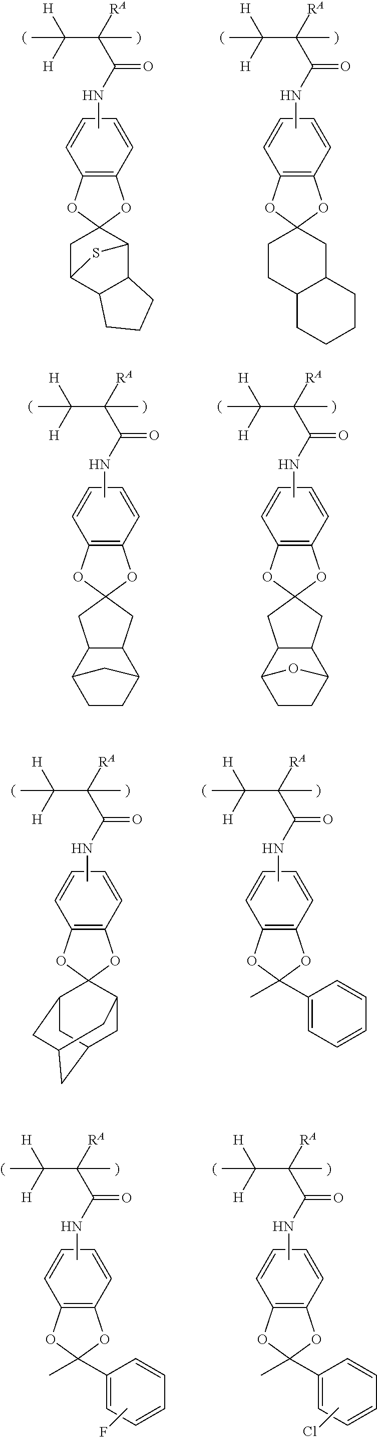

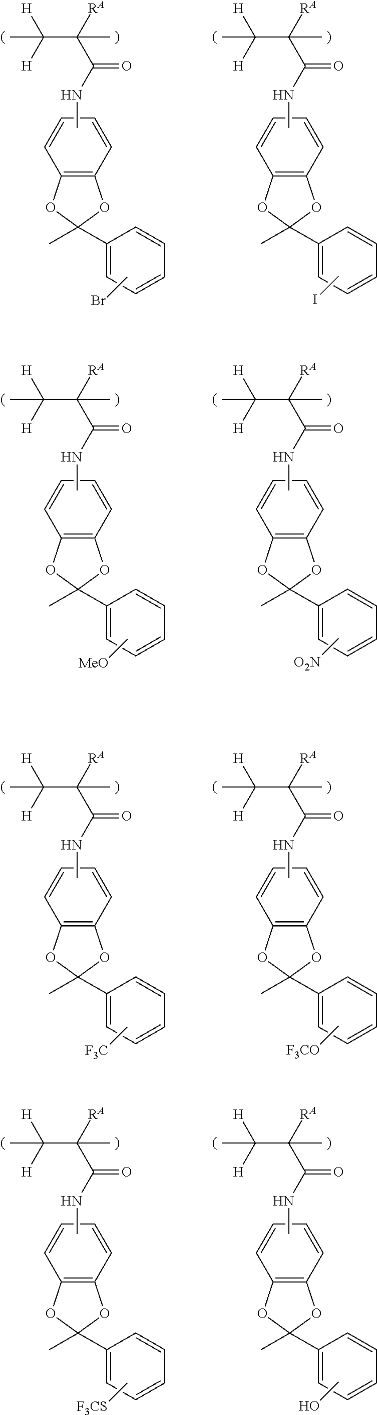

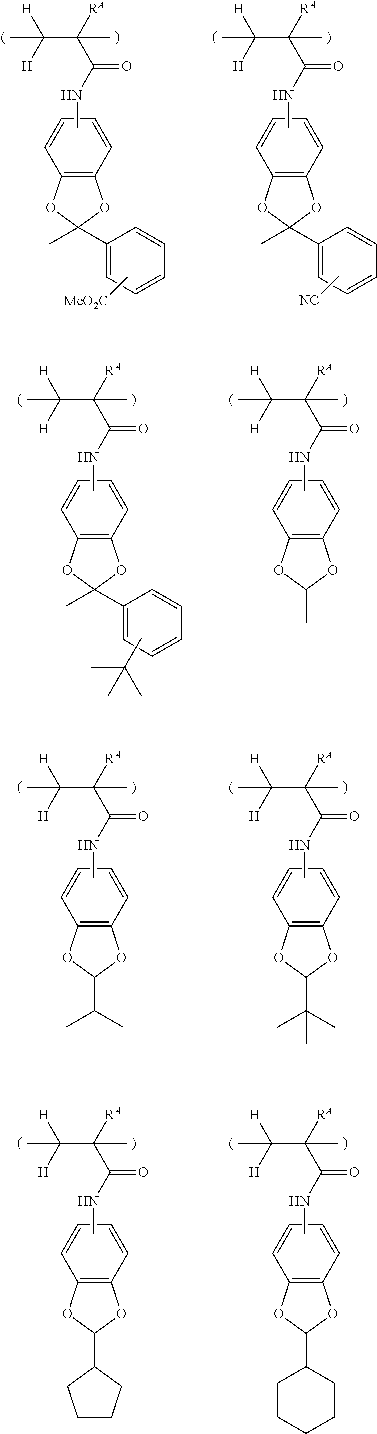

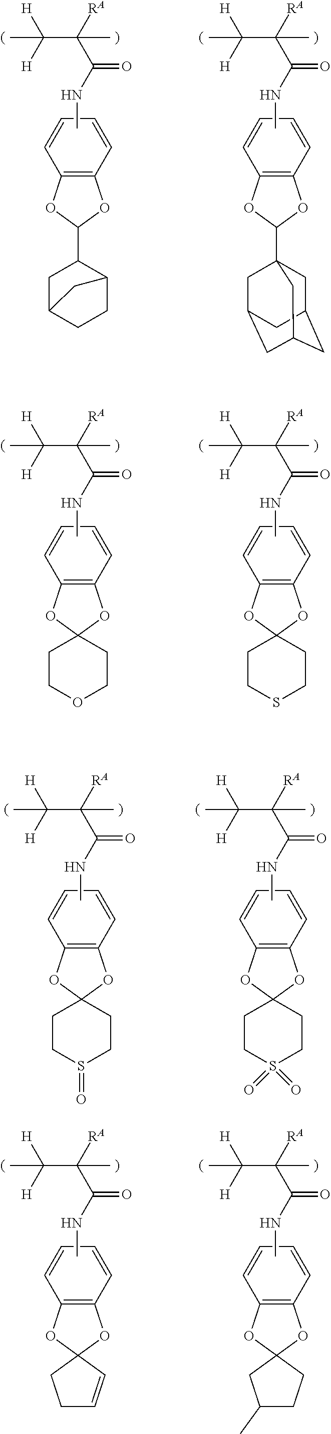

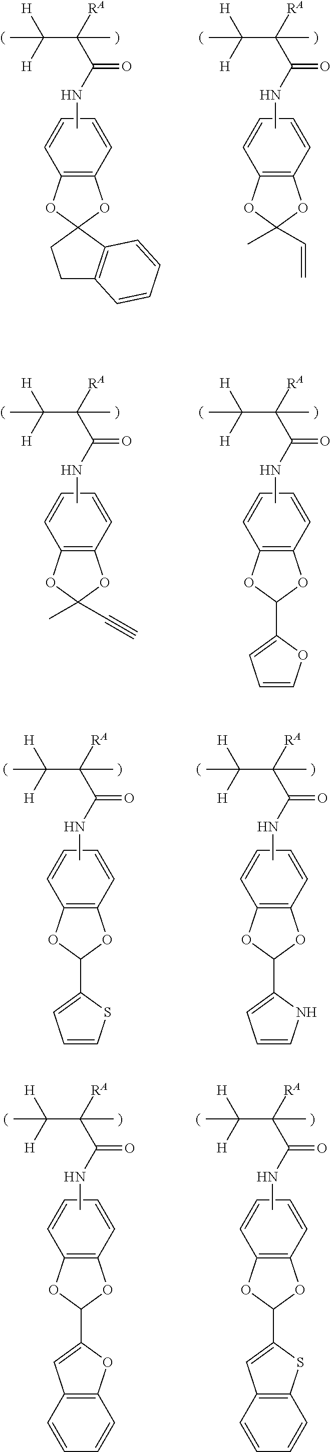

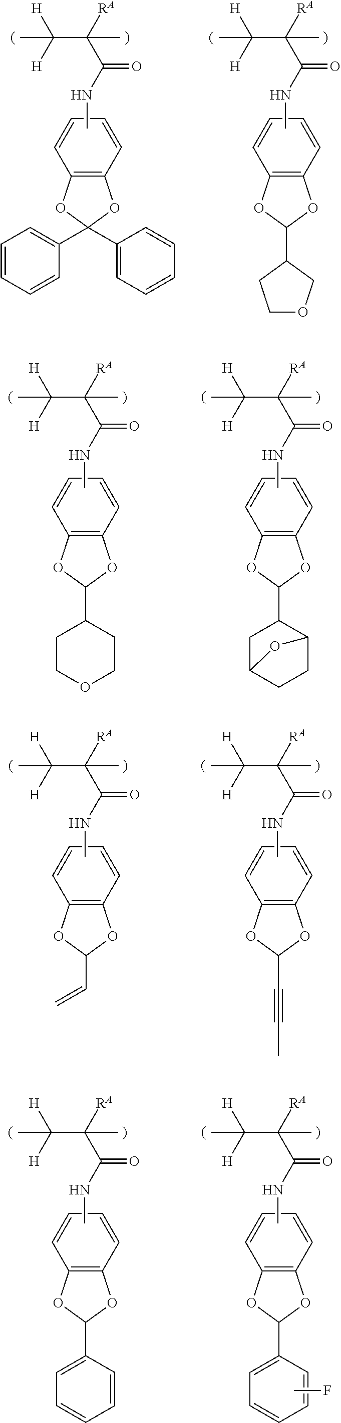

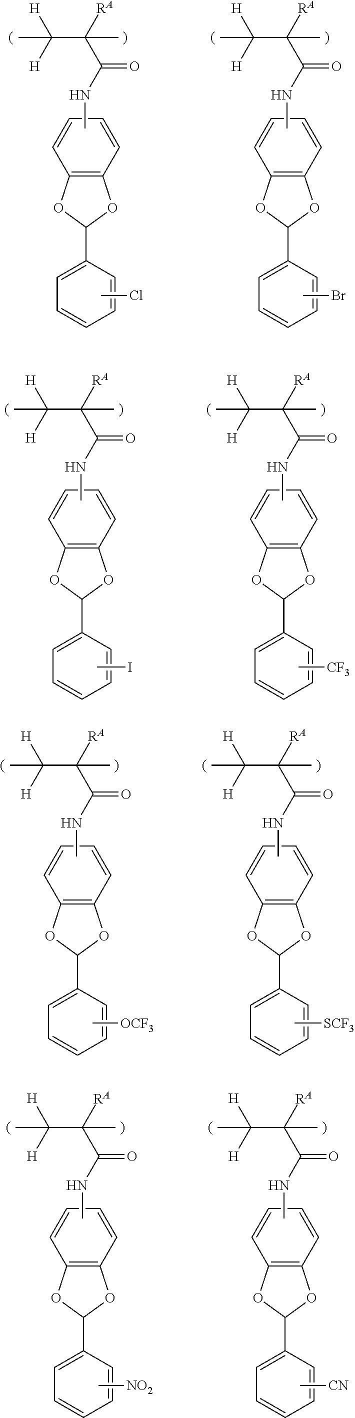

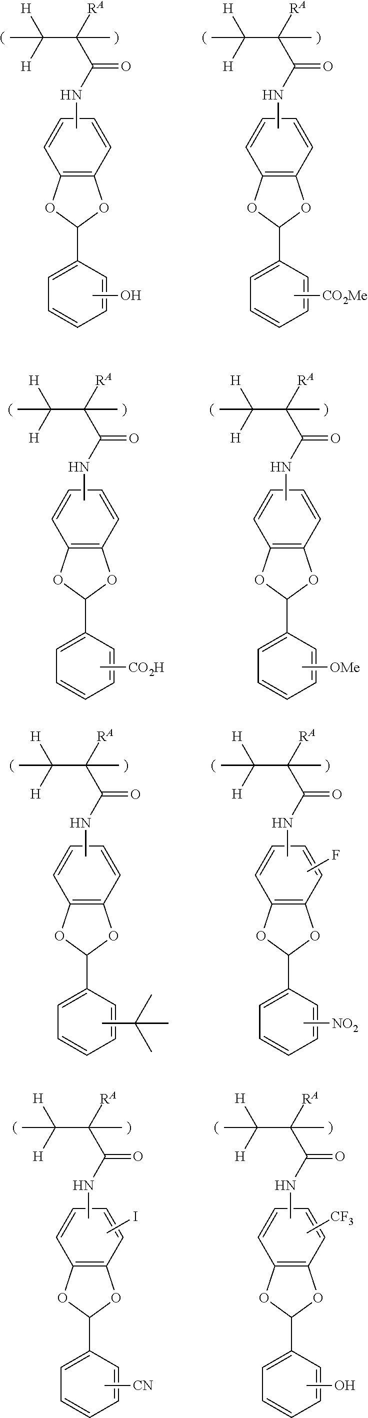

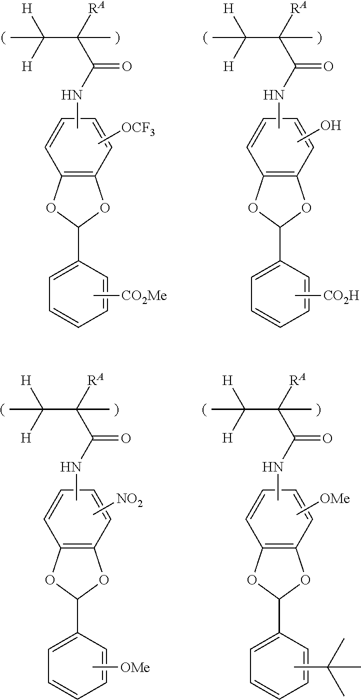

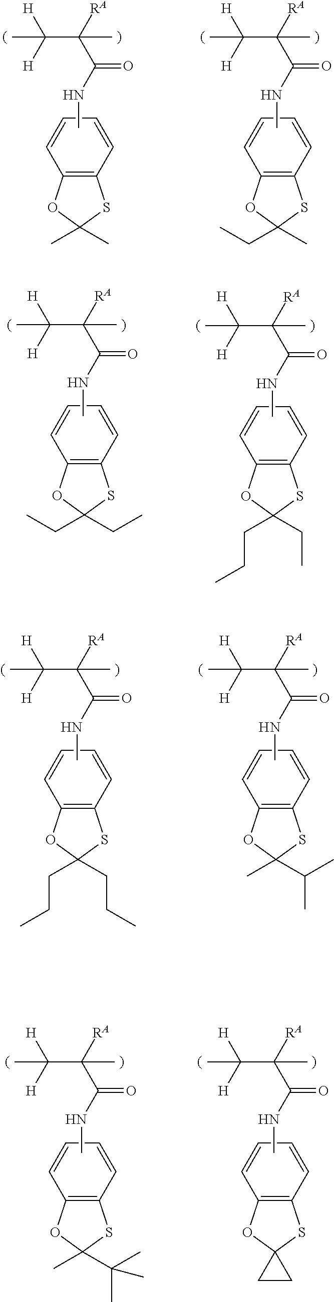

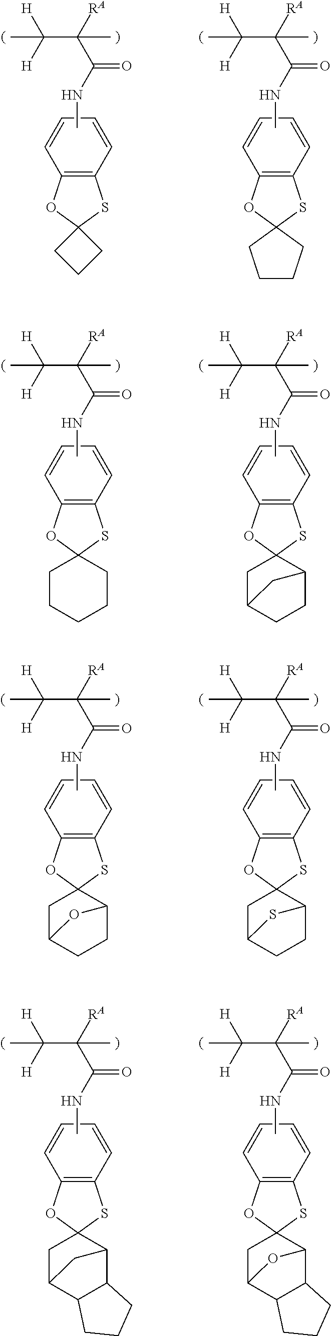

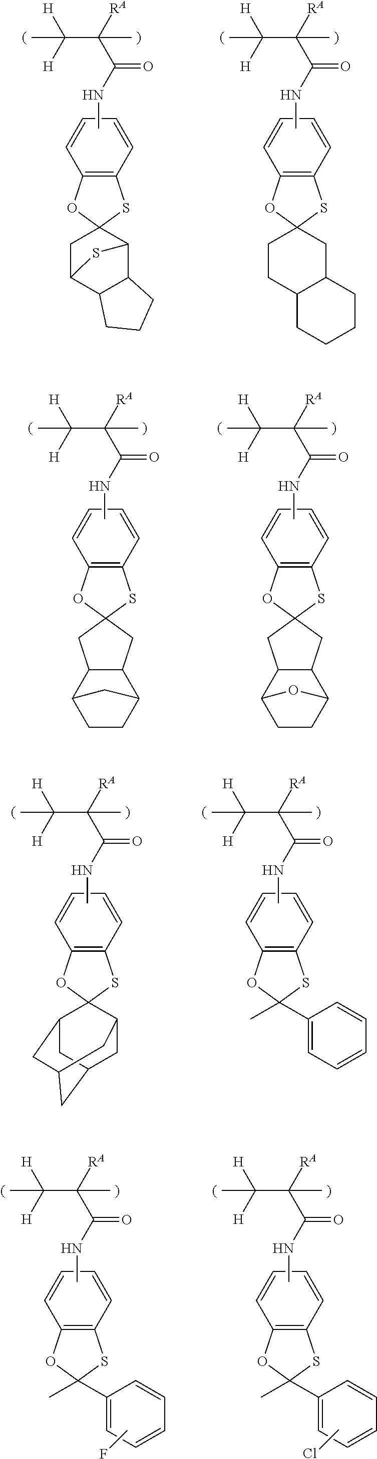

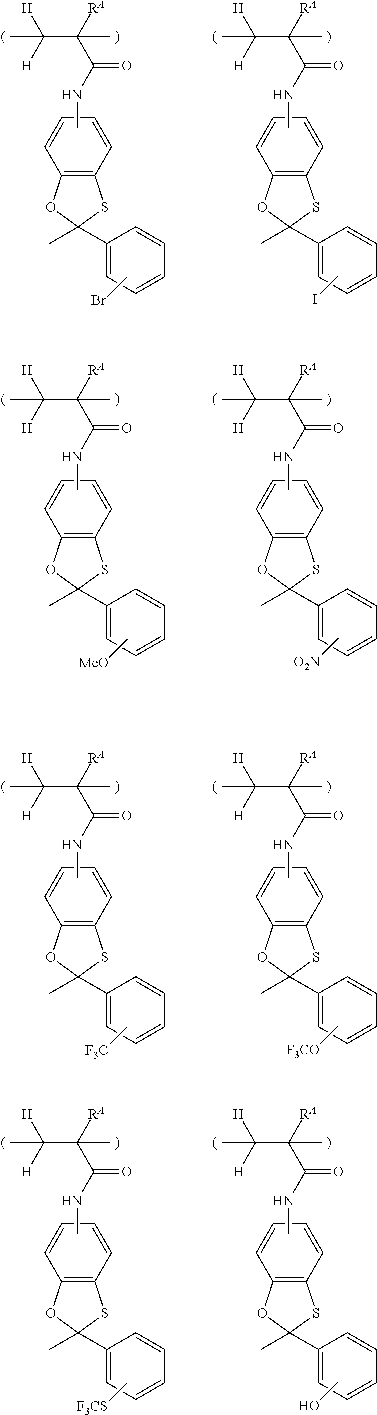

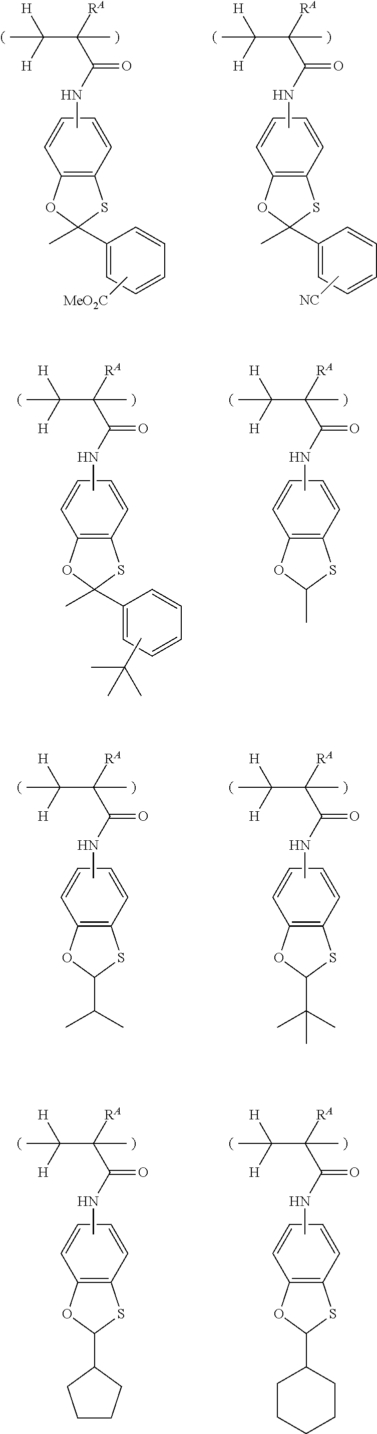

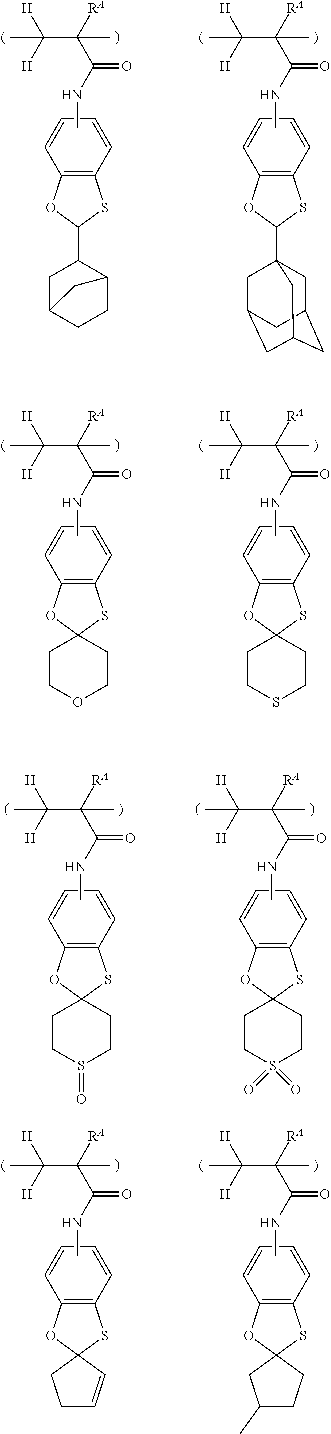

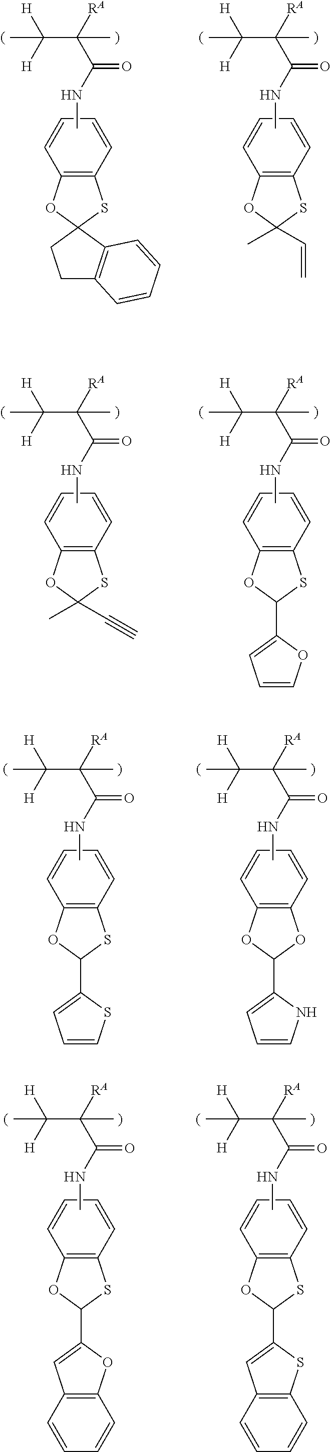

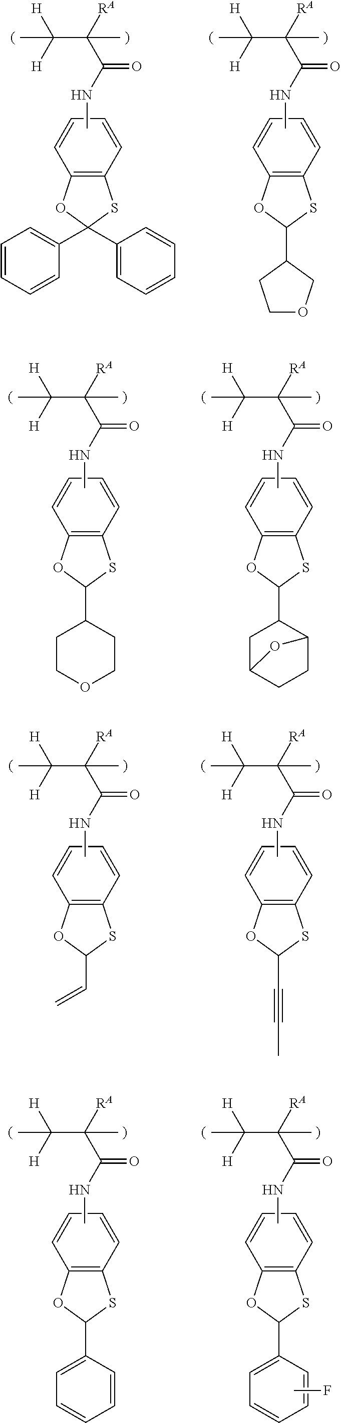

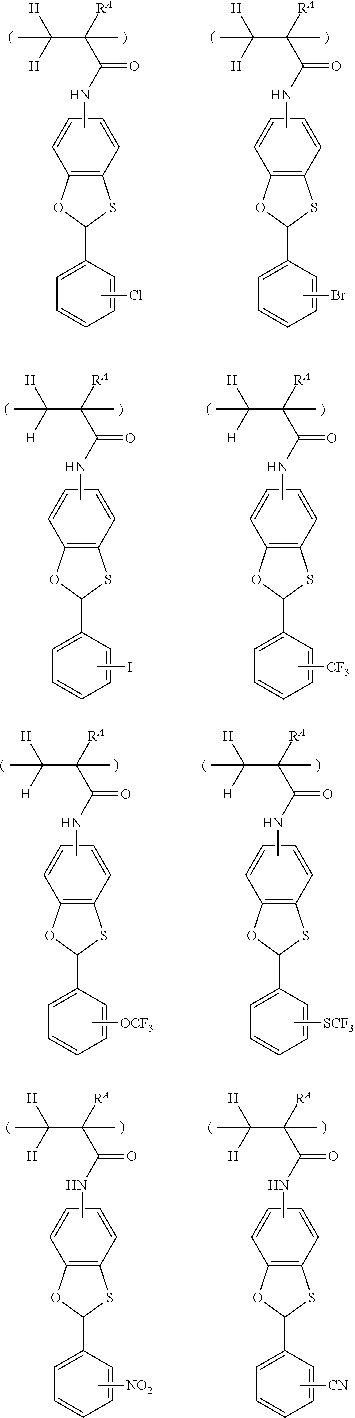

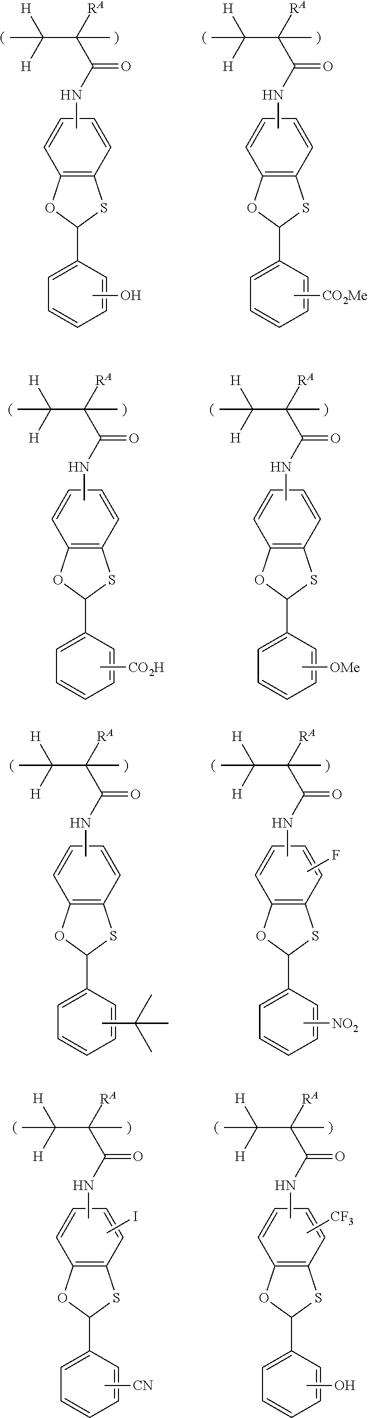

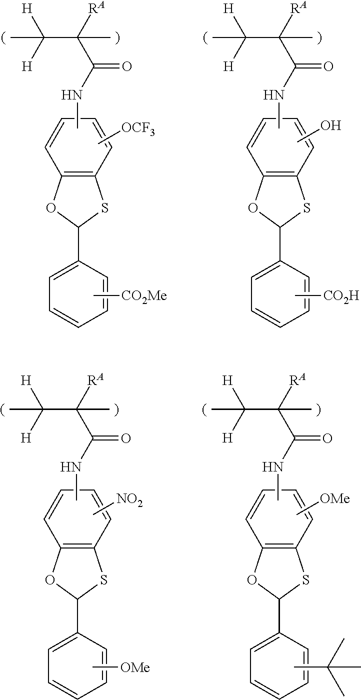

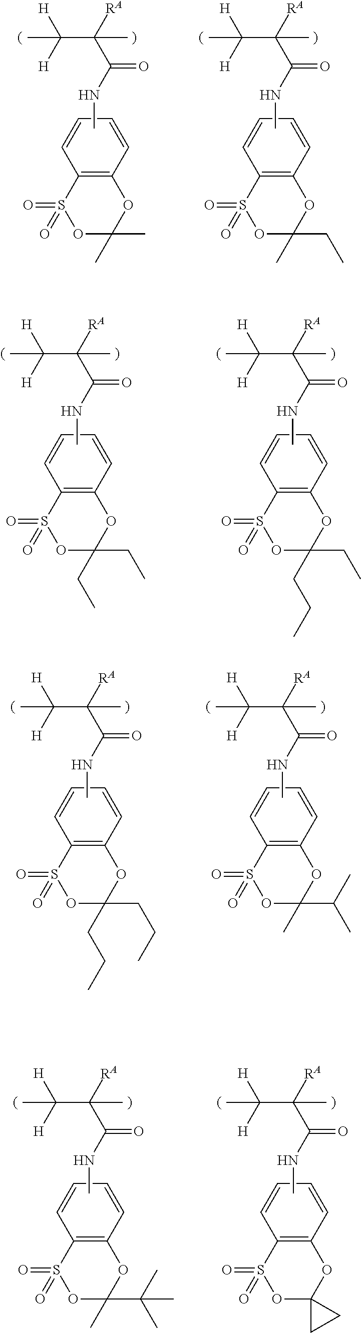

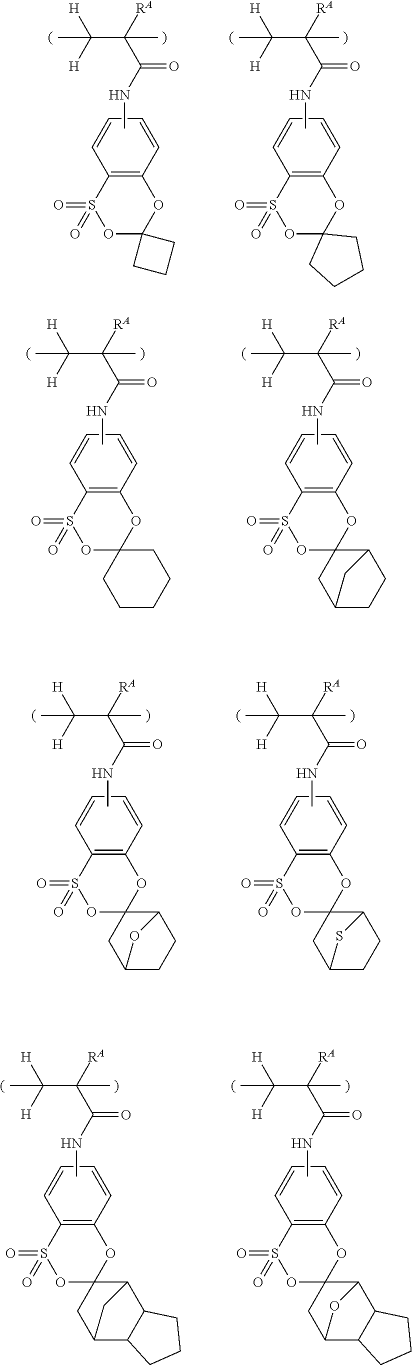

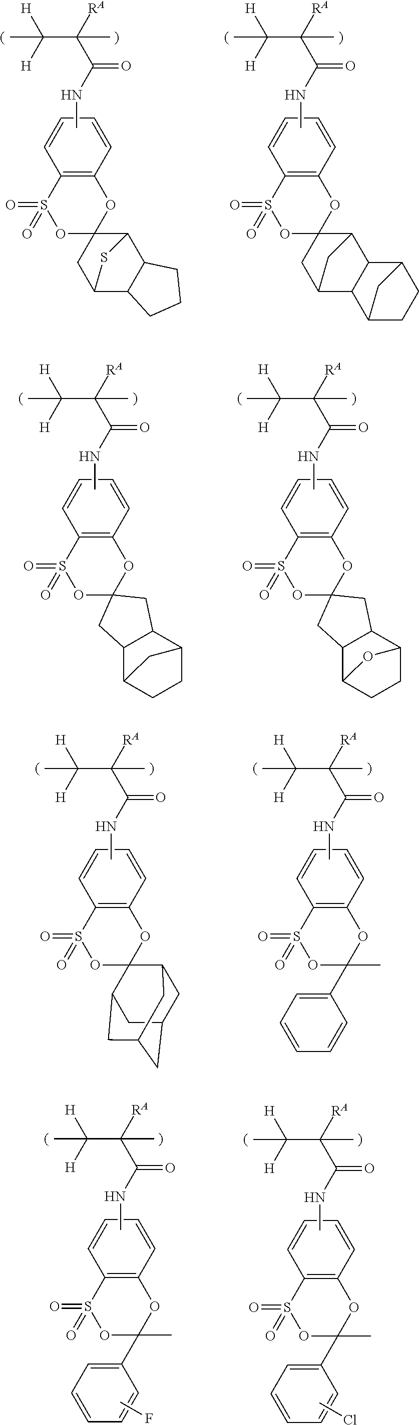

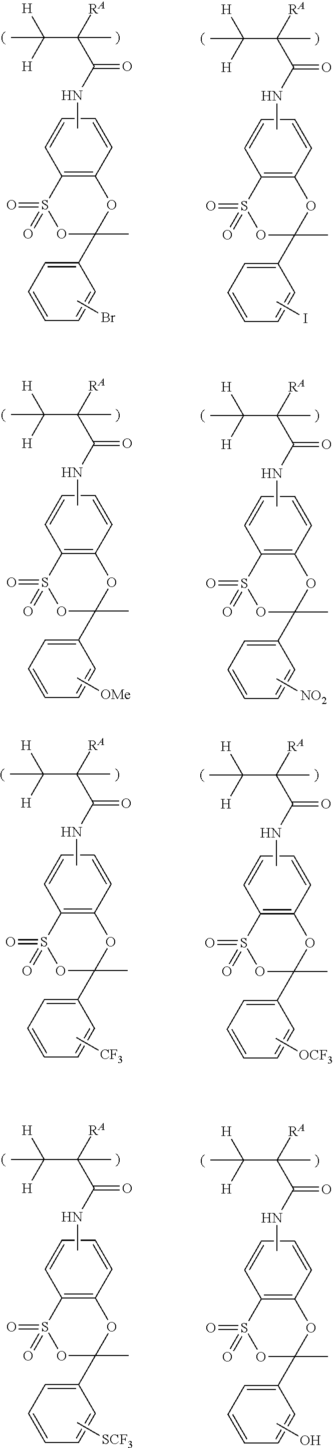

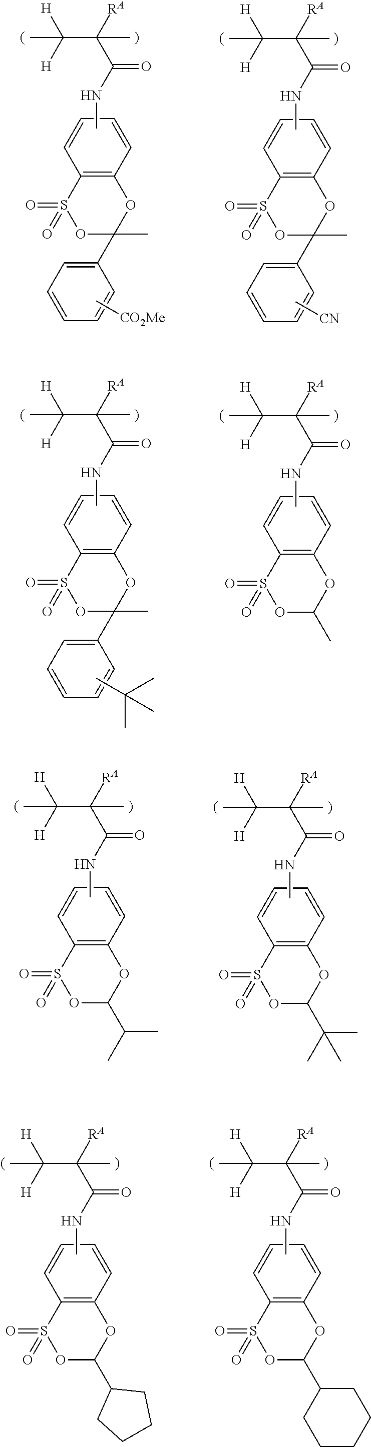

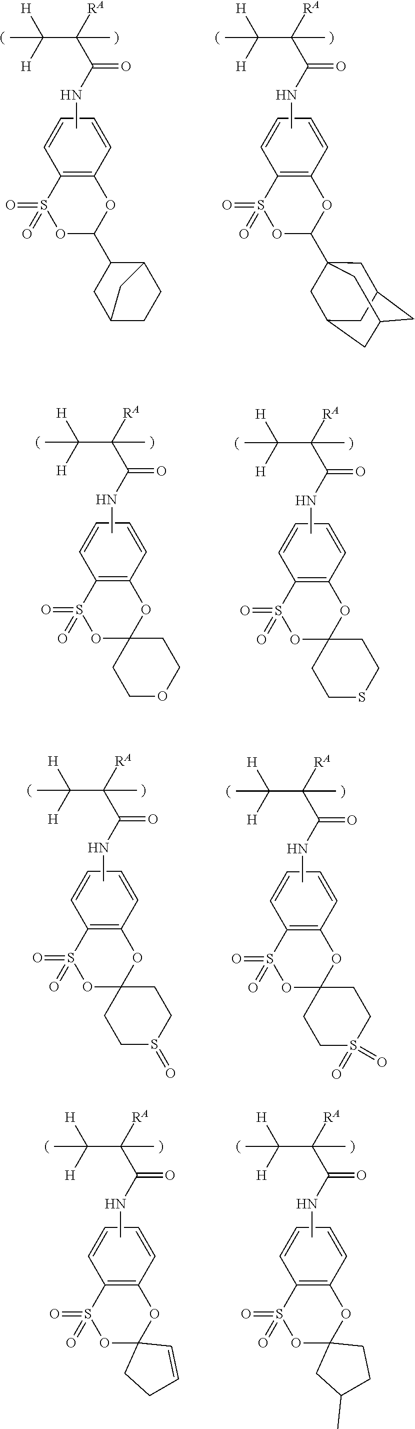

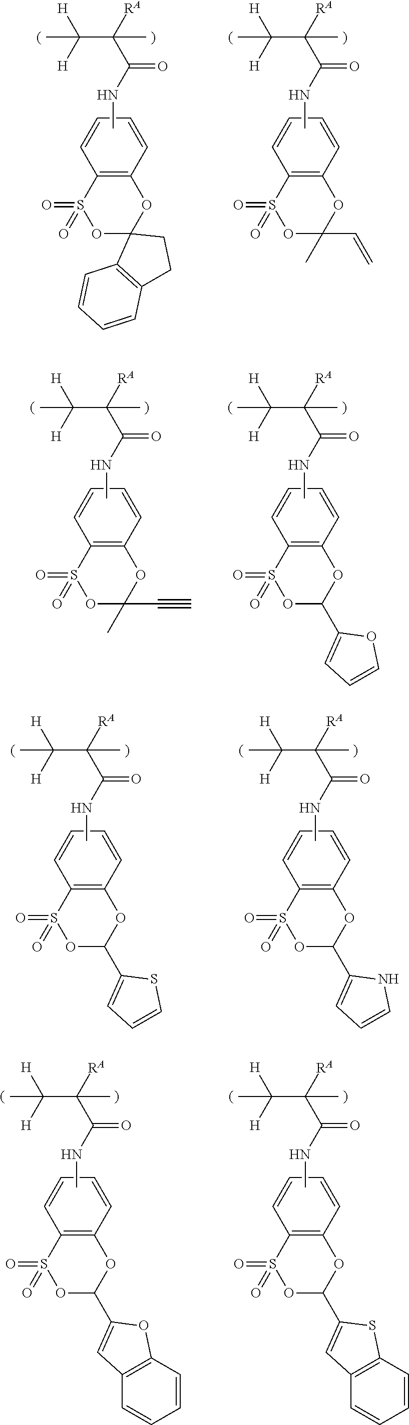

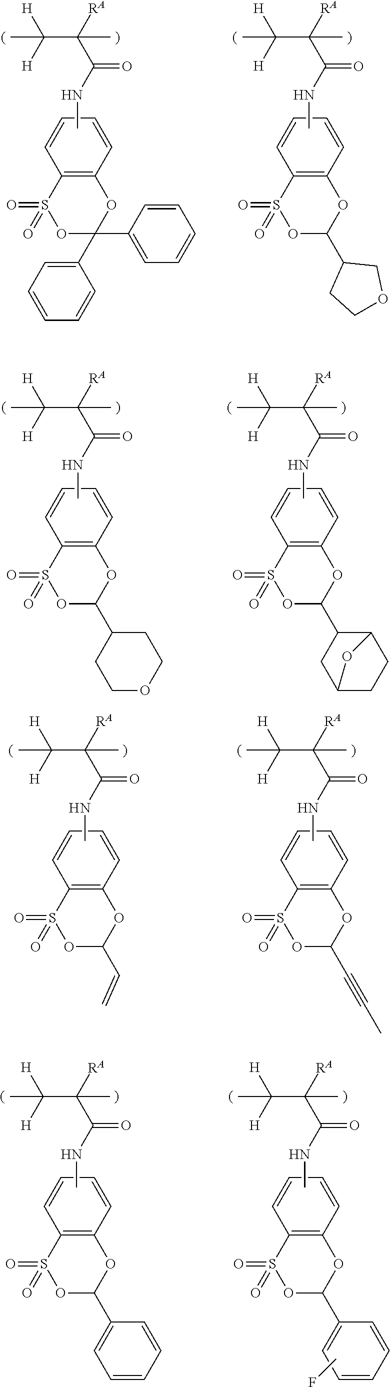

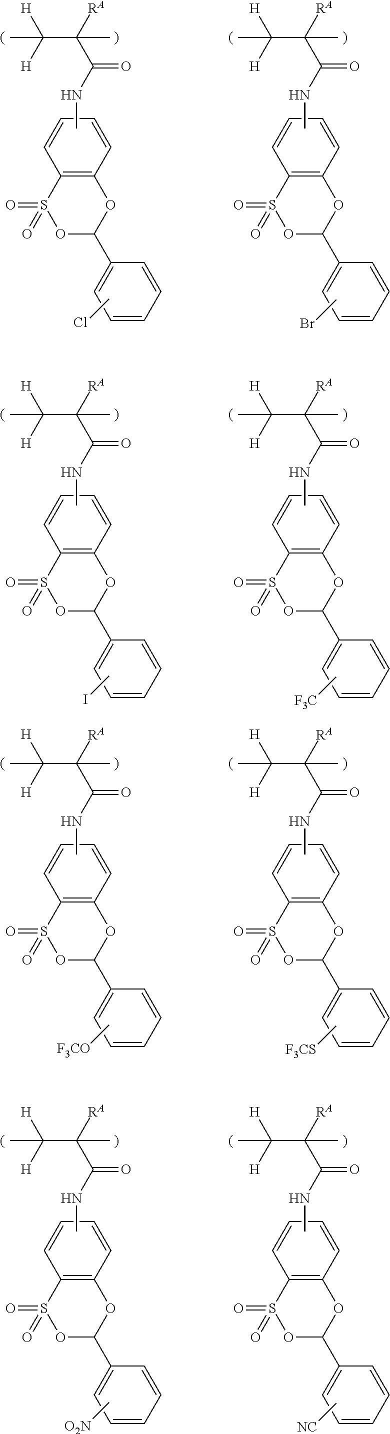

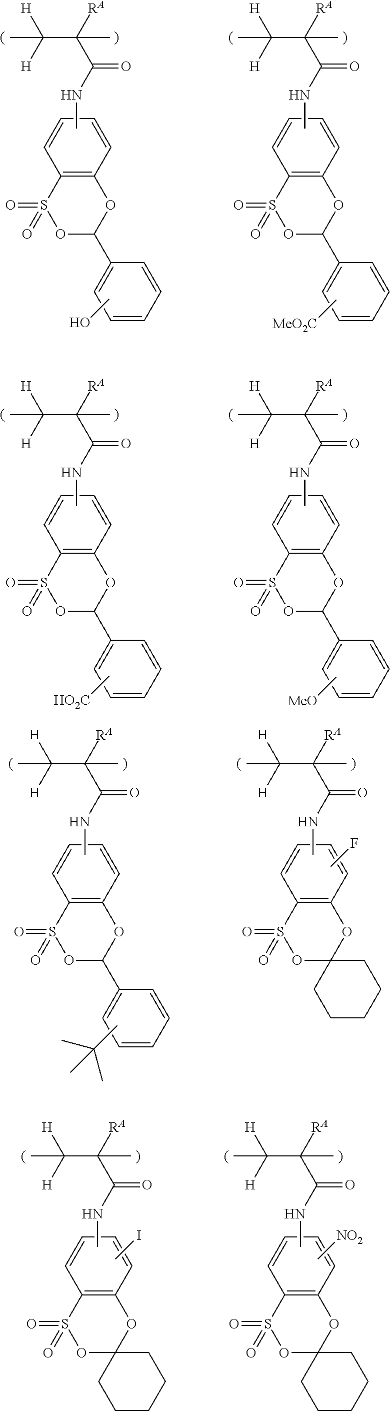

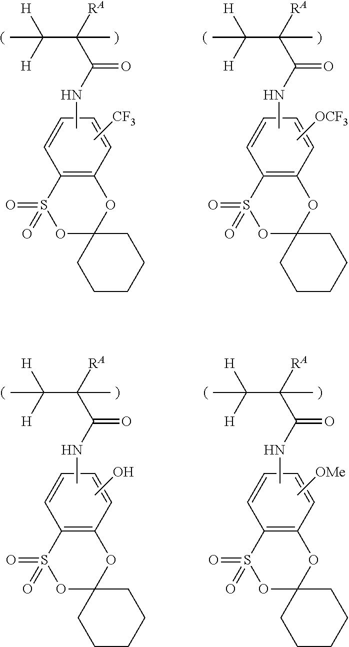

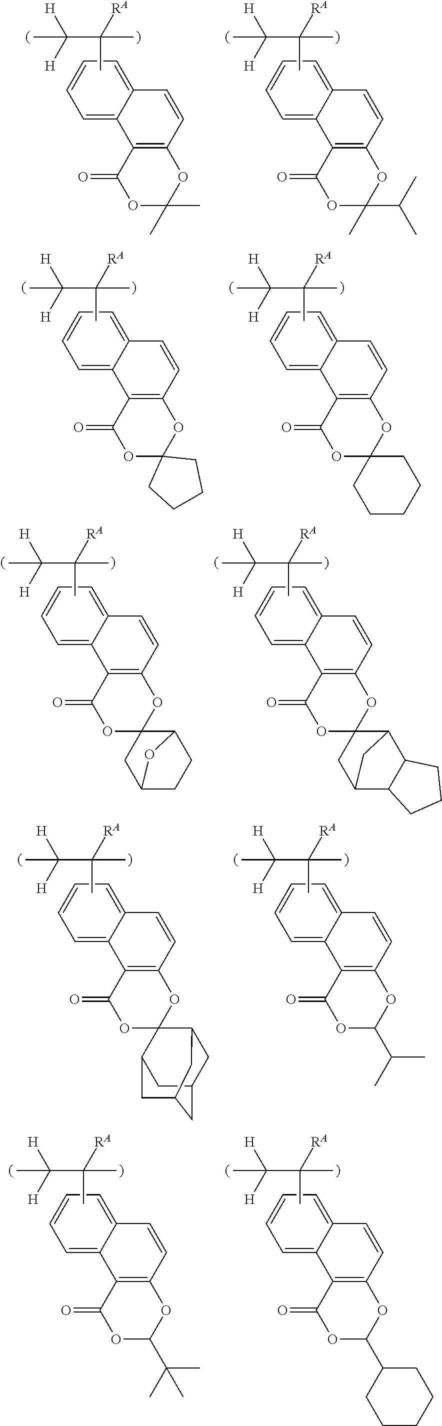

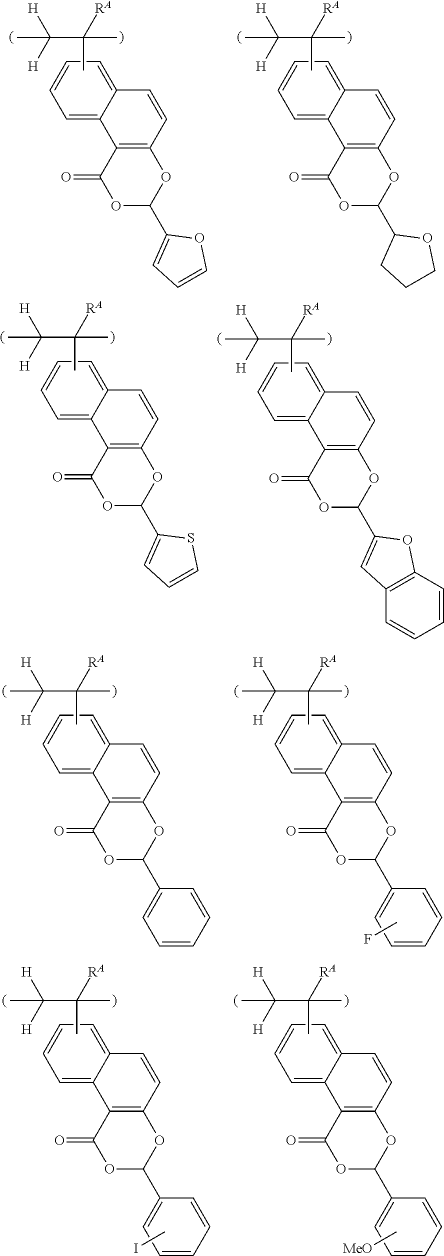

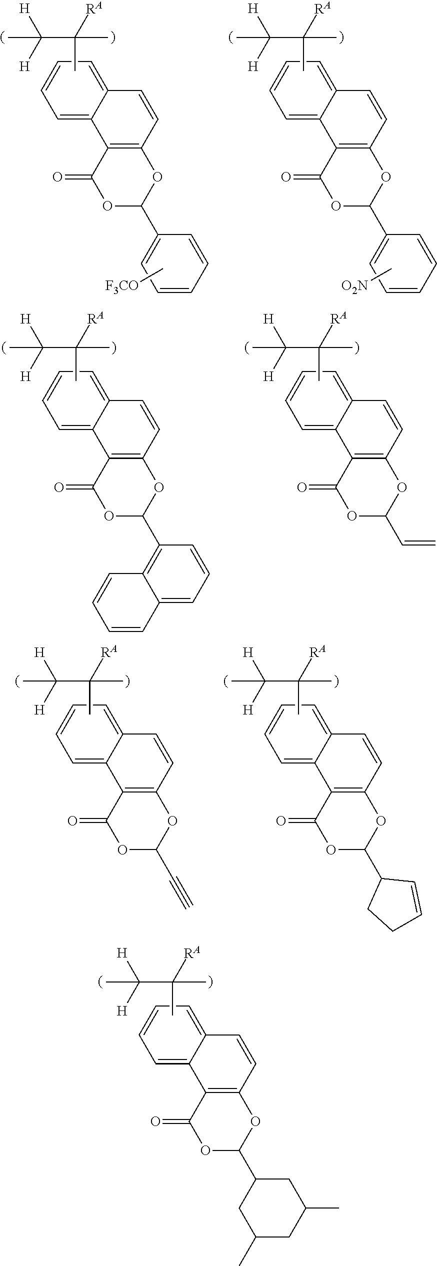

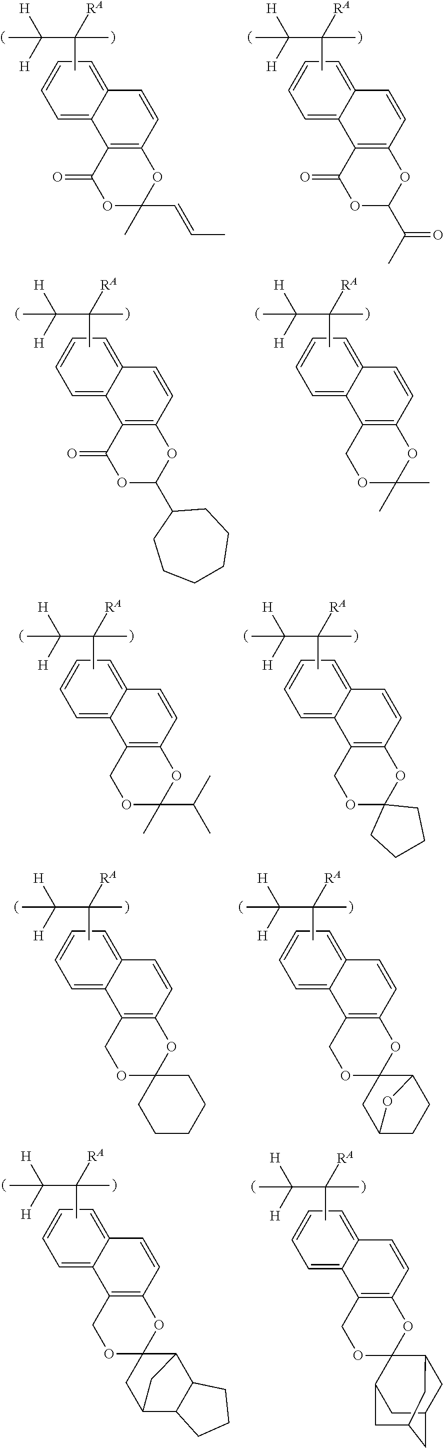

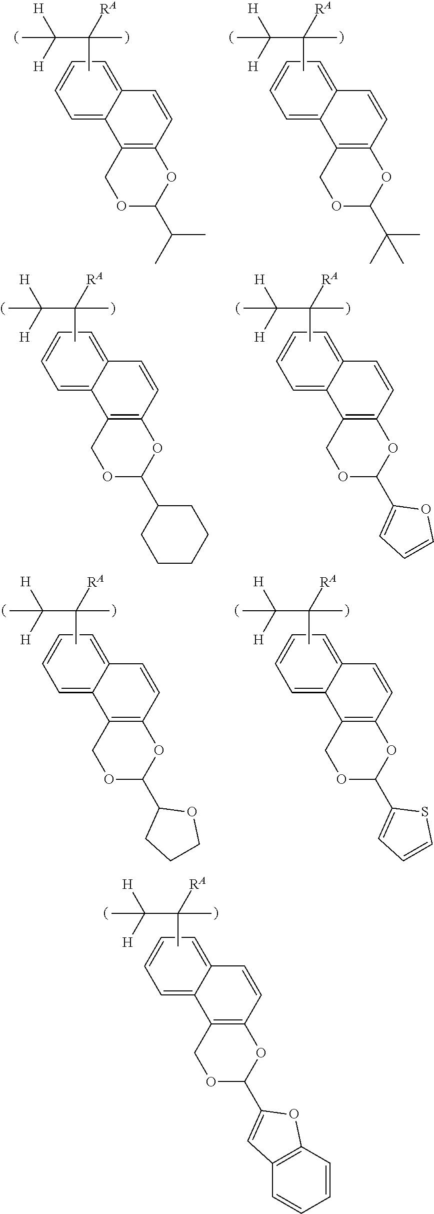

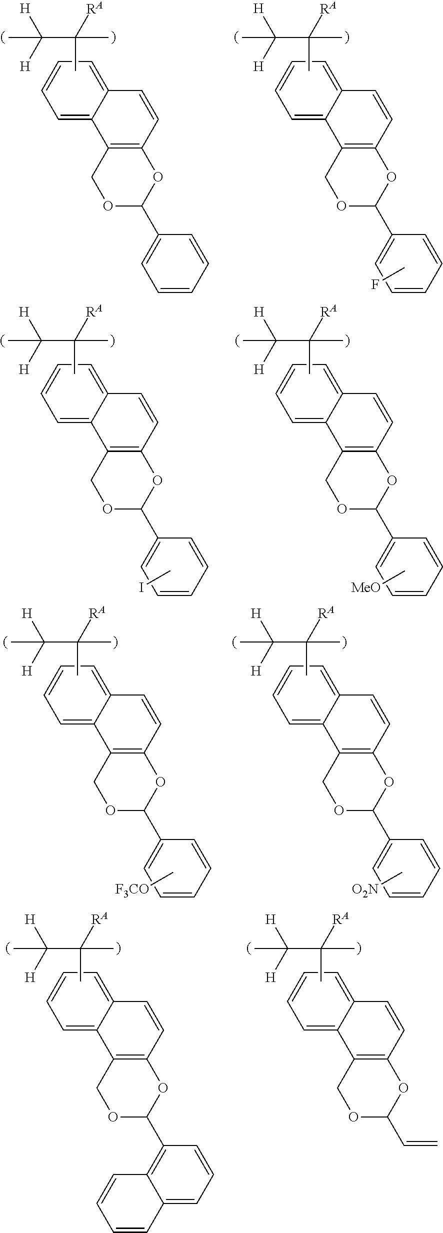

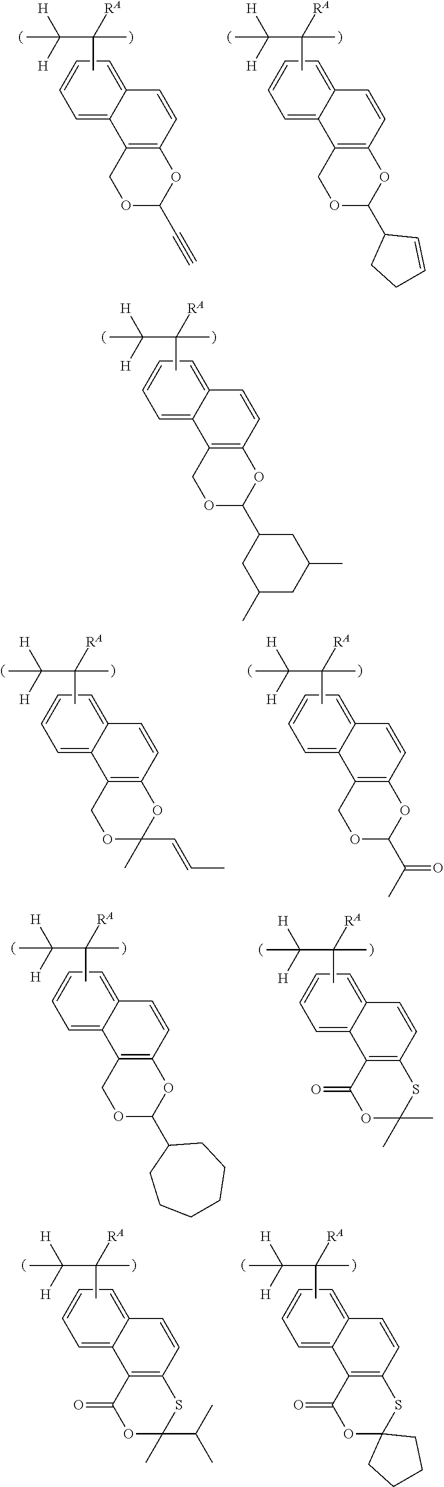

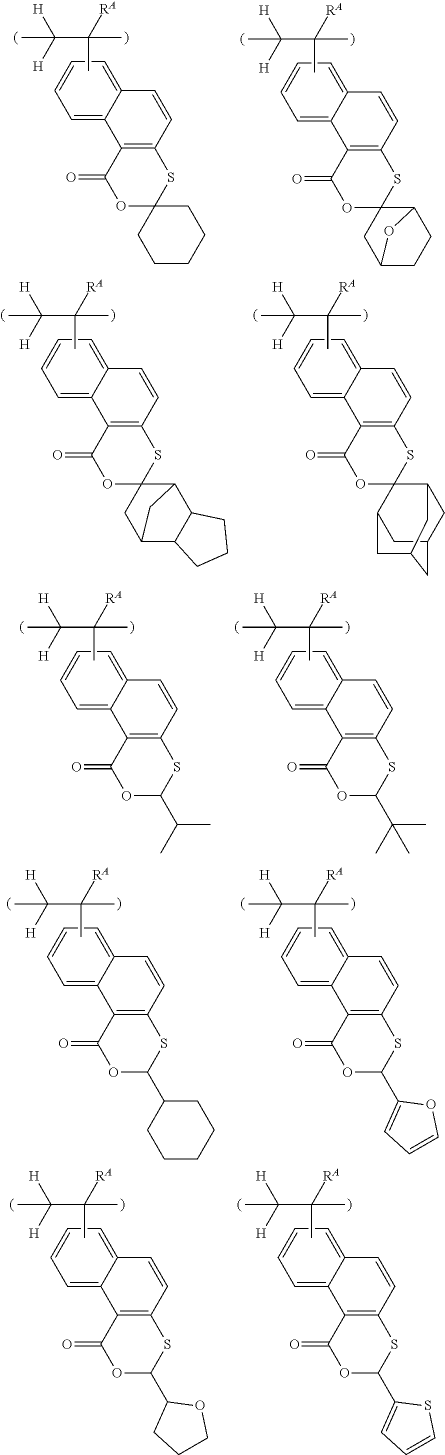

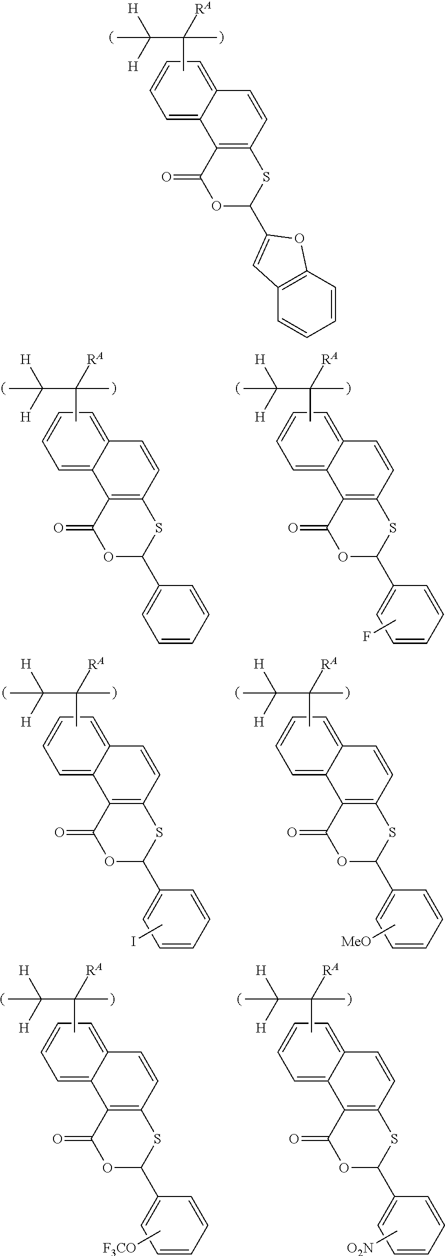

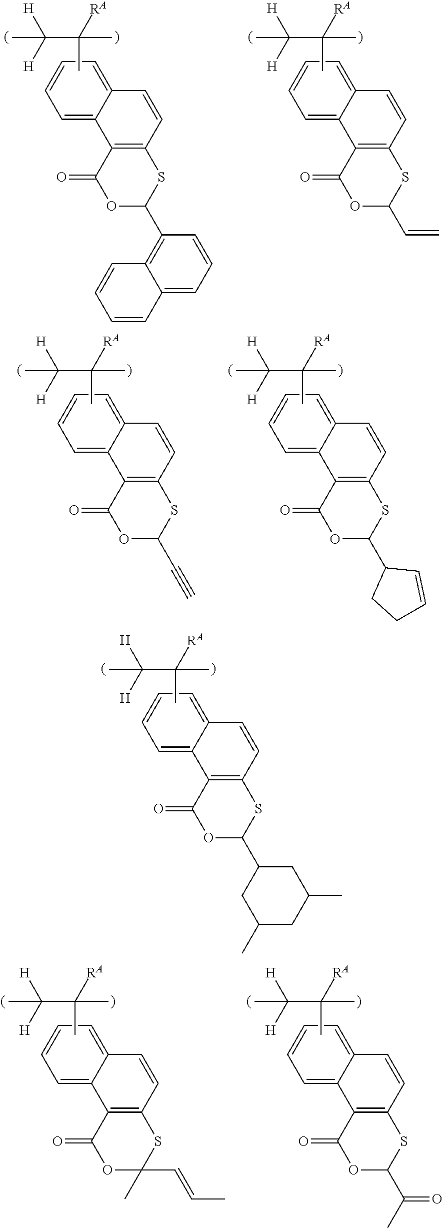

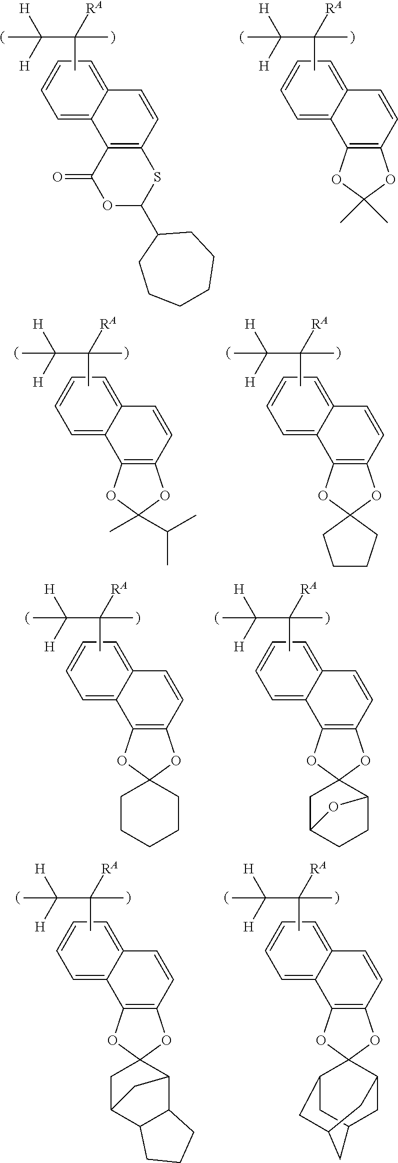

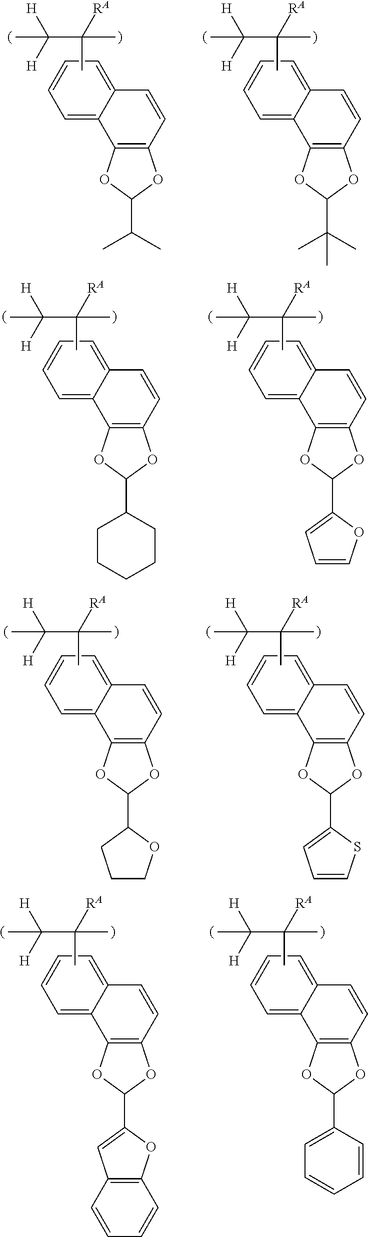

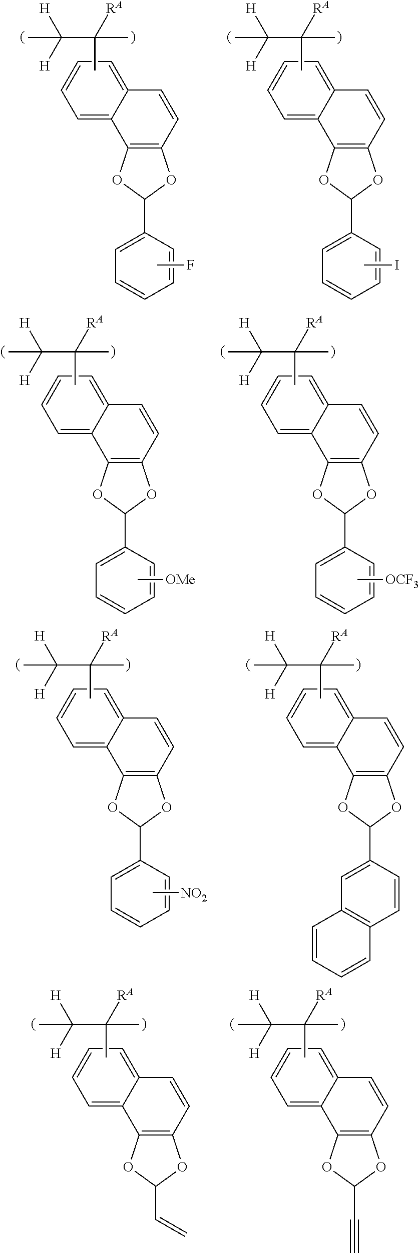

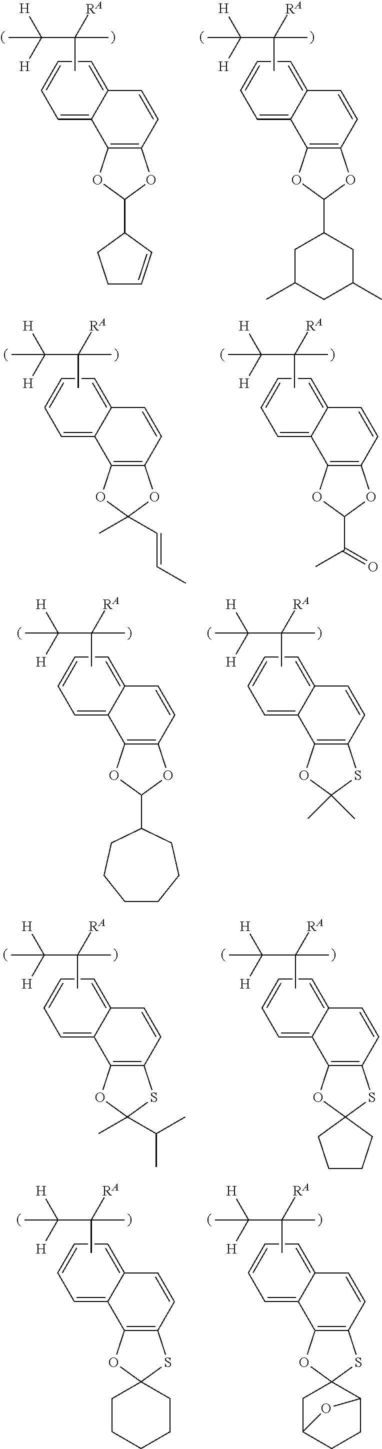

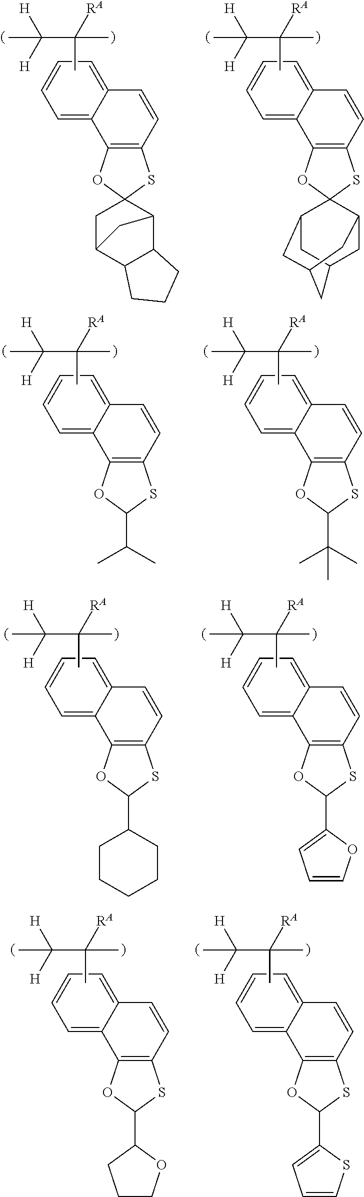

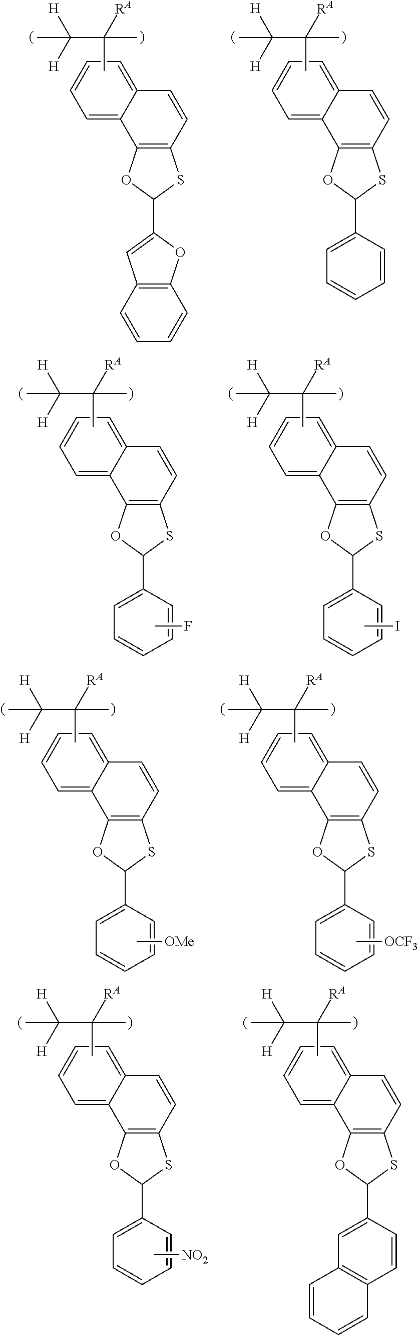

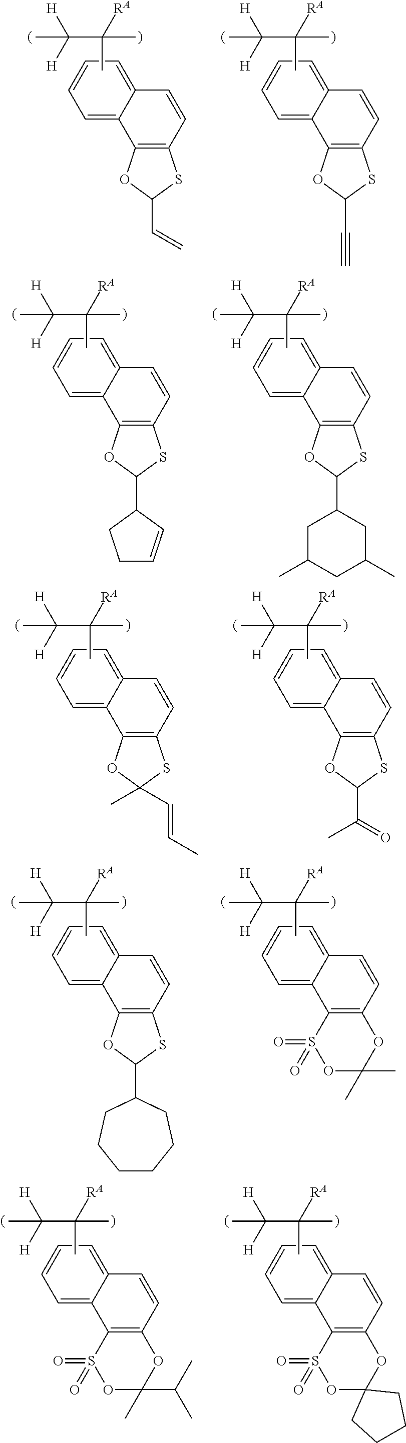

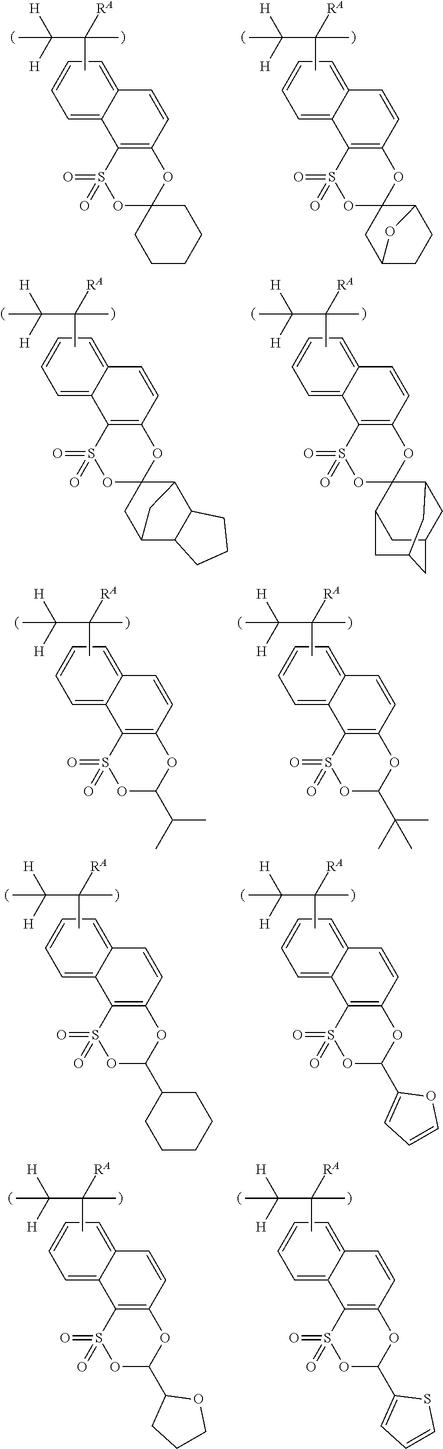

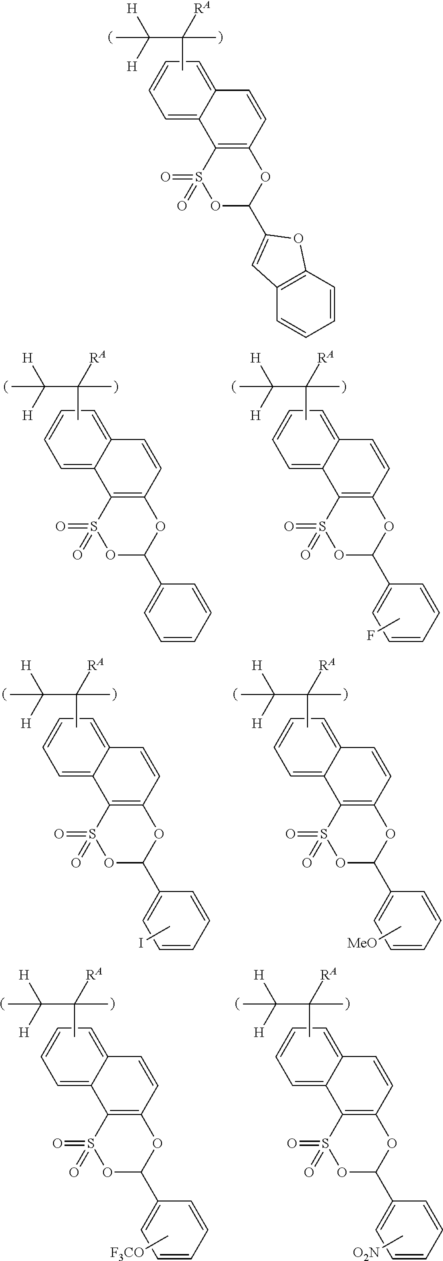

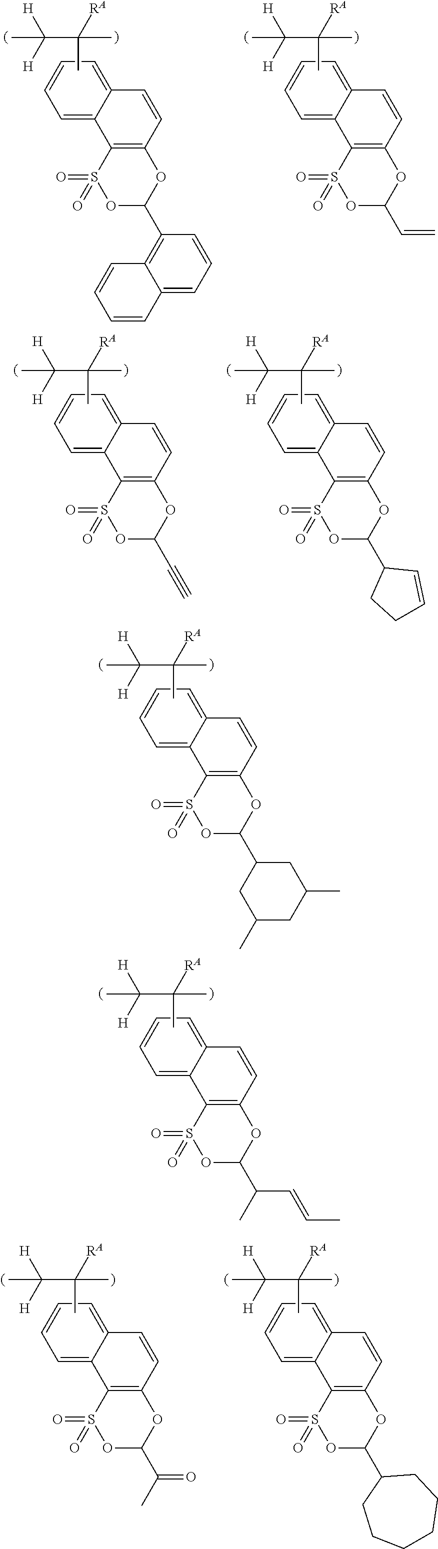

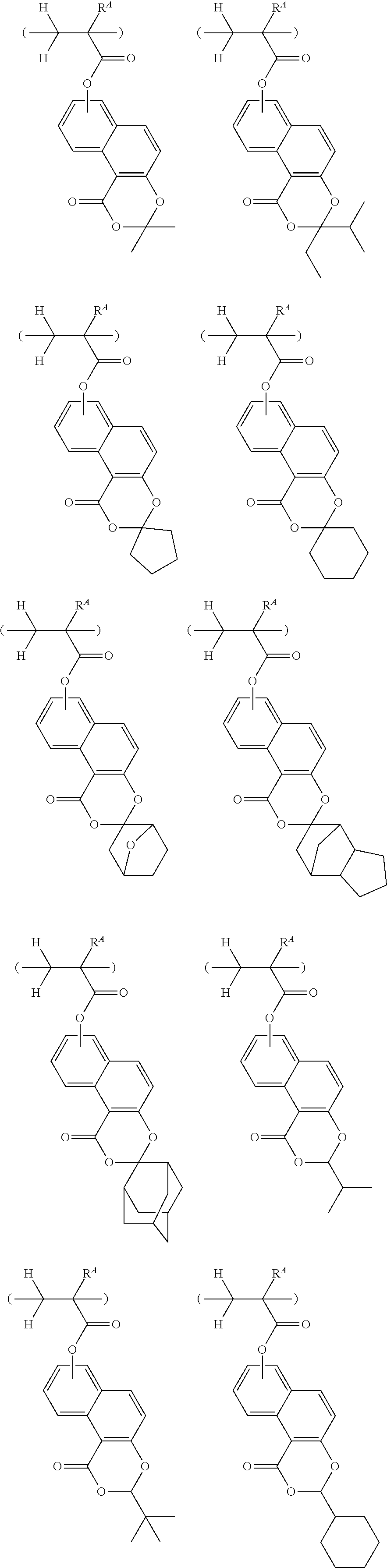

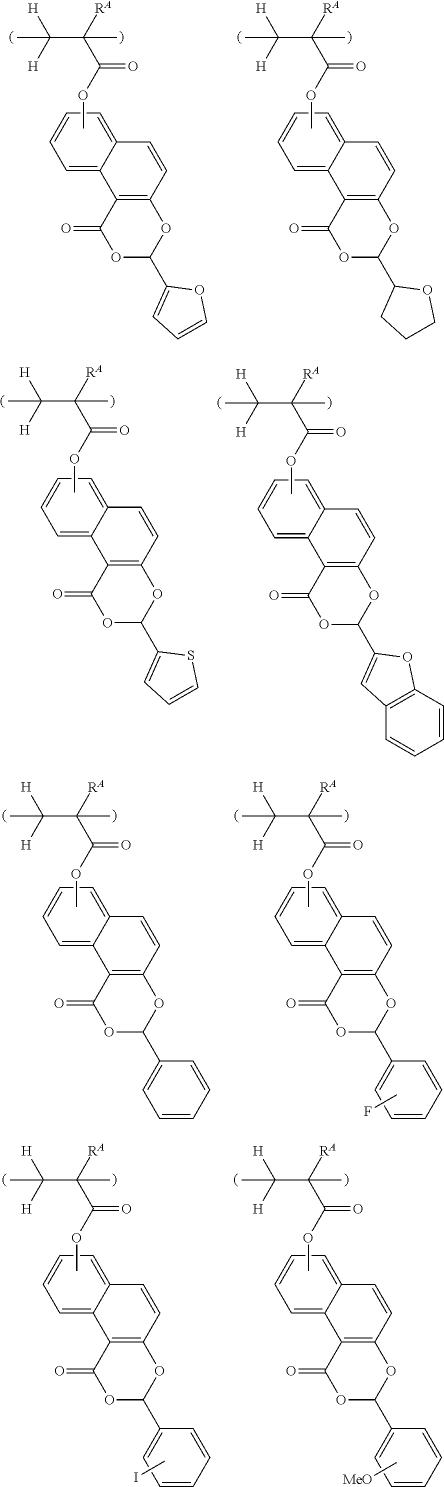

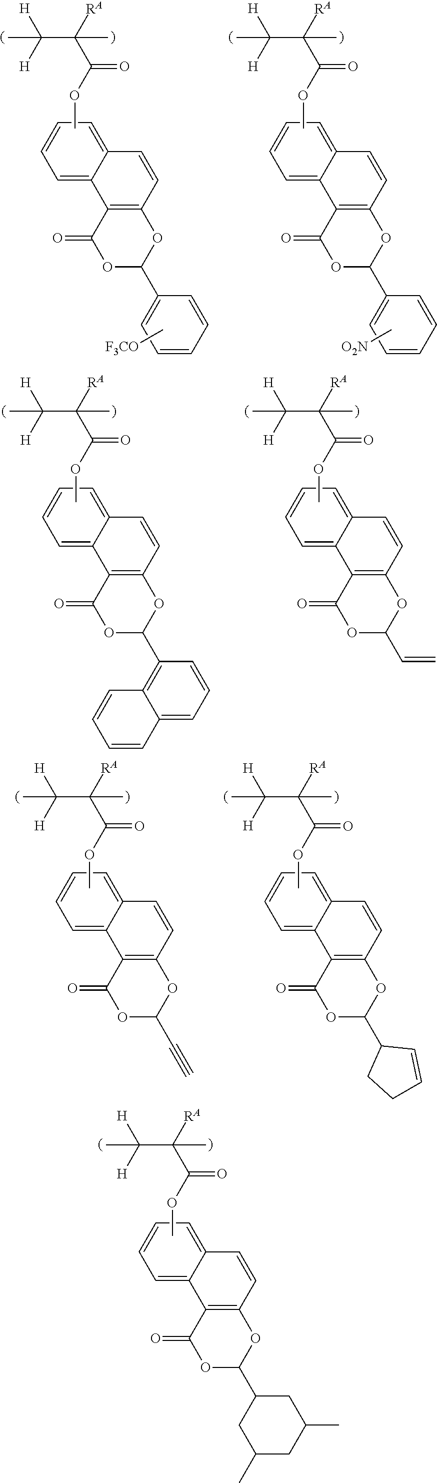

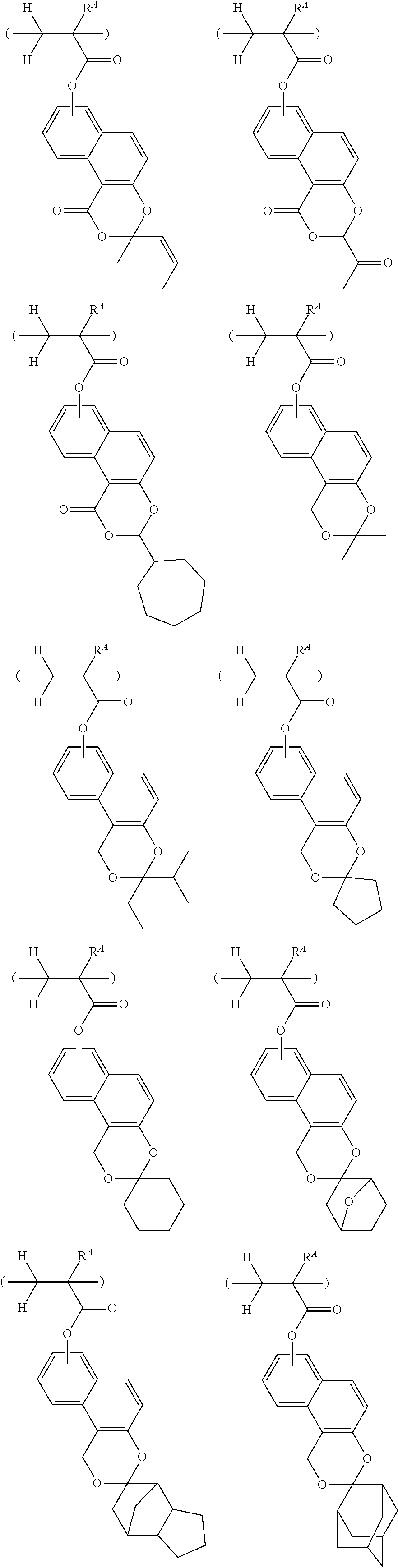

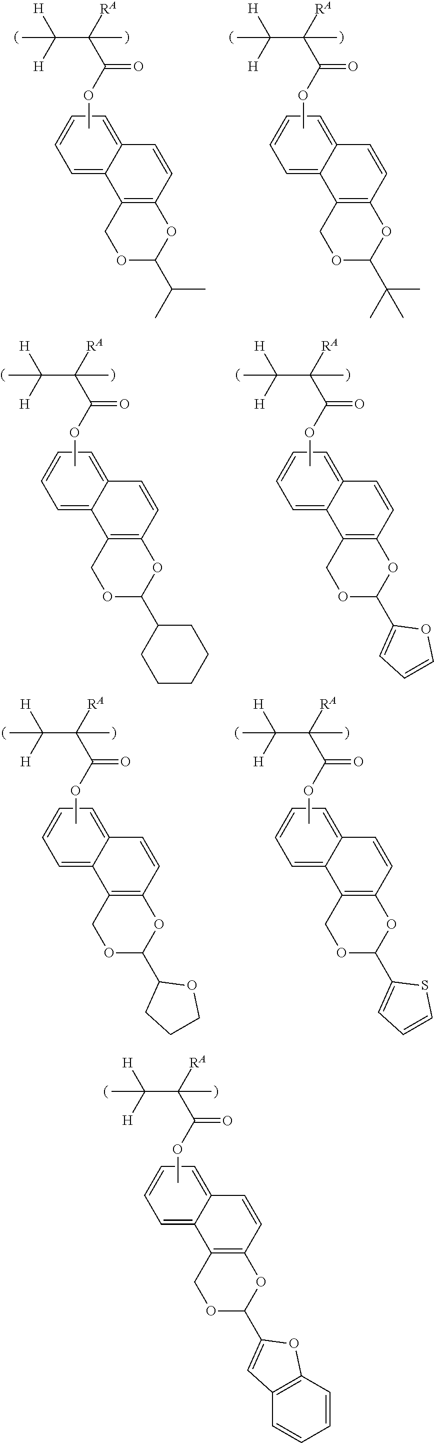

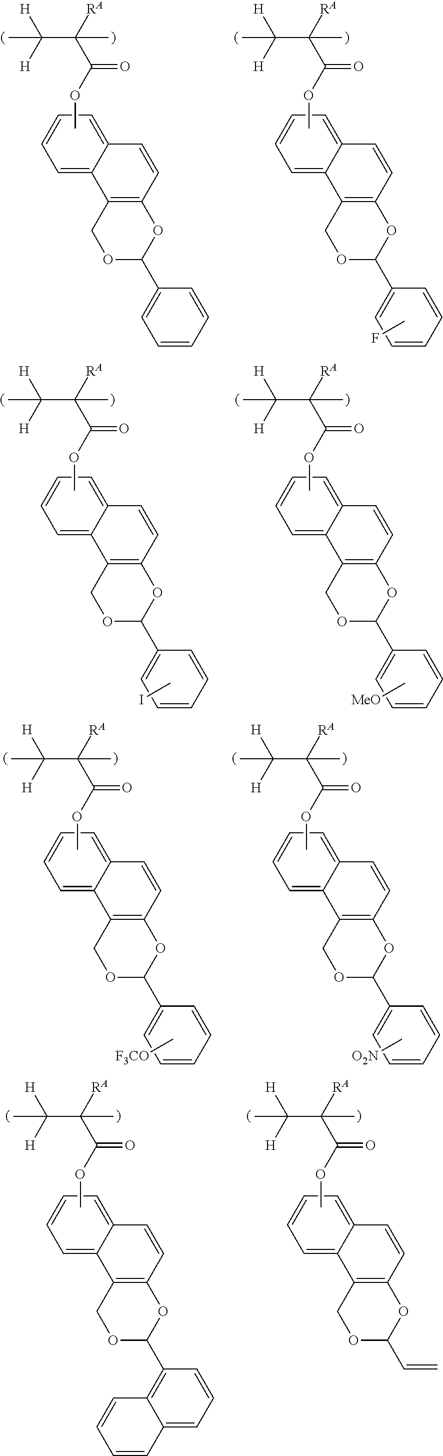

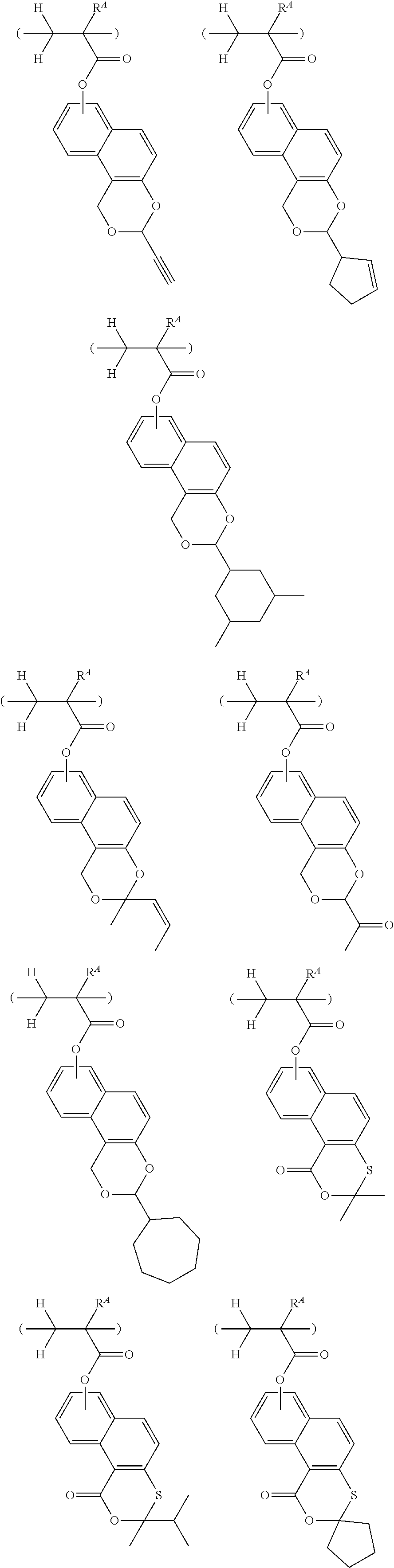

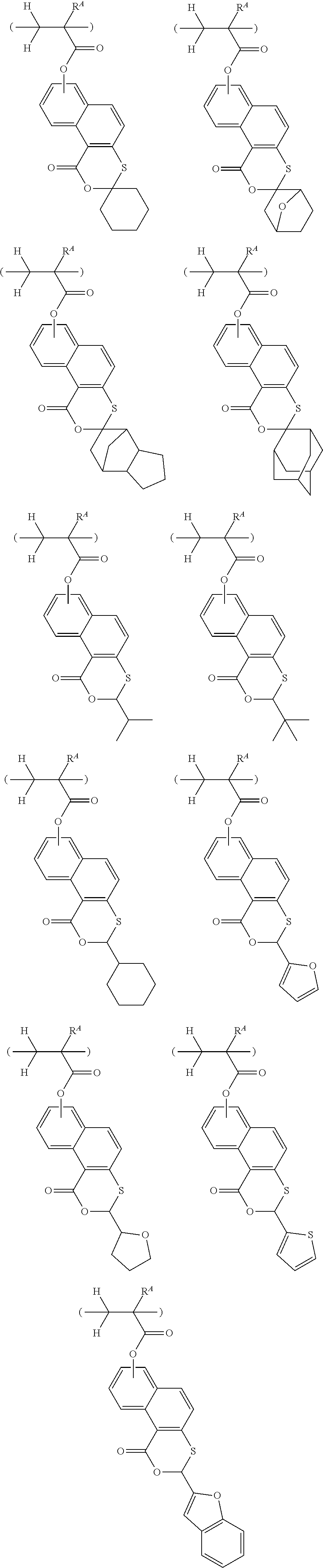

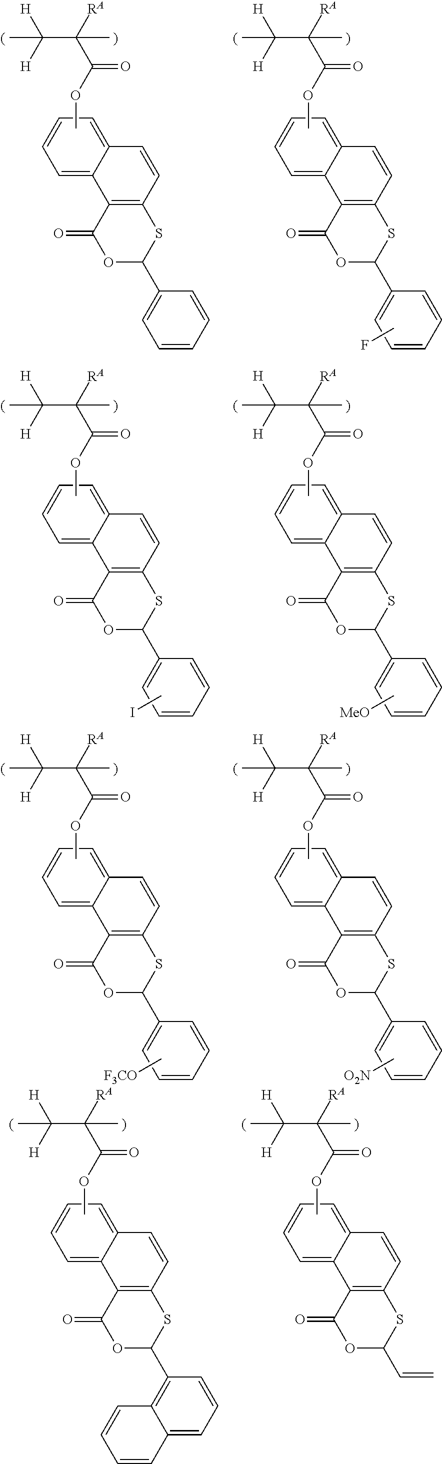

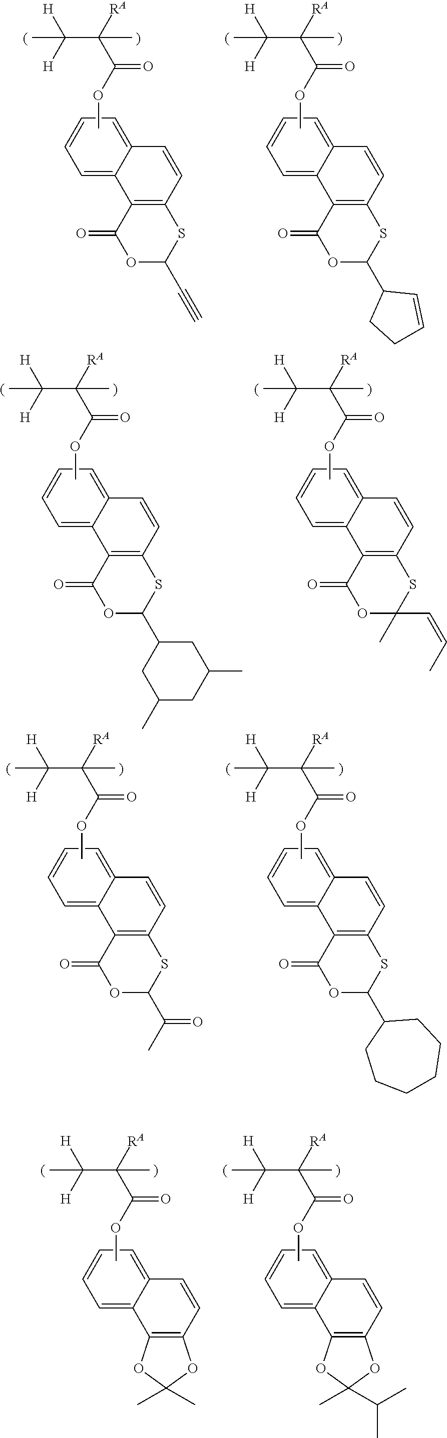

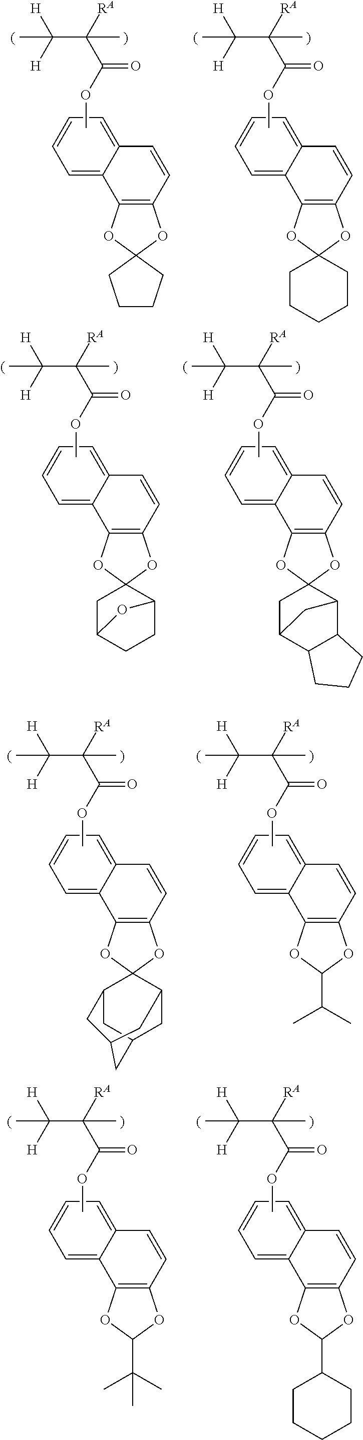

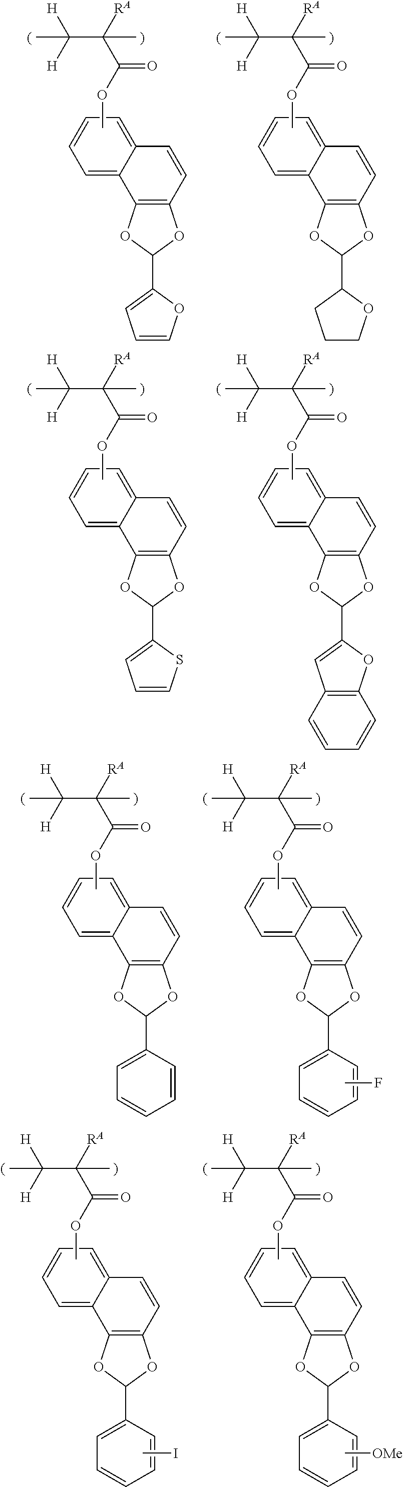

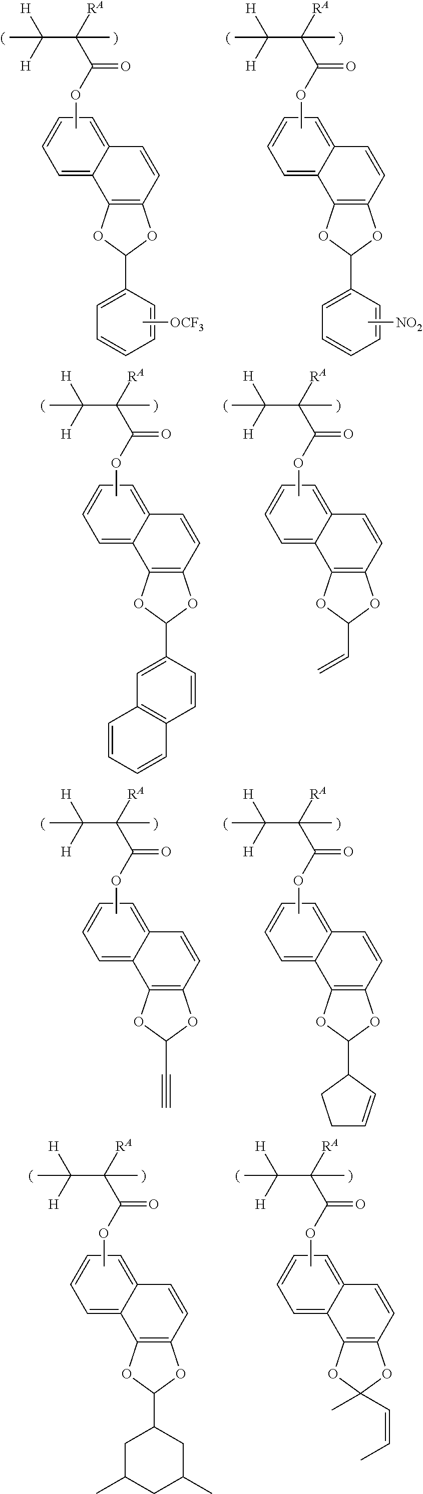

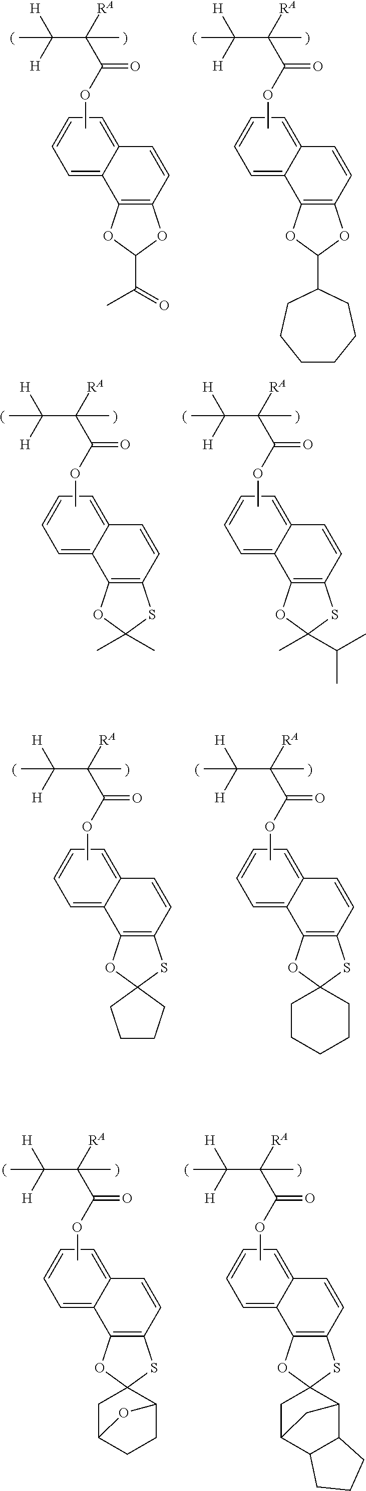

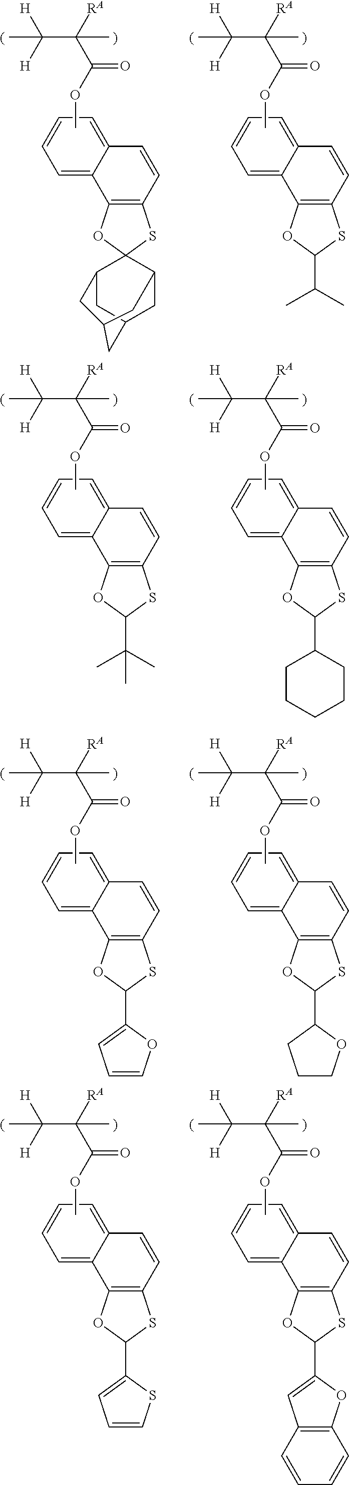

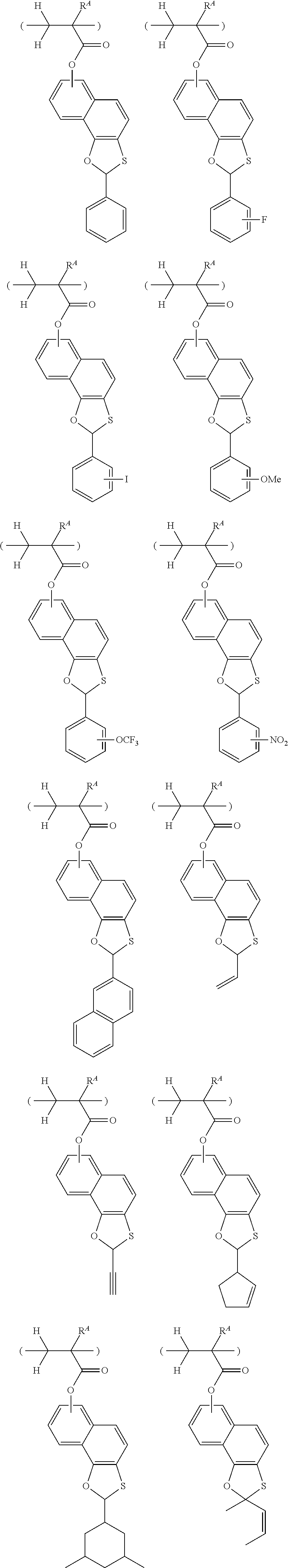

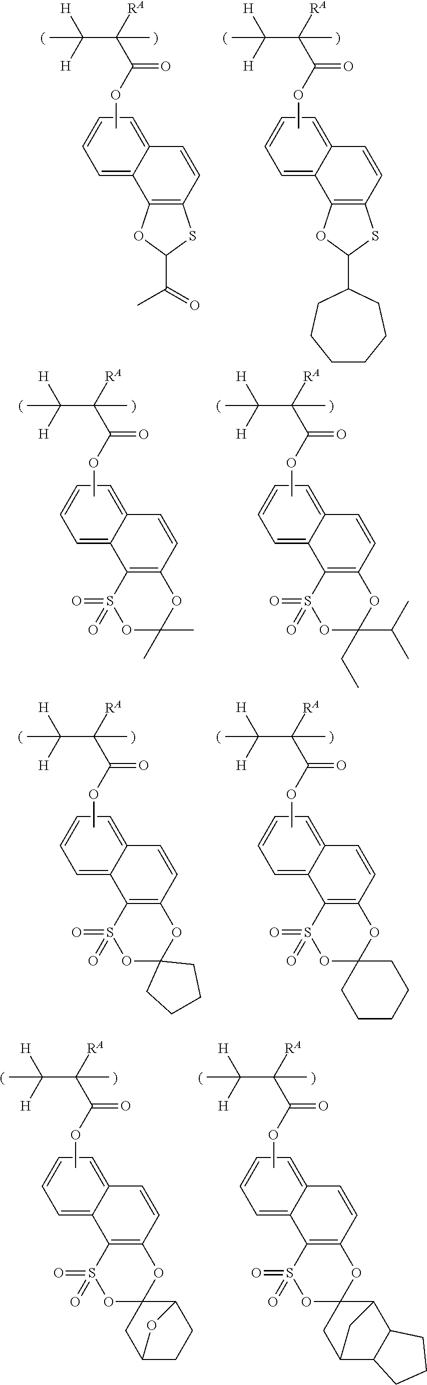

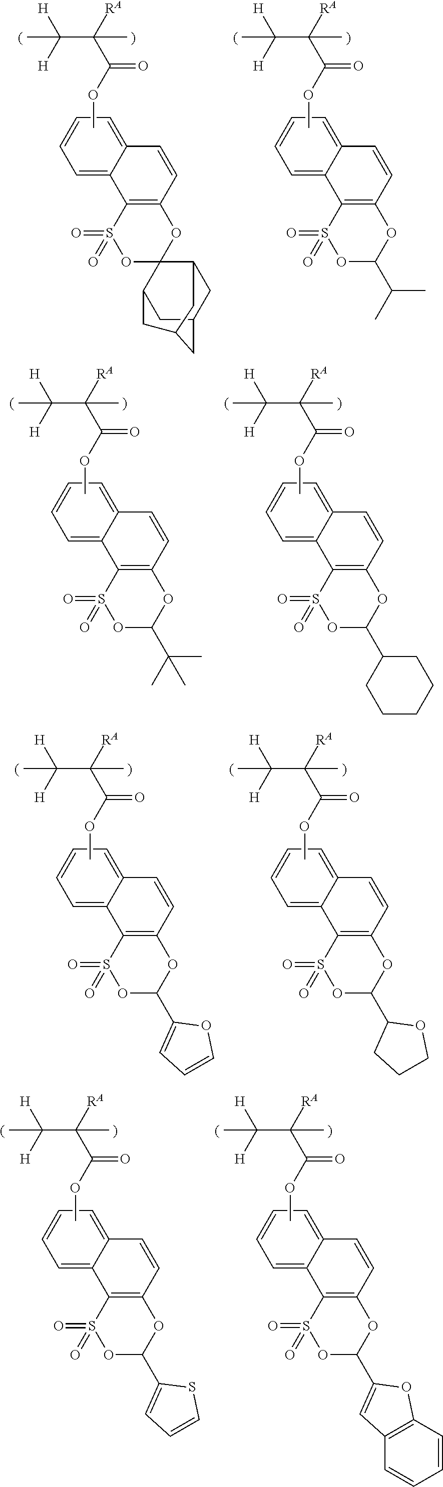

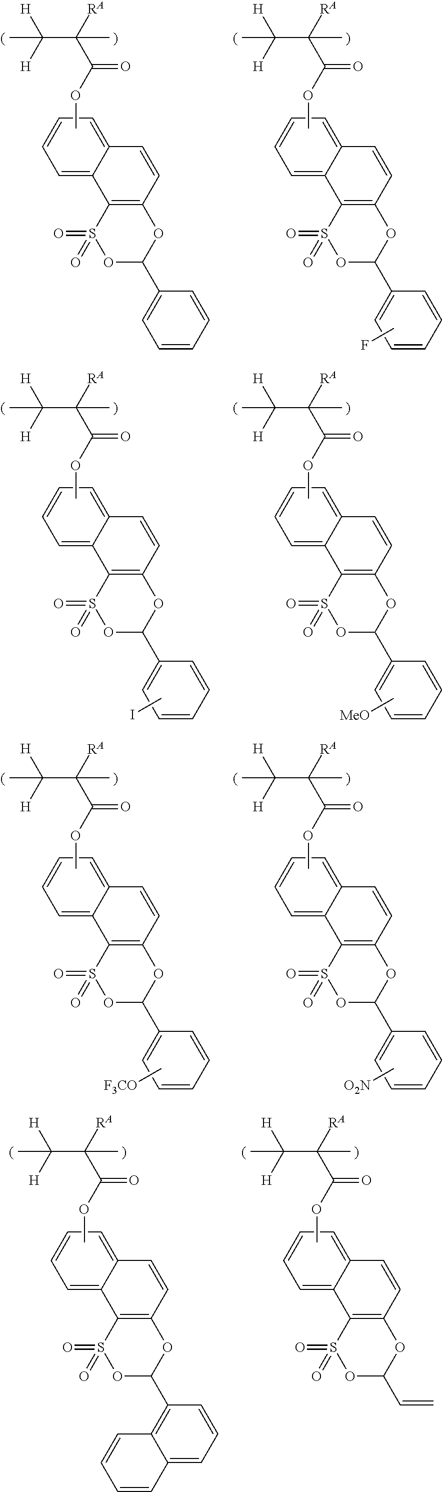

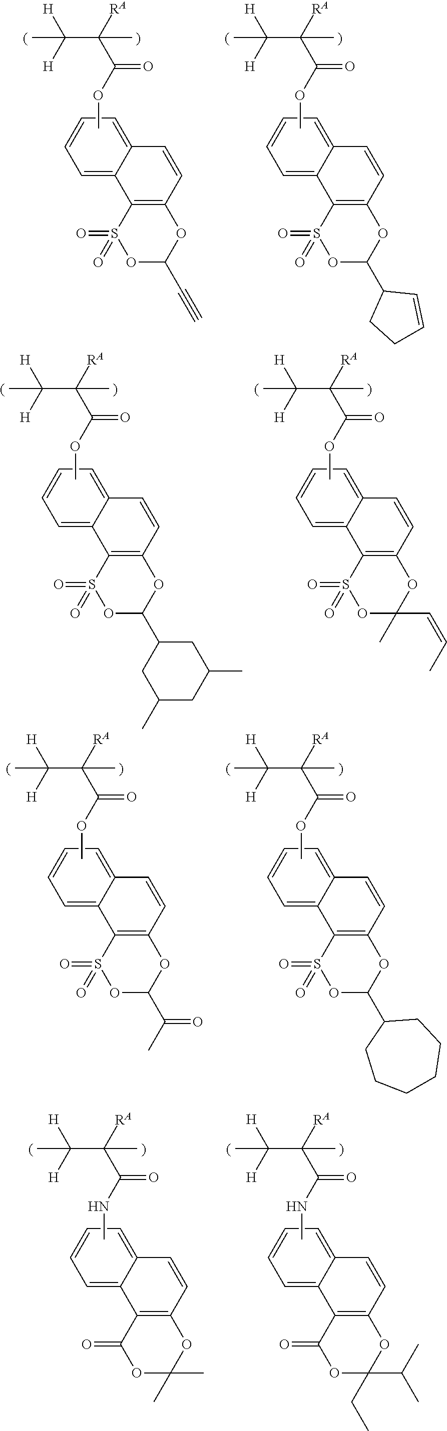

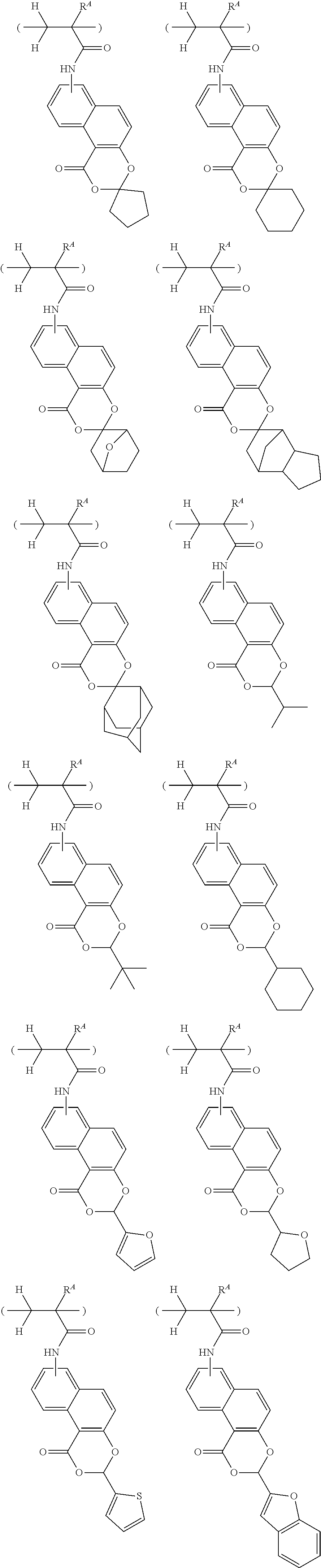

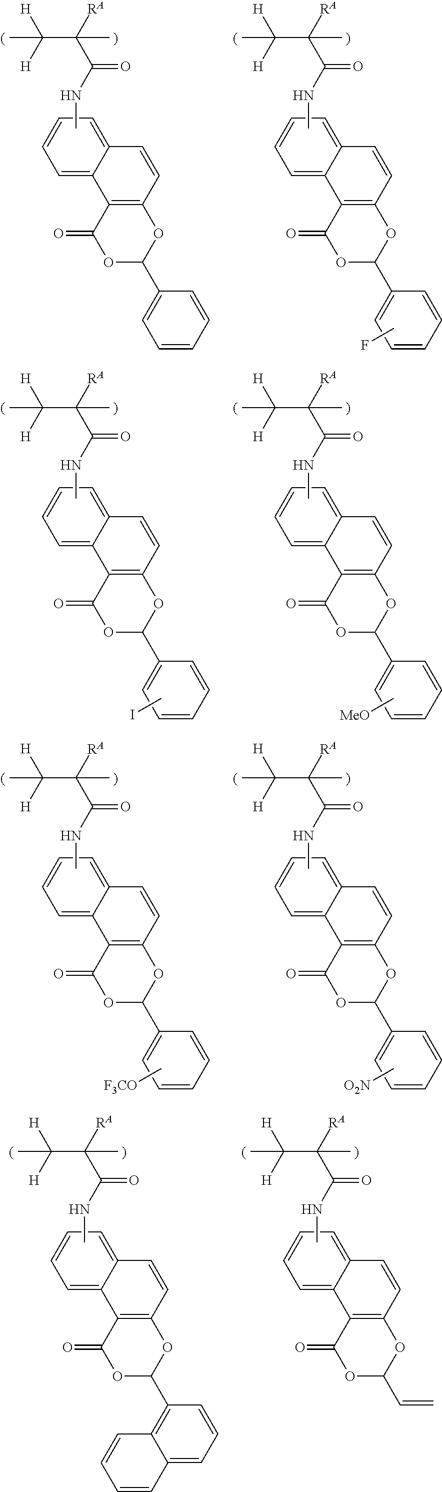

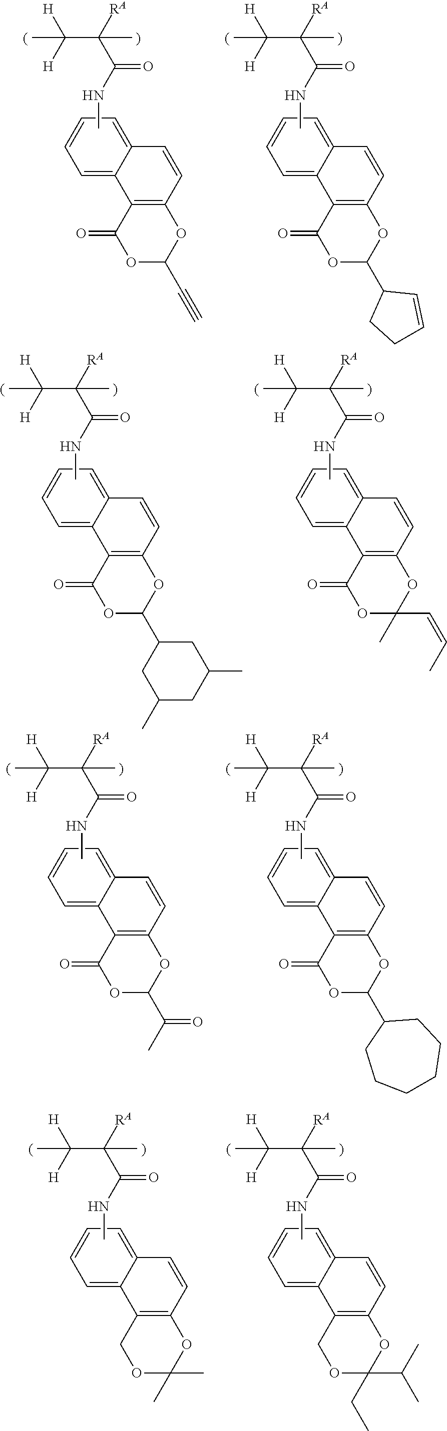

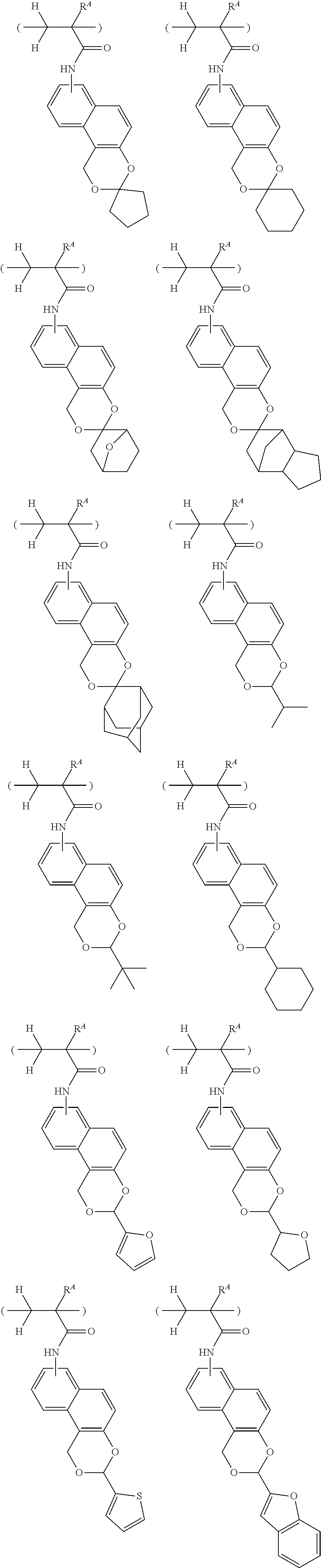

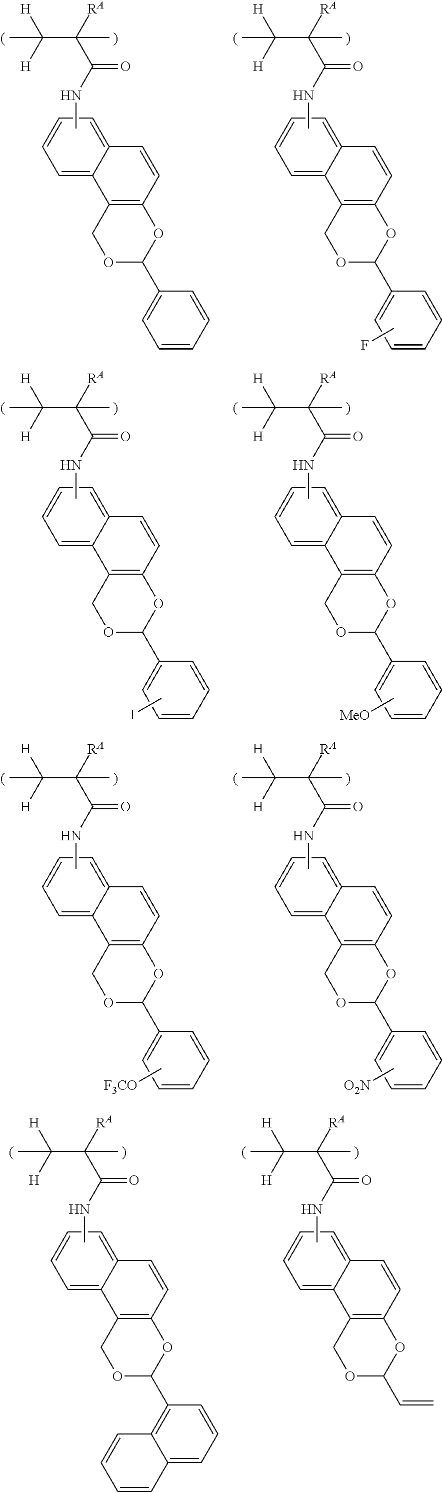

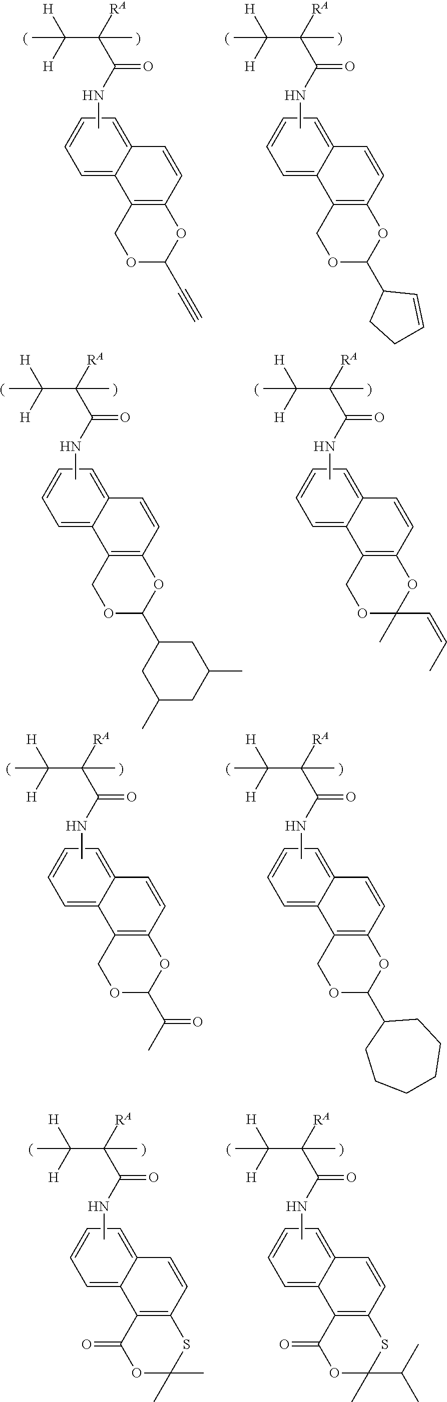

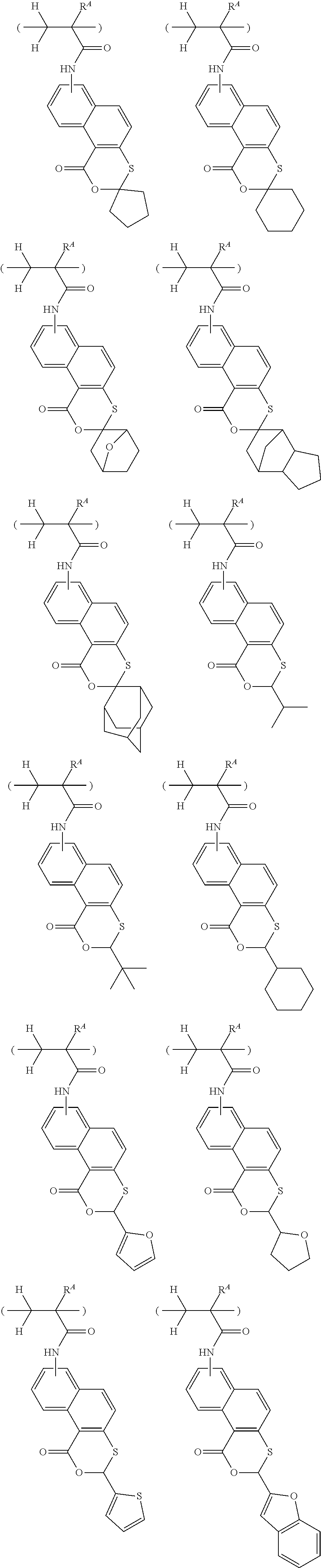

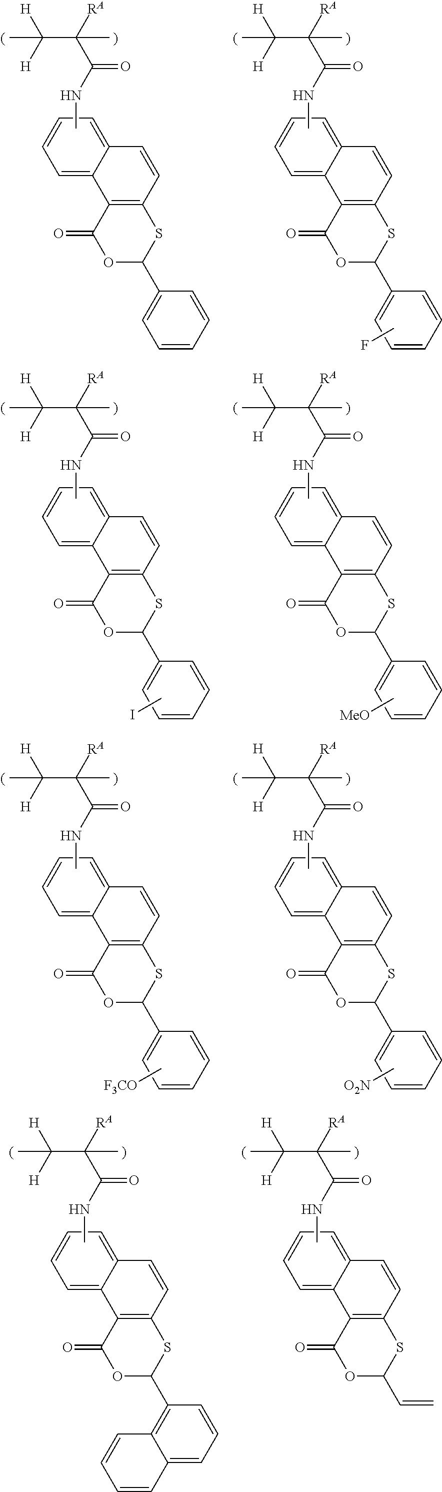

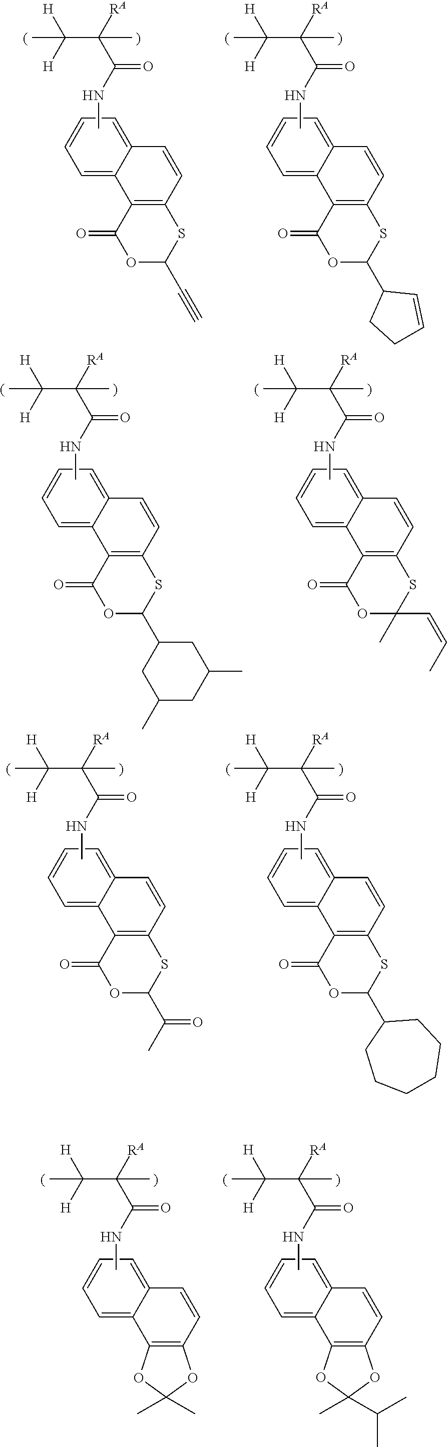

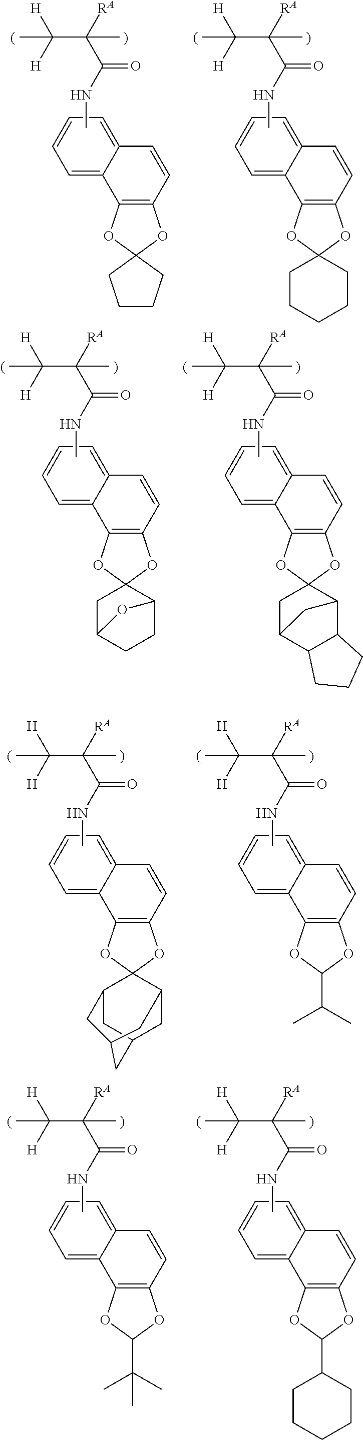

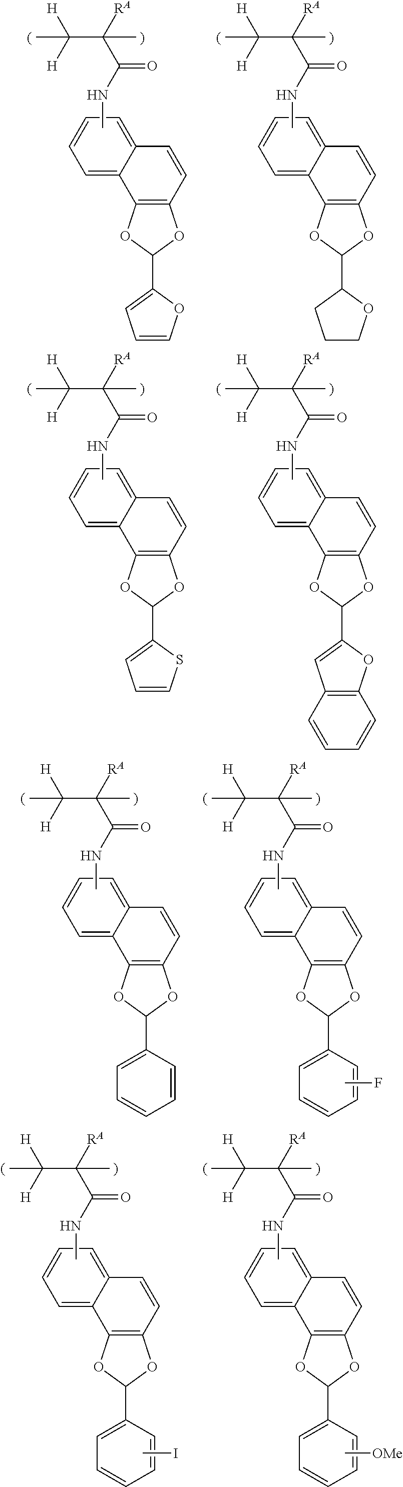

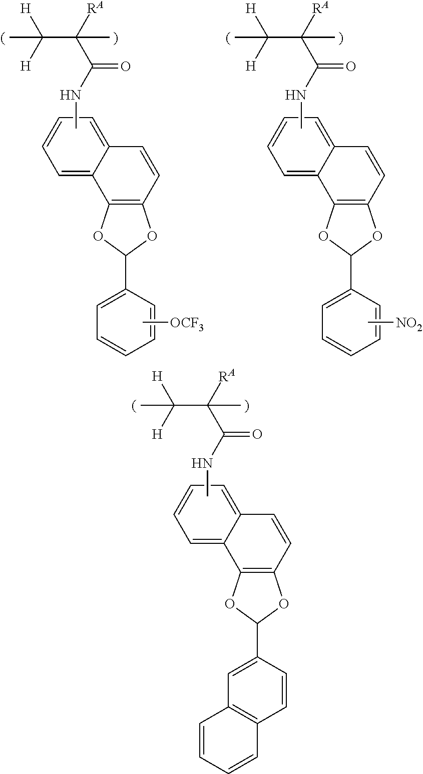

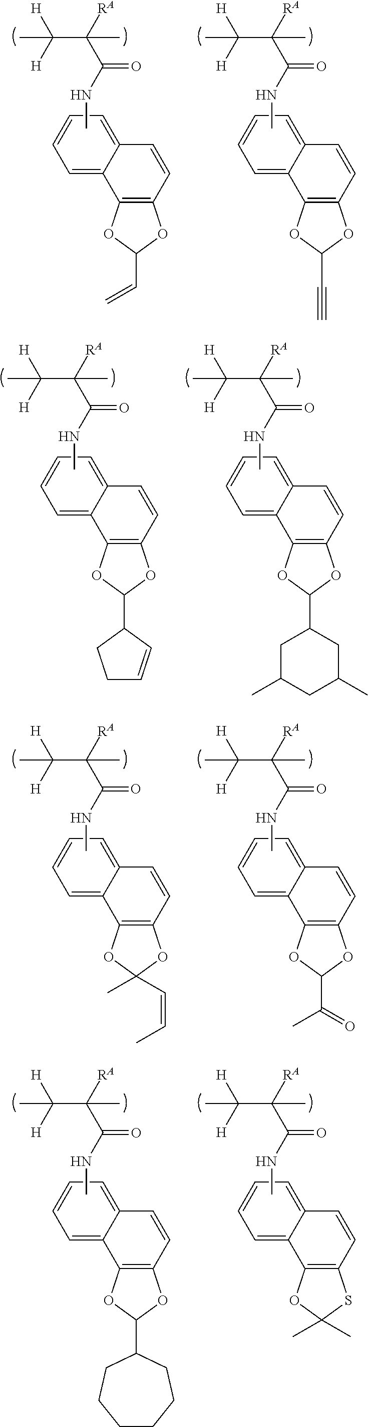

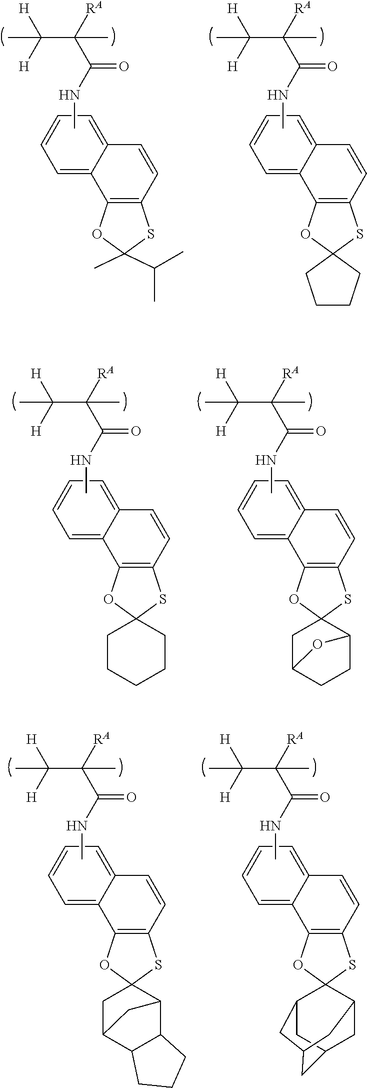

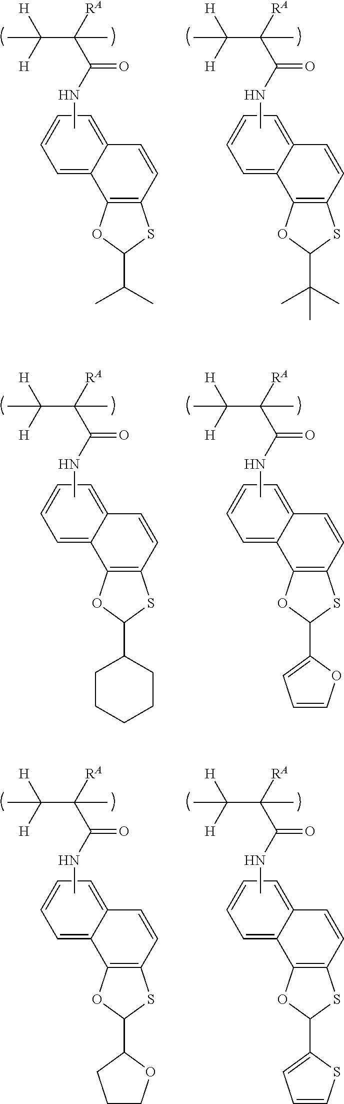

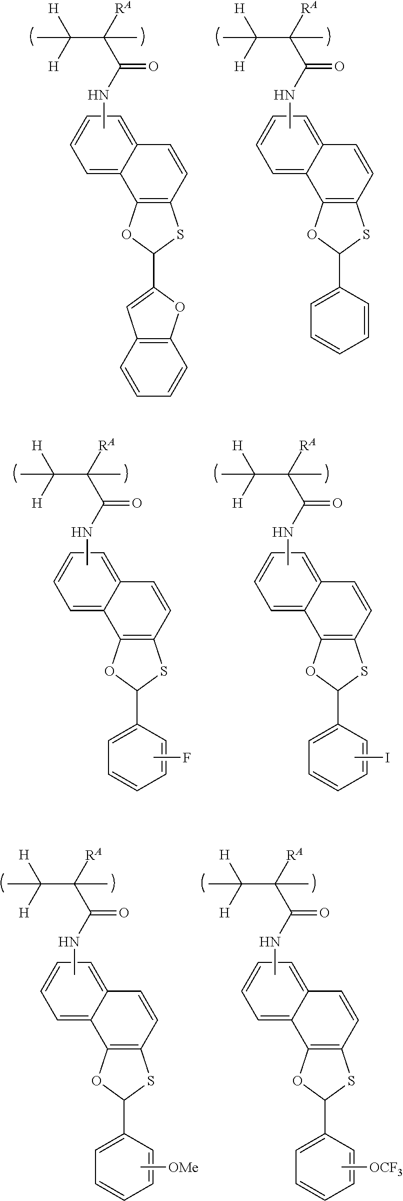

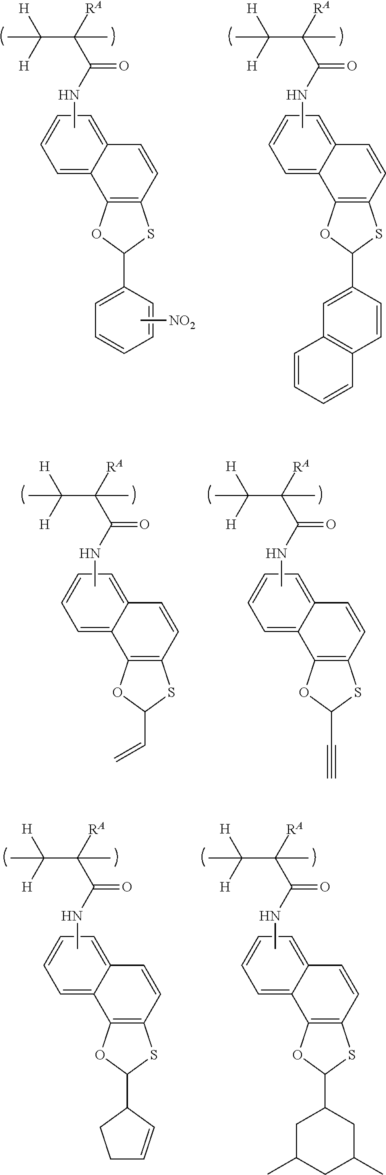

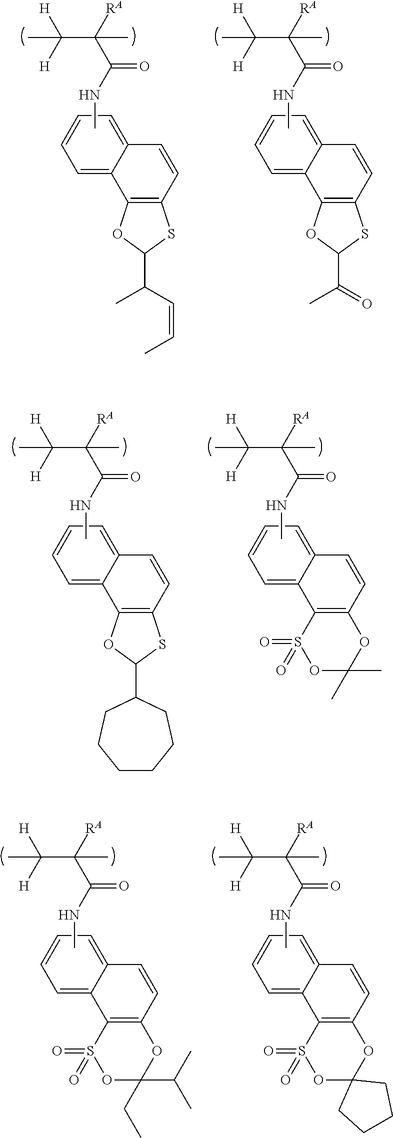

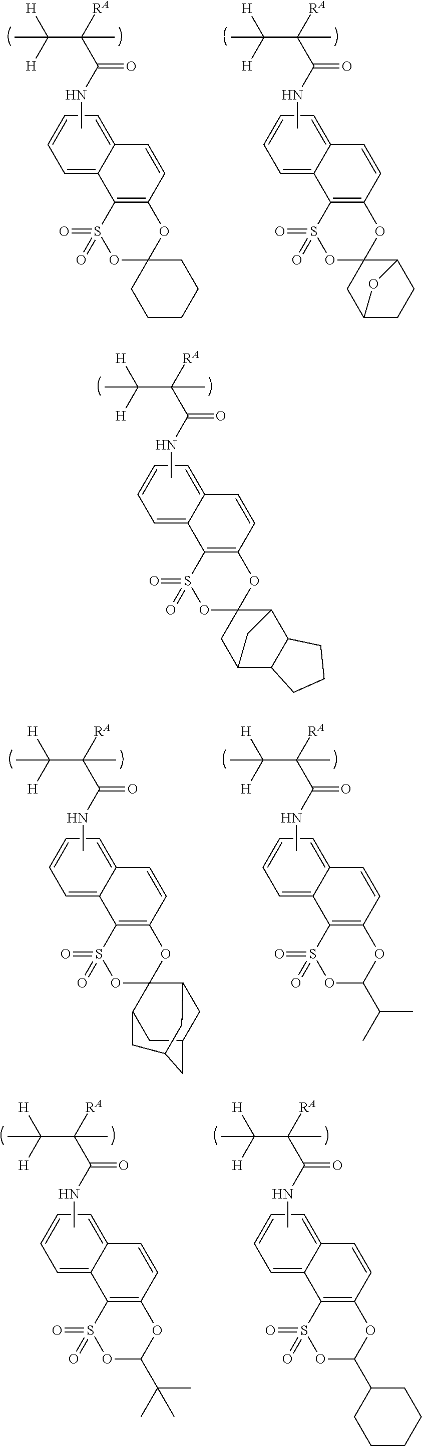

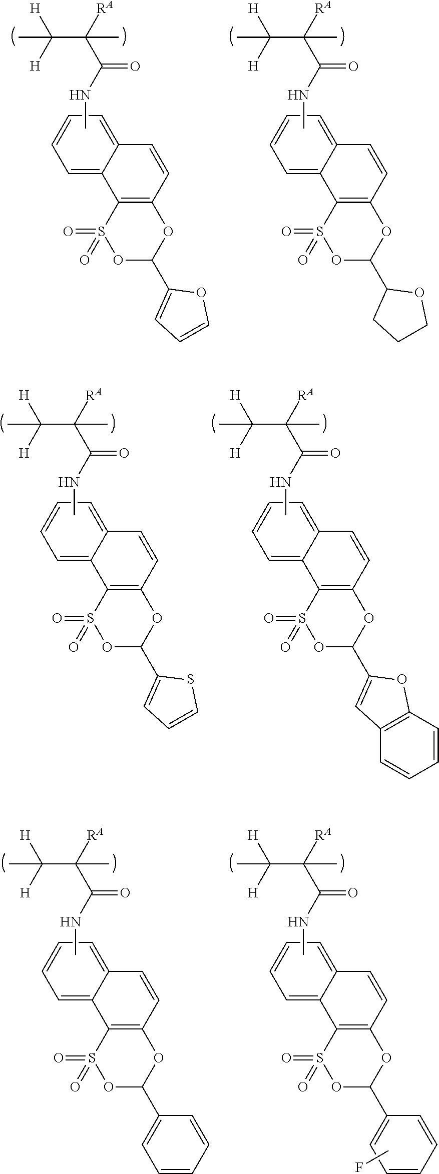

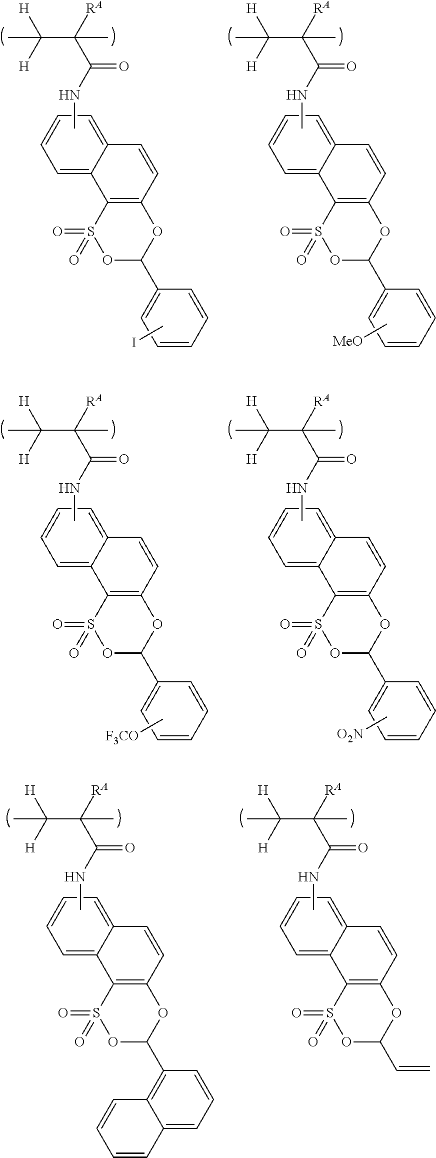

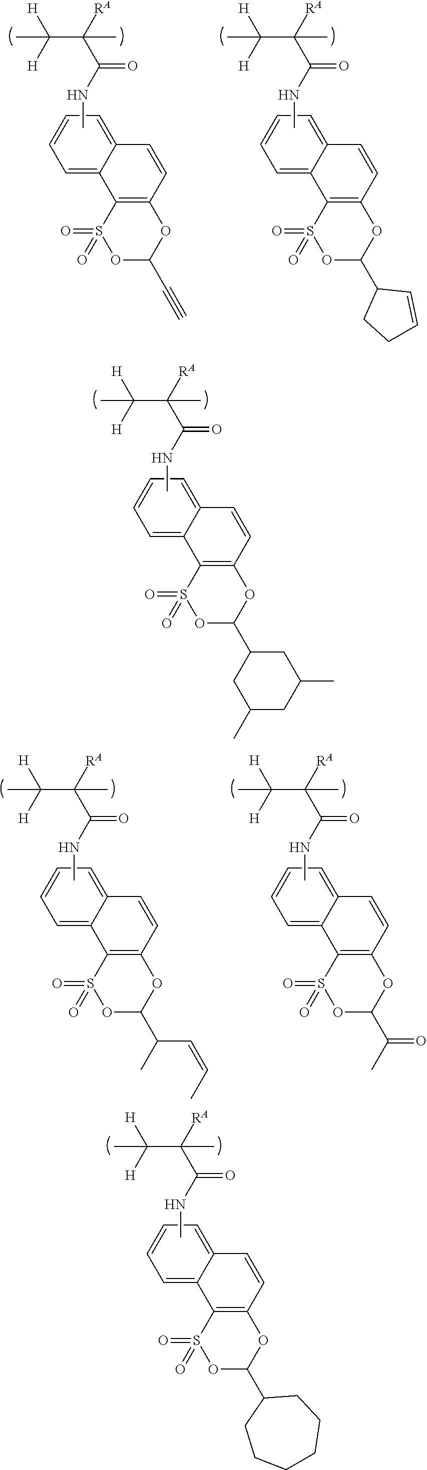

It is preferable that the polymer further contains a repeating unit represented by the following general formula (c)(hereinafter also referred to as repeating unit-c).

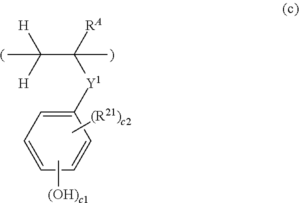

In the formula, R^{A} is a hydrogen atom, a fluorine atom, a methyl group, or a trifluoromethyl group;
Y¹ is a single bond, *—C(═O)—O—, or *—C(═O)—NH—; * indicates a bond to a carbon atom in the main chain;
R²¹ is a halogen atom, a carboxy group, a nitro group, a cyano group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom;
c1 is an integer from 1 to 4; and c2 is an integer from 0 to 3; however, 1≤c1+c2≤5.

In the general formula (c), R^{A} is a hydrogen atom, a fluorine atom, a methyl group, or a trifluoromethyl group. Y¹ is a single bond, *—C(═O)—O—, or *—C(═O)—NH—. * indicates a bond to a carbon atom in the main chain. R²¹ is a halogen atom, a carboxy group, a nitro group, a cyano group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom. c1 is an integer from 1 to 4; and c2 is an integer from 0 to 3; however, 1≤c1+c2≤5.

Specific examples of the repeating unit-c include, but are not limited to, those shown below. In the following formulae, R^{A} is as defined above.

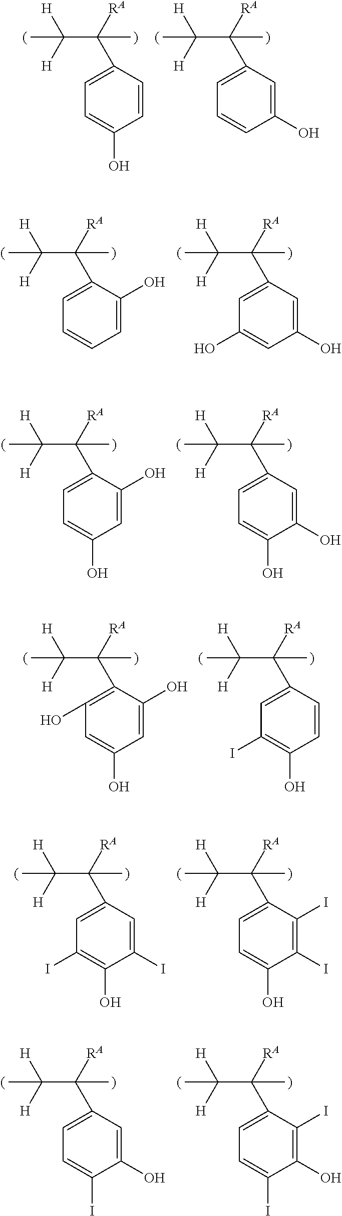

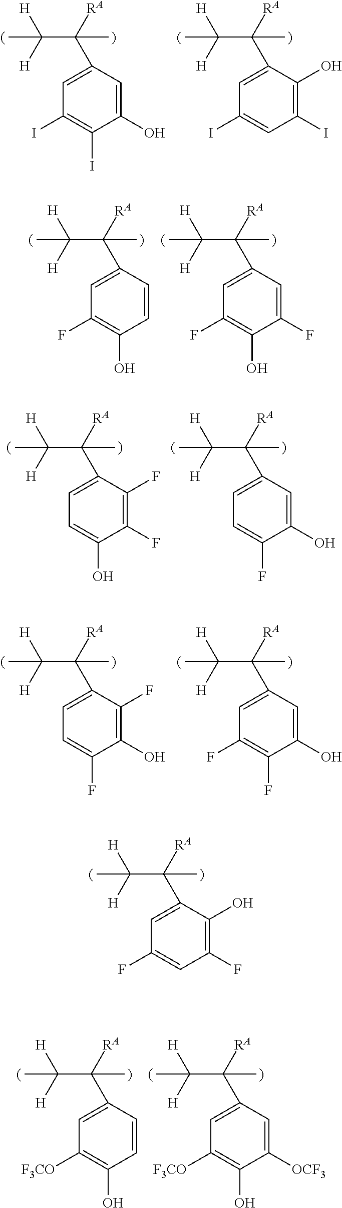

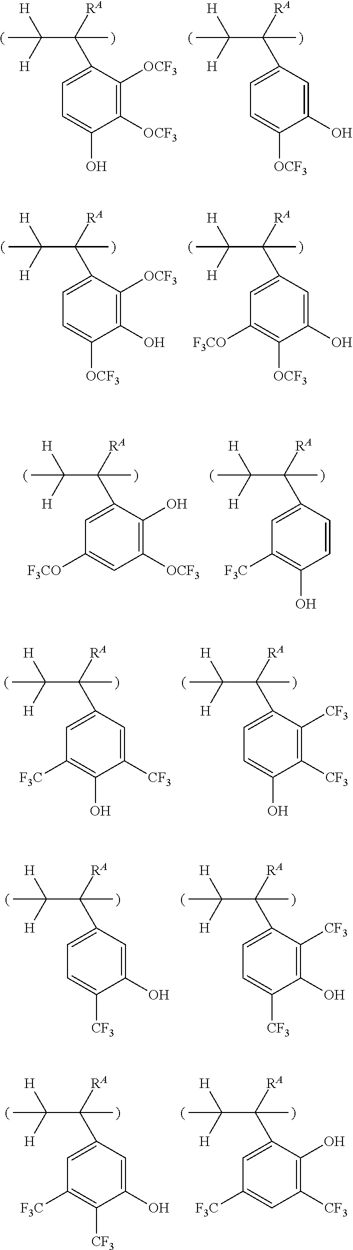

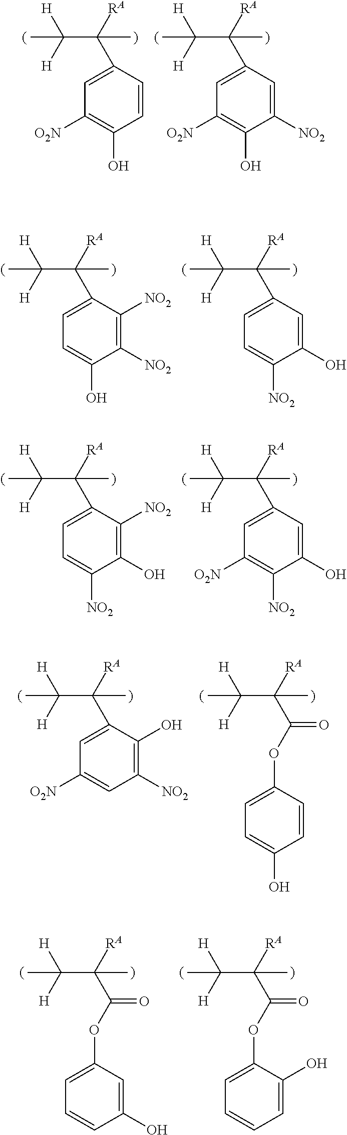

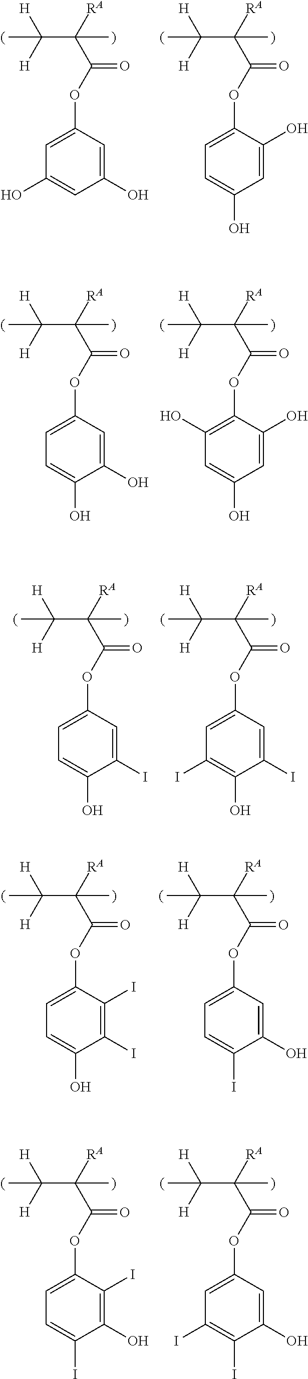

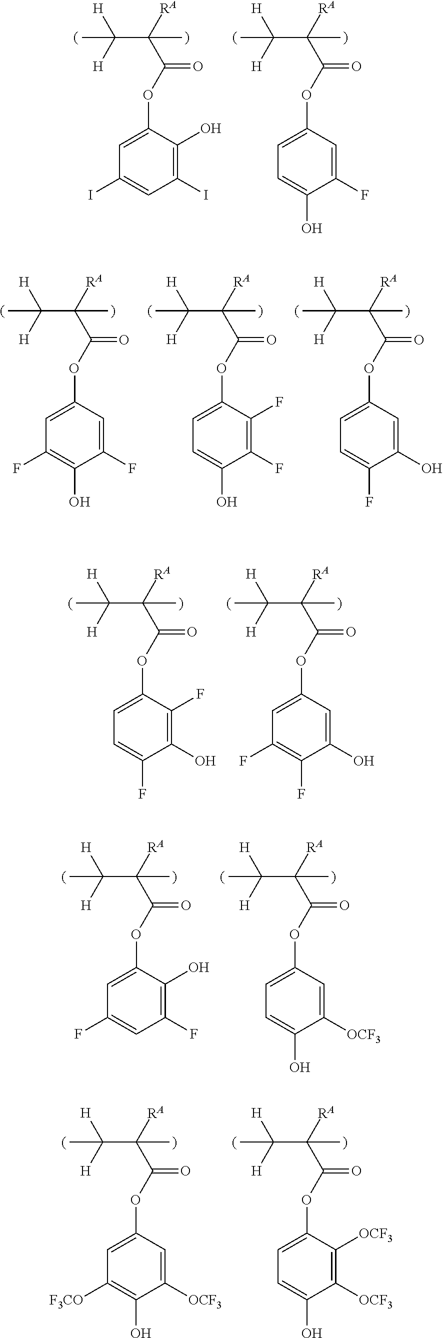

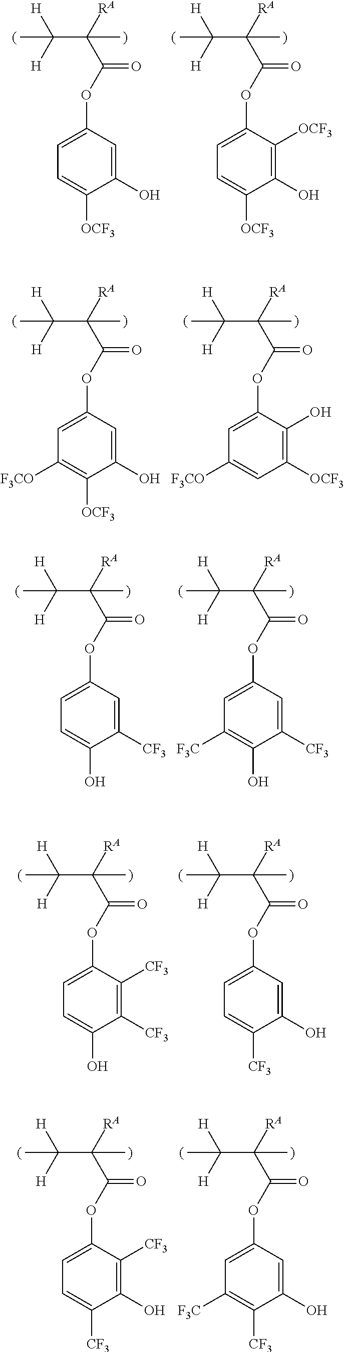

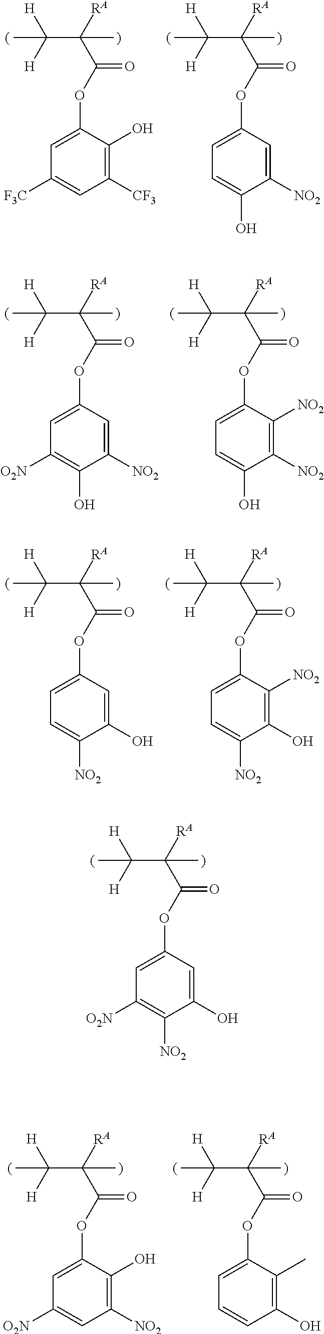

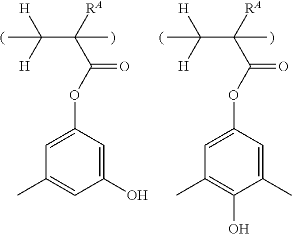

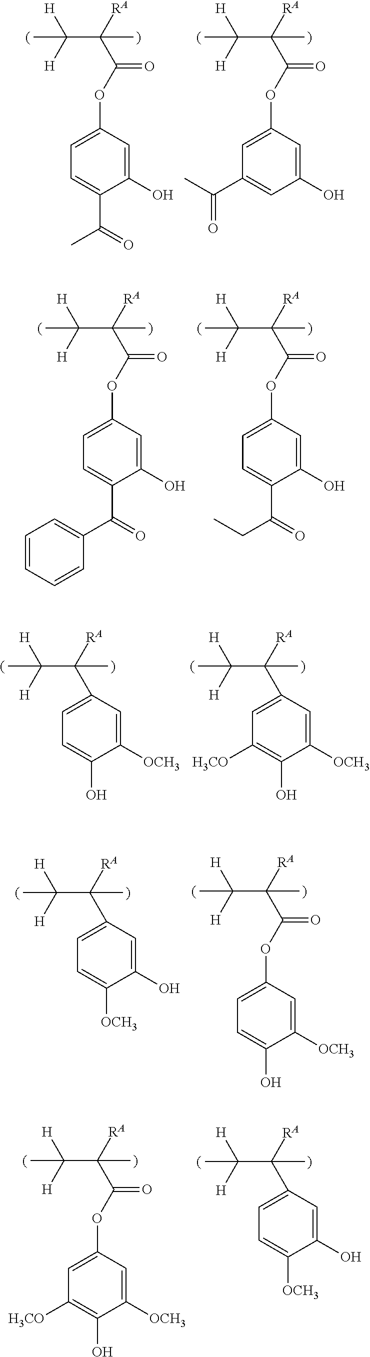

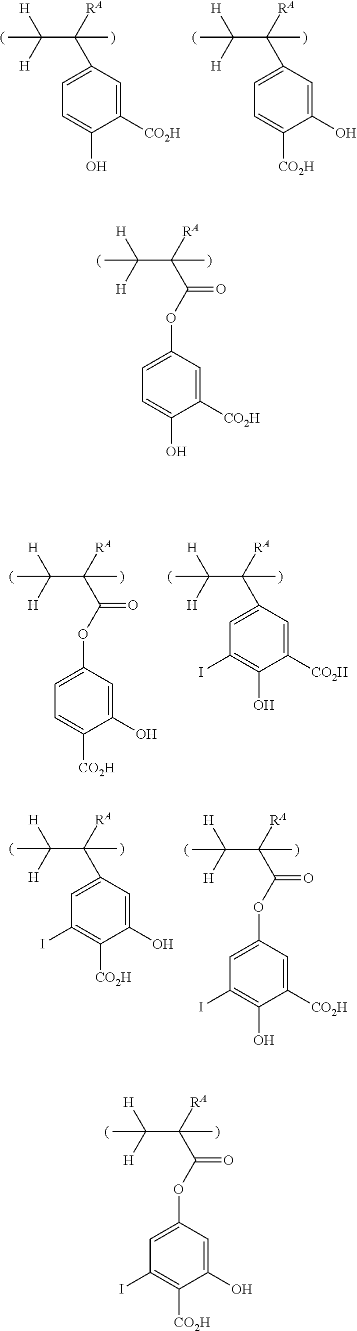

The polymer preferably further contains a repeating unit (hereinafter also referred to a repeating unit-d) derived from an onium salt type monomer containing a fluorosulfonate anion having a polymerizable group and at least one iodine atom, and a sulfonium cation.

Specific examples of the anion of the repeating unit d include structures described in paragraphs [0023] to [0029] of JP6973274B2, and paragraphs [0032] to [0047] of JP2024-043941A.

Furthermore, specific examples of the anion of the repeating unit-d are preferably those represented by the following general formula (d1).

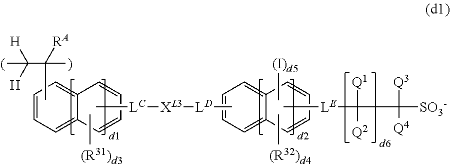

In the general formula (d1), d1 is 0 or 1. When d1 is 0, the structure is a benzene ring, and when d1 is 1, the structure is a naphthalene ring; however, from the viewpoint of solvent solubility, d1 is preferably 0, giving a benzene ring. d2 is 0 or 1. When d2 is 0, the structure is a benzene ring, and when d2 is 1, the structure is a naphthalene ring; however, from the viewpoint of solvent solubility, d2 is preferably 0, giving a benzene ring. d3 is an integer from 0 to 4. From the viewpoint of raw material procurement, d3 is preferably 0, 1 or 2, and more preferably 0 or 1. d4 is an integer from 0 to 4, preferably 0 to 3, more preferably 0, 1 or 2, and further preferably 0 or 1. d5 is an integer from 1 to 6. The larger the number of iodine atoms in the anion structure, the higher the absorption especially for EUV, but since there is a concern that solvent solubility will be poor and precipitation will occur in the resist composition, d5 is preferably 1, 2, or 3, and more preferably 1 or 2. However, when d2 is 0, 1≤d4+d5≤4, and when d2 is 1, 1≤d4+d5≤6. d6 is an integer from 0 to 4, preferably 0 to 3, and more preferably 1.

In the general formula (d1), R^{A} is a hydrogen atom, a fluorine atom, a methyl group, or a trifluoromethyl group. Among these, a hydrogen atom or a methyl group is preferable, and a hydrogen atom is more preferable.

In the general formula (d1), the iodine atom in the aromatic ring of the anion is preferably bonded to the ortho position of the carbon atom to which L^{B} is bonded. Since the iodine atom is an element with a large atomic radius, the rotation of the bond axis between the aromatic ring to which the polymerizable group is bonded and the aromatic ring to which the iodine atom is bonded is suppressed, improving the rigidity.

In the general formula (d1), R³¹ is a halogen atom, or a hydrocarbyl group having 1 to 20 carbon atoms and optionally containing a heteroatom. The halogen atom is preferably a fluorine atom, a chlorine atom, a bromine atom, or an iodine atom, and more preferably a fluorine atom or an iodine atom. The hydrocarbyl group may be saturated or unsaturated and may be linear, branched, or cyclic. Specific examples thereof include alkyl groups having 1 to 20 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyl group, an n-decyl group, an undecyl group, a dodecyl group, a tridecyl group, a tetradecyl group, a pentadecyl group, a heptadecyl group, an octadecyl group, a nonadecyl group, and an icosyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, an allyl group, a propenyl group, a butenyl group, and a hexenyl group; cyclic unsaturated hydrocarbyl groups having 3 to 20 carbon atoms, such as a cyclohexenyl group; aryl groups having 6 to 20 carbon atoms, such as a phenyl group and a naphthyl group; aralkyl groups having 7 to 20 carbon atoms, such as a benzyl group, a 1-phenylethyl group, and a 2-phenylethyl group; and groups obtained by combining these groups. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc. When d3 is 2, 3 or 4, each R³¹ may be the same or they may be different from each other.

Furthermore, when d3 is 2, 3 or 4, a plurality of R³¹ may be bonded to each other to form a ring together with the carbon atoms of the aromatic ring to which they are bonded. Specific examples of the ring formed in this case include a cyclopropane ring, a cyclobutane ring, a cyclopentane ring, a cyclohexane ring, a norbornane ring, an adamantane ring, etc. Furthermore, some or all of the hydrogen atoms of the ring may be substituted with a group containing a heteroatom such as an oxygen atom, a sulfur atom, a nitrogen atom, or a halogen atom, and some of the —CH₂— of the ring may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

In the general formula (d1), R³² is a halogen atom other than an iodine atom, or a hydrocarbyl group having 1 to 20 carbon atoms and optionally containing a heteroatom. Specific examples of the halogen atom other than an iodine atom include a fluorine atom, a chlorine atom, and a bromine atom. The hydrocarbyl group may be saturated or unsaturated and may be linear, branched, or cyclic. Specific examples of these include, but are not limited to, ones similar to those exemplified as the hydrocarbyl group represented by R³¹. When d4 is 2, 3 or 4, each R³² may be the same or they may be different from each other.

Furthermore, when d4 is 2, 3 or 4, a plurality of R³² may be bonded to each other to form a ring together with the carbon atom to which they are bonded. As the ring, a ring having 5 to 8 carbon atoms is preferable.

In the general formula (d1), L^{C}, L^{D} and L^{E} are each independently a single bond, an ether bond, an ester bond, a sulfonate ester bond, a sulfonamide bond, a carbonate bond, or a carbamate bond. Among these, L^{C} is preferably a single bond, an ether bond, an ester bond, or a sulfonate ester bond, and more preferably an ester bond or a sulfonate ester bond. L^{D} is preferably a single bond, an ether bond, or an ester bond, and more preferably a single bond. L^{E} is preferably a single bond, an ether bond, an ester bond, or a sulfonate ester bond, and more preferably an ether bond or an ester bond.

In the general formula (d1), X^{L3} is a single bond or a hydrocarbylene group having 1 to 40 carbon atoms and optionally containing a heteroatom. The hydrocarbylene group may be linear, branched, or cyclic, and specific examples thereof include an alkanediyl group, a cyclic saturated hydrocarbylene group, an arylene group, etc. Specific examples of the heteroatom include an oxygen atom, a nitrogen atom, and a sulfur atom. Specific examples of the hydrocarbylene group having 1 to 40 carbon atoms and optionally containing a heteroatom represented by X^{L3} include X^{L}-0 to X^{L}-58 exemplified as specific examples of the hydrocarbylene group having 1 to 40 carbon atoms and optionally containing a heteroatom represented by X^{L1} and X^{L2} in the description of the general formula (Z). Among these, X^{L}-0 to X^{L}-22, X^{L}-29 to X^{L}-34, and X^{L}-47 to X^{L}-58 are preferable.

From the viewpoint of the rigidity of the obtained polymer, X^{L3} is preferably a single bond.

In the general formula (d1), Q¹ and Q² are each independently a hydrogen atom, a fluorine atom, or a fluorinated saturated hydrocarbyl group having 1 to 6 carbon atoms. As the fluorinated saturated hydrocarbyl group having 1 to 6 carbon atoms, a trifluoromethyl group is preferable.

In the general formula (d1), Q³ and Q⁴ are each independently a fluorine atom or a fluorinated saturated hydrocarbyl group having 1 to 6 carbon atoms. As the fluorinated saturated hydrocarbyl group having 1 to 6 carbon atoms, a trifluoromethyl group is preferable. Q³ and Q⁴ is more preferably a fluorine atom.

In the general formula (d1), specific examples of the partial structure represented by —[C(Q¹)(Q²)]_{d6}—C(Q³)(Q⁴)—SO₃— are preferably, but are not limited to, those shown below. In the following formulae, * represents a bond to L^{E}.

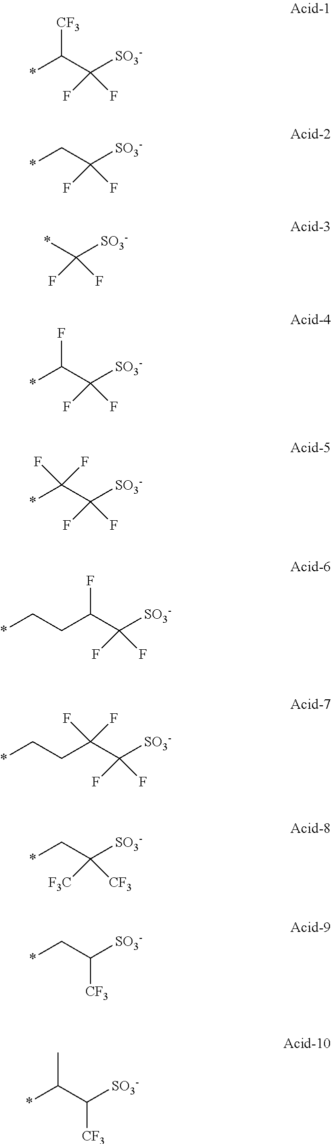

Among these, Acid-1 to Acid-7 are preferable, and Acid-1 to Acid-3, Acid-6, and Acid-7 are more preferable.

The anion represented by the general formula (d1) is preferably represented by the following general formula (d1-1).

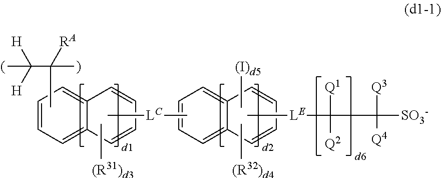

In the formula, d1 to d6, R^{A}, R³¹, R³², L^{C}, L^{E}, and Q¹ to Q⁴ are as defined above.

The anion represented by the general formula (d1-1) is preferably represented by the following general formula (d1-2).

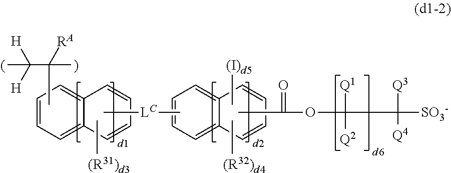

In the formula, d1 to d6, R^{A}, R³¹, R³², L^{C}, and Q¹ to Q⁴ are as defined above.

Specific examples of the anion represented by the general formula (d1) include, but are not limited to, those shown below. In the following formulae, R^{A} and Q¹ are as defined above, and Me is a methyl group. In addition, the bonding positions of various substituents on the aromatic ring may be interchanged.

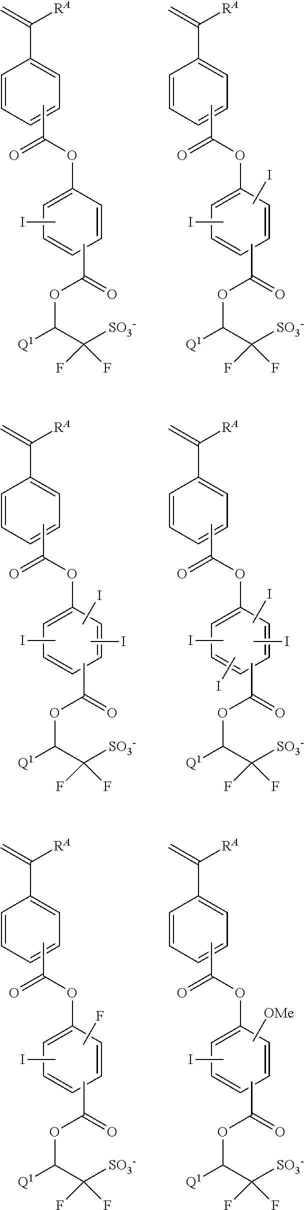

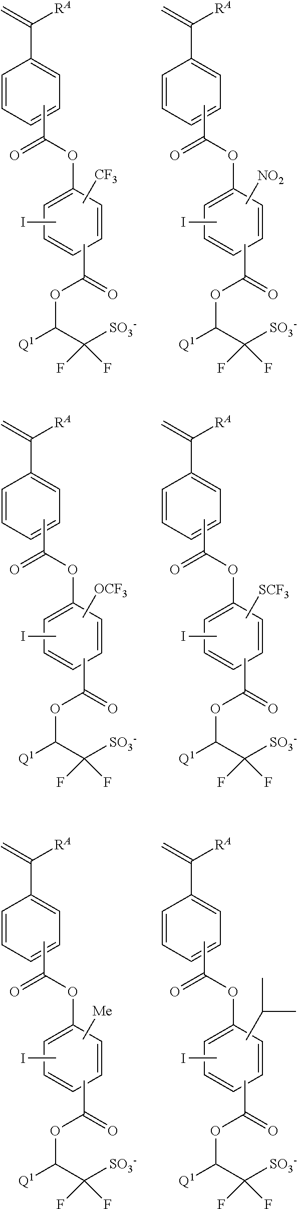

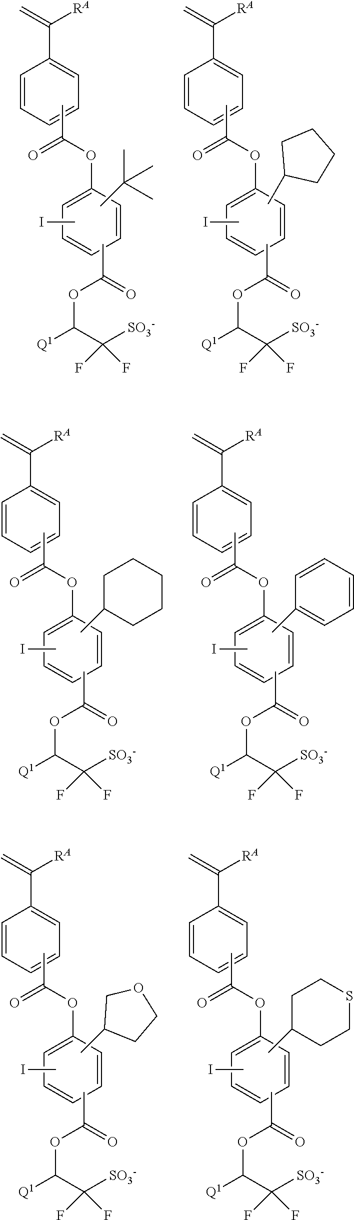

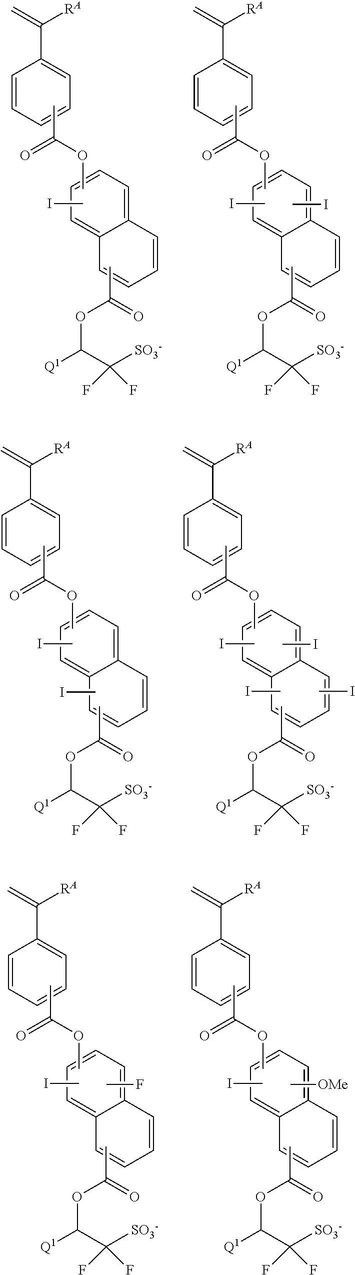

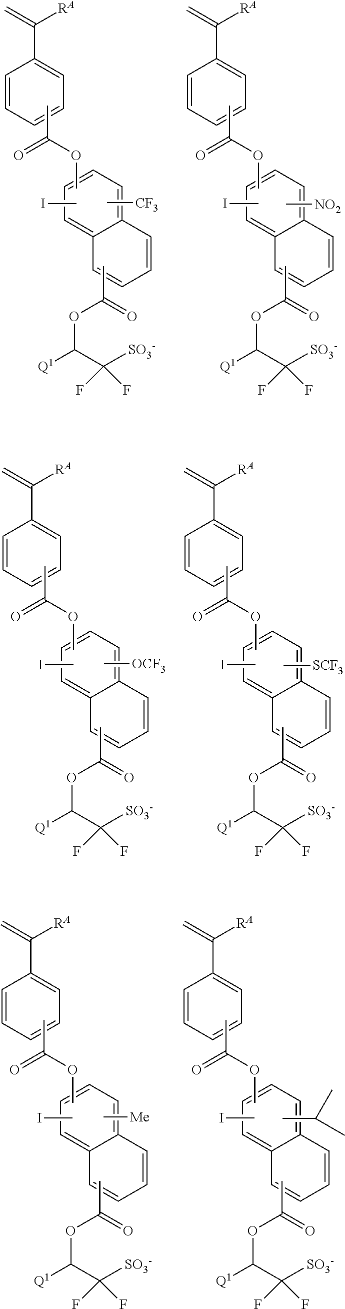

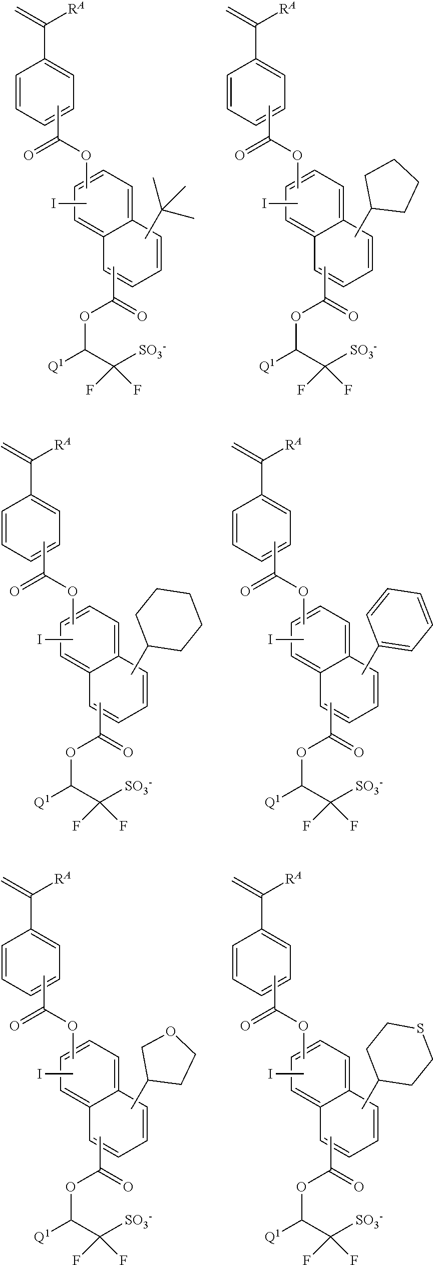

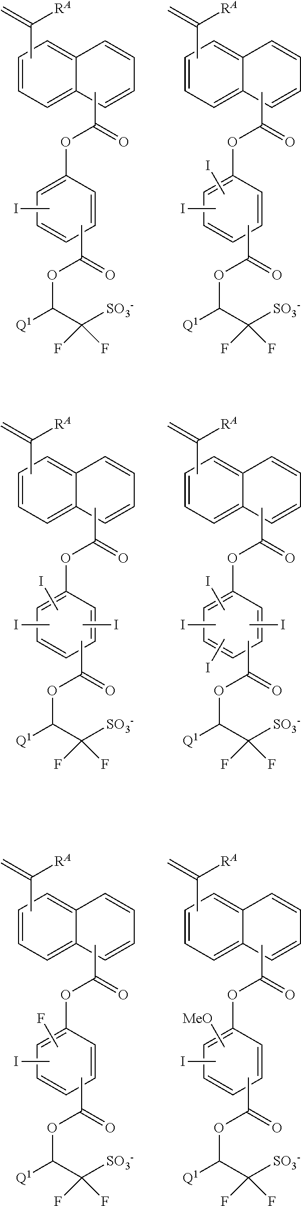

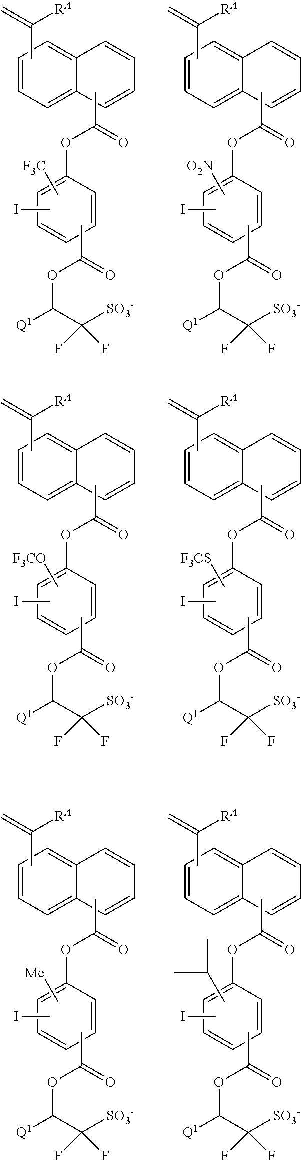

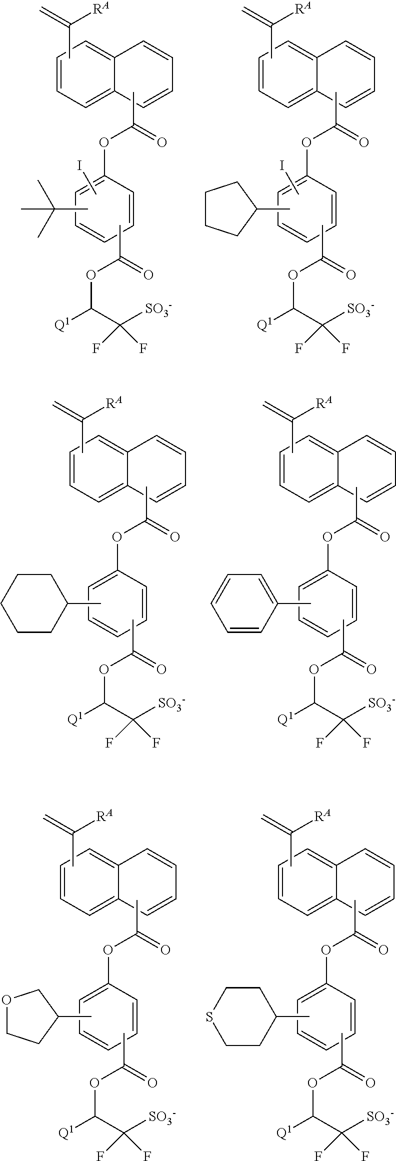

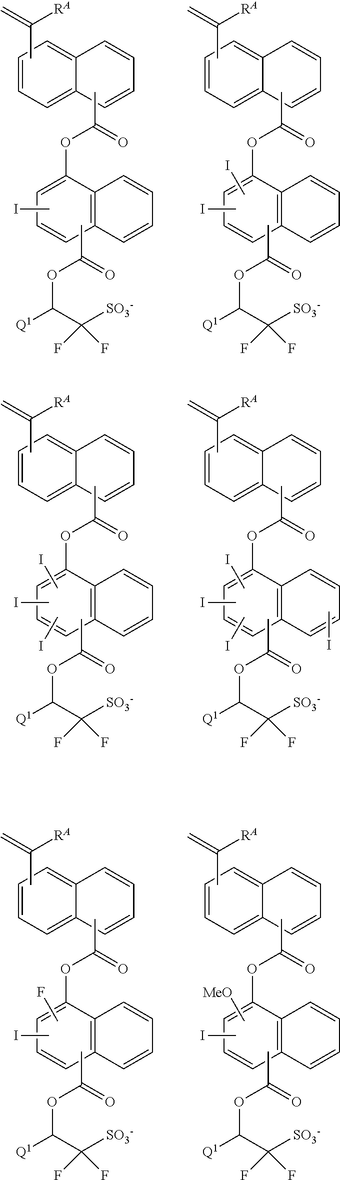

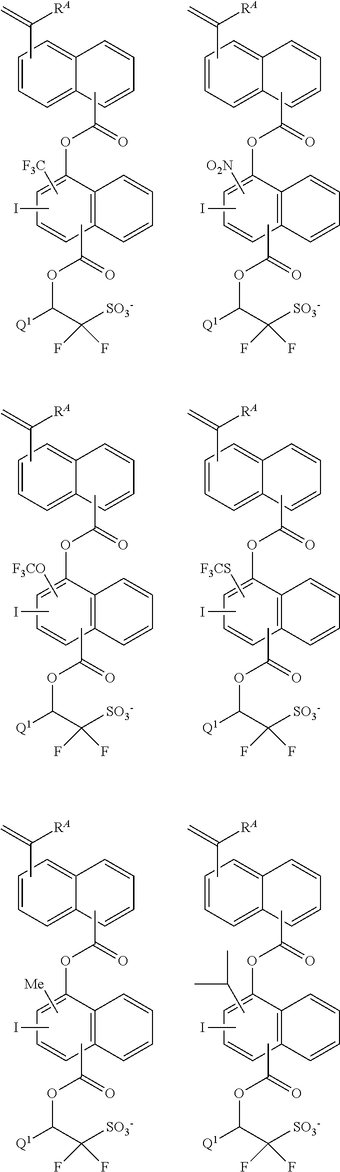

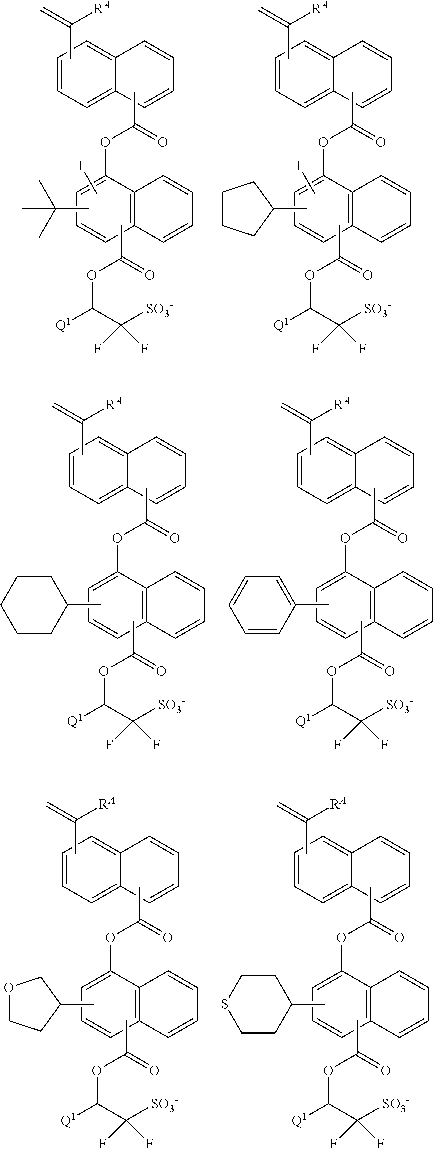

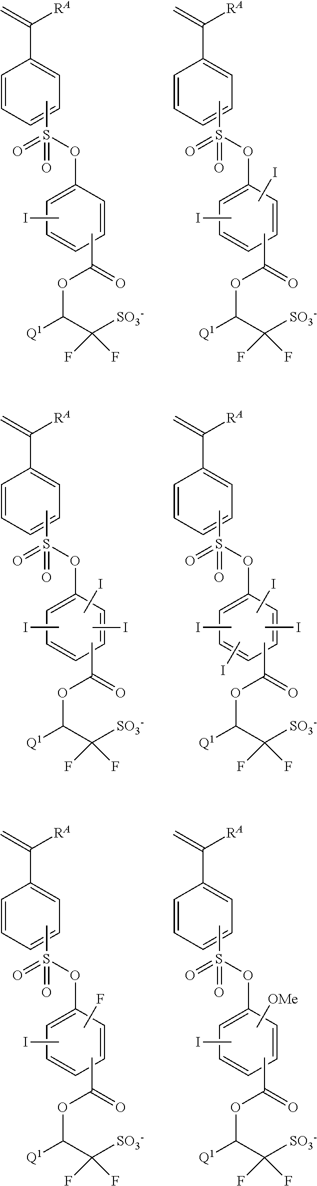

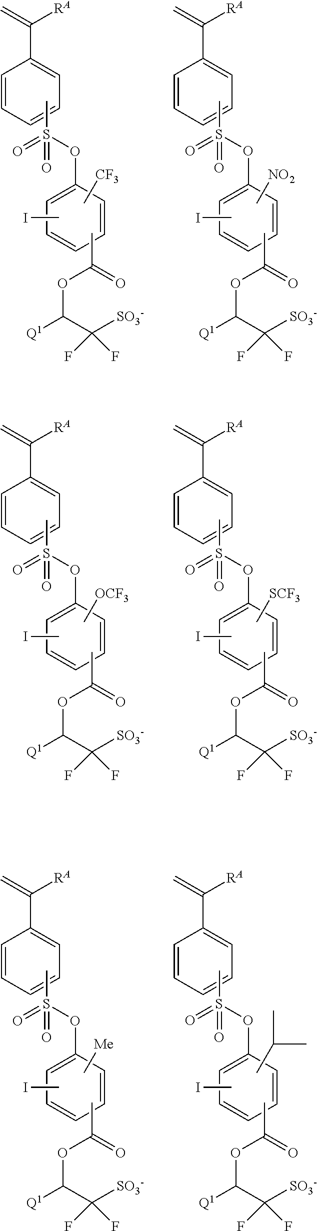

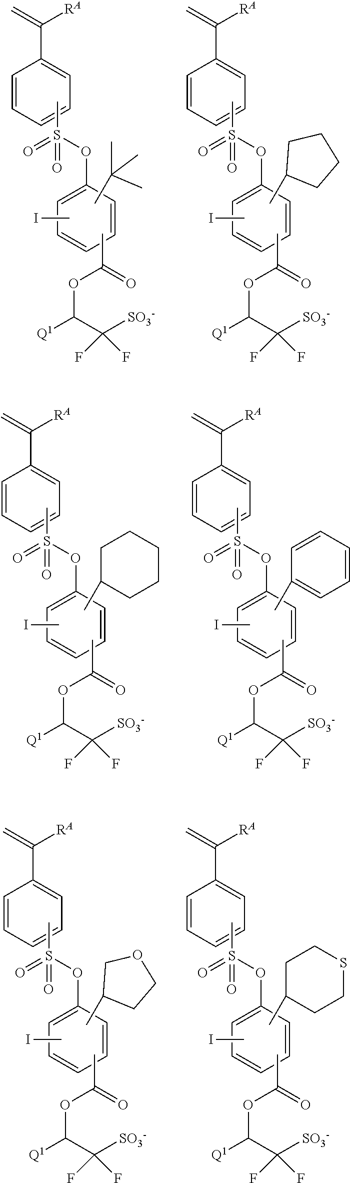

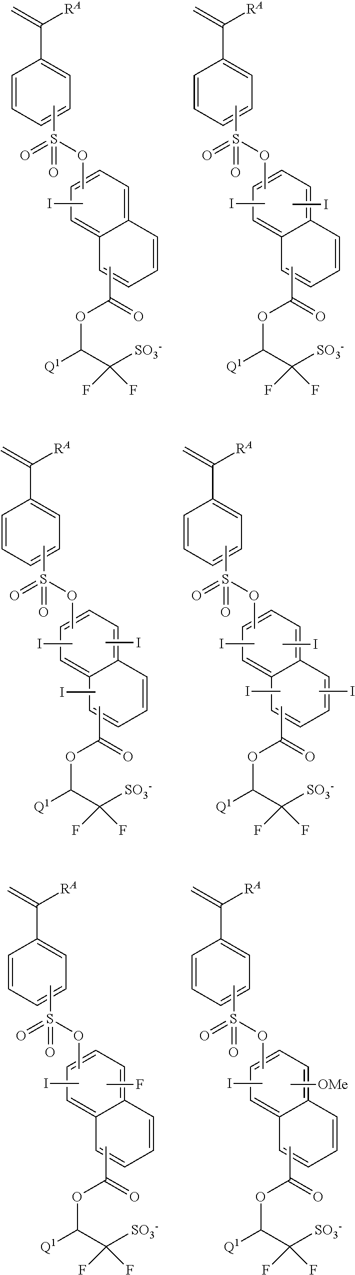

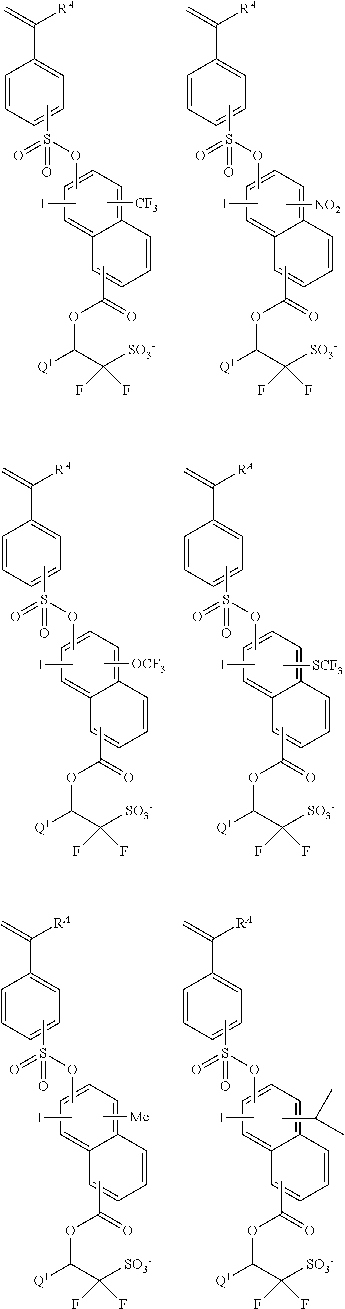

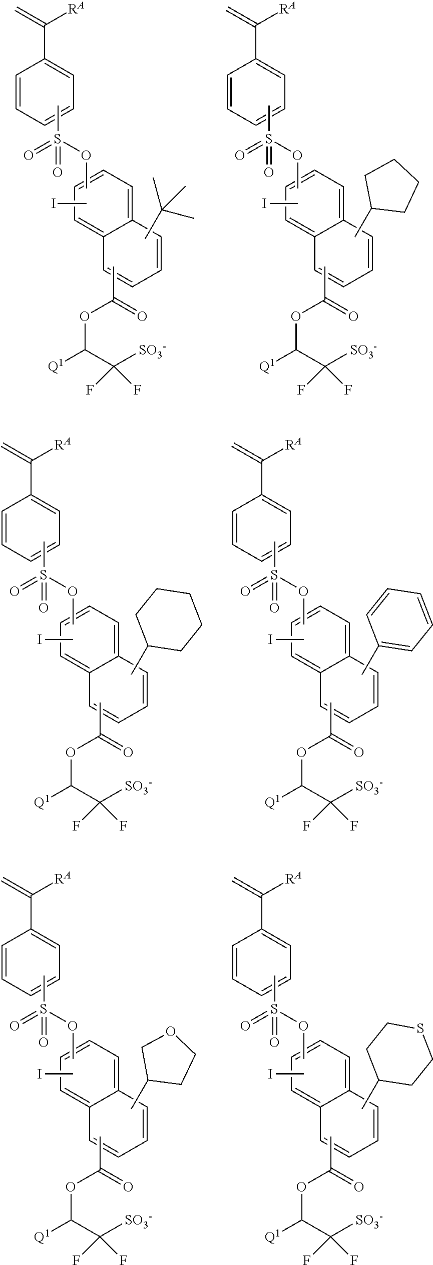

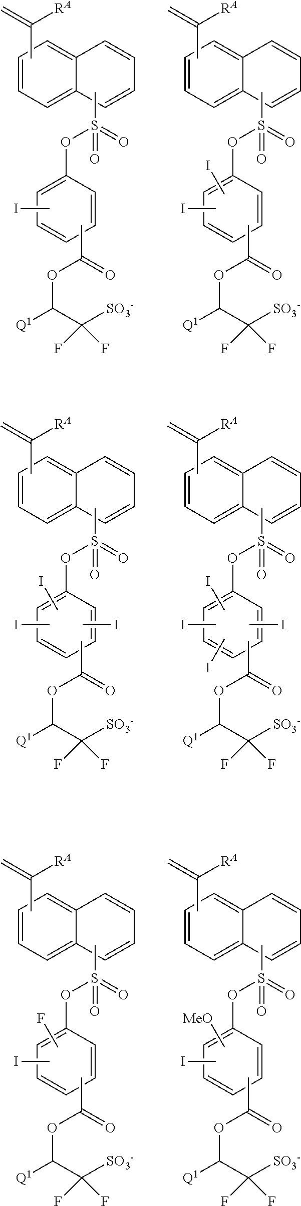

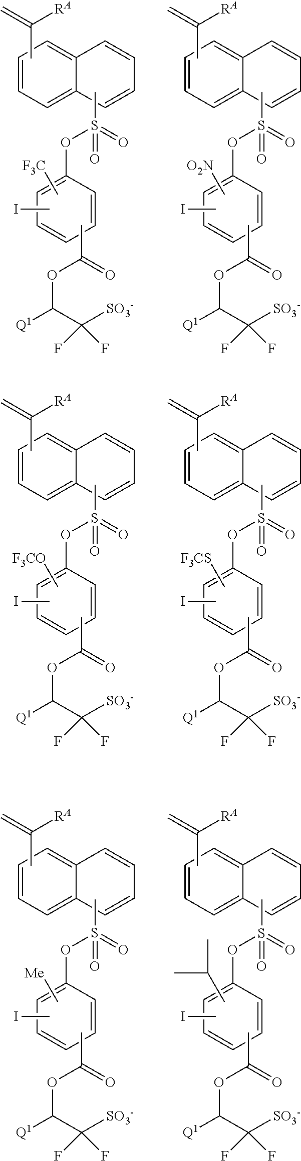

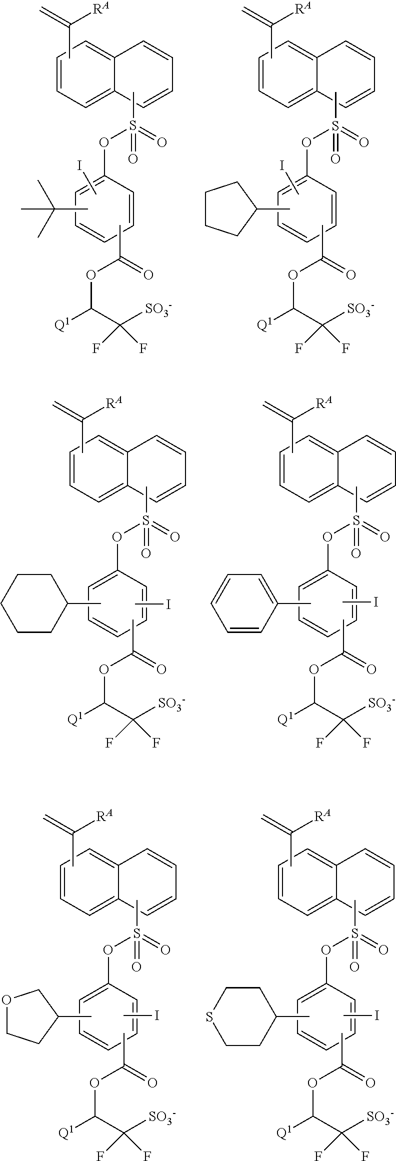

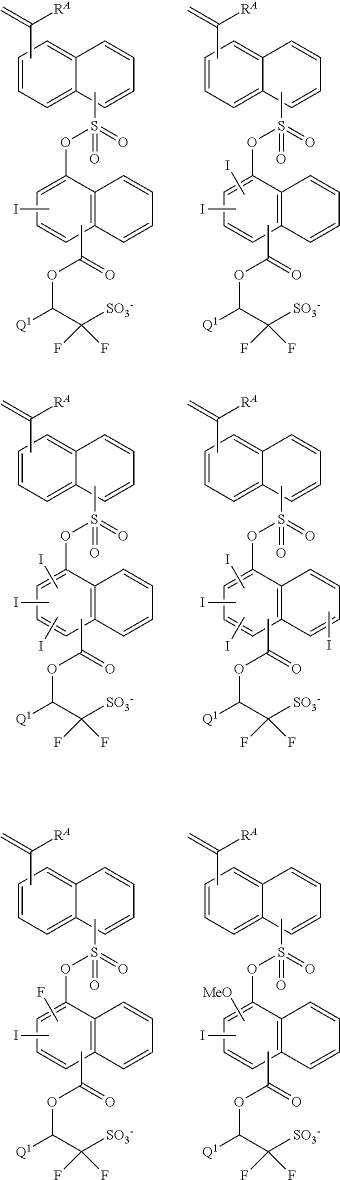

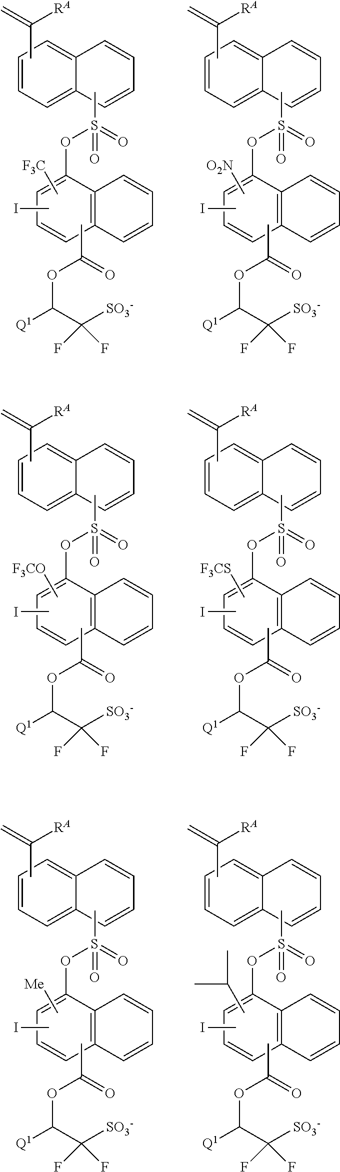

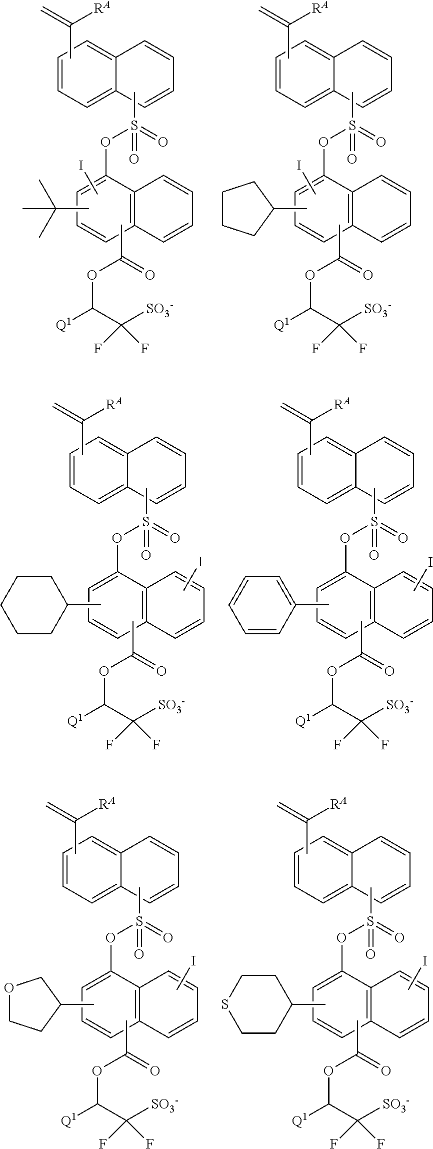

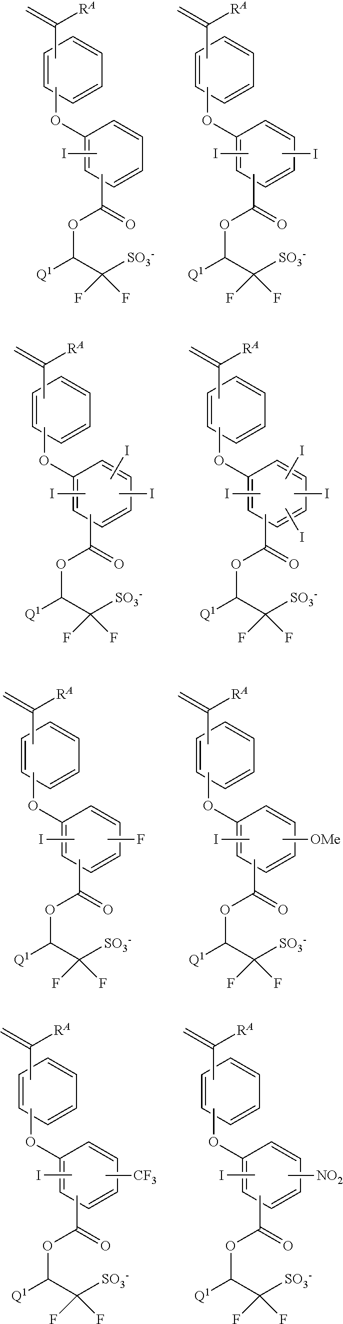

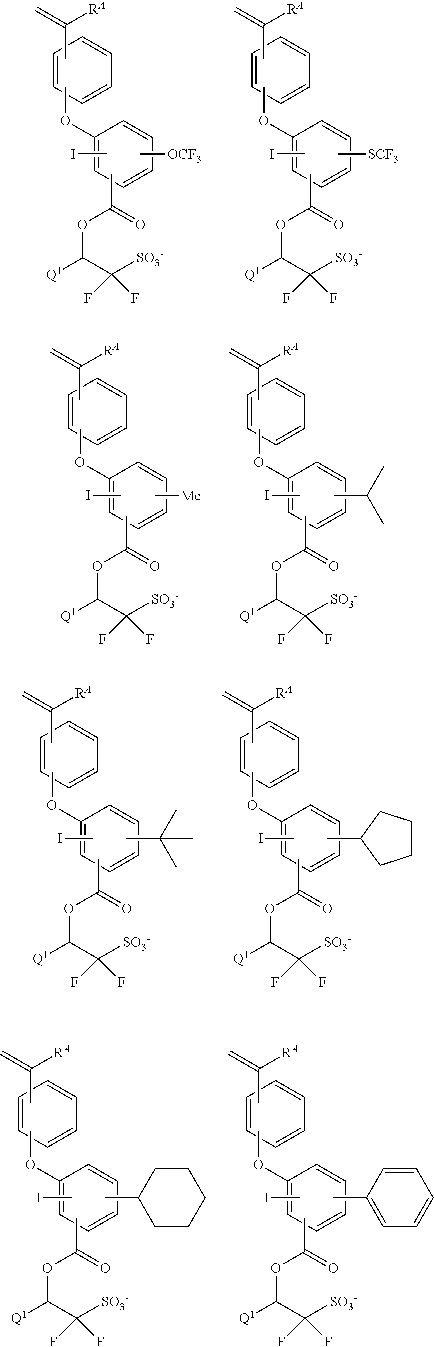

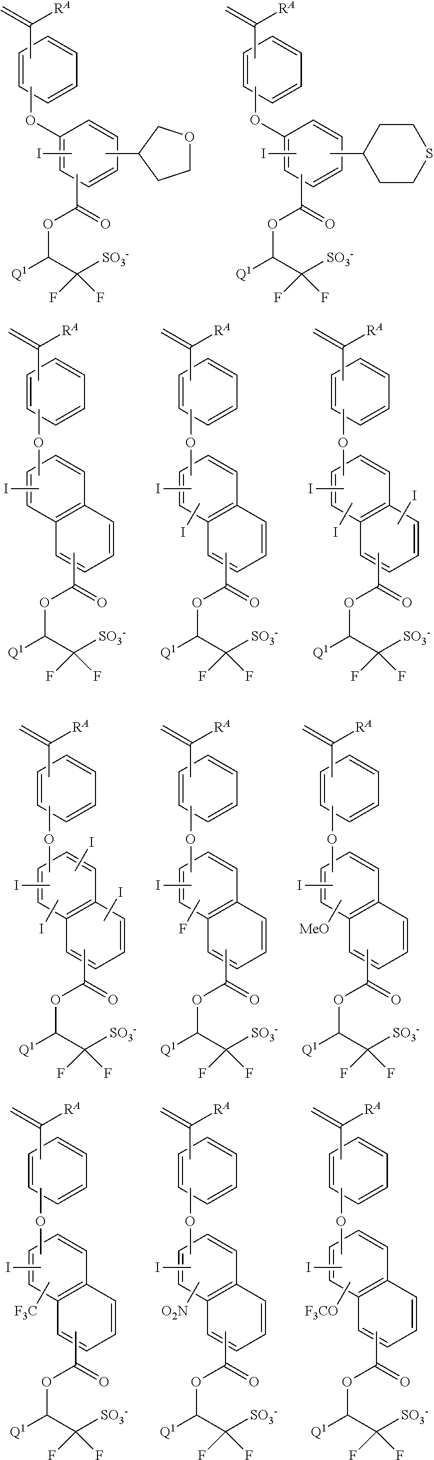

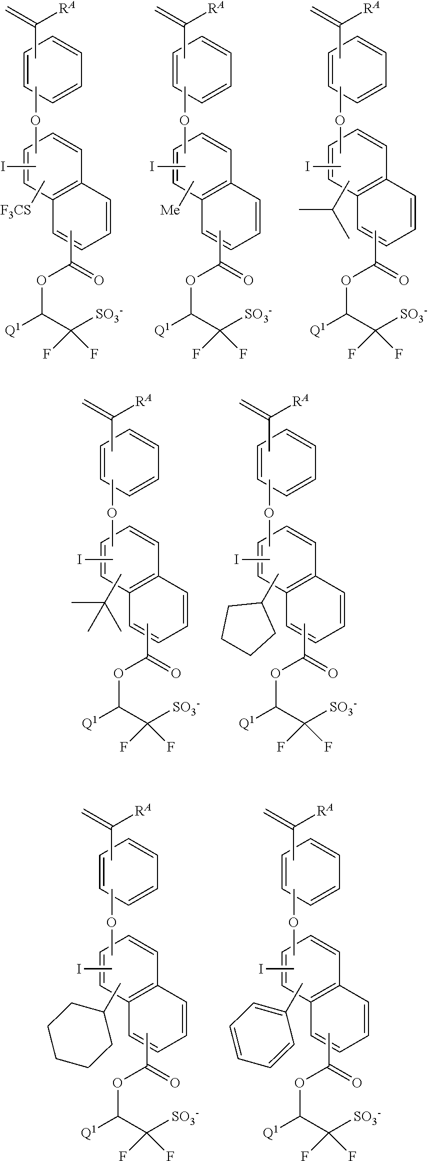

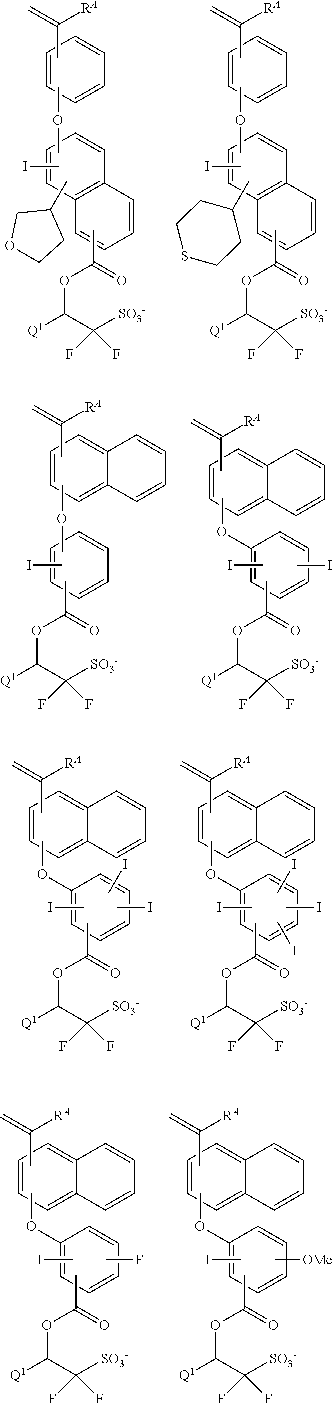

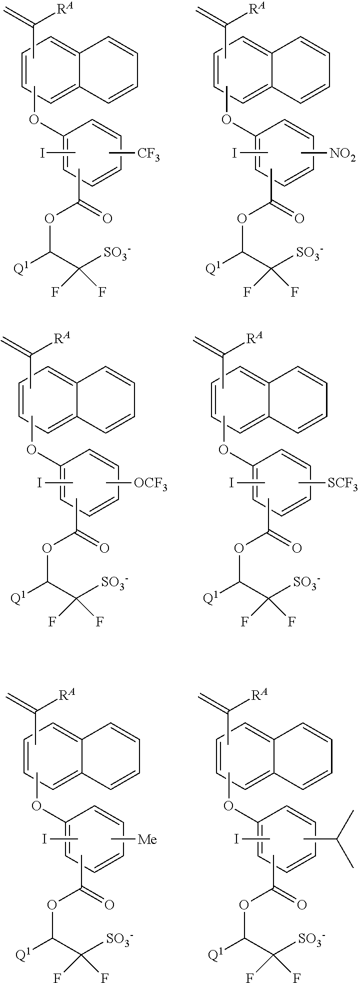

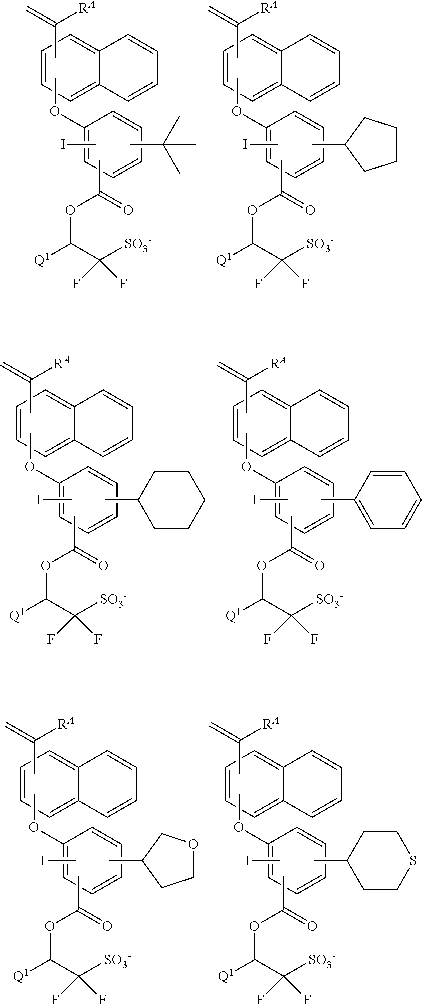

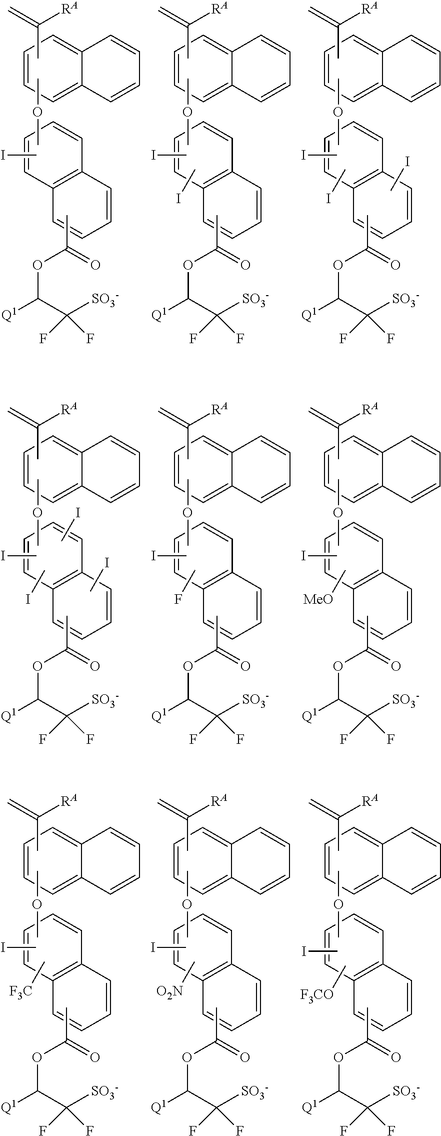

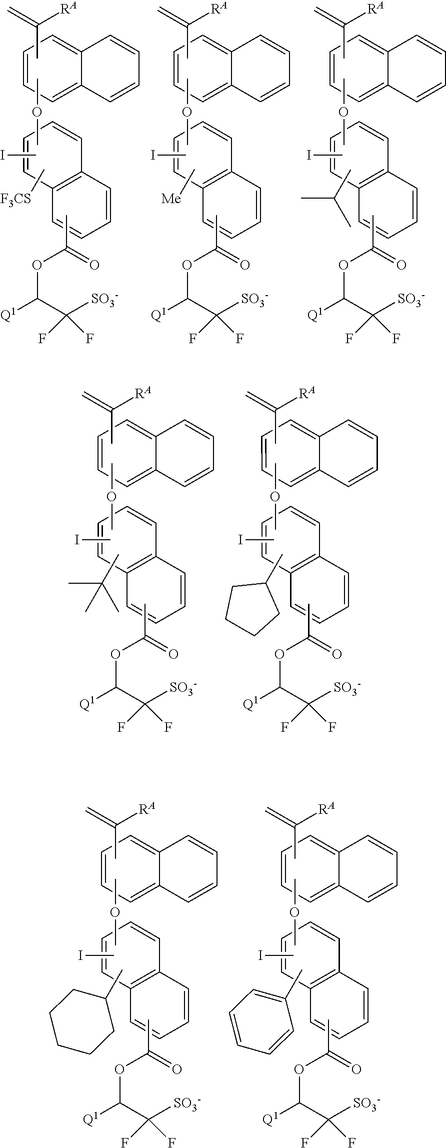

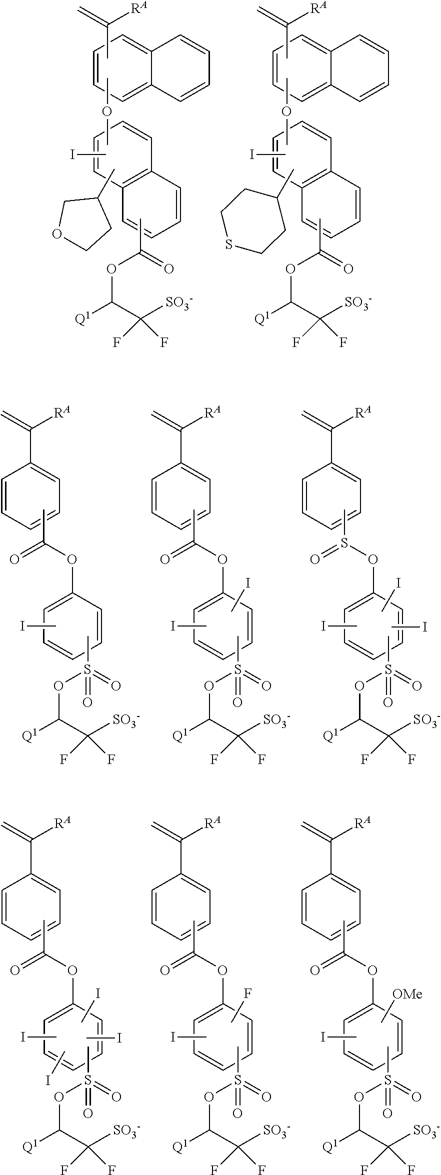

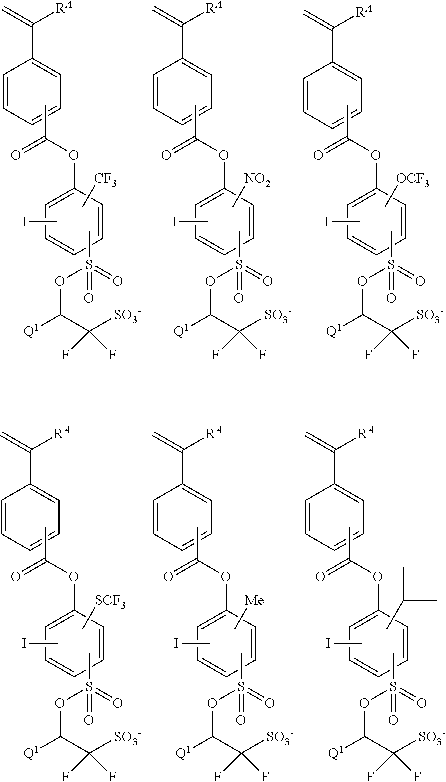

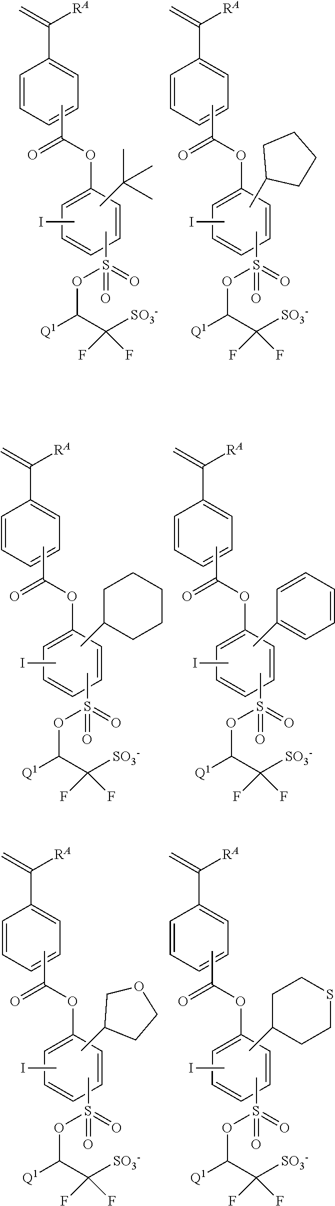

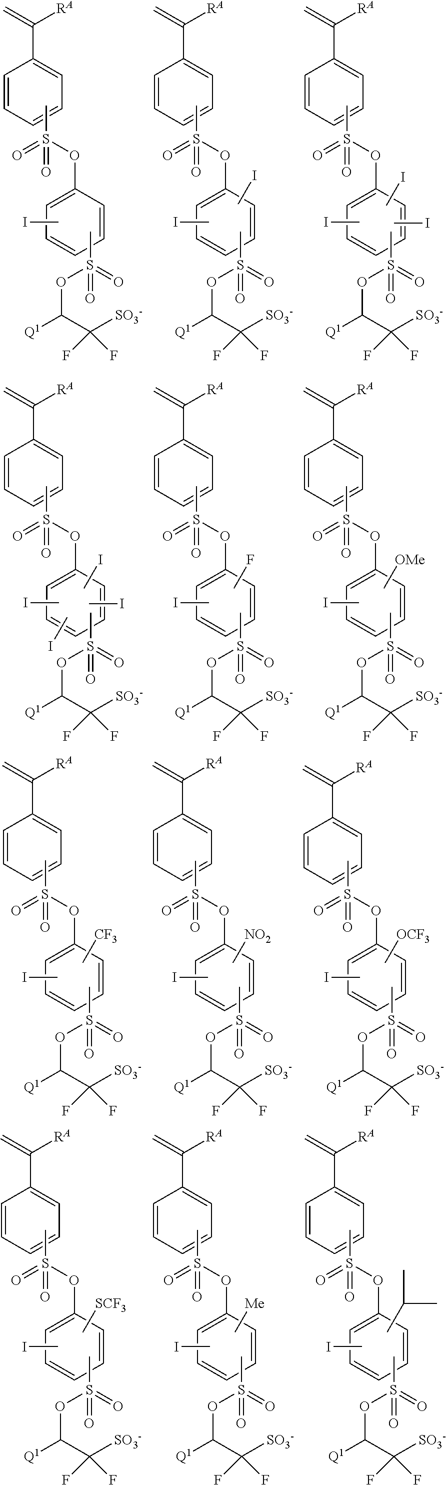

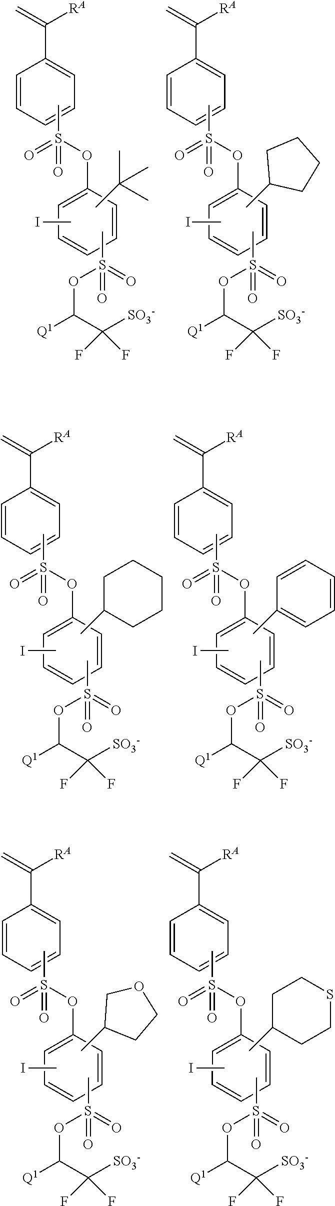

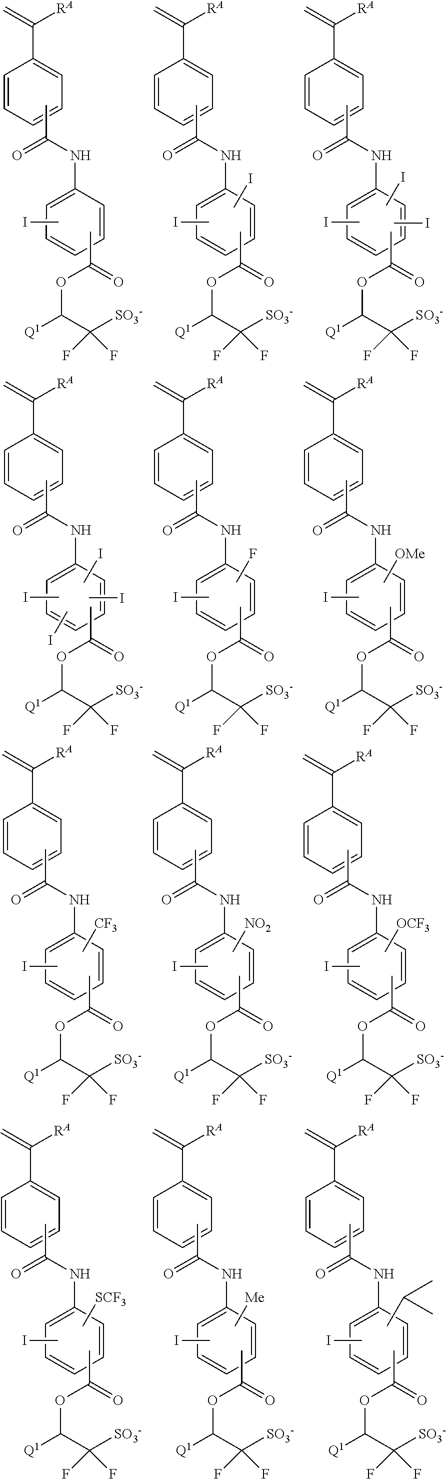

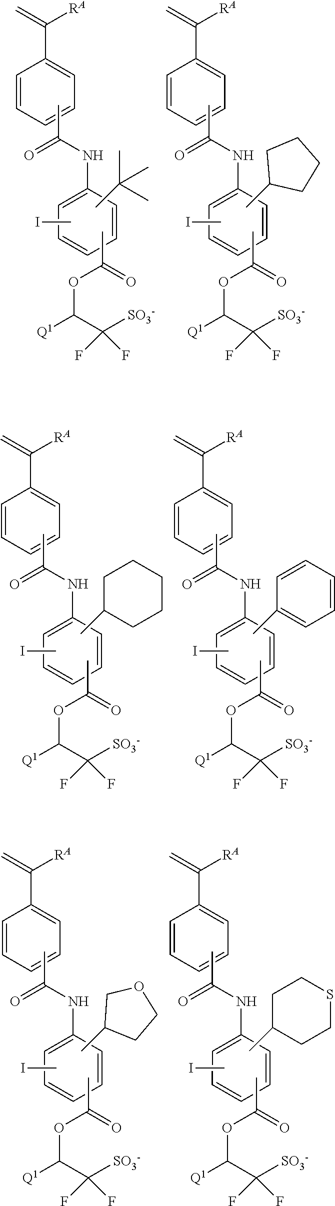

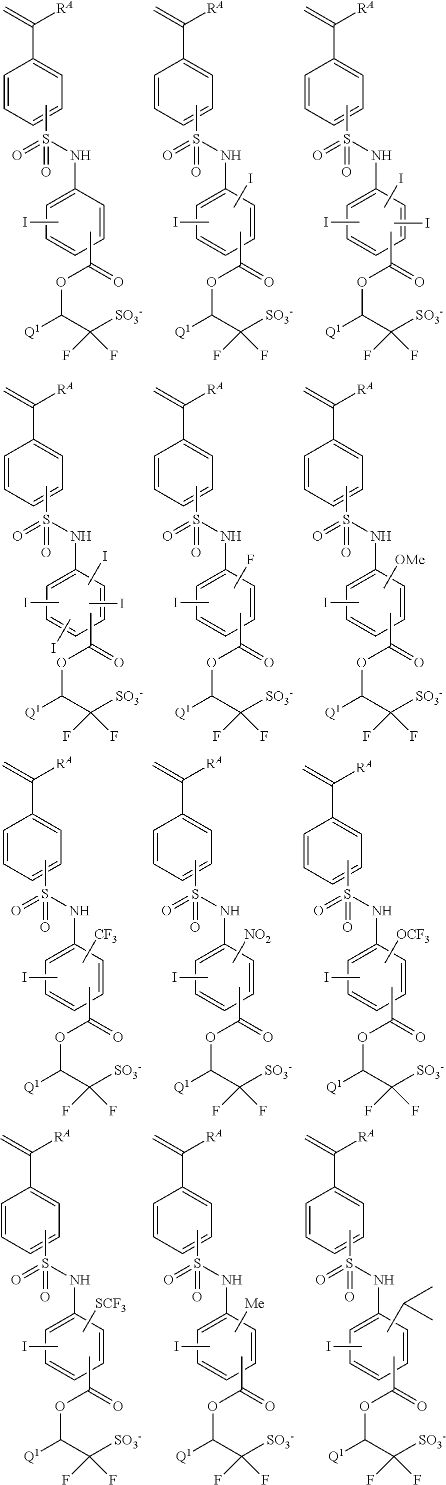

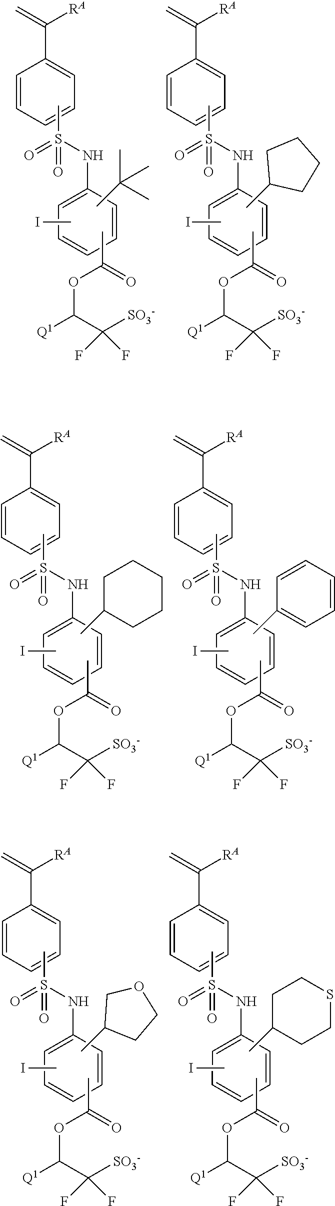

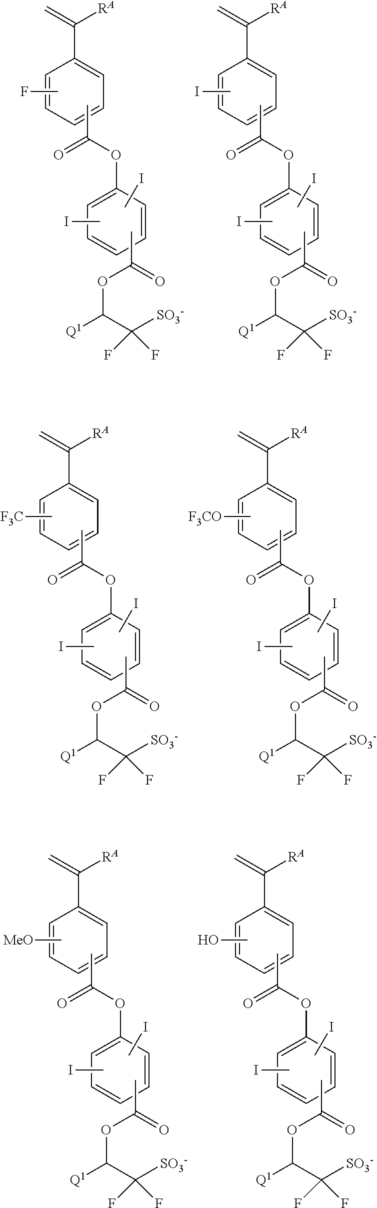

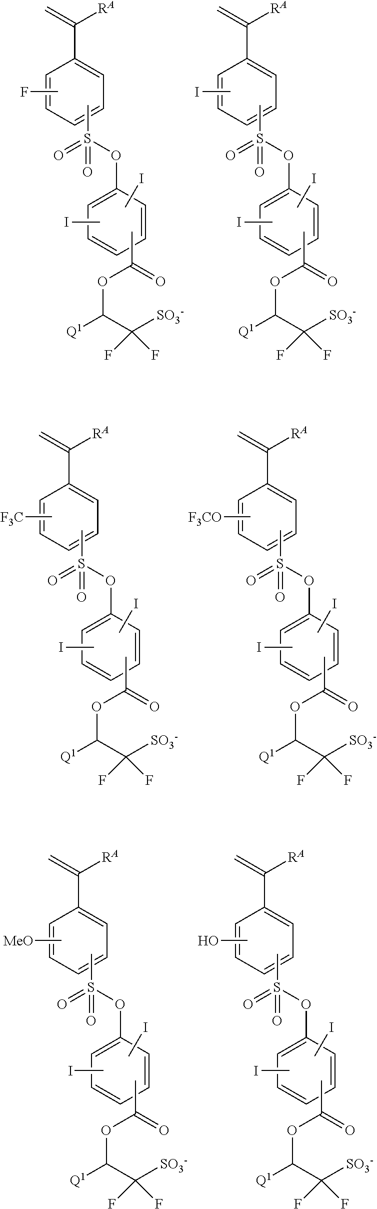

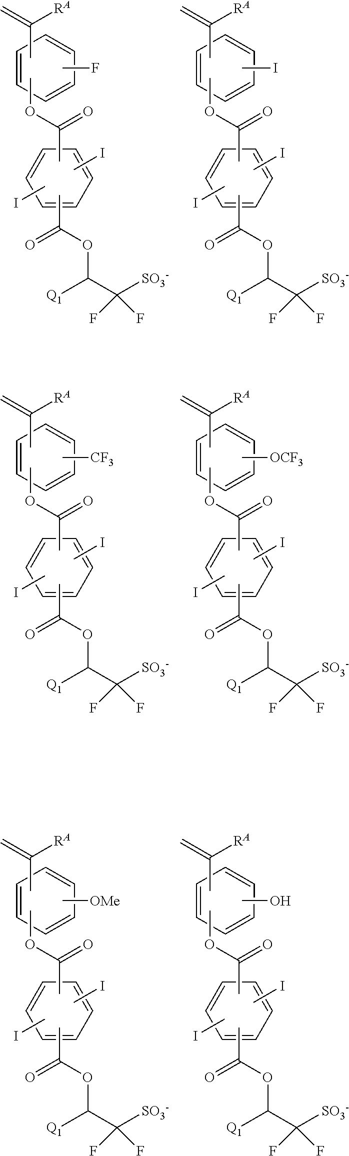

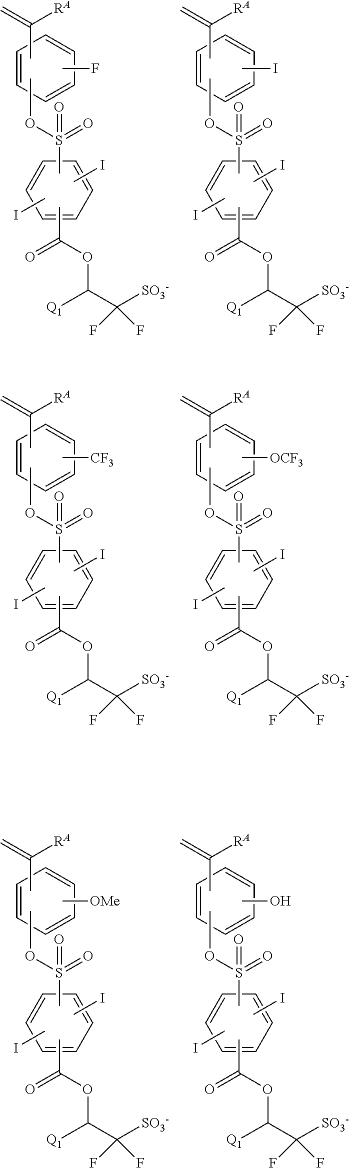

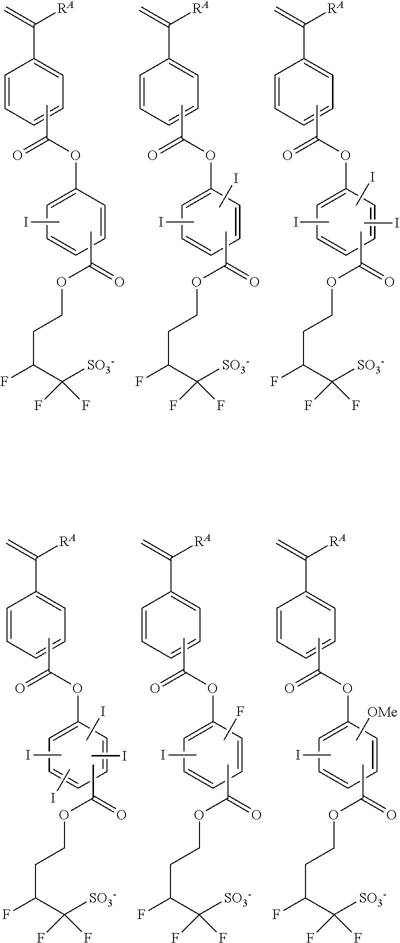

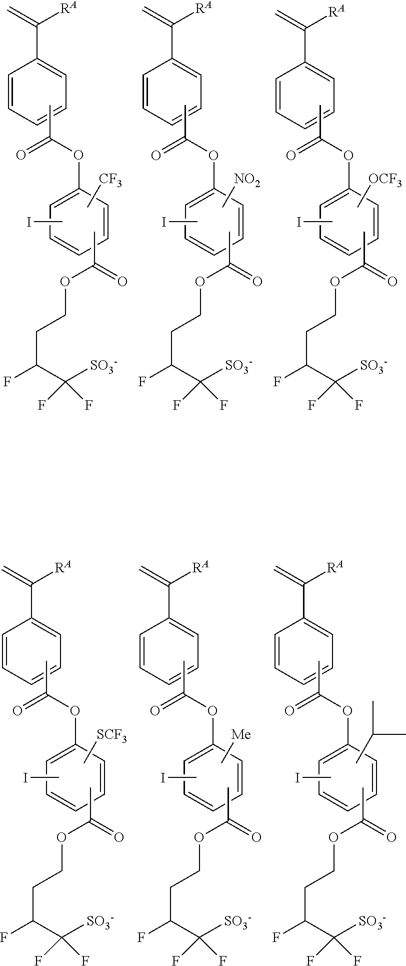

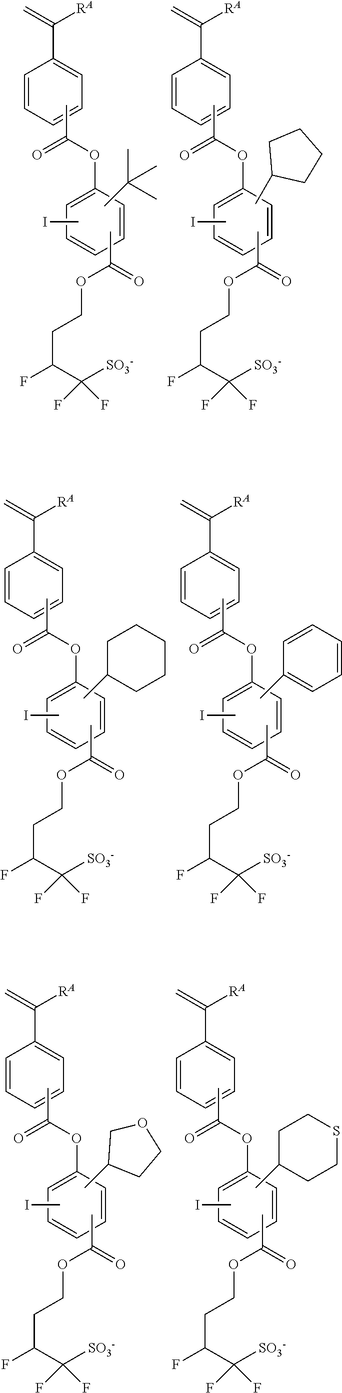

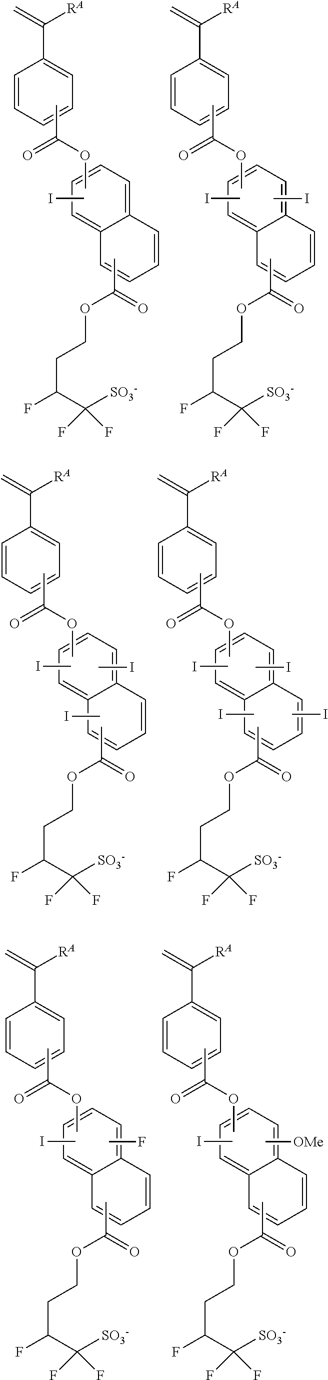

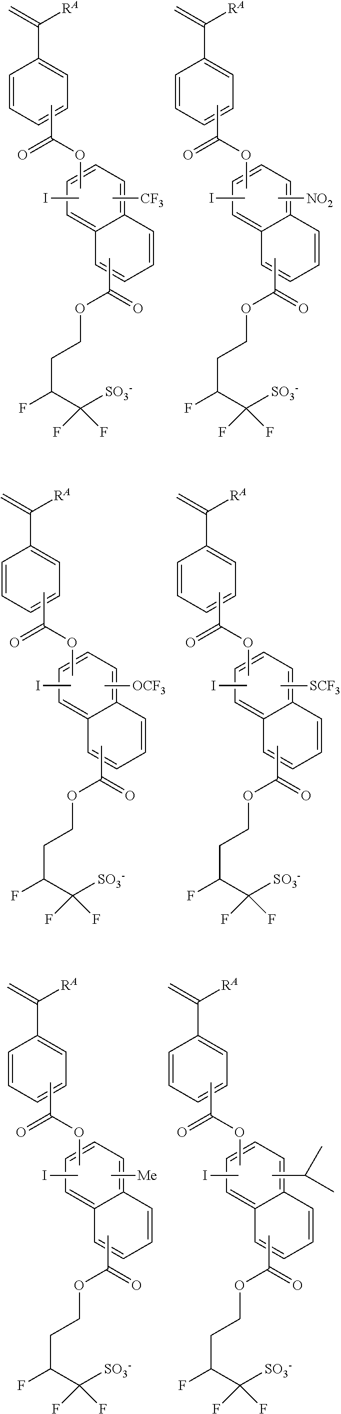

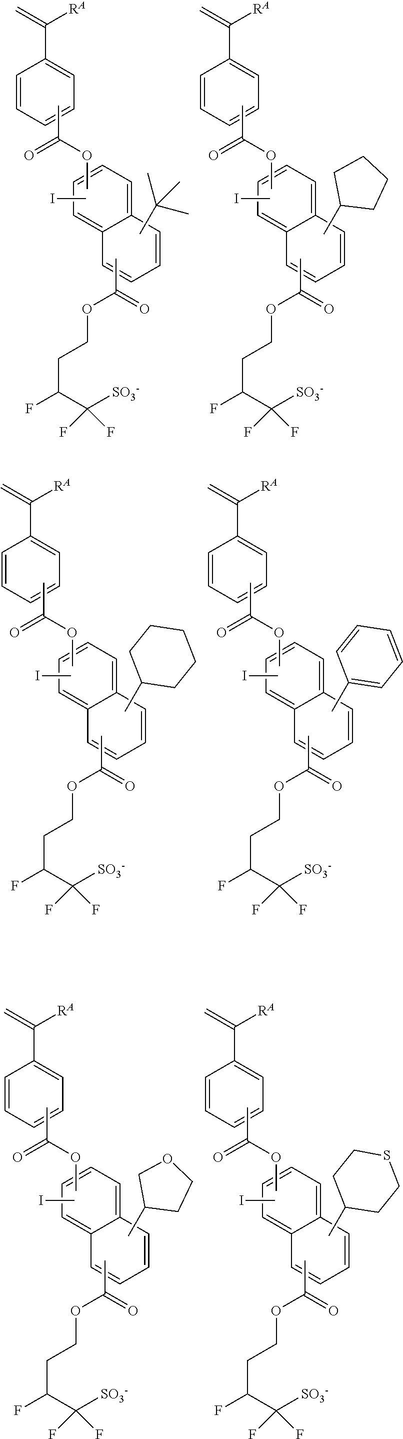

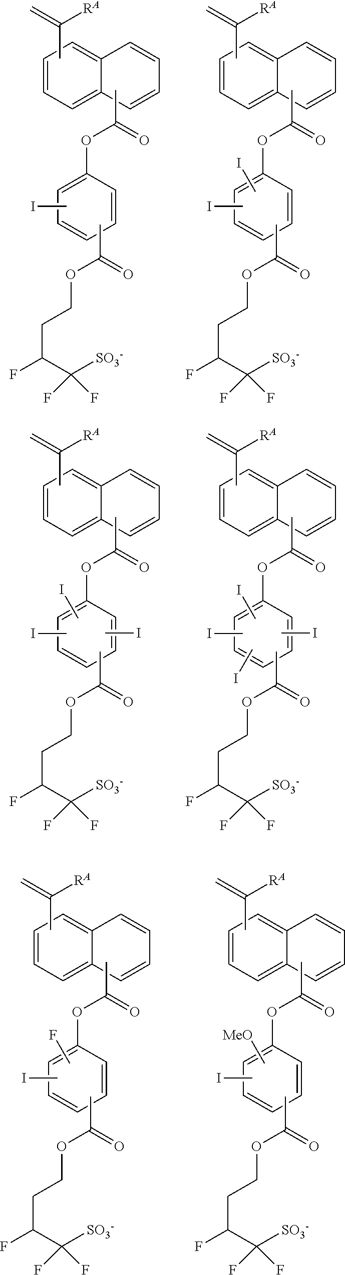

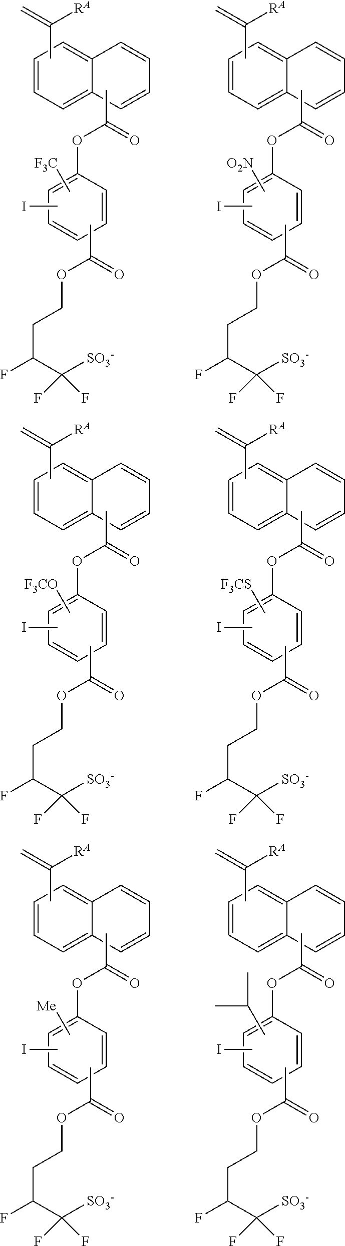

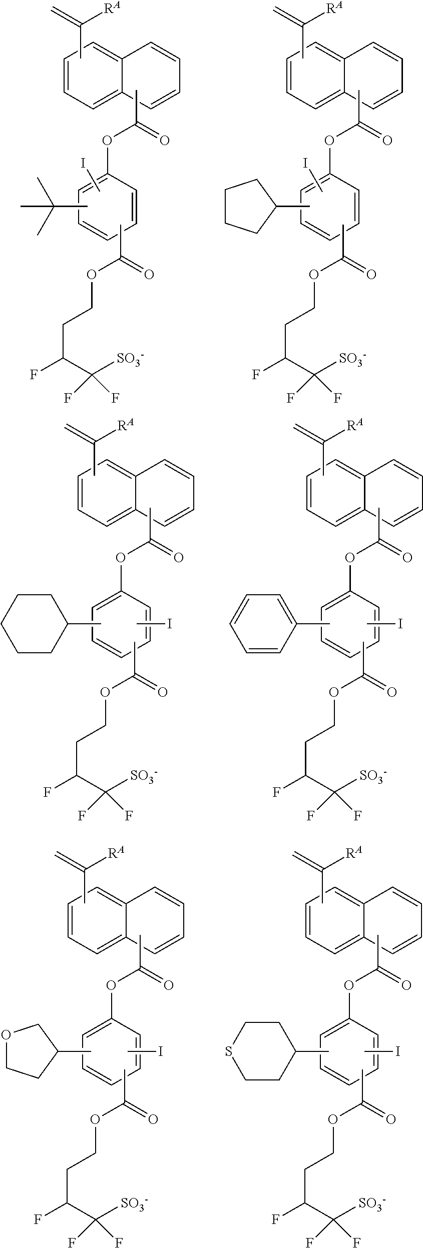

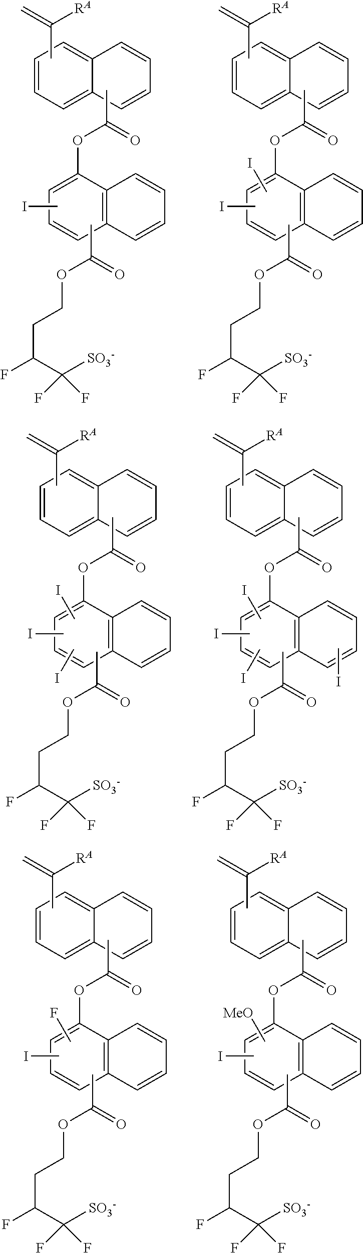

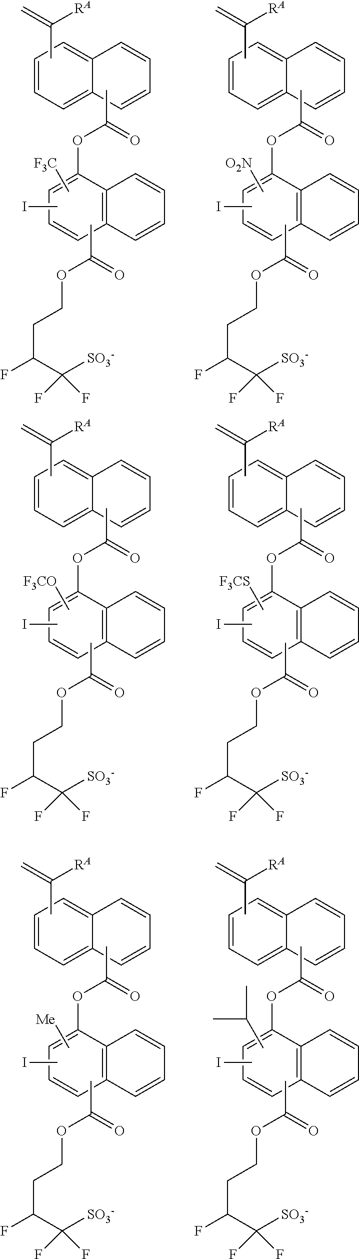

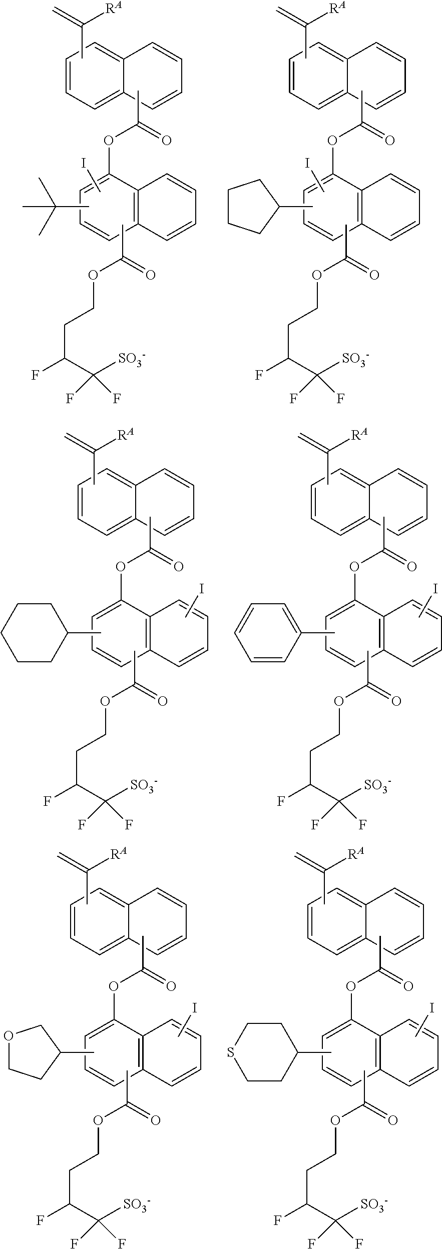

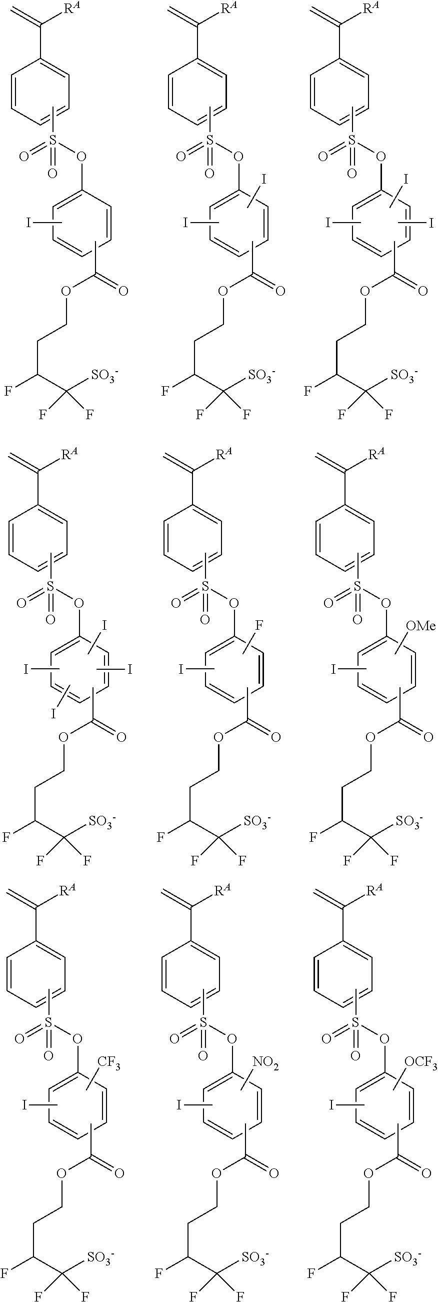

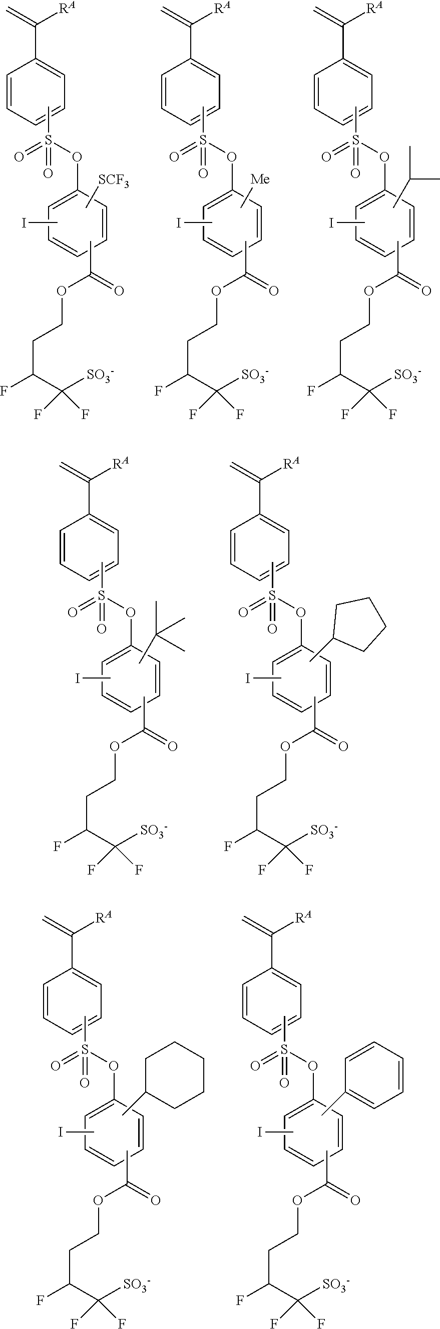

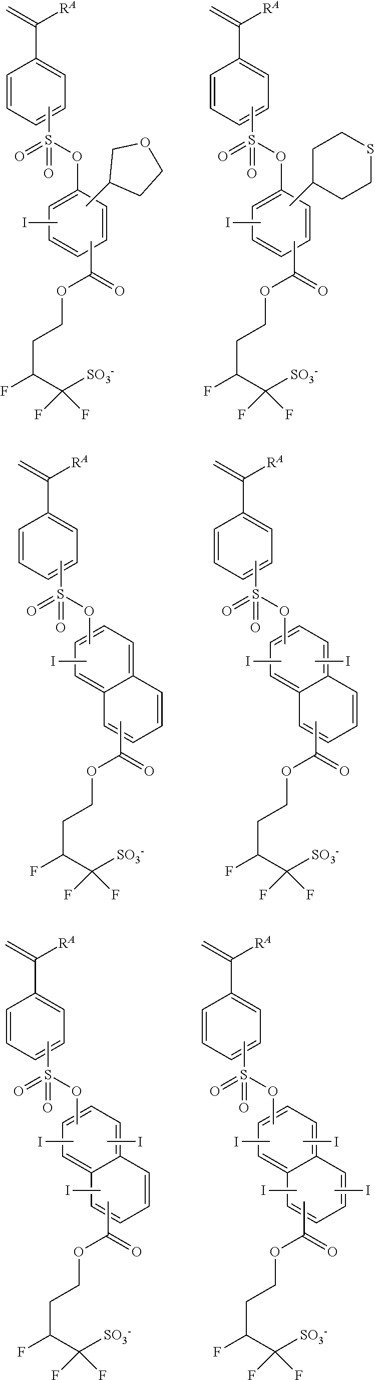

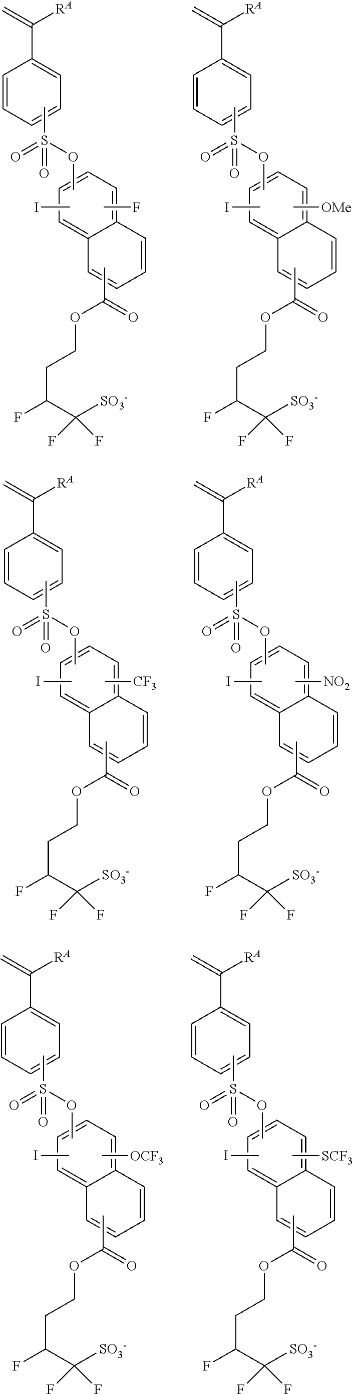

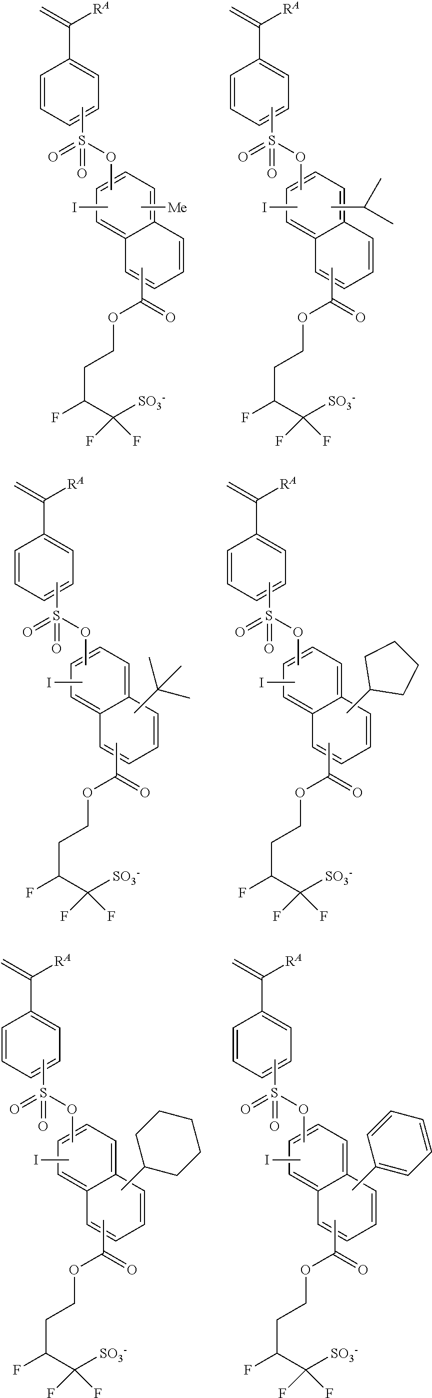

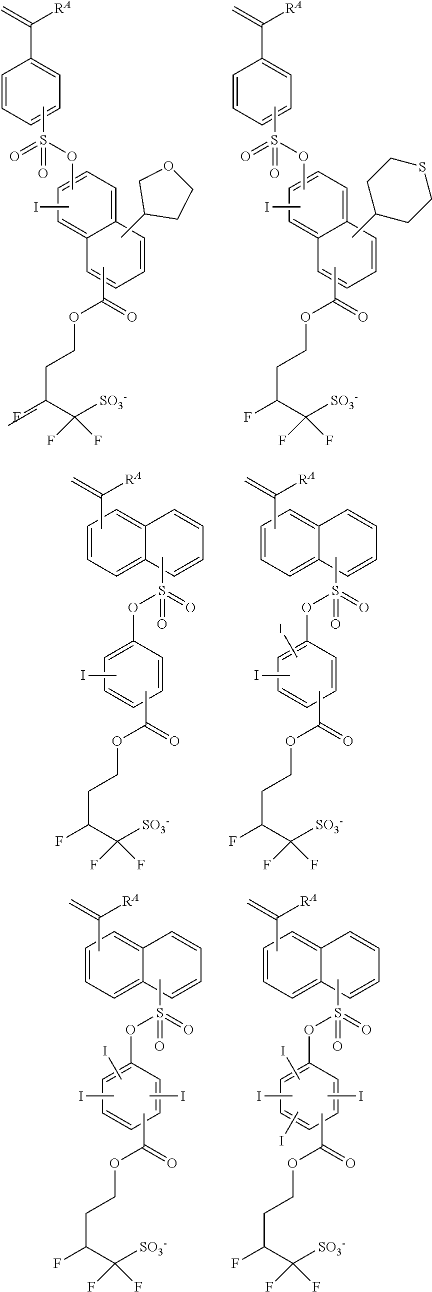

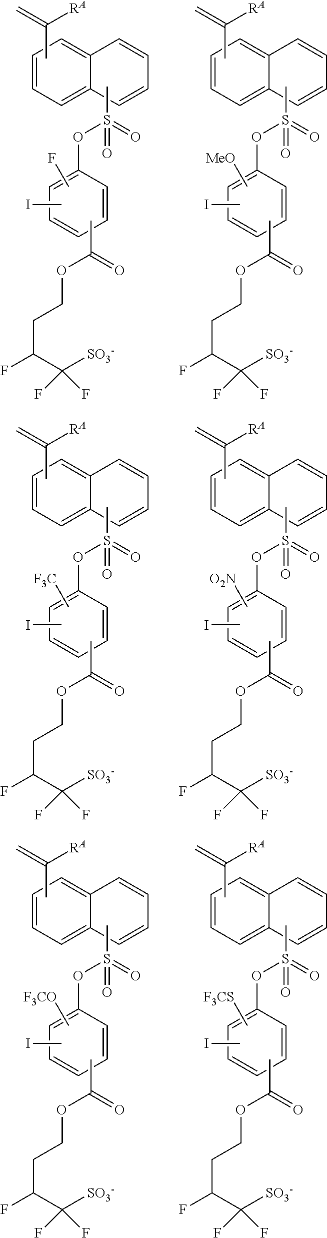

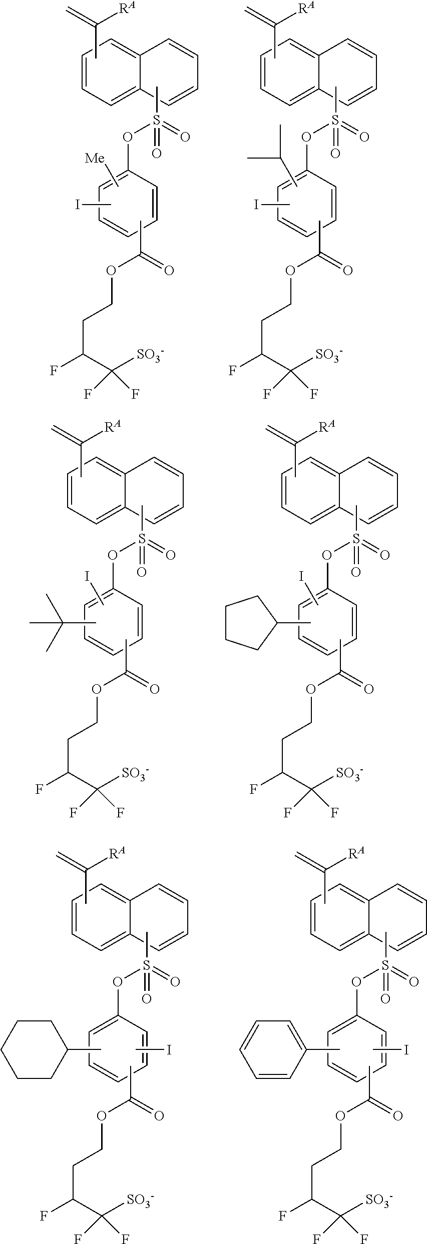

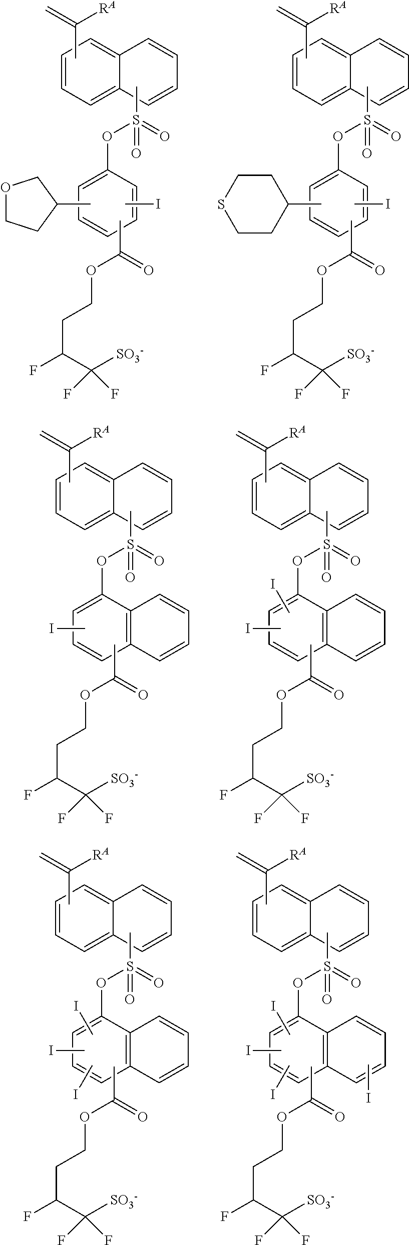

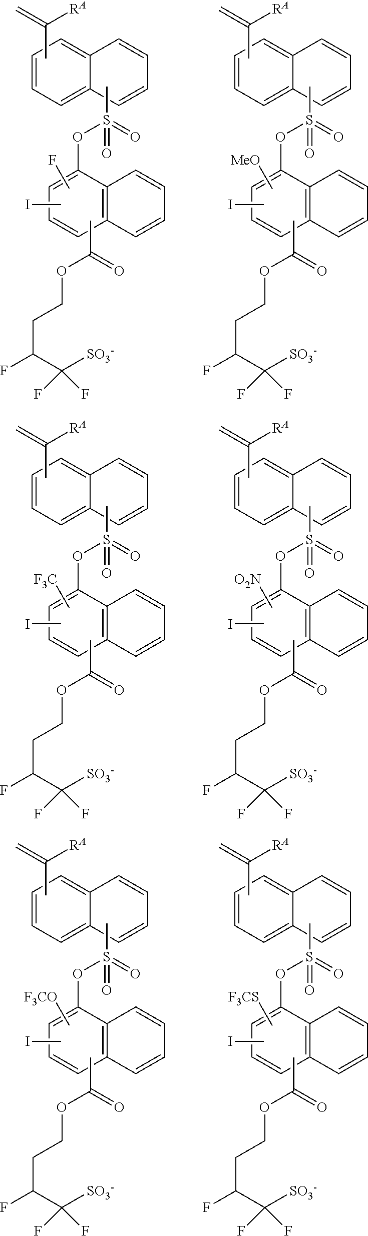

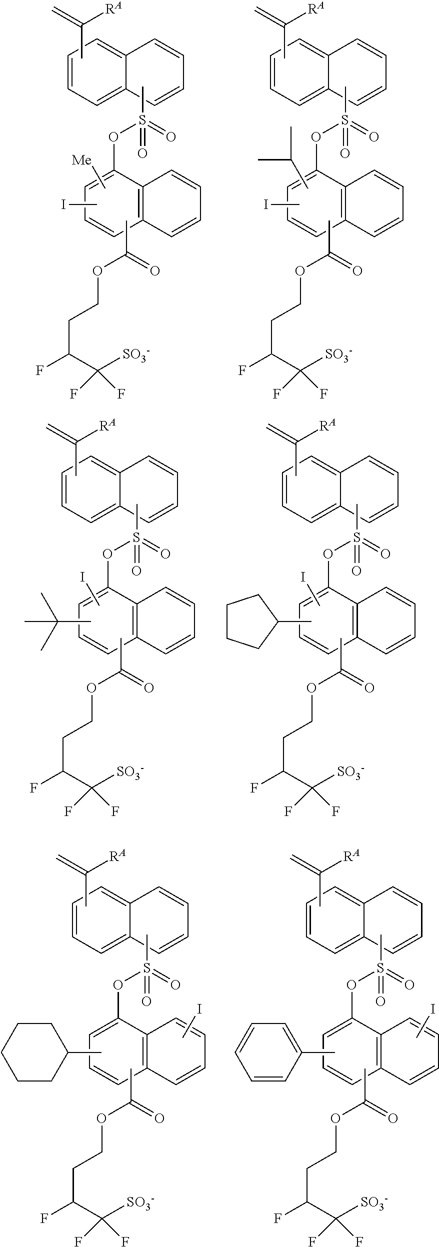

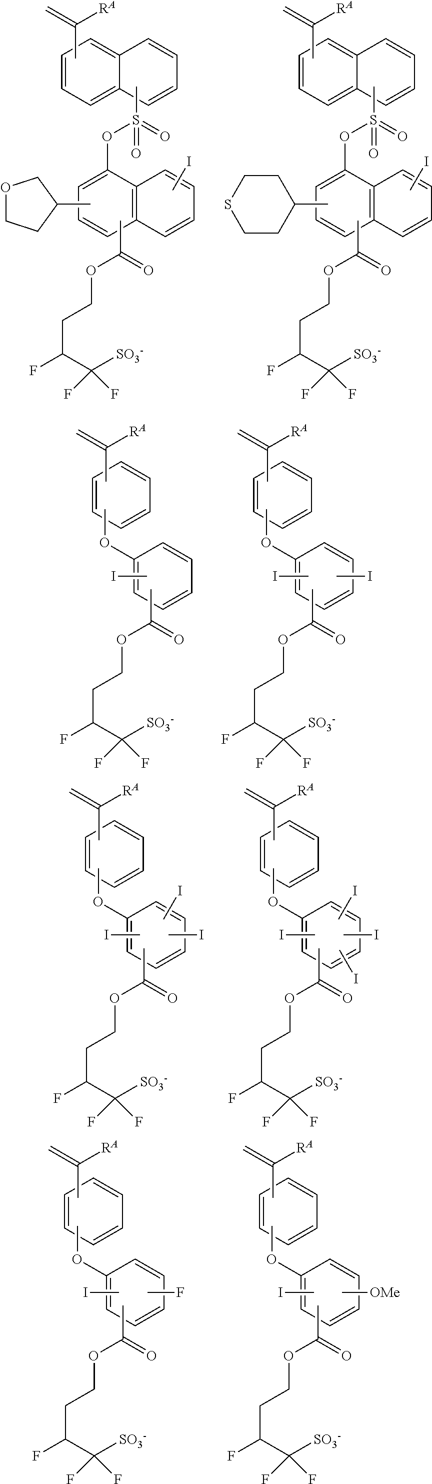

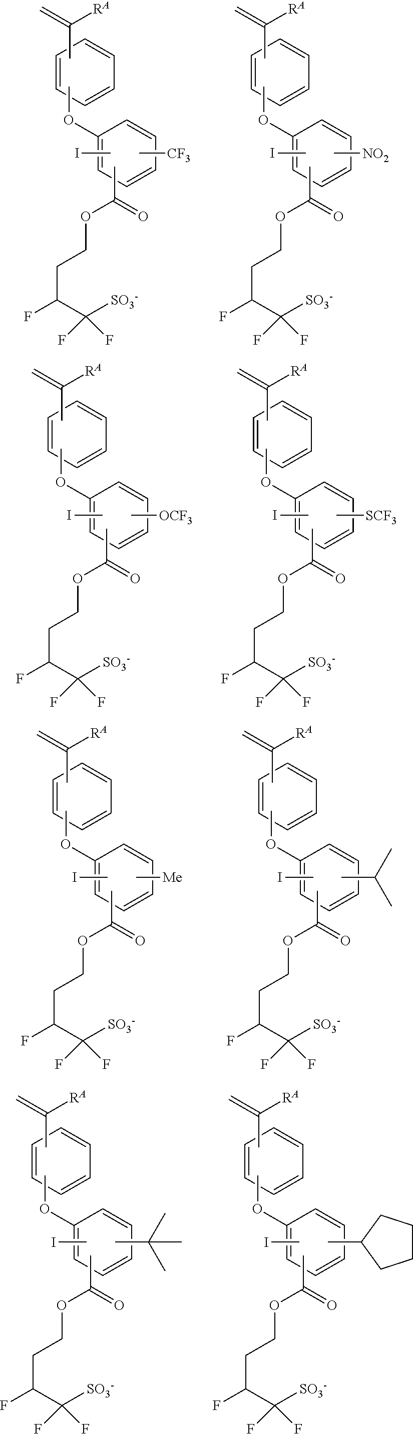

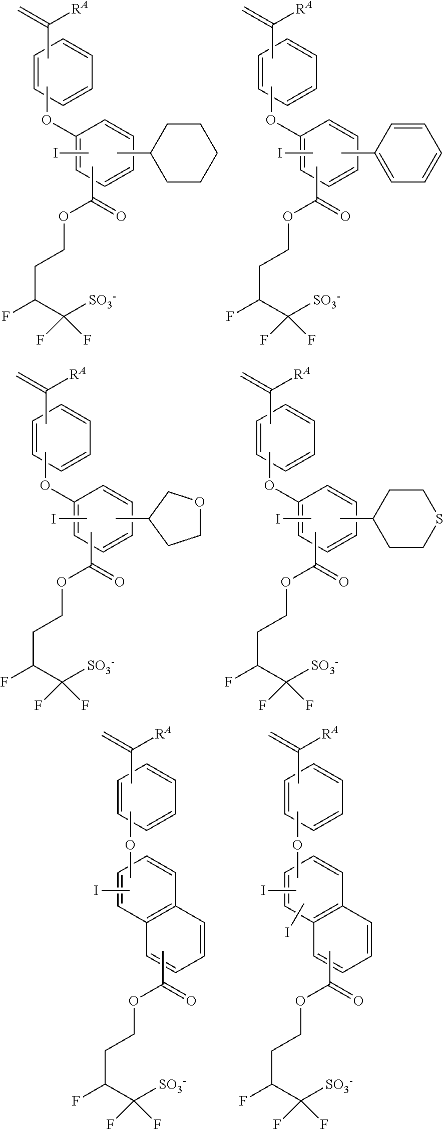

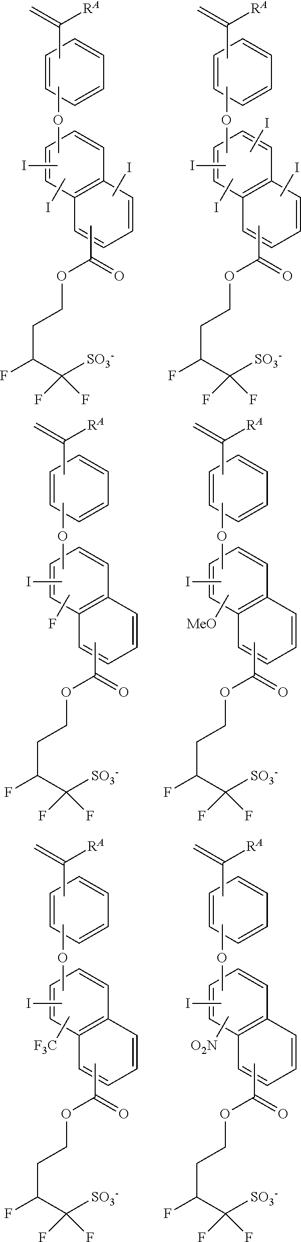

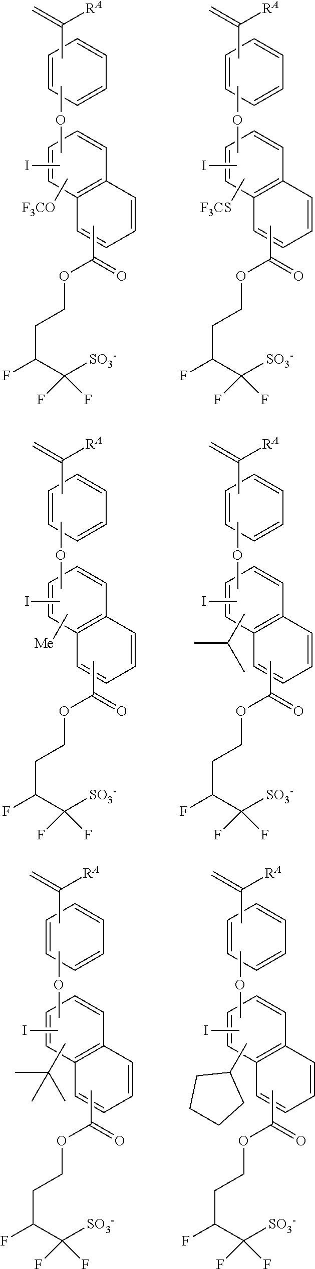

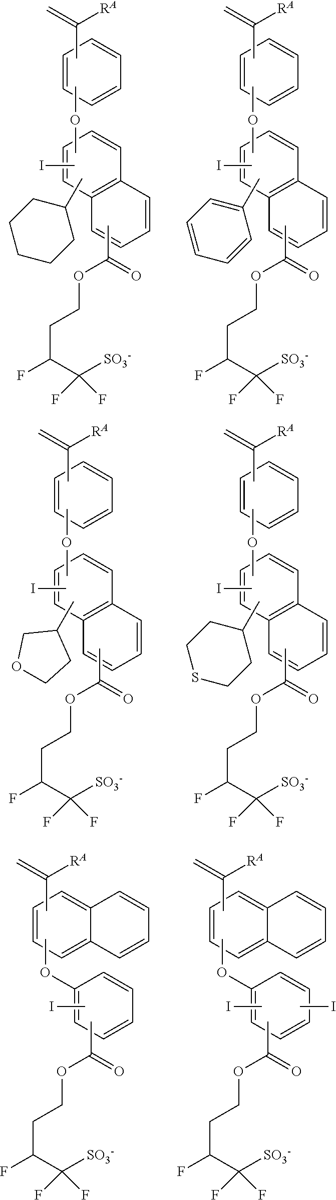

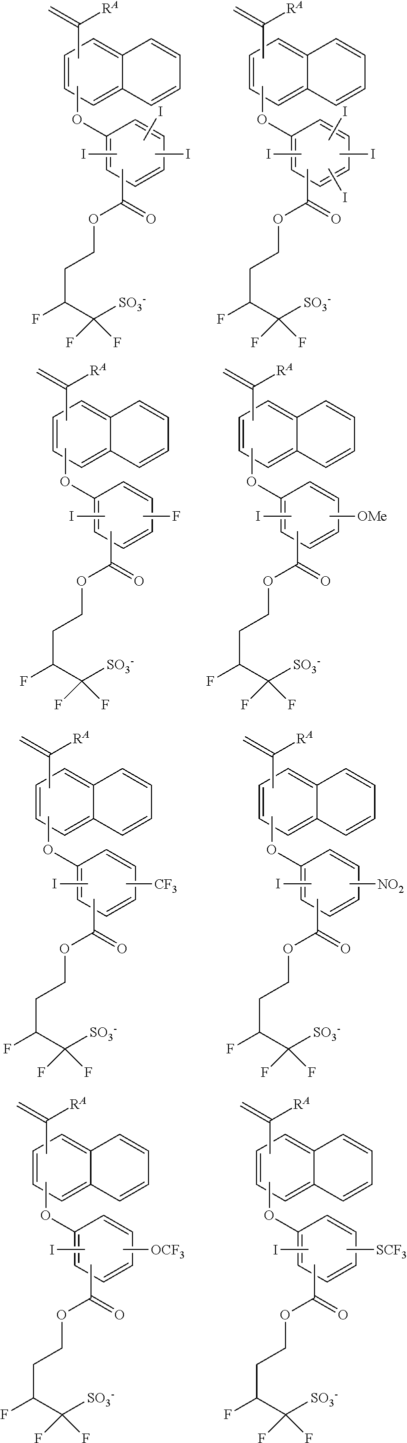

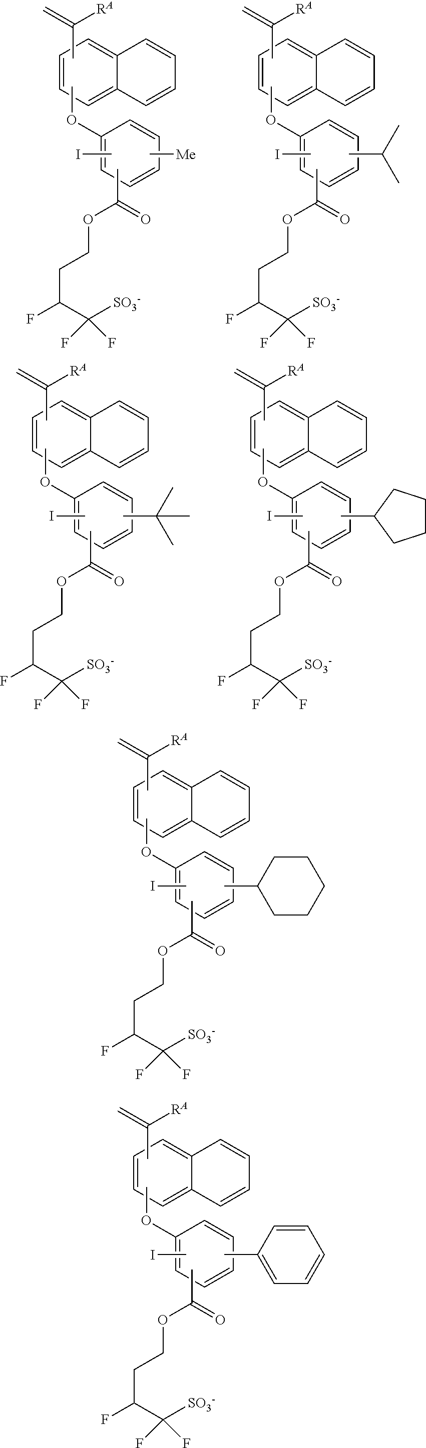

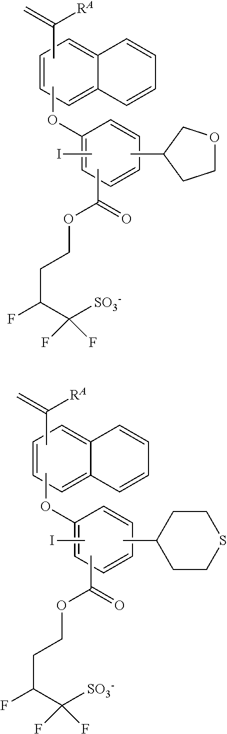

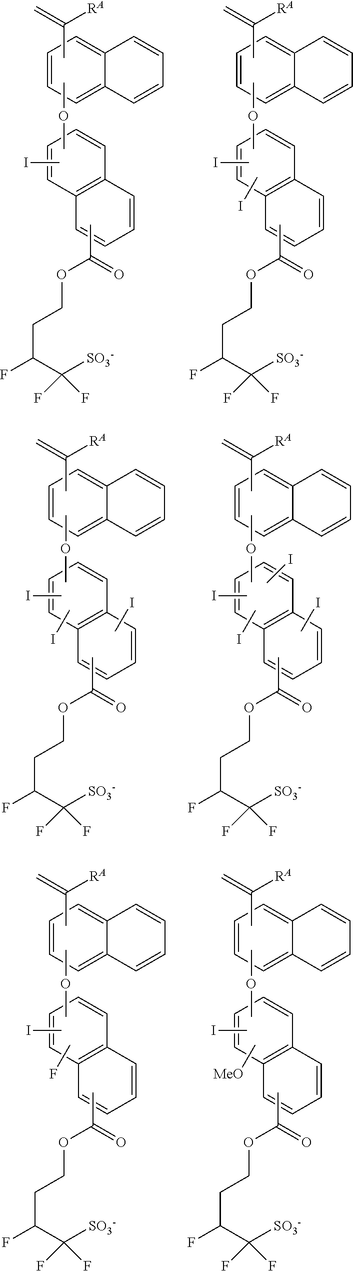

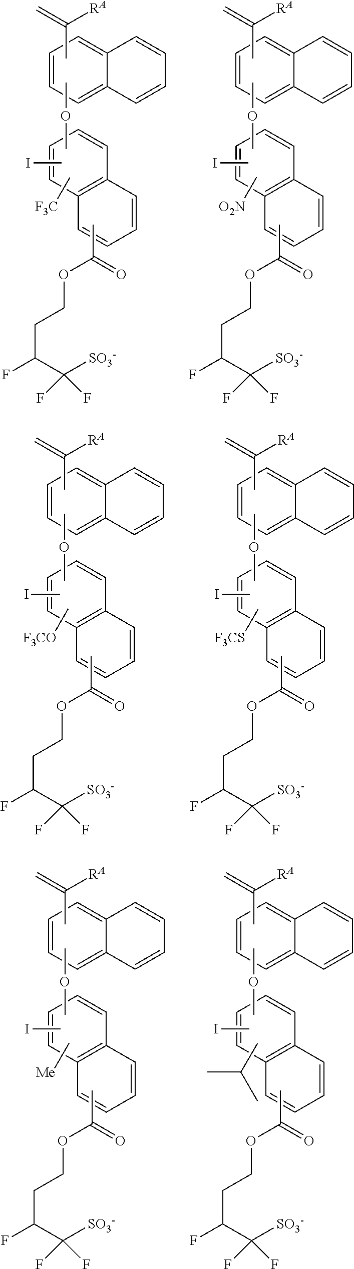

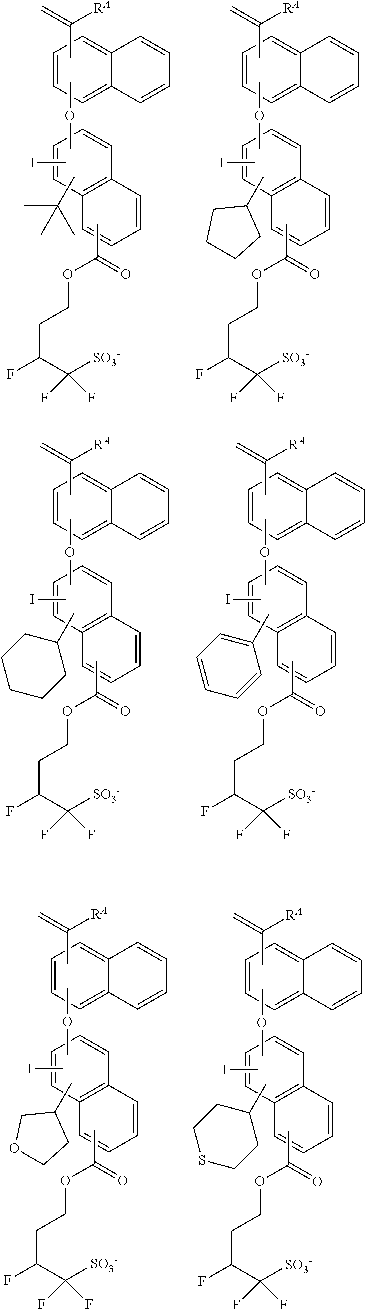

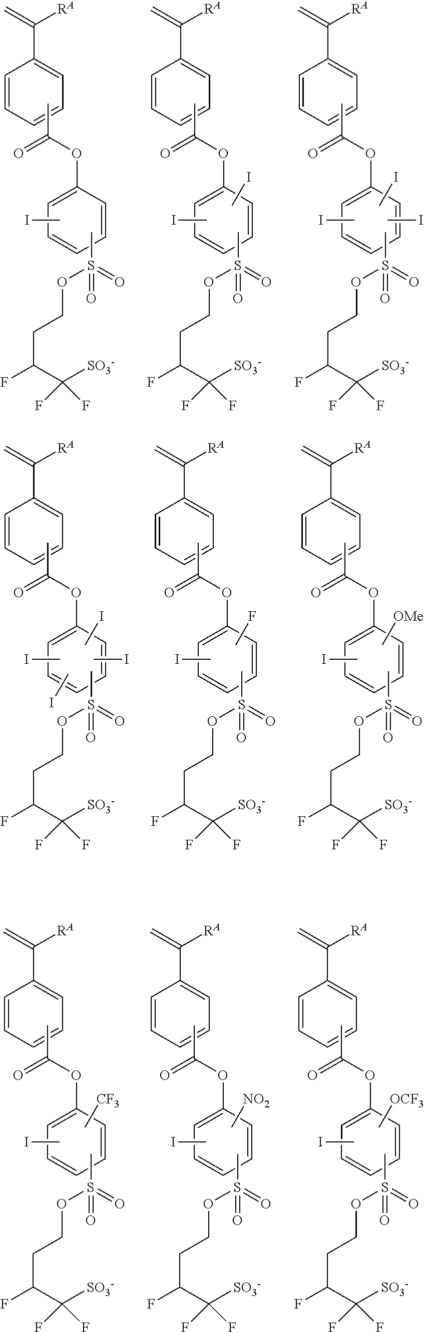

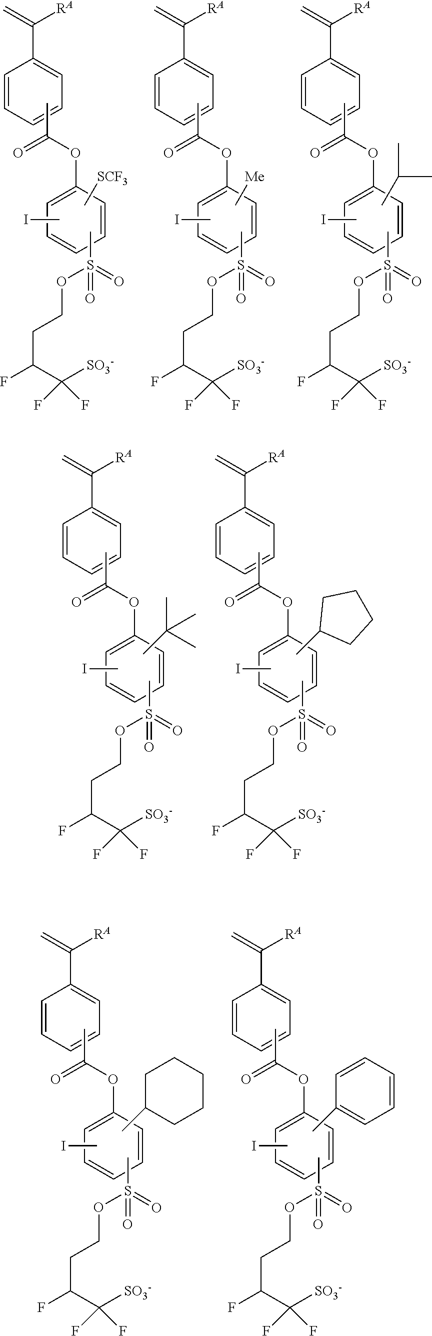

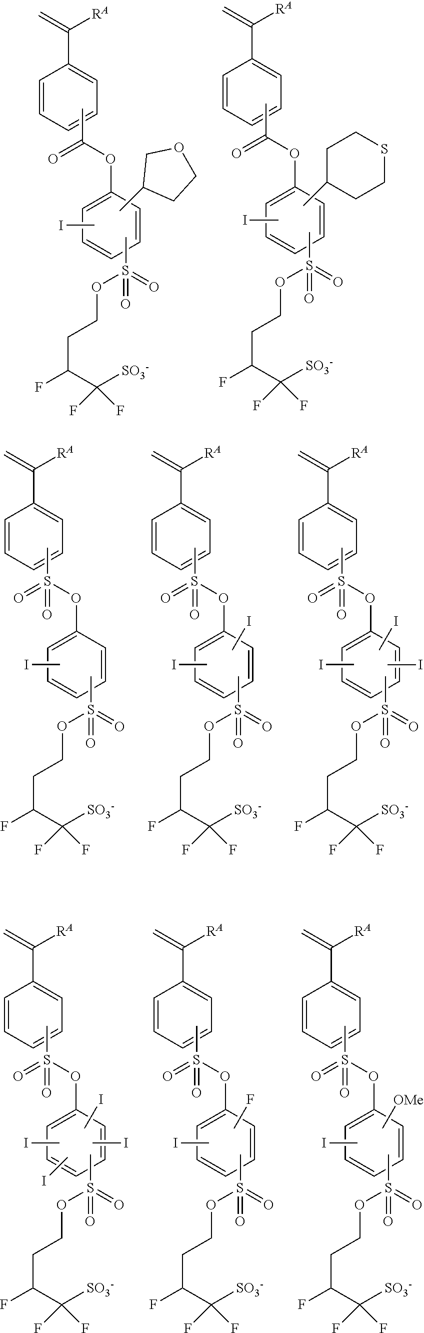

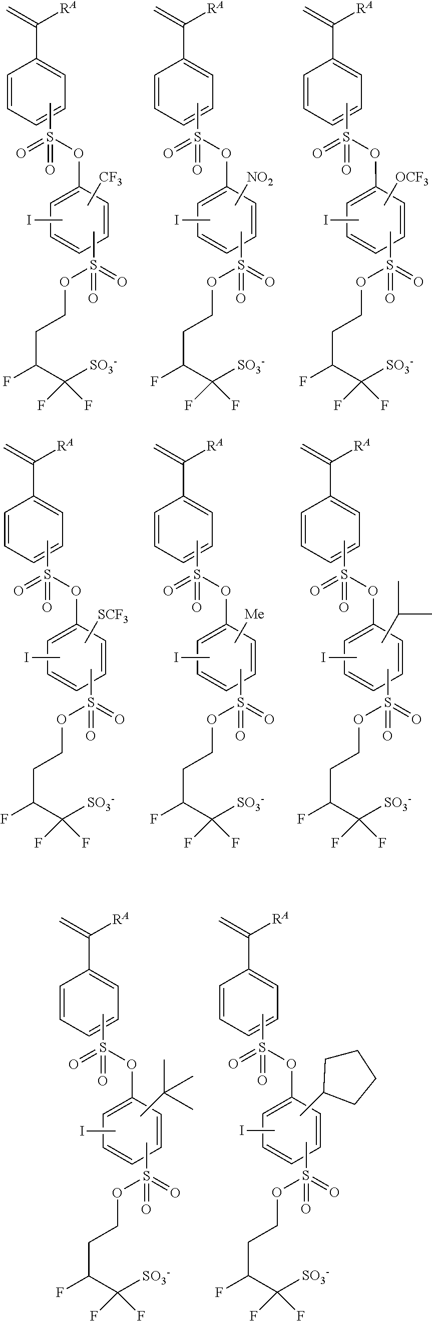

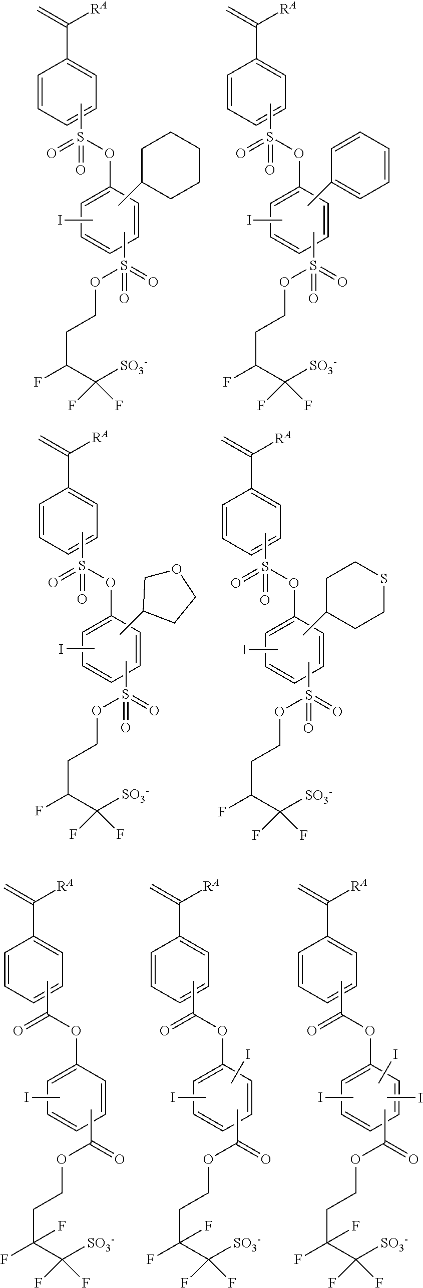

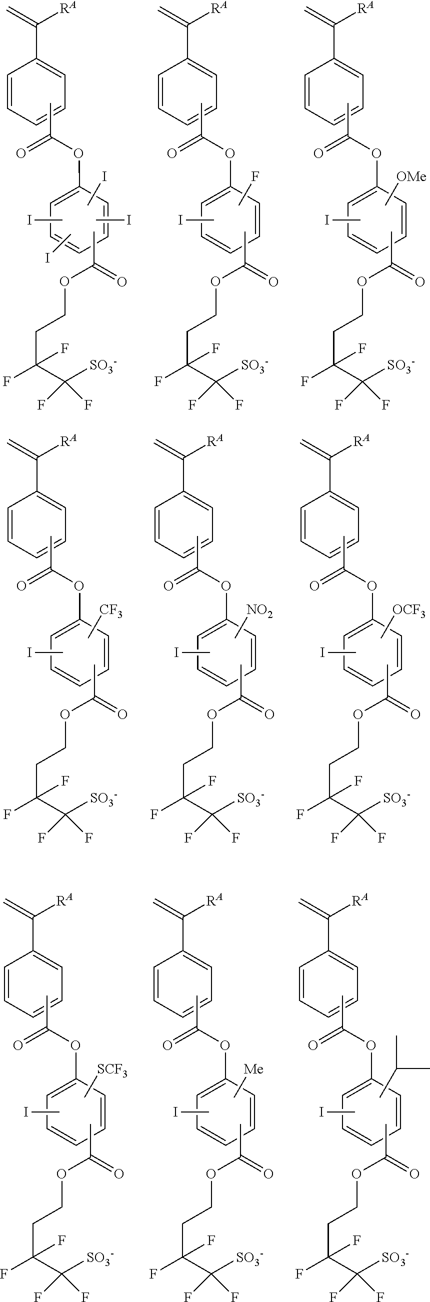

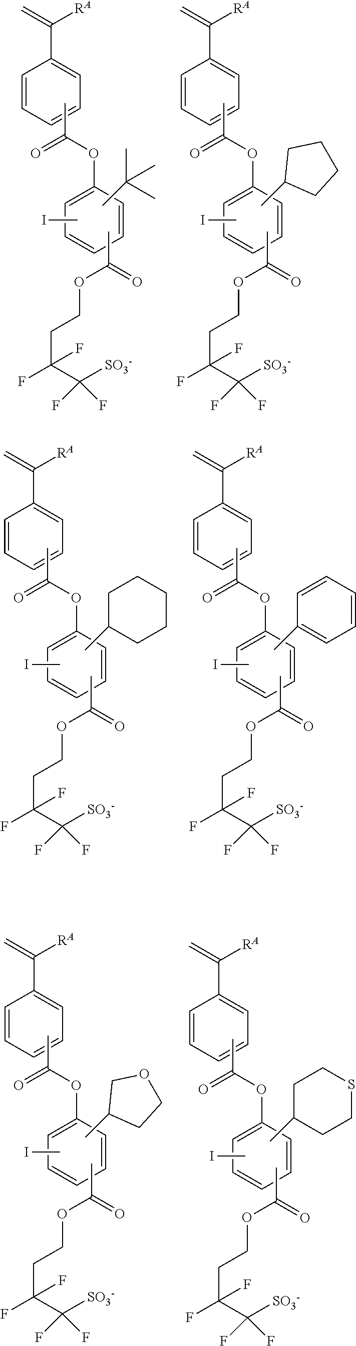

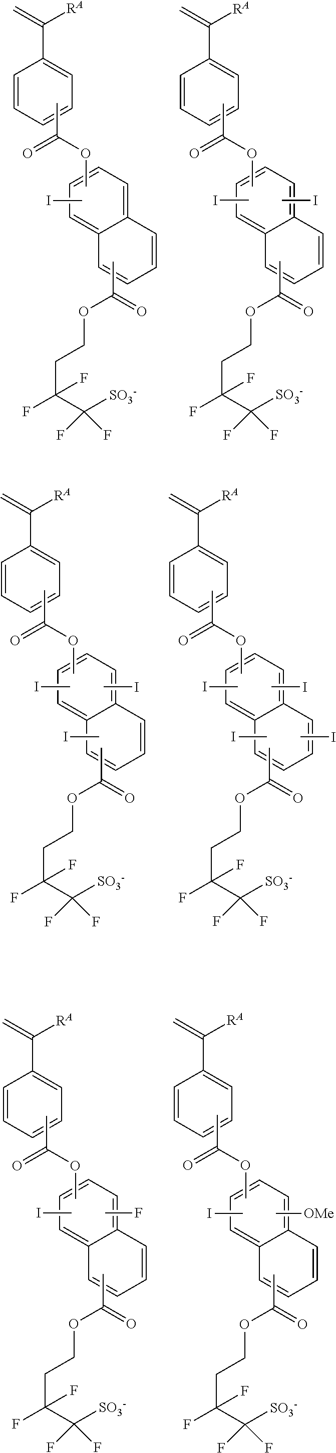

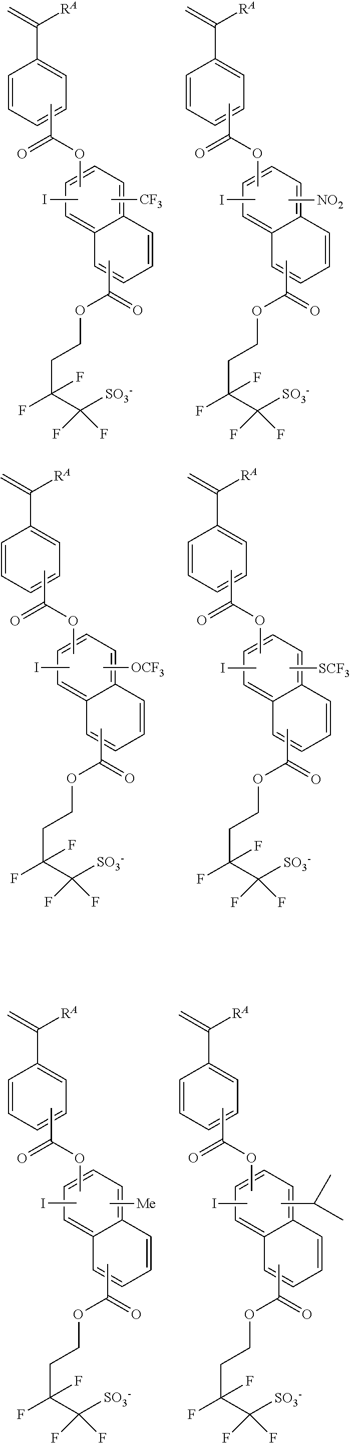

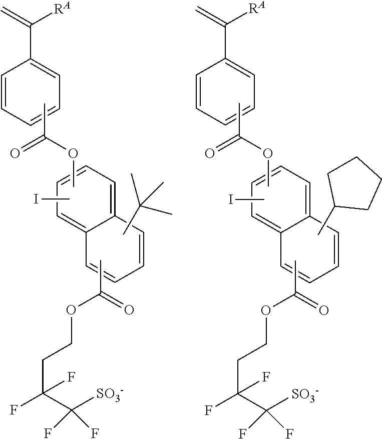

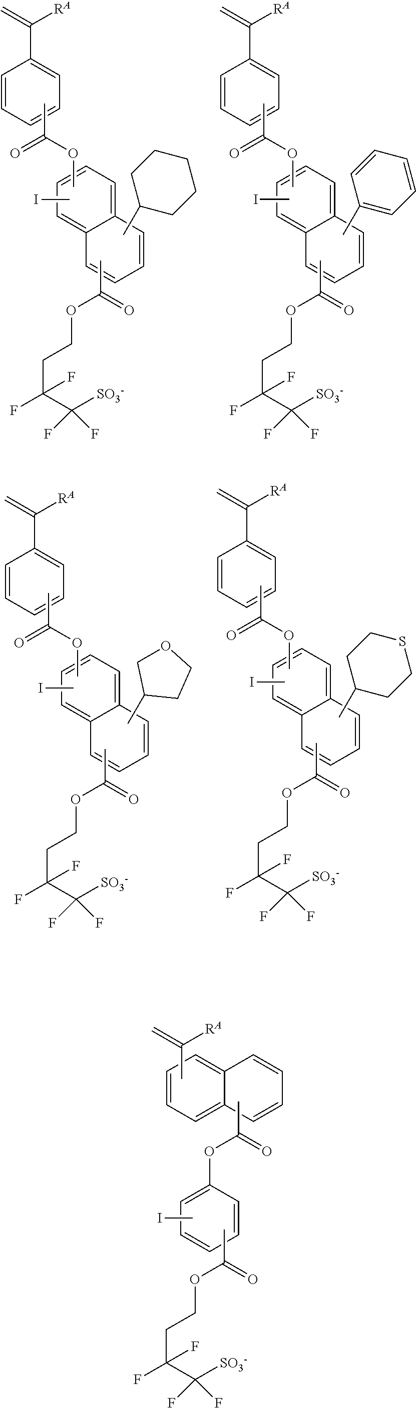

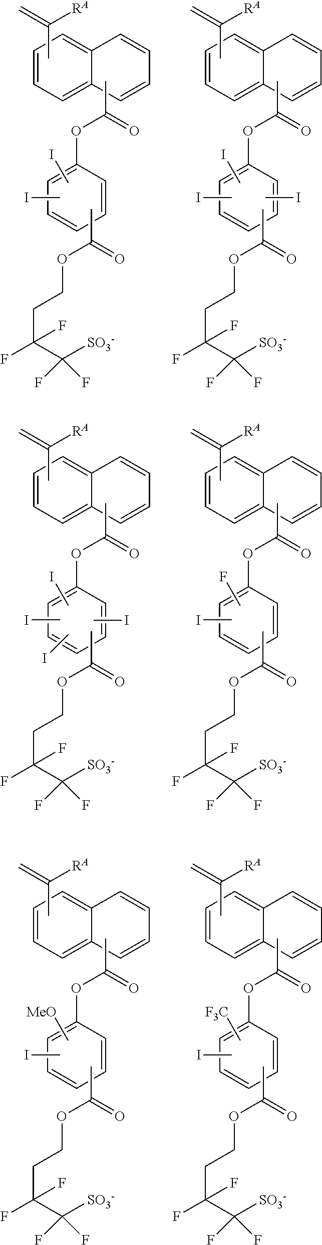

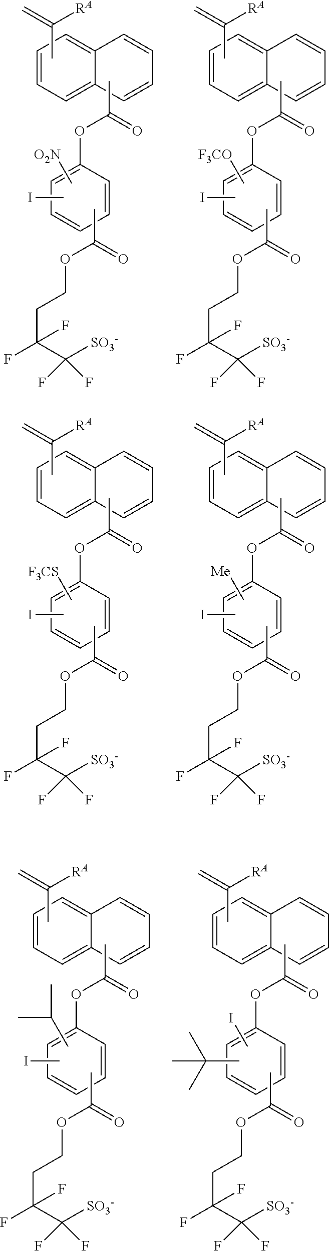

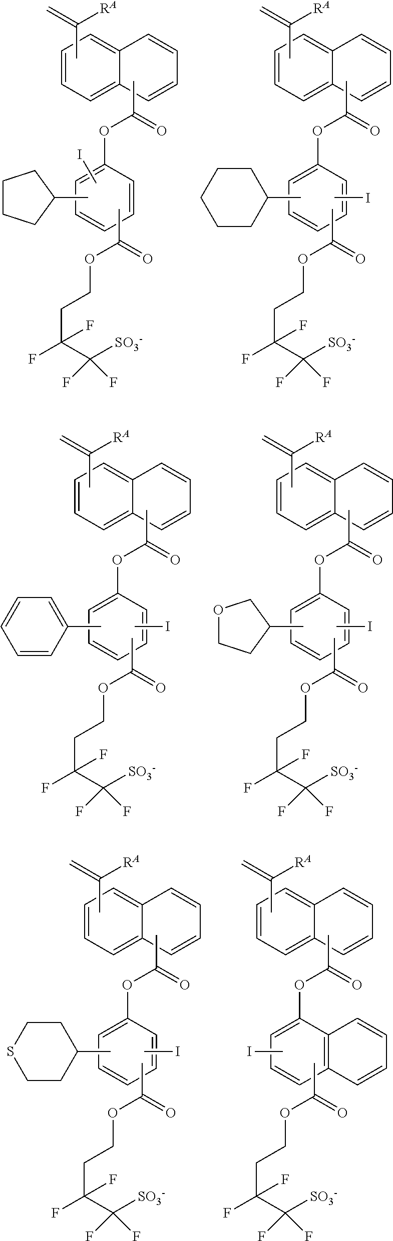

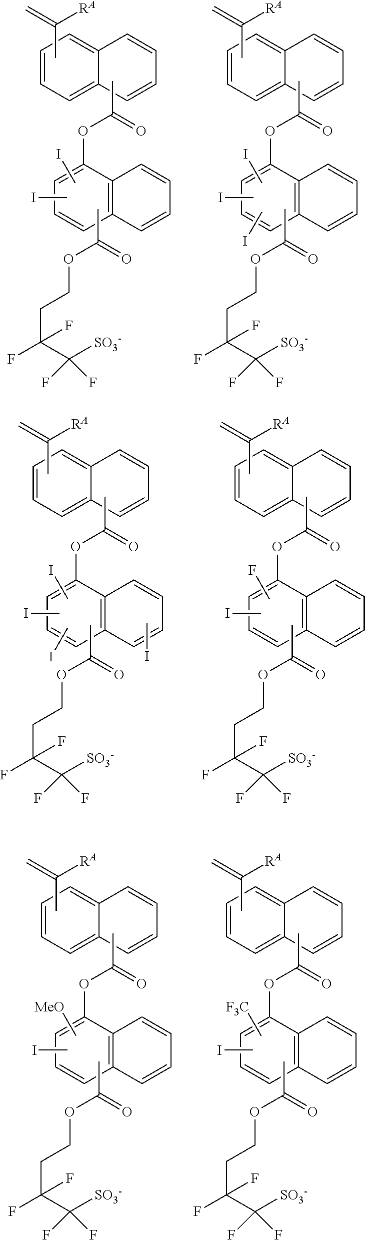

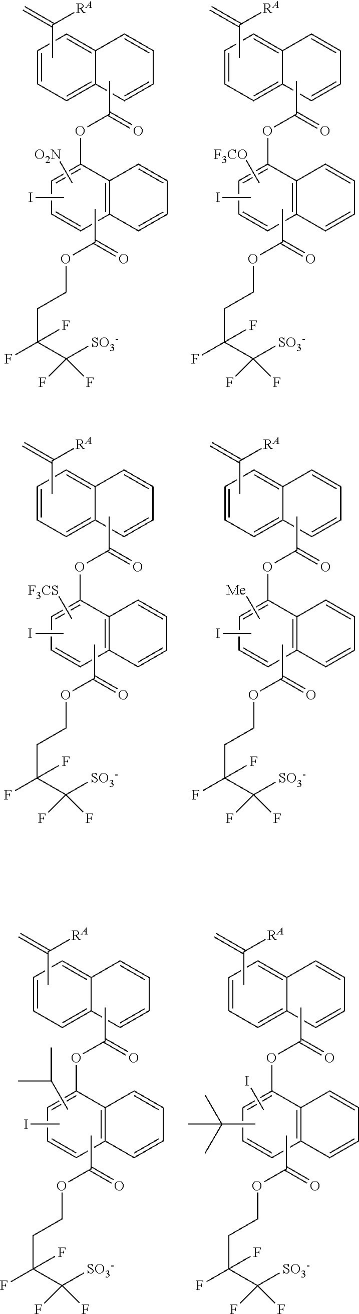

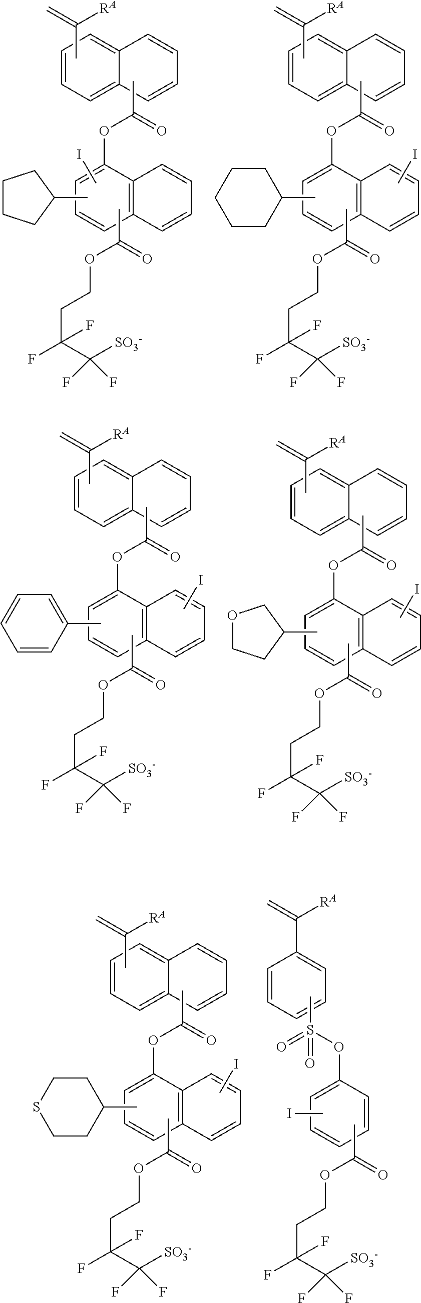

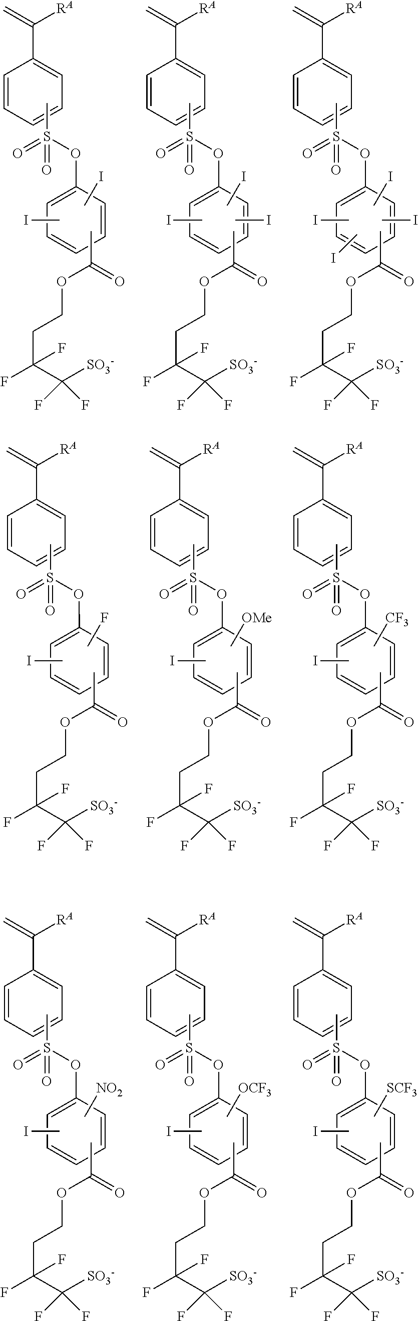

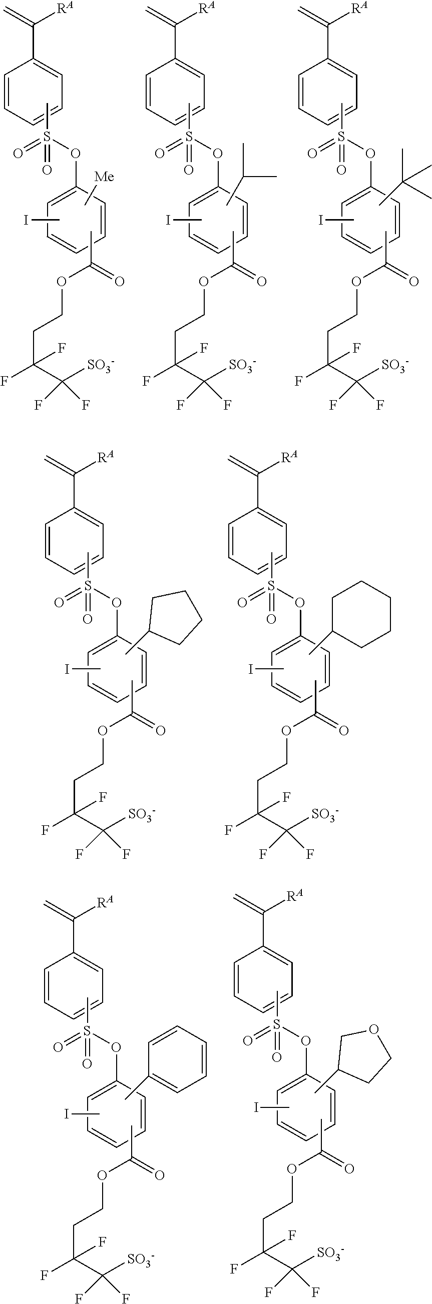

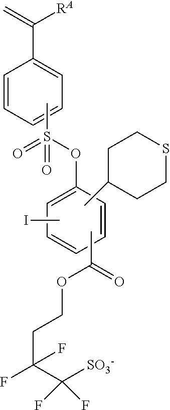

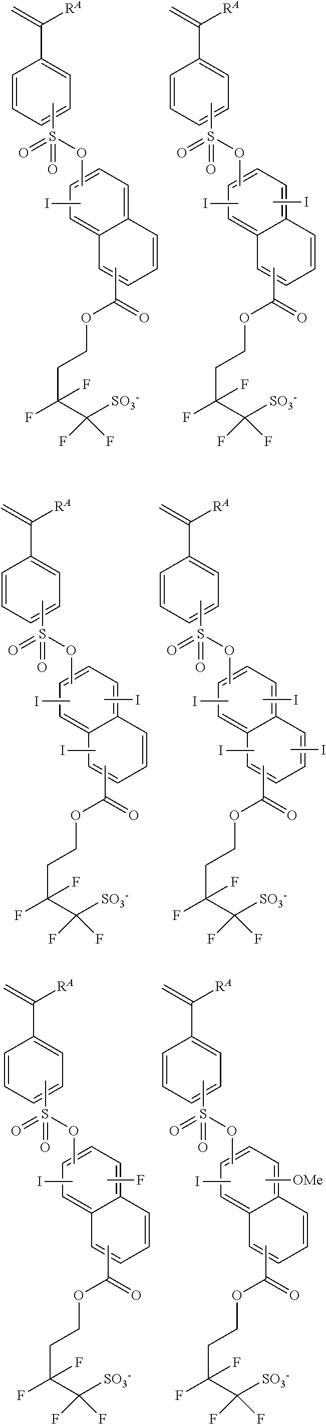

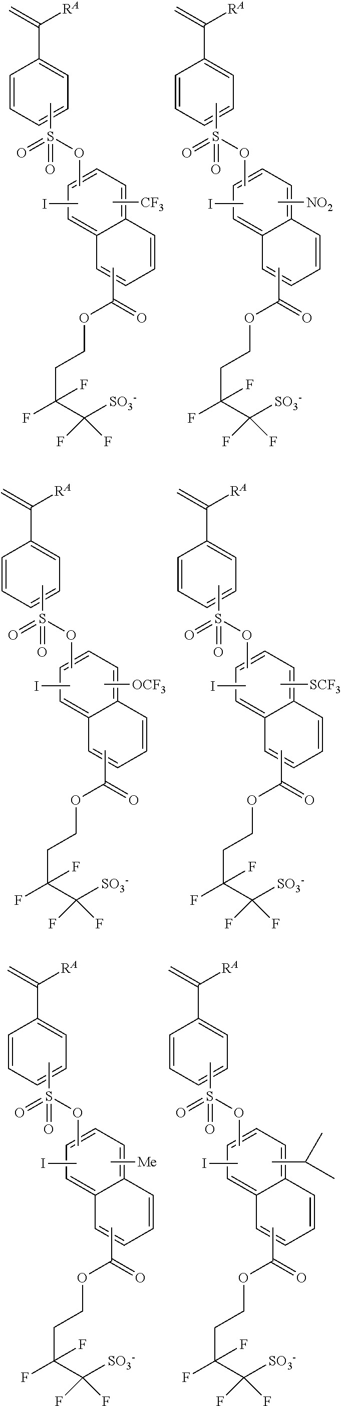

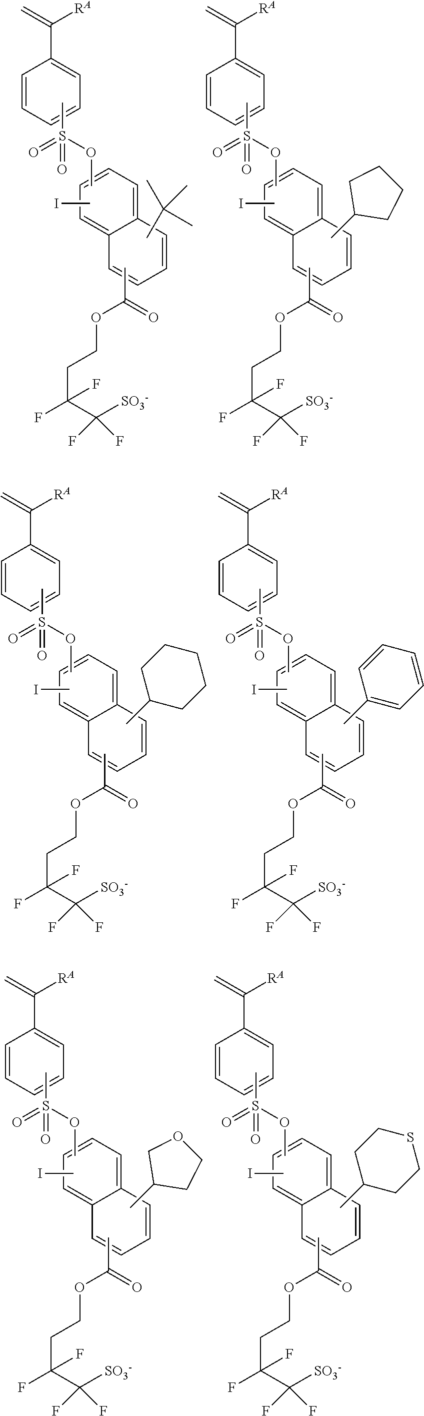

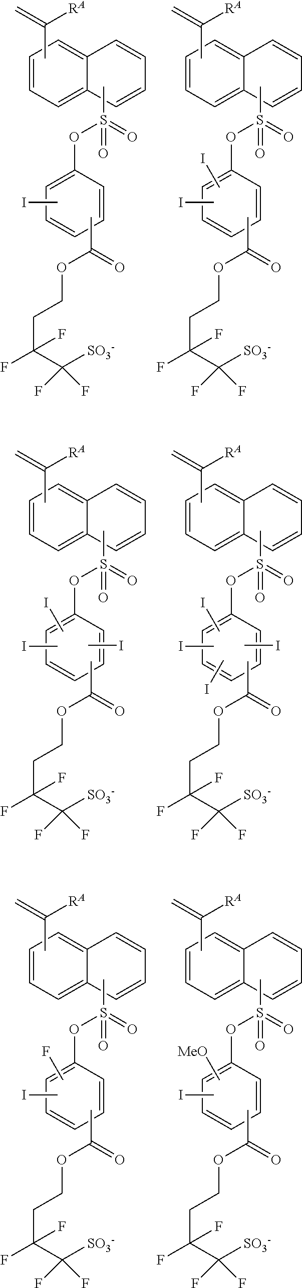

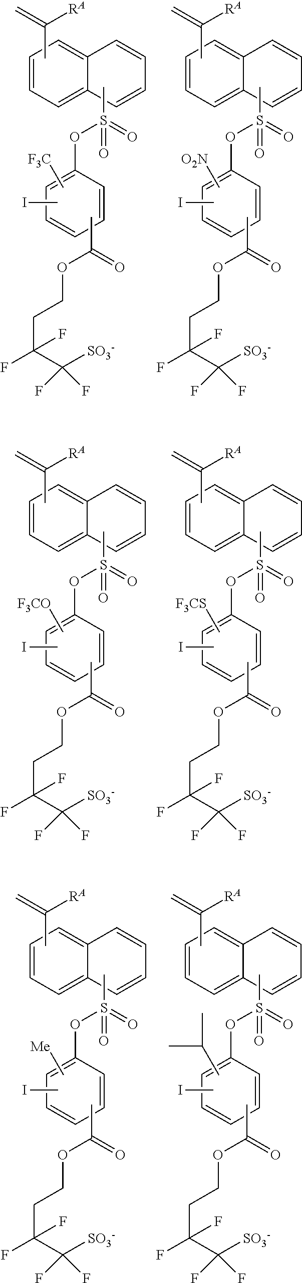

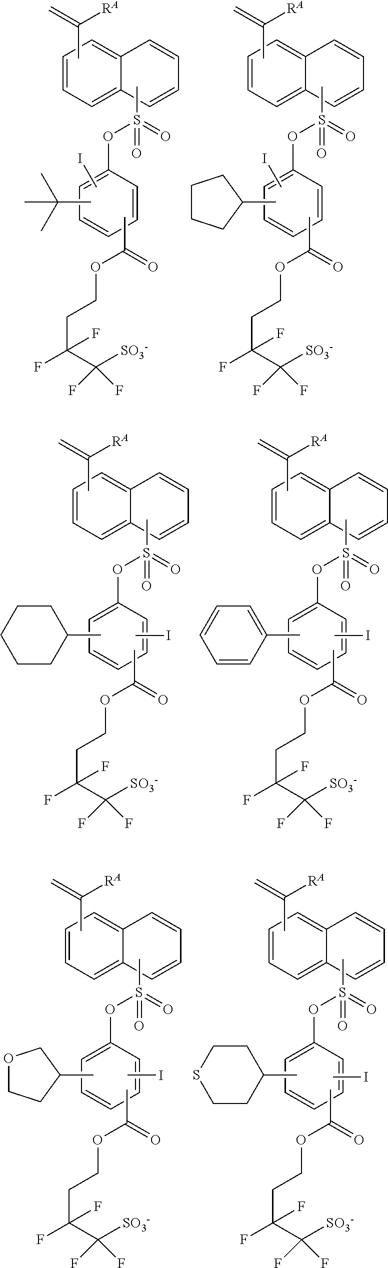

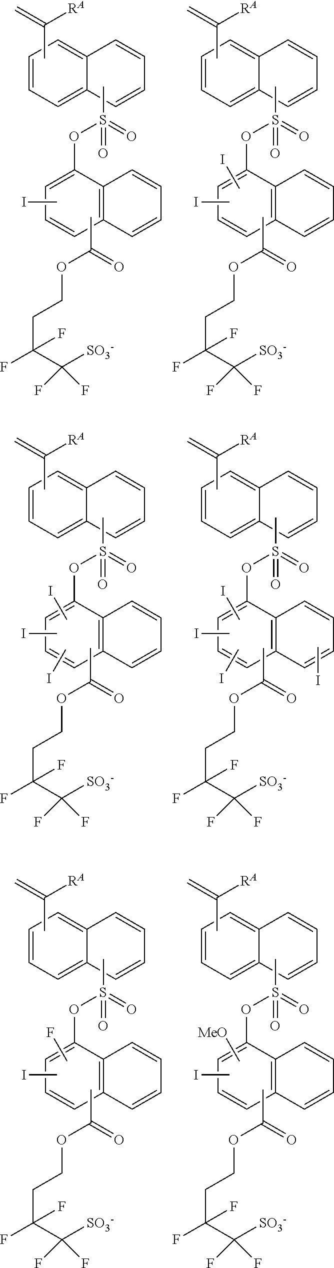

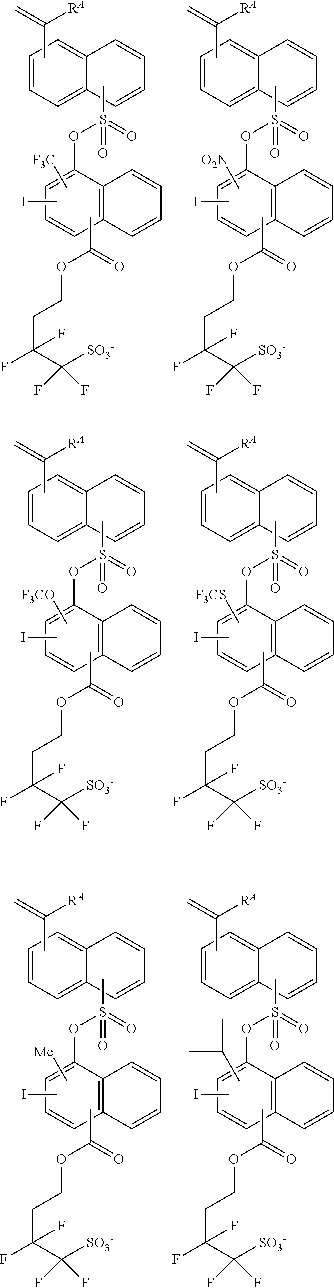

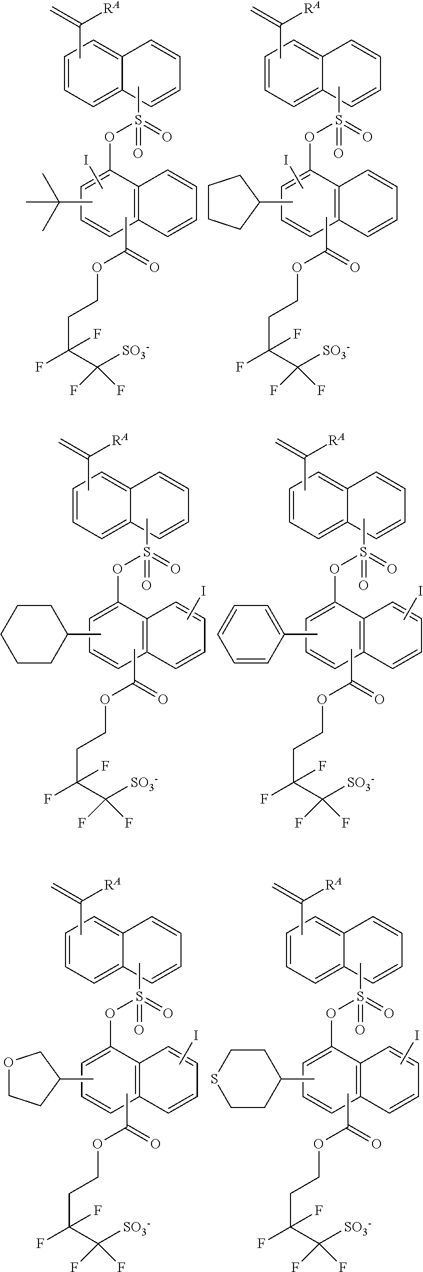

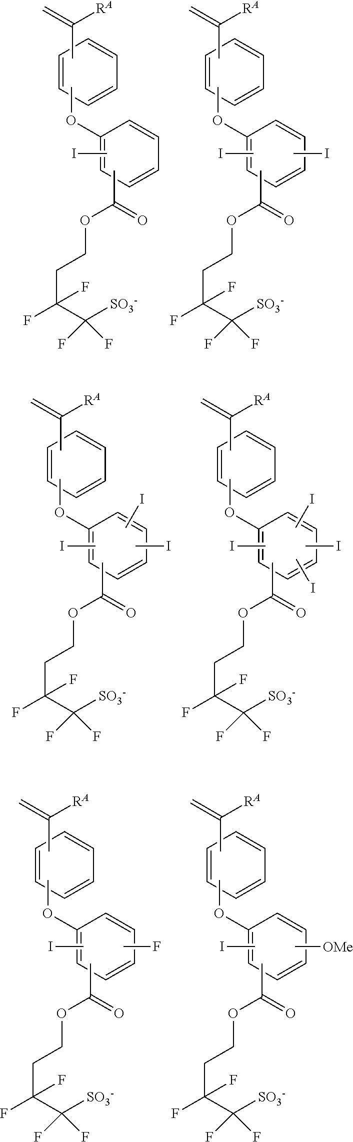

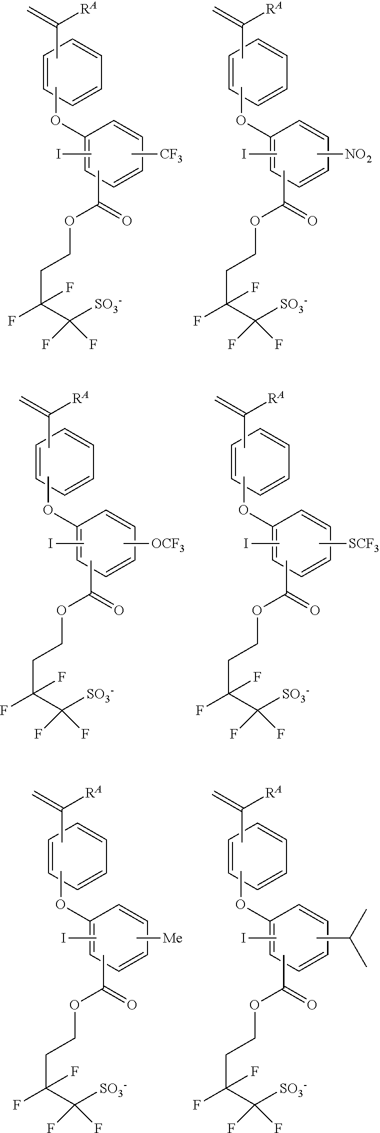

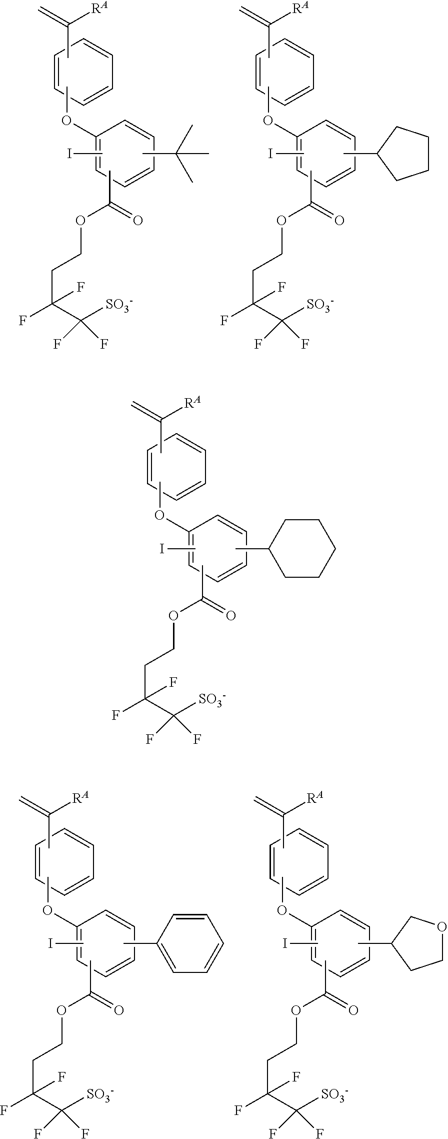

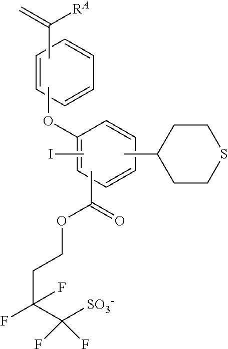

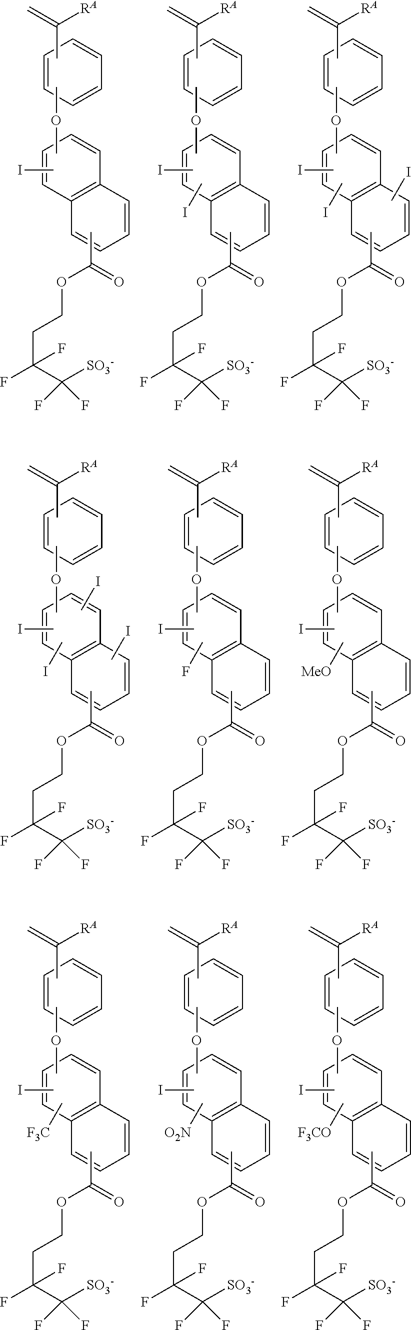

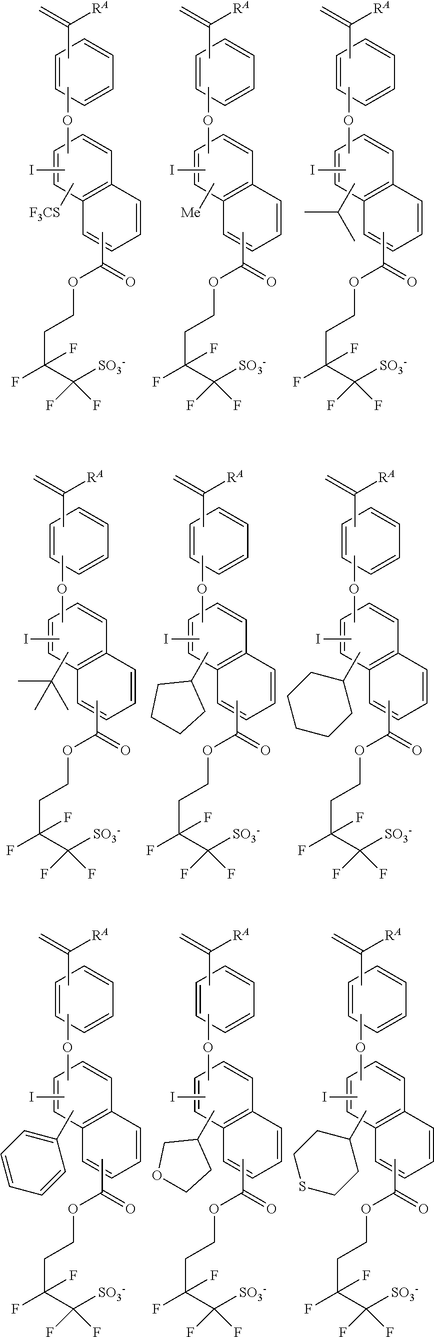

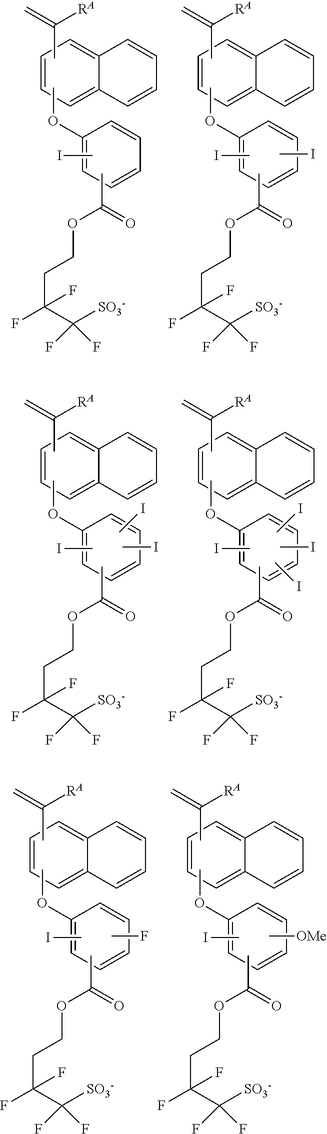

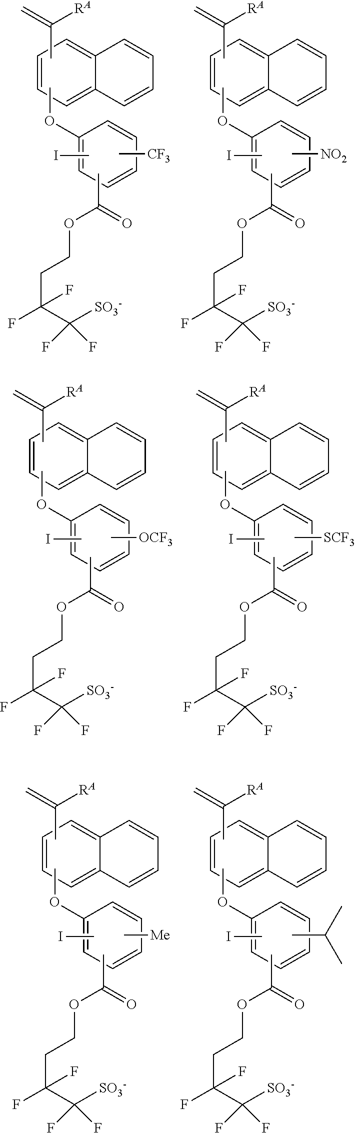

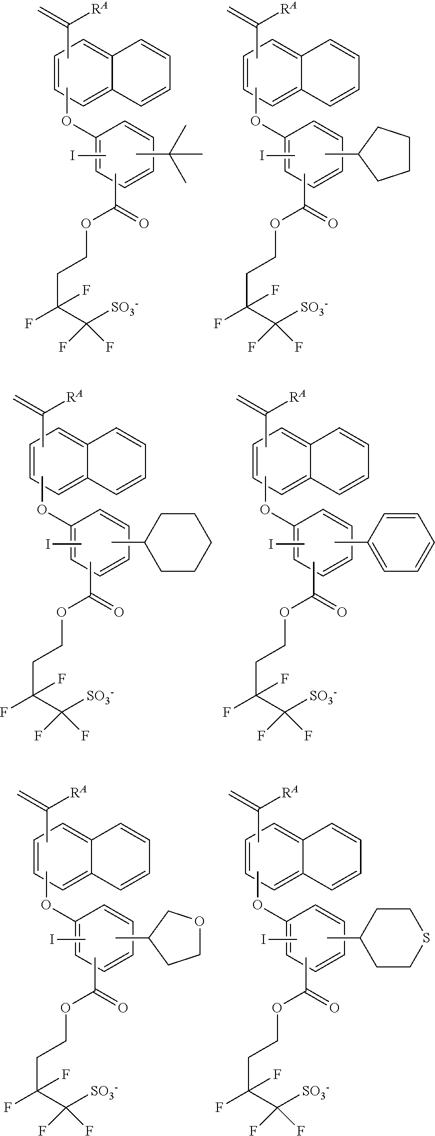

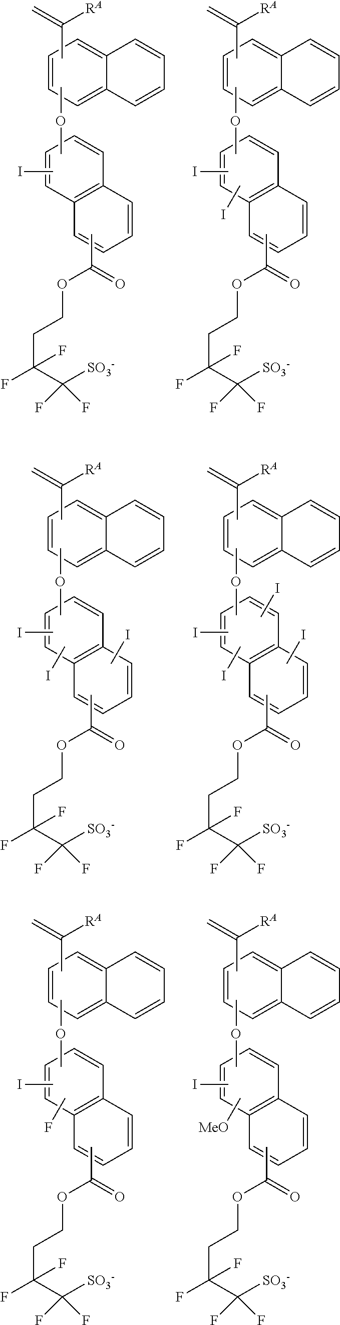

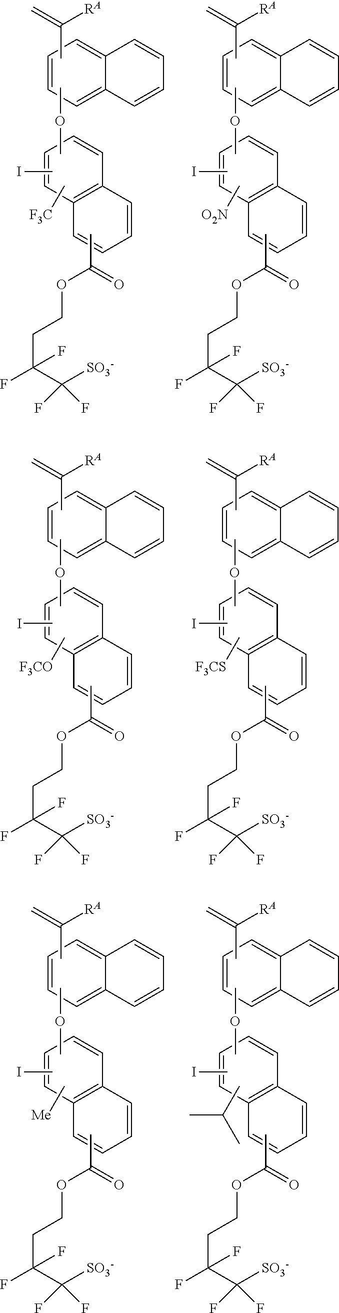

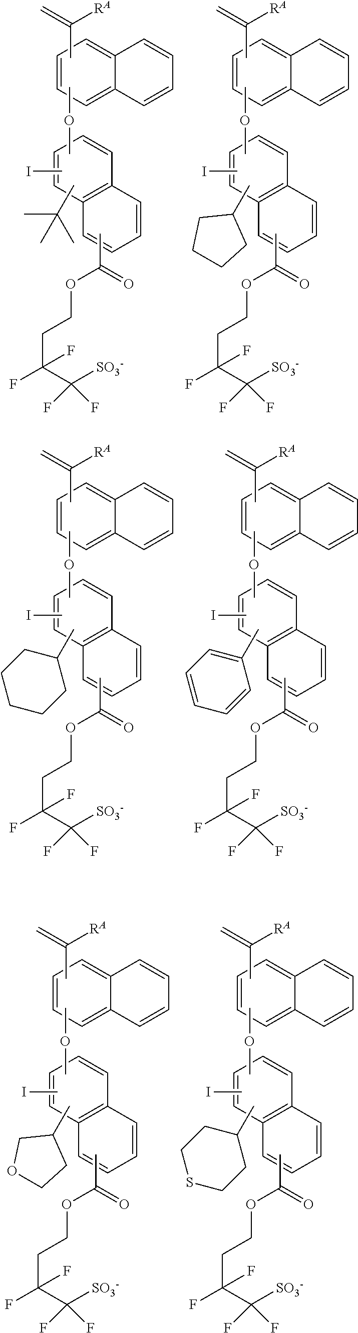

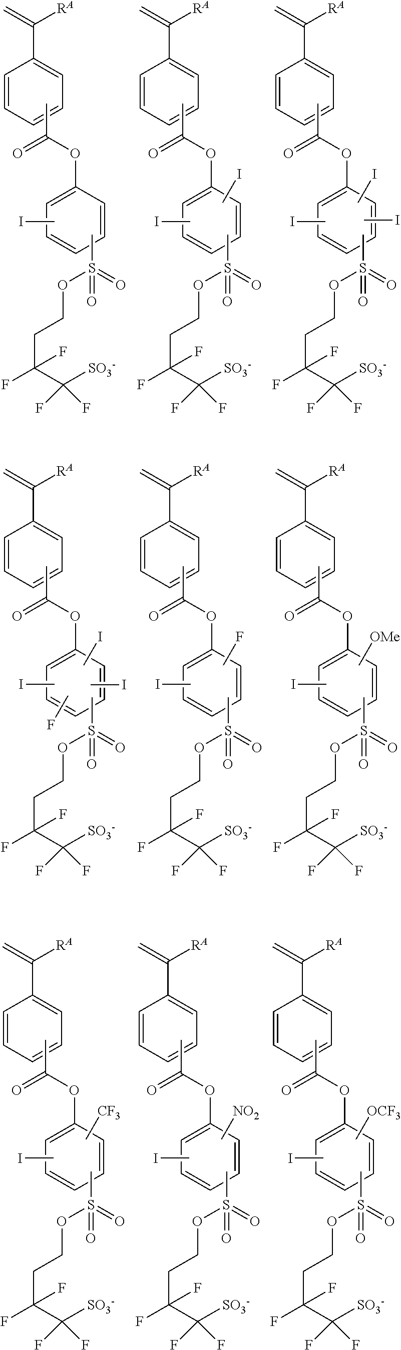

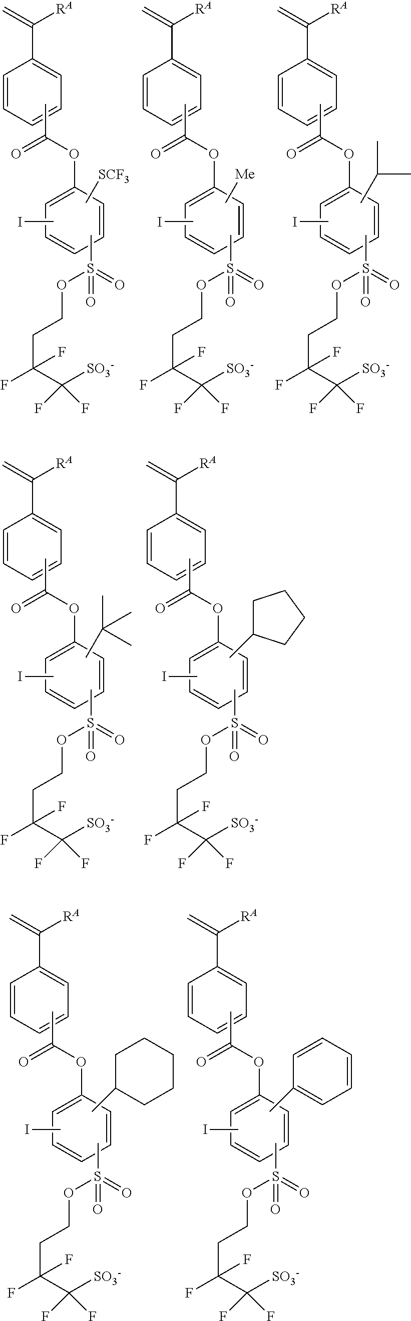

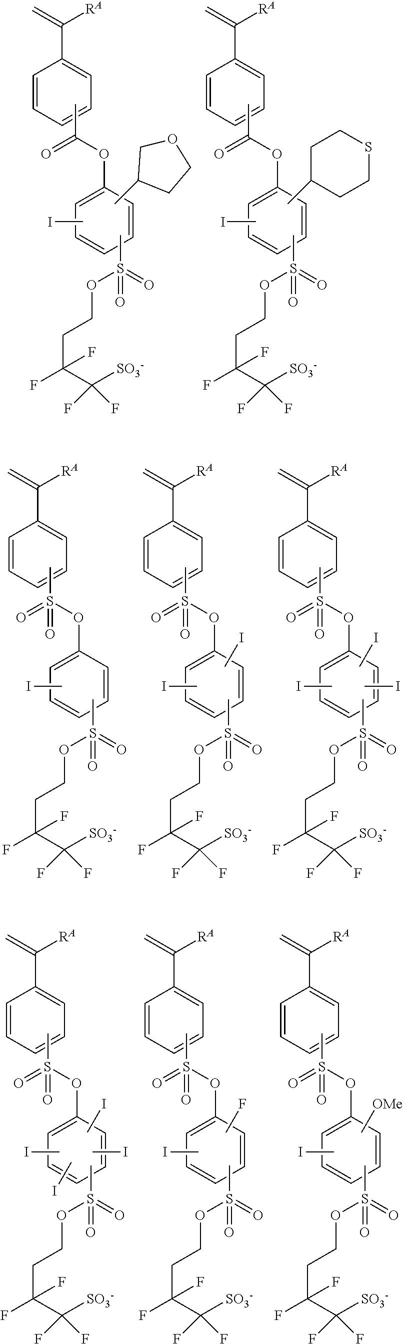

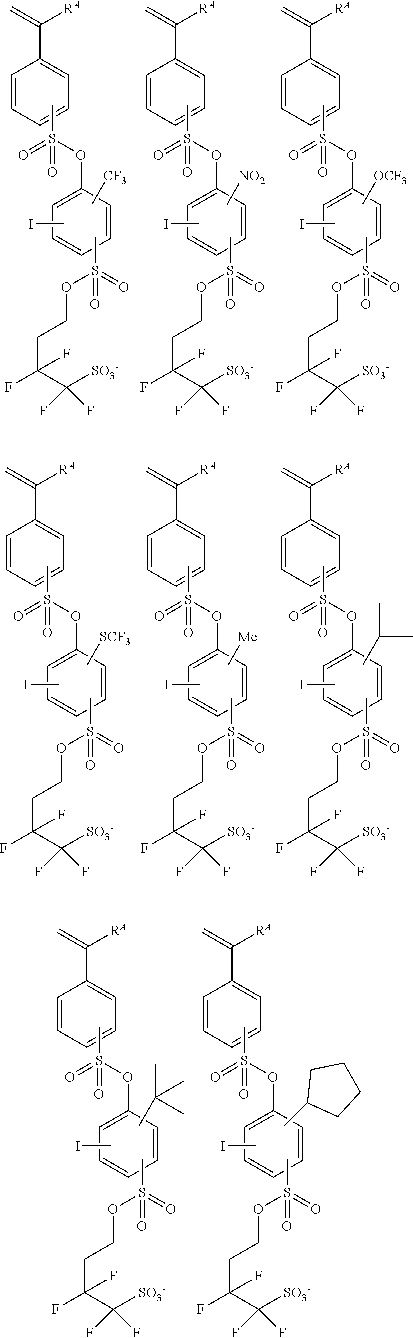

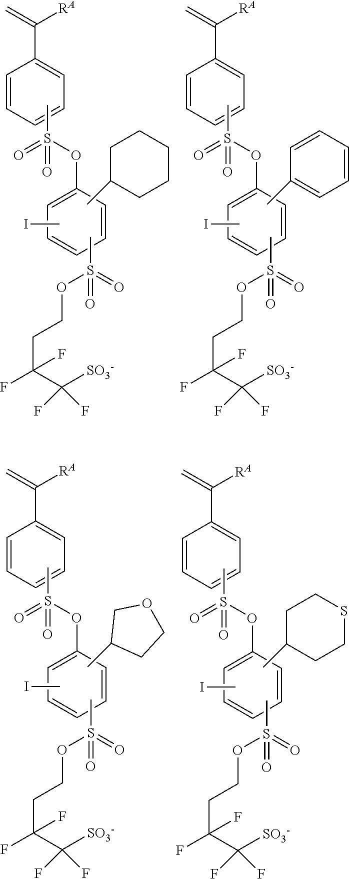

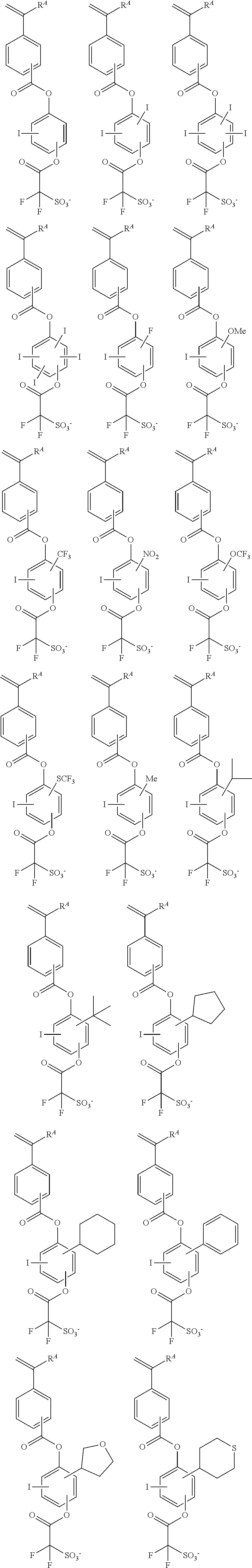

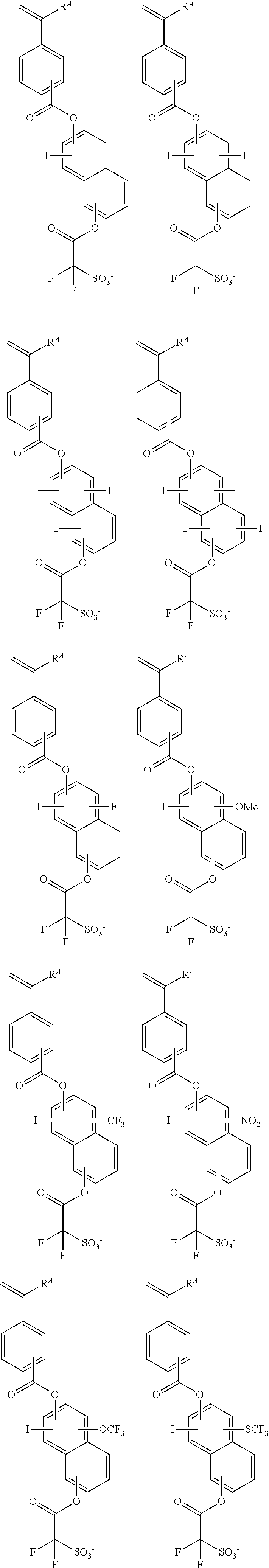

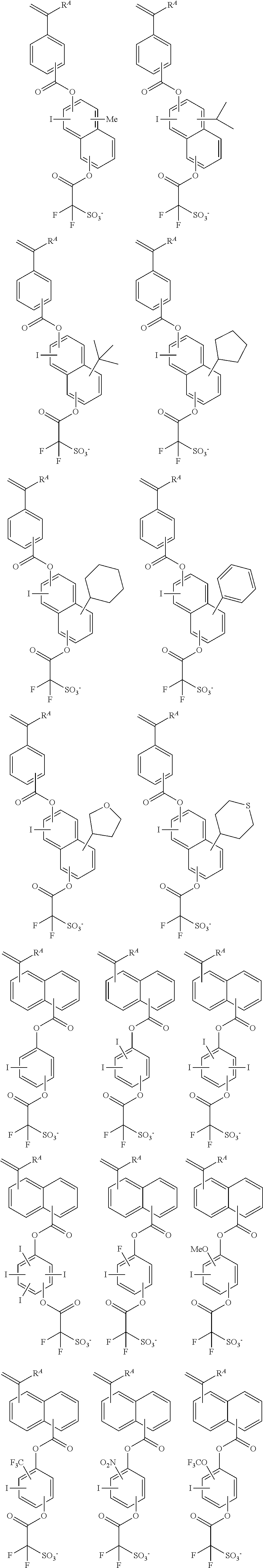

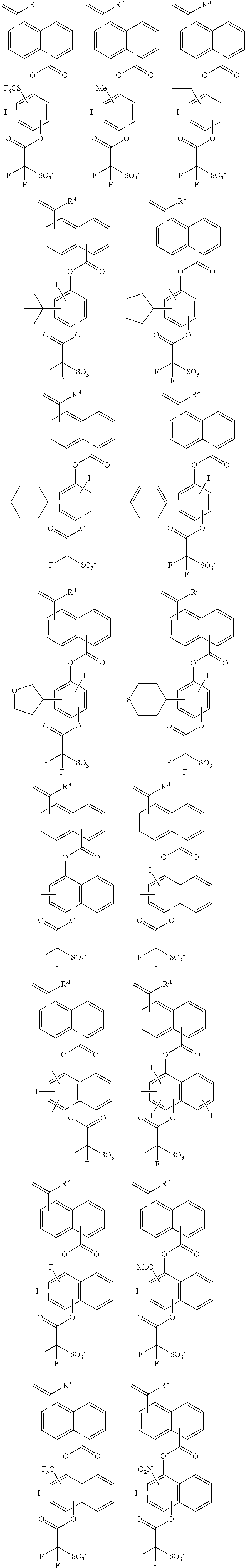

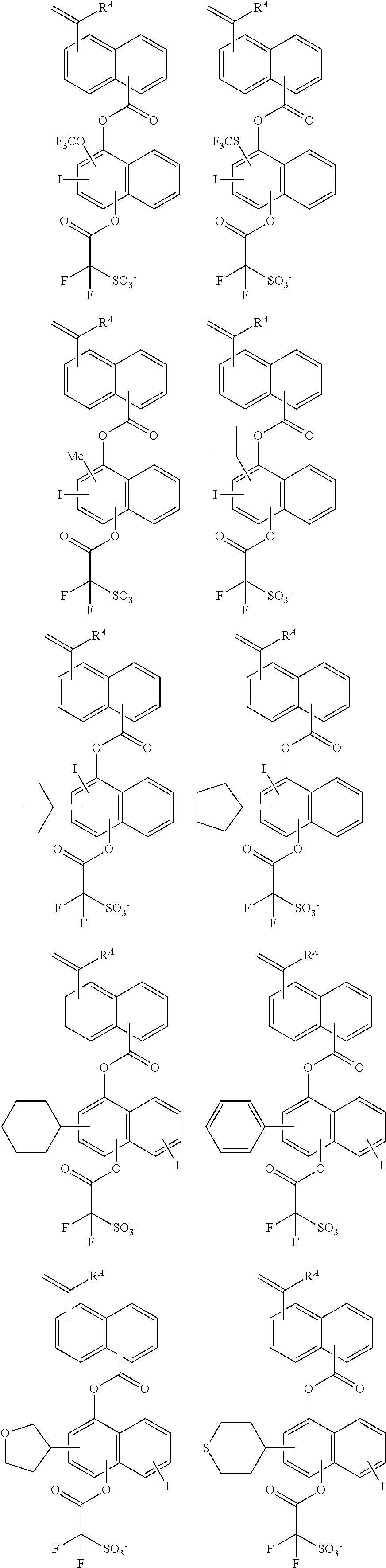

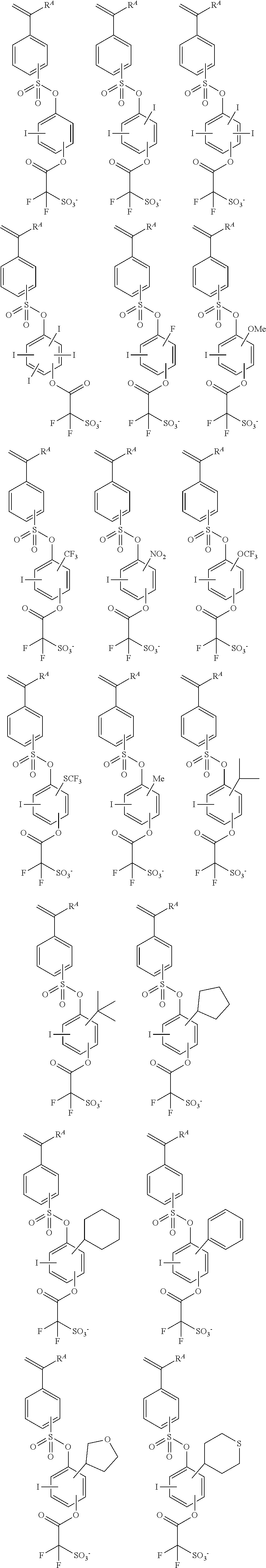

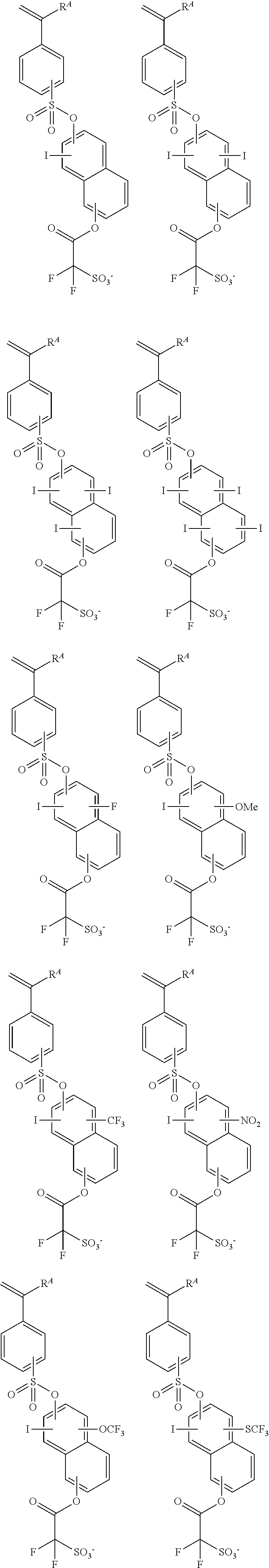

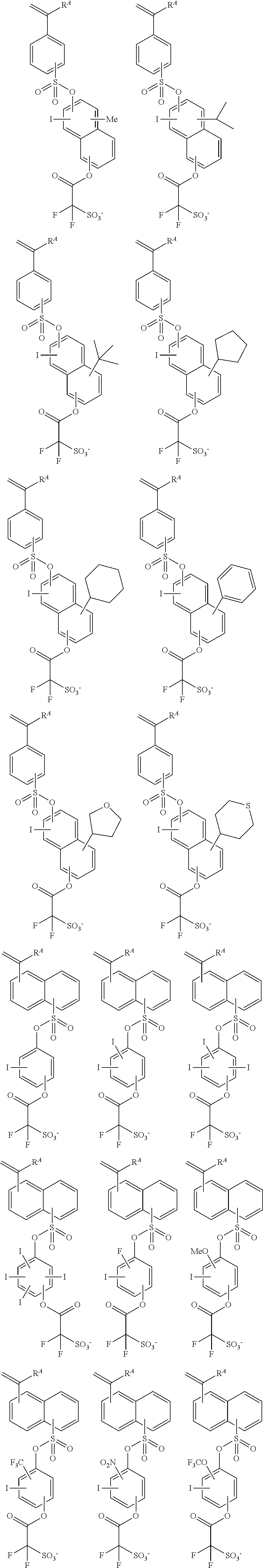

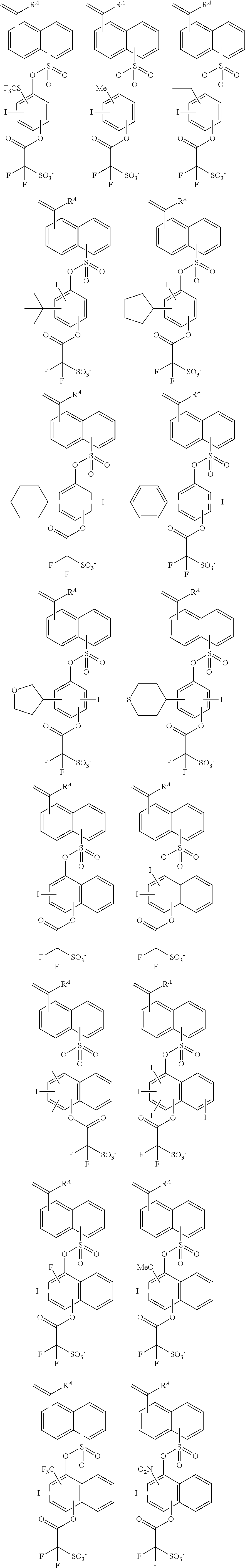

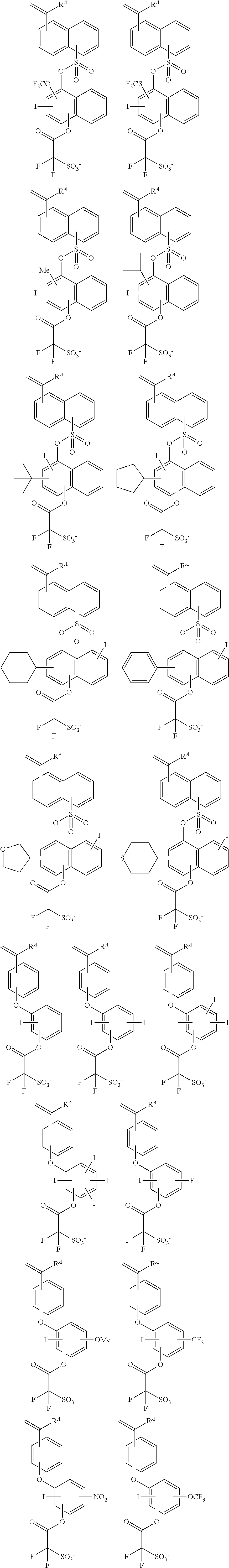

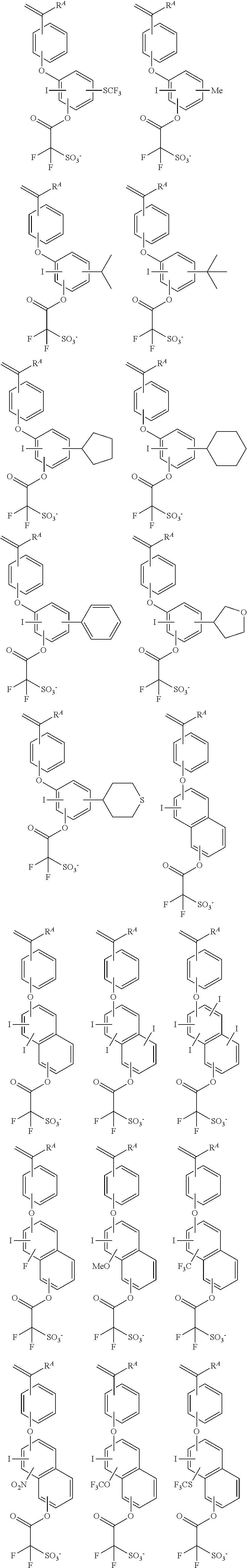

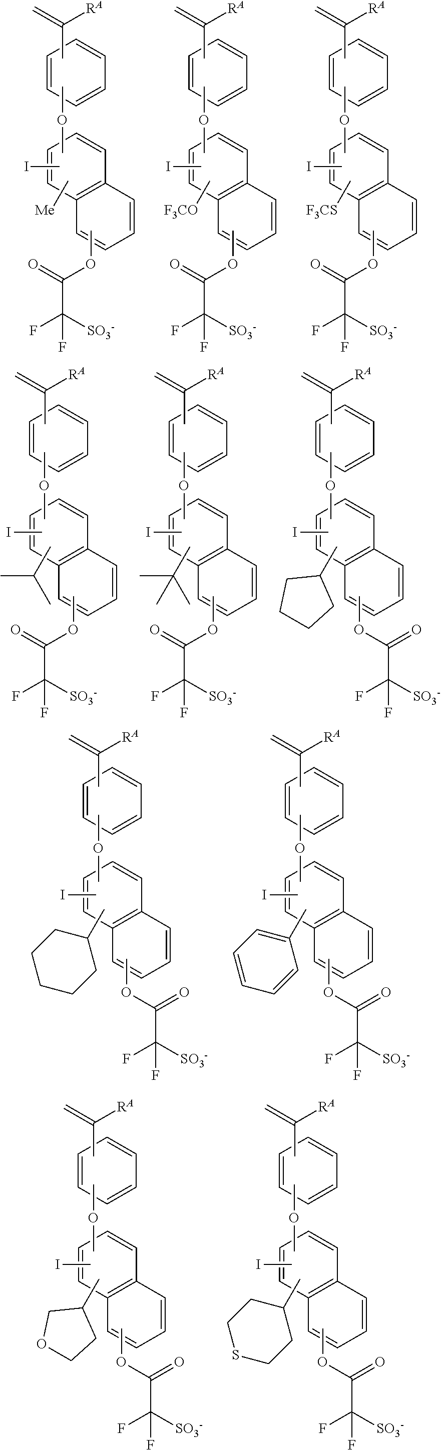

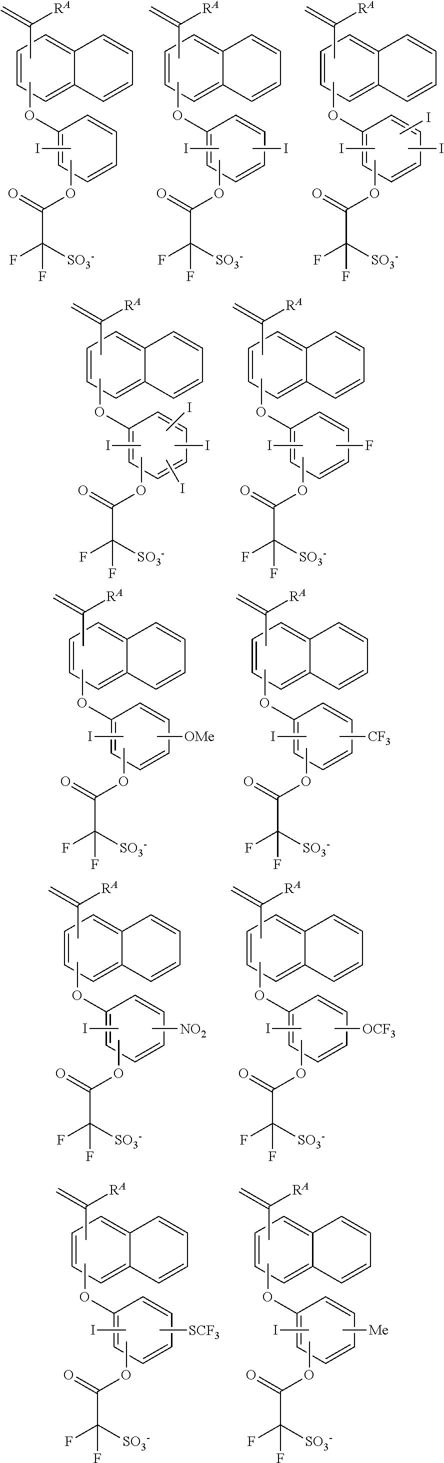

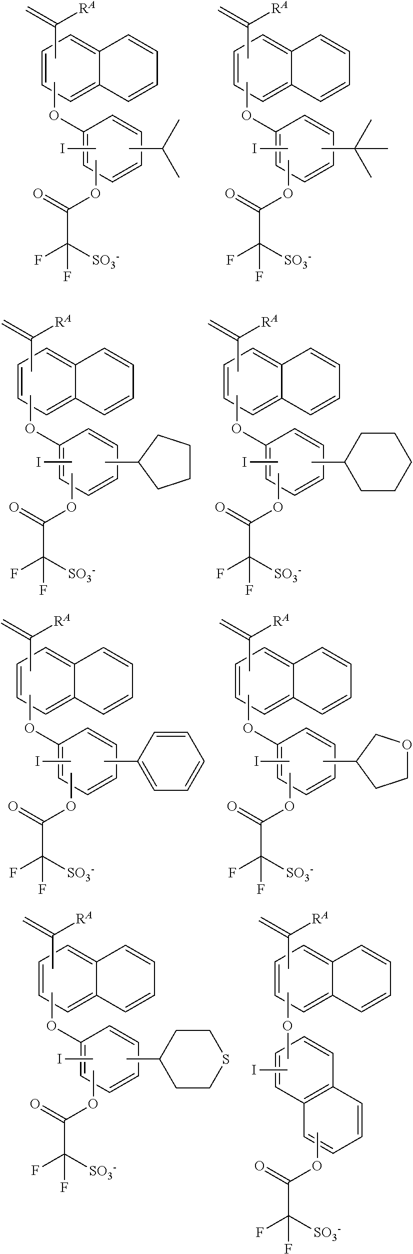

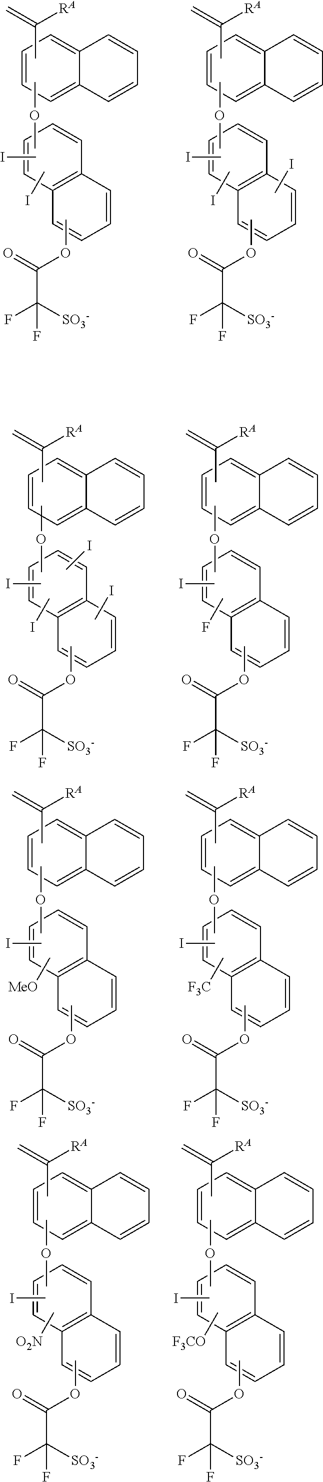

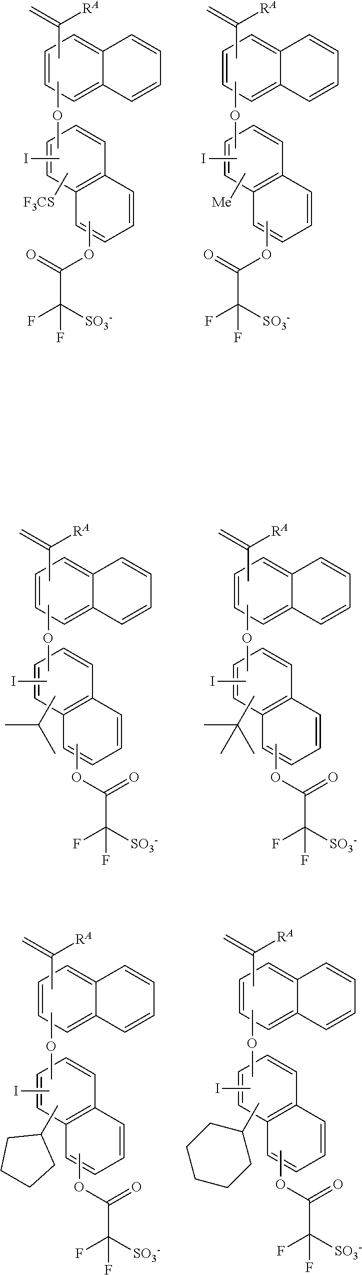

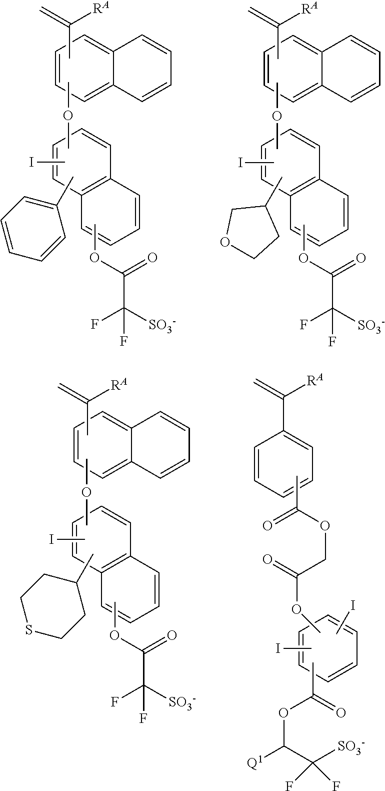

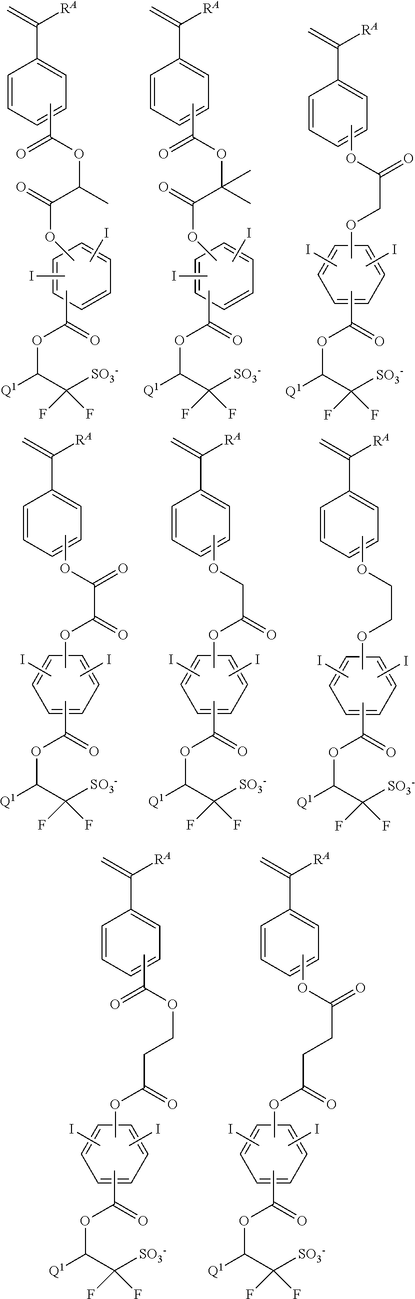

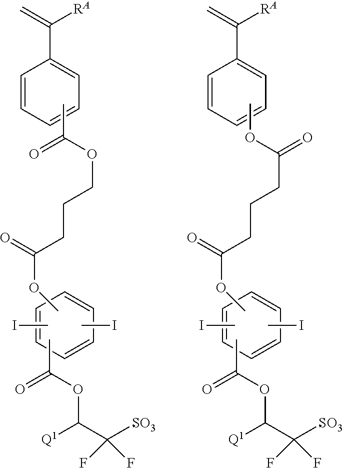

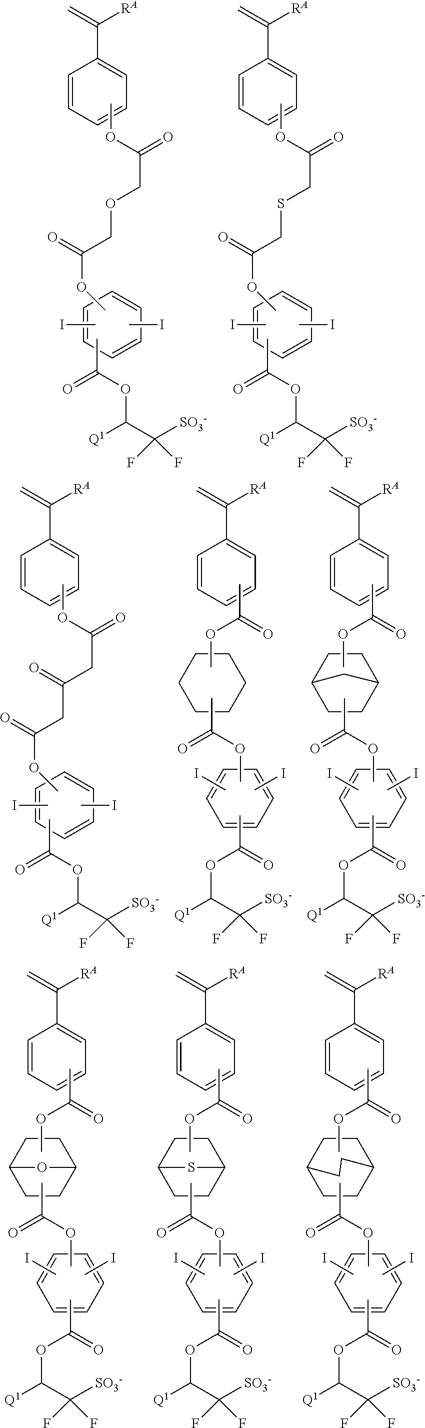

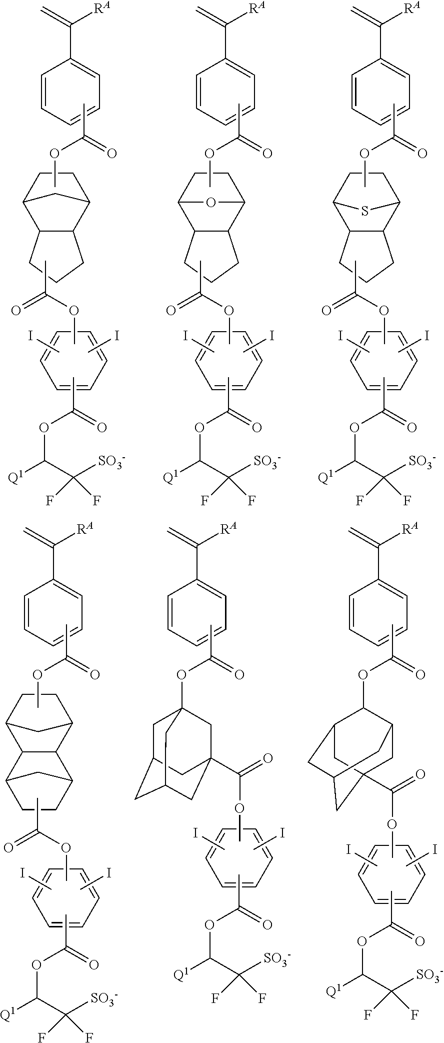

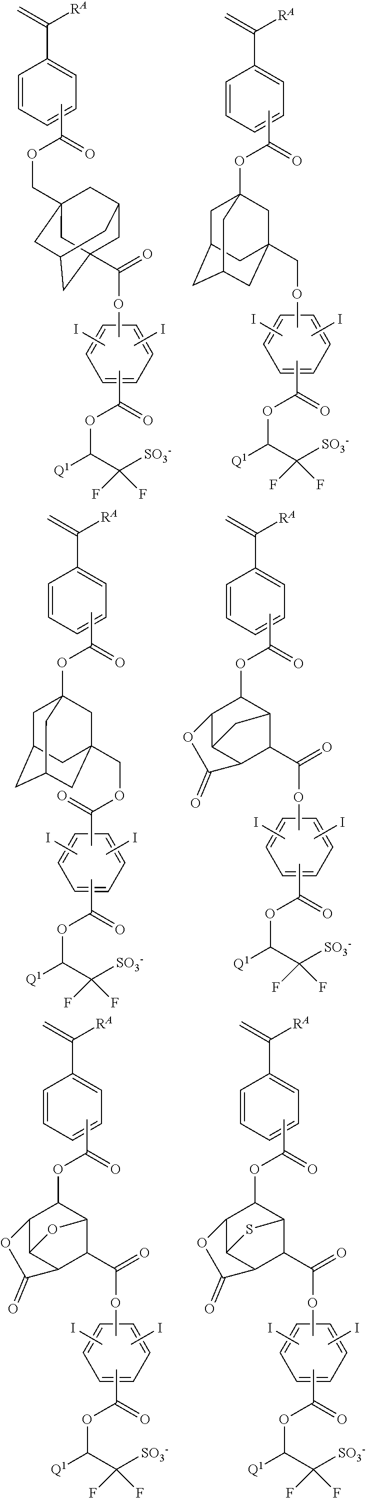

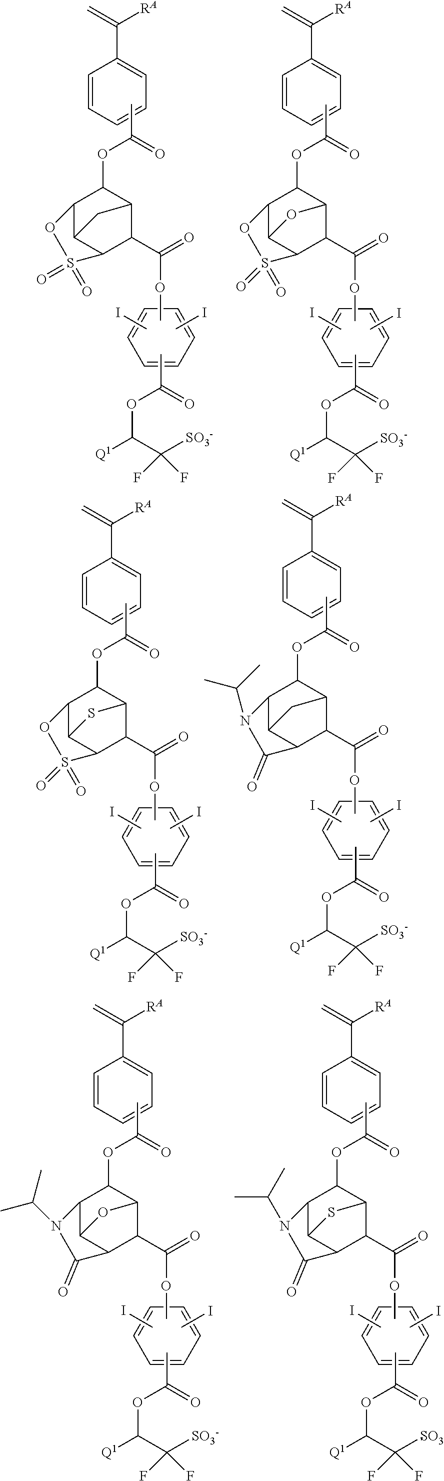

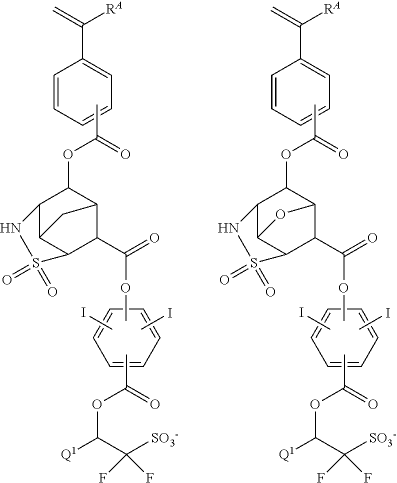

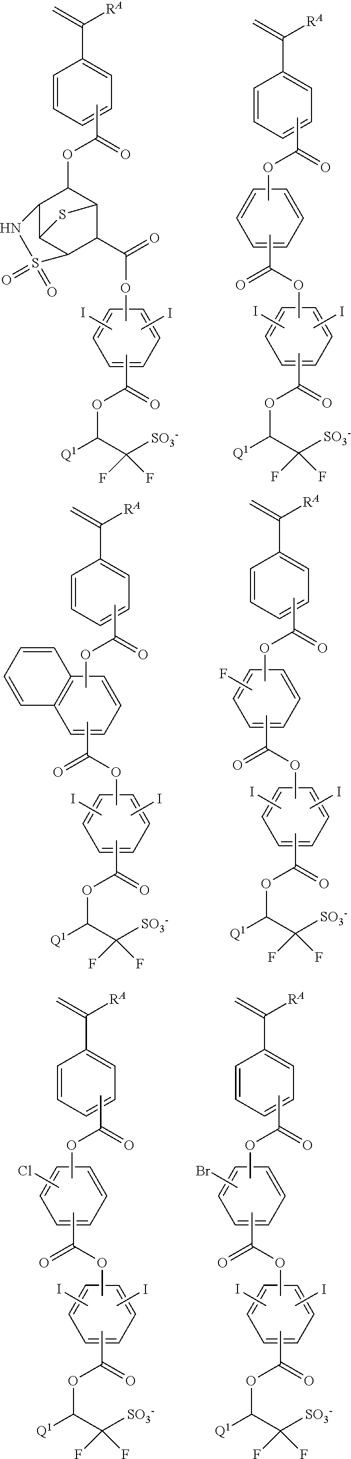

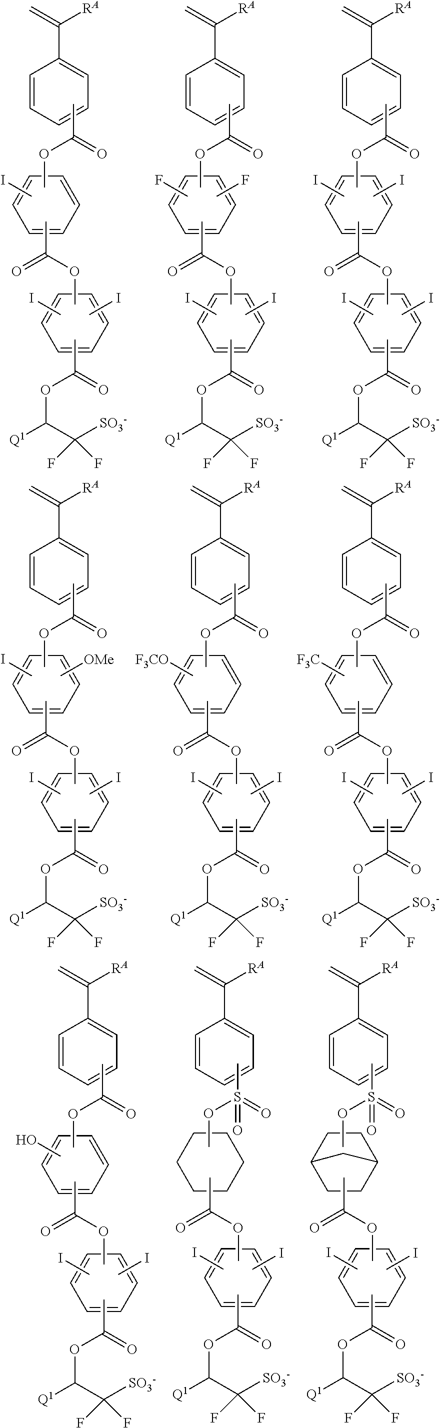

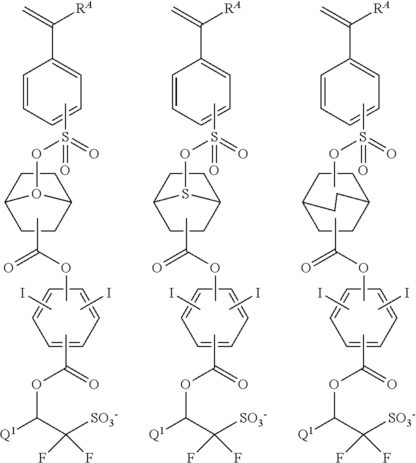

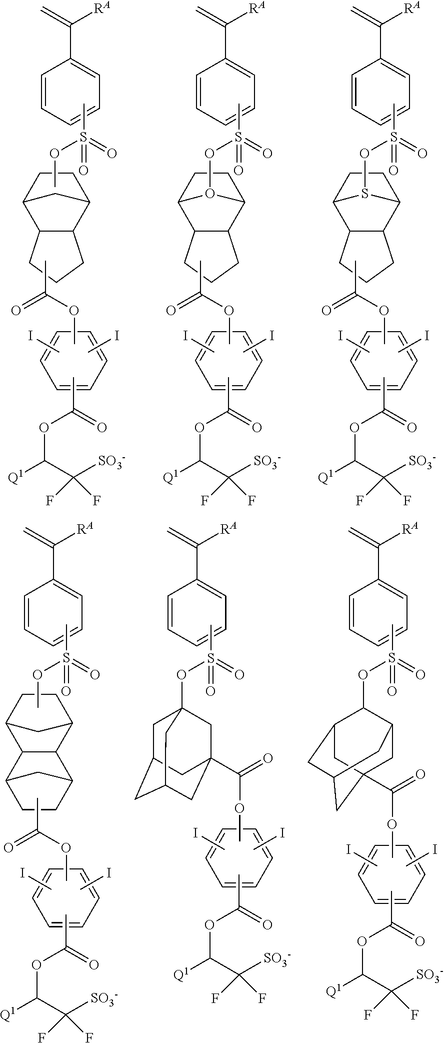

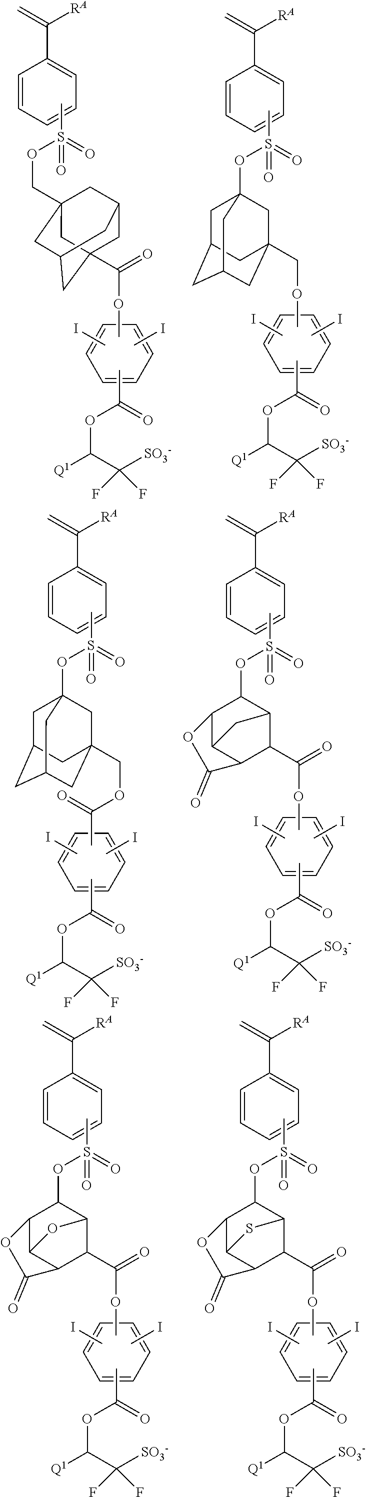

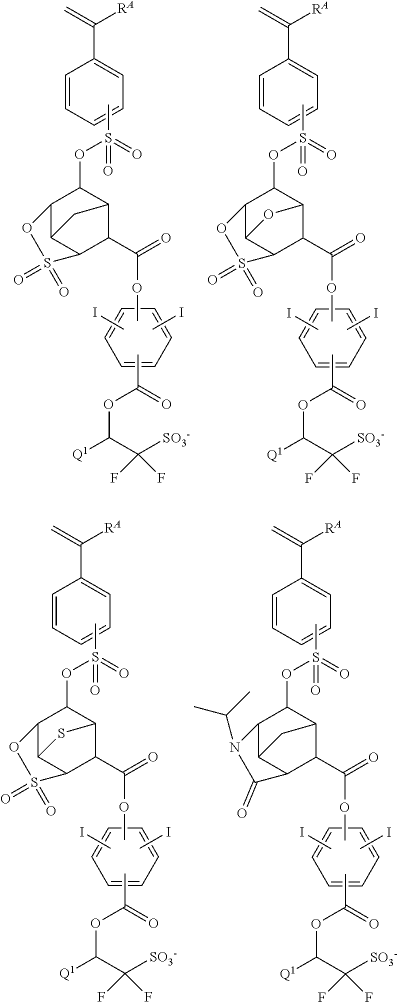

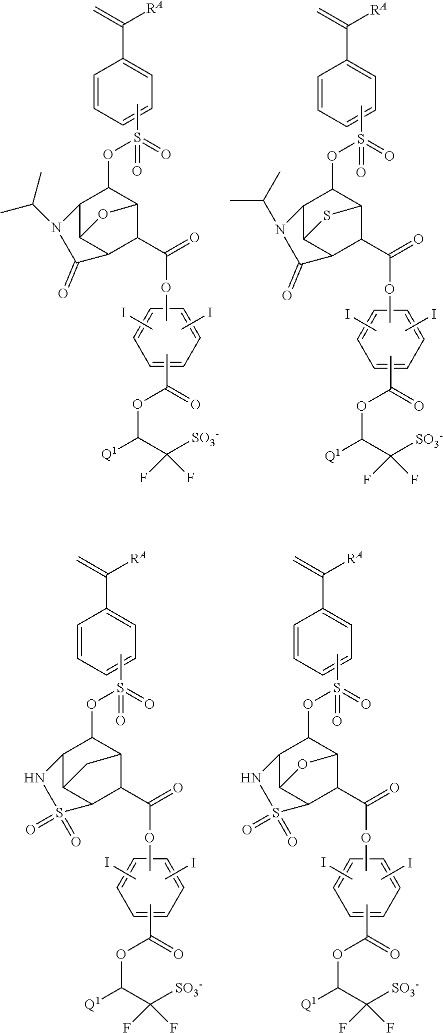

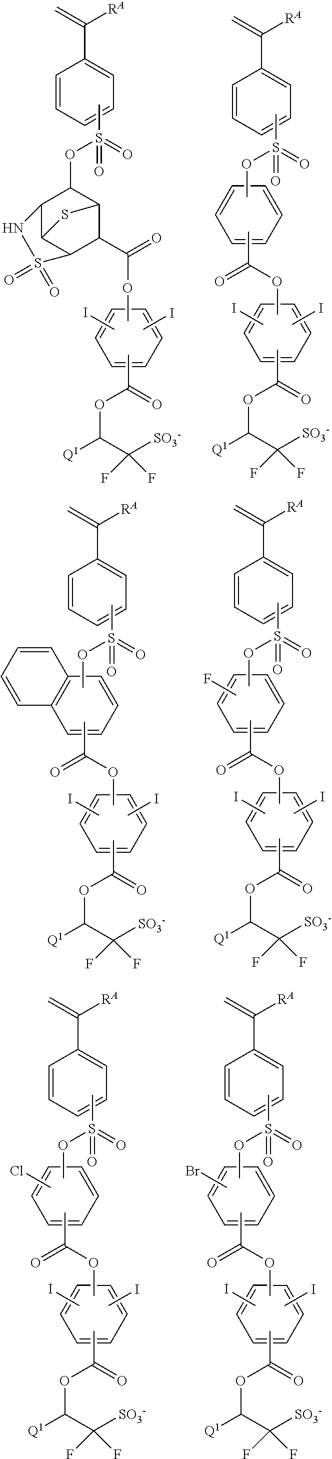

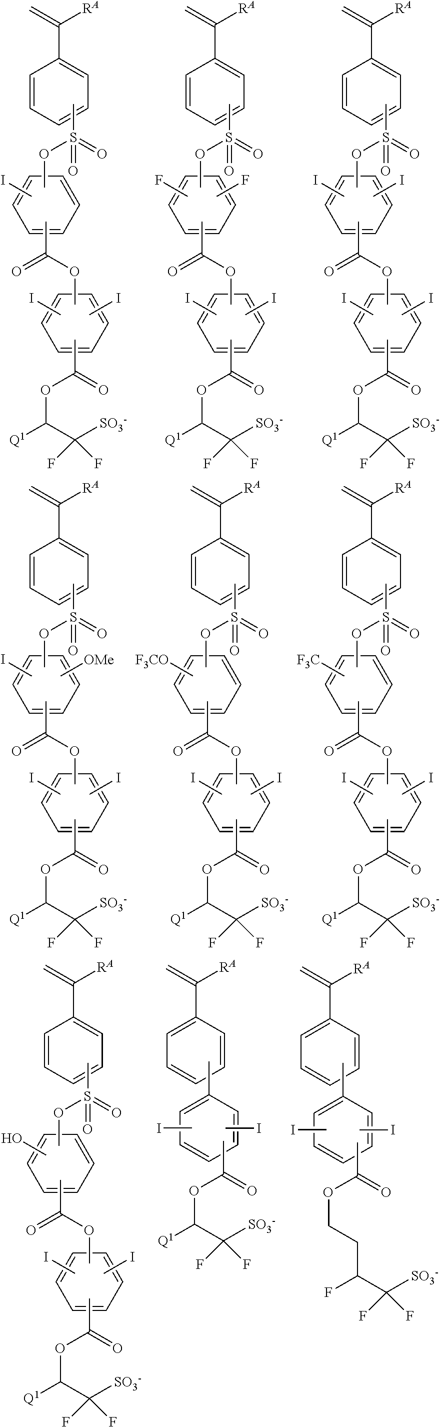

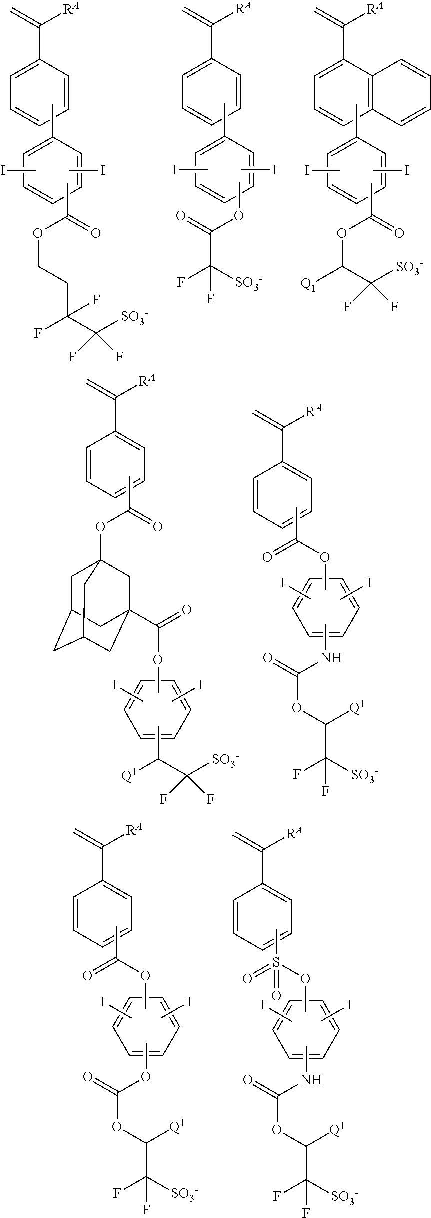

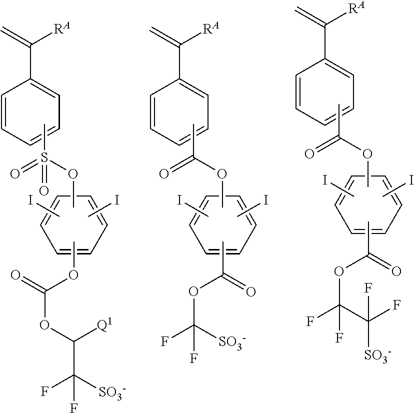

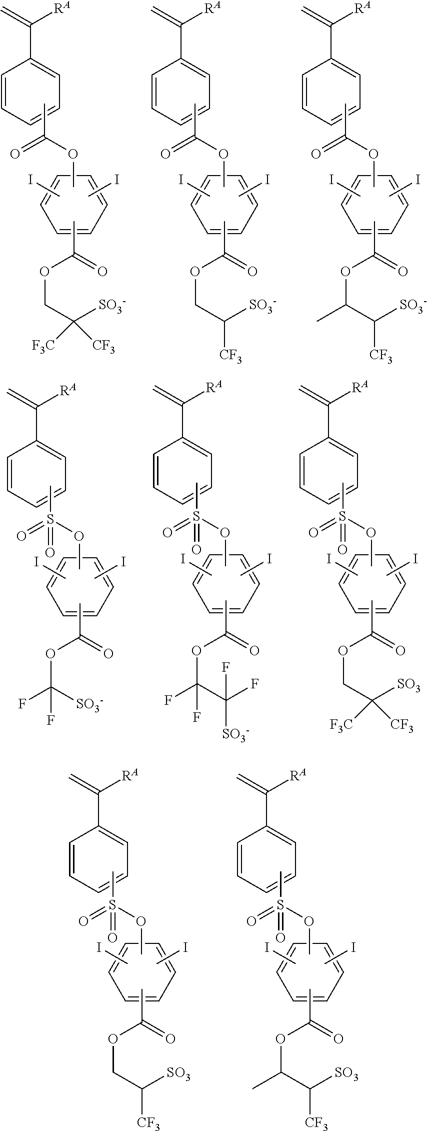

Furthermore, the anion of the repeating unit-d is also preferably represented by the following general formula (d2).

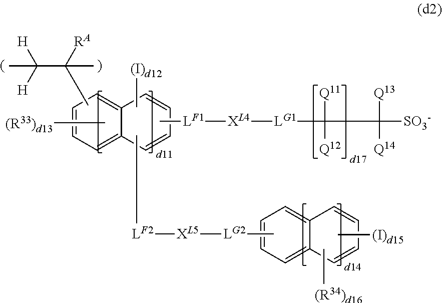

In the general formula (d2), d11 is 0 or 1. When d11 is 0, the structure is a benzene ring, and when d11 is 1, the structure is a naphthalene ring; however, from the viewpoint of solvent solubility, d11 is preferably 0, giving a benzene ring. d12 is an integer from 1 to 4. From the viewpoint of raw material procurement, d12 is preferably 1, 2 or 3, more preferably 1 or 2, and further preferably 1. d13 is 0, 1 or 2. However, when d11 is 0, 1≤d12+d13≤4, and when d11 is 1, 1≤d12+d13≤6.

In the general formula (d2), d14 is 0 or 1. When d14 is 0, the structure is a benzene ring, and when d14 is 1, the structure is a naphthalene ring; however, from the viewpoint of solvent solubility, d14 is preferably 0, giving a benzene ring. d15 represents an integer from 1 to 4, and is preferably 1, 2 or 3. The larger the number of iodine atoms in the anion structure, the higher the absorption especially for EUV, but since there is a concern that solvent solubility will be poor and precipitation will occur in the resist composition, the number of iodine atoms in the anion is preferably 2 to 5, and more preferably 2, 3 or 4. d16 is 0, 1 or 2. However, when d14 is 0, 1≤d15+d16≤4, and when d14 is 1, 1≤d15+d16≤6.

In the general formula (d2), d17 is an integer from 0 to 4, preferably 0 to 3, more preferably 1, 2, or 3, and further preferably 1.

In the general formula (d2), R^{A} is a hydrogen atom, a fluorine atom, a methyl group, or a trifluoromethyl group. Among these, a hydrogen atom or a methyl group is preferable, and a hydrogen atom is more preferable.

In the general formula (d2), R³³ is a halogen atom other than an iodine atom, a nitro group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. The halogen atom other than an iodine atom is preferably a fluorine atom, a chlorine atom, or a bromine atom, and more preferably a fluorine atom. The hydrocarbyl group and the hydrocarbyl moiety of the hydrocarbyloxy group and the hydrocarbylthio group may be saturated or unsaturated, and may be linear, branched, or cyclic. Specific examples thereof include alkyl groups having 1 to 20 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-octyl group, an n-nonyls group, an n-decyl group, an undecyl group, a dodecyl group, a tridecyl group, a tetradecyl group, a pentadecyl group, a heptadecyl group, an octadecyl group, a nonadecyl group, and an icosyl group; cyclic saturated hydrocarbyl groups having 3 to 20 carbon atoms, such as a cyclopropyl group, a cyclopentyl group, a cyclohexyl group, a cyclopropylmethyl group, a 4-methylcyclohexyl group, a cyclohexylmethyl group, a norbornyl group, and an adamantyl group; alkenyl groups having 2 to 20 carbon atoms, such as a vinyl group, an allyl group, a propenyl group, a butenyl group, and a hexenyl group; cyclic unsaturated hydrocarbyl groups having 3 to 20 carbon atoms, such as a cyclohexenyl group; aryl groups having 6 to 20 carbon atoms, such as a phenyl group and a naphthyl group; aralkyl groups having 7 to 20 carbon atoms, such as a benzyl group, a 1-phenylethyl group, and a 2-phenylethyl group; and groups obtained by combining these groups. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc. When d13 is 2, each R³³ may be the same or they may be different from each other.

Also, when d13 is 2, two R³³ may be bonded to each other to form a ring together with the carbon atoms of the aromatic ring to which they are bonded. Specific examples of the ring formed in this case include a cyclopropane ring, a cyclobutane ring, a cyclopentane ring, a cyclohexane ring, a norbornane ring, an adamantane ring, etc. Furthermore, some or all of the hydrogen atoms of the ring may be substituted with a group containing a heteroatom such as an oxygen atom, a sulfur atom, a nitrogen atom, or a halogen atom, and some of the —CH₂— of the ring may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

In the general formula (d2), R³⁴ is a halogen atom other than an iodine atom, a nitro group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. Specific examples of the halogen atom other than an iodine atom include a fluorine atom, a chlorine atom, and a bromine atom. The hydrocarbyl group and the hydrocarbyl moiety of the hydrocarbyloxy group and the hydrocarbylthio group may be saturated or unsaturated, and may be linear, branched, or cyclic. Specific examples of these include, but are not limited to, ones similar to those exemplified as the hydrocarbyl group represented by R³³. When d16 is 2, each R³⁴ may be the same or they may be different from each other.

Also, when d16 is 2, two R³⁴ may be bonded to each other to form a ring together with the carbon atom to which they are bonded. As the ring, a ring having 5 to 8 carbon atoms is preferable.

In the general formula (d2), L^{F1}, L^{F2}, L^{G1}, and L^{G2} are each independently a single bond, an ether bond, an ester bond, a sulfonate ester bond, an amide bond, a sulfonamide bond, a carbonate bond, or a carbamate bond. Among these, L^{F1} is preferably a single bond, an ether bond, an ester bond, or a sulfonate ester bond, and more preferably an ester bond or a sulfonate ester bond. L^{F2} is preferably a single bond, an ether bond, an ester bond, or a sulfonate ester bond, and more preferably an ester bond or a sulfonate ester bond. L^{G1} is preferably a single bond, an ether bond, an ester bond, or a sulfonate ester bond, and more preferably a single bond, an ether bond, or an ester bond. L^{G2} is preferably a single bond, an ether bond, an ester bond, or a sulfonate ester bond, and more preferably a single bond, an ether bond, or an ester bond.

L^{F1} and L^{F2} are preferably bonded to adjacent carbon atoms of an aromatic ring. In this case, the substituent containing the fluorosulfonate anion structure and the substituent containing an aromatic ring substituted with an iodine atom are located in closer spatial positions, so it is expected to be more highly sensitive.

In the general formula (d2), X^{L4} and X^{L5} are each independently a single bond or a hydrocarbylene group having 1 to 40 carbon atoms and optionally containing a heteroatom. The hydrocarbylene group may be linear, branched, or cyclic, and specific examples thereof include an alkanediyl group, a cyclic saturated hydrocarbylene group, an arylene group, etc. Specific examples of the heteroatom include an oxygen atom, a nitrogen atom, and a sulfur atom. Specific examples of the hydrocarbylene group having 1 to 40 carbon atoms and optionally containing a heteroatom represented by X^{L4} and X^{L5} include X^{L}-0 to X^{L}-58 exemplified as specific examples of the hydrocarbylene group having 1 to 40 carbon atoms and optionally containing a heteroatom represented by X^{L1} and X^{L2} in the description of general formula (Z). Among these, X^{L}-0 to X^{L}-22, X^{L}-29 to X^{L}-34, and X^{L}-47 to X^{L}-58 are preferable.

In the general formula (d2), Q¹¹ and Q¹² are each independently a hydrogen atom, a fluorine atom, or a fluorinated saturated hydrocarbyl group having 1 to 6 carbon atoms. As the fluorinated saturated hydrocarbyl group having 1 to 6 carbon atoms, a trifluoromethyl group is preferable.

In the general formula (d2), Q¹³ and Q¹⁴ are each independently a fluorine atom or a fluorinated saturated hydrocarbyl group having 1 to 6 carbon atoms. As the fluorinated saturated hydrocarbyl group having 1 to 6 carbon atoms, a trifluoromethyl group is preferable. Q¹³ and Q¹⁴ are more preferably a fluorine atom.

In the general formula (d2), specific examples of the partial structure represented by —[C(Q¹¹)(Q¹²)]_{d17}—C(Q¹³)(Q¹⁴)—SO₃— are preferably, but are not limited to, those shown below. In the following formulae, * represents a bond to L^{G1}.

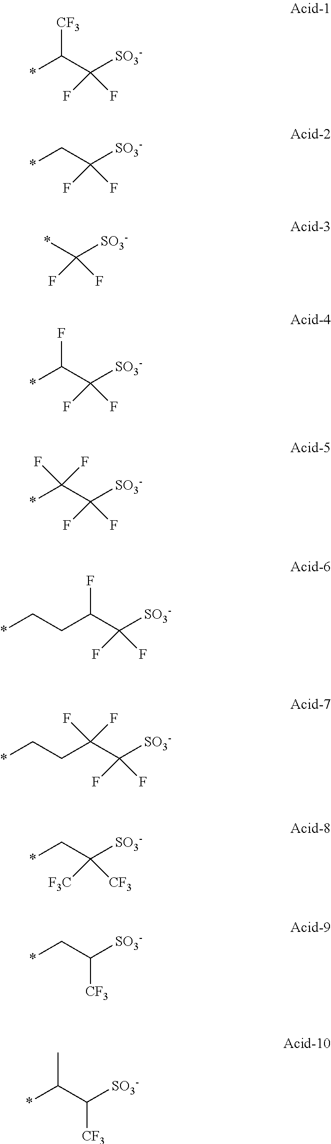

Among these, Acid-1 to Acid-7 are preferable, and Acid-1 to Acid-3, Acid-6, and Acid-7 are more preferable.

The anion represented by the general formula (d2) is preferably represented by the following general formula (d2-1).

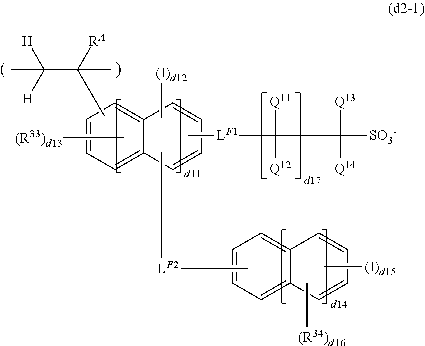

In the formula, R^{A}, R³³, R³⁴, L^{F1}, L^{F2}, Q¹¹ to Q¹⁴, and d11 to d17 are as defined above.

The anion represented by the general formula (d2-1) is preferably represented by the following general formula (d2-2).

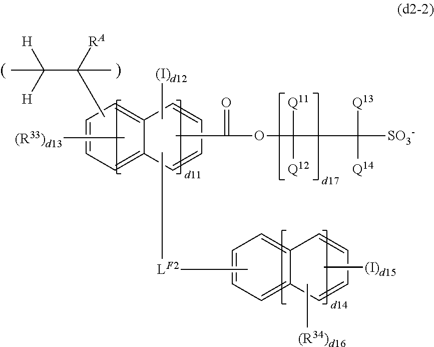

In the formula, R^{A}, R³³, R³⁴, L^{F2}, Q¹¹ to Q¹⁴, and d11 to d17 are as defined above.

Specific examples of the anion represented by the general formula (d2) include, but are not limited to, those shown below. In the following formulae, R^{A} and Q¹¹ are as defined above, and Me is a methyl group. In addition, the bonding positions of various substituents on the aromatic ring may be interchanged.

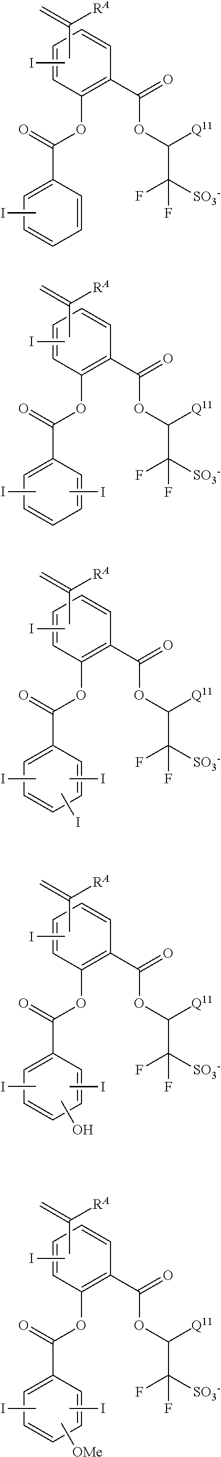

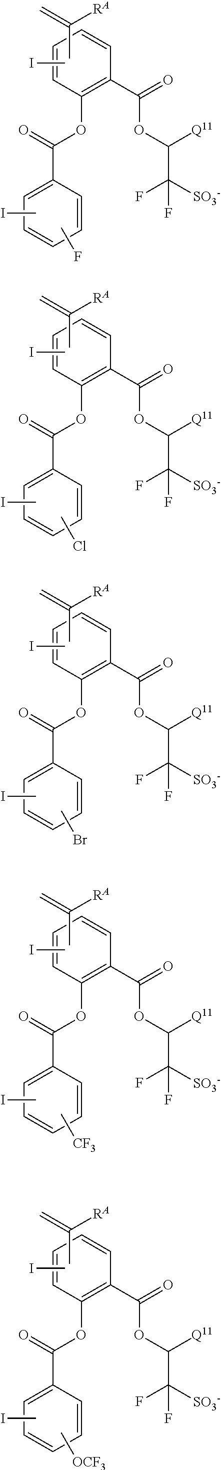

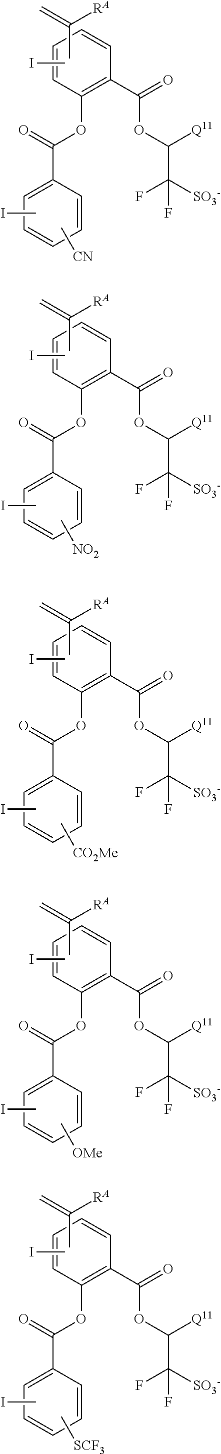

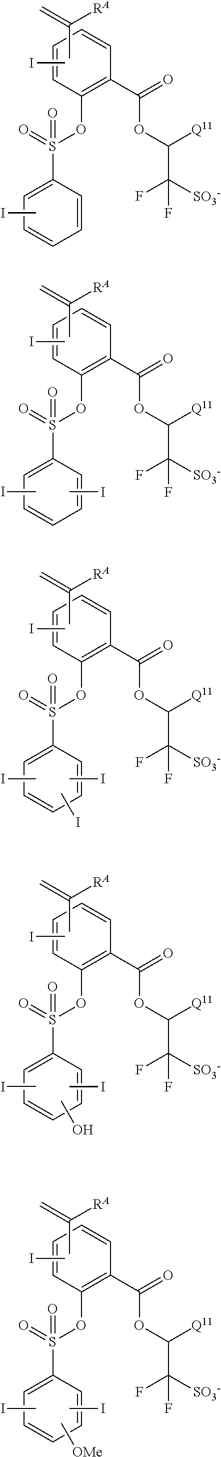

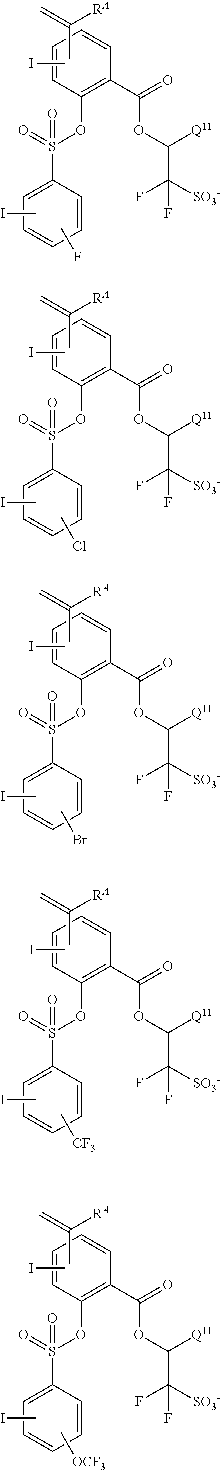

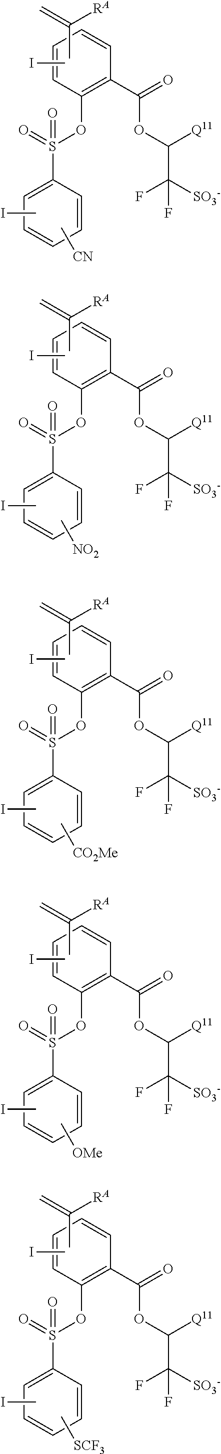

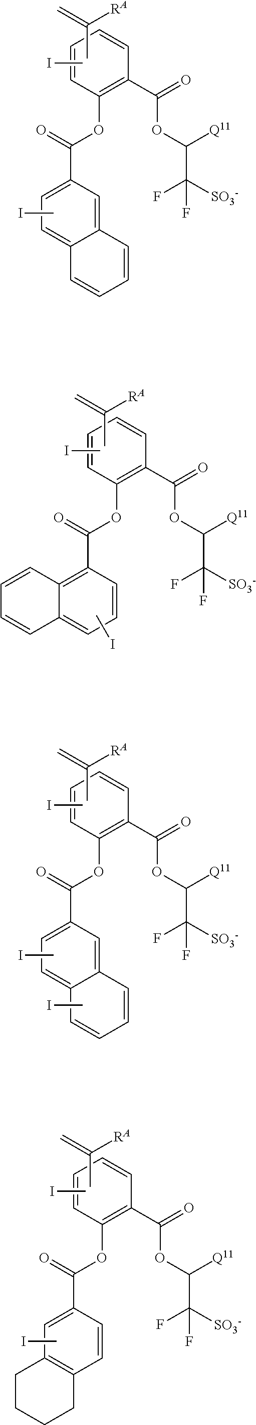

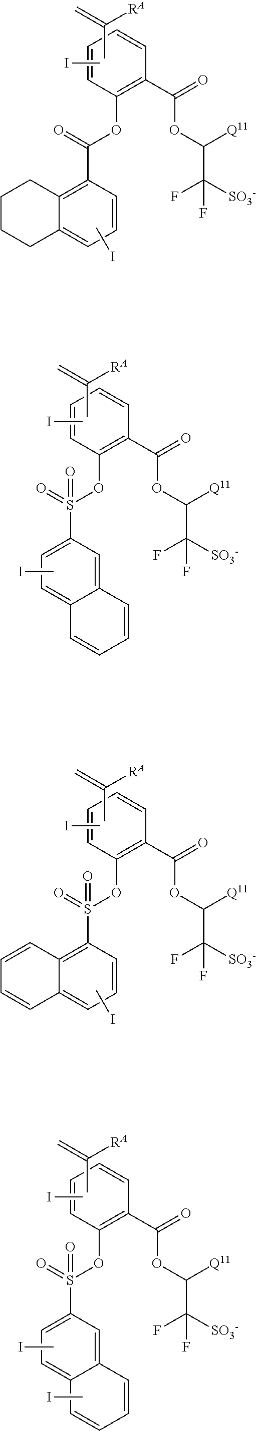

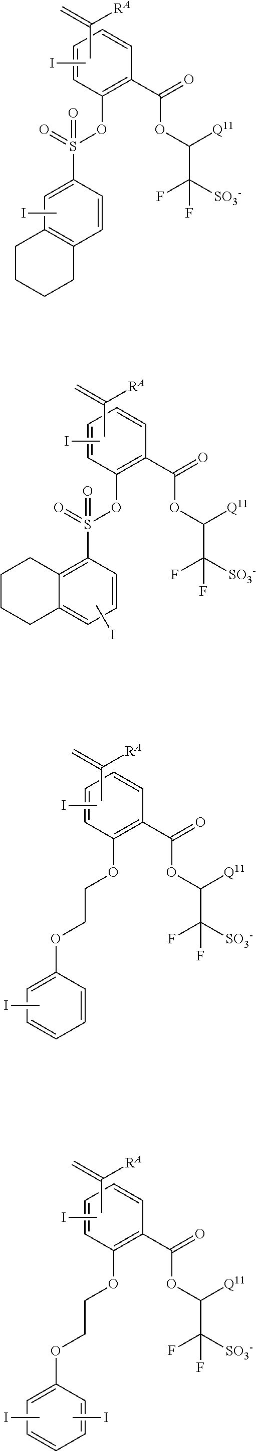

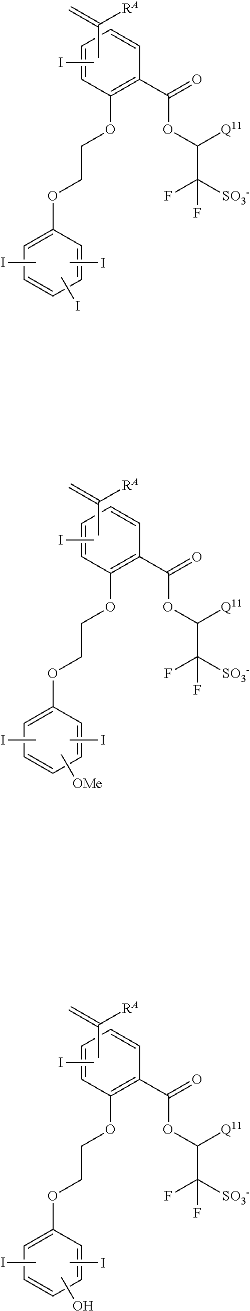

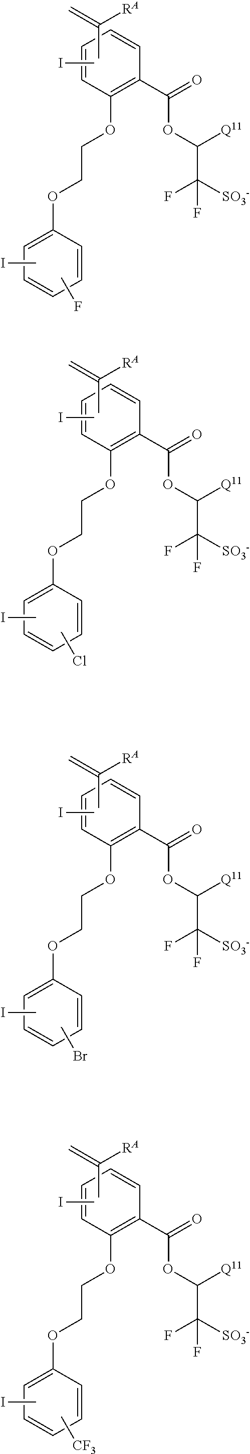

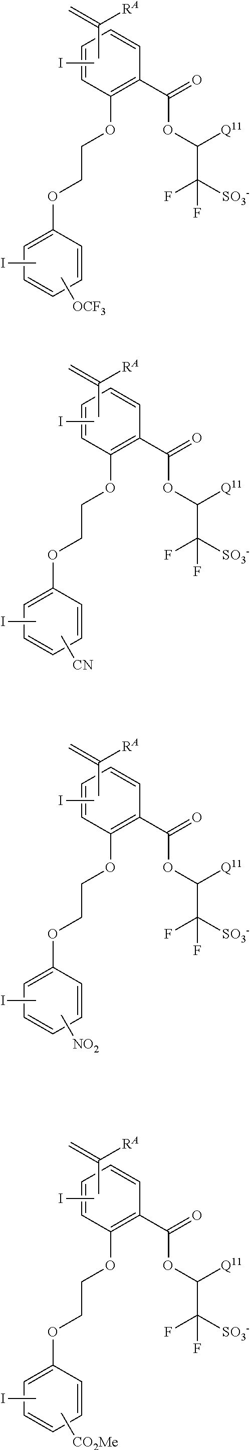

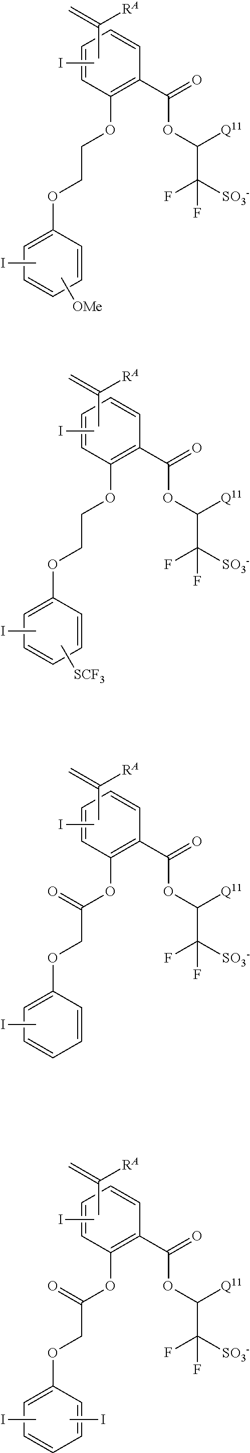

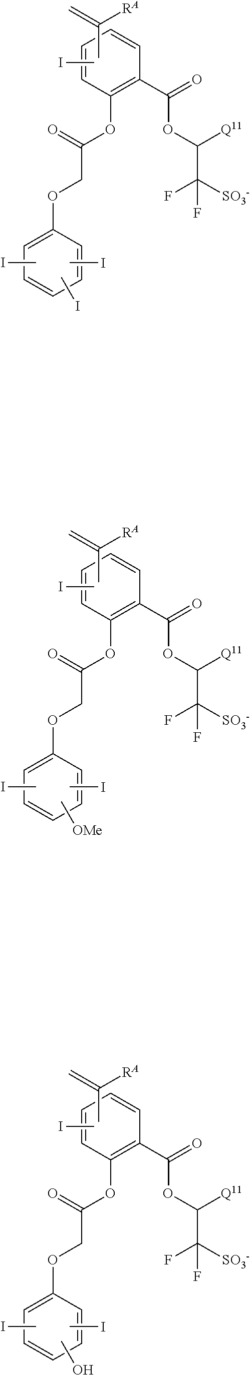

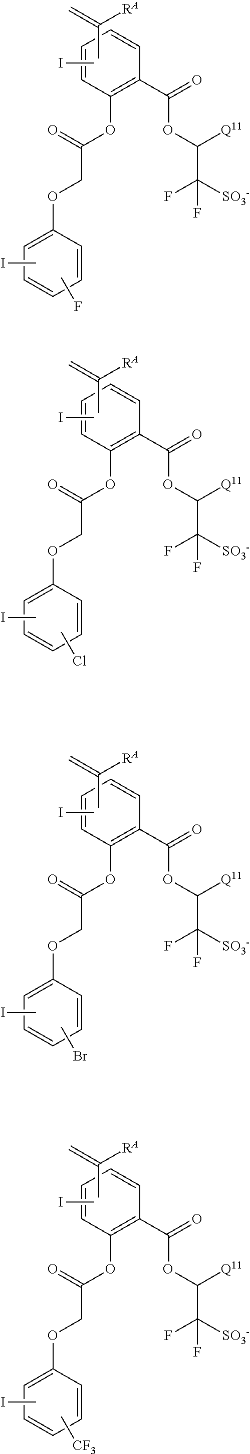

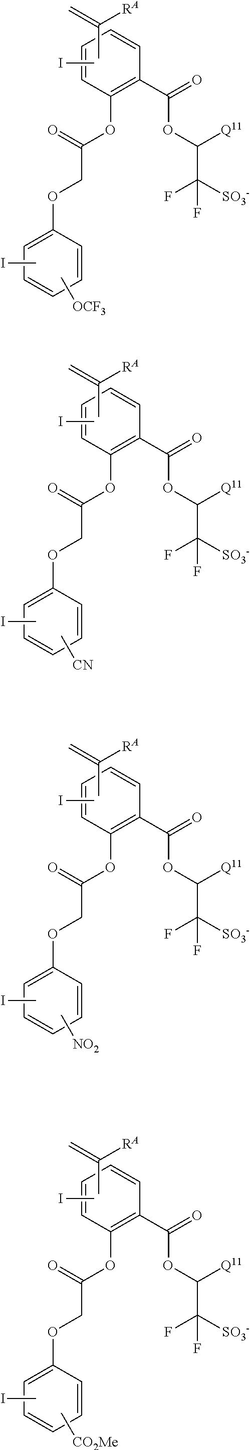

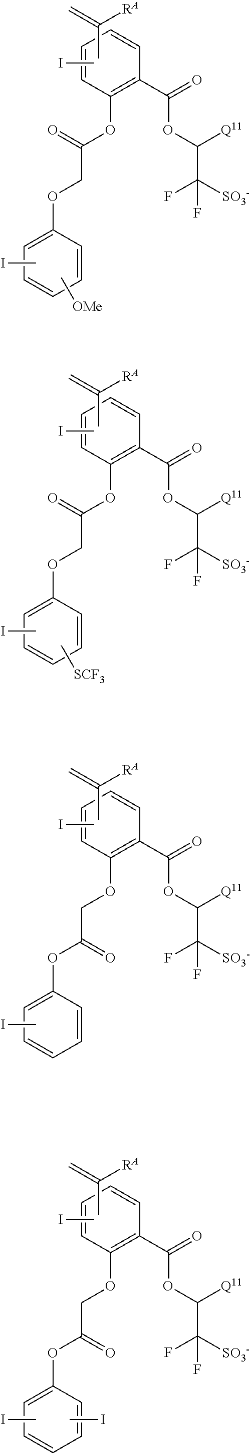

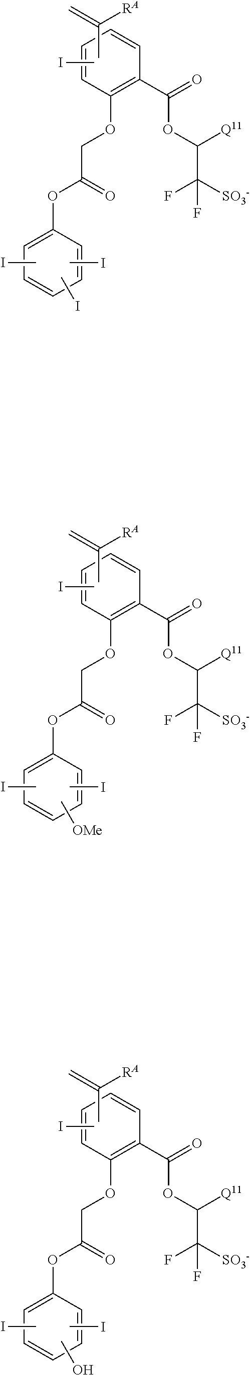

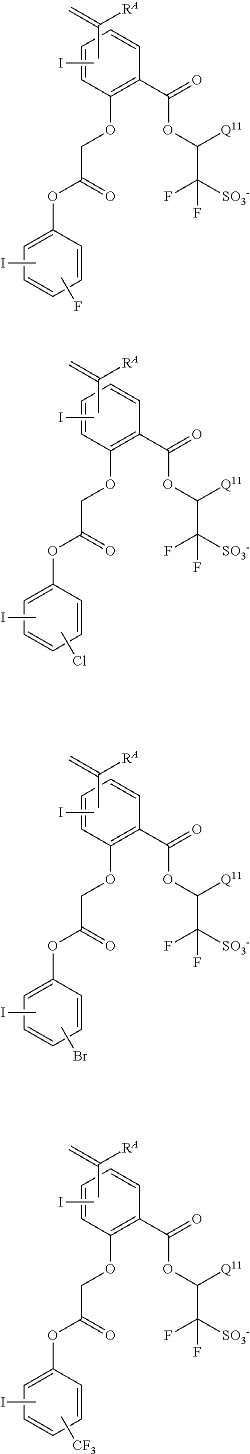

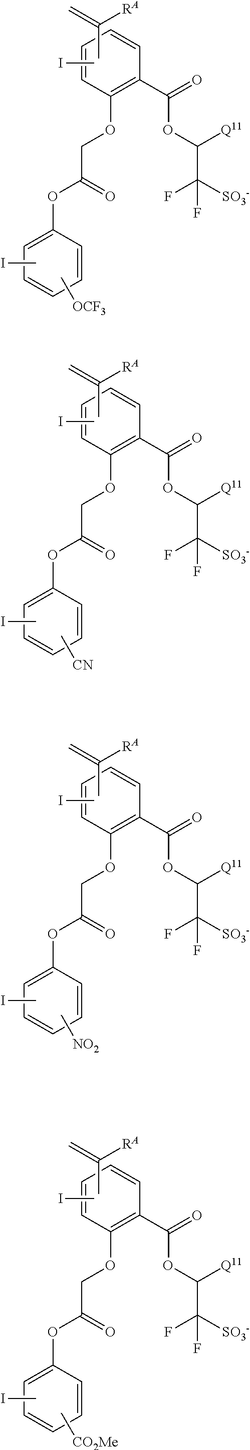

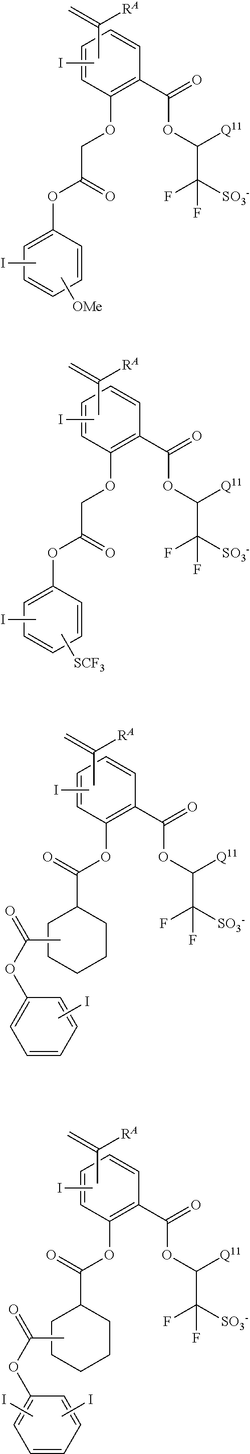

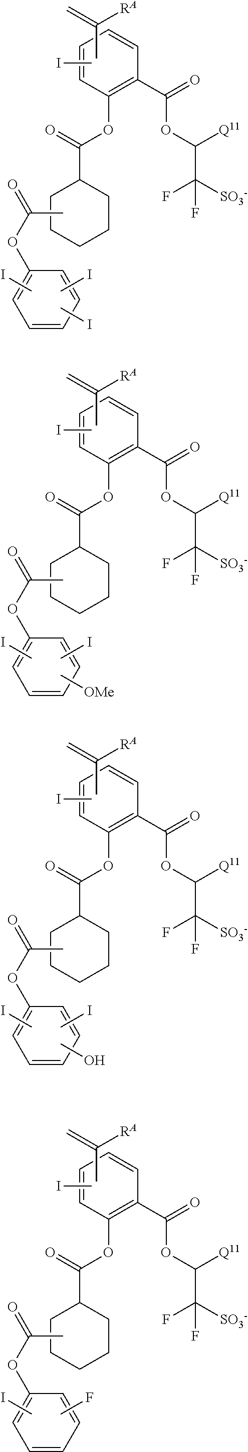

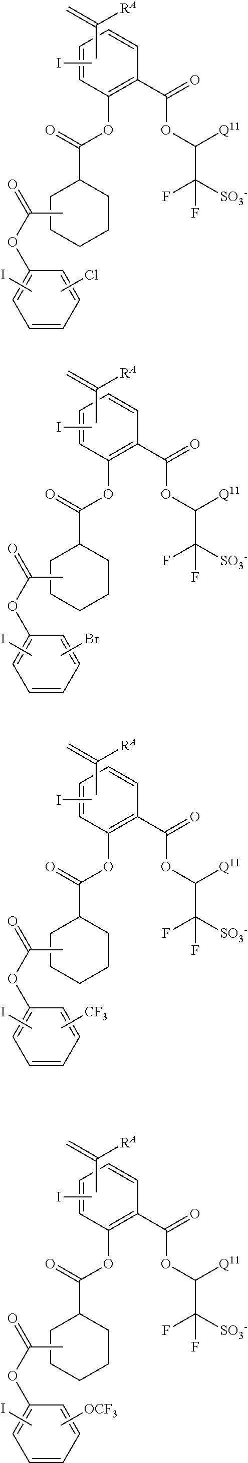

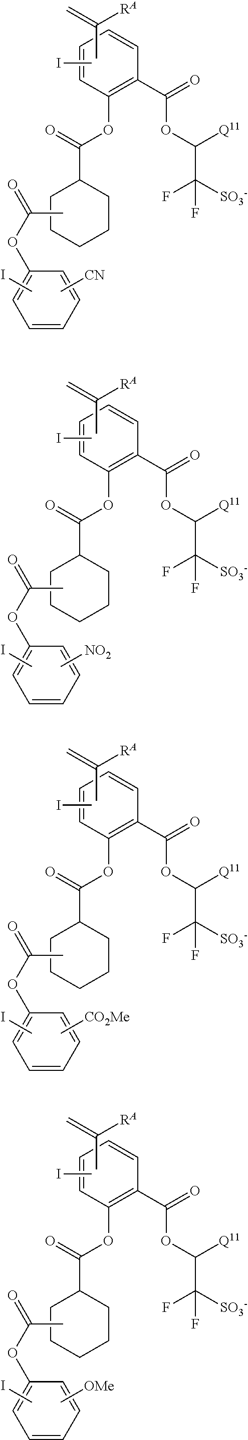

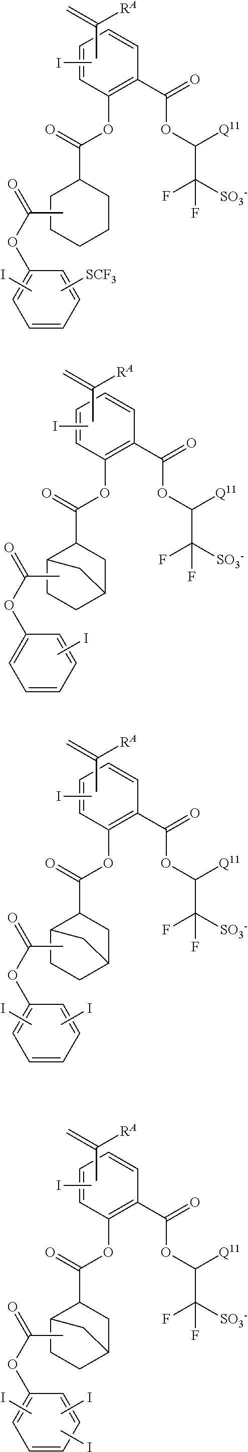

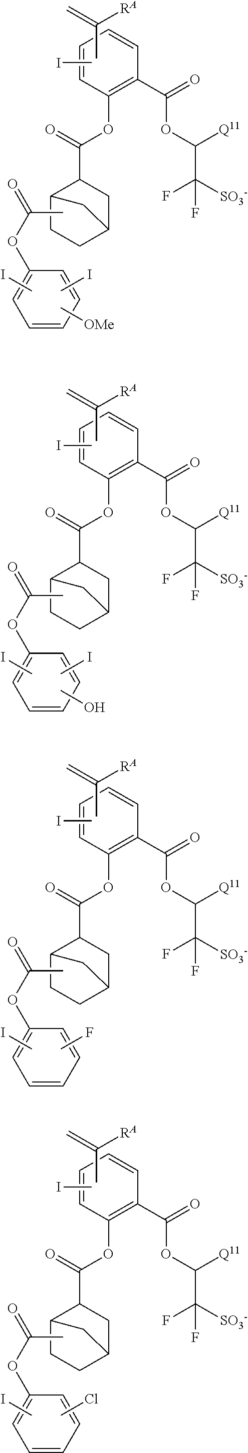

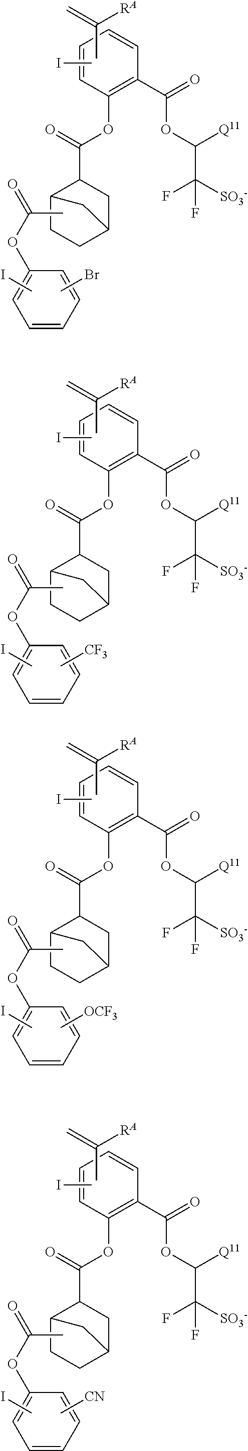

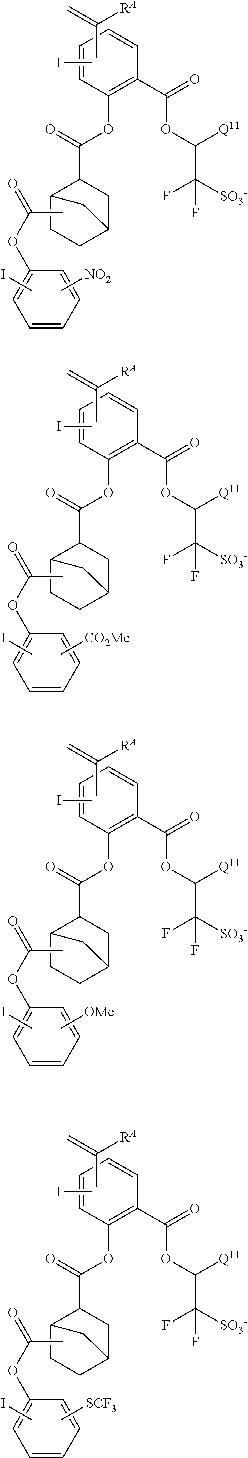

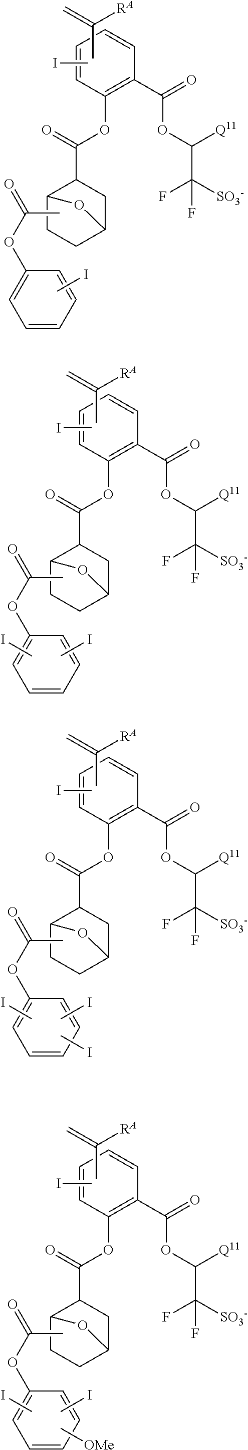

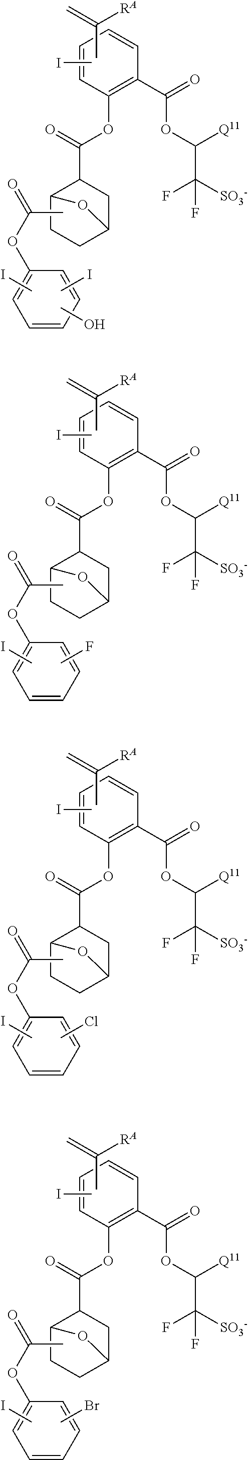

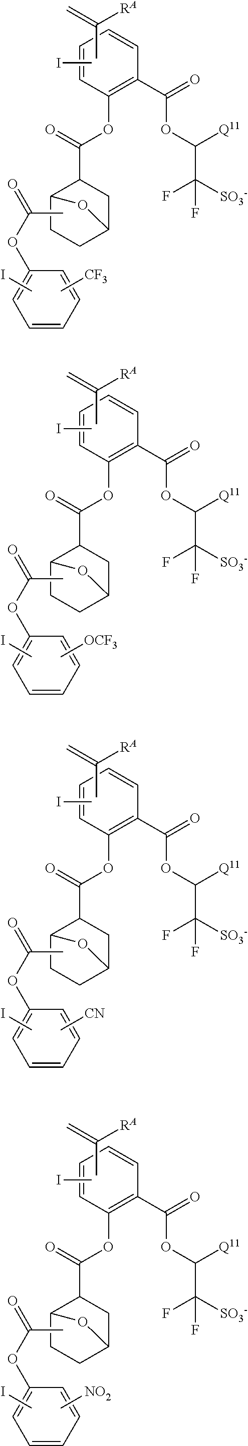

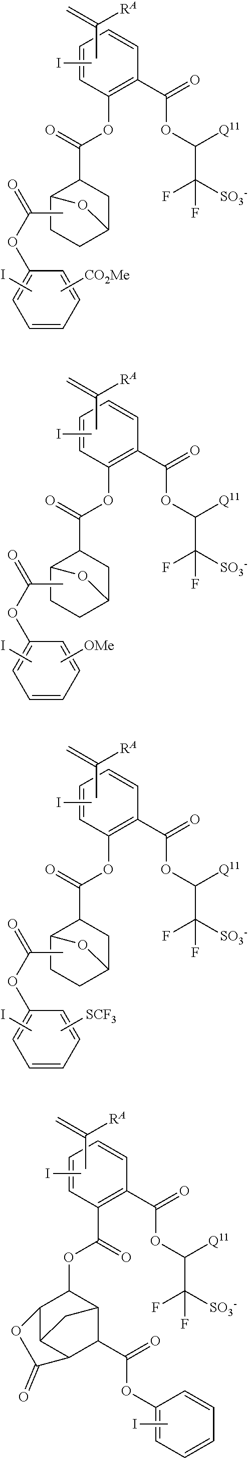

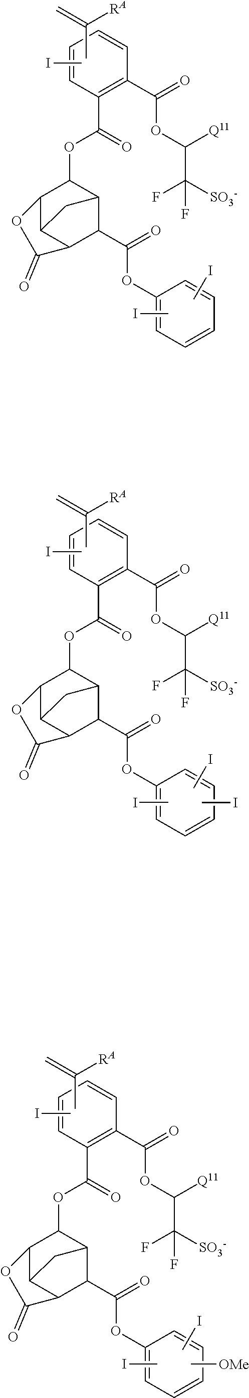

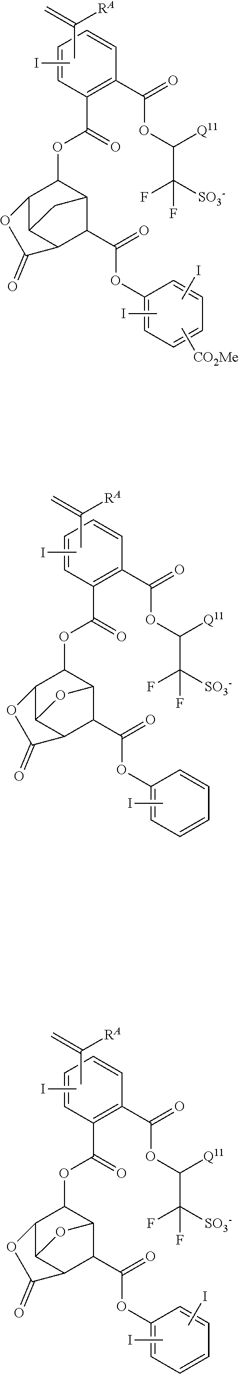

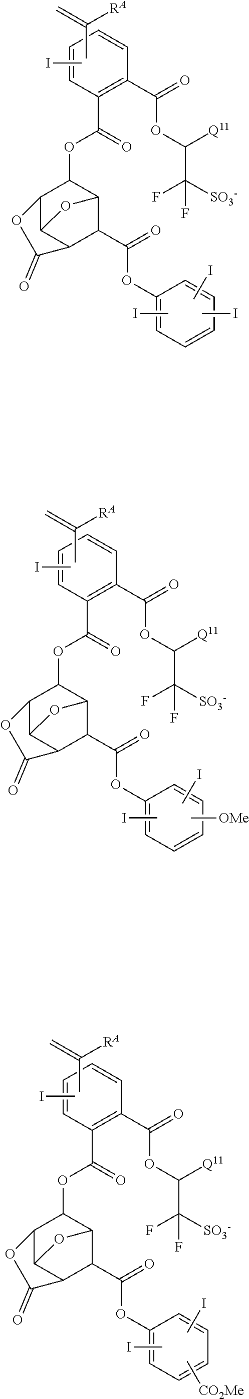

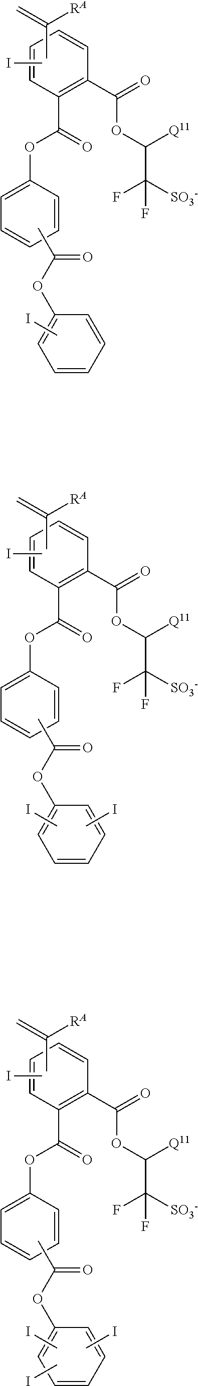

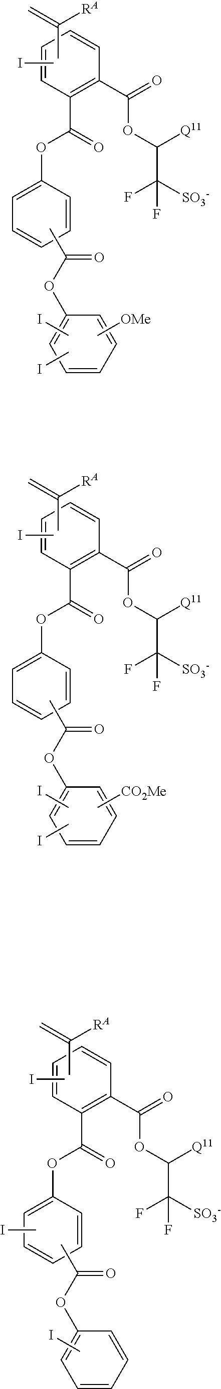

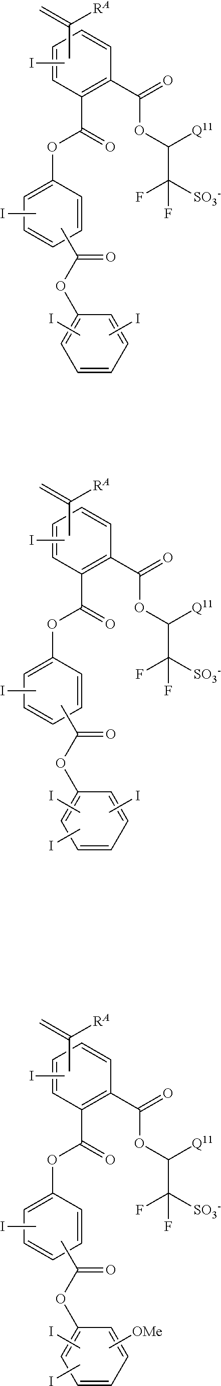

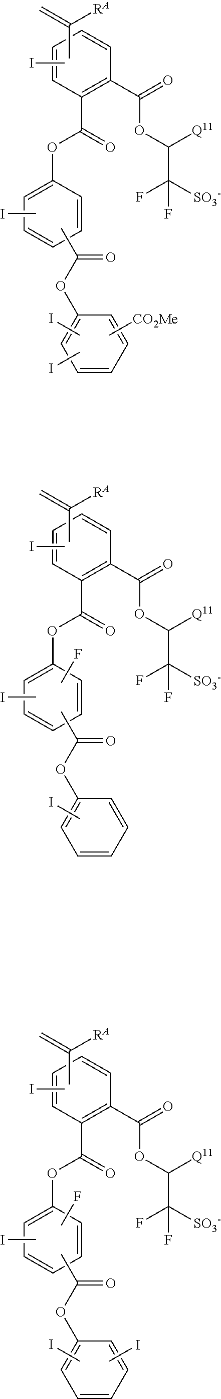

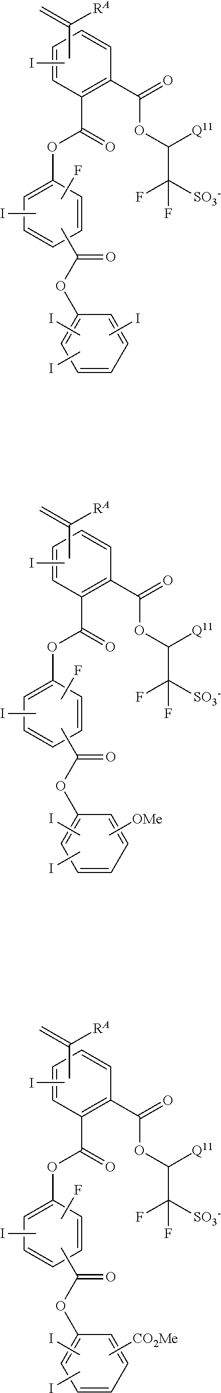

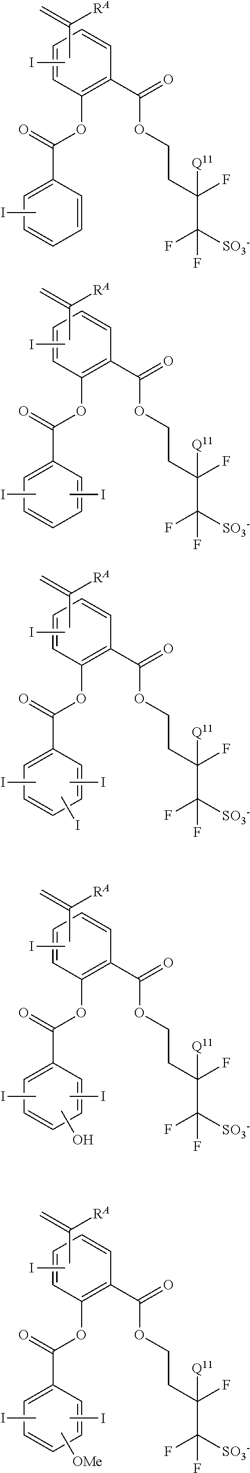

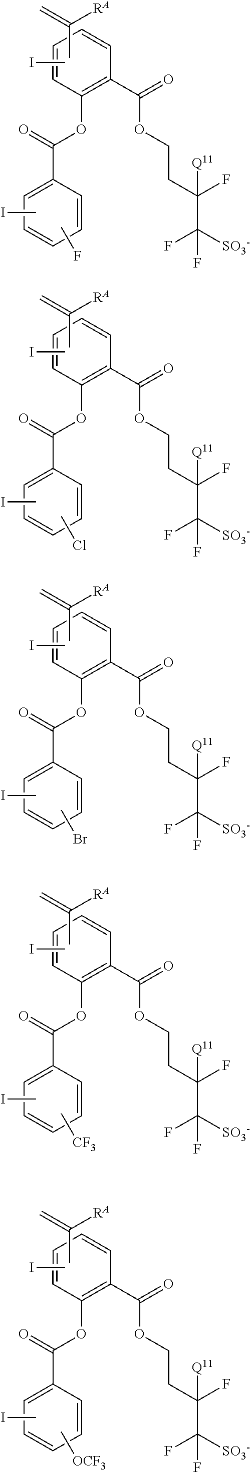

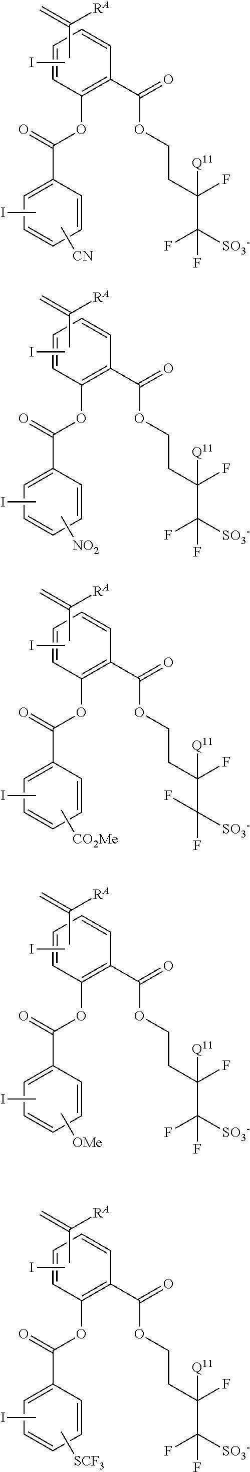

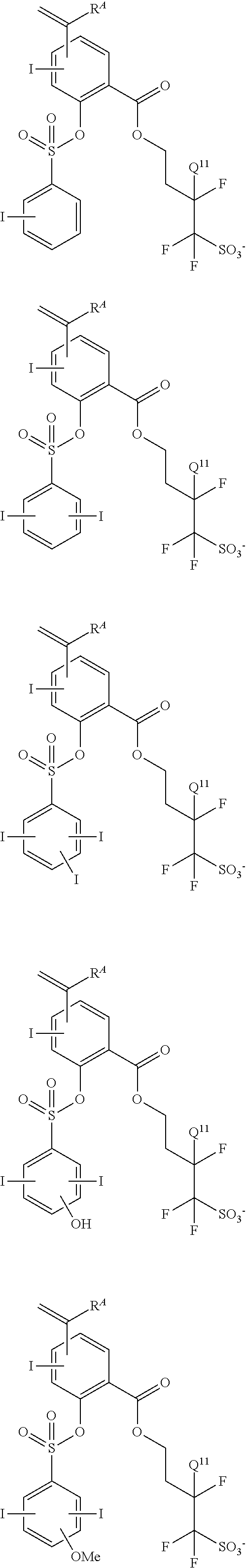

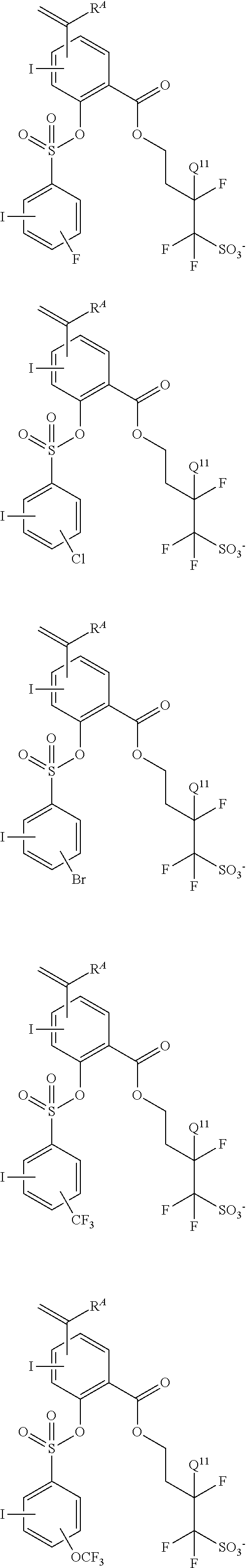

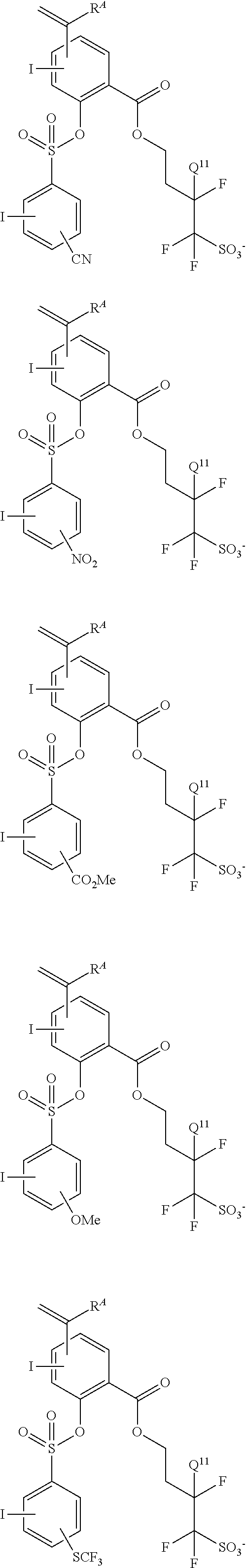

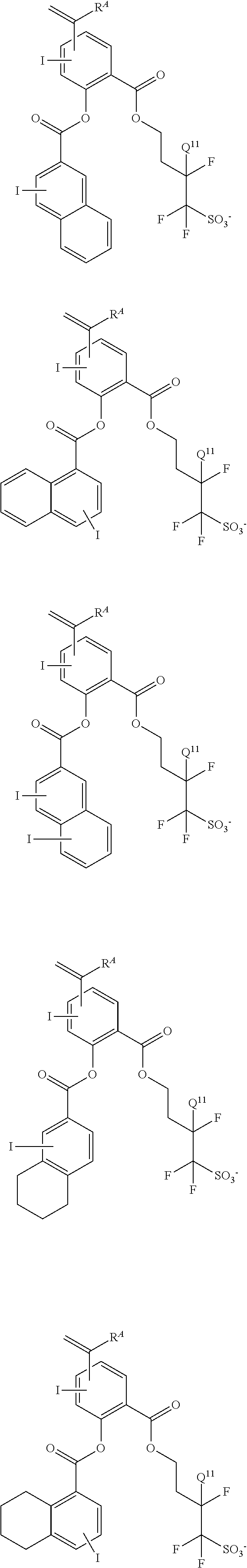

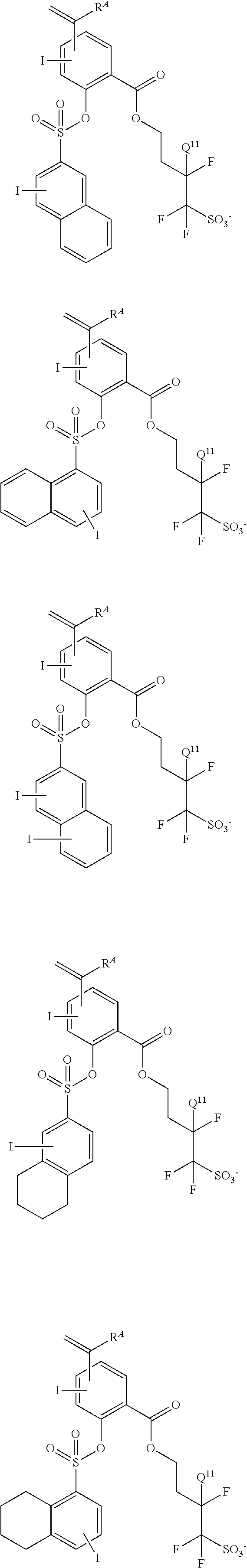

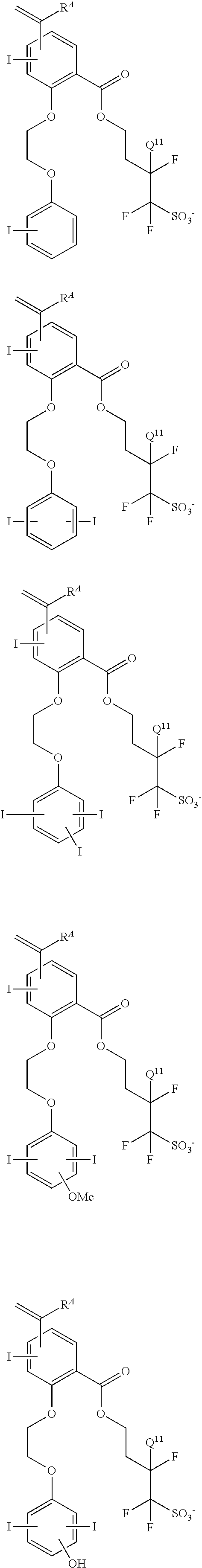

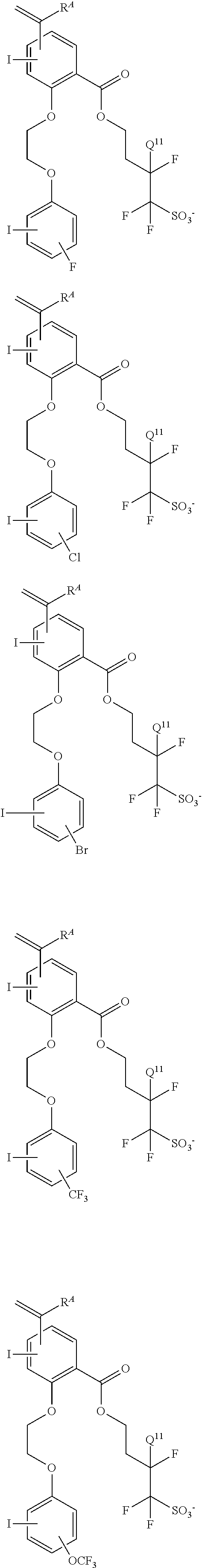

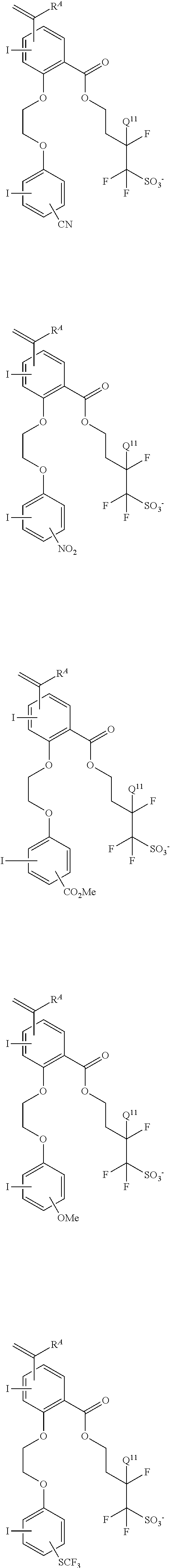

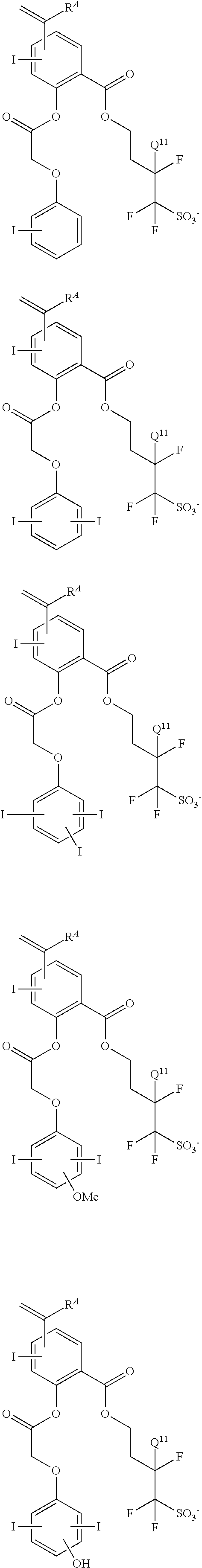

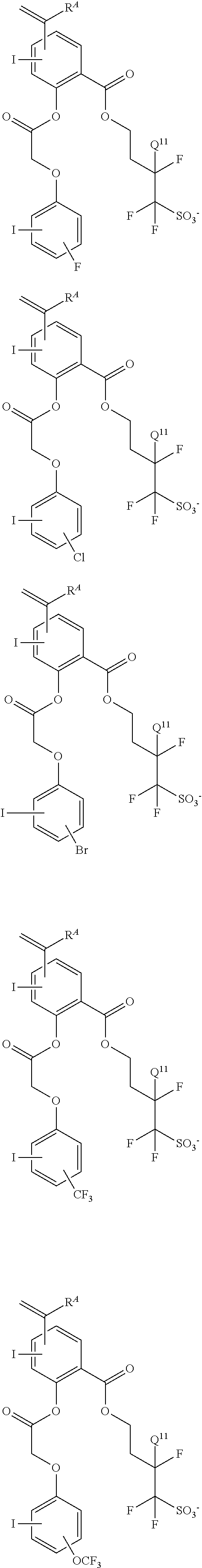

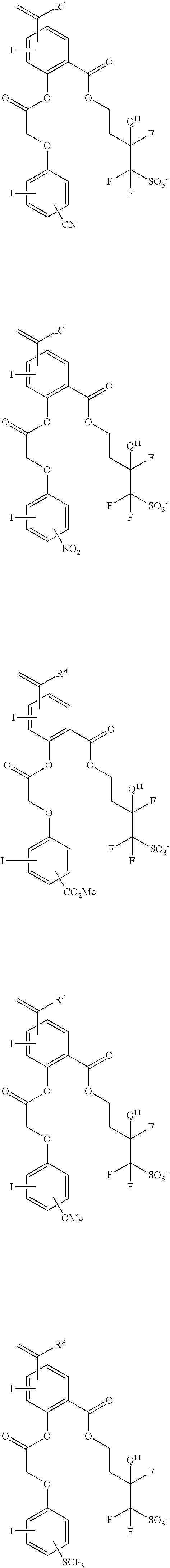

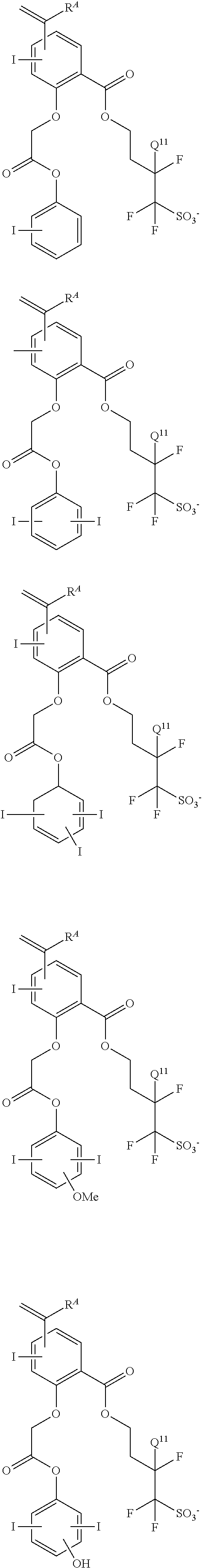

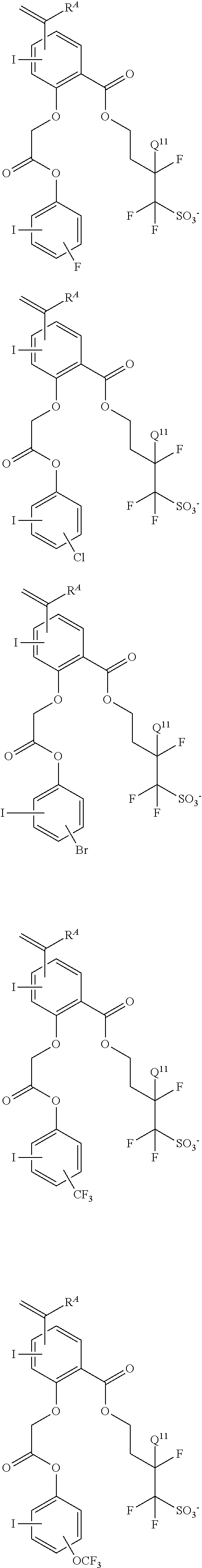

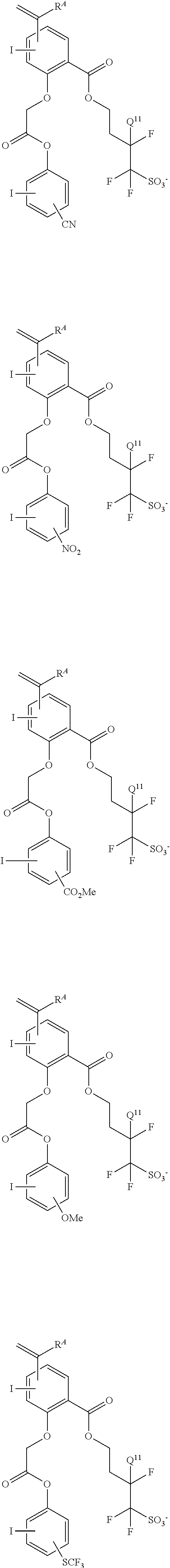

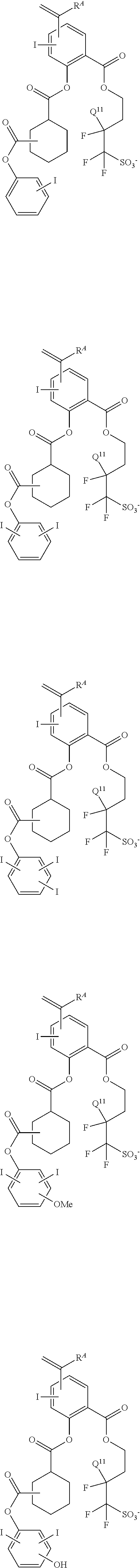

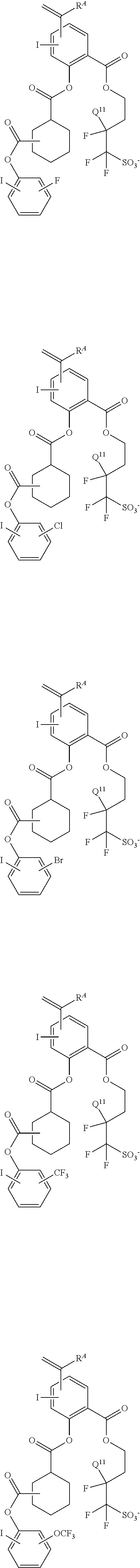

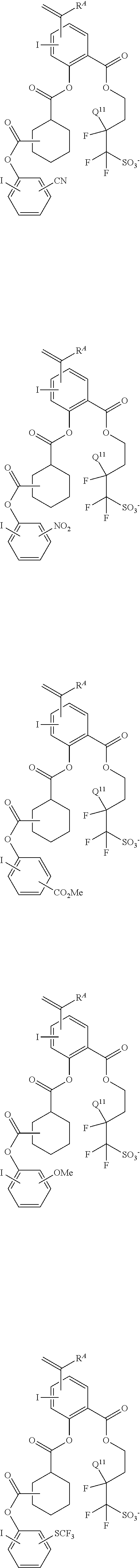

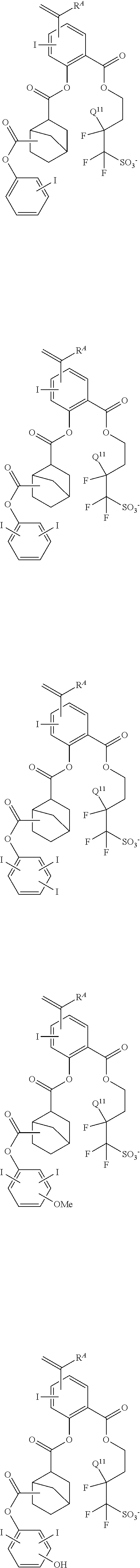

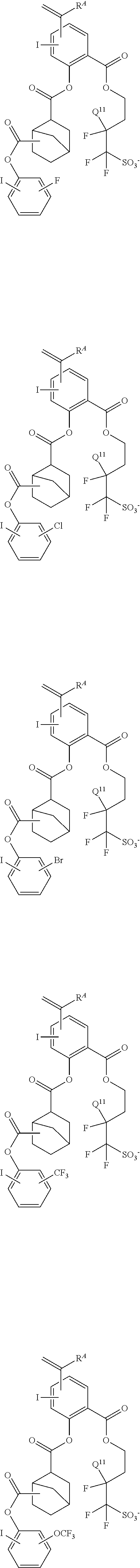

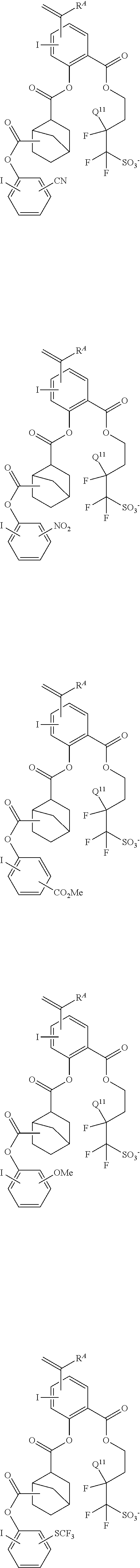

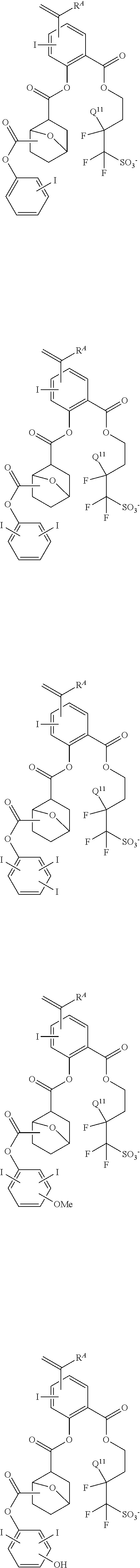

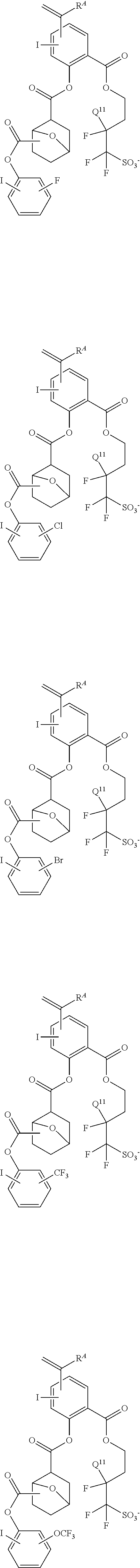

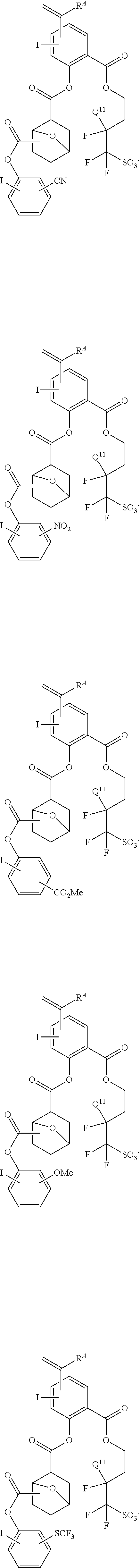

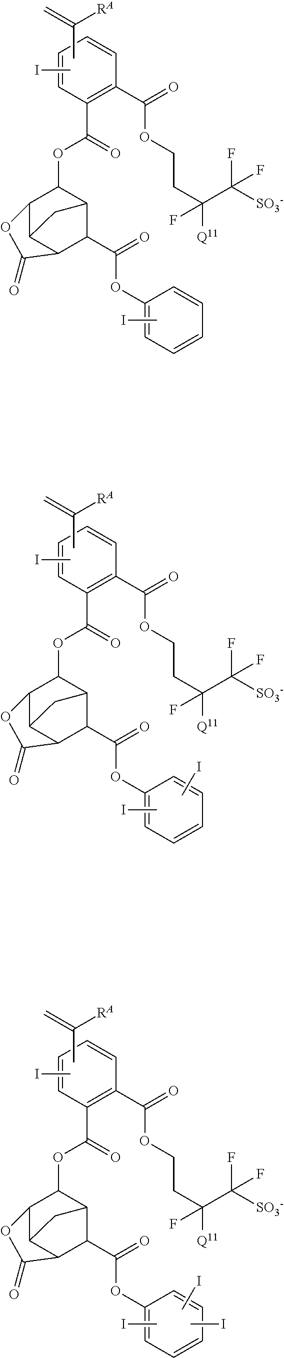

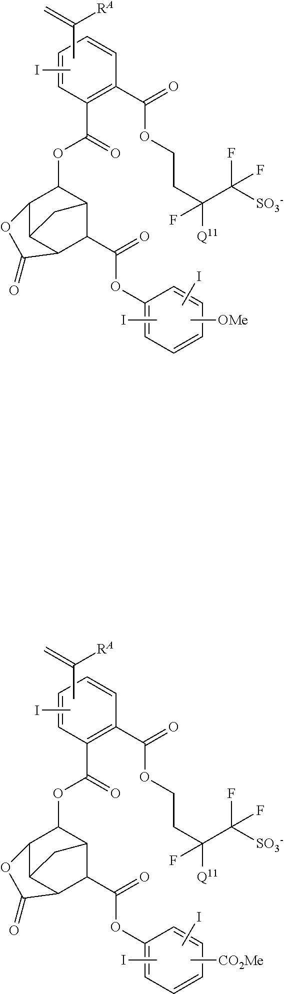

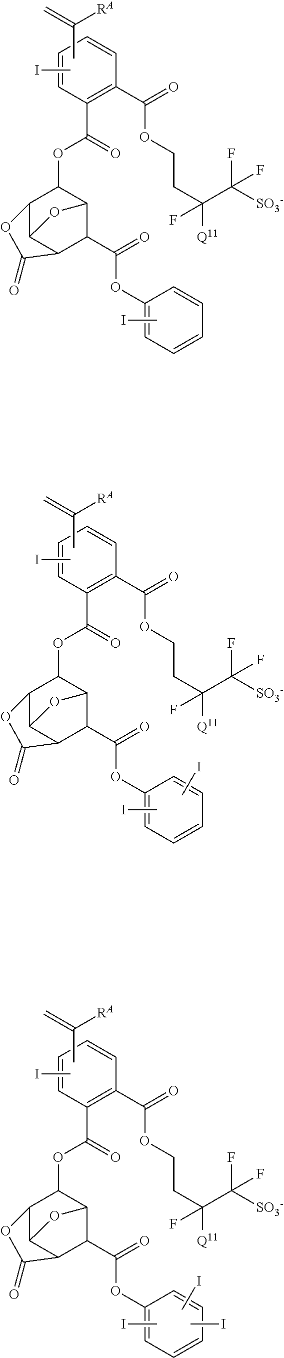

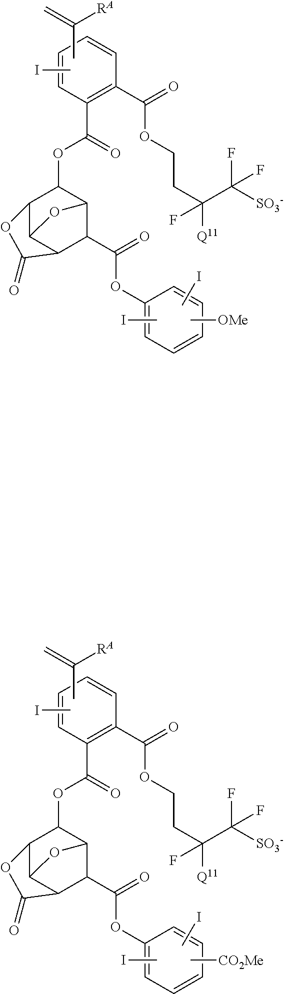

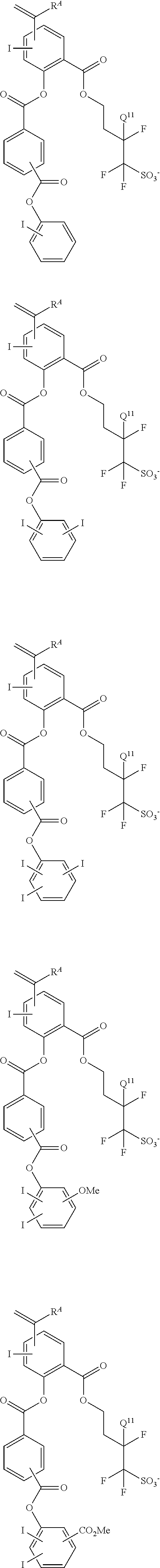

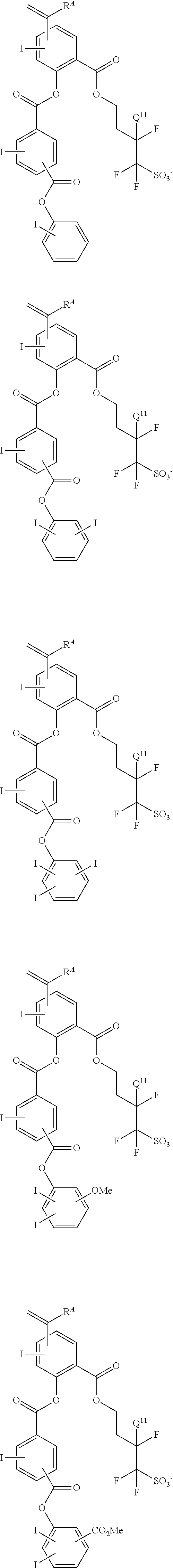

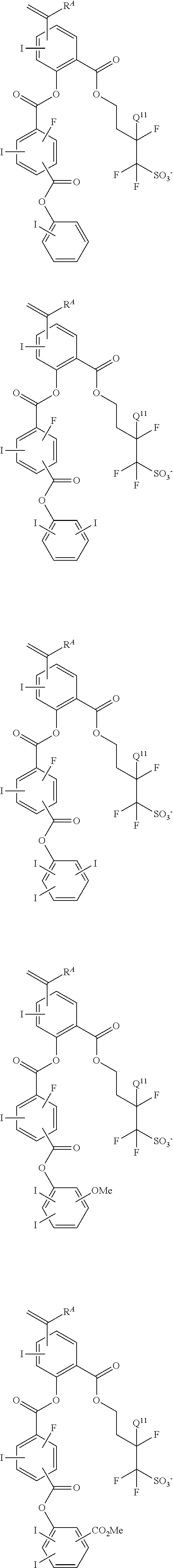

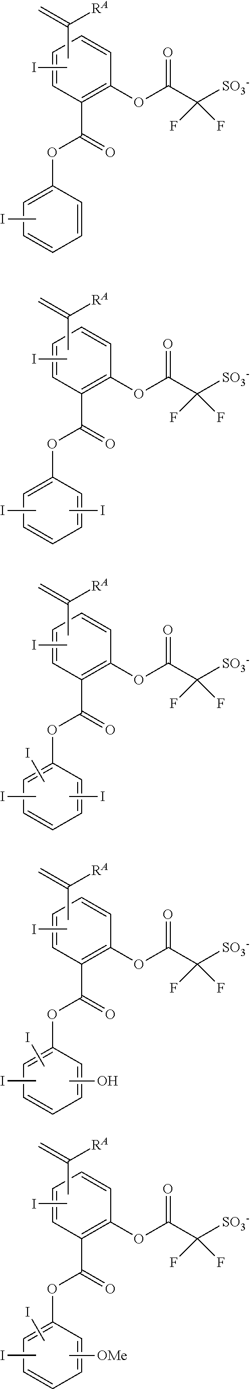

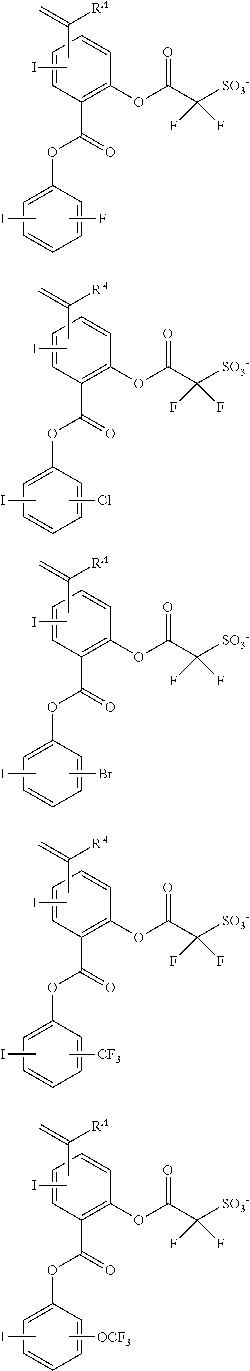

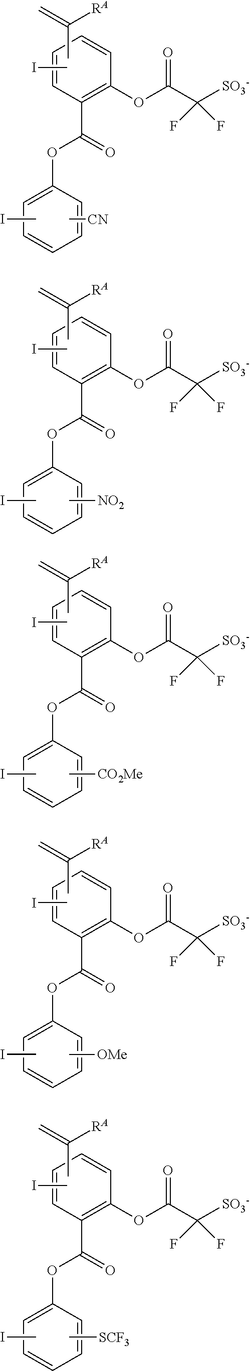

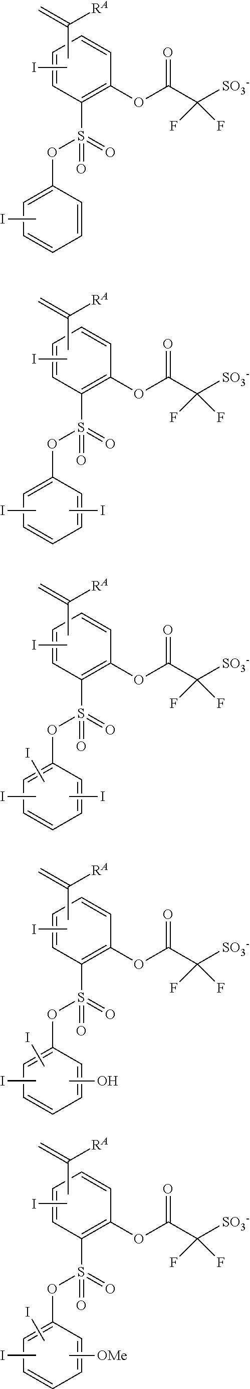

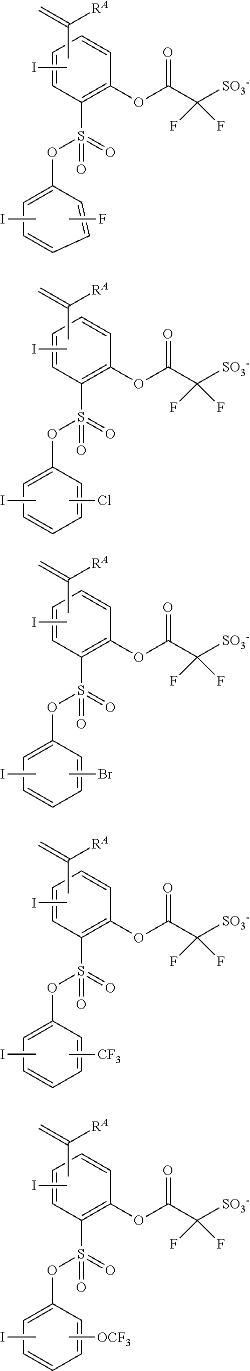

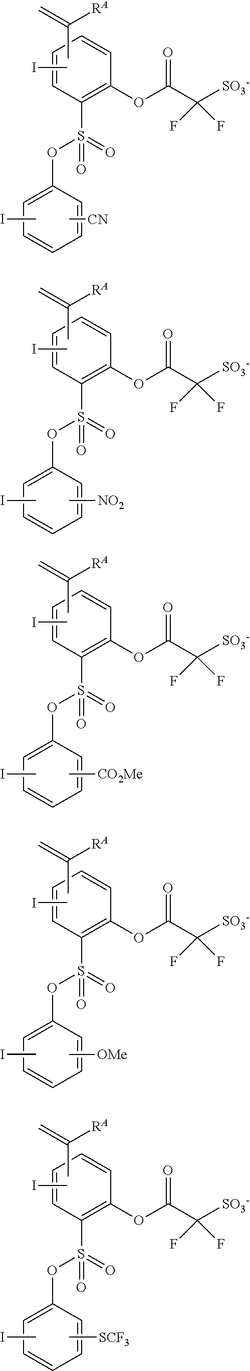

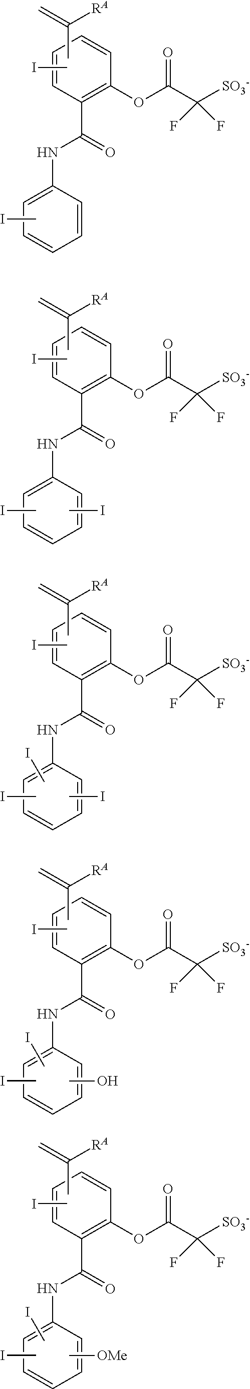

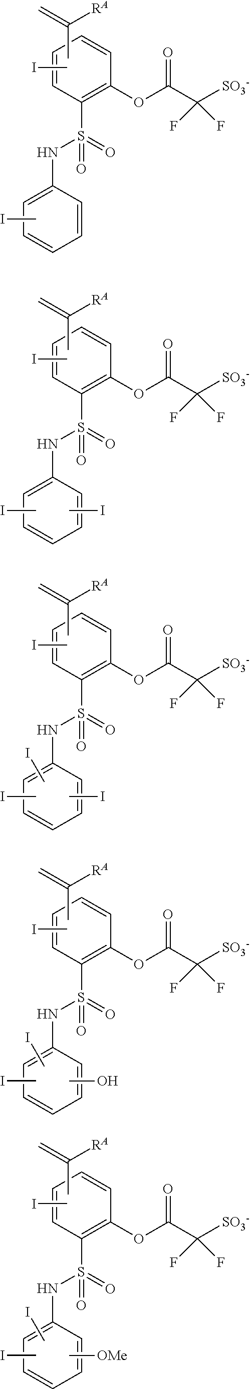

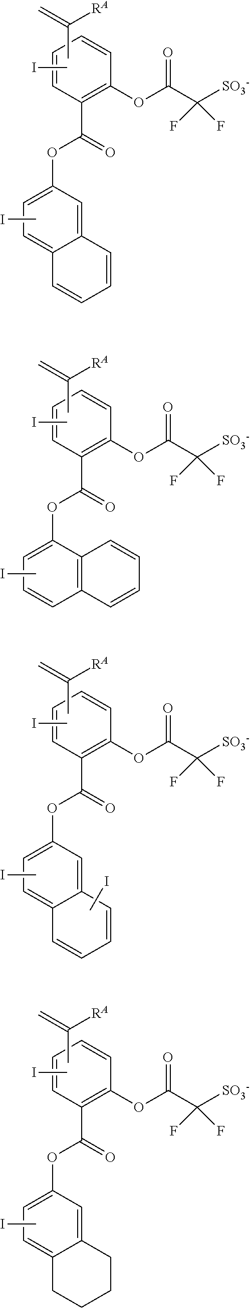

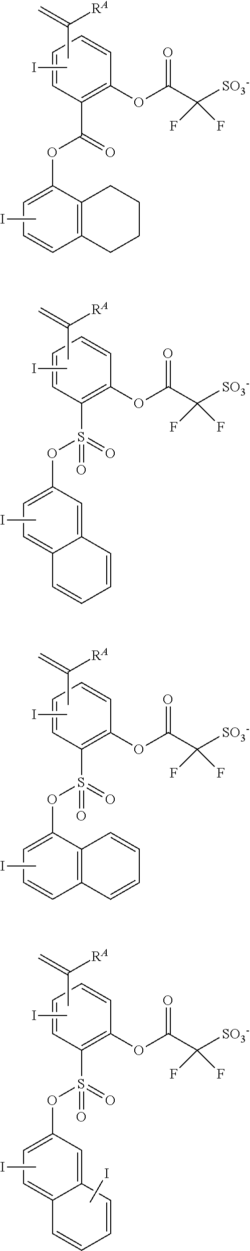

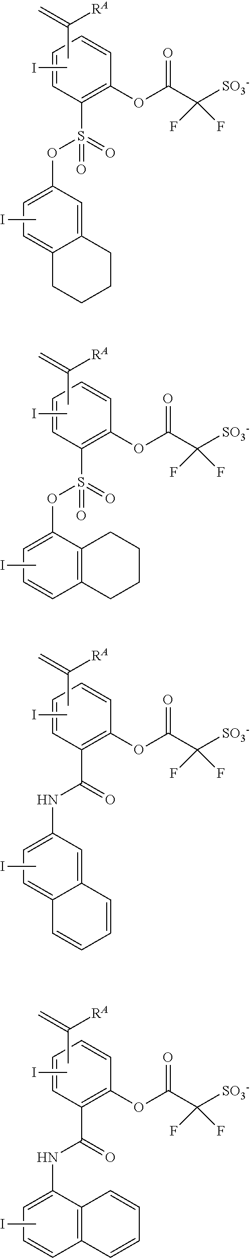

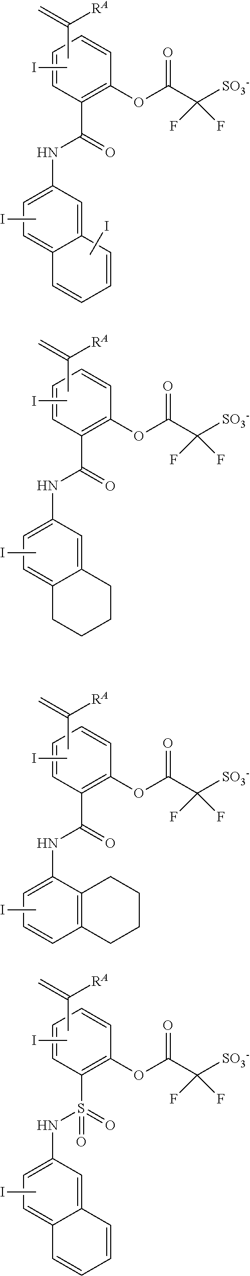

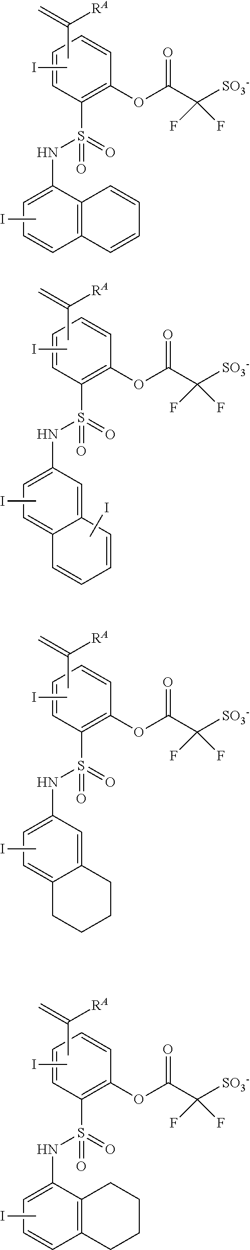

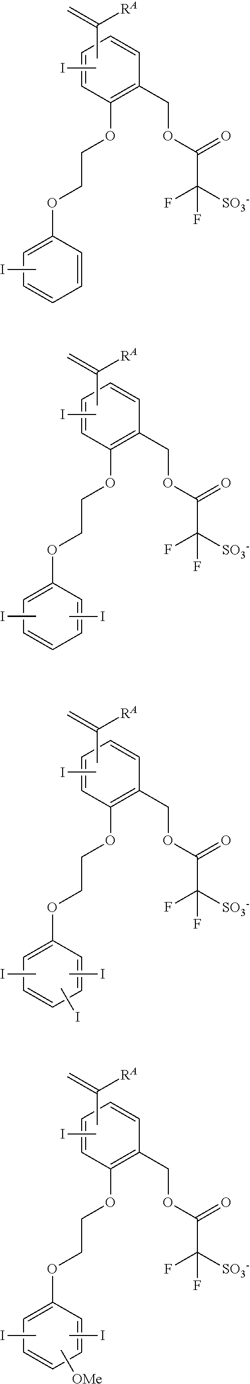

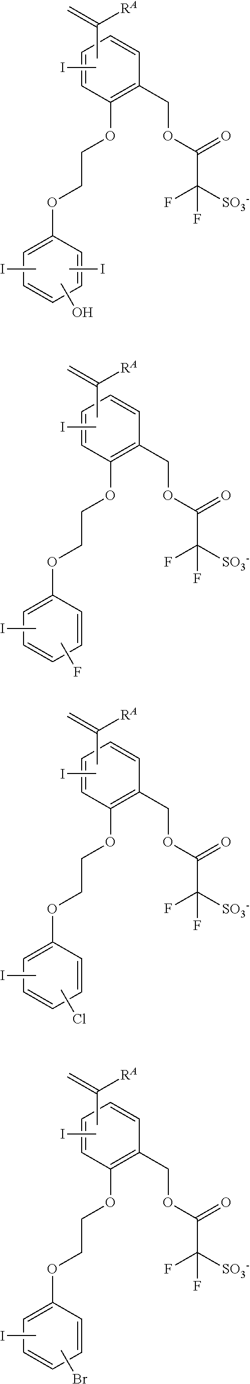

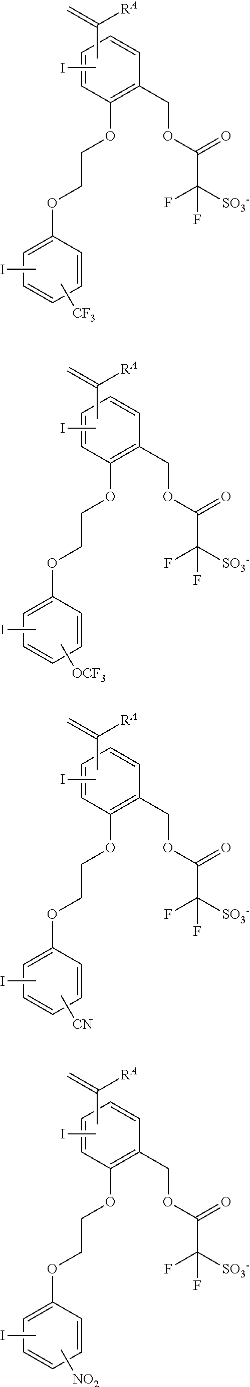

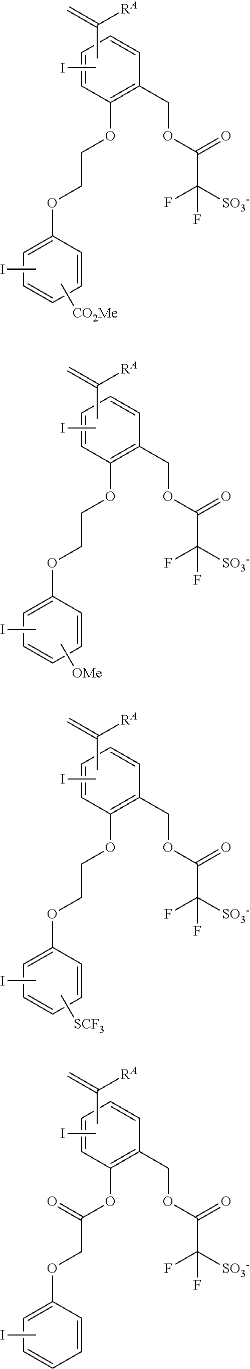

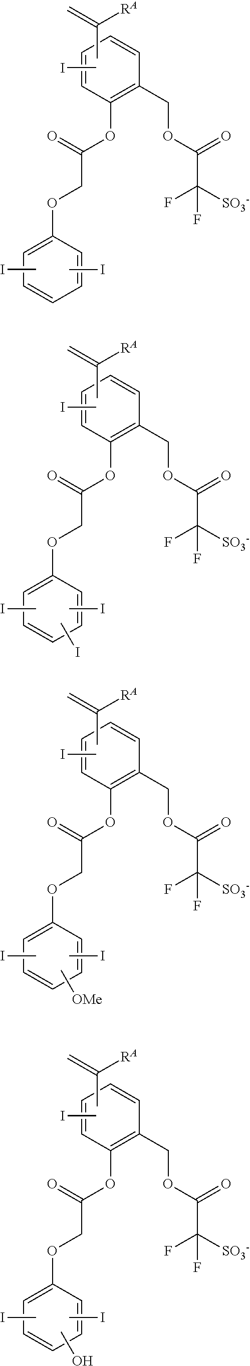

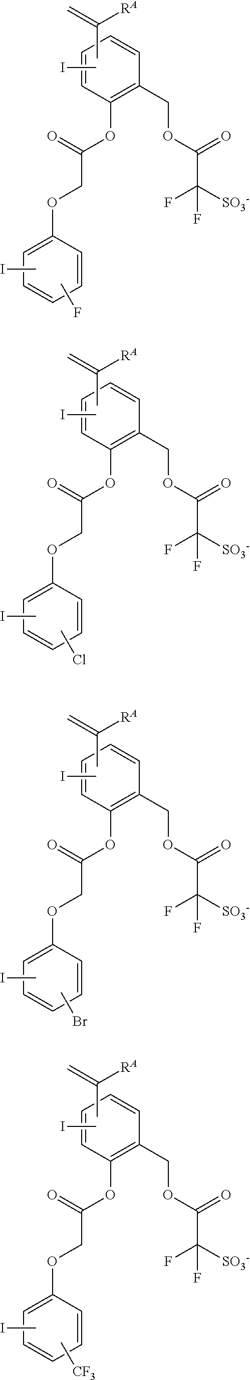

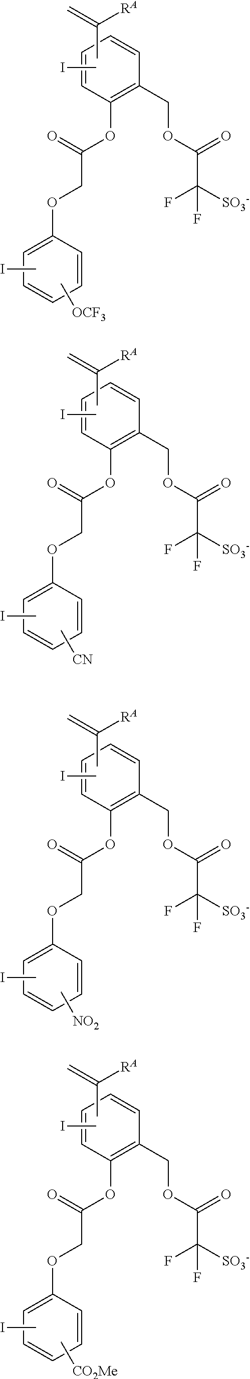

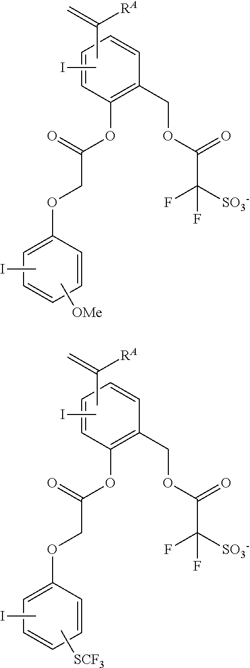

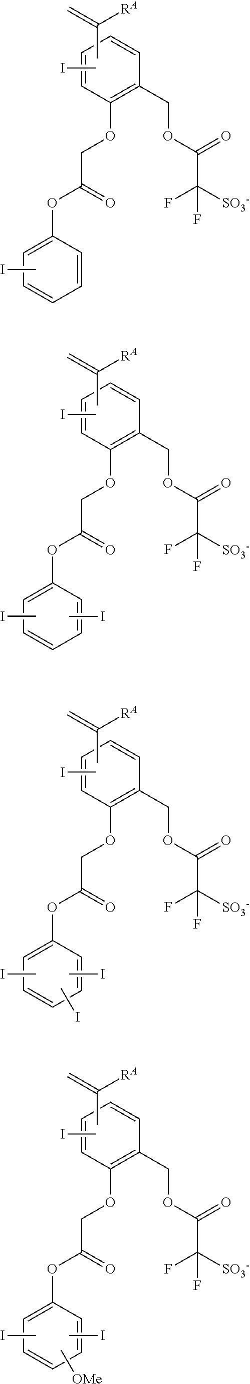

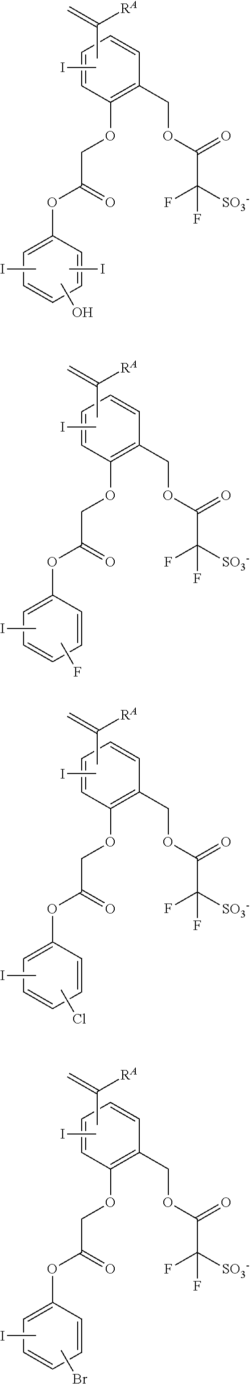

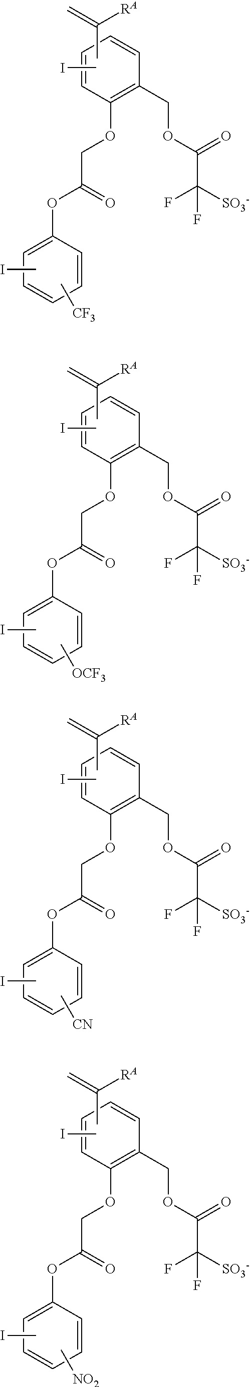

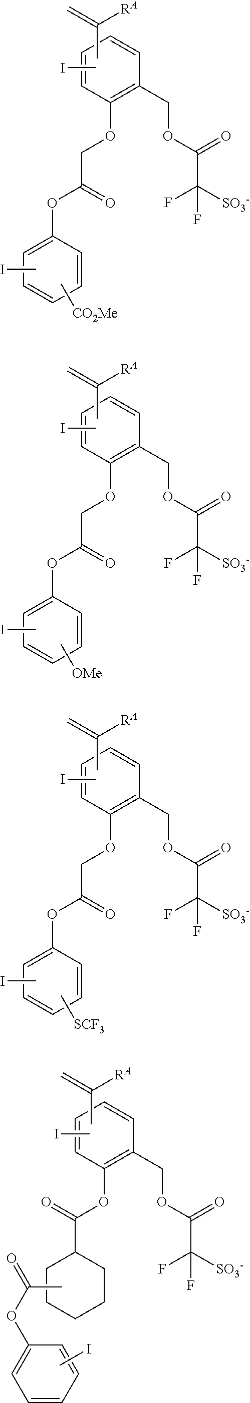

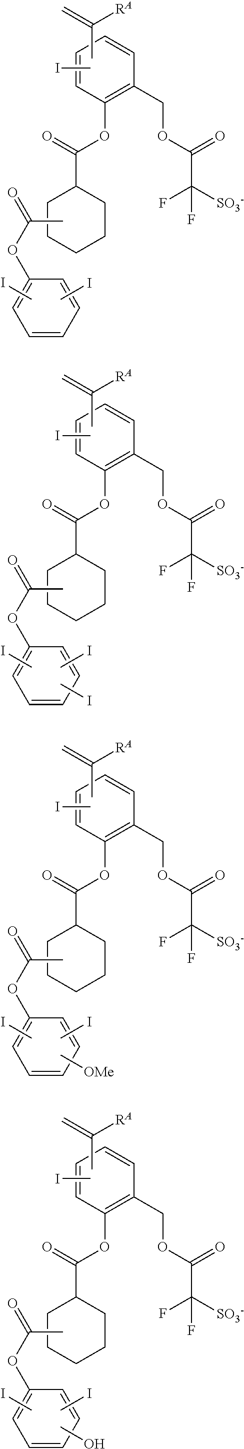

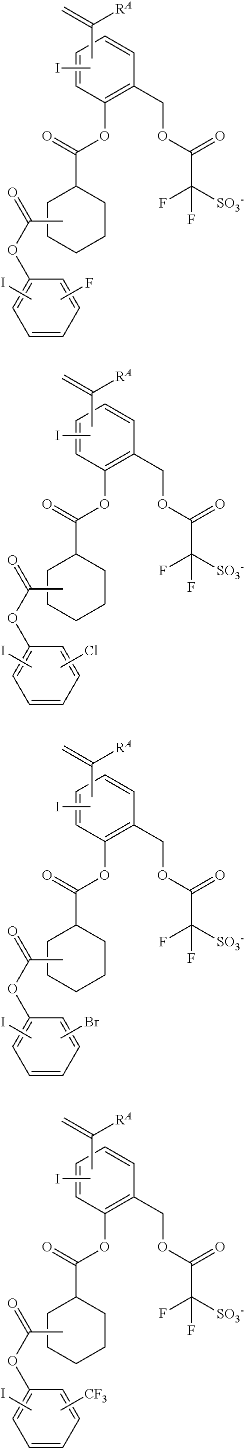

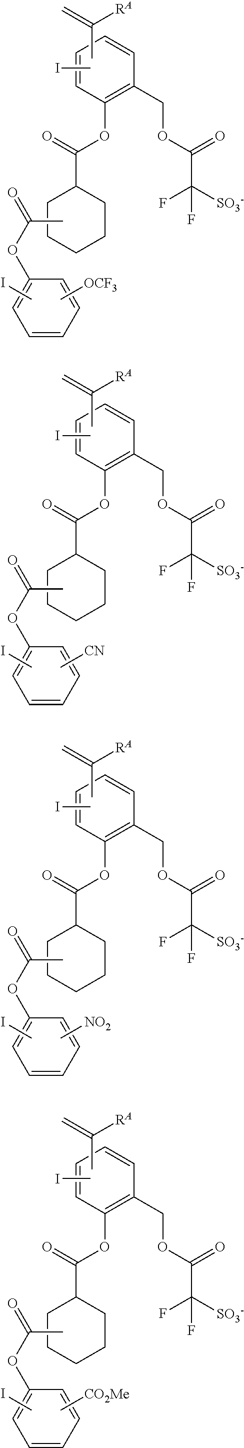

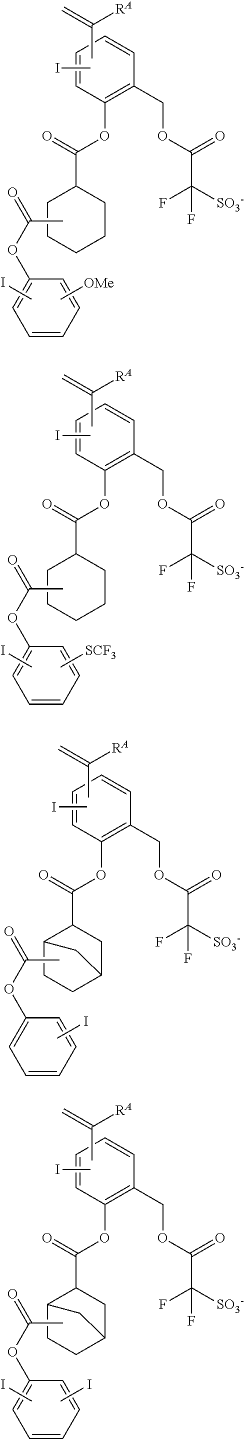

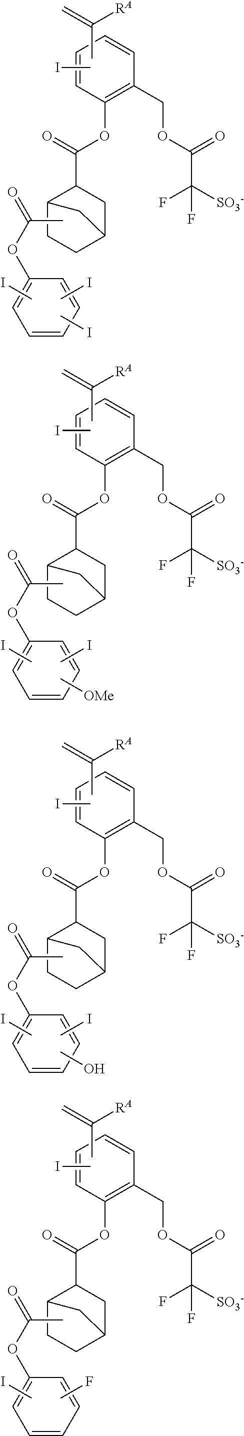

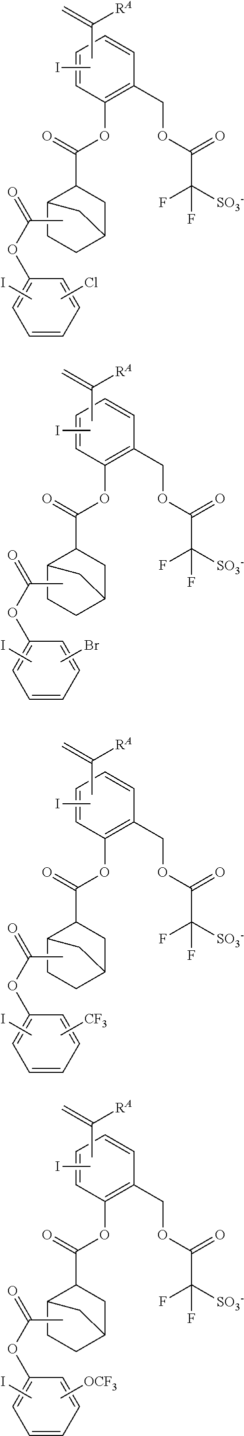

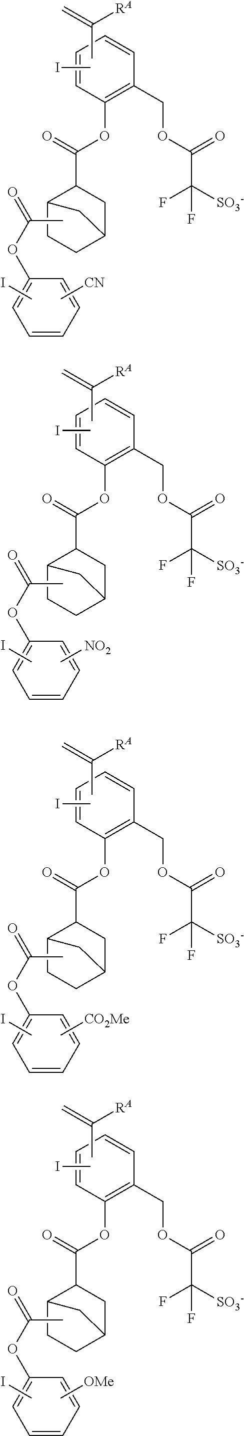

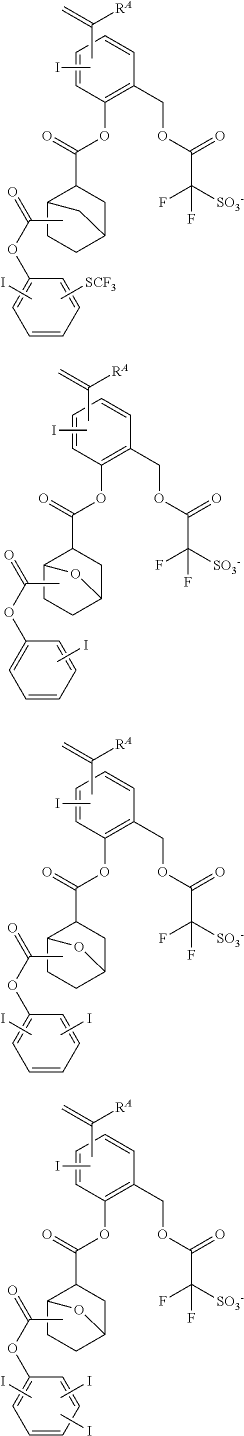

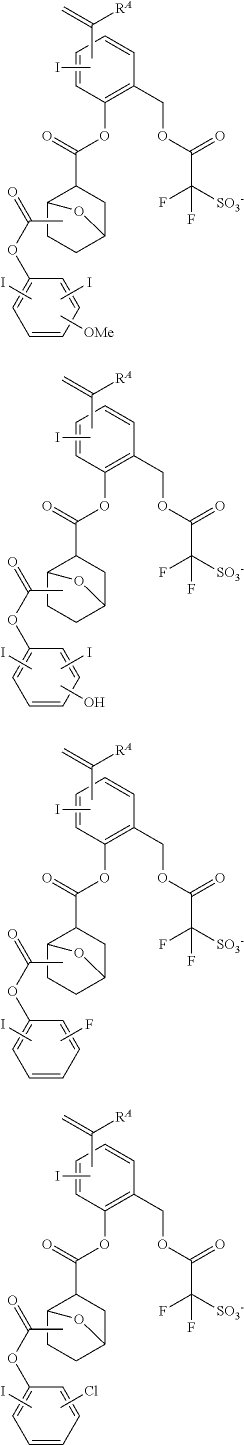

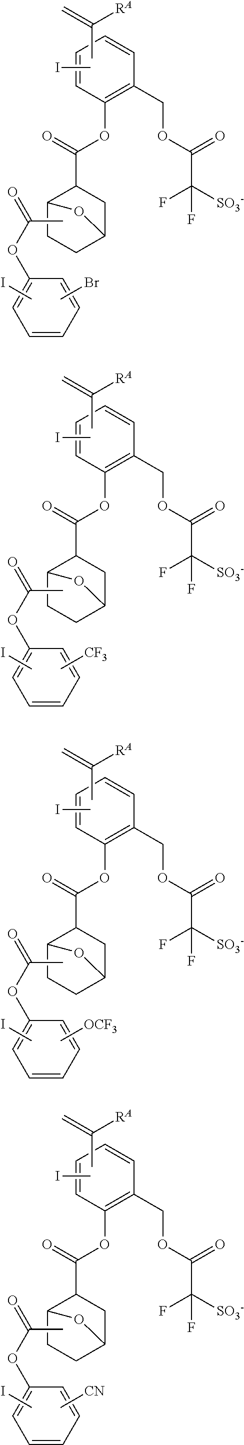

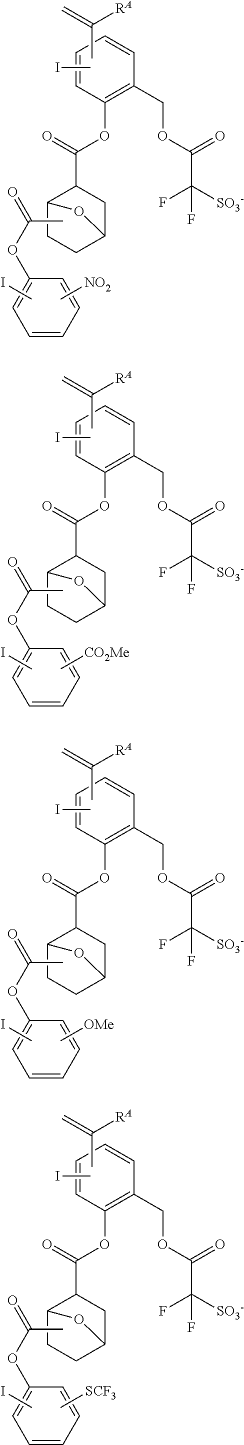

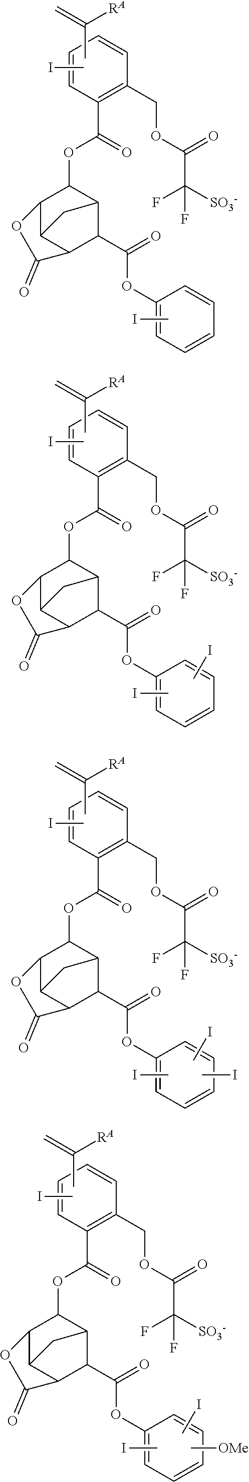

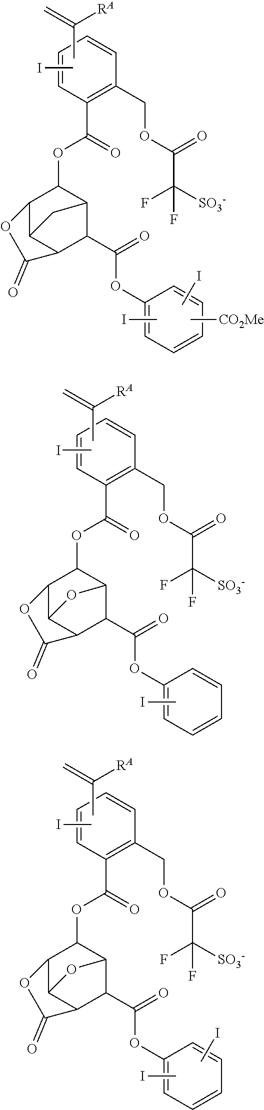

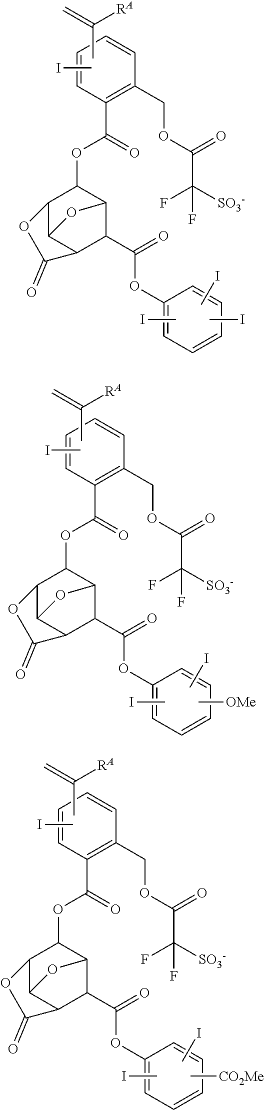

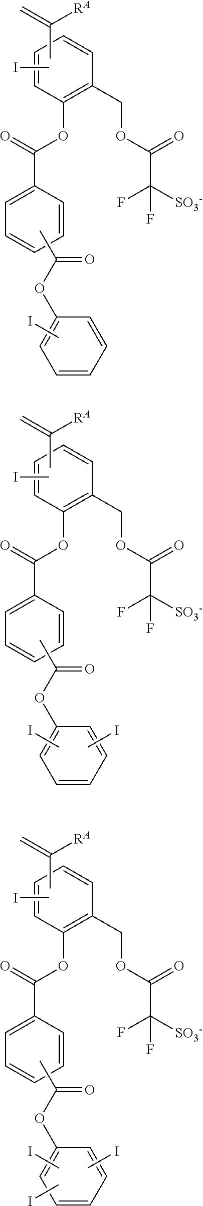

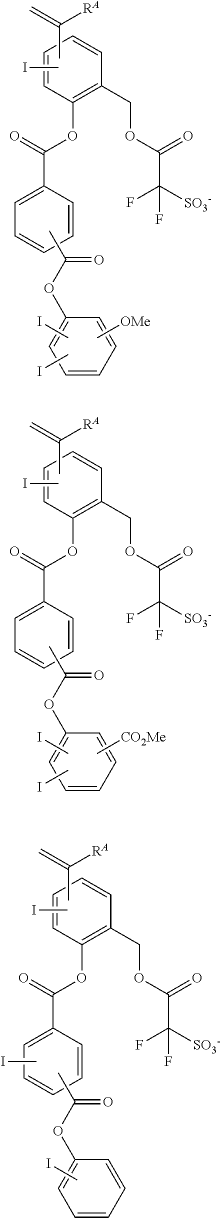

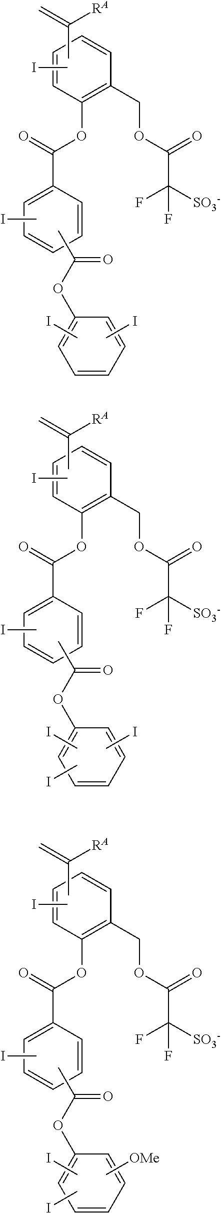

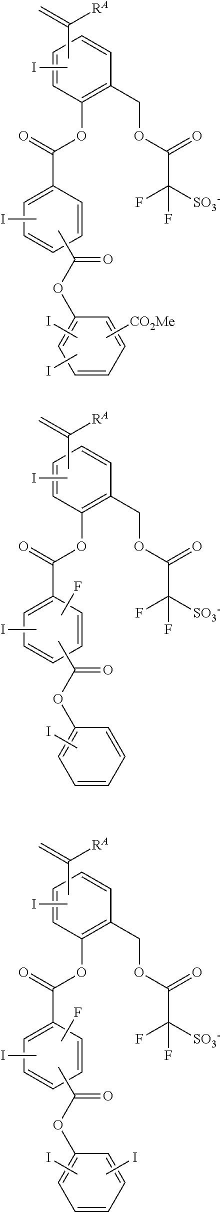

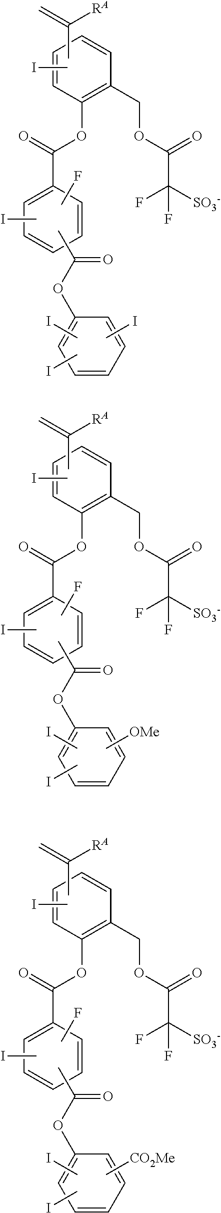

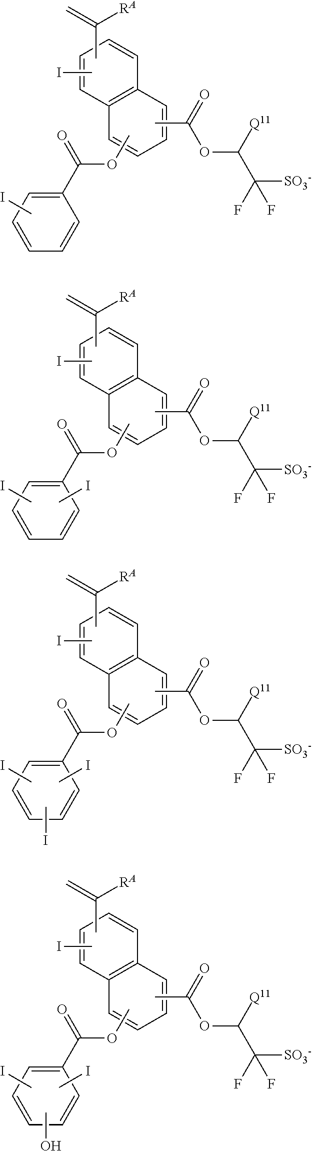

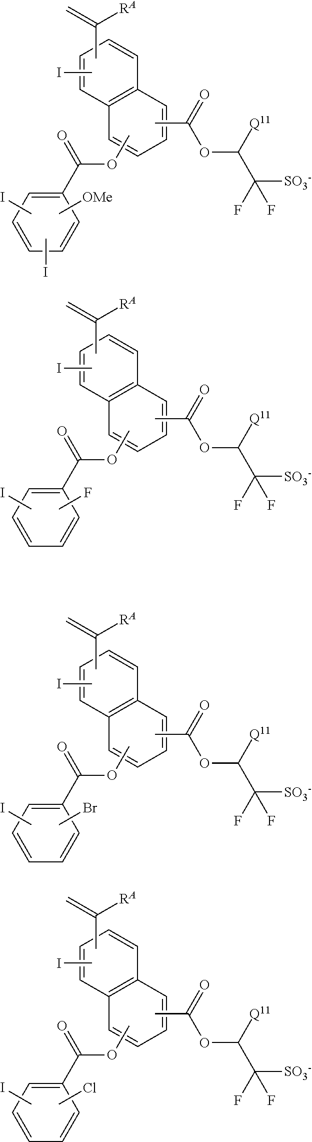

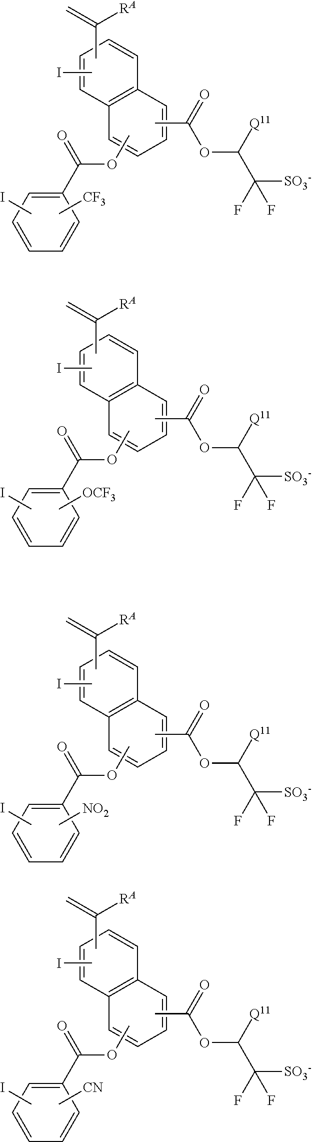

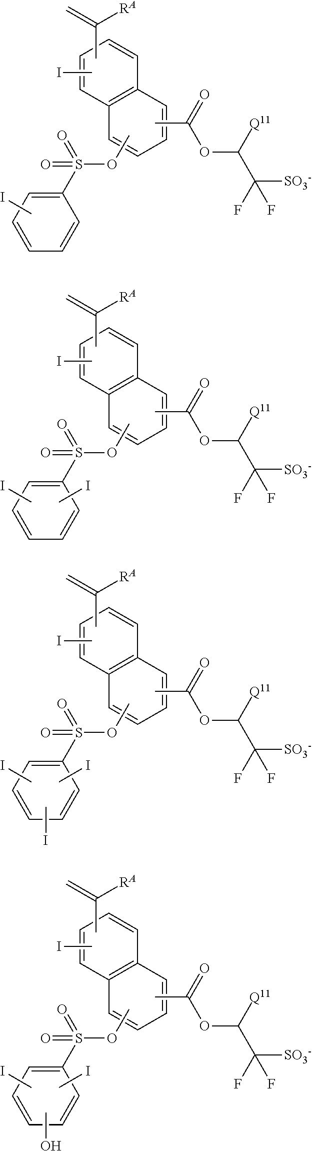

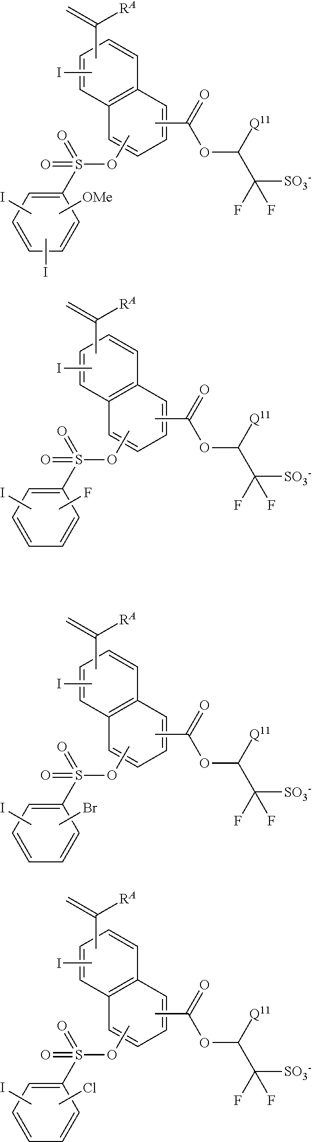

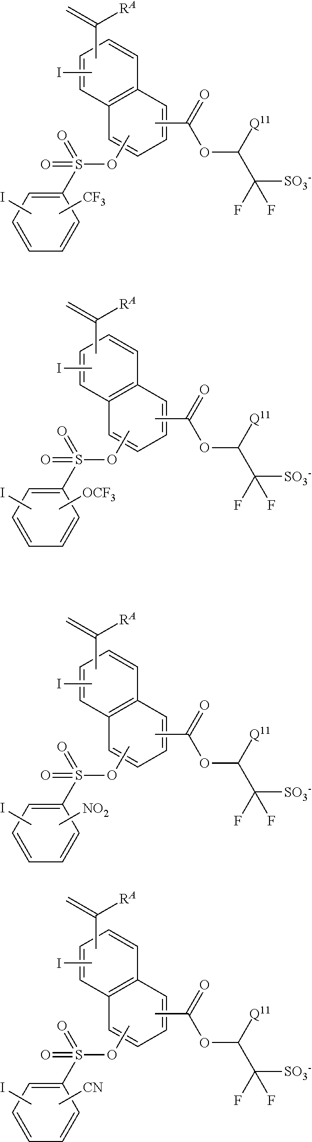

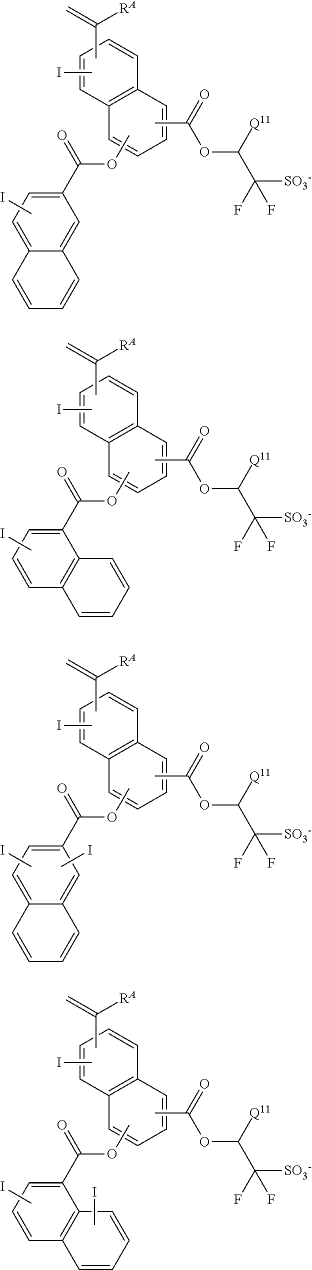

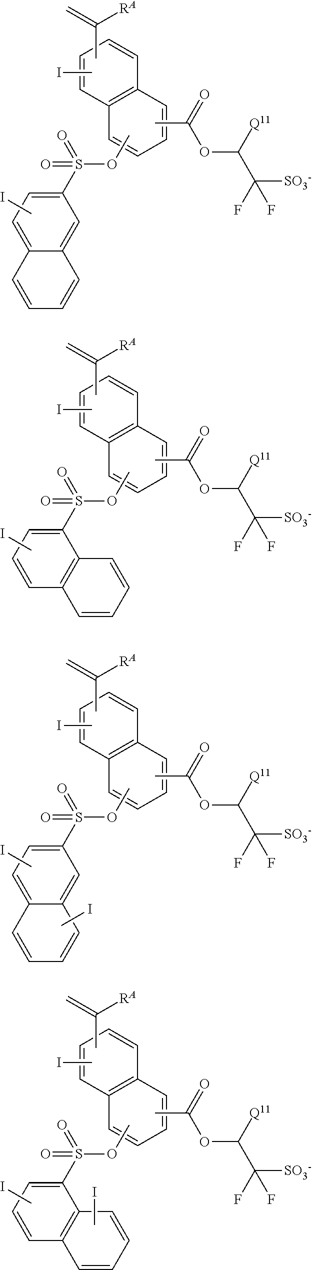

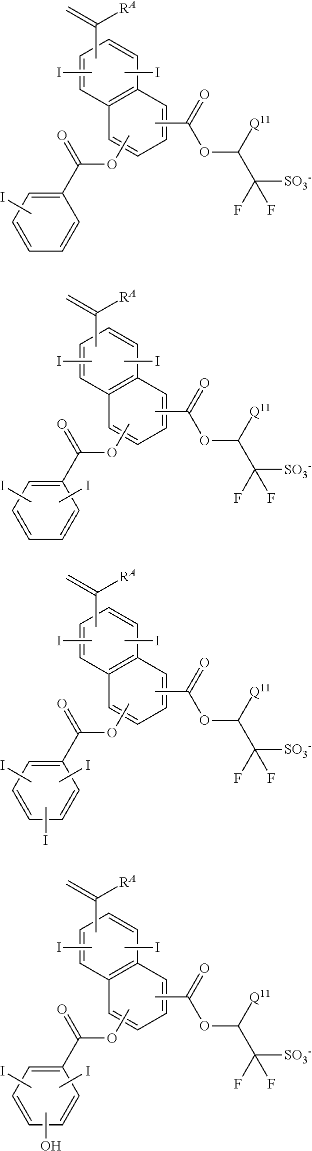

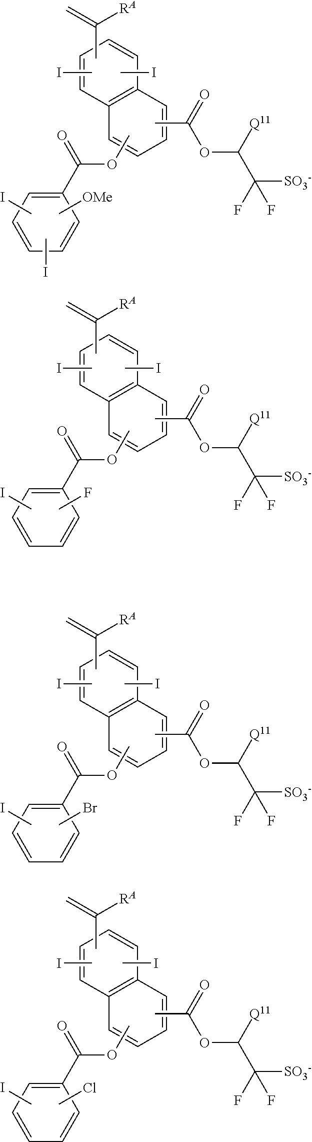

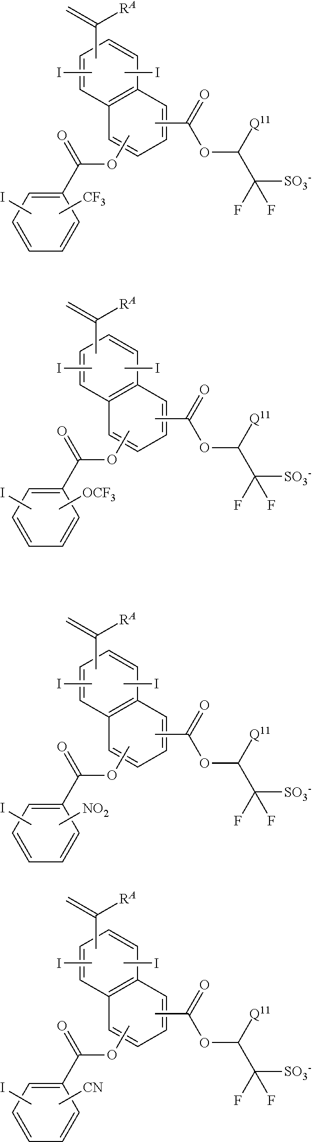

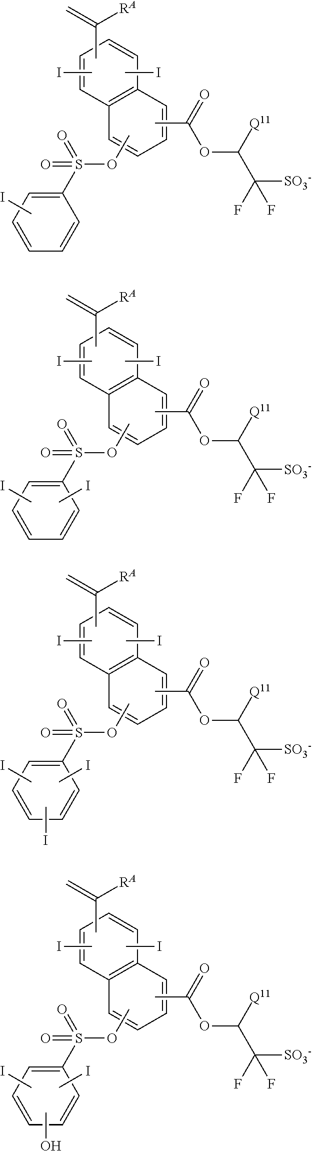

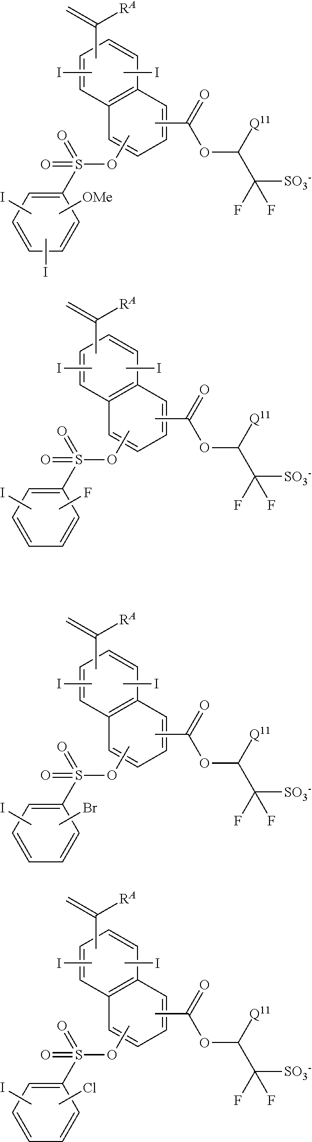

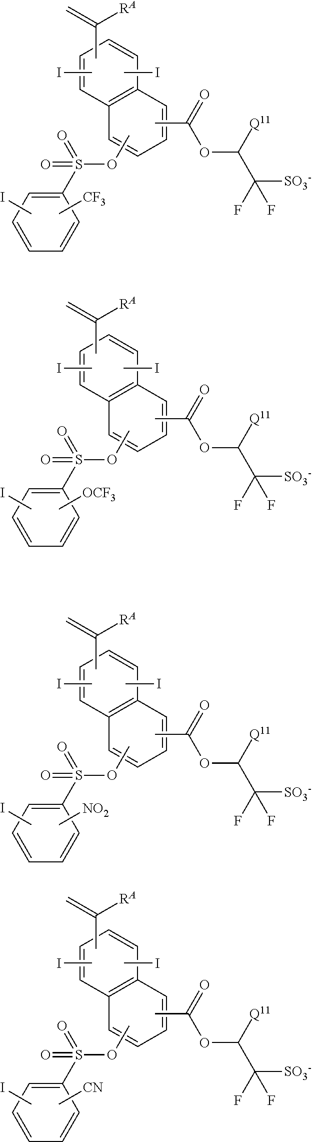

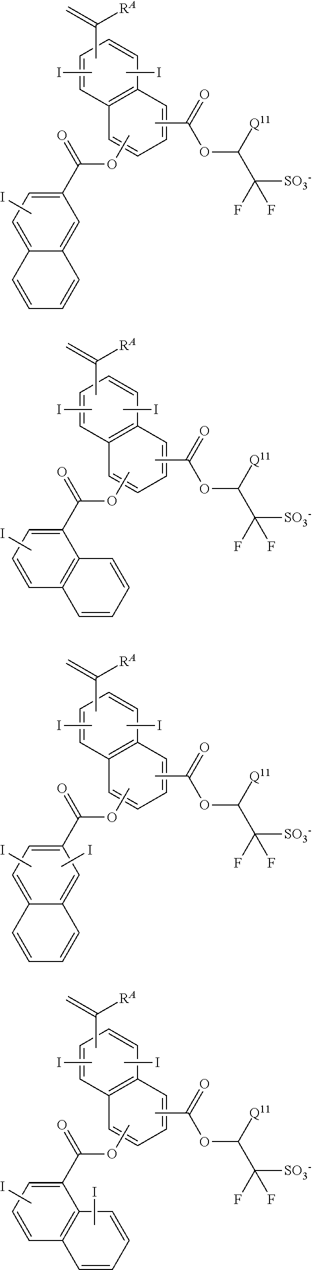

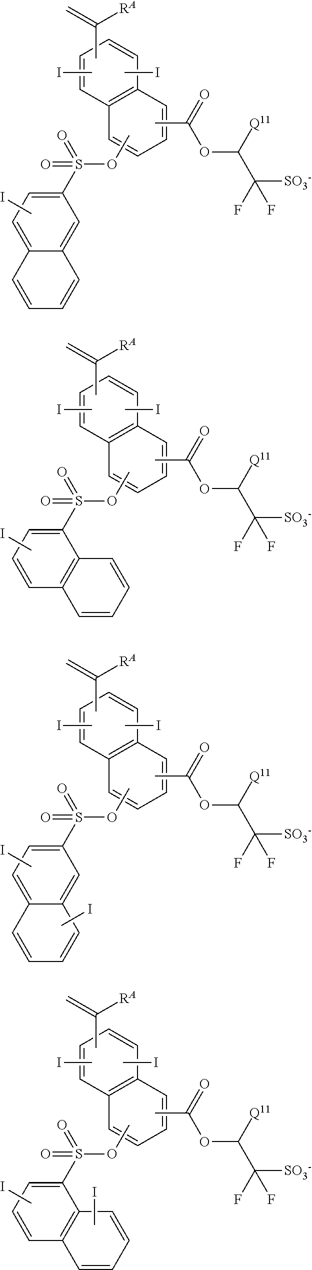

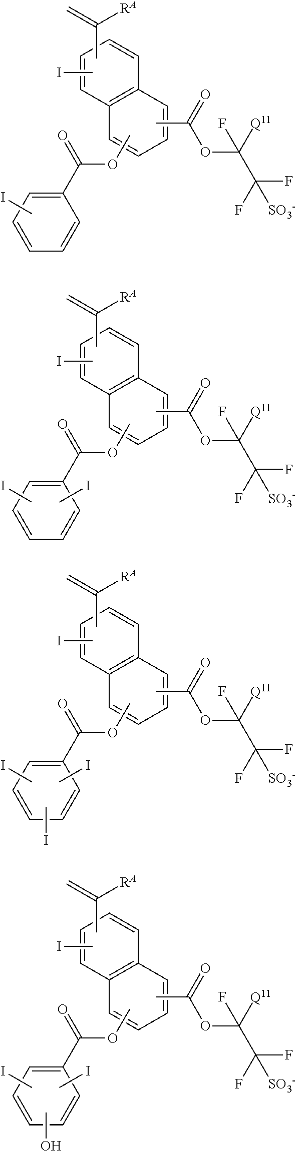

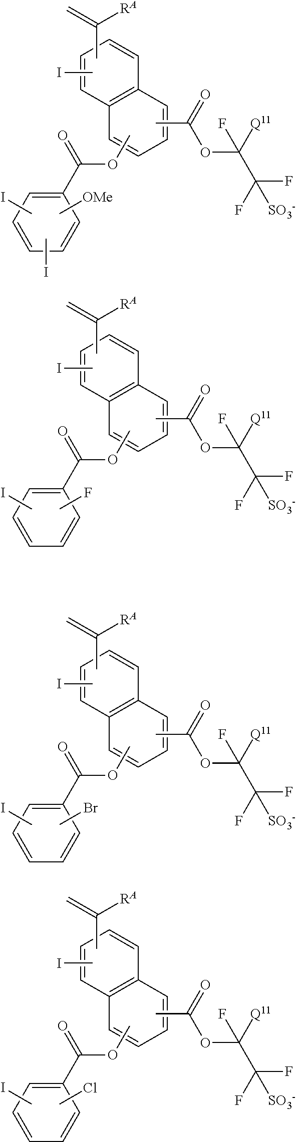

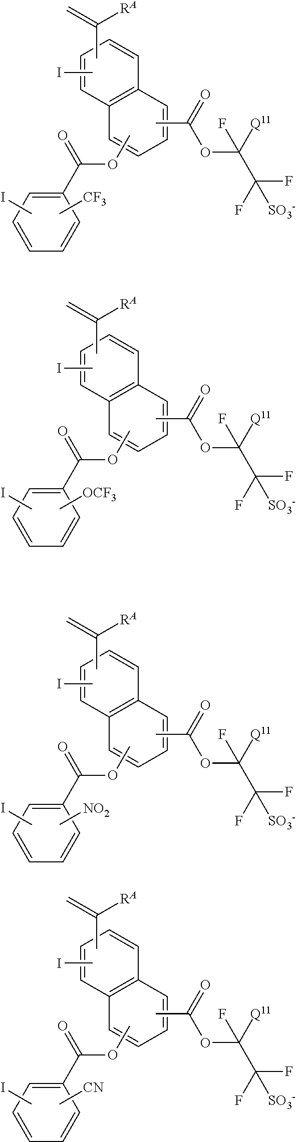

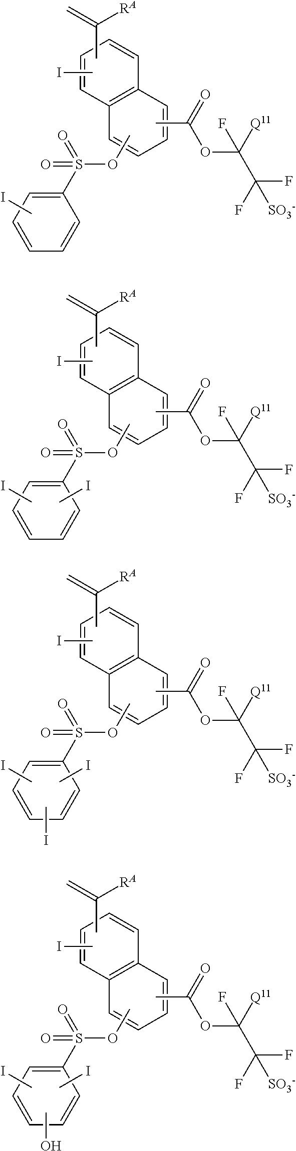

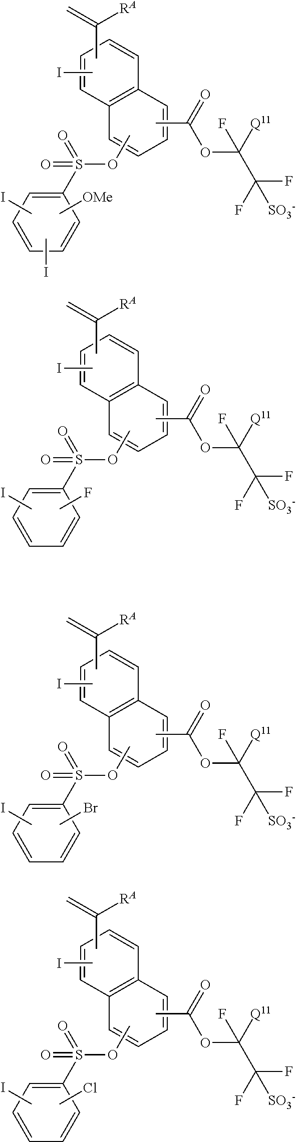

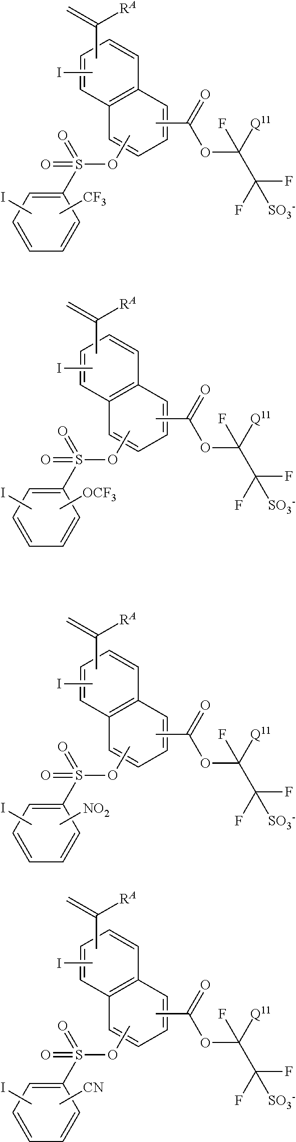

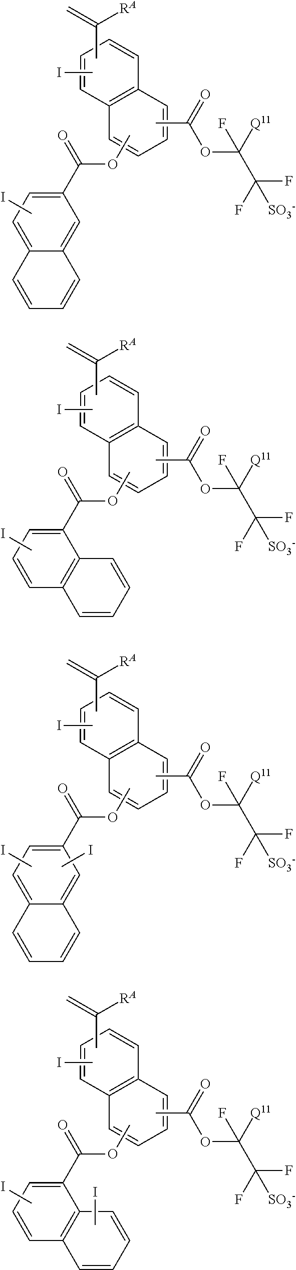

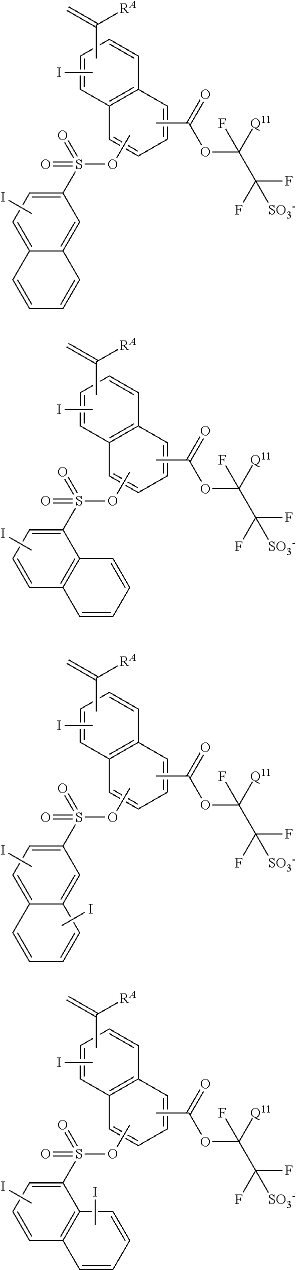

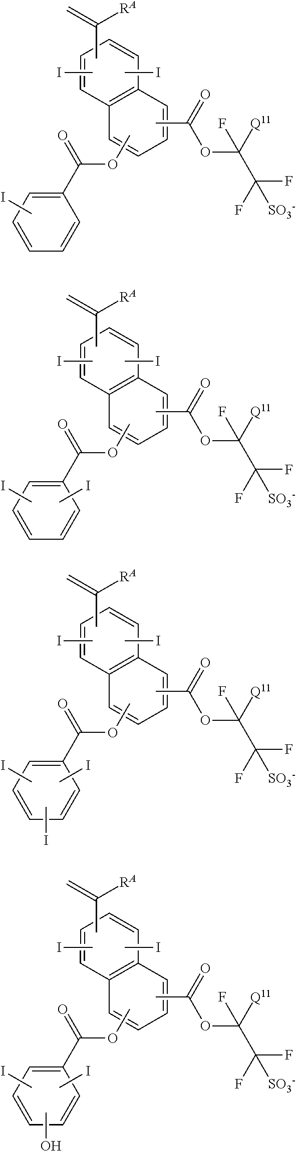

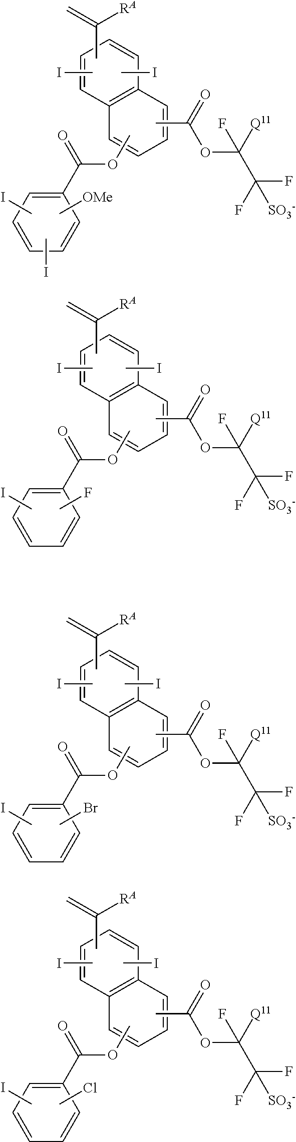

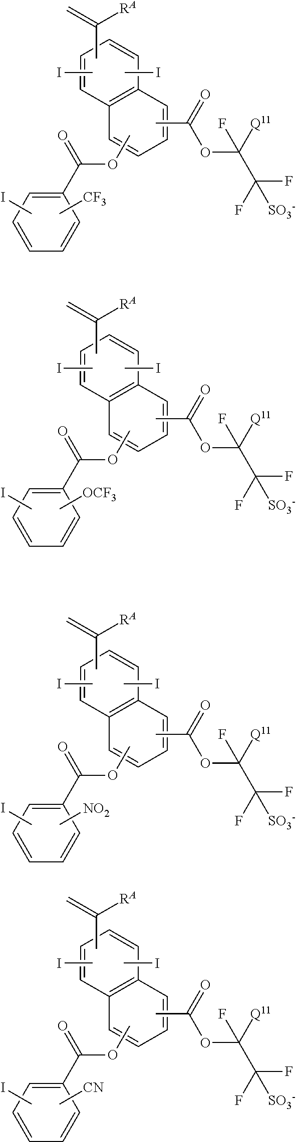

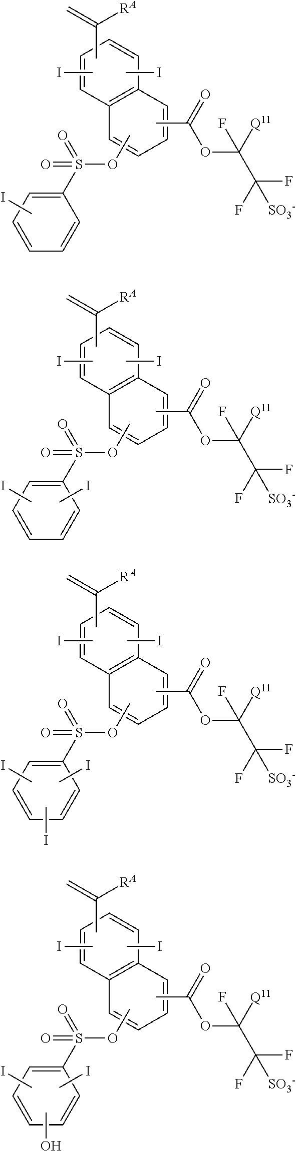

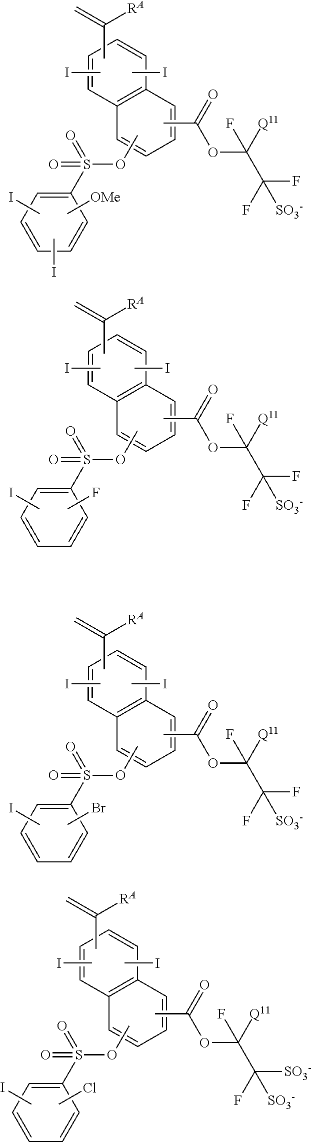

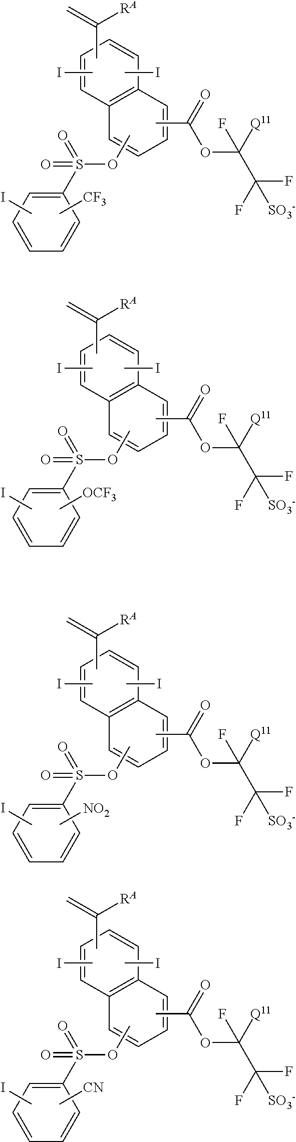

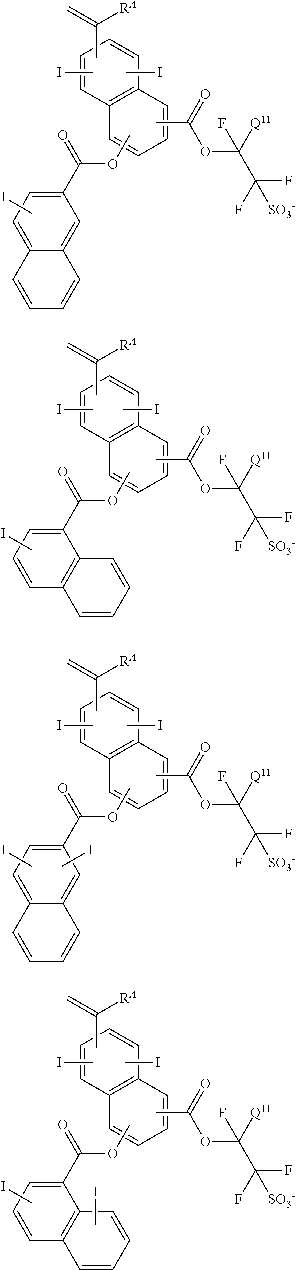

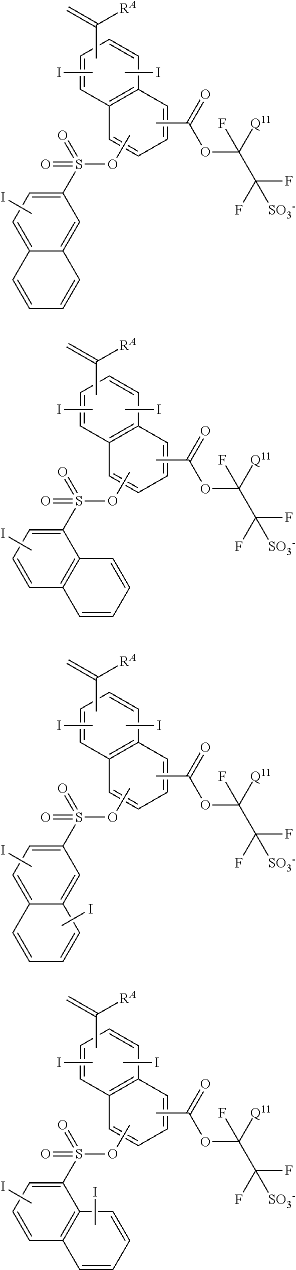

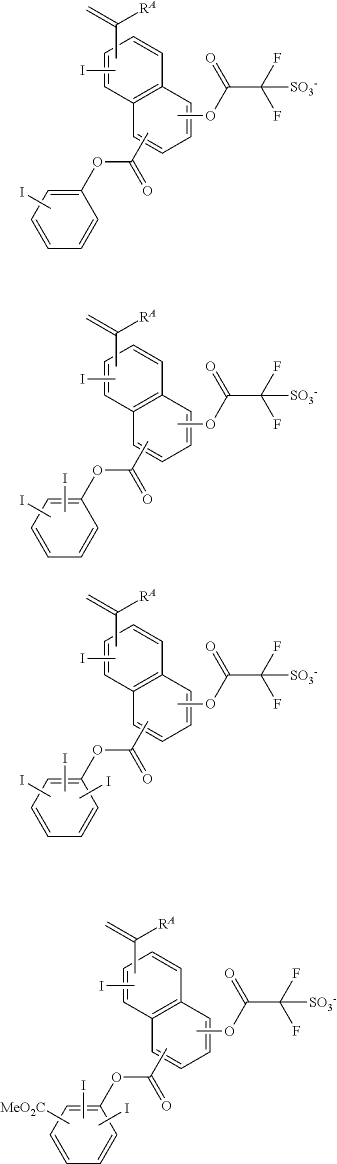

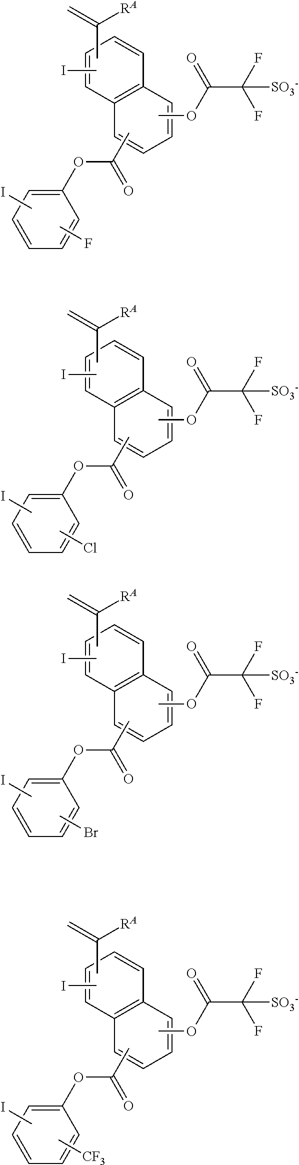

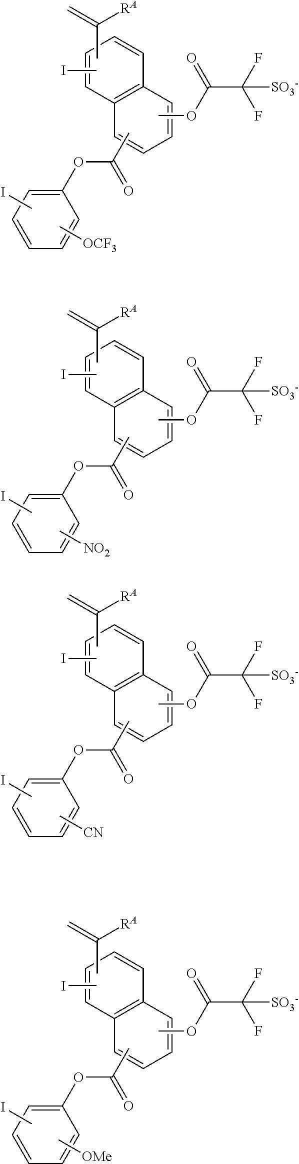

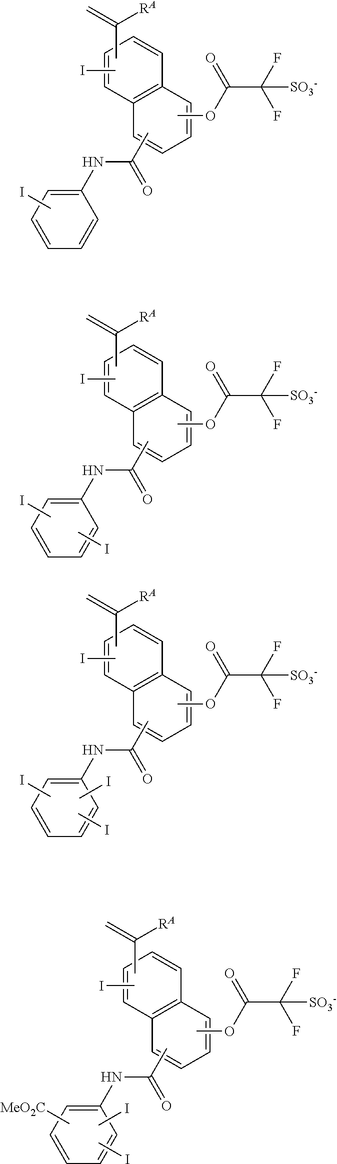

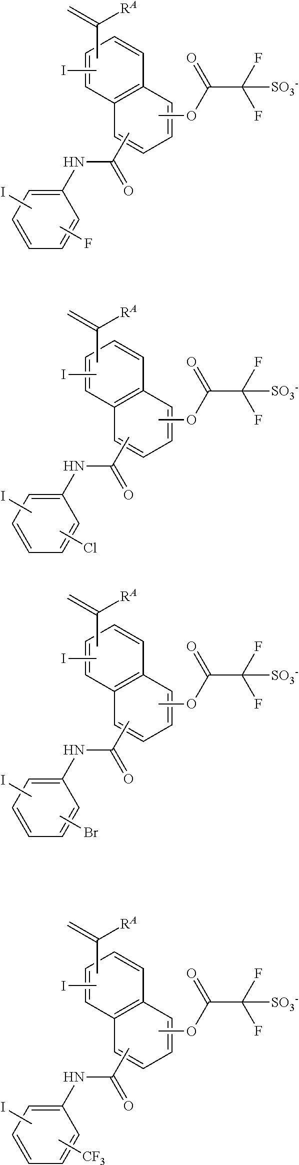

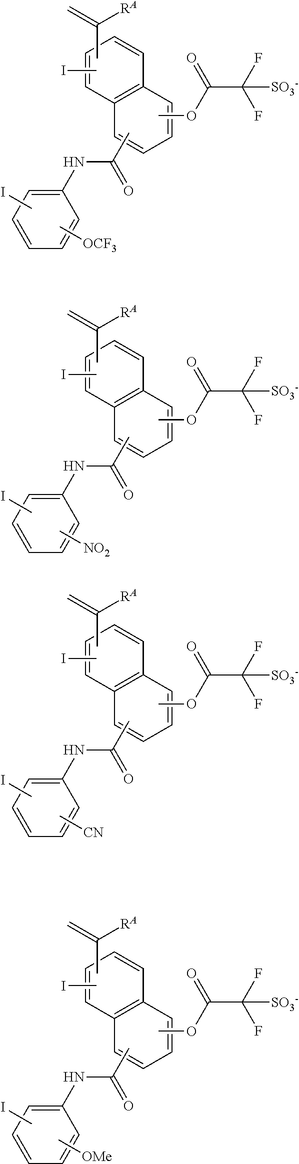

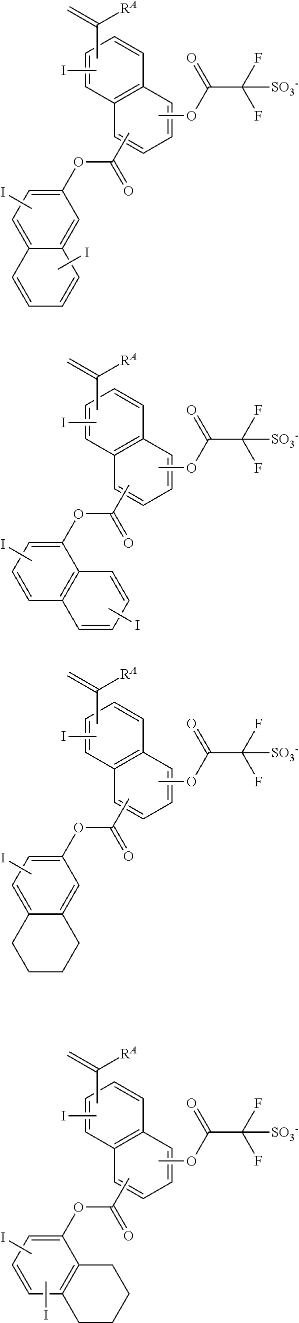

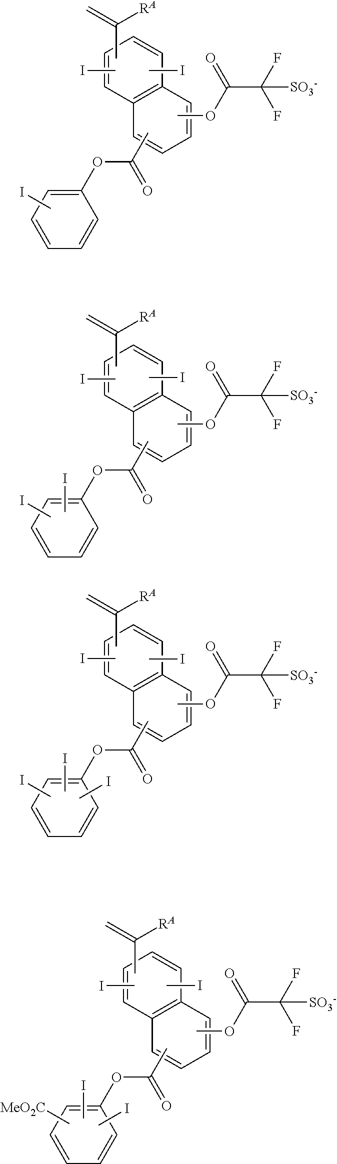

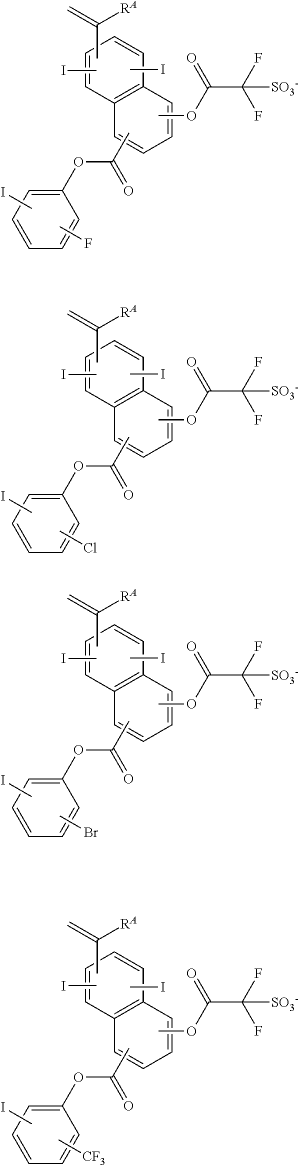

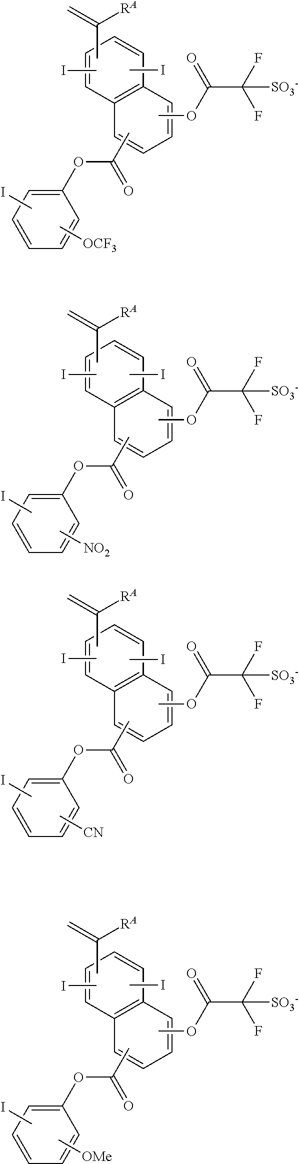

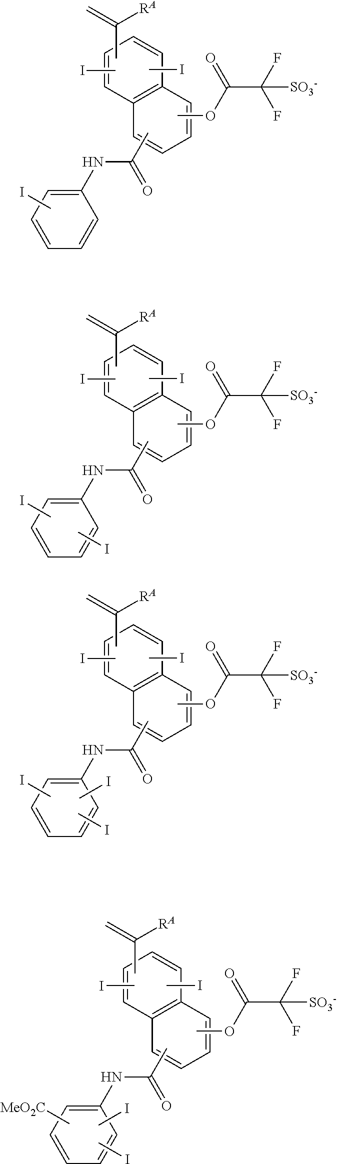

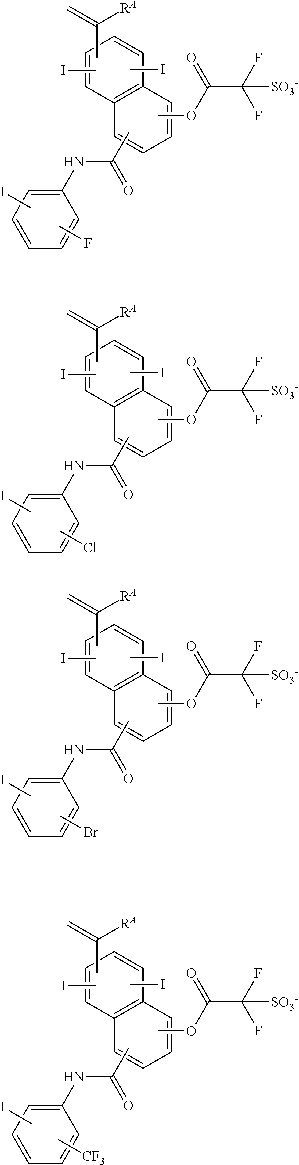

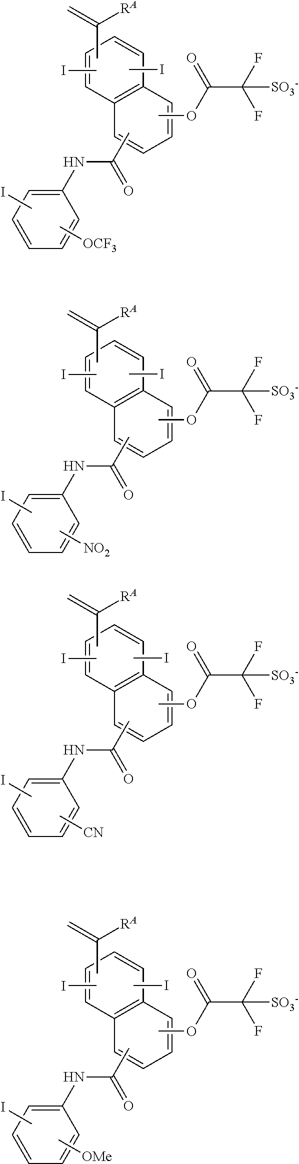

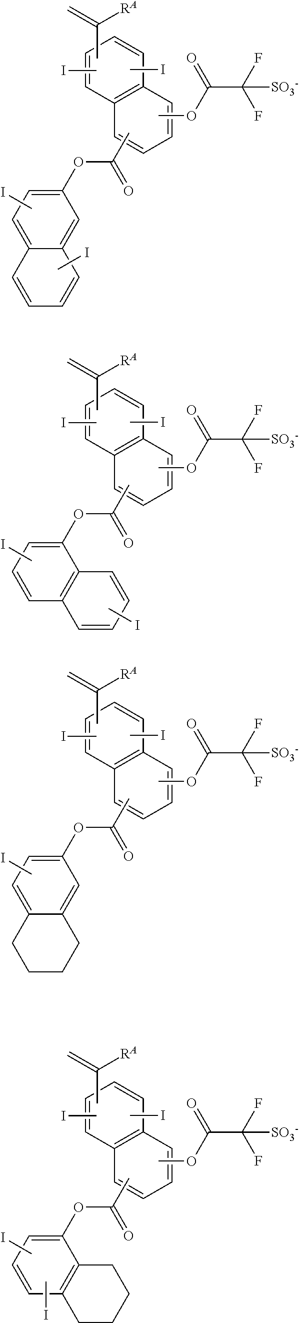

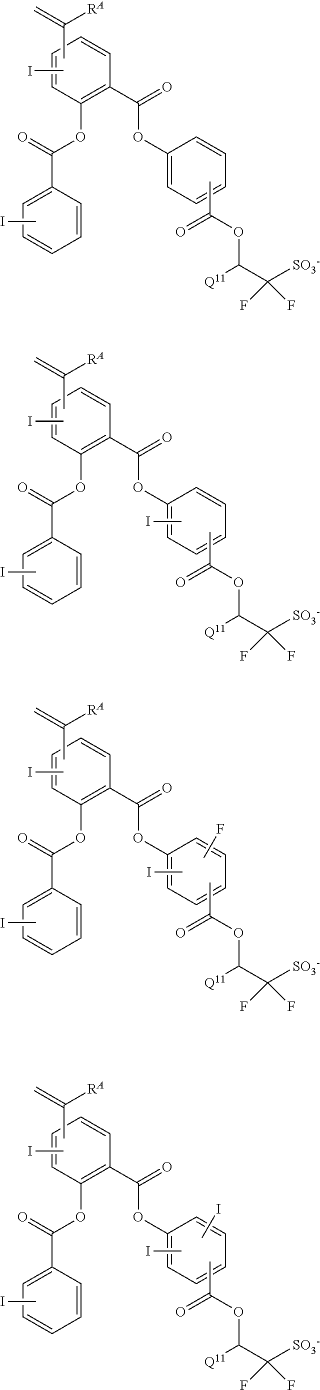

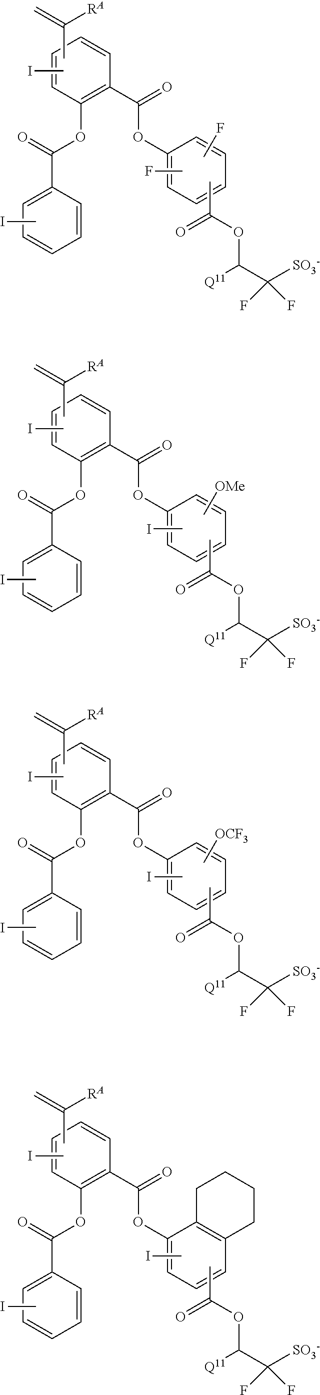

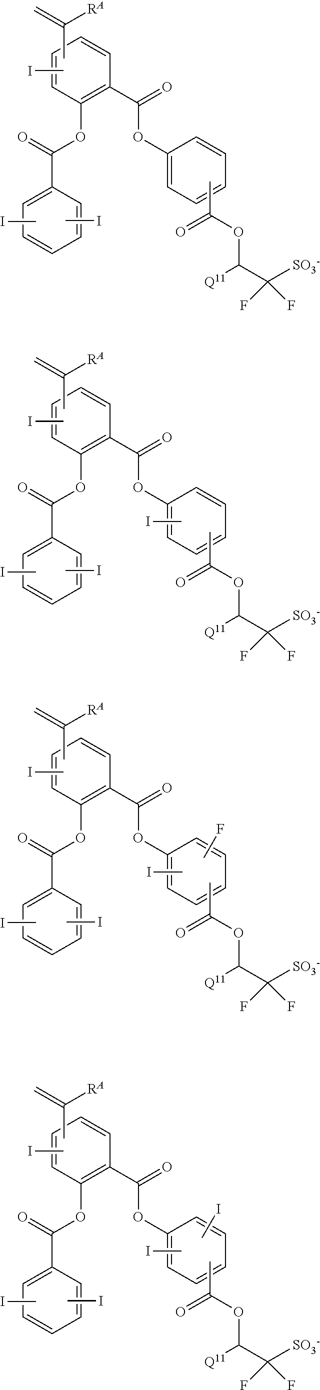

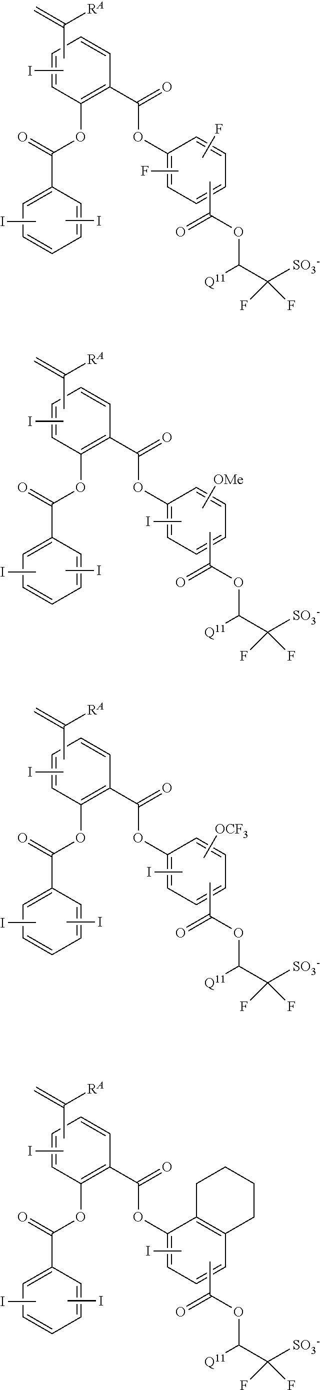

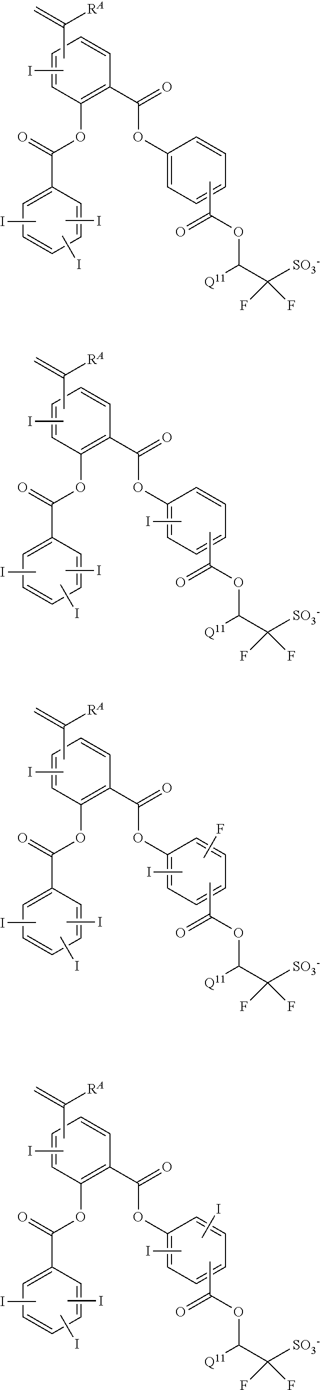

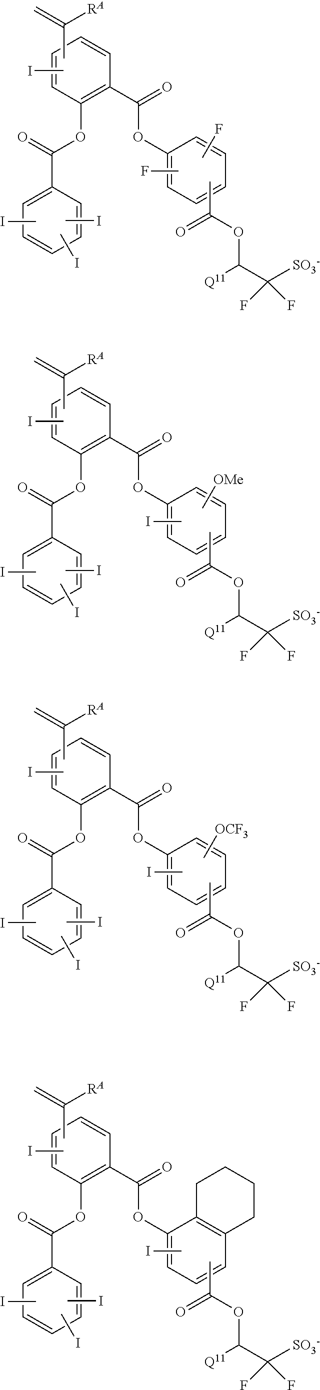

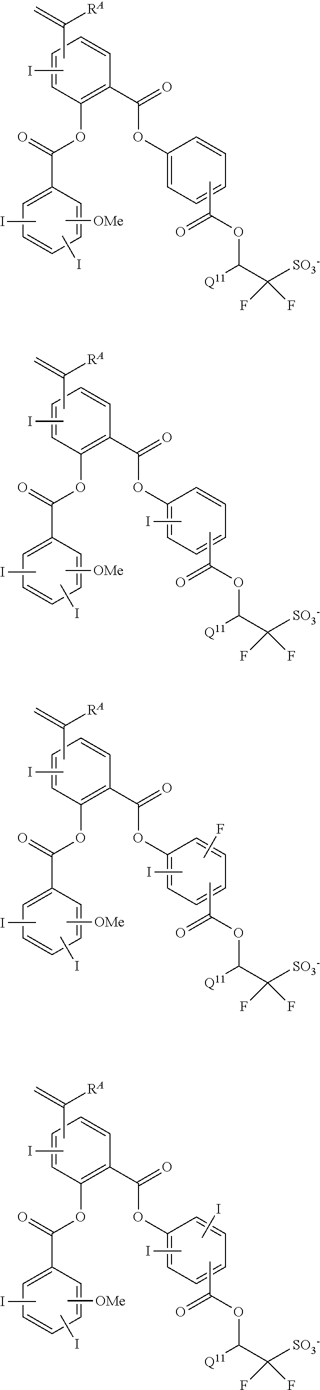

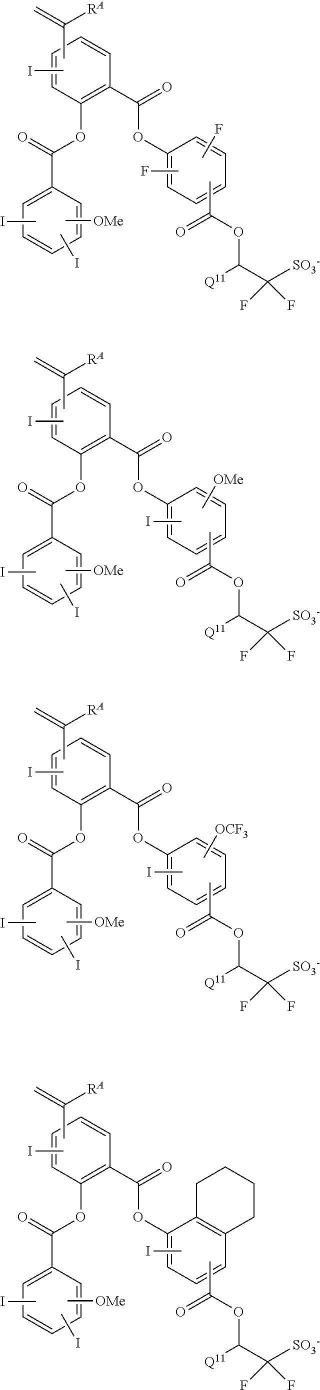

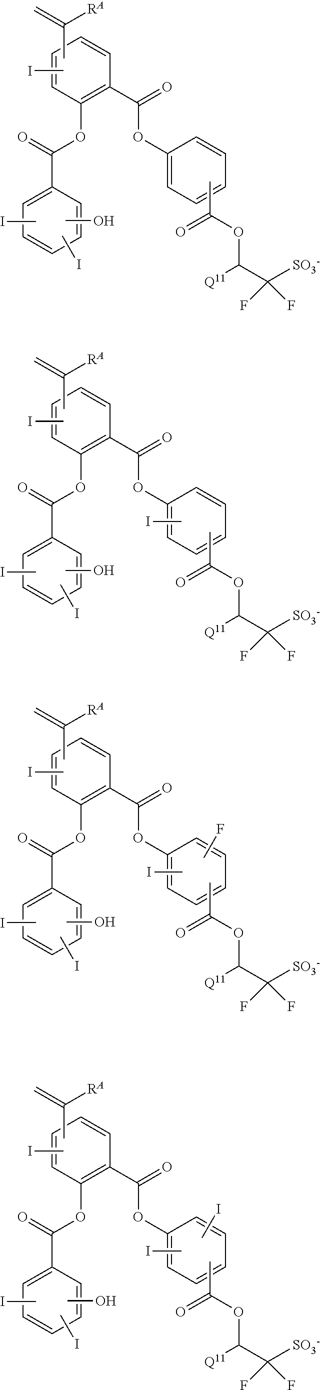

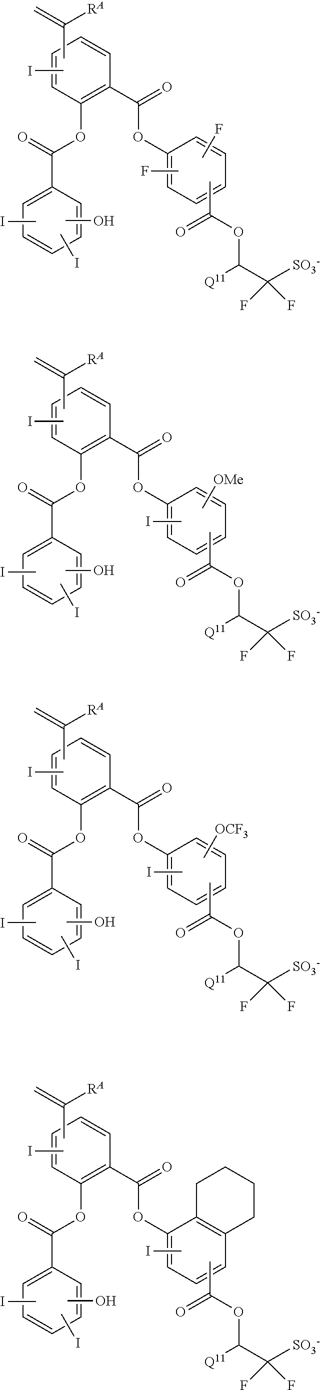

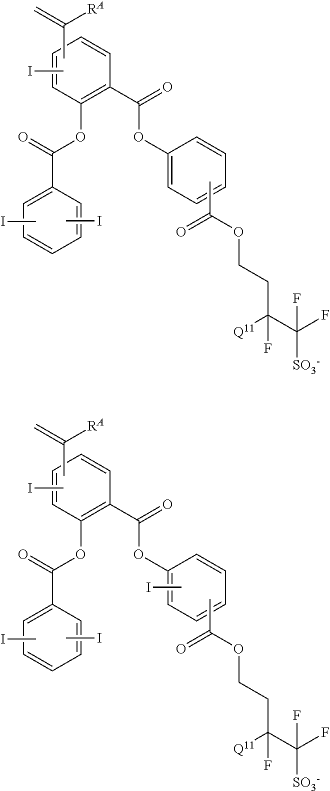

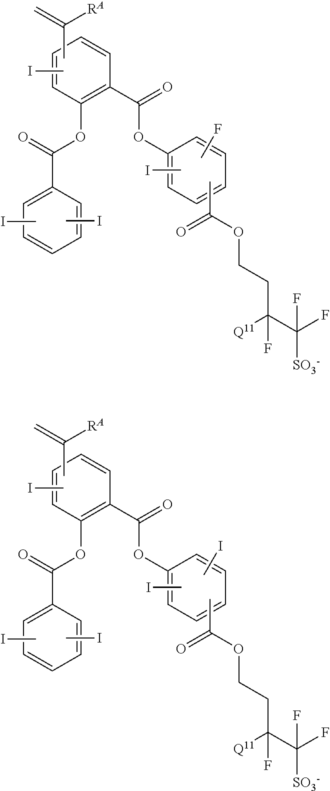

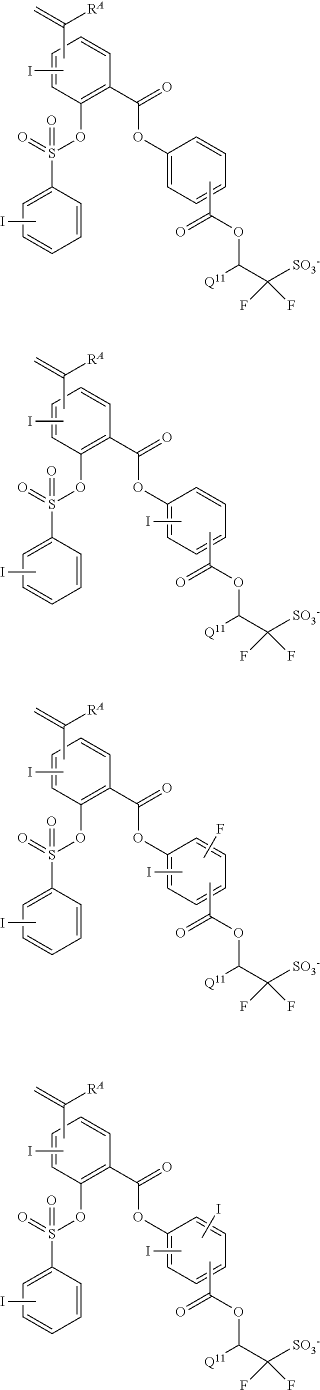

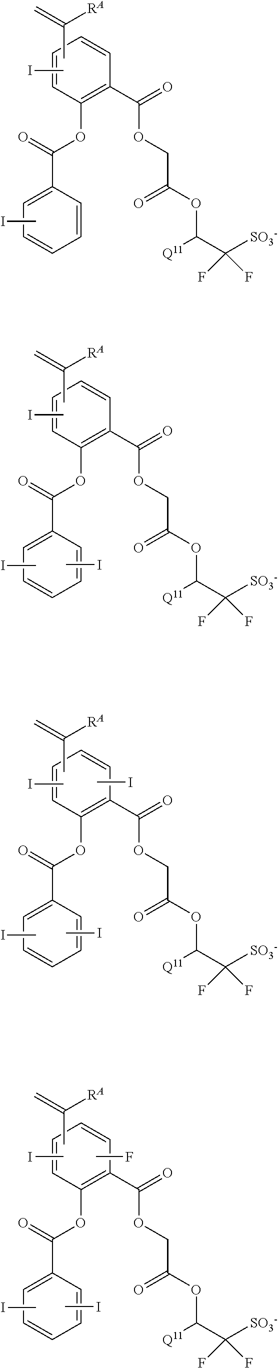

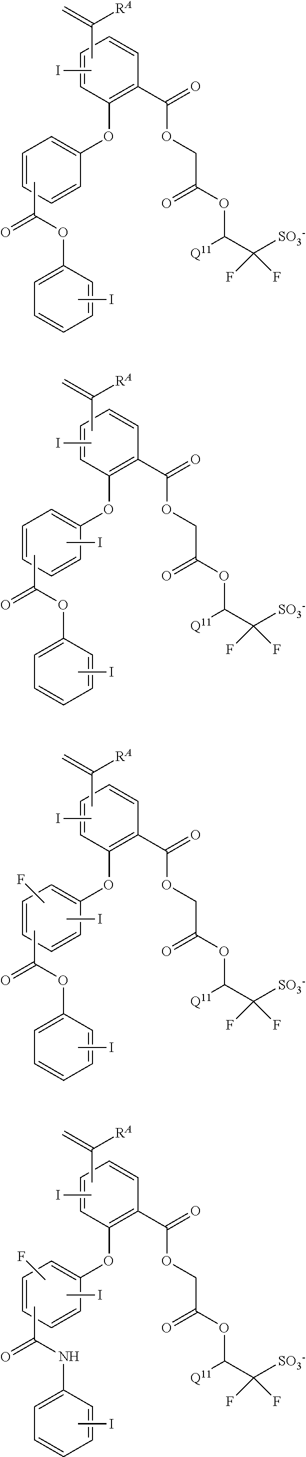

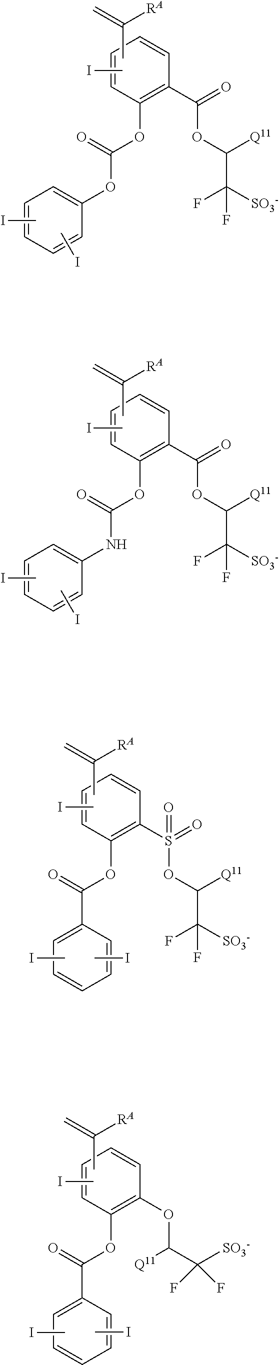

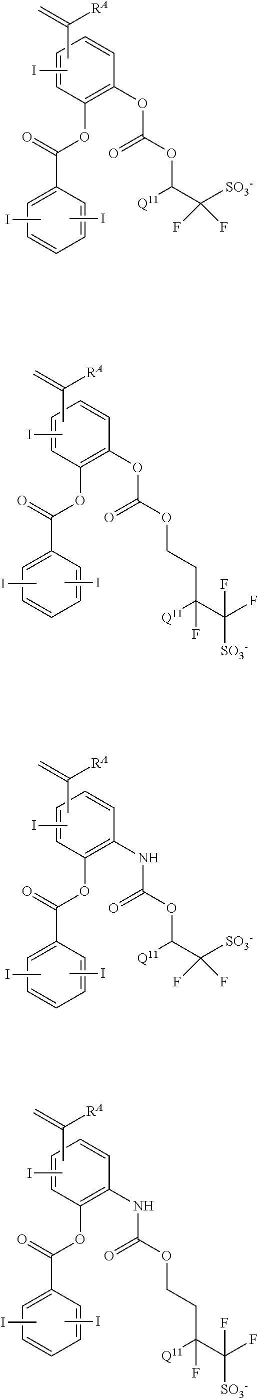

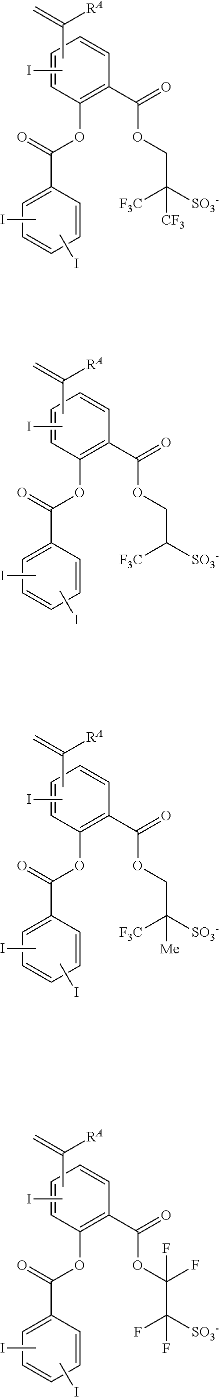

Specific examples of the sulfonium cation of the repeating unit-d include, but are not limited, those exemplified as the sulfonium cation of the sulfonium salt type monomer represented by the general formula (a), those described in paragraphs [0102] to [0125] of JP2024-003744A, those described in paragraphs [0044] to [0049] of W02024/128017A1, and those described in paragraphs [0035] to [0046] of JP7491173B2.

Furthermore, as the sulfonium cation of the repeating unit-d, the sulfonium cation represented by the following general formula (d3) is also preferable.

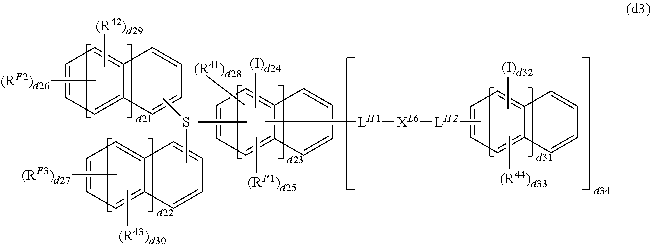

In the general formula (d3), d21 is 0 or 1. When d21 is 0, the structure is a benzene ring, and when d21 is 1, the structure is a naphthalene ring; however, from the viewpoint of solvent solubility, d21 is preferably 0, giving a benzene ring. d22 is 0 or 1. When d22 is 0, the structure is a benzene ring, and when d22 is 1, the structure is a naphthalene ring, but from the viewpoint of solvent solubility, d21 is preferable 0, giving a benzene ring. d23 is 0 or 1. When d23 is 0, the structure is a benzene ring, and when d23 is 1, the structure is a naphthalene ring; however, from the viewpoint of solvent solubility, d23 is preferably 0, giving a benzene ring.

In the general formula (d3), d24 is an integer from 0 to 4. The larger the number of iodine atoms in the anion structure, the higher the absorption especially for EUV, but since there is a concern that solvent solubility will be poor and precipitation will occur in the resist composition, d24 is preferably 0 to 3, and more preferably 0, 1, or 2.

In the general formula (d3), d25 is an integer from 0 to 4. From the viewpoint of raw material procurement, d25 is preferably 0 to 3, and more preferably 0, 1 or 2. d26 is an integer from 0 to 6. From the viewpoint of raw material procurement, d26 is preferably 0 to 3, and more preferably 0, 1 or 2. d27 is an integer from 0 to 6. From the viewpoint of raw material procurement, d27 is preferably 0 to 3, and more preferably 0, 1 or 2.

In the general formula (d3), d28 is 0, 1 or 2. From the viewpoint of raw material procurement, d28 is preferably 0 or 1. d29 is 0, 1 or 2. From the viewpoint of raw material procurement, d29 is preferably 0 or 1. d30 is 0, 1 or 2. From the viewpoint of raw material procurement, d30 is preferably 0 or 1.

In the general formula (d3), d31 is 0 or 1. When d31 is 0, the structure is a benzene ring, and when d31 is 1, the structure is a naphthalene ring; however, from the viewpoint of solvent solubility, d31 is preferably 0, giving a benzene ring.

In the general formula (d3), d32 is an integer from 0 to 4. The larger the number of iodine atoms in the anion structure, the higher the absorption especially for EUV, but since there is a concern that solvent solubility will be poor and precipitation will occur in the resist composition, d32 is preferably 0 to 3, and more preferably 0, 1 or 2.

In the general formula (d3), d33 is 0, 1 or 2. From the viewpoint of raw material procurement, d33 is preferably 0 or 1. d34 is 0, 1 or 2. From the viewpoint of synthesis, d34 is preferably 0 or 1.

However, when d21 is 0, 0≤d26+d29≤4, and when d21 is 1, 0≤d26+d29≤6. When d22 is 0, 0≤d27+d30≤4, and when d22 is 1, 0≤d27+d30≤6. When d23 is 0, 1≤d24+d25+d28+d34≤4, and when d23 is 1, 1≤d24+d25+d28+d34≤6. When d31 is 0, 0≤d32+d33≤4, and when d31 is 1, 0≤d32+d33≤6. Also, 1≤d24+d32.

In the general formula (d3), R^{F1} to R^{F3} are each independently a fluorine atom, a fluorinated saturated hydrocarbyl group having 1 to 6 carbon atoms, a fluorinated saturated hydrocarbyloxy group having 1 to 6 carbon atoms, or a fluorinated saturated hydrocarbylthio group having 1 to 6 carbon atoms. Among these, a trifluoromethyl group, a trifluoromethoxy group, or a trifluorothiomethoxy group is preferable. When d25 is 2 or more, each R^{F1} may be the same or they may be different from each other, when d26 is 2 or more, each R^{F2} may be the same or different, and when d27 is 2 or more, each R^{F3} may be the same or different from each other.

In the general formula (d3), R⁴¹ to R⁴⁴ is a halogen atom other than an iodine atom and a fluorine atom, a nitro group, a cyano group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom. The hydrocarbyl group and the hydrocarbyl moiety of the hydrocarbyloxy group and the hydrocarbylthio group may be saturated or unsaturated, and may be linear, branched, or cyclic. Specific examples of these include, but are not limited to, ones similar to those exemplified as the hydrocarbyl group represented by R¹ in the description of the general formula (a). Furthermore, some or all of the hydrogen atoms of the hydrocarbyl group and the hydrocarbyl moiety of the hydrocarbyloxy group and the hydrocarbylthio group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

Also, when d28 is 2, two R⁴¹ may be the same or they may be different from each other, and two R⁴¹ may be bonded to each other to form a ring together with the carbon atom to which they are bonded, and when d29 is 2, two R⁴² may be the same or they may be different from each other, and two R⁴² may be bonded to each other to form a ring together with the carbon atom to which they are bonded, and when d30 is 2, two R⁴³ may be the same or different from each other, and two R⁴³ may be bonded to each other to form a ring together with the carbon atom to which they are bonded, and when d33 is 2, two R⁴⁴ may be the same or they may be different from each other, and two R⁴⁴ may be bonded to each other to form a ring together with the carbon atom to which they are bonded. Specific examples of the ring formed in this case include a cyclopropane ring, a cyclobutane ring, a cyclopentane ring, a cyclohexane ring, a norbornane ring, an adamantane ring, etc. Furthermore, some or all of the hydrogen atoms of the ring may be substituted with a group containing a heteroatom such as an oxygen atom, a sulfur atom, a nitrogen atom, or a halogen atom, and some of the —CH₂— of the ring may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

In addition, the aromatic rings directly bonded to S⁺ in the sulfonium cation represented by the general formula (d3) may be bonded to each other to form a ring together with S⁺. In this case, specific examples of the ring structure include those represented by the following formulae.

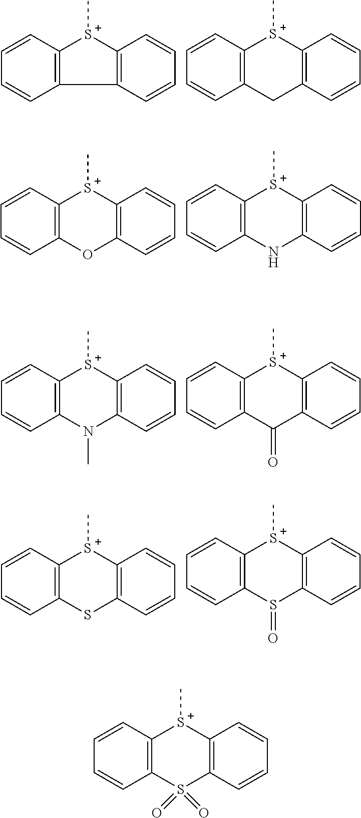

In the formulae, the dashed lines represent bonds.

In the general formula (d3), L^{H1} and L^{H2} are each independently a single bond, an ether bond, an ester bond, an amide bond, a sulfonate ester bond, a sulfonamide bond, a carbonate bond, or a carbamate bond. Among these, L^{H1} is preferably a single bond, an ether bond, an ester bond, or a sulfonate ester bond, and more preferably an ester bond or a sulfonate ester bond. L^{H2} is preferably a single bond, an ether bond, or an ester bond, and more preferably a single bond.

In the general formula (d3), X^{L6} is a single bond or a hydrocarbylene group having 1 to 40 carbon atoms and optionally containing a heteroatom. The hydrocarbylene group may be linear, branched, or cyclic, and specific examples thereof include an alkanediyl group, a cyclic saturated hydrocarbylene group, an arylene group, etc. Specific examples of the heteroatom include an oxygen atom, a nitrogen atom, and a sulfur atom. Specific examples of the hydrocarbylene group having 1 to 40 carbon atoms and optionally containing a heteroatom represented by X^{L6} include X^{L}-0 to X^{L}-58 exemplified as specific examples of the hydrocarbylene group having 1 to 40 carbon atoms and optionally containing a heteroatom represented by X^{L1} and X^{L2} in the description of the general formula (Z). Among these, X^{L}-0 to X^{L}-22, X^{L}-29 to X^{L}-34, and X^{L}-47 to X^{L}-58 are preferable.

The sulfonium cation represented by the general formula (d3) is preferably represented by the following general formula (d3-1).

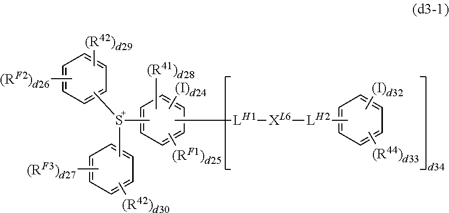

In the formula, d24 to d30, d32 to d34, R^{F1} to R^{F3}, R⁴¹ to R⁴⁴, L^{H1}, L^{H2}, and X^{L6} are as defined above.

The sulfonium cation represented by the general formula (d3-1) is preferably represented by the following general formula (d3-2).

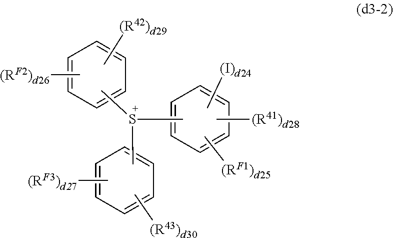

In the formula, d24 to d30, R^{F1} to R^{F3}, and R⁴¹ to R⁴³ are as defined above.

Specific examples of the sulfonium cation represented by the general formula (d3) include, but are not limited to, those shown below. In the following formulae, Me is a methyl group.

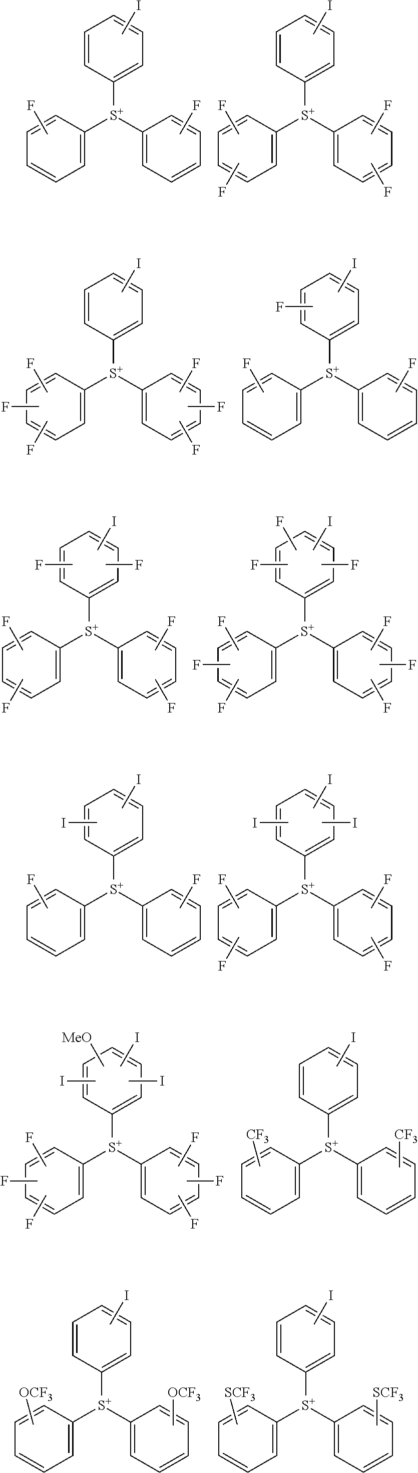

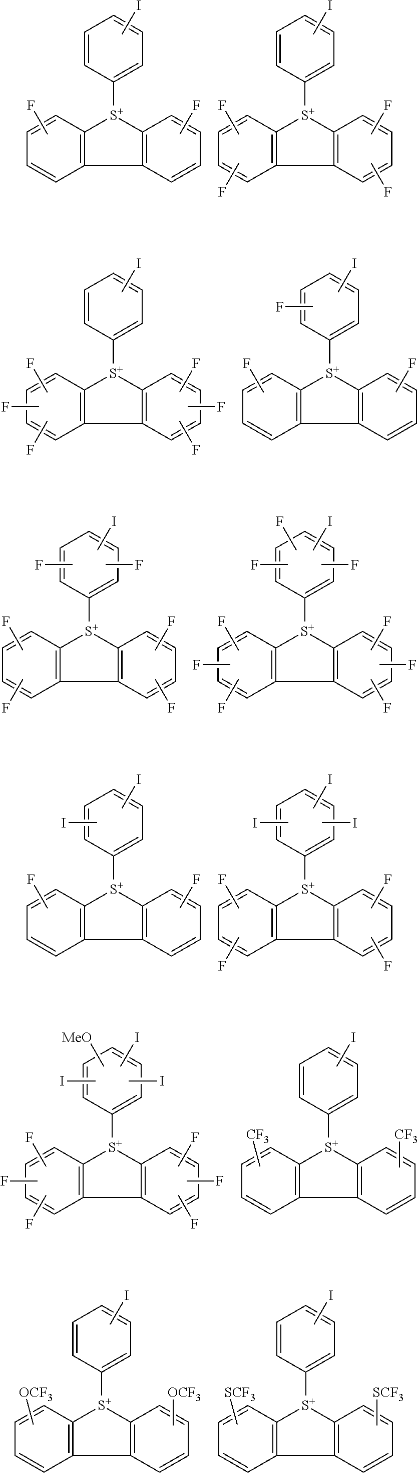

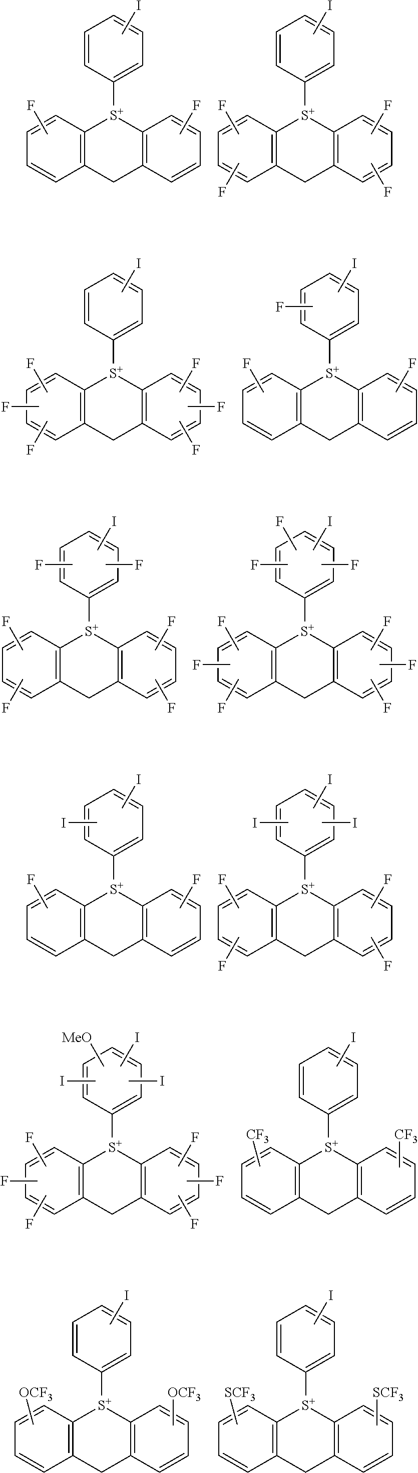

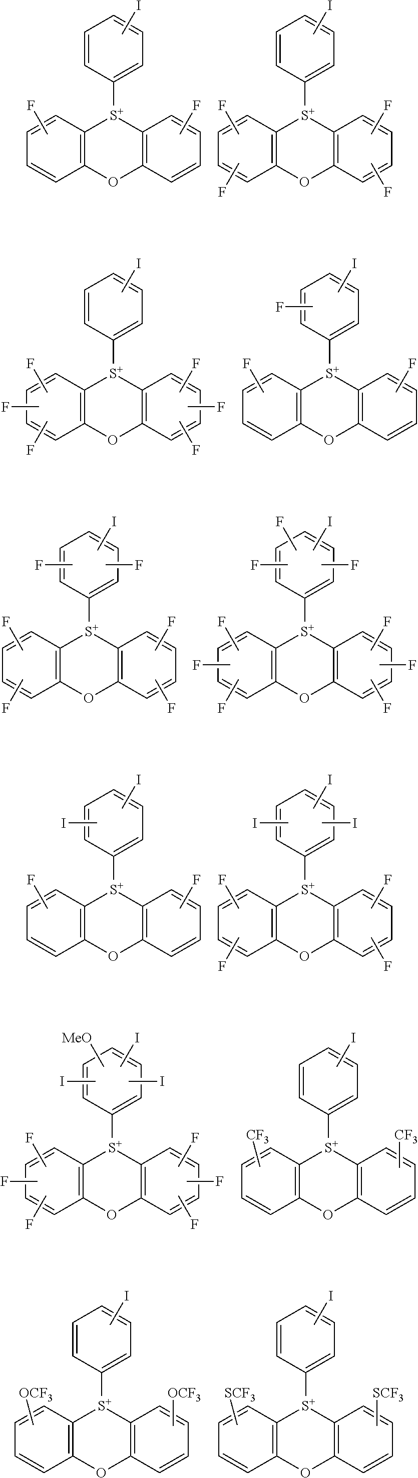

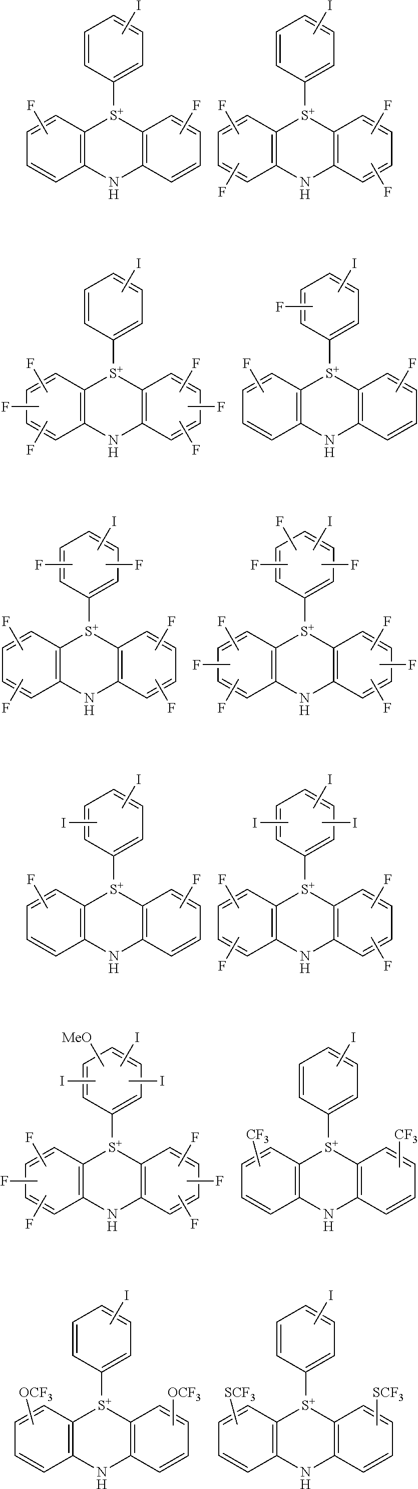

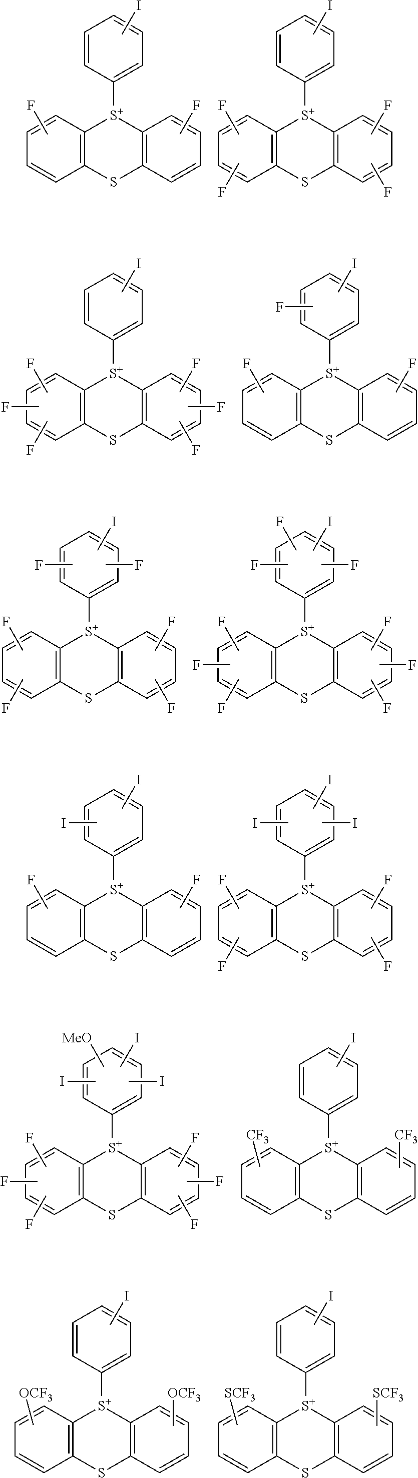

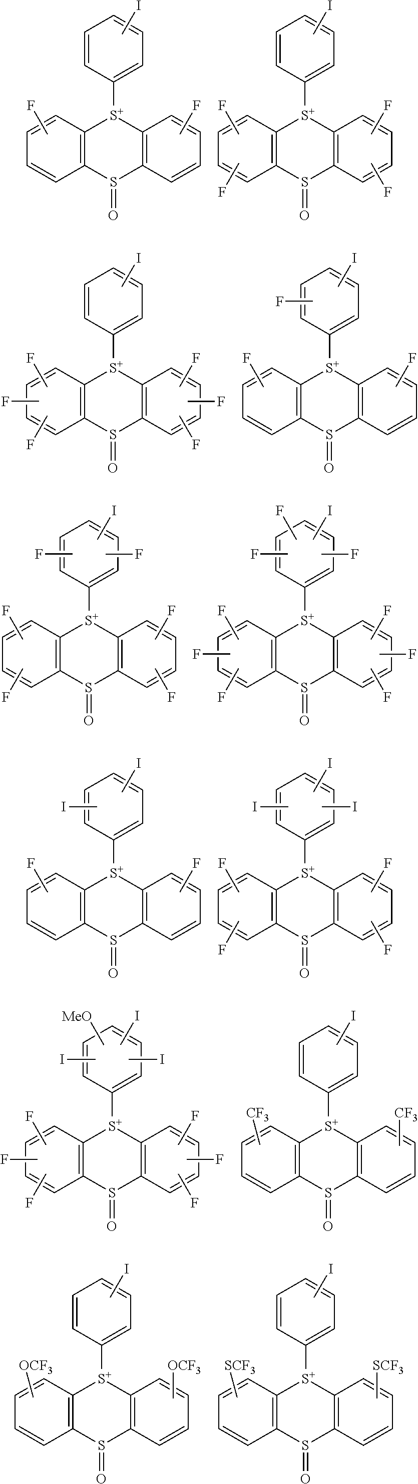

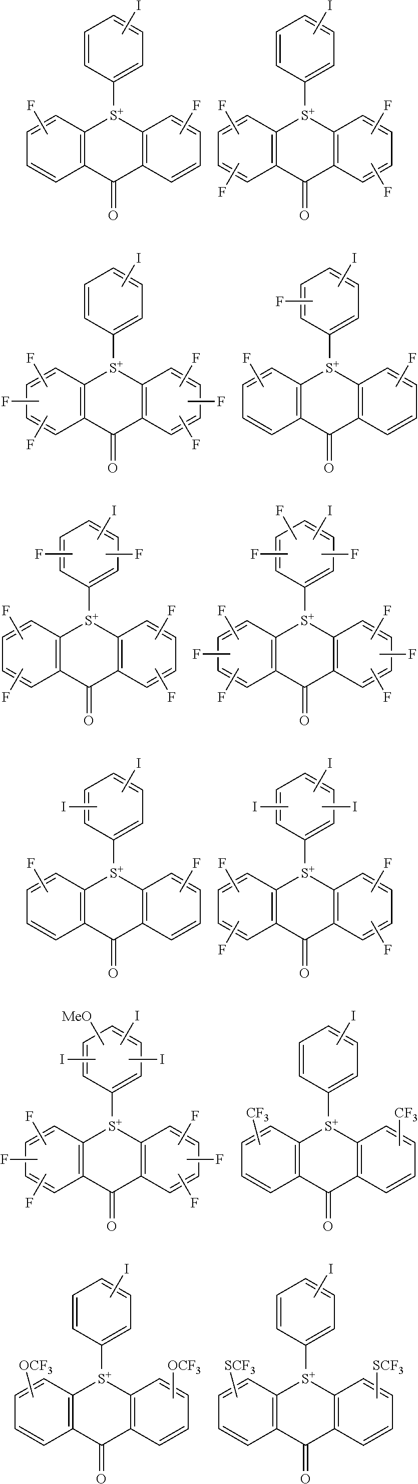

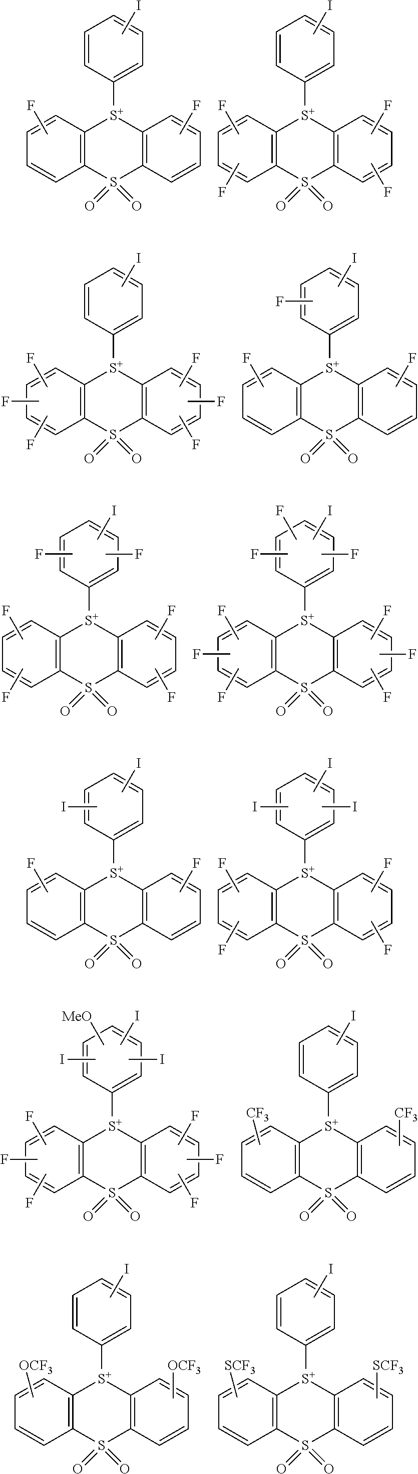

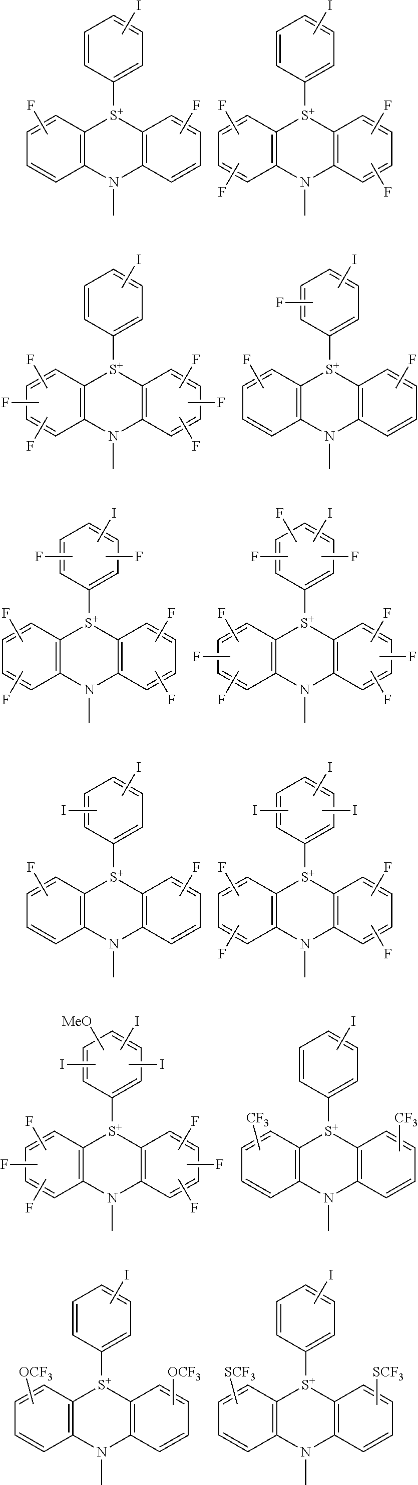

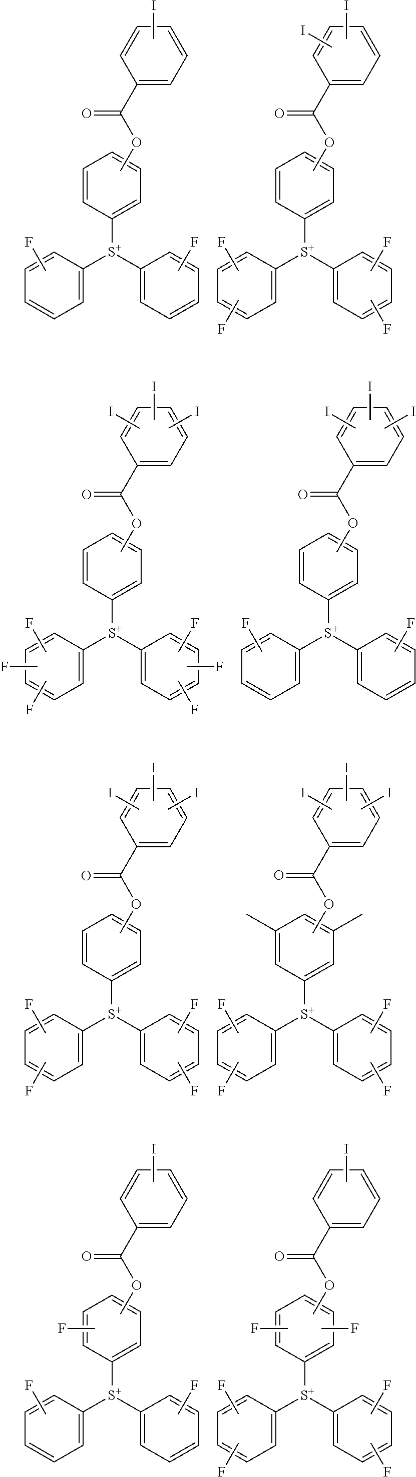

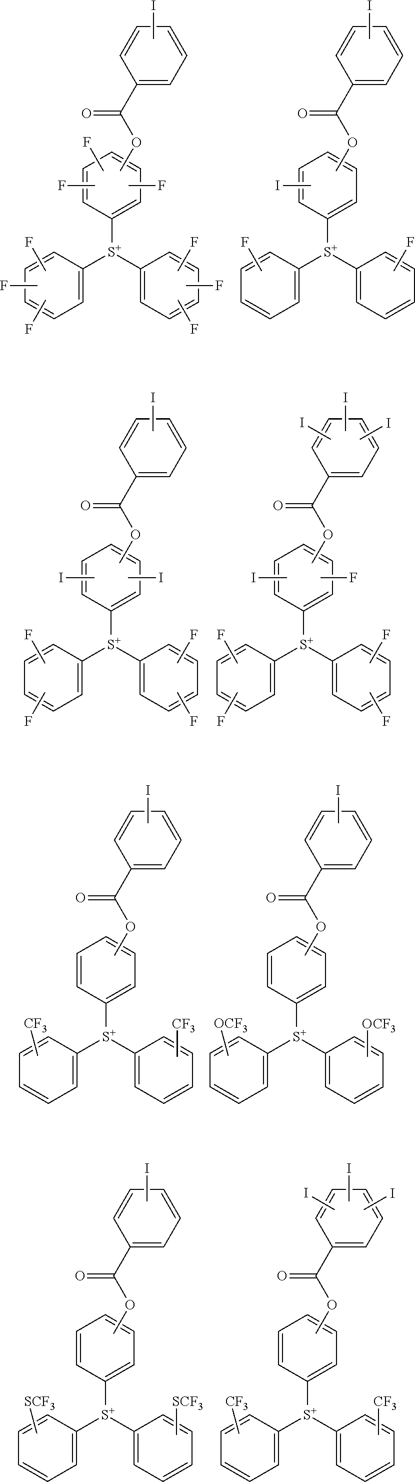

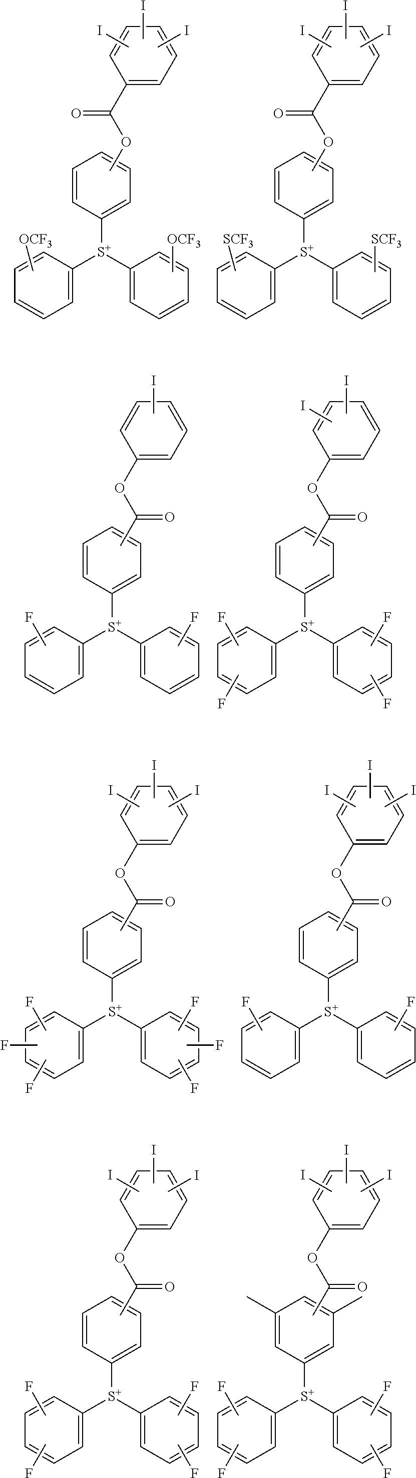

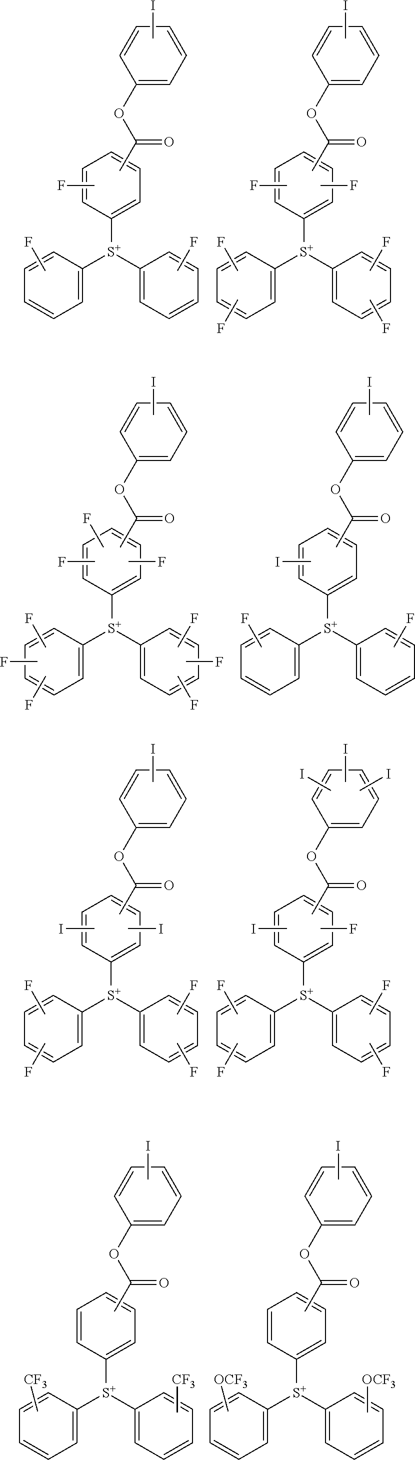

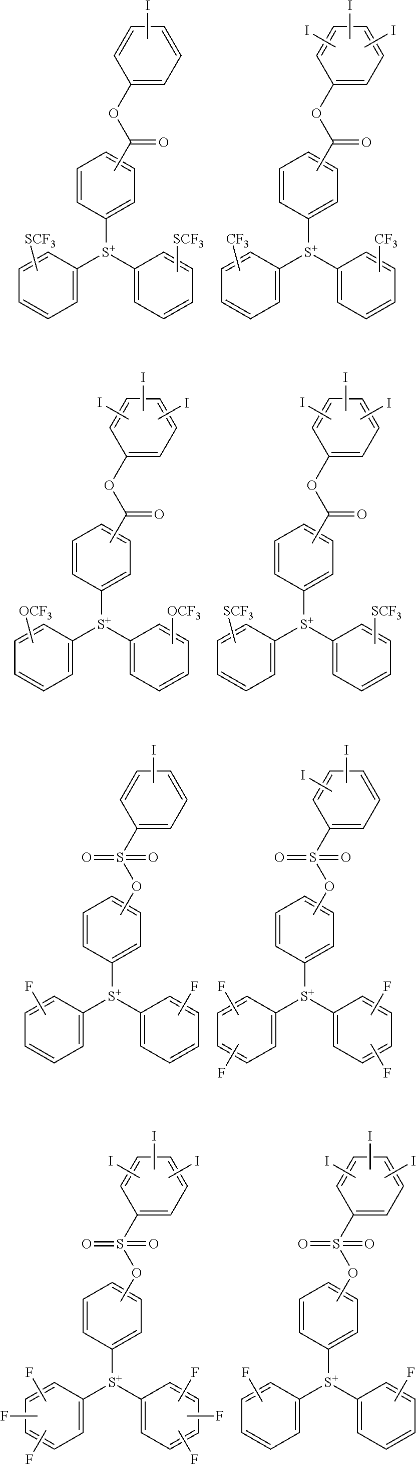

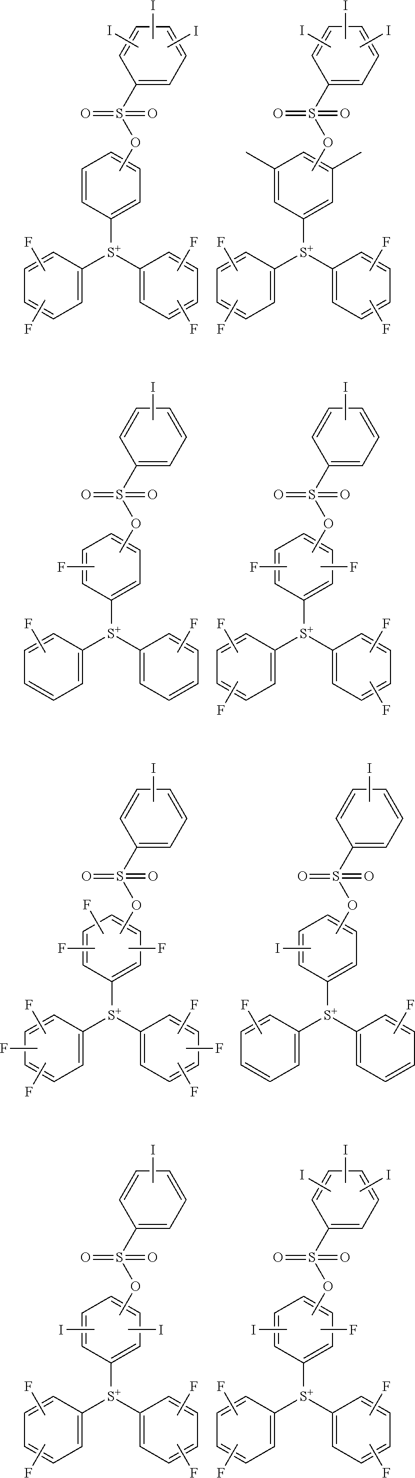

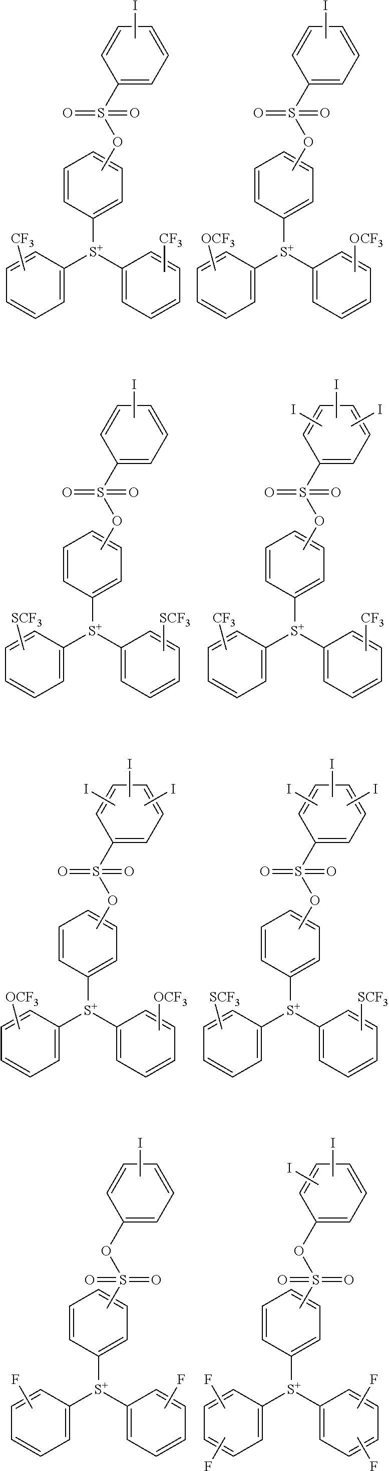

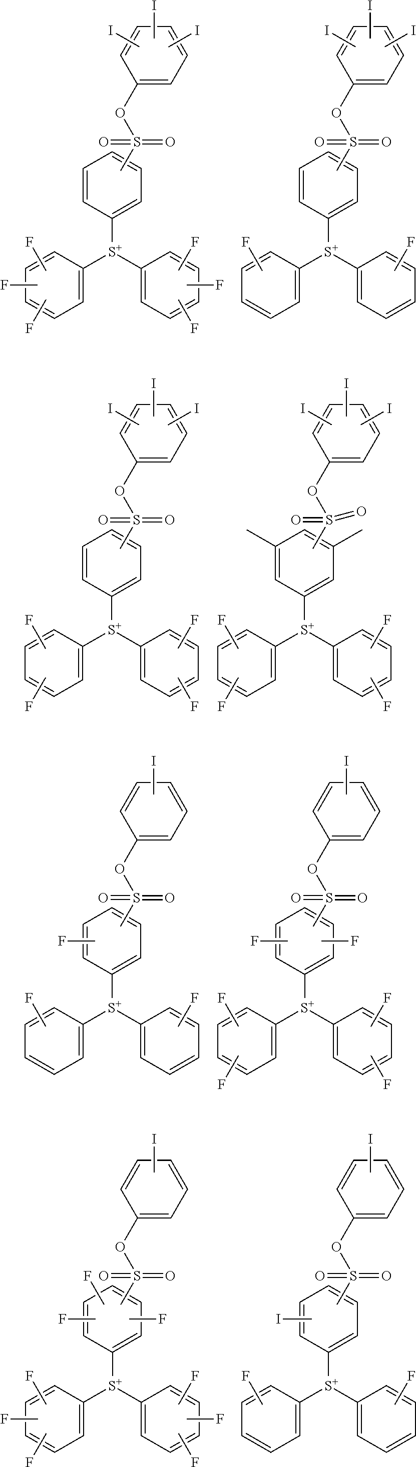

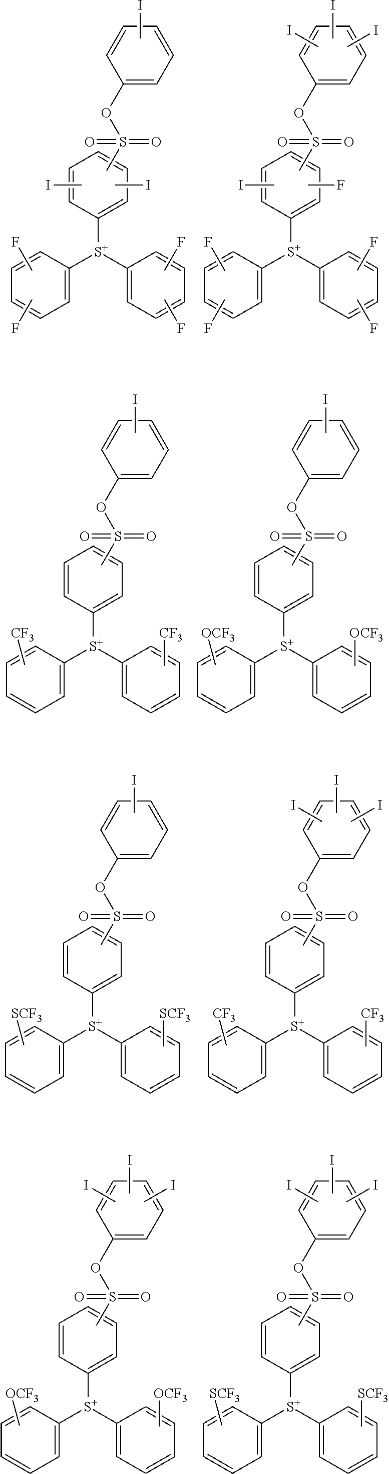

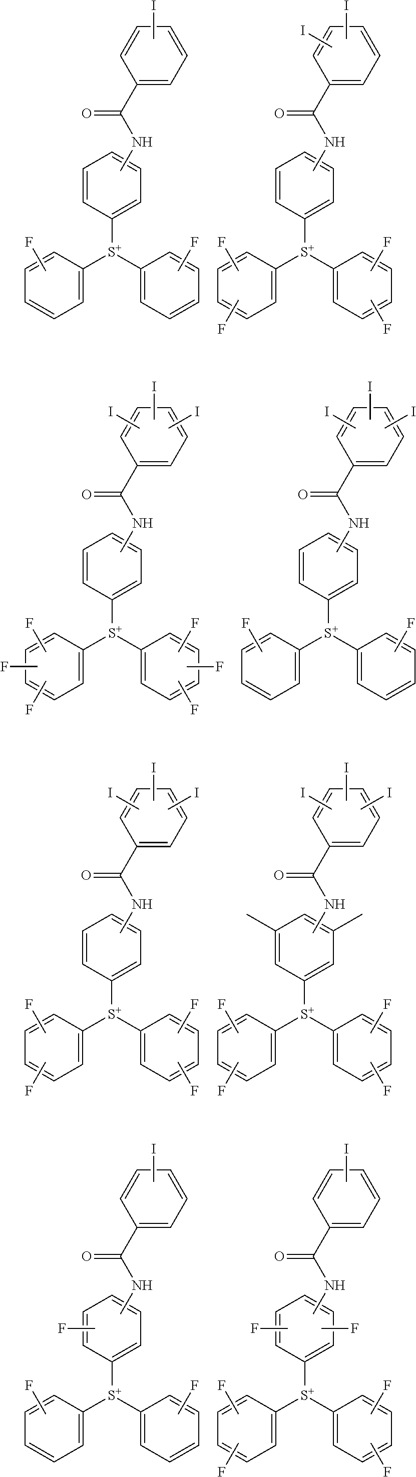

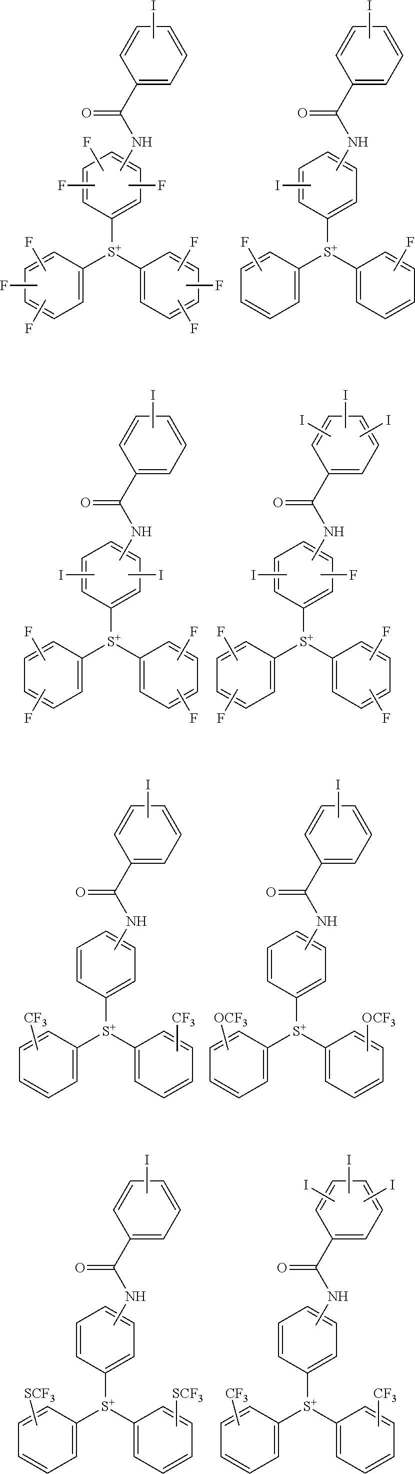

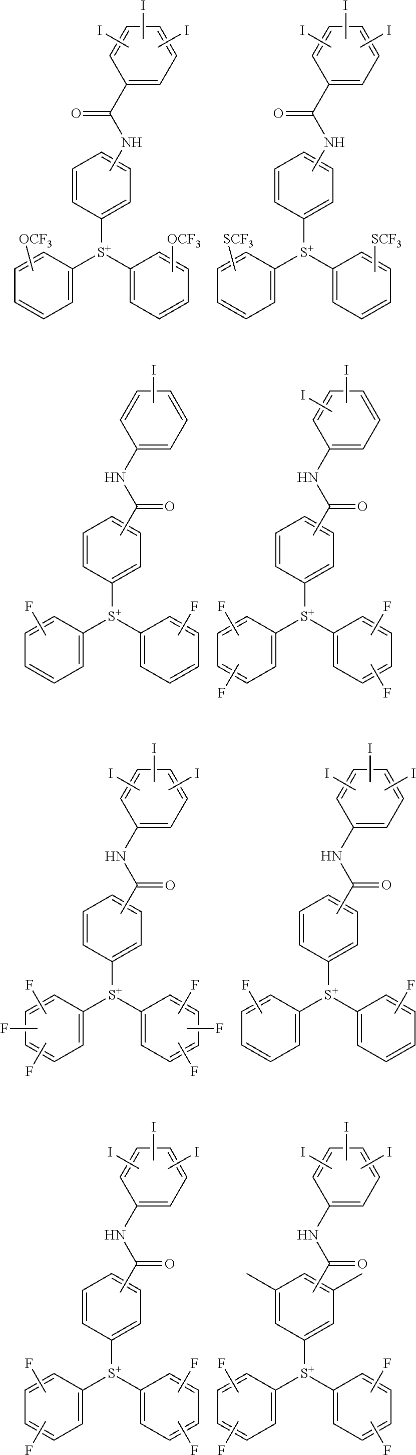

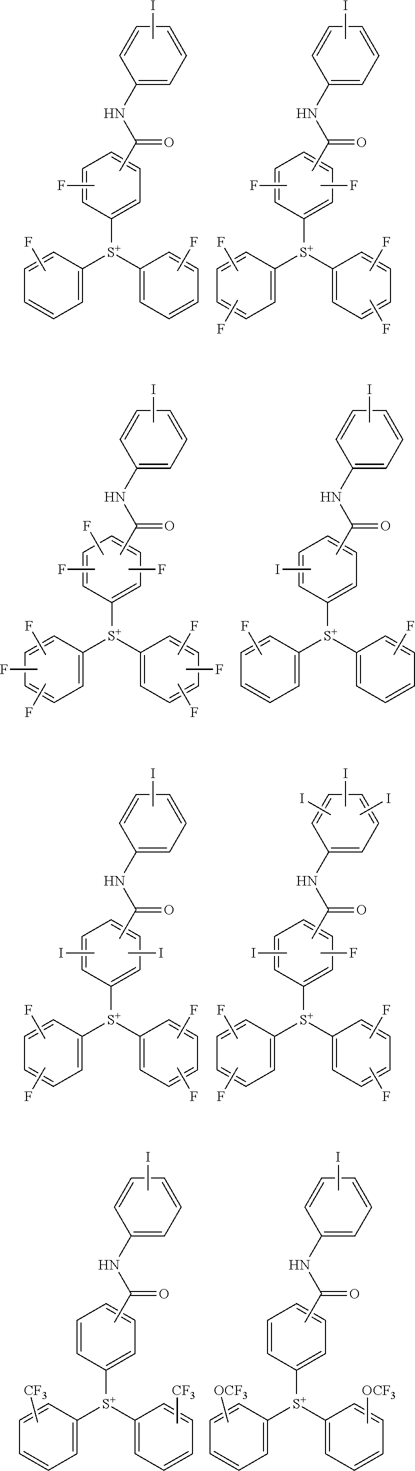

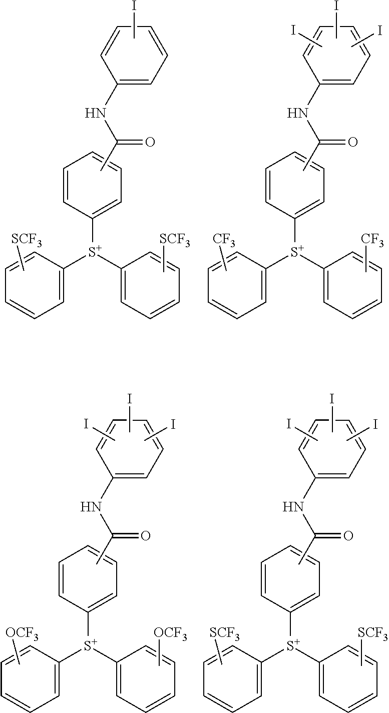

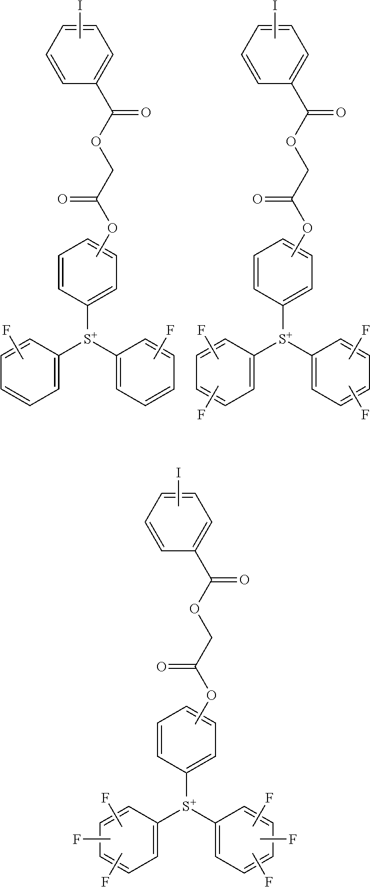

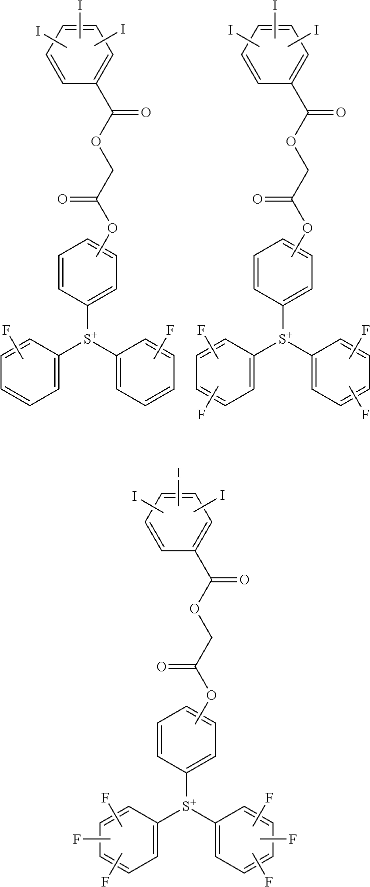

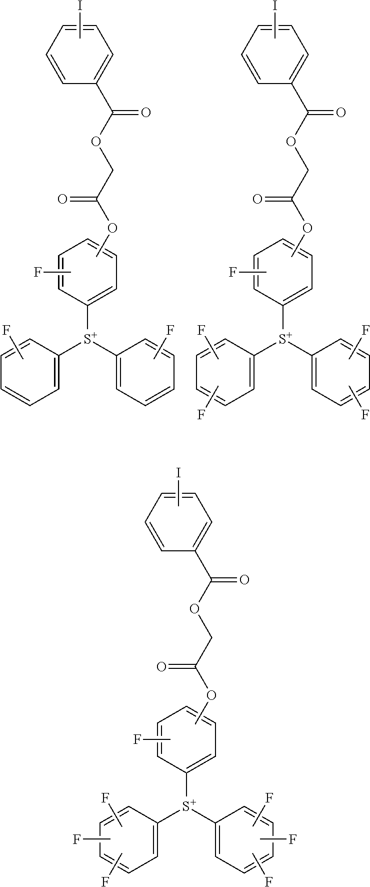

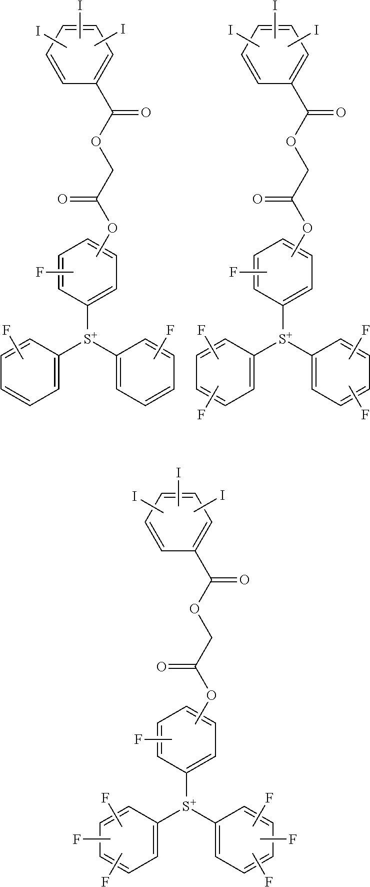

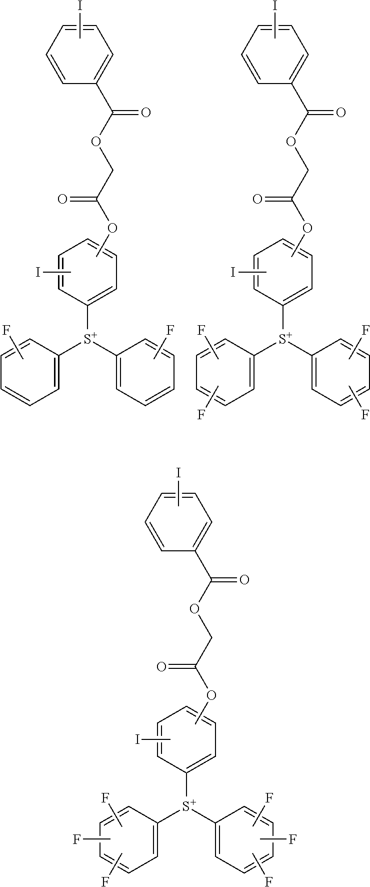

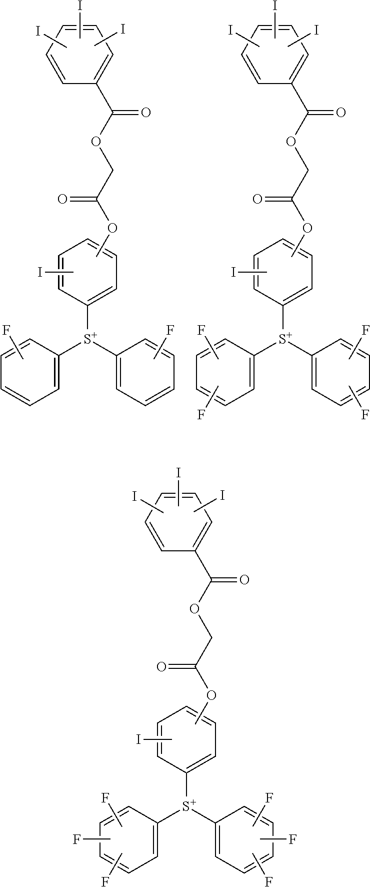

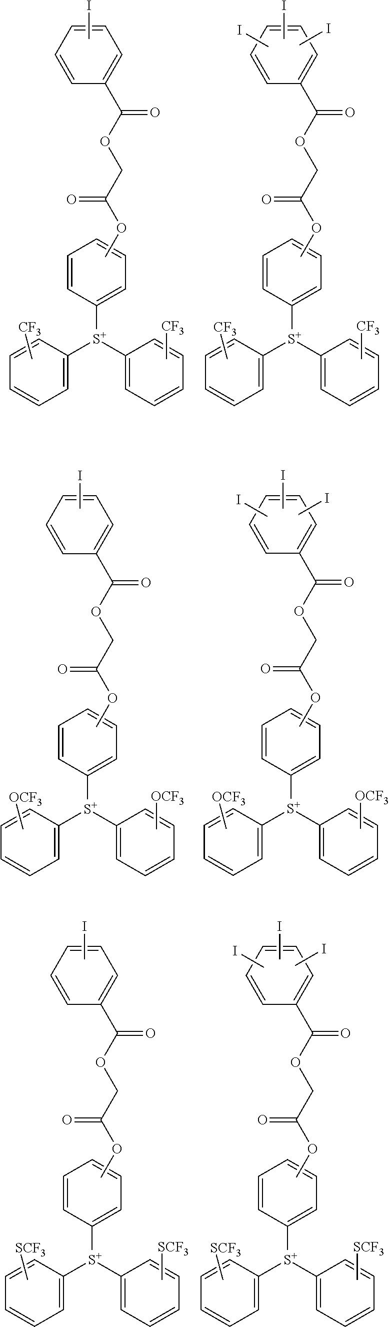

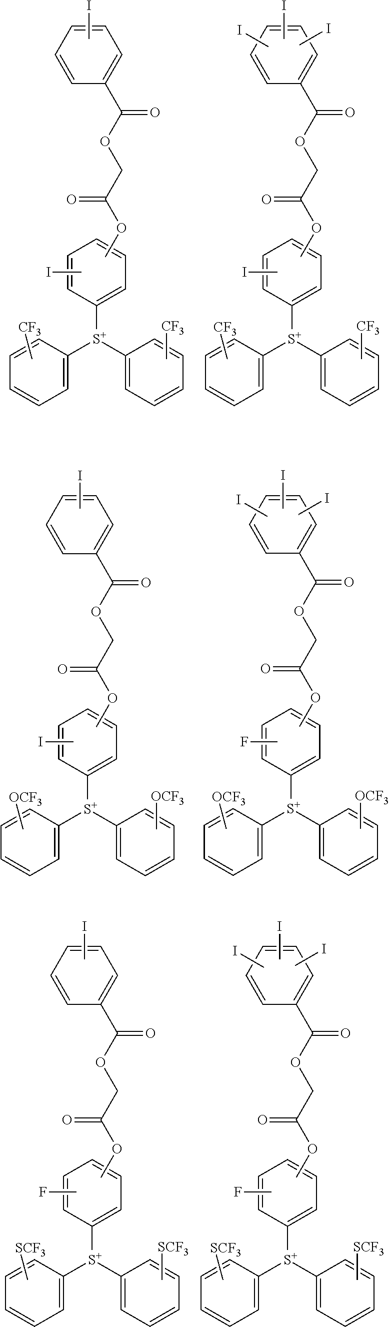

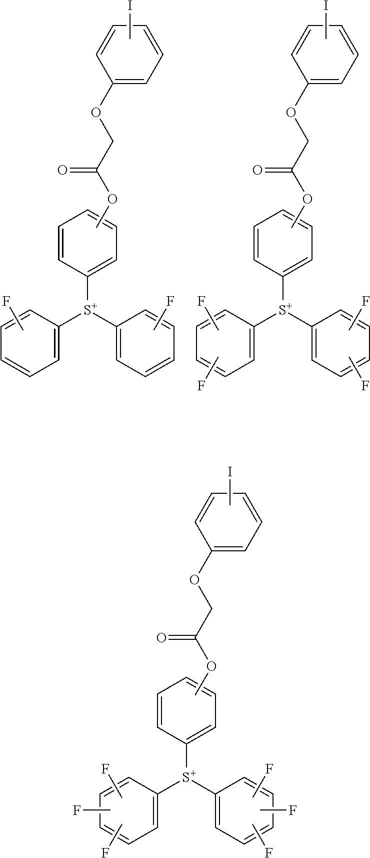

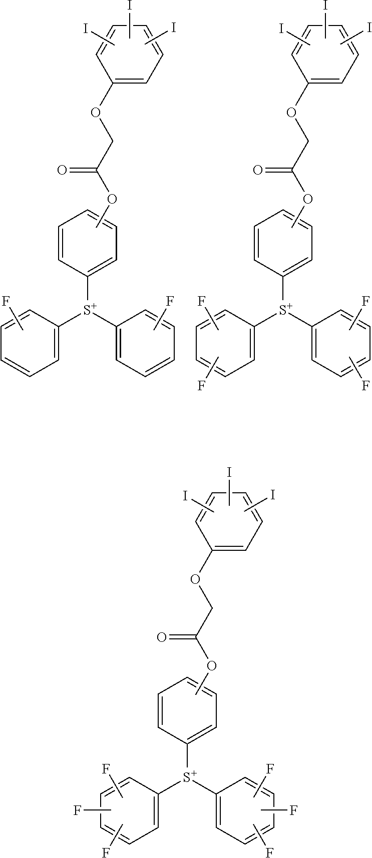

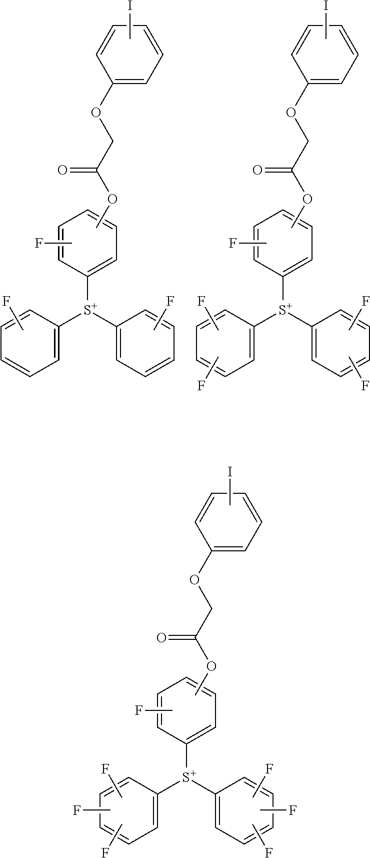

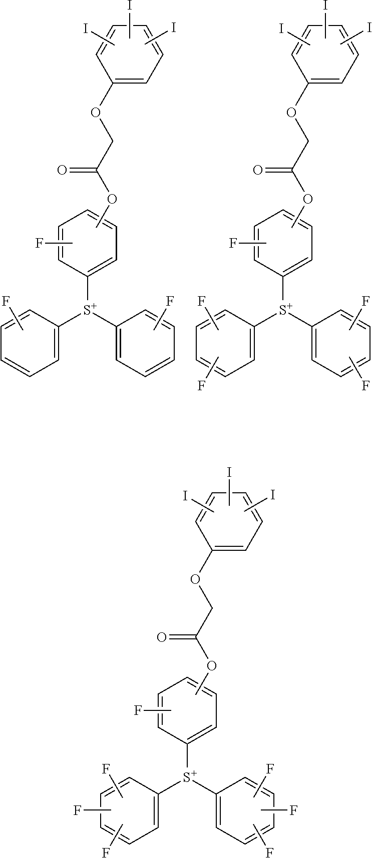

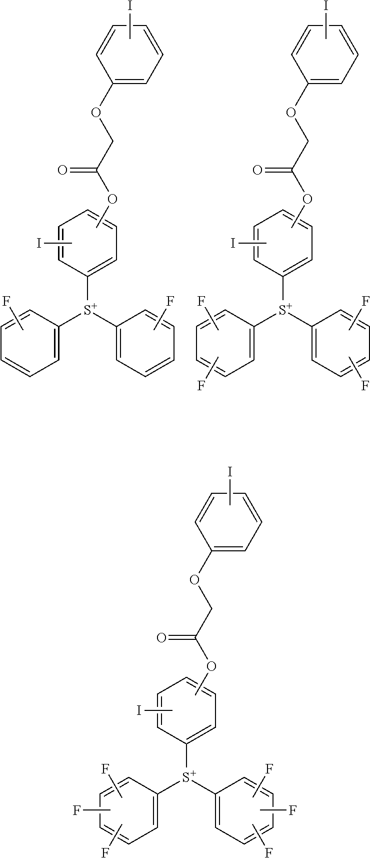

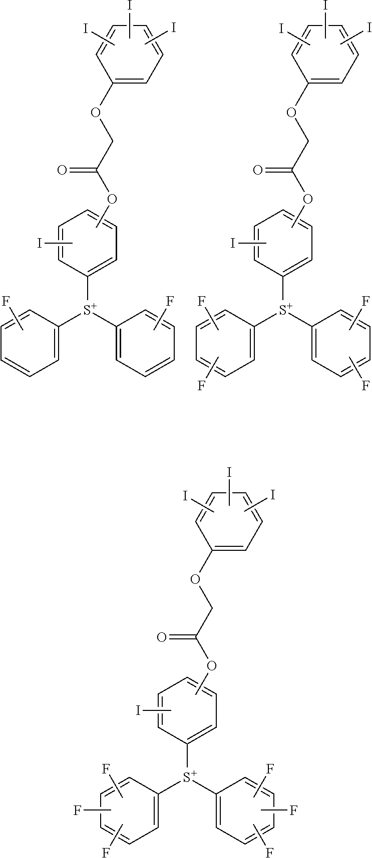

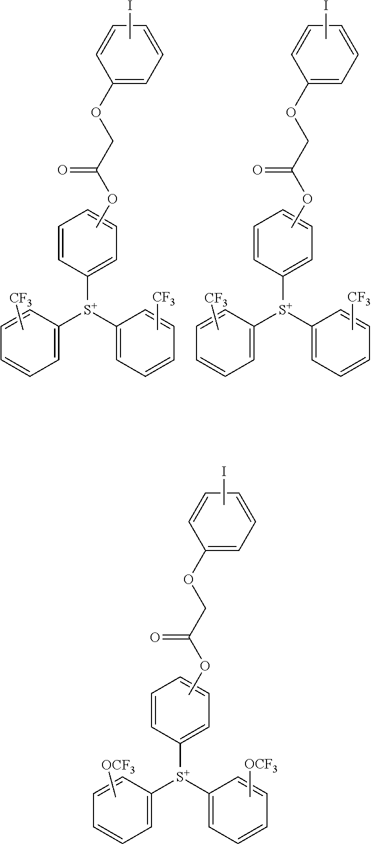

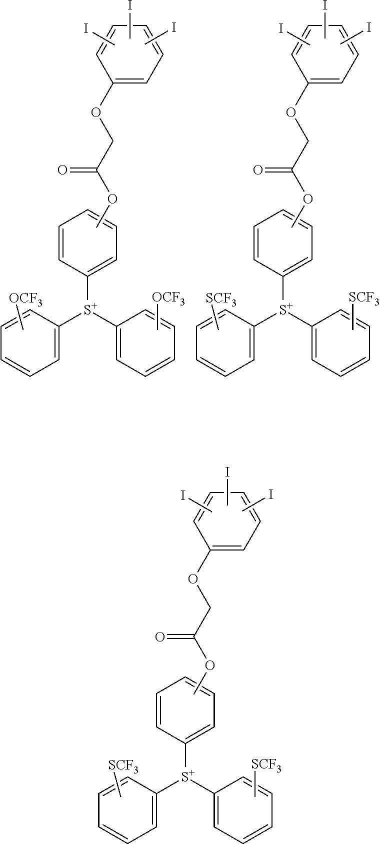

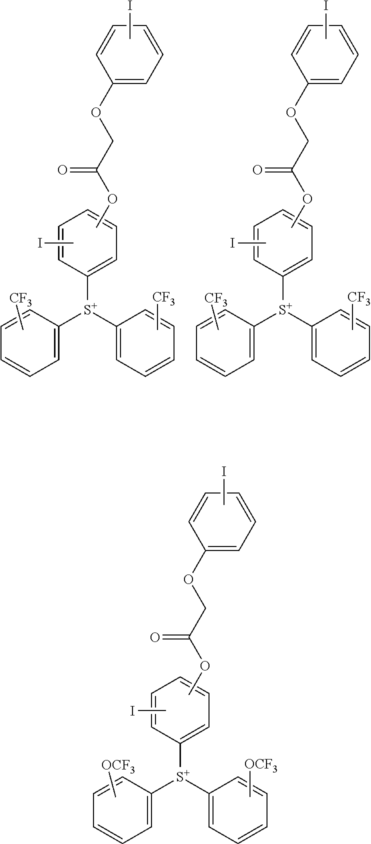

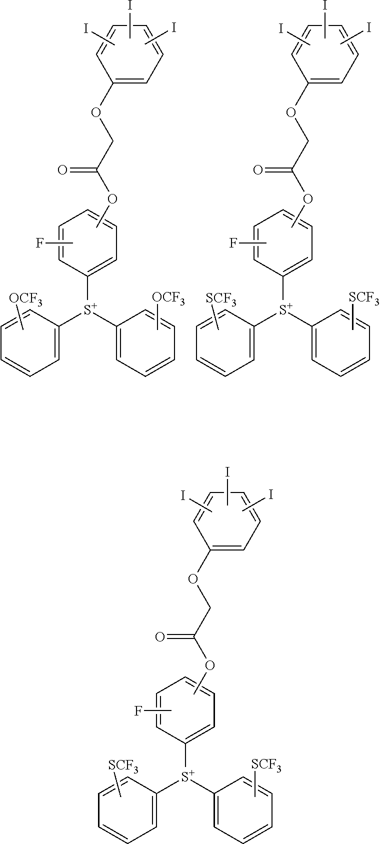

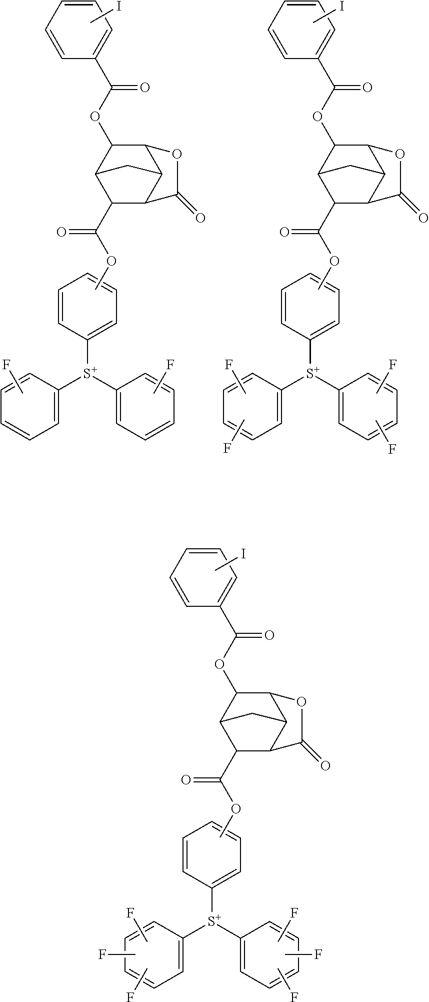

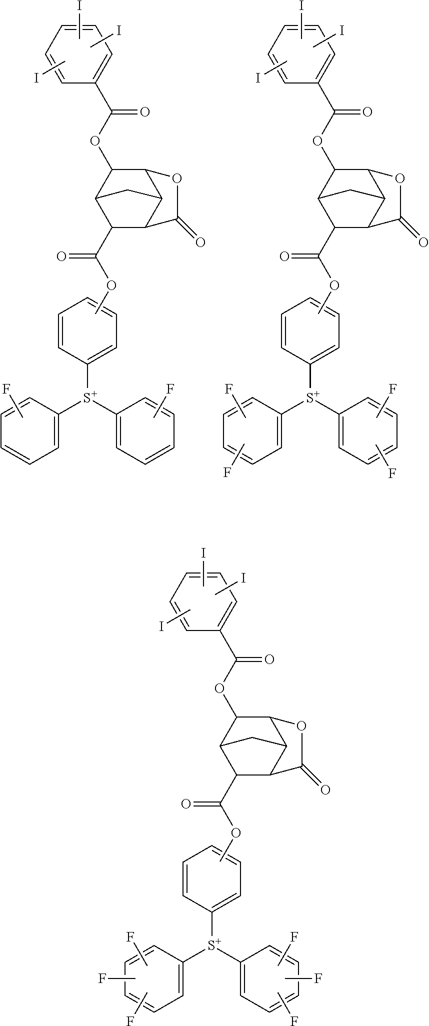

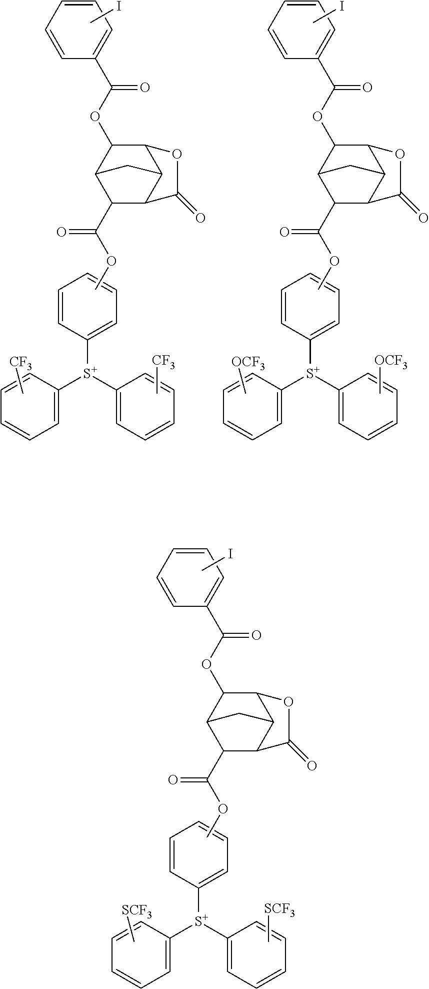

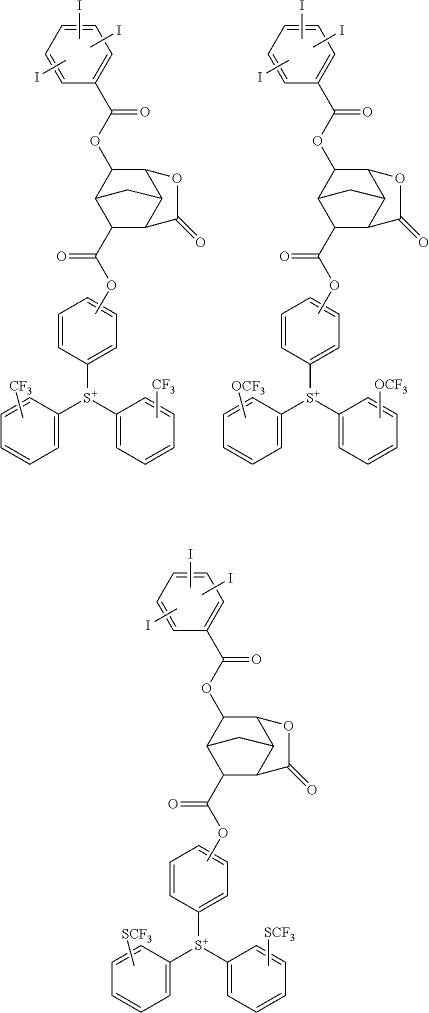

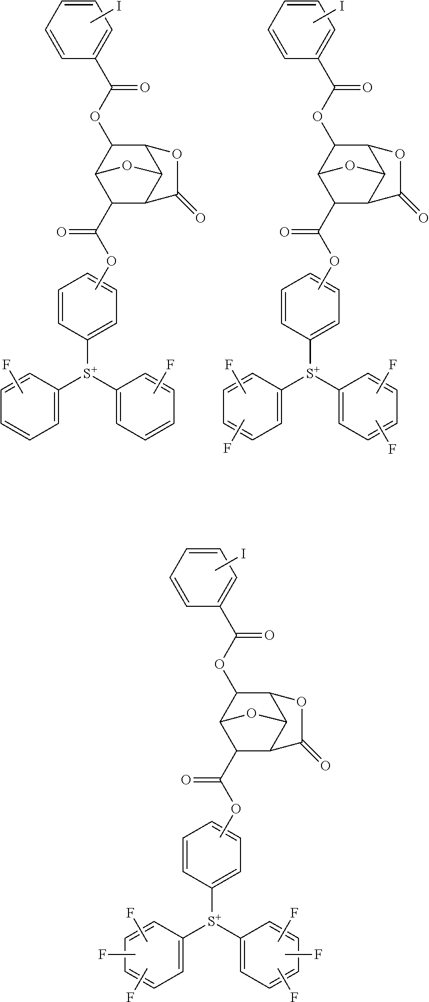

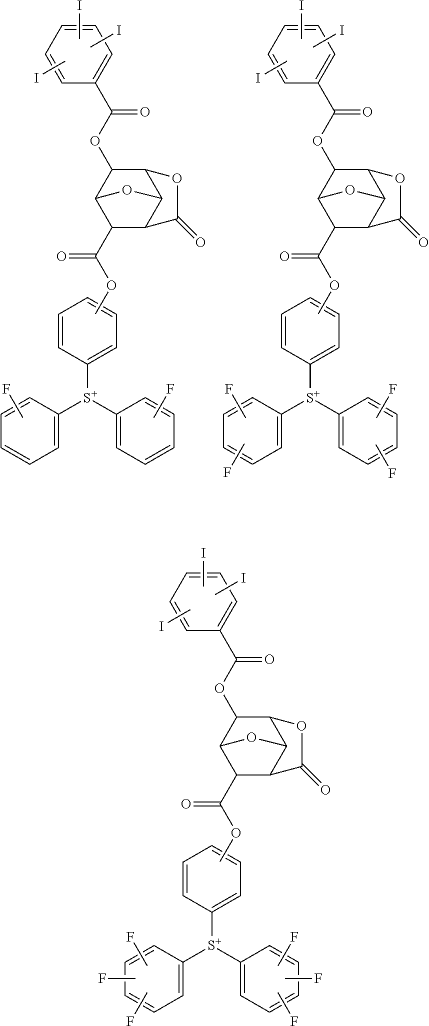

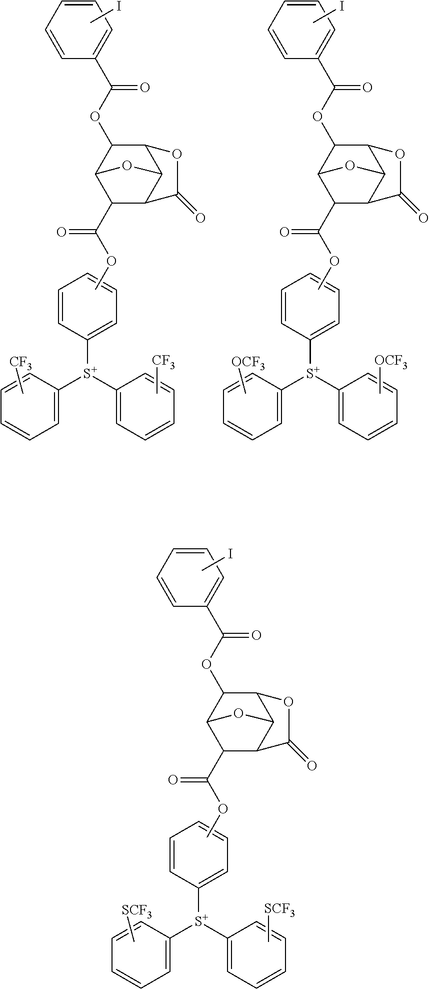

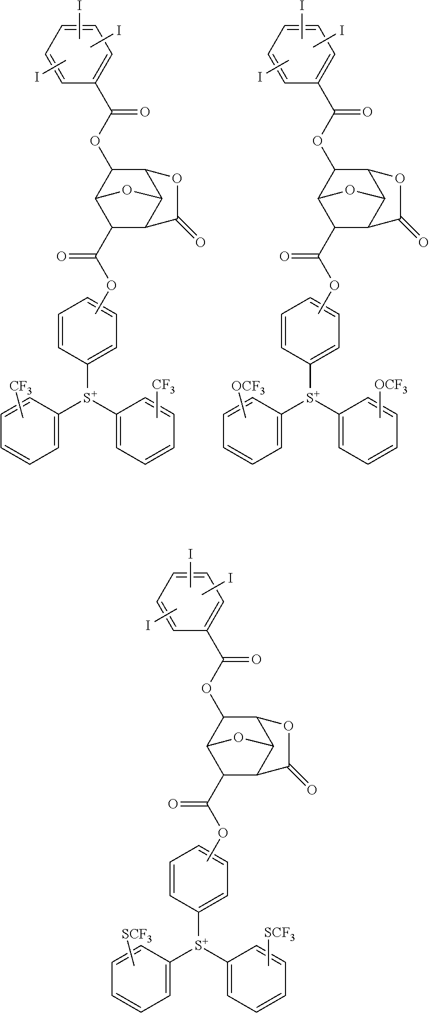

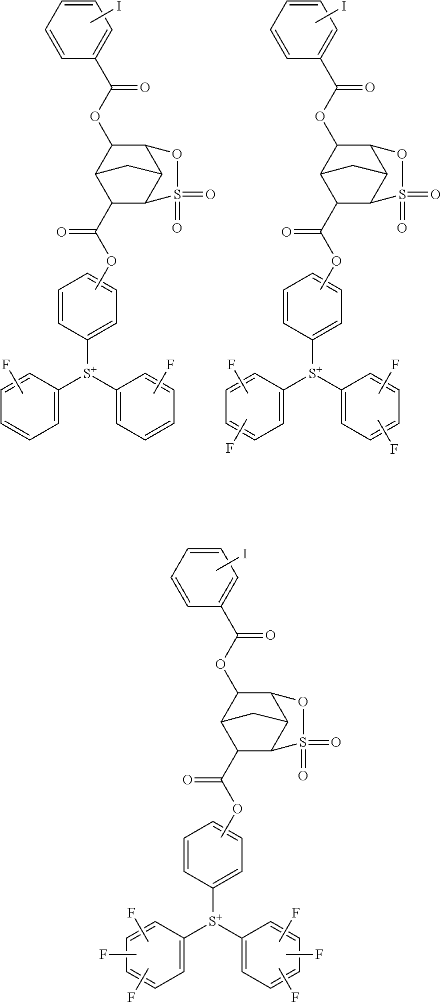

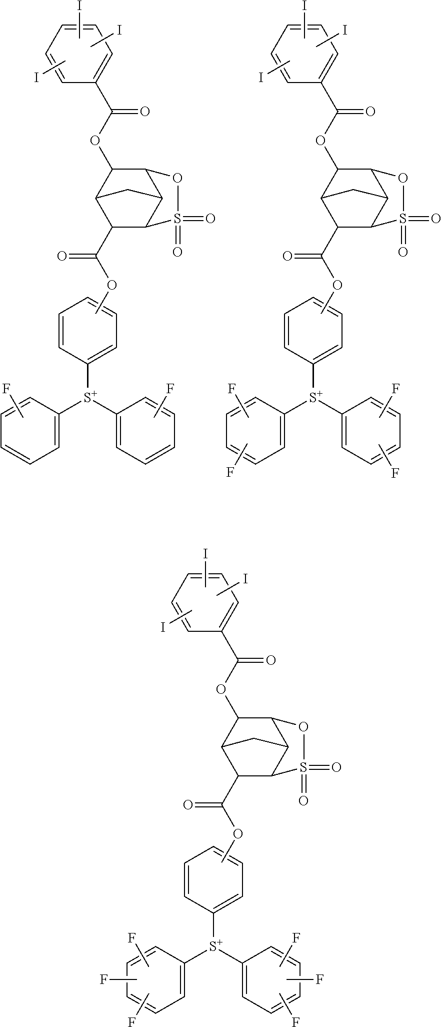

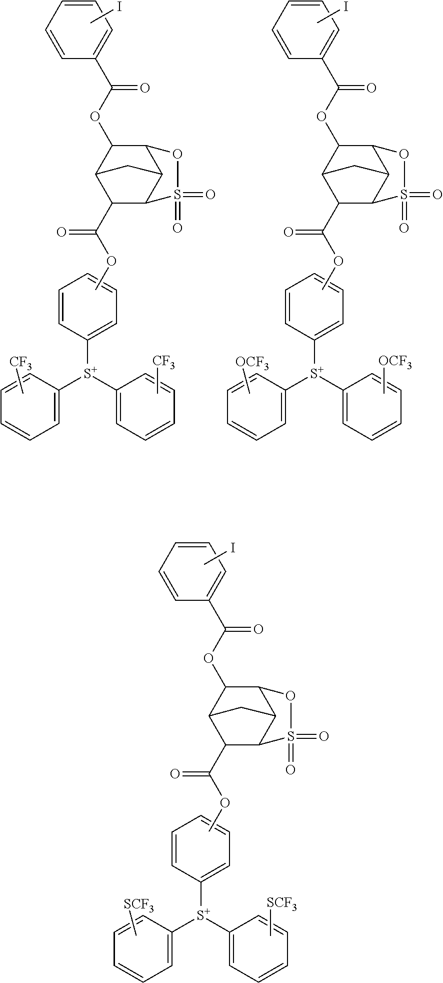

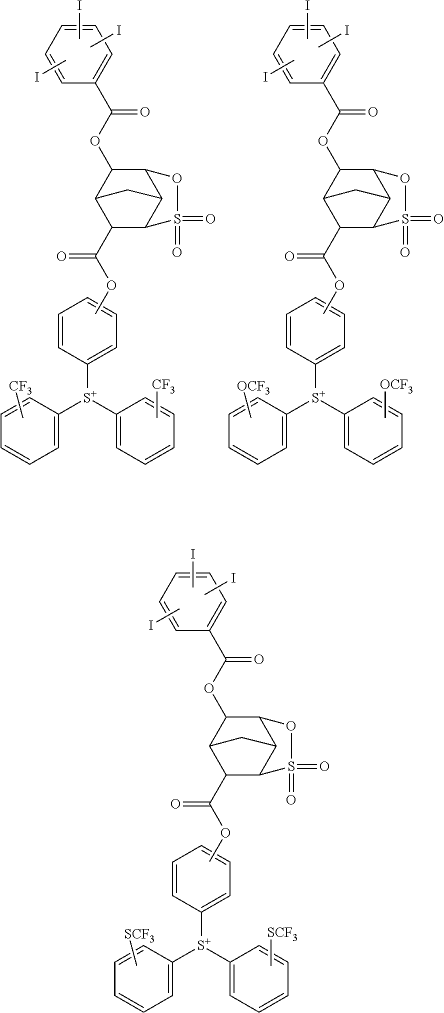

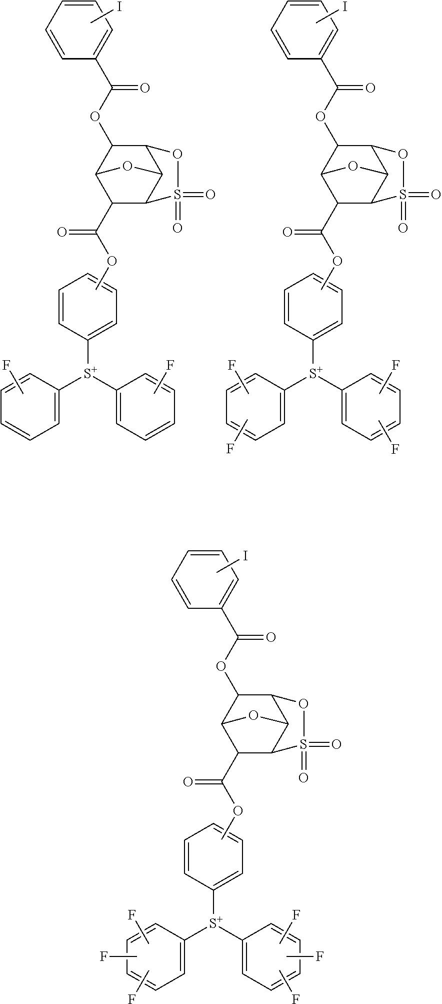

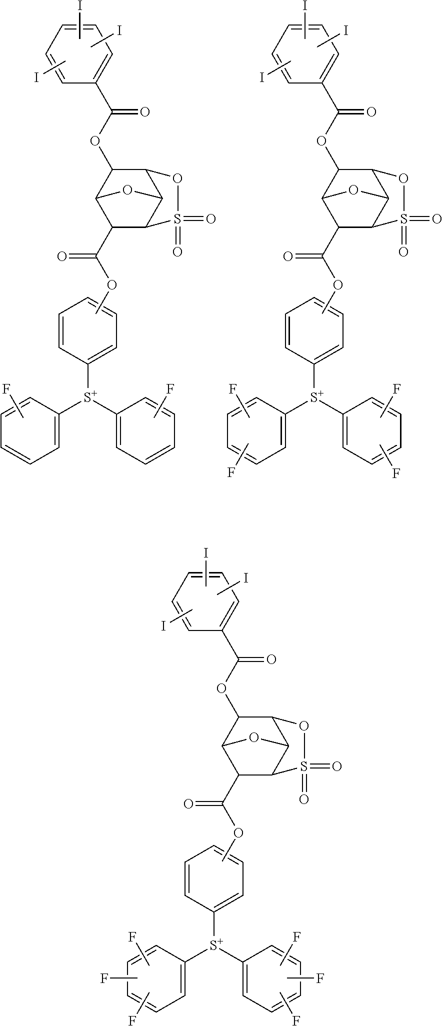

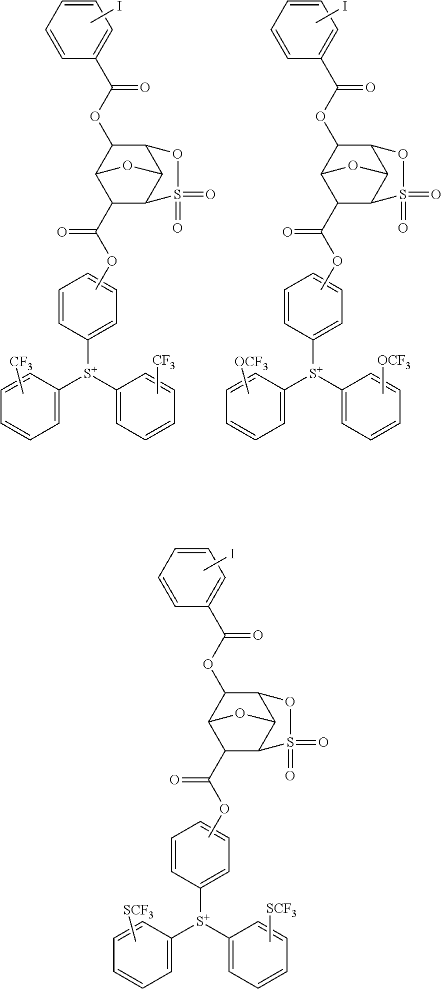

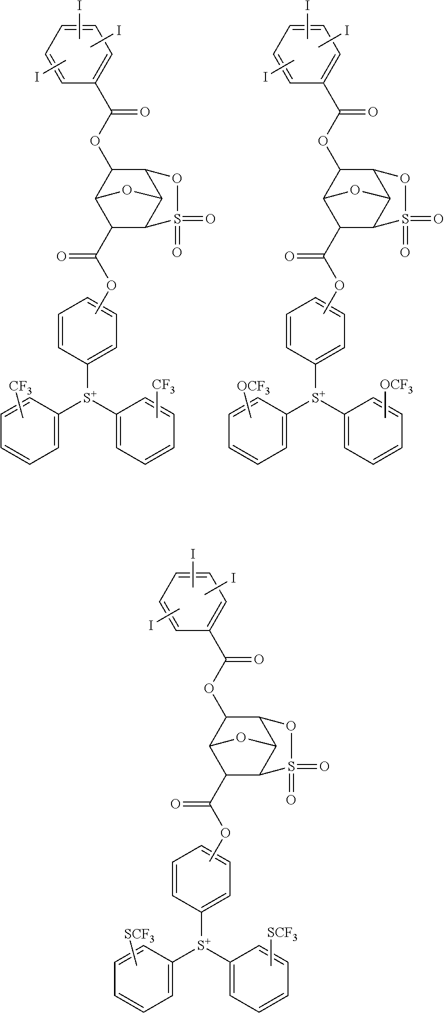

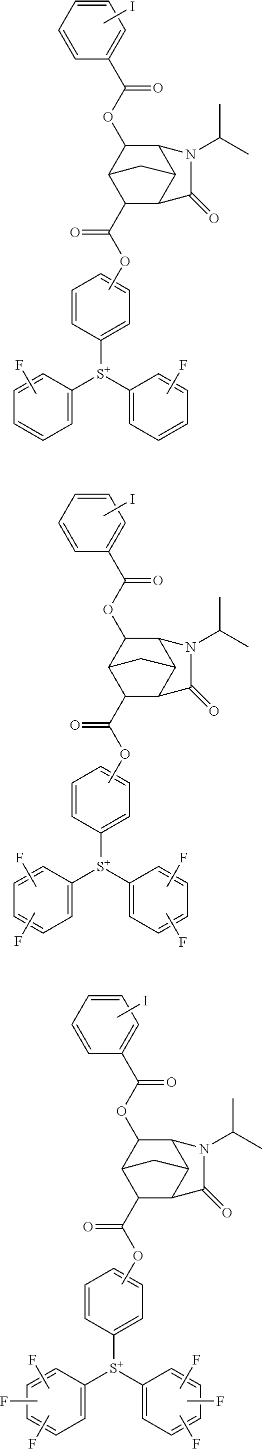

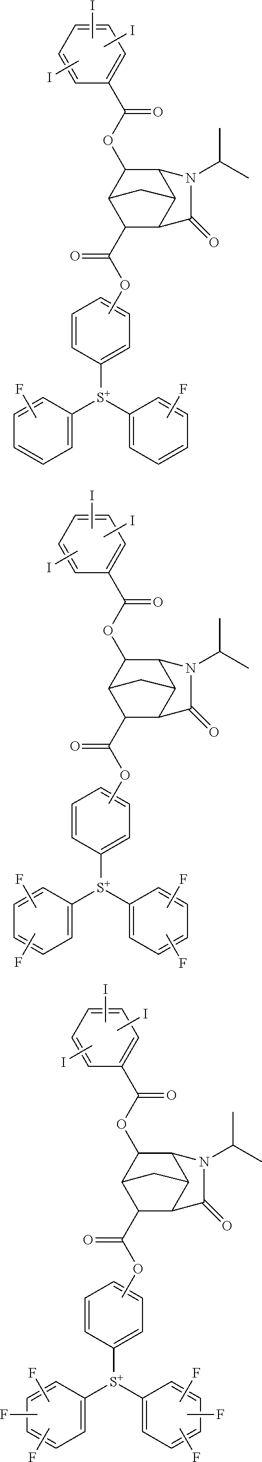

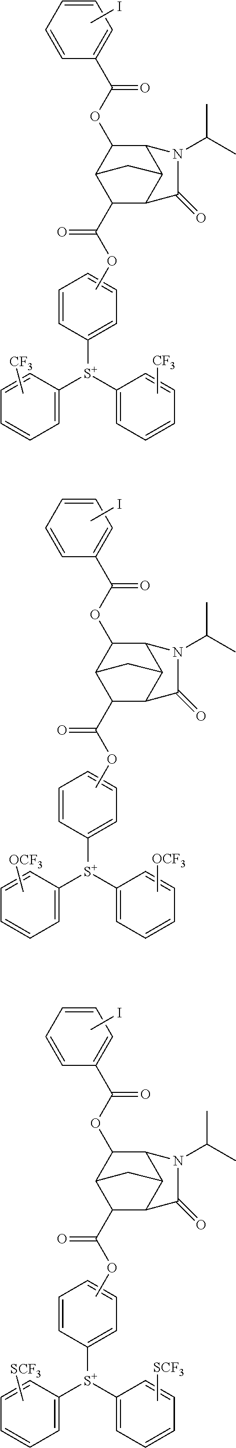

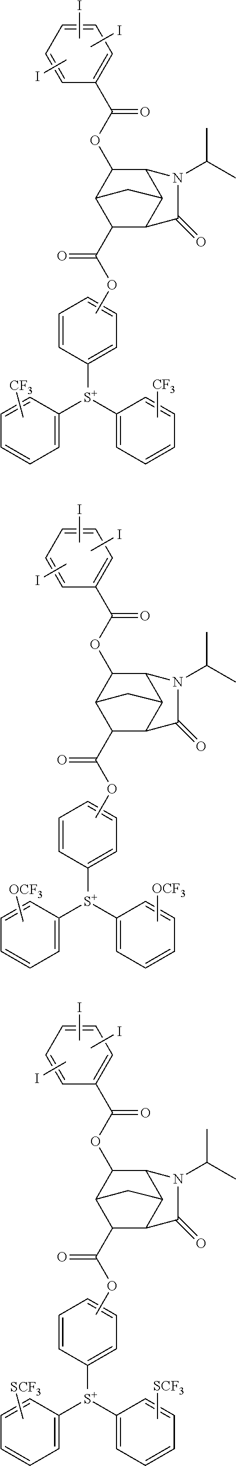

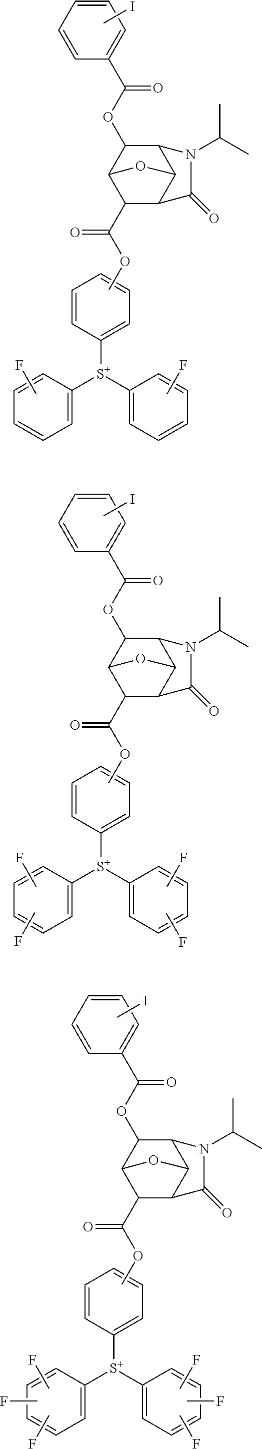

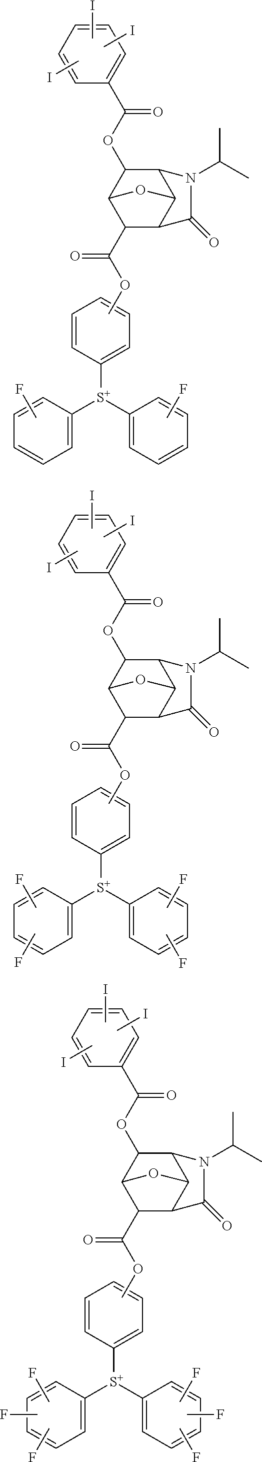

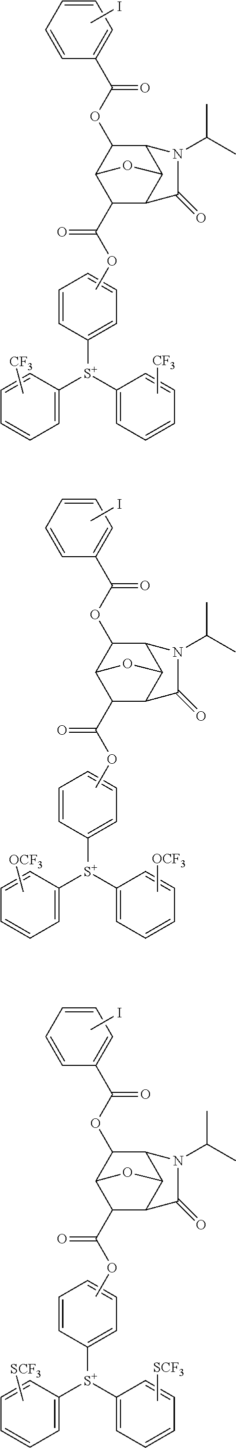

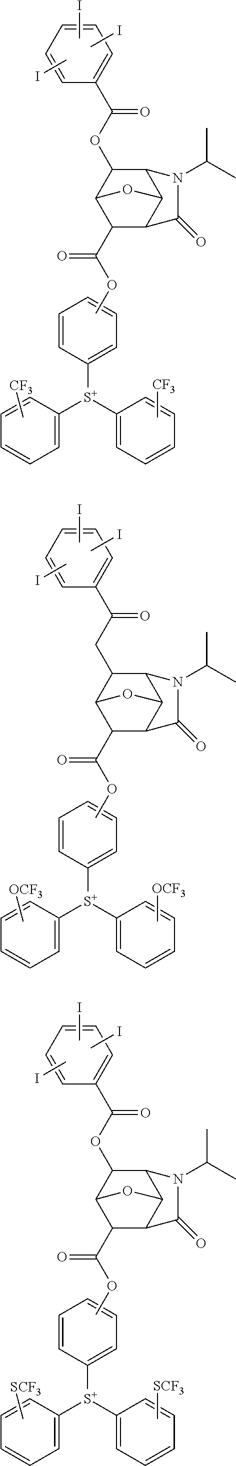

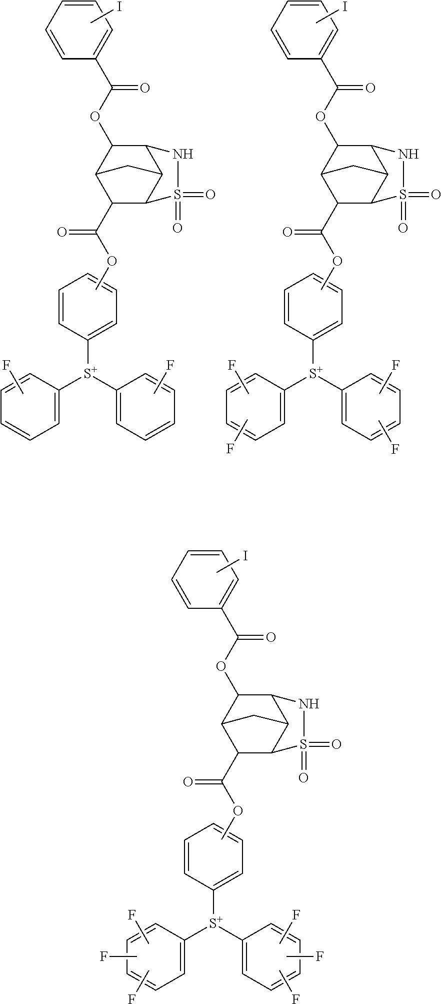

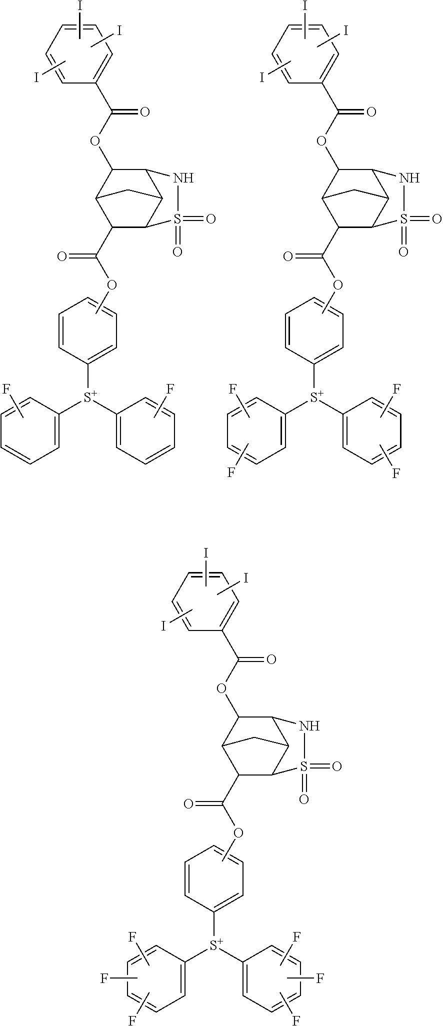

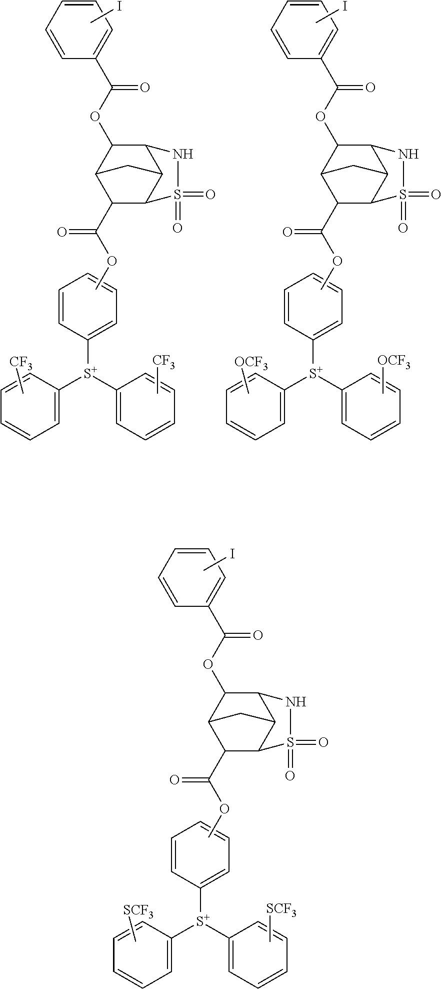

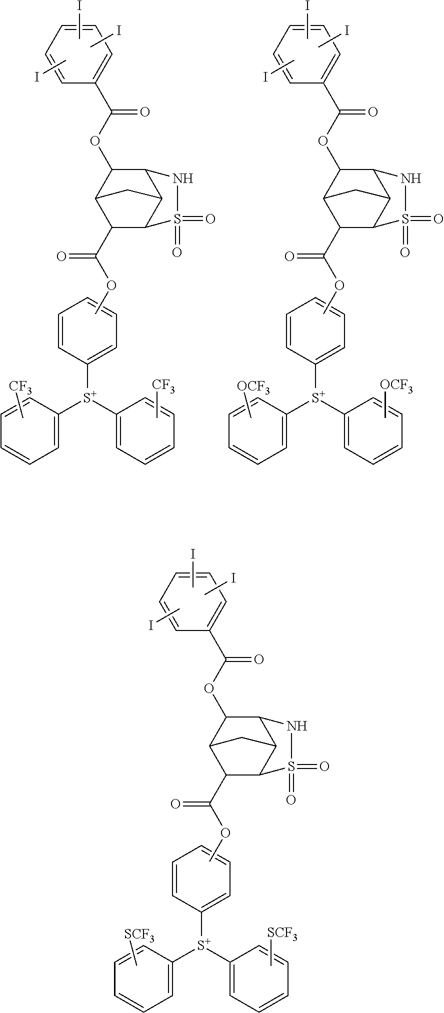

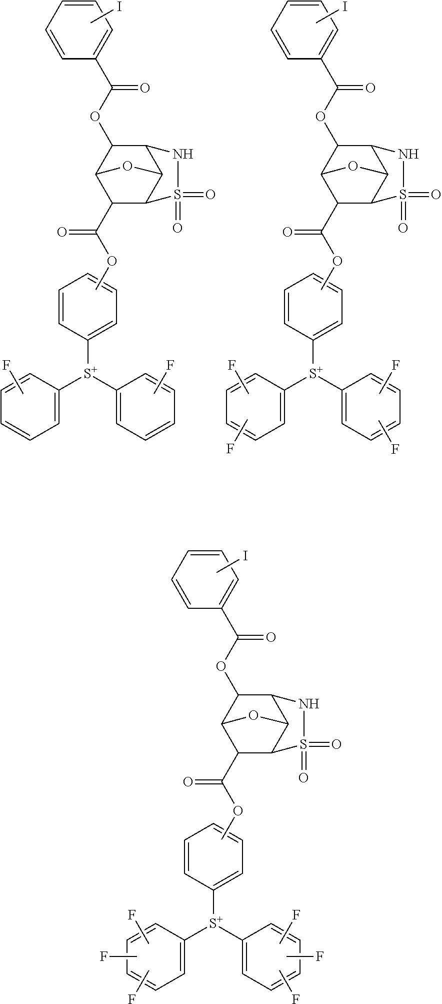

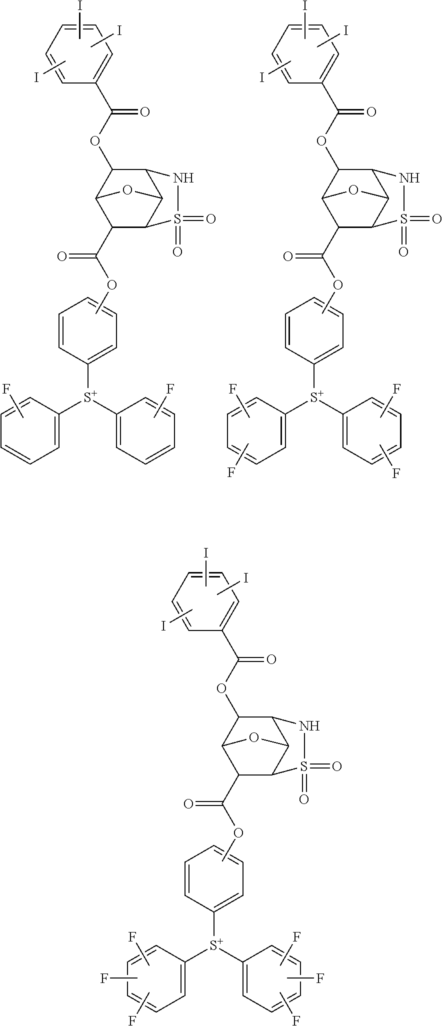

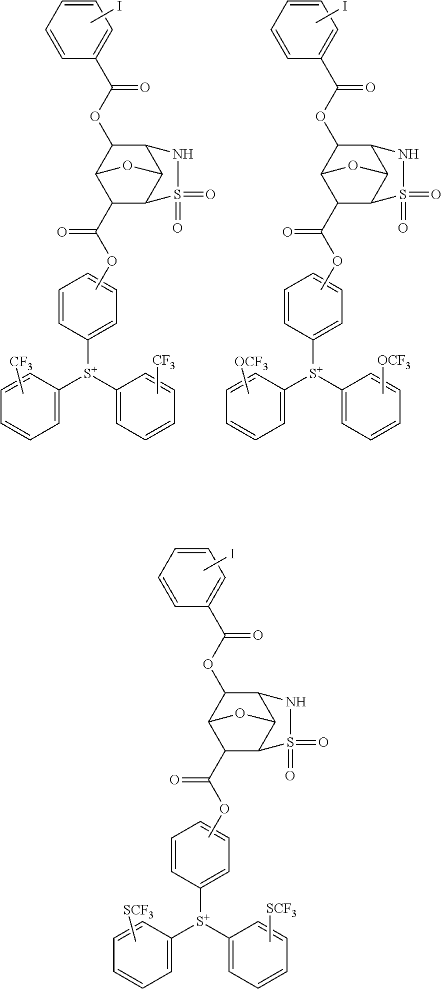

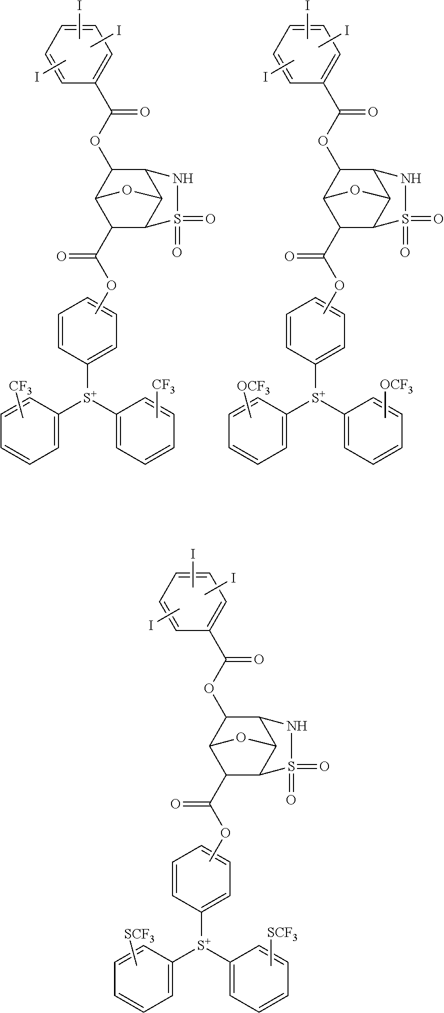

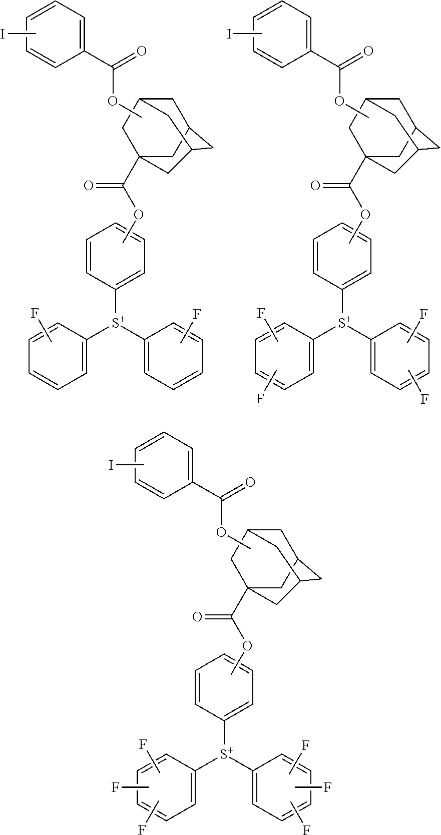

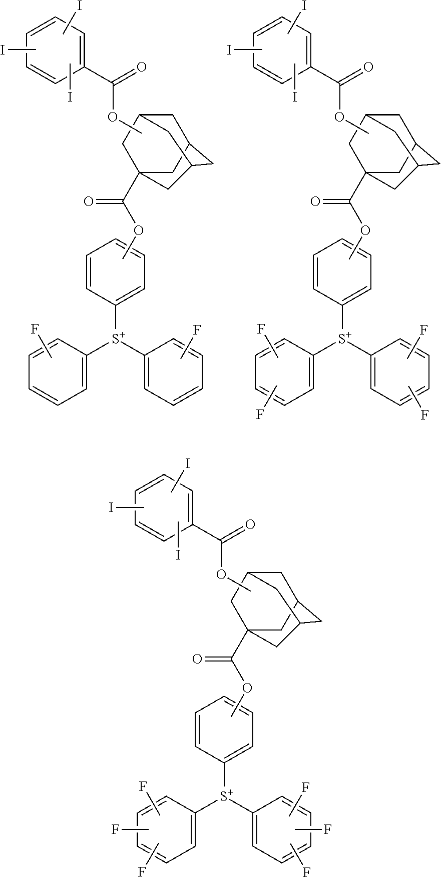

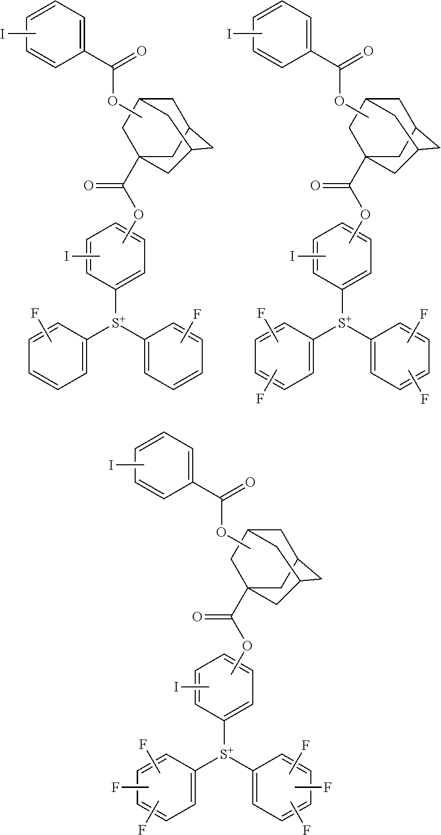

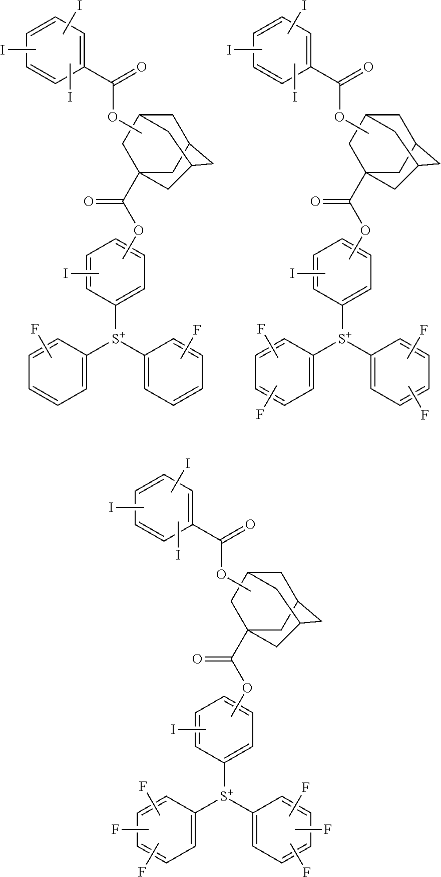

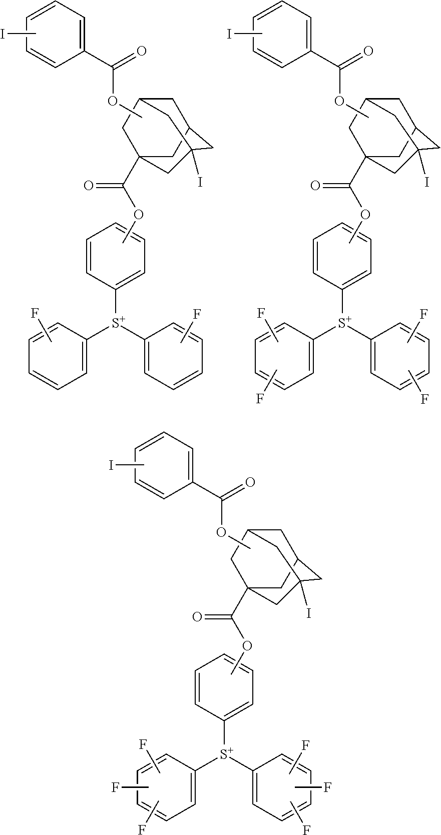

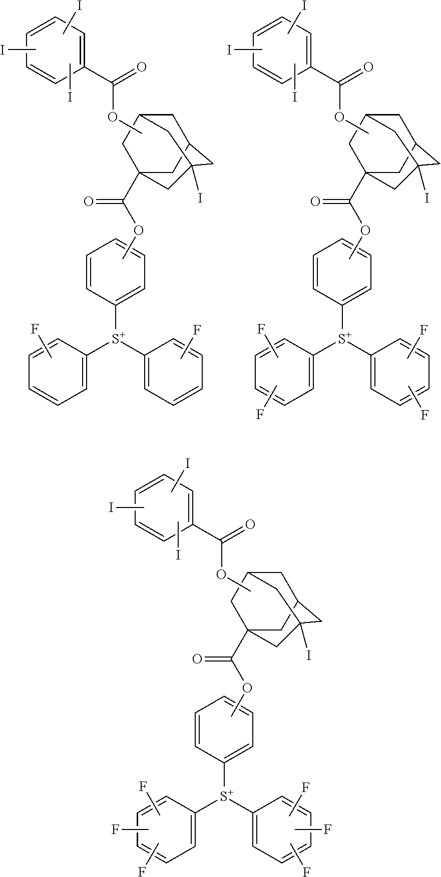

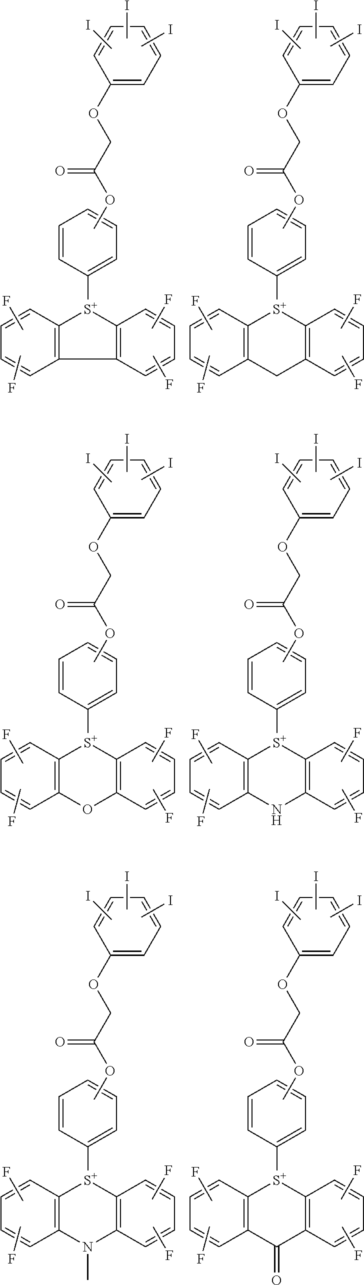

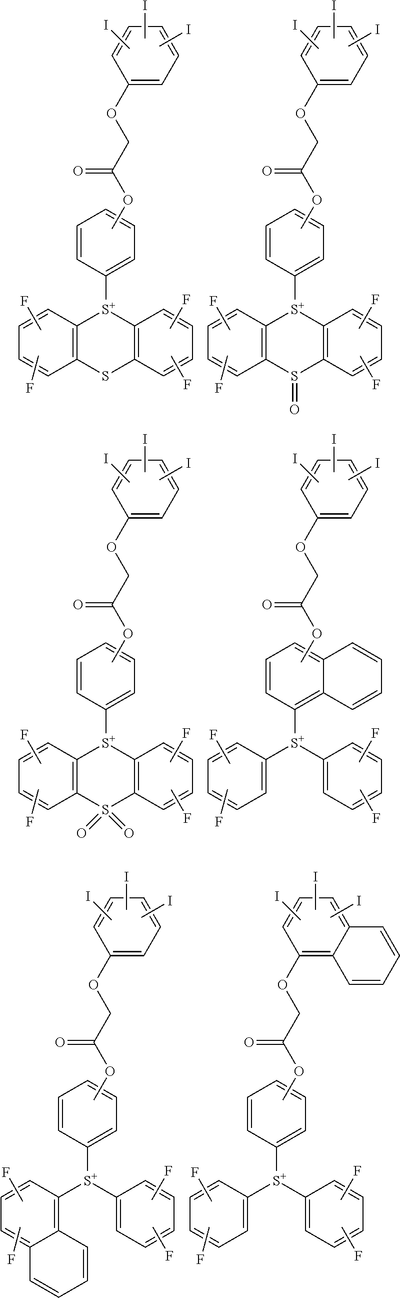

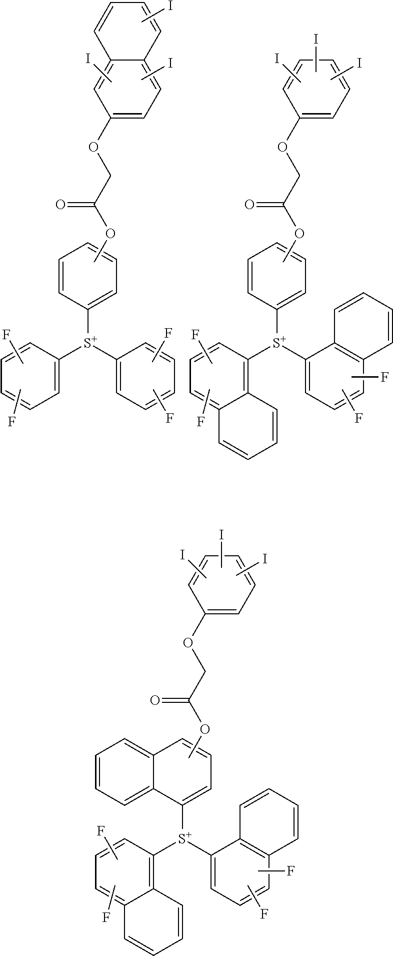

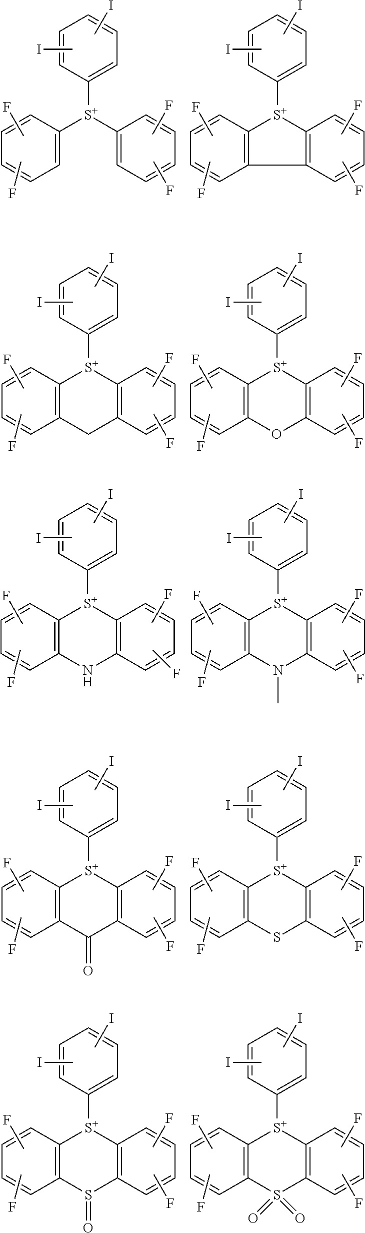

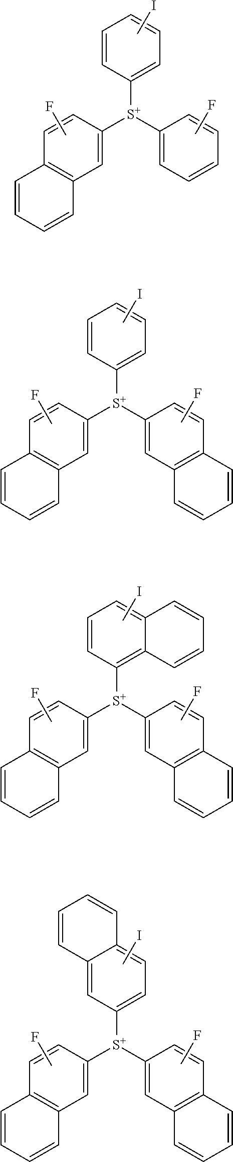

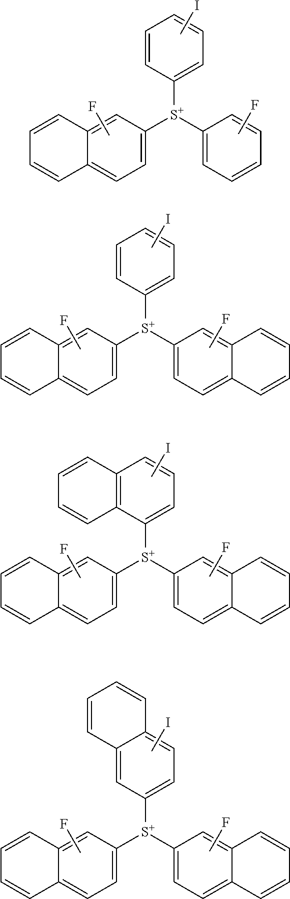

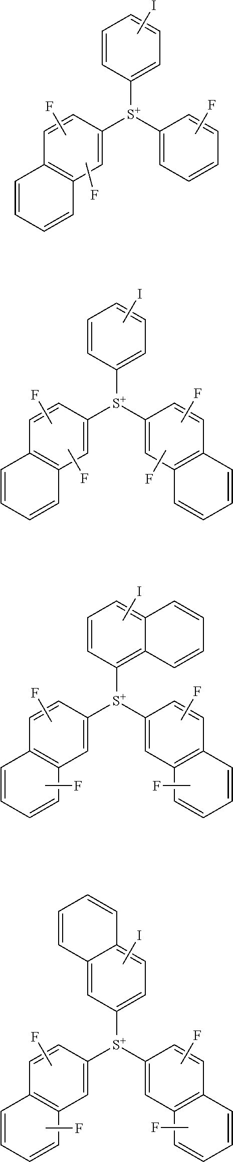

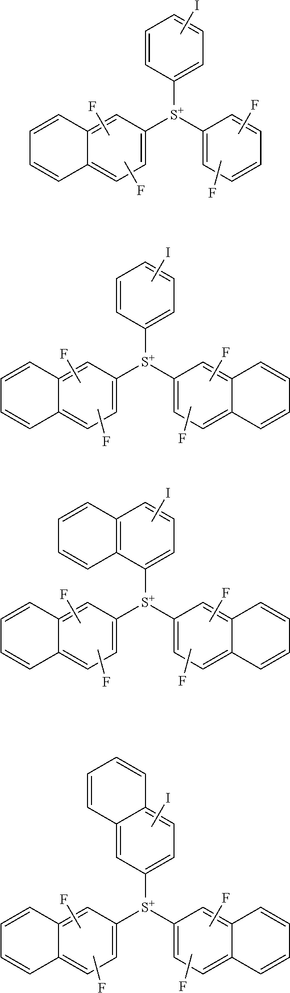

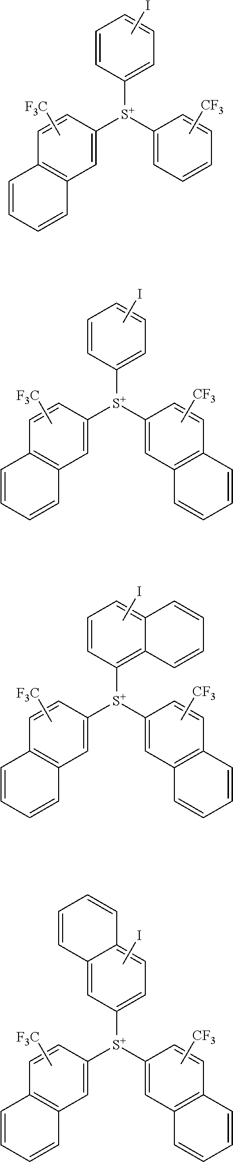

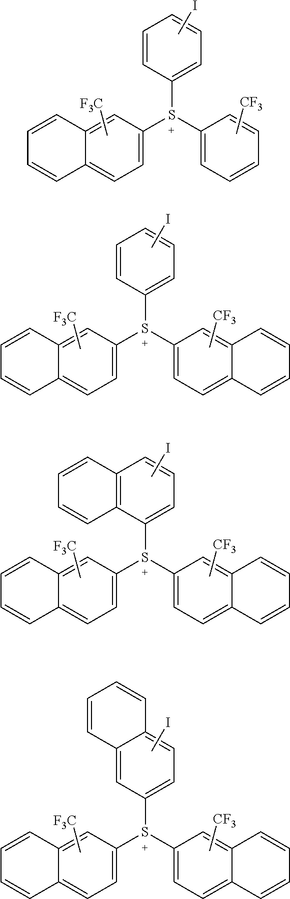

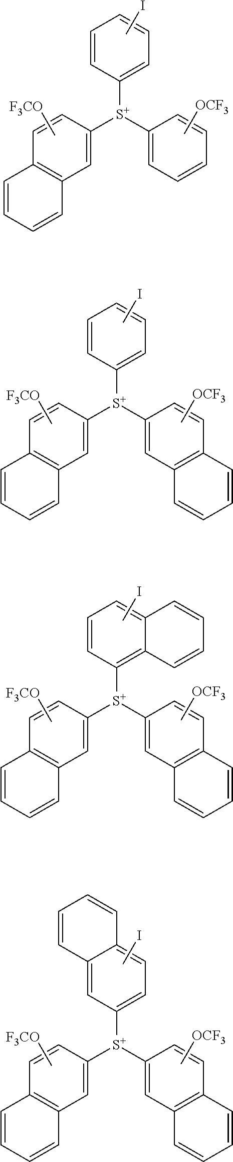

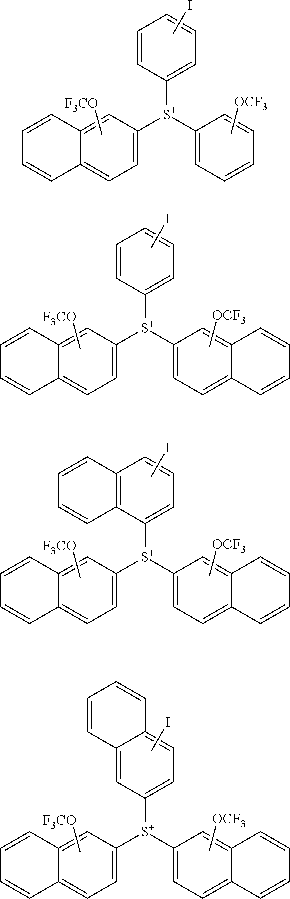

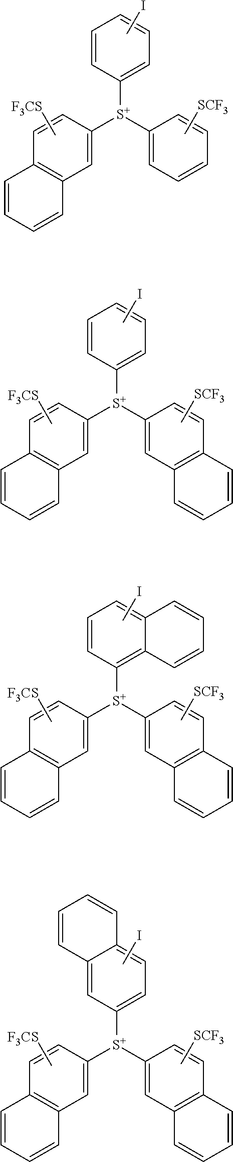

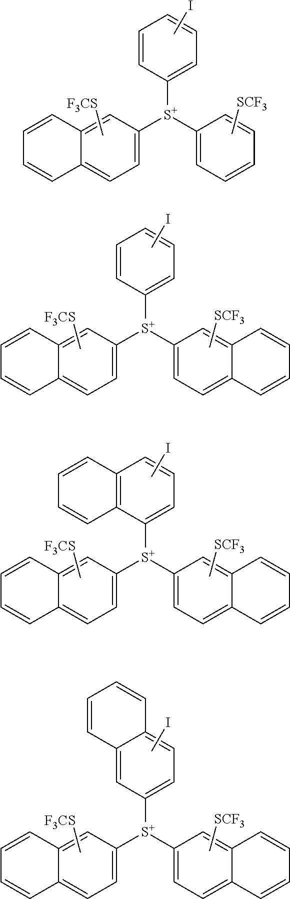

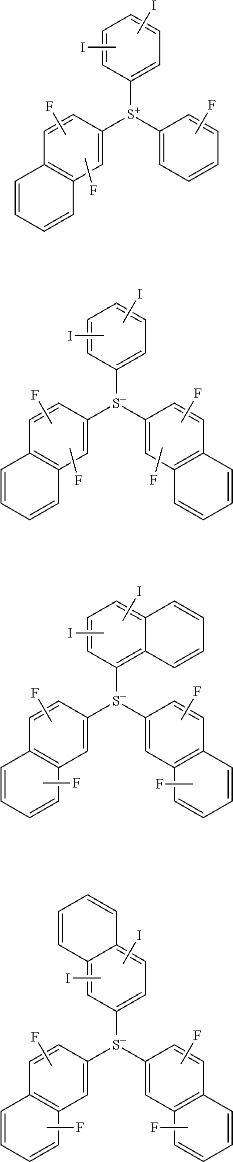

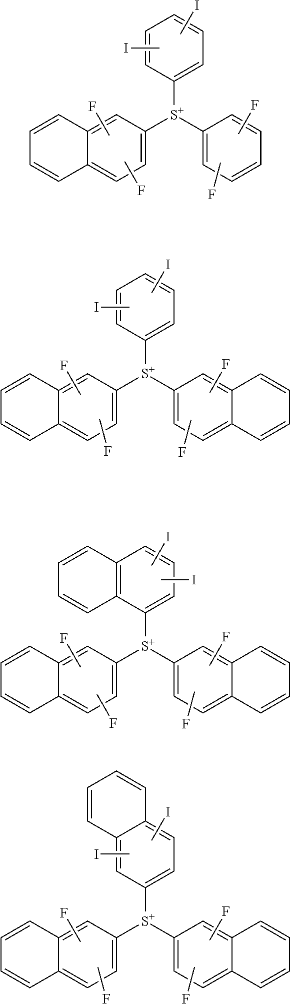

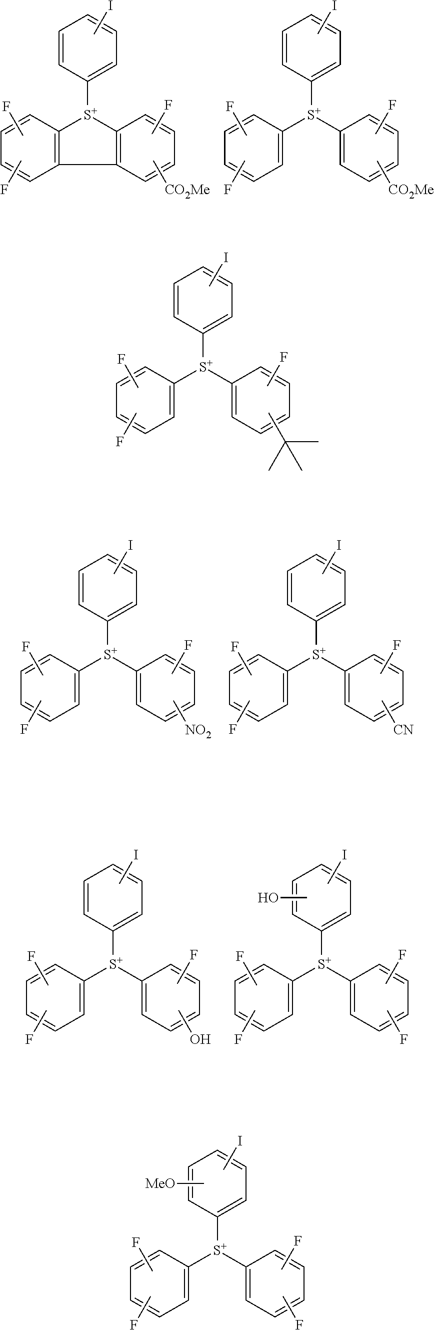

The polymer preferably further contains a repeating unit represented by the following general formula (e)(hereinafter also referred to as repeating unit-e).

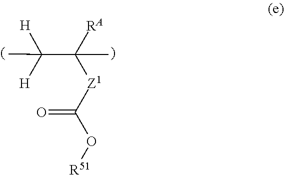

In the formula, R^{A} is a hydrogen atom, a fluorine atom, a methyl group, or a trifluoromethyl group;
Z¹ is a single bond, a phenylene group, a naphthylene group, *—C(═O)—O—Z¹¹—, or *—C(═O)—NH—Z¹¹—, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; * indicates a bond to a carbon atom in the main chain; Z¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring; and
R⁵¹ is a hydrogen atom, or a group having 1 to 20 carbon atoms containing at least one structure selected from a hydroxy group other than a phenolic hydroxy group, a cyano group, a carbonyl group, a carboxy group, an ether bond, an ester bond, a sulfonate ester bond, a carbonate bond, a lactone ring, a sultone ring, and a carboxylic anhydride (—C(═O)—O—C(═O)—).

In the general formula (e), R^{A} is a hydrogen atom, a fluorine atom, a methyl group, or a trifluoromethyl group. Z¹ is a single bond, a phenylene group, a naphthylene group, *—C(═O)—O—Z¹¹— or *—C(═O)—NH—Z¹¹—, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom. * indicates a bond to a carbon atom in the main chain. Z¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring. R⁵¹ is a hydrogen atom, or a group having 1 to 20 carbon atoms and containing at least one structure selected from a hydroxy group other than a phenolic hydroxy group, a cyano group, a carbonyl group, a carboxy group, an ether bond, an ester bond, a sulfonate ester bond, a carbonate bond, a lactone ring, a sultone ring, and a carboxylic anhydride (—C(═O)—O—C(═O)—).

Specific examples of the repeating unit-e include, but are not limited to, those shown below. In the following formulae, R^{A} is as defined above.

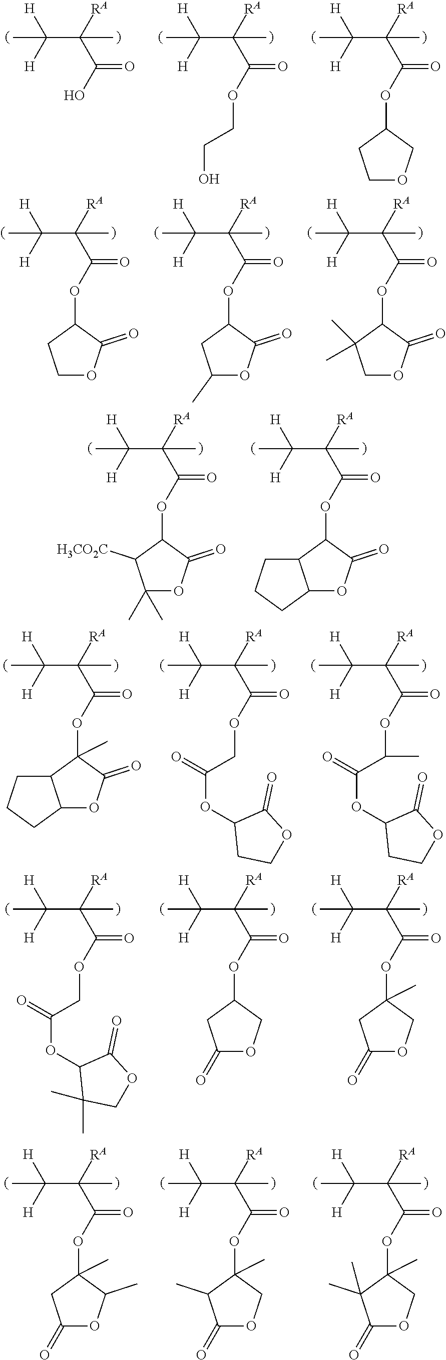

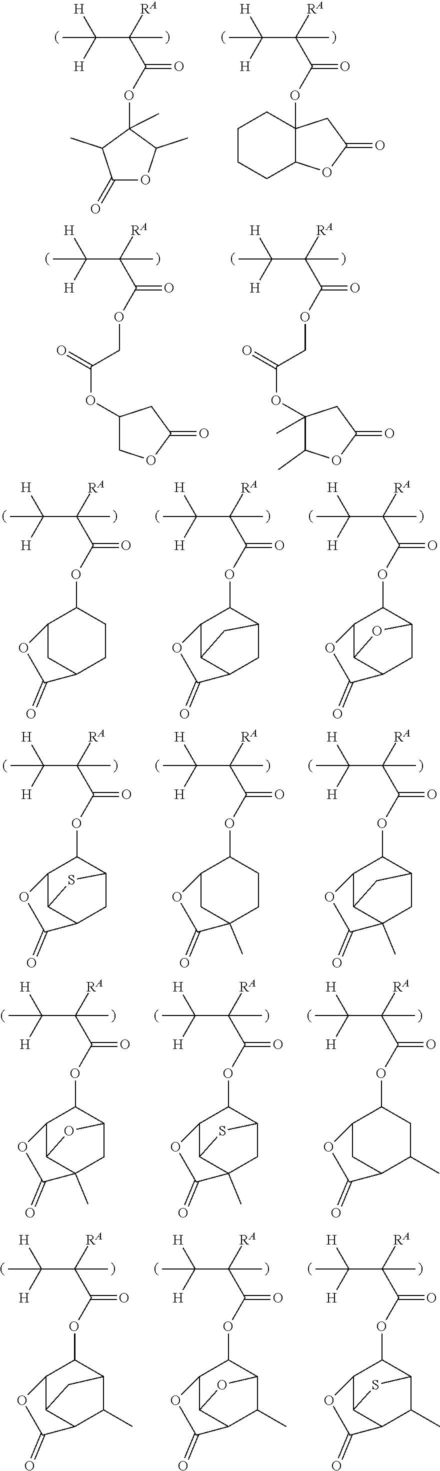

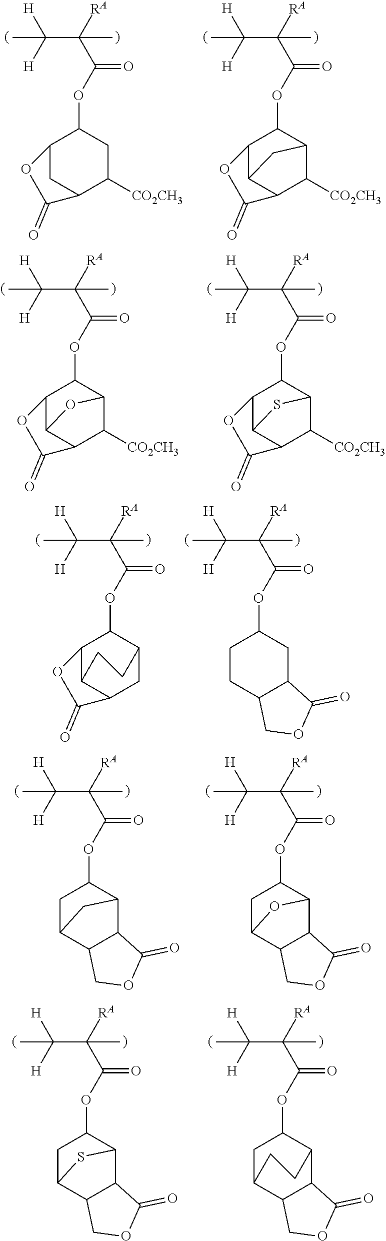

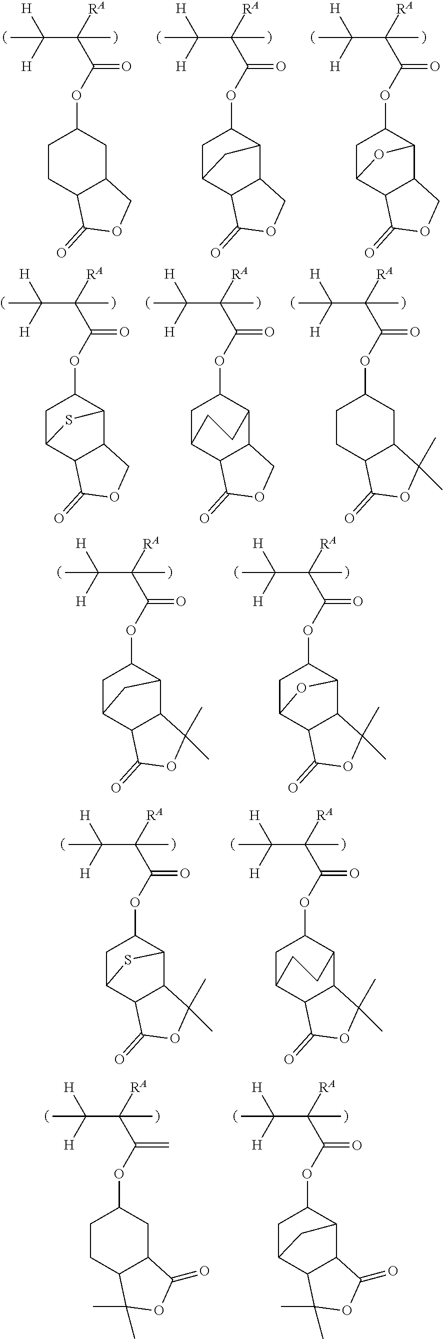

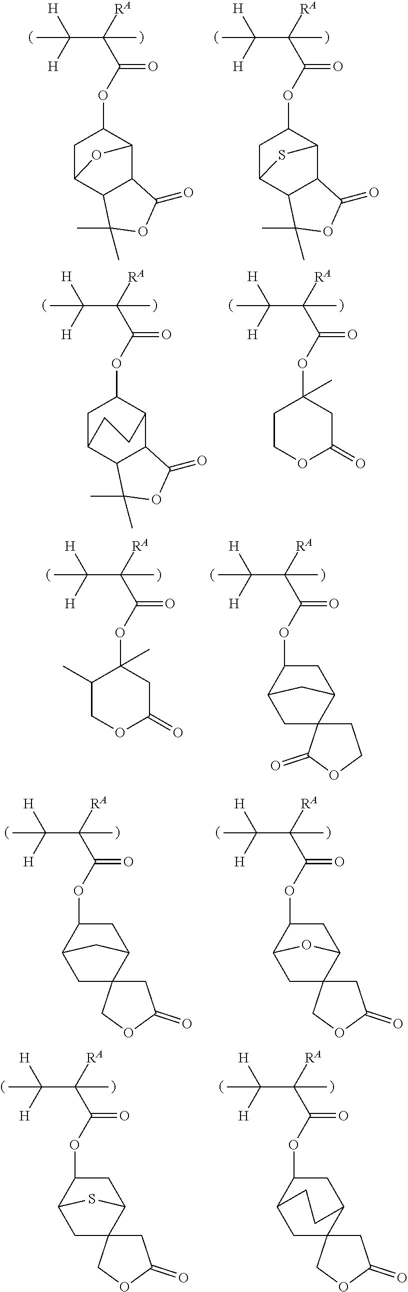

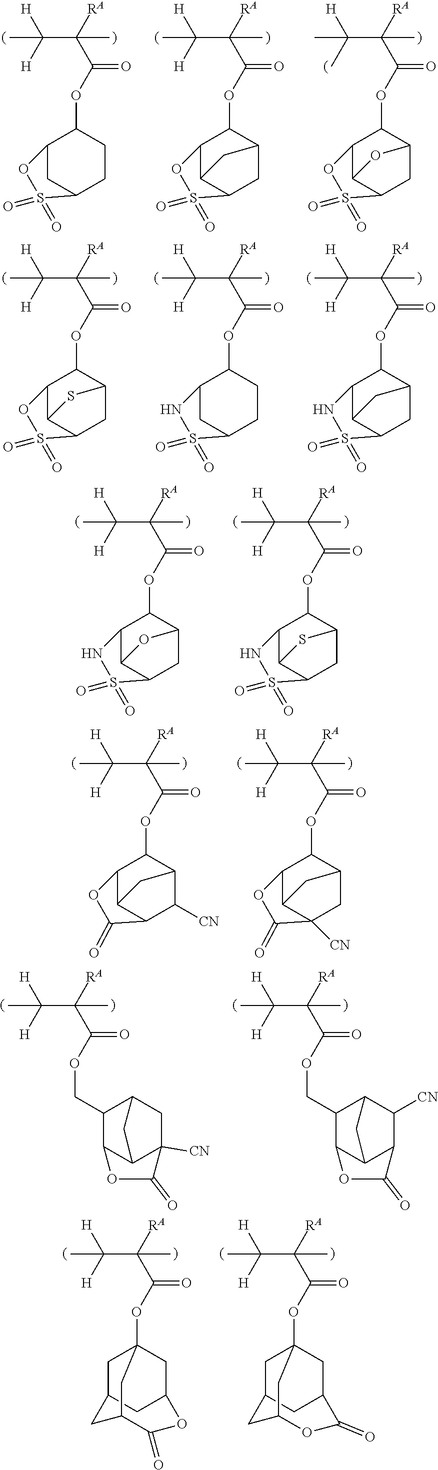

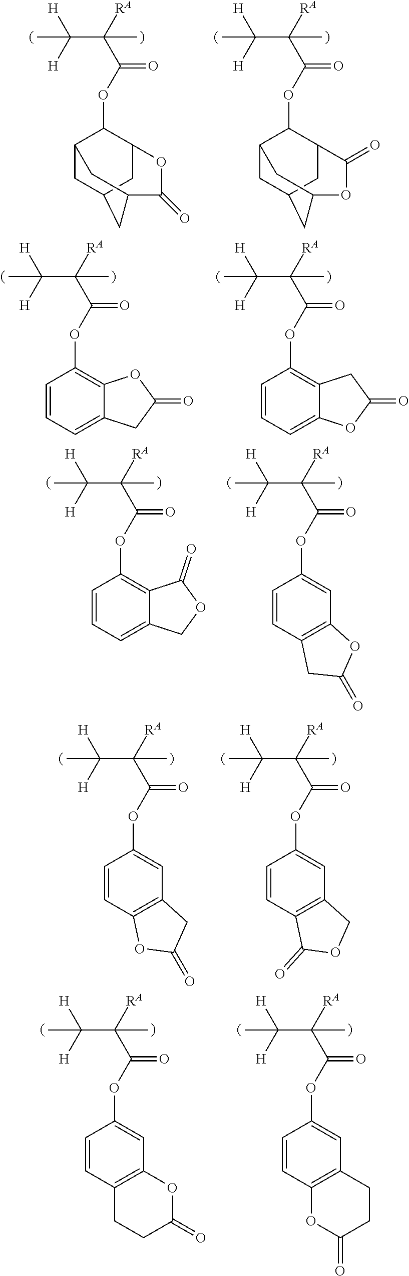

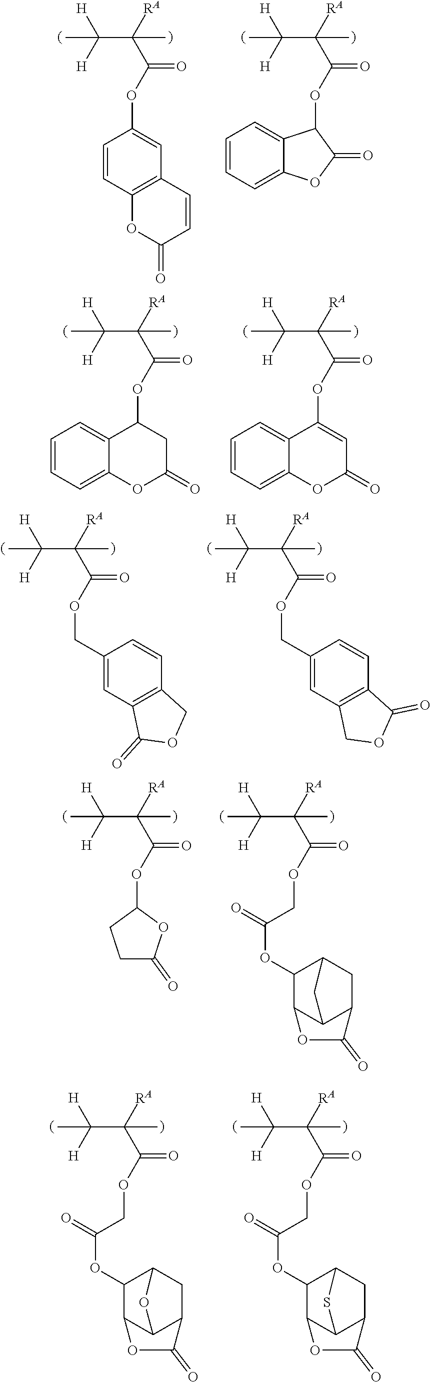

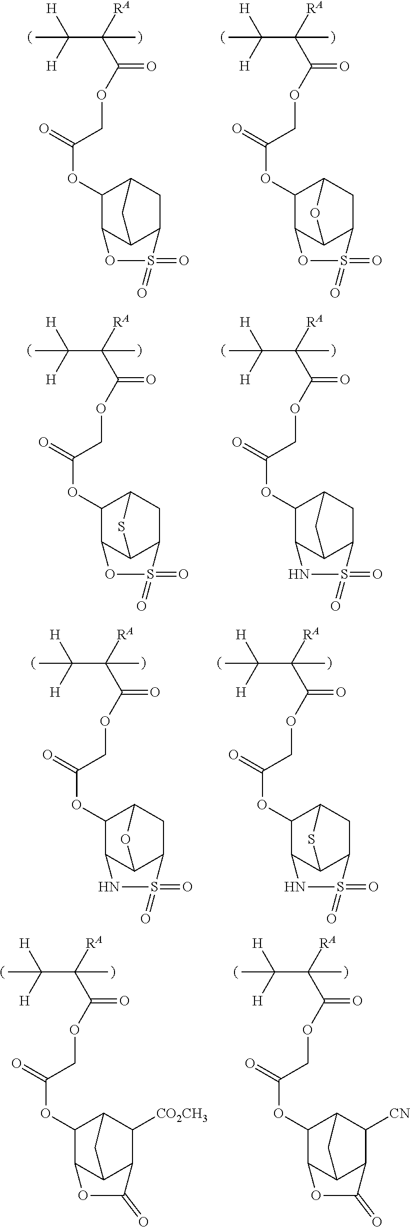

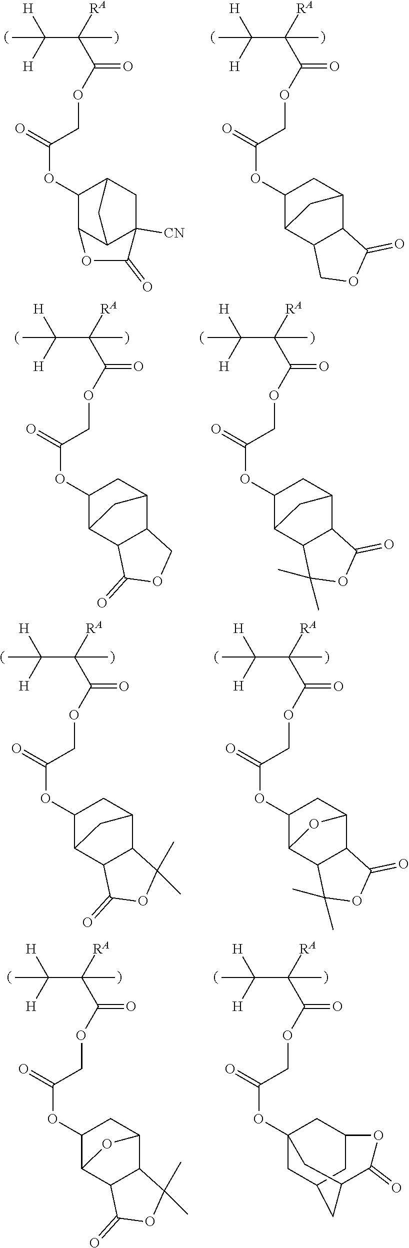

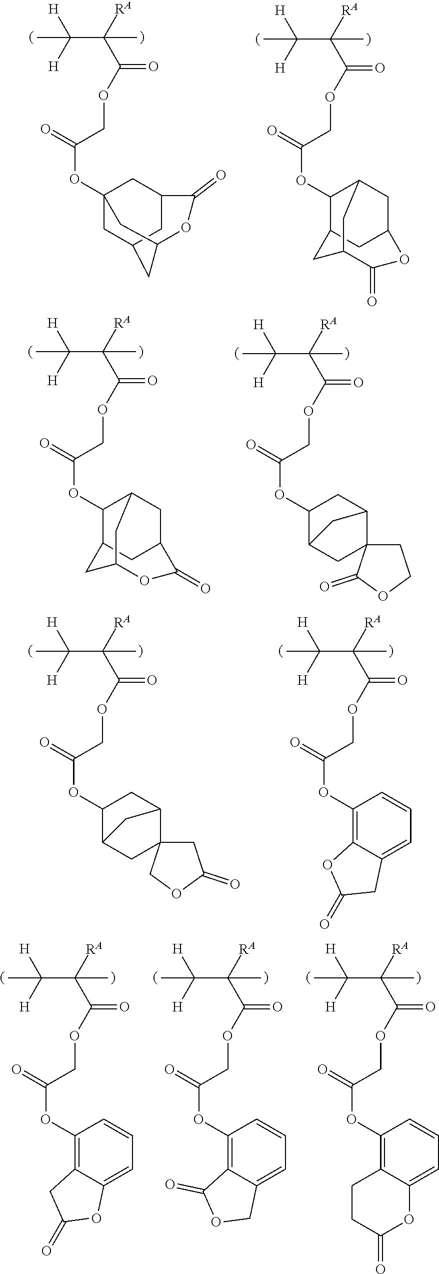

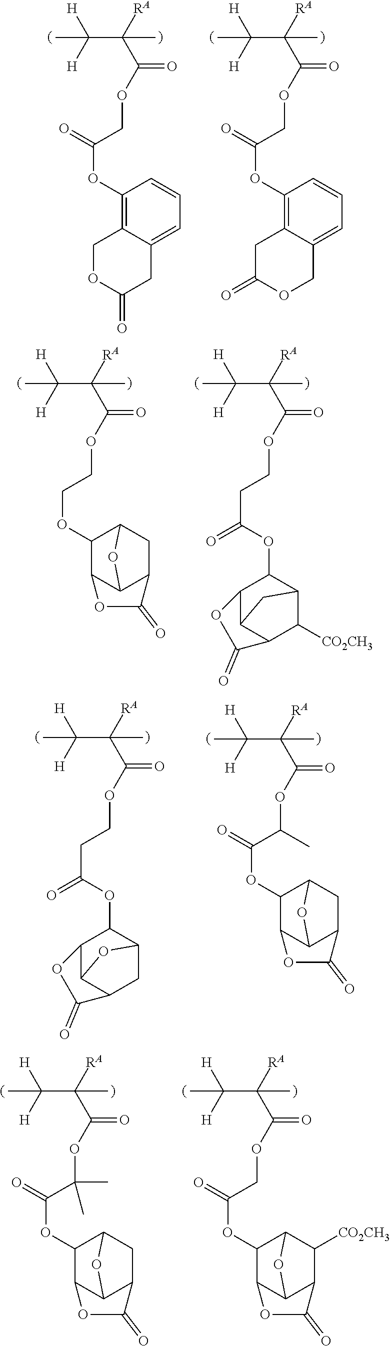

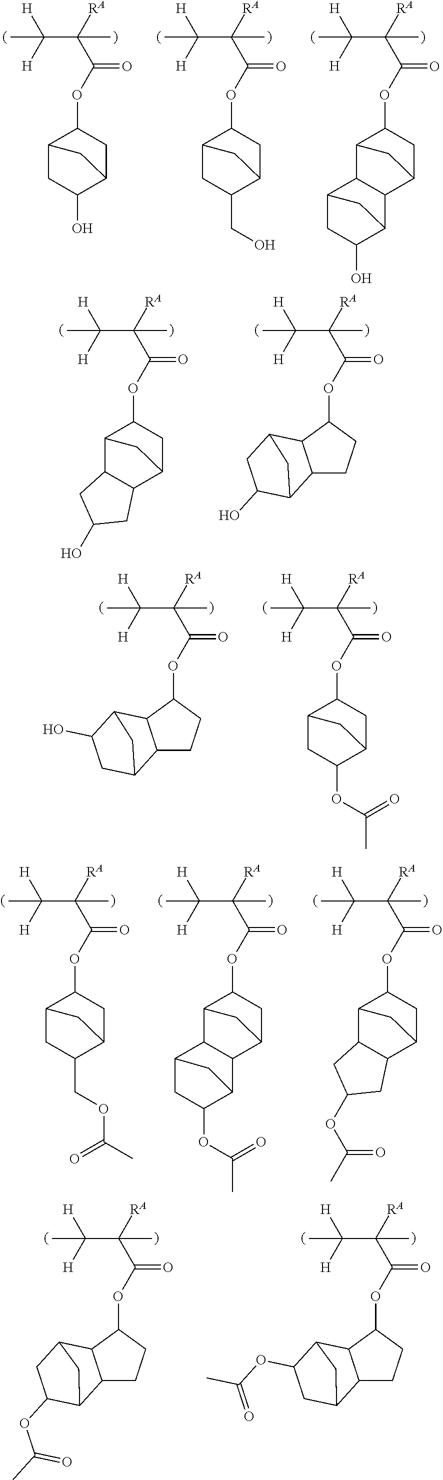

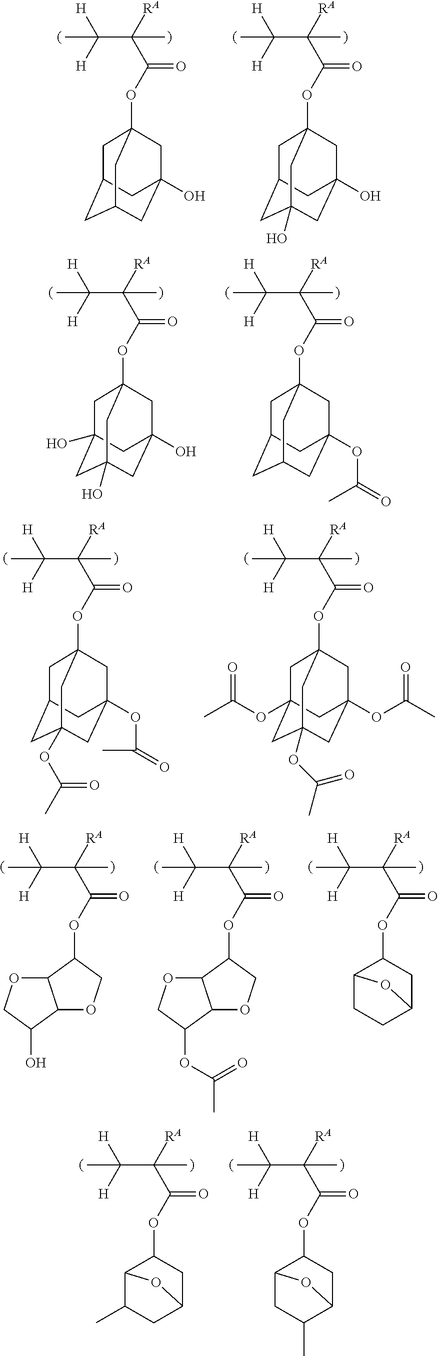

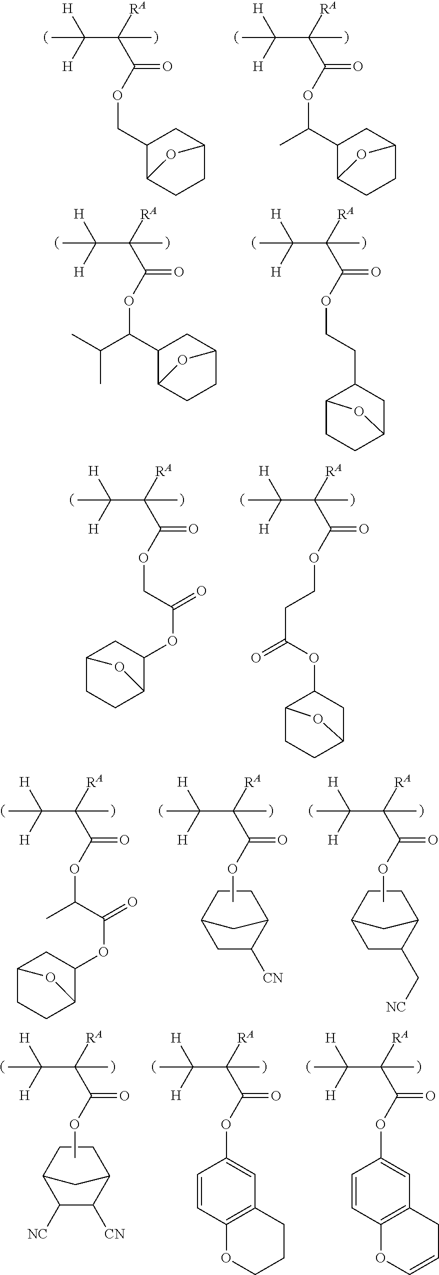

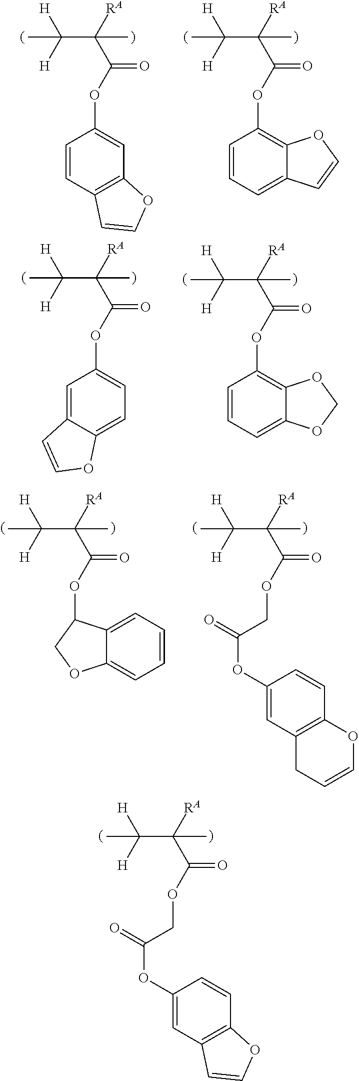

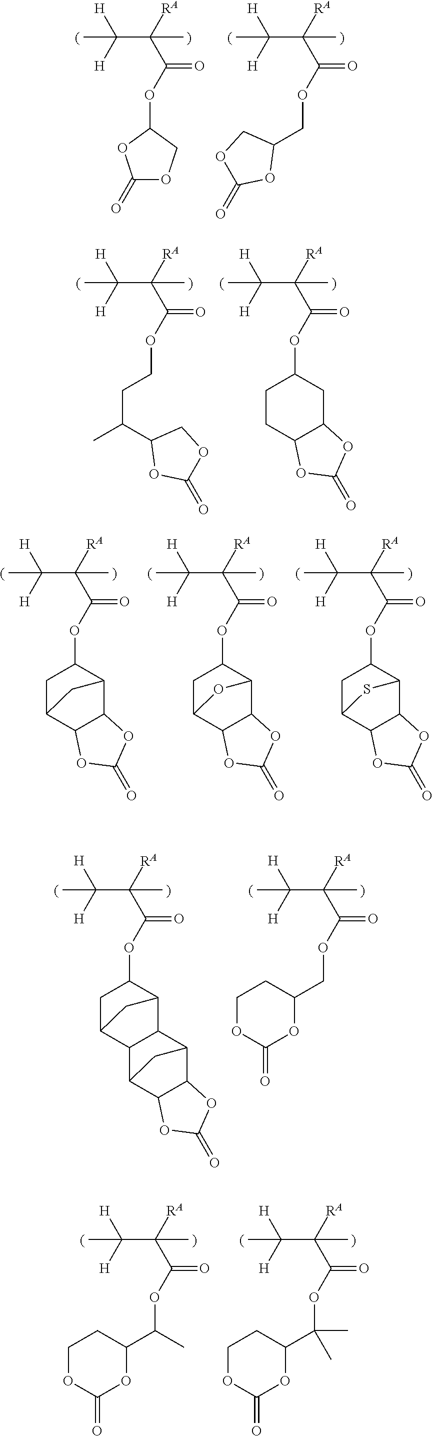

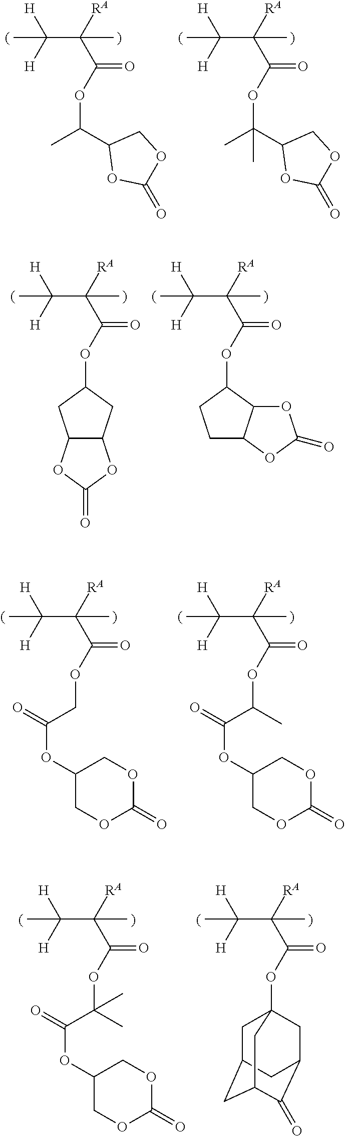

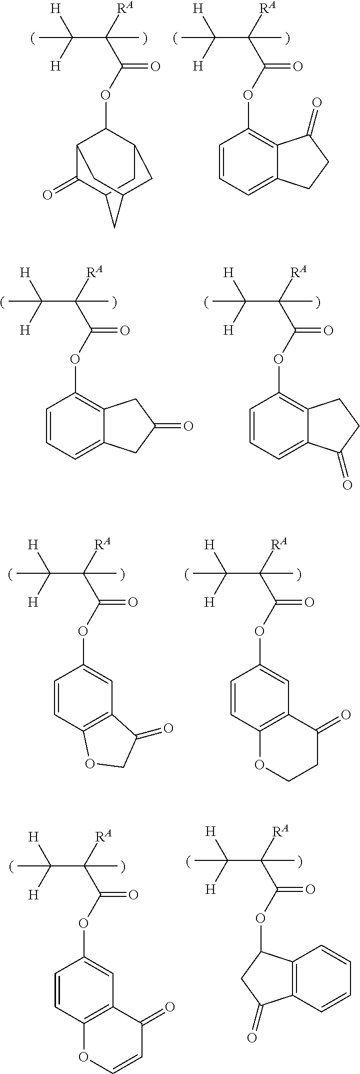

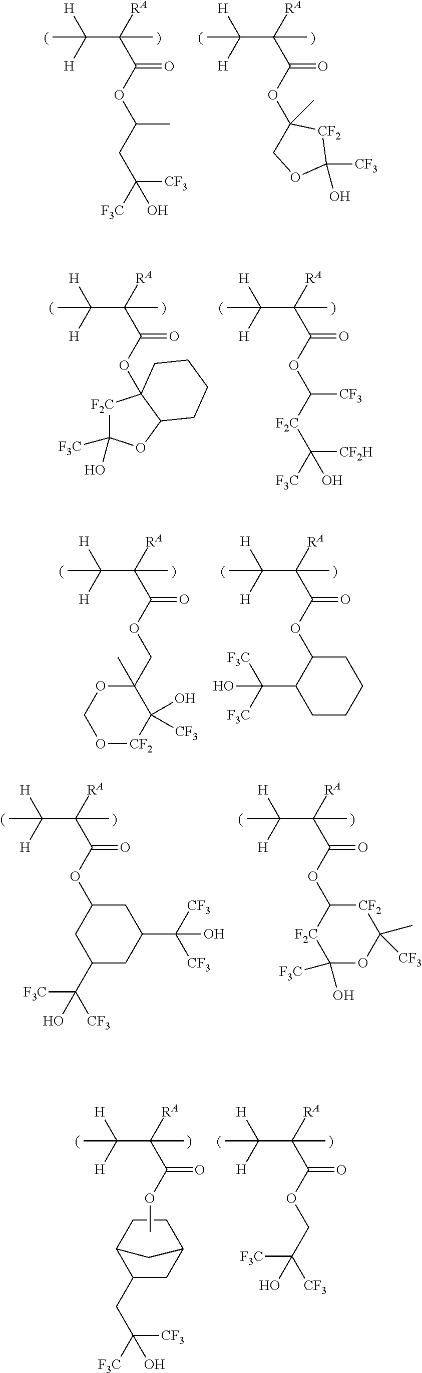

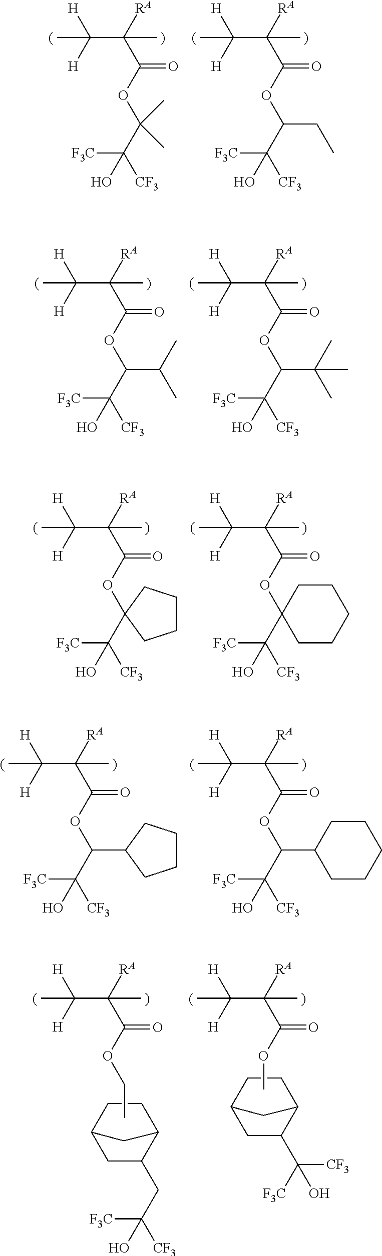

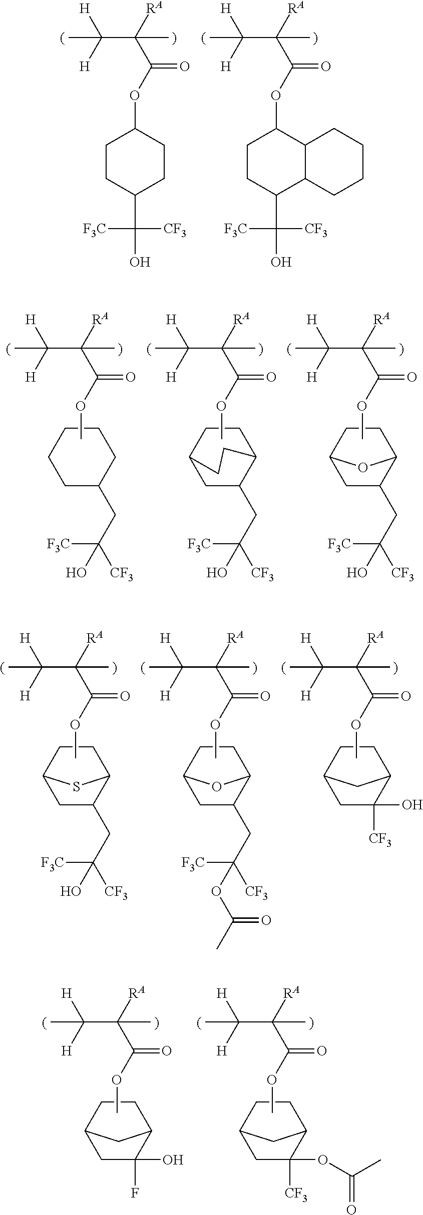

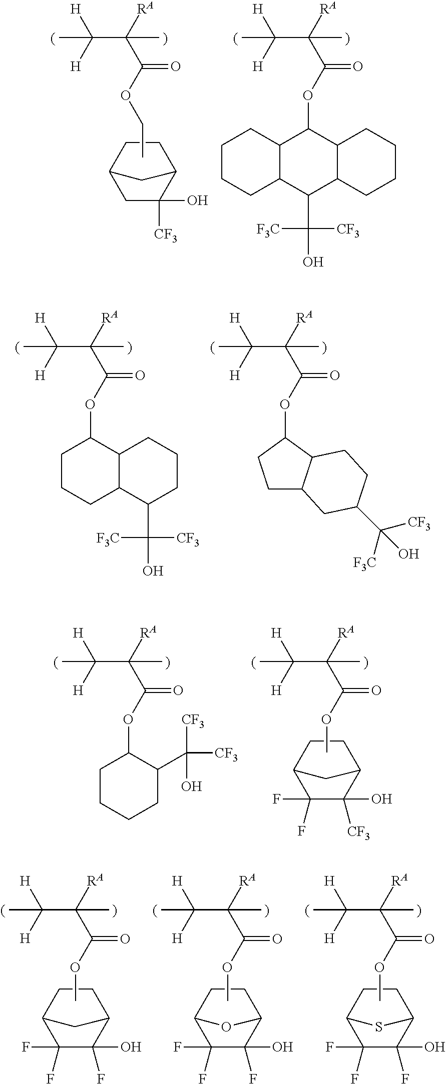

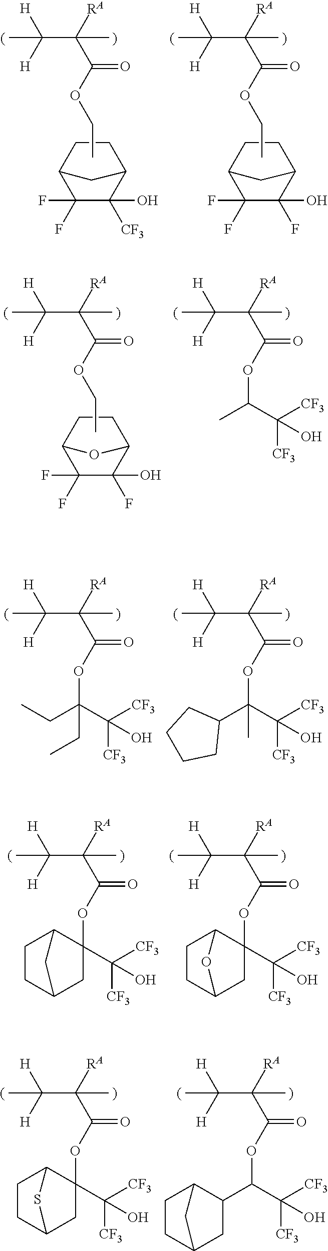

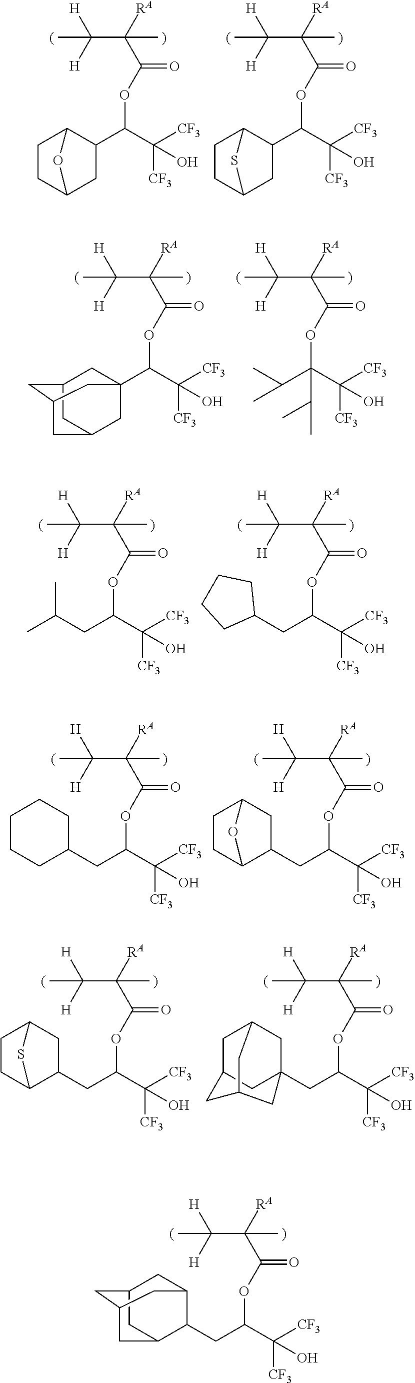

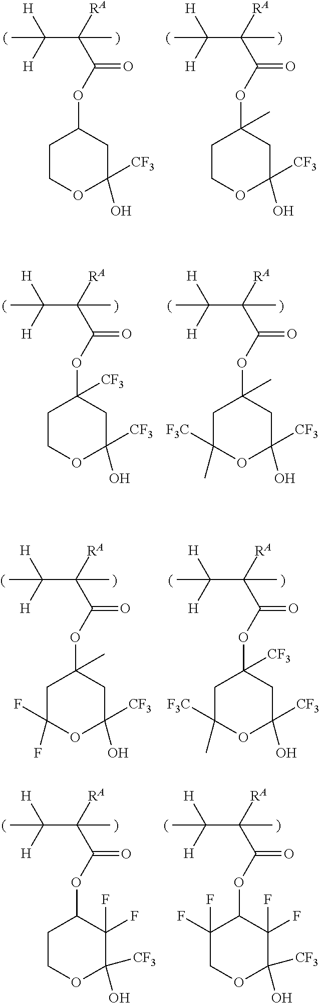

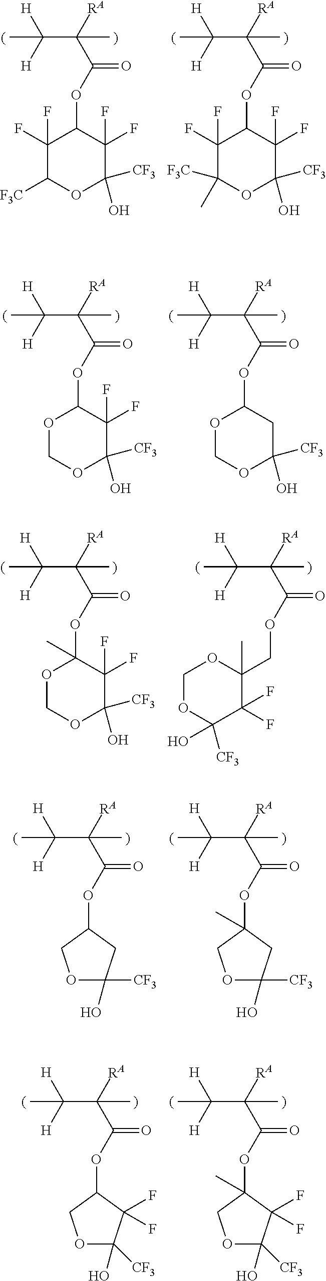

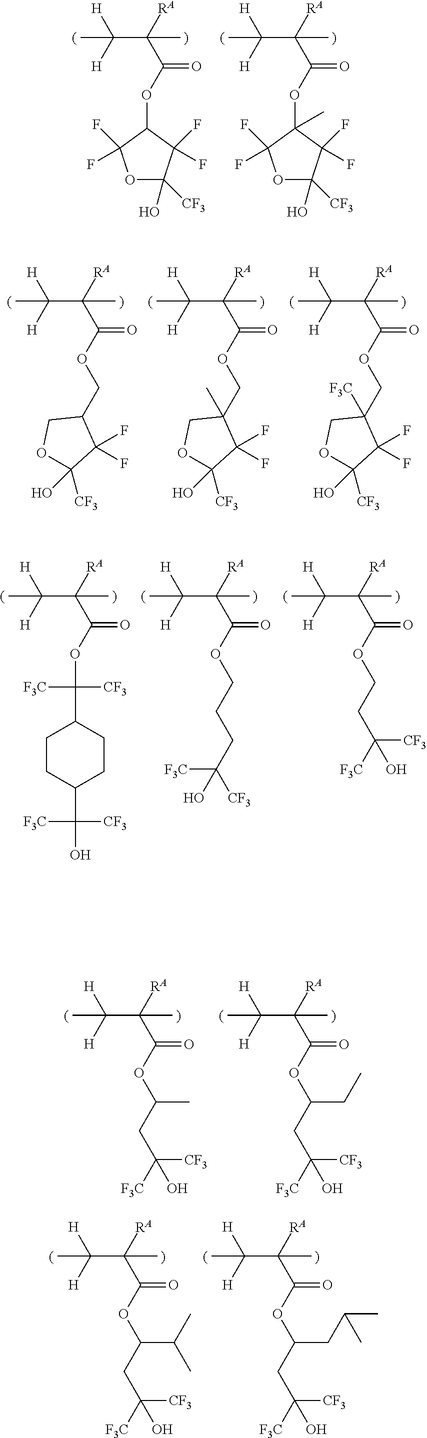

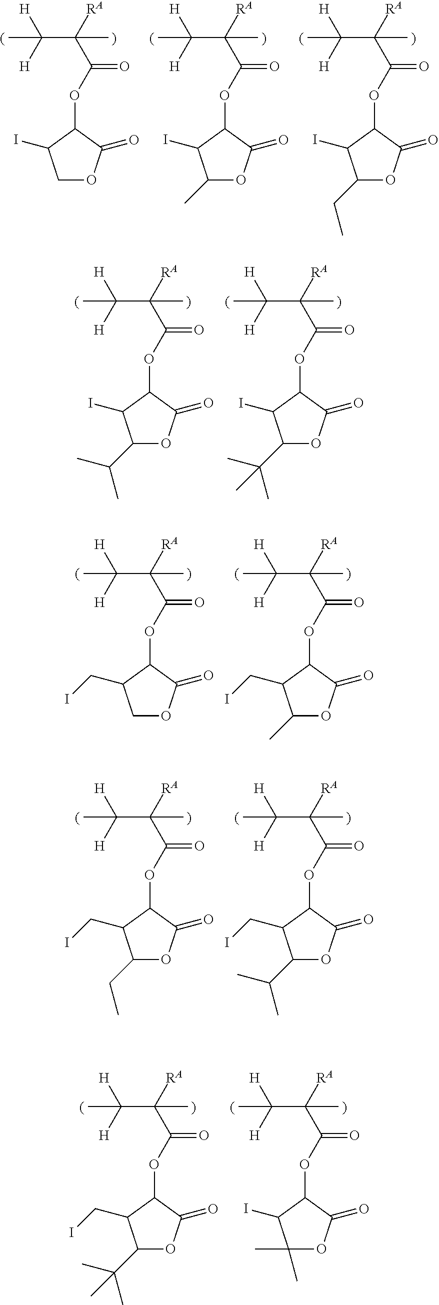

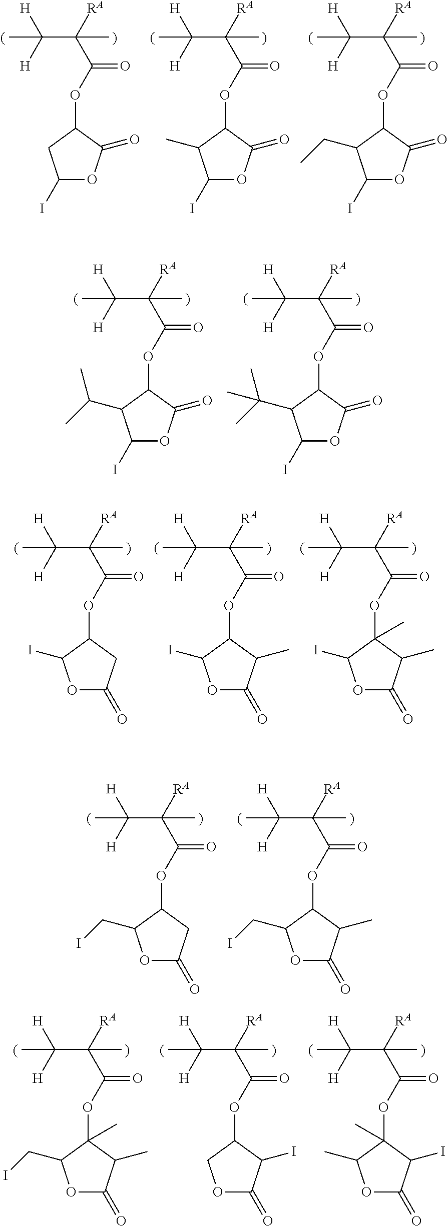

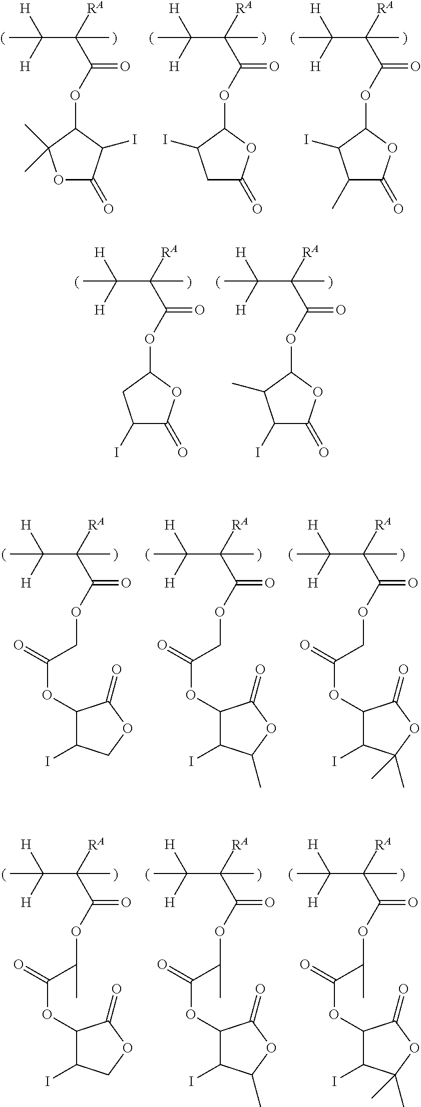

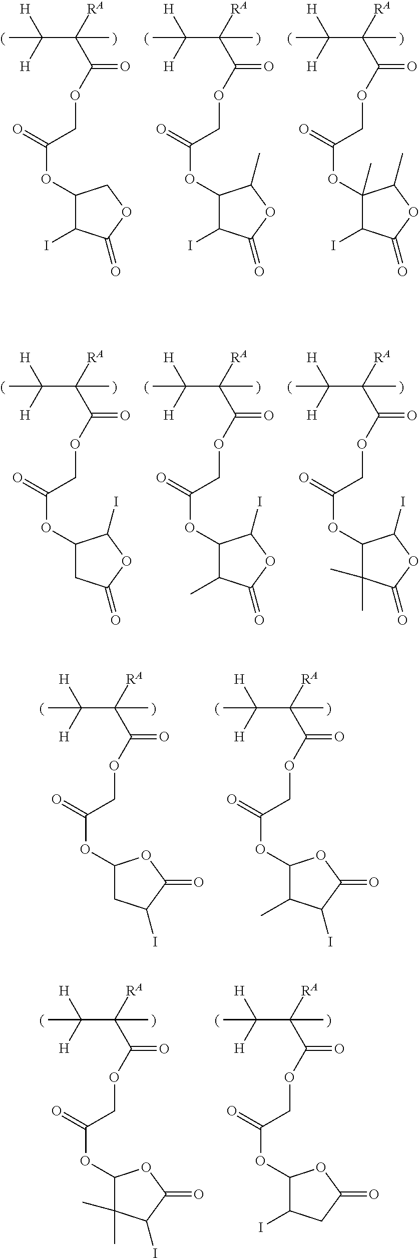

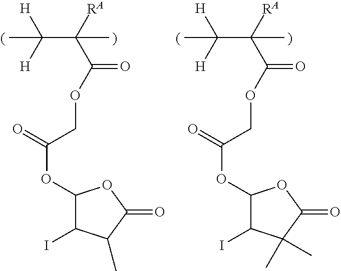

As the repeating unit-e, ones having a lactone ring as a polar group are particularly preferable in ArF lithography, and ones having a phenol moiety are preferable in KrF lithography, EB lithography and EUV lithography.

The polymer may further include a repeating unit (hereinafter also referred to as repeating unit-f) having a structure in which a hydroxy group is protected by an acid-labile group. The repeating unit-f is not particularly limited as long as it has one or more structures in which a hydroxy group is protected and the protecting group is decomposed by the action of an acid to generate a hydroxy group, preferably represented by the following general formula (f).

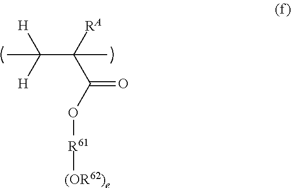

In the general formula (f), R^{A} is a hydrogen atom, a fluorine atom, a methyl group or a trifluoromethyl group. R⁶¹ is a hydrocarbon group having 1 to 30 carbon atoms and a valence of (e+1) and optionally containing a heteroatom. R⁶² is an acid-labile group. “e” is an integer from 1 to 4.

In the general formula (f), the acid-labile group represented by R⁶² may be any group that can be deprotected by the action of an acid to generate a hydroxy group. The structure of R⁶² is not particularly limited, but is preferably an acetal structure, a ketal structure, an alkoxycarbonyl group, or an alkoxymethyl group represented by the following formula (f1), and is particularly preferably an alkoxymethyl group represented by the following formula (f1).

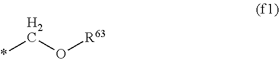

In the formula, * represents a bonding point; and R⁶³ is a hydrocarbyl group having 1 to 15 carbon atoms.

Specific examples of the acid-labile group represented by R⁶², the alkoxymethyl group represented by the general formula (f1), and the repeating unit-f are the same as those exemplified in the description of the repeating unit-d described in JP2020-111564A.

The polymer may further contain repeating unit-g derived from indene, benzofuran, benzothiophene, acenaphthylene, chromone, coumarin, norbornadiene, or derivatives thereof. Specific examples of monomers that provide the repeating unit-g include, but are not limited to, those shown below.

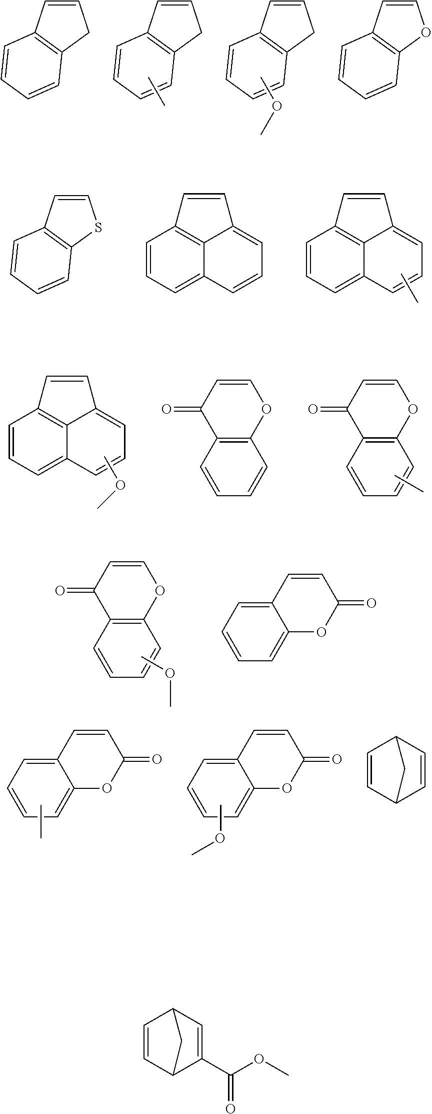

The polymer may further include repeating unit-h derived from styrene, indane, vinylpyridine, or vinylcarbazole.

In the polymer of the present invention, the content ratios of the repeating units-a, b1, b2, b3, c, d, e, f, g and h are preferably 0≤a≤0.4, 0≤b1≤0.8, 0≤b2≤0.8, 0≤b3≤0.6, 0≤c≤0.6, 0 d≤0.4, 0≤e≤0.6, 0≤f≤0.3, 0≤g≤0.3, and 0≤h≤0.3, and more preferably 0≤a≤0.3, 0≤b1≤0.7, 0≤b2≤0.7, 0≤b3≤0.5, 0≤c≤0.5, 0≤d≤0.3, 0≤e≤0.5, 0≤f≤0.2, 0≤g≤0.2, and 0≤h≤0.2. However, a+b1+b2+b3+c+d+e+f+g+h 1.0.

The weight average molecular weight (Mw) of the polymer is preferably 1,000 to 500,000, and more preferably 3,000 to 100,000. When Mw is within this range, sufficient etching resistance can be obtained, and there is no risk of deterioration in resolution due to inability to maintain a difference in dissolution rate before and after exposure. In the present invention, Mw is a value measured in terms of polystyrene by gel permeation chromatography (GPC) using tetrahydrofuran (THF) or N,N-dimethylformamide (DMF) as a solvent.

Furthermore, since the influence of Mw/Mn on the molecular weight distribution (Mw/Mn) of the polymer tends to become greater as the pattern rules become finer, it is preferable that Mw/Mn is a narrow dispersion of 1.0 to 2.0 in order to obtain a resist composition that is suitable for use with fine pattern dimensions. If it is within the above range, there will be few low-molecular-weight or high-molecular-weight polymers compared to Mw, and there will be no risk of foreign matter being found on the pattern or the shape of the pattern being deteriorated after exposure.

As a method for synthesizing the polymer, an example is to polymerize a monomer that gives the repeating unit mentioned above by heating in an organic solvent with a radical polymerization initiator added to it.

Specific examples of organic solvents used during polymerization include toluene, benzene, THF, diethyl ether, dioxane, cyclohexane, cyclopentane, methyl ethyl ketone (MEK), propylene glycol monomethyl ether acetate (PGMEA), and γ-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of these initiators added is preferably 0.01 to 25 mol % based on the total amount of monomers to be polymerized. The reaction temperature is preferably 50 to 150° C., and more preferably 60 to 100° C. The reaction time is preferably 2 to 24 hours, and from the viewpoint of production efficiency, more preferably 2 to 12 hours.

The polymerization initiator may be added to the monomer solution and supplied to the reaction vessel, or an initiator solution may be prepared separately from the monomer solution and each may be independently supplied to the reaction vessel. During the waiting period, radicals generated from the initiator may cause the polymerization reaction to progress and produce an ultra-polymer, so from the viewpoint of quality control, the monomer solution and the initiator solution should be prepared independently and added dropwise. The acid-labile group may be used as is after being introduced into the monomer, or it may be protected or partially protected after polymerization. Furthermore, a known chain transfer agent such as dodecylmercaptan or 2-mercaptoethanol may be used in combination to adjust the molecular weight. In this case, the amount of these chain transfer agents added is preferably 0.01 to 20 mol % based on the total amount of monomers to be polymerized.

In the case of a monomer containing a hydroxy group, the hydroxy group may be substituted with an acetal group that is easily deprotected with an acid such as an ethoxyethoxy group during polymerization, and deprotection may be performed with a weak acid and water after polymerization, or alkaline hydrolysis may be performed after polymerization after substitution with an acetyl group, a formyl group, a pivaloyl group, etc.

If copolymerizing hydroxystyrene or hydroxyvinylnaphthalene, hydroxystyrene or hydroxyvinylnaphthalene and other monomers may be polymerized by heating in an organic solvent with the addition of a radical polymerization initiator, or acetoxystyrene or acetoxyvinylnaphthalene may be used, and after polymerization, the acetoxy group may be deprotected by alkaline hydrolysis to produce polyhydroxystyrene or hydroxypolyvinylnaphthalene.

As the base for alkaline hydrolysis, aqueous ammonia, triethylamine, etc. can be used. Furthermore, the reaction temperature is preferably −20 to 100° C., and more preferably 0 to 60° C. The reaction time is preferably 0.2 to 100 hours, and more preferably 0.5 to 20 hours.

Note that the amount of each monomer in the monomer solution may be appropriately set, for example, so as to achieve a preferable content ratio of the repeating units mentioned above.

The polymer obtained by the above production method may be use the reaction solution obtained by the polymerization reaction as the final product, or by adding the polymerization solution to a poor solvent and performing a purification process such as a reprecipitation method to obtain a powder. Although the powder may be handled as a final product, from the viewpoint of work efficiency and quality stabilization, it is preferable to handle as the final product a polymer solution obtained by dissolving the powder obtained in the purification process in a solvent.

Specific examples of the solvent used in this case, described in paragraphs [0144] to [0145] of JP2008-111103A, include ketones such as cyclohexanone and methyl-2-n-pentyl ketone; alcohols such as 3-methoxybutanol, 3-methyl-3-methoxybutanol, 1-methoxy-2-propanol, 1-ethoxy-2-propanol,; ethers such as propylene glycol monomethyl ether (PGME), ethylene glycol monomethyl ether, propylene glycol monoethyl ether, ethylene glycol monoethyl ether, propylene glycol dimethyl ether, diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, propylene glycol mono tert-butyl ether acetate; lactones such as GBL; alcohols such as diacetone alcohol (DAA); high-boiling-point alcohol solvents such as diethylene glycol, propylene glycol, glycerin, 1,4-butanediol, and 1,3-butanediol; and mixed solvents thereof.

The concentration of the polymer in the polymer solution is preferably 0.01 to 30% by mass, and more preferably 0.1 to 20% by mass.

The reaction solution and polymer solution are preferably filtered. By performing filter filtration, foreign substances and gels that may cause defects can be removed, and this is effective in terms of quality stabilization.

Examples of the filter material used for the filter filtration include fluorocarbon-based, cellulose-based, nylon-based, polyester-based, and hydrocarbon-based materials, but in the filtration process of chemically amplified resist compositions, filters such as so-called Teflon (registered trademark) made of fluorocarbon, hydrocarbon such as polyethylene or polypropylene, and nylon are preferable. The pore size of the filter can be appropriately selected depending on the target cleanliness, but is preferably 100 nm or less, and more preferably 20 nm or less. Furthermore, one type of these filters may be used alone, or a plurality of filters may be used in combination. For the filtration method, the solution may be passed through just once, but it is more preferable to circulate the solution and perform filtration a plurality of times. The filtration step can be performed in any order and any number of times in the polymer production process, but it is preferable to filter the reaction solution after the polymerization reaction, the polymer solution, or both.

### [Chemically Amplified Resist Composition]

The present invention also provides a chemically amplified resist composition contains a base polymer (A) containing the above-described polymer.

### [Base Polymer (A)]

The chemically amplified resist composition of the present invention contains a base polymer containing the above-mentioned polymer as a component (A).

The polymer may be used as one type alone or by combining two or more with different composition ratios, Mw, and/or Mw/Mn. In addition to the above-mentioned polymer, the base polymer (A) may also contain a hydrogenated product of a ring-opening metathesis polymer, and for this, those described in JP2003-066612A can be used.

Furthermore, in the present invention, the chemically amplified resist composition preferably further contains at least one type selected from an organic solvent (B), a quencher (C) other than the sulfonium salt type quencher, an acid generator (D), and a surfactant (E). In the following sections, each component is explained in detail.

### [Organic Solvent (B)]

The chemically amplified resist composition of the present invention may contain an organic solvent as a component (B). The organic solvent (B) is not particularly limited as long as it is capable of dissolving the components mentioned above and below. Specific examples of such organic solvents include ketones such as cyclopentanone, cyclohexanone, and methyl-2-n-pentyl ketone; alcohols such as 3-methoxybutanol, 3-methyl-3-methoxybutanol, 1-methoxy-2-propanol, and 1-ethoxy-2-propanol; ketoalcohols such as DAA; ethers such as PGME, ethylene glycol monomethyl ether, propylene glycol monoethyl ether, ethylene glycol monoethyl ether, propylene glycol dimethyl ether, and diethylene glycol dimethyl ether; esters such as PGMEA, propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono tert-butyl ether acetate; lactones such as GBL; and mixed solvents thereof.

Among these organic solvents, 1-ethoxy-2-propanol, PGMEA, cyclohexanone, GBL, DAA, and mixed solvents thereof are preferable, as they have particularly excellent solubility for the base polymer for component (A).

In the chemically amplified resist composition of the present invention, the content of the organic solvent (B) is preferably 200 to 5,000 parts by mass, and more preferably 400 to 3,500 parts by mass, based on 80 parts by mass of the base polymer (A). The organic solvent (B) may be used as one type alone or by mixing two or more.

### [Other Quencher (C)]

The chemically amplified resist composition of the present invention may contain a quencher other than the sulfonium salt type quencher as a component (C) (hereinafter also referred to as other quencher). In the present invention, “quencher” means a material that traps the acid generated by the photoacid generator in the chemically amplified resist composition, thereby preventing the acid from diffusing into unexposed areas, and forming a desired pattern.

Other quencher (C) includes onium salts represented by the following formula (1) or (2).

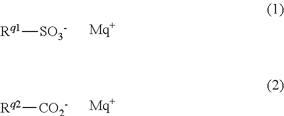

In the general formula (1), R^{q1} is a hydrogen atom or a hydrocarbyl group having 1 to 40 carbon atoms and optionally containing a heteroatom, excluding those in which the hydrogen atom bonded to the carbon atom at the α-position of the sulfo group is substituted with a fluorine atom or a fluoroalkyl group. In the general formula (2), R^{q2} is a hydrogen atom or a hydrocarbyl group having 1 to 40 carbon atoms and optionally containing a heteroatom.

Specific examples of the hydrocarbyl group having 1 to 40 carbon atoms represented by R^{q1} include alkyl groups having 1 to 40 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 40 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decyl group, and an adamantyl group; and aryl groups having 6 to 40 carbon atoms, such as a phenyl group, a naphthyl group, and an anthracenyl group. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

Specific examples of the hydrocarbyl group represented by R^{q2} include, in addition to the substituents exemplified as specific examples of R^{q1}, fluorinated saturated hydrocarbyl groups such as a trifluoromethyl group and a trifluoroethyl group, and fluorinated aryl groups such as a pentafluorophenyl group and a 4-trifluoromethylphenyl group.

Specific examples of the anion of the onium salt represented by the general formula (1) include, but are not limited to, those shown below.

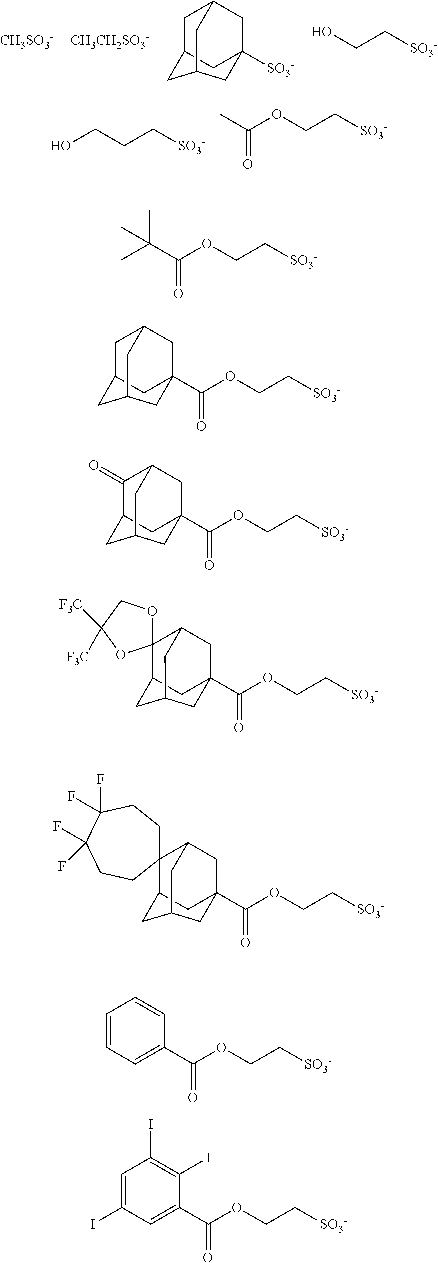

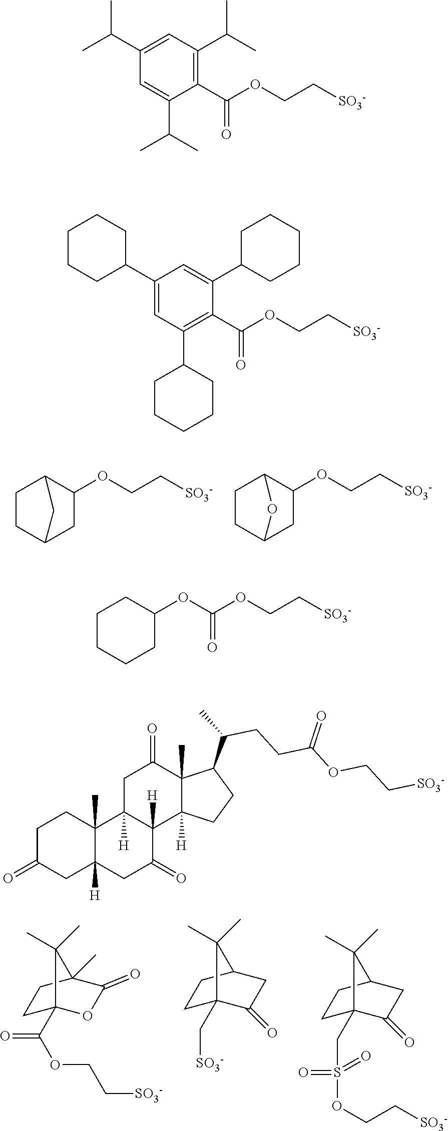

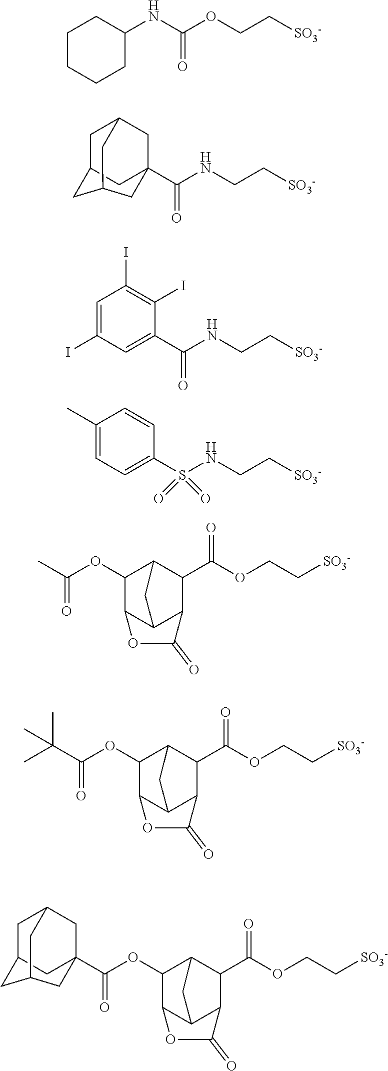

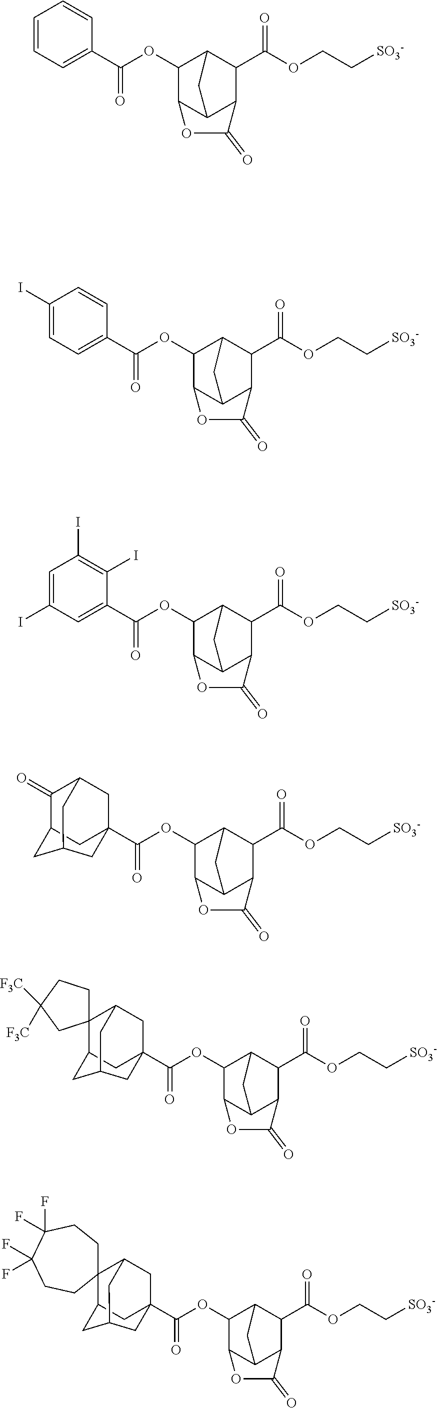

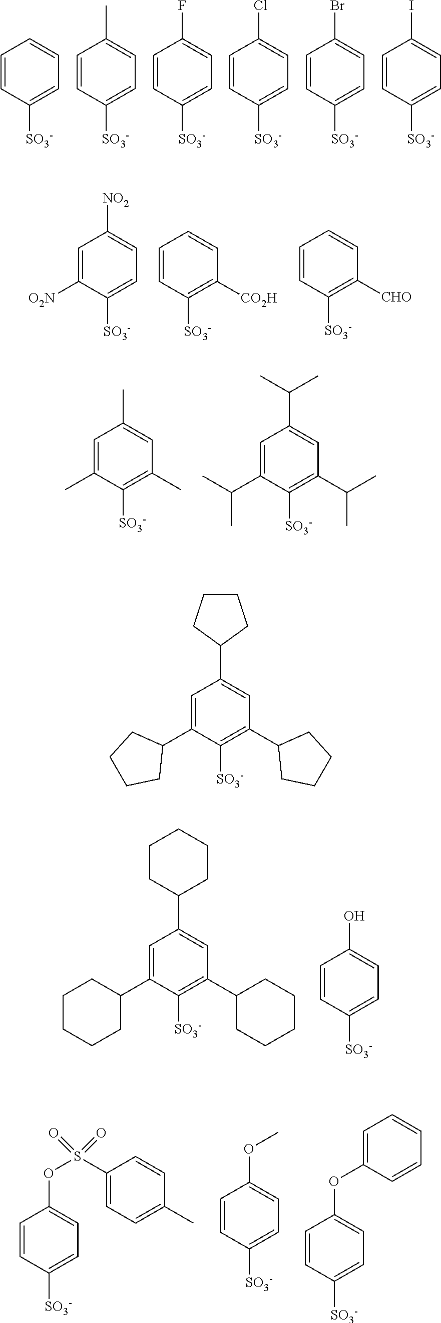

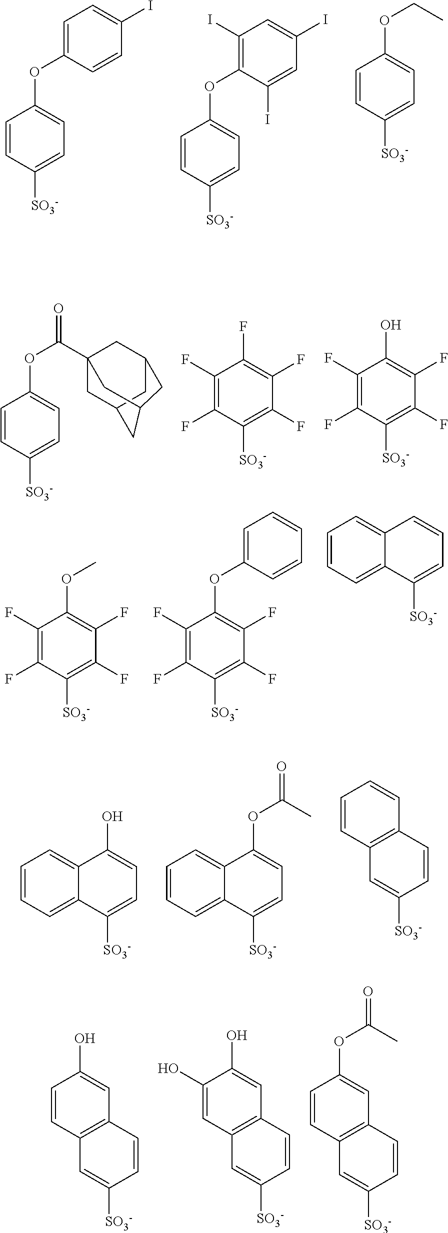

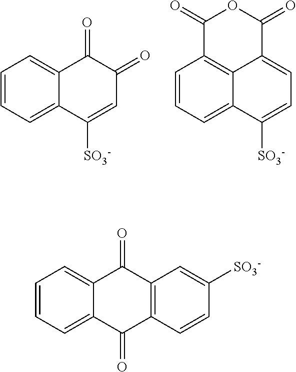

Specific examples of the anion of the onium salt represented by the general formula (2) include, but are not limited to, those shown below.

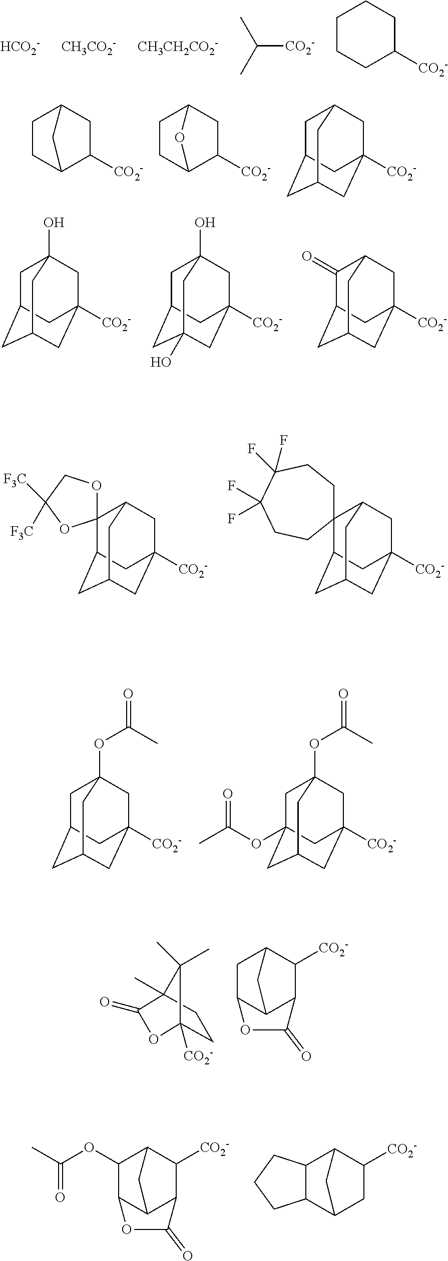

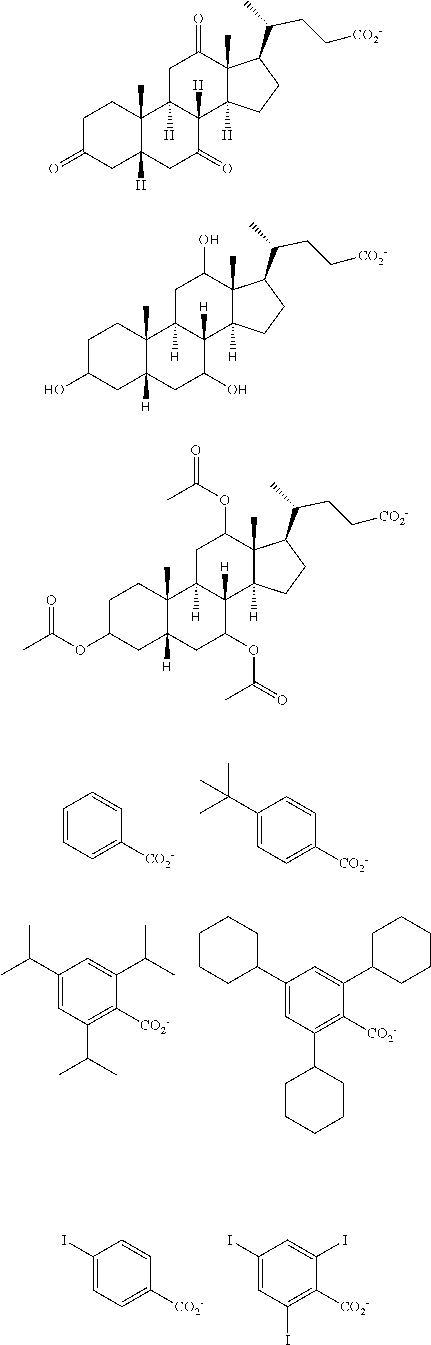

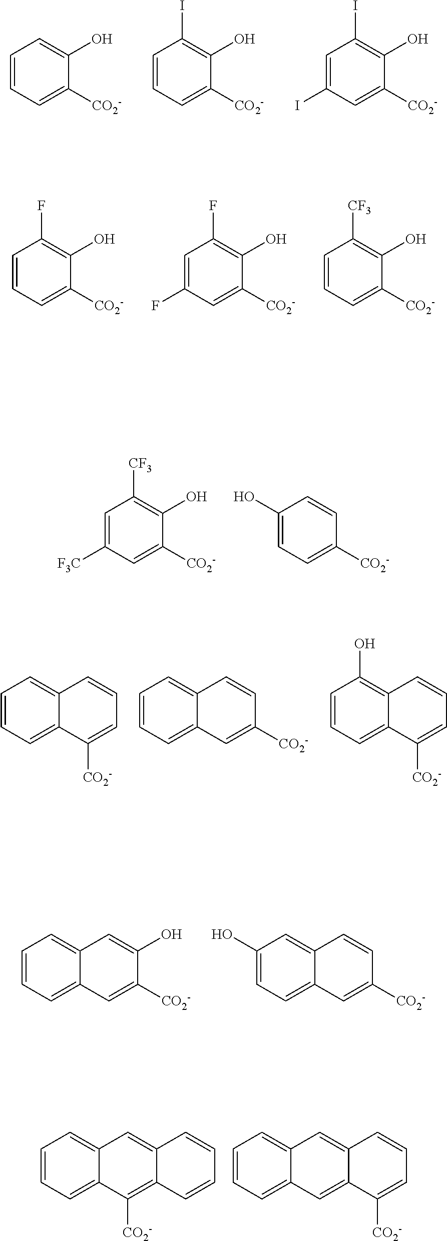

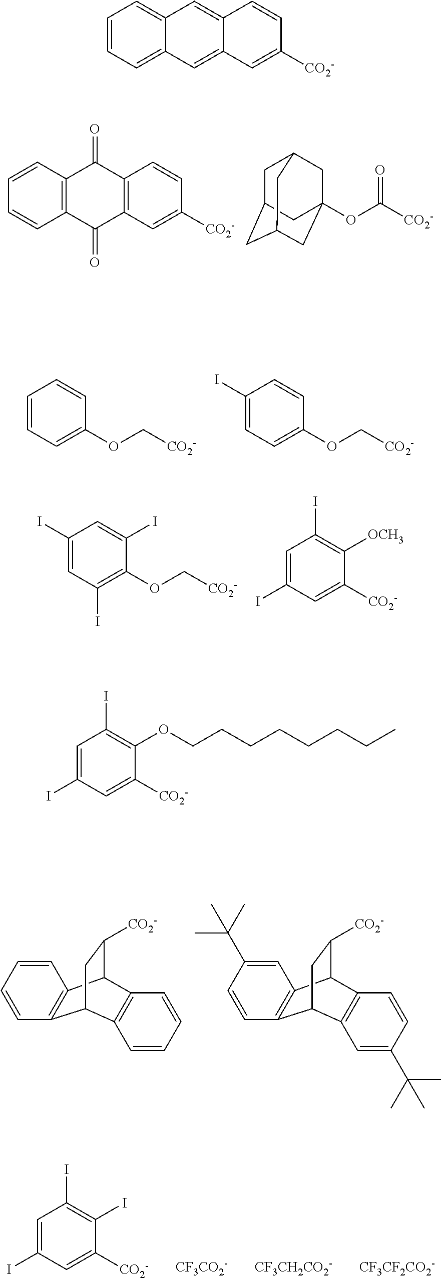

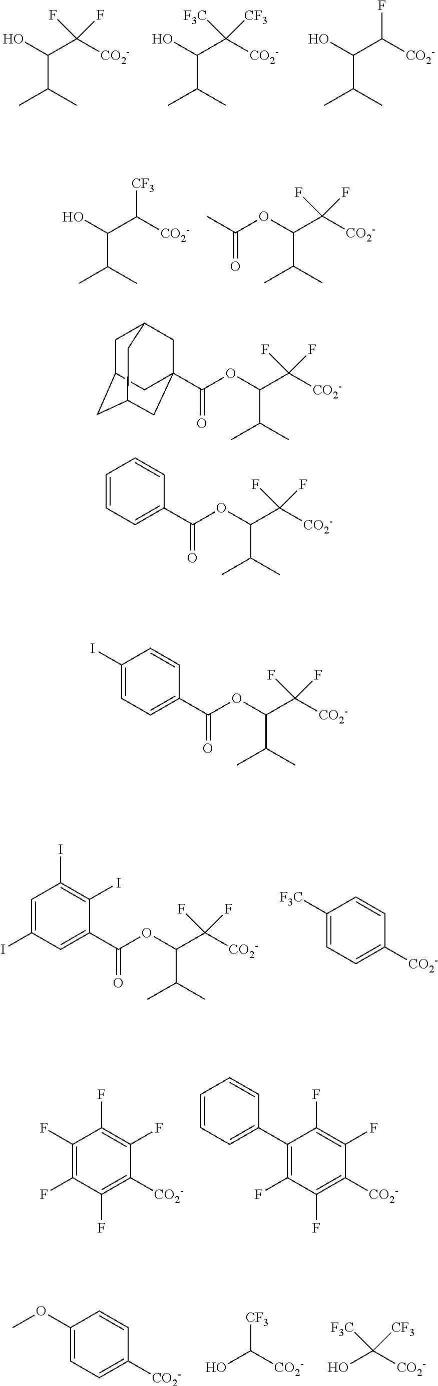

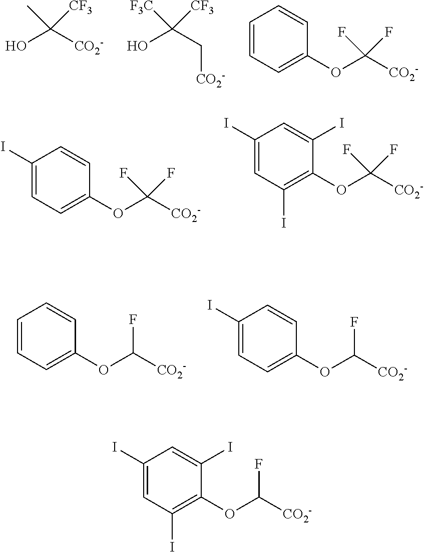

In the general formulae (1) and (2), Mq⁺ is an onium cation. The onium cation is preferably a sulfonium cation, an iodonium cation, or an ammonium cation. Specific examples of the sulfonium cation include, but are not limited to, ones similar to those exemplified as the sulfonium cation of the sulfonium salt type monomer represented by the general formula (a) those described in paragraphs [0102] to [0125] of JP2024-003744A, those described in paragraphs [0044] to [0049] of W02024/128017A, those described in paragraphs [0035] to [0046] of JP7491173B2, and those represented by the general formula (d3). Specific examples of the iodonium cation include, but are not limited to, those described in paragraph [0181] of JP2024-000259A. The ammonium cation is preferably represented by the following general formula (am-1), but is not limited to thereto.

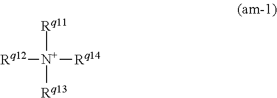

In the general formula (am-1), R^{q11} to R^{g14} are each independently a hydrocarbyl group having 1 to 40 carbon atoms and optionally containing a heteroatom. Also, R^{q11} and R^{q12} may be bonded to each other to form a ring together with the nitrogen atom to which they are bonded. Specific examples of the hydrocarbyl group include ones similar to those exemplified as the hydrocarbyl group represented by R² in the description of the general formula (a).

Specific examples of the ammonium cation represented by the general formula (am-1) include, but are not limited to, those shown below.

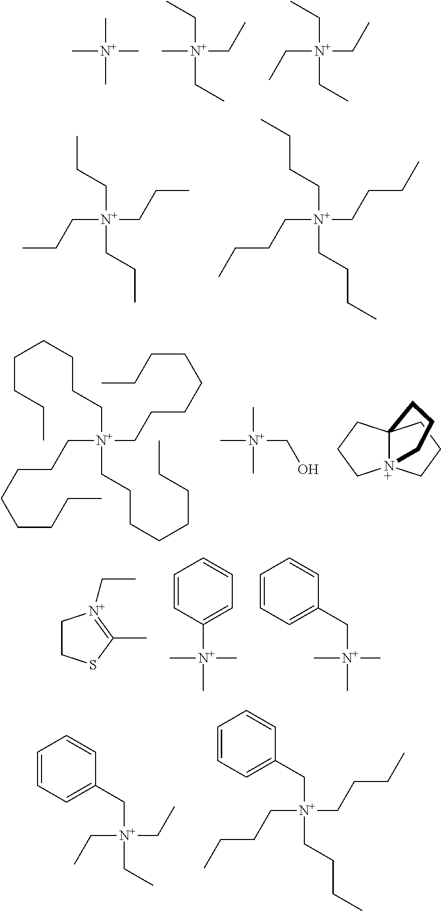

Specific examples of onium salts represented by formula (1) or (2) include any combination of the anions and cations mentioned above. These onium salts can be easily prepared by ion exchange reactions using known organic chemical methods. For information on ion exchange reactions, see, for example, JP2007-145797A.

The onium salt represented by general formula (1) or (2) acts as a quencher in the chemically amplified resist composition of the present invention. This is because each counter anion of the onium salt is a conjugate base of a weak acid. The term “weak acid” as used herein means one having an acidity that cannot deprotect the acid-labile group of the acid-labile group-containing unit used in the base polymer. When the onium salt represented by general formula (1) or (2) is used in combination with an onium salt type photoacid generator having a conjugate base of a strong acid such as a sulfonic acid fluorinated at the α-position as a counter anion, it functions as a quencher. In other words, when an onium salt that generates a strong acid such as a sulfonic acid fluorinated at the α-position is mixed with an onium salt that generates a weak acid such as a non-fluorinated sulfonic acid or a carboxylic acid, then a strong acid generated from a photoacid generator by high-energy irradiation collides with an onium salt having an unreacted weak acid anion, the weak acid is released by salt exchange and an onium salt having a strong acid anion is generated. In this process, the strong acid is exchanged for a weak acid with lower catalytic ability, so the acid appears to be deactivated and acid diffusion can be controlled.

In addition, as the quencher (C), onium salts having a sulfonium cation and a phenoxide anion moiety in the same molecule described in JP6848776B2, and furthermore, onium salts having a sulfonium cation and a carboxylate anion moiety in the same molecule described in JP6583136B2 and JP2020-200311A, and onium salts having an iodonium cation and a carboxylate anion moiety in the same molecule described in JP6274755B2 can also be used.

Here, when the photoacid generator that generates a strong acid is an onium salt, as mentioned above, the strong acid generated by high-energy irradiation can be exchanged for a weak acid, but on the other hand, it is thought that the weak acid generated by high-energy irradiation collides with the onium salt that generates the unreacted strong acid and is unlikely to undergo salt exchange. This is due to the phenomenon that the onium cation is more likely to form an ion pair with the anion of the strong acid.

When the chemically amplified resist composition of the present invention contains an onium salt represented by general formula (1) or (2) as the quencher (C), the content is preferably 0.1 to 20 parts by mass, and more preferably 0.1 to 10 parts by mass, relative to 80 parts by mass of the base polymer (A). When the onium salt-type quencher for component (C) is within the above range, it is preferable because the resolution is good and there is no significant decrease in sensitivity. The onium salt represented by general formula (1) or (2) may be used as one type alone or by combining two or more.

The chemically amplified resist composition of the present invention may contain a nitrogen-containing compound as other quencher (C). As the nitrogen-containing compound for component (C), examples include primary, secondary, or tertiary amine compounds described in paragraphs [0146] to [0164] of JP2008-111103A, particularly amine compounds having a hydroxy group, an ether bond, an ester bond, a lactone ring, a cyano group, or a sulfonate ester bond. Furthermore, compounds in which a primary or secondary amine is protected with a carbamate group described in JP3790649B2 can also be included.

In addition, a sulfonium salt of a sulfonic acid having a nitrogen-containing substituent group may be used as the nitrogen-containing compound. Such a compound functions as a quencher in the unexposed area, and loses its quenching ability by neutralization with the acid generated by itself in the exposed area, functioning as a so-called photodegradable base. By using a photodegradable base, the contrast between the exposed area and the unexposed area can be further enhanced. For example, JP2009-109595A and JP2012-046501A can be used as reference for photodegradable bases.

When the chemically amplified resist composition of the present invention contains a nitrogen-containing compound as other quencher (C), the content thereof is preferably 0.001 to 12 parts by mass, and more preferably 0.01 to 8 parts by mass, based on 80 parts by mass of the base polymer (A). The nitrogen-containing compounds may be used as one type alone or by combining two or more.

### [Acid Generator (D)]

The chemically amplified resist composition of the present invention may contain an acid generator (D) in accordance with the purpose of the present invention. The acid generator (D) includes compounds that generate acid in response to actinic rays or radiation (photoacid generators). The photoacid generator is not particularly limited as long as it is a compound that generates acid when irradiated with high-energy radiation, but those that generate a sulfonic acid, an imide acid, or a methide acid are preferable. Suitable photoacid generators include sulfonium salts, iodonium salts, sulfonyldiazomethane, N-sulfonyloximide, oxime-O-sulfonate type acid generators, etc. Specific examples of acid generators include those described in paragraphs [0122] to [0142] of JP2008-111103A.

Furthermore, as the photoacid generator, a sulfonium salt represented by the following formula (3-1) or an iodonium salt represented by the following formula (3-2) can also be suitably used.

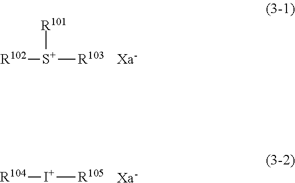

In the general formulae (3-1) and (3-2), R¹⁰¹ to R¹⁰⁵ each independently represent a halogen atom, or a hydrocarbyl group having 1 to 20 carbon atoms and optionally containing a heteroatom. Examples of the halogen atom and hydrocarbyl group include those exemplified as the halogen atom and hydrocarbyl groups represented by R² in the description of the general formula (a). Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a nitro group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc. Furthermore, R¹⁰¹ and R¹⁰² may be bonded to each other to form a ring together with the sulfur atom to which they are bonded. Specific examples of the ring formed in this case include ones similar to those exemplified as the ring that can be formed with the sulfur atom to which two of the three substituents bonded to S⁺ are bonded while being bonded to each other in the description of the general formula (a).

Specific examples of the cation of the sulfonium salt represented by the general formula (3-1) include, but are not limited to, ones similar to those exemplified as the sulfonium cation of the sulfonium salt type monomer represented by the general formula (a), those described in paragraphs [0102] to [0125] of JP2024-003744A, those described in paragraphs [0044] to [0049] of W02024/128017A, and those described in paragraphs [0035] to [0046] of JP7491173B2, and those represented by the general formula (d3). Furthermore, specific examples of the cation of the iodonium salt represented by the general formula (3-2) include, but are not limited to, those described in paragraph [0181] of JP2024-000259A.

In the general formulae (3-1) and (3-2), Xa⁻ is an anion selected from the following general formulae (3A) to (3D).

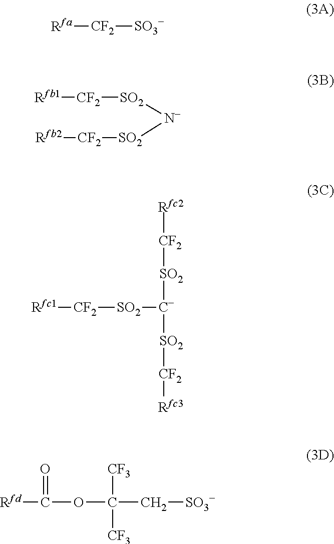

In the general formula (3A), R^{fa} is a fluorine atom or a hydrocarbyl group having 1 to 40 carbon atoms and optionally containing a heteroatom. The hydrocarbyl group may be saturated or unsaturated and may be linear, branched, or cyclic. Specific examples include ones similar to those exemplified in the description of R^{fa1} in the general formula (3A′) below.

The anion represented by the general formula (3A) is preferably one represented by the following general formula (3A′).

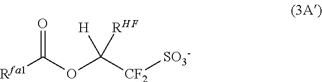

In the general formula (3A′), R^{HF} is a hydrogen atom or a trifluoromethyl group, and is preferably a trifluoromethyl group.

In the general formula (3A′), R^{fa1} is a hydrocarbyl group having 1 to 38 carbon atoms and optionally containing a heteroatom. The heteroatom is preferably an oxygen atom, a nitrogen atom, a sulfur atom, a halogen atom, etc., and more preferably an oxygen atom. From the viewpoint of obtaining a high resolution in fine pattern formation, the hydrocarbyl group preferably has 6 to 30 carbon atoms.

The hydrocarbyl group having 1 to 38 carbon atoms represented by R^{fa1} may be saturated or unsaturated, and may be linear, branched, or cyclic. Specific examples thereof include alkyl groups having 1 to 38 carbon atoms, such as a methyl group, an ethyl group, an n-propyl group, an isopropyl group, an n-butyl, an isobutyl group, a sec-butyl group, a tert-butyl group, a pentyl group, a neopentyl group, a hexyl group, a heptyl group, a 2-ethylhexyl group, a nonyl group, an undecyl group, a tridecyl group, a pentadecyl group, a heptadecyl group, and an icosyl group; cyclic saturated hydrocarbyl groups having 3 to 38 carbon atoms such as a cyclopentyl group, a cyclohexyl group, a 1-adamantyl group, a 2-adamantyl group, a 1-adamantylmethyl group, a norbornyl group, a norbornylmethyl group, a tricyclodecyl group, a tetracyclododecyl group, a tetracyclododecylmethyl group, and a dicyclohexylmethyl group; unsaturated aliphatic hydrocarbyl groups having 2 to 38 carbon atoms, such as an allyl group and a 3-cyclohexenyl group; aryl groups having 6 to 38 carbon atoms, such as a phenyl group, a 1-naphthyl group, and a 2-naphthyl group; aralkyl groups having 7 to 38 carbon atoms, such as a benzyl group and a diphenylmethyl group; and groups obtained by combining these.

Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a fluorine atom, a chlorine atom, a bromine atom, an iodine atom, a cyano group, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc. The heteroatom is preferably an oxygen atom. Specific examples of hydrocarbyl groups containing a heteroatom include a tetrahydrofuryl group, a methoxymethyl group, an ethoxymethyl group, a methylthiomethyl group, an acetamidomethyl group, a trifluoroethyl group, a (2-methoxyethoxy)methyl group, an acetoxymethyl group, a 2-carboxy-1-cyclohexyl group, a 2-oxopropyl group, a 4-oxo-1-adamantyl group, and a 3-oxocyclohexyl group.

Regarding the synthesis of a sulfonium salt containing an anion represented by the general formula (3A′), see JP2007-145797A, JP2008-106045A, JP2009-007327A, and JP2009-258695A. Furthermore, sulfonium salts described in JP2010-215608A, JP2012-041320A, JP2012-106986A, JP2012-153644A, etc. are also preferably used.

Specific examples of the anion represented by the general formula (3A) include, but are not limited to, those shown below. In addition, in the following formulae, Ac is an acetyl group.

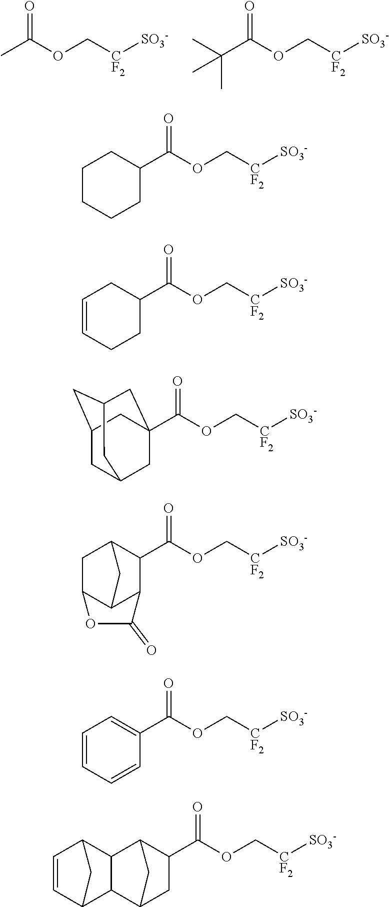

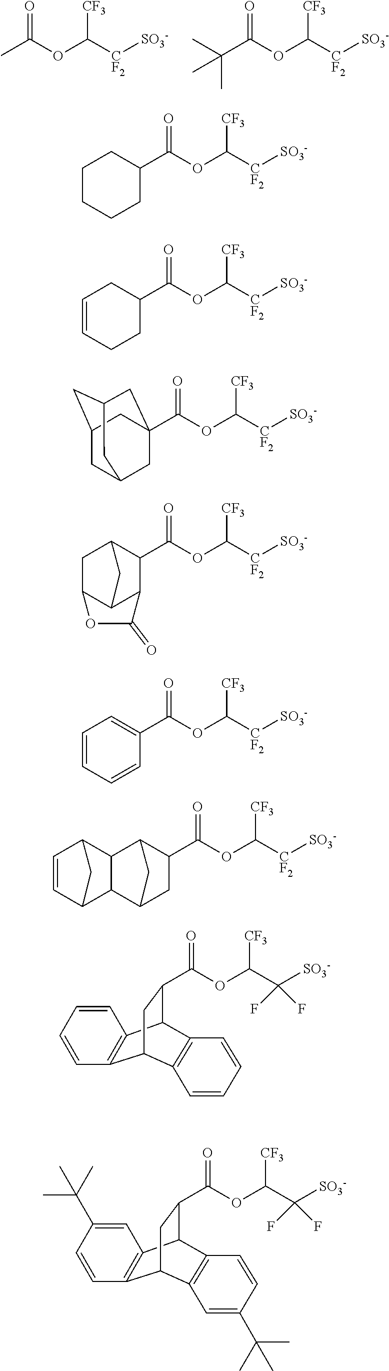

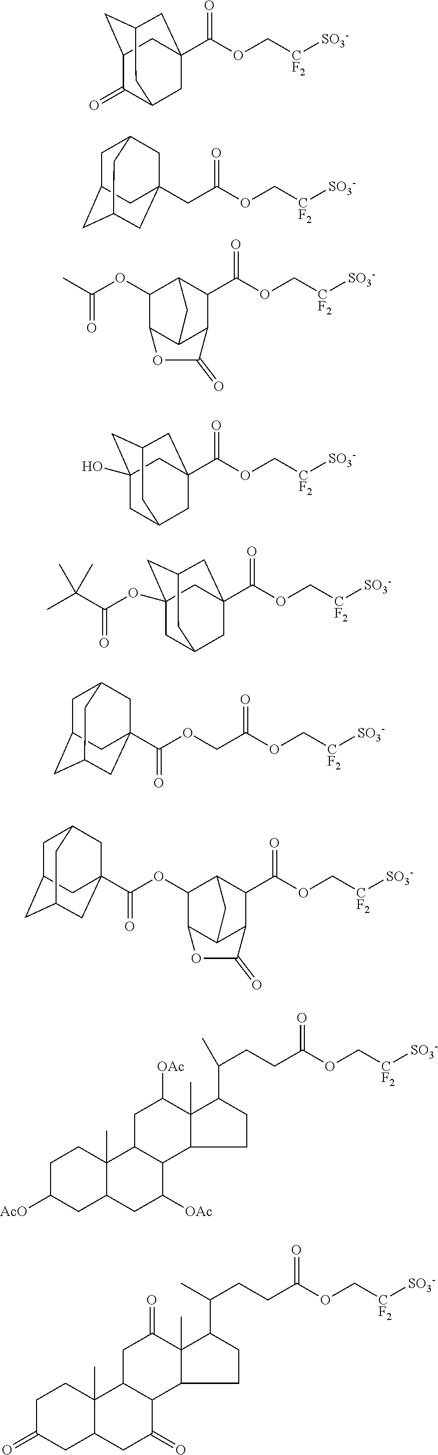

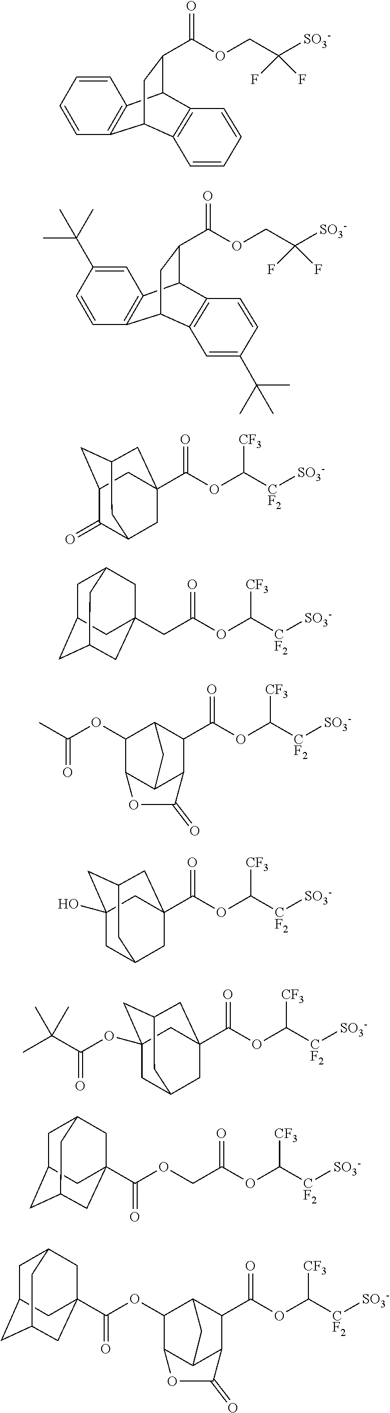

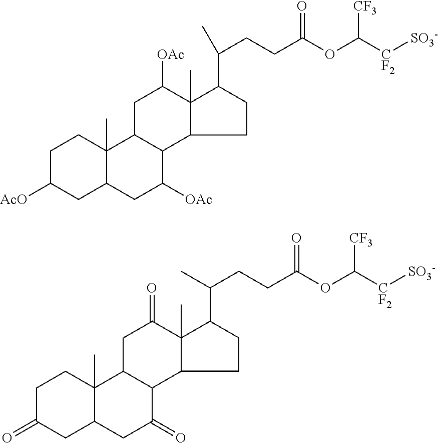

In the general formula (3B), R^{fb1} and R^{fb2} are each independently a fluorine atom or a hydrocarbyl group having 1 to 40 carbon atoms and optionally containing a heteroatom. The hydrocarbyl group may be saturated or unsaturated and may be linear, branched, or cyclic. Specific examples thereof include ones similar to those exemplified as the hydrocarbyl group represented by R^{fa1} in the general formula (3A′). R^{fb1} and R^{fb2} are preferably a fluorine atom or a linear fluorinated alkyl group having 1 to 4 carbon atoms. Furthermore, R^{fb1} and R^{fb2} may be bonded to each other to form a ring together with the group (—CF₂—SO₂—N—SO₂—CF₂—) to which they are bonded, and in this case, the group obtained by bonding R^{fb1} and R^{fb2} to each other is preferably a fluorinated ethylene group or a fluorinated propylene group.

In the general formula (3C), R^{fc1}, R^{fc2}, and R^{fc3} are each independently a fluorine atom or a hydrocarbyl group having 1 to 40 carbon atoms and optionally containing a heteroatom. The hydrocarbyl group may be saturated or unsaturated and may be linear, branched, or cyclic. Specific examples thereof include ones similar to those exemplified as the hydrocarbyl group represented by R^{fa1} in the general formula (3A′). R^{fc1}, R^{fc2}, and R^{fc3} are preferably a fluorine atom or a linear fluorinated alkyl group having 1 to 4 carbon atoms. Furthermore, R^{fc1} and R^{fc2} may be bonded to each other to form a ring together with the group (—CF₂—SO₂—C—SO₂—CF₂—) to which they are bonded, and in this case, the group obtained by bonding R^{fc1} and R^{fc2} to each other is preferably a fluorinated ethylene group or a fluorinated propylene group.

In the general formula (3D), R^{fd} is a hydrocarbyl group having 1 to 40 carbon atoms and optionally containing a heteroatom. The hydrocarbyl group may be saturated or unsaturated and may be linear, branched, or cyclic. Specific examples thereof include ones similar to those exemplified as the hydrocarbyl group represented by R^{fa1} in the general formula (3A′).

For the synthesis of sulfonium salts containing the anion represented by the general formula (3D), see JP2010-215608A and JP2014-133723A.

Specific examples of the anion represented by the general formula (3D) include, but are not limited to, those shown below.

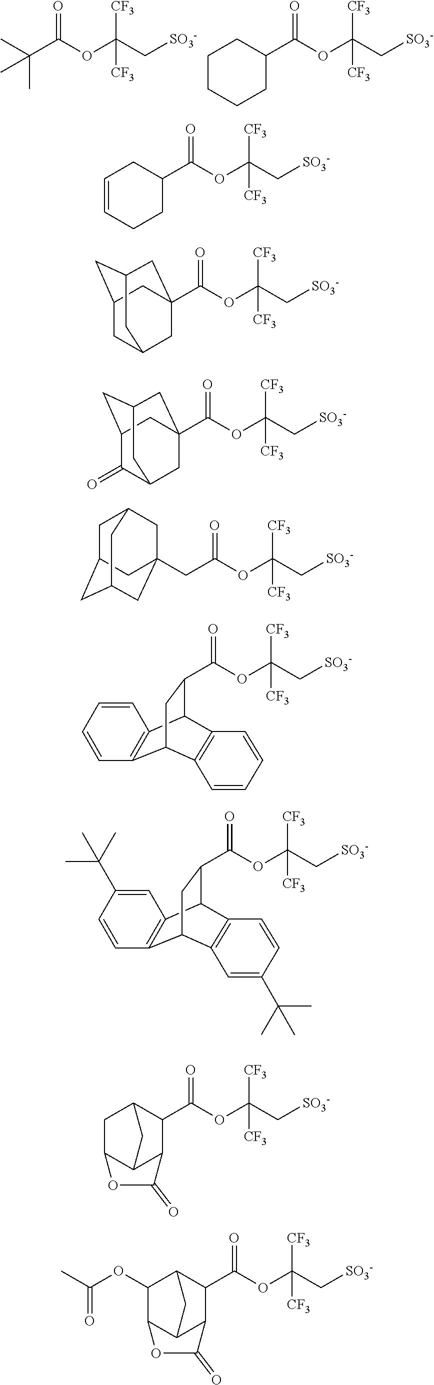

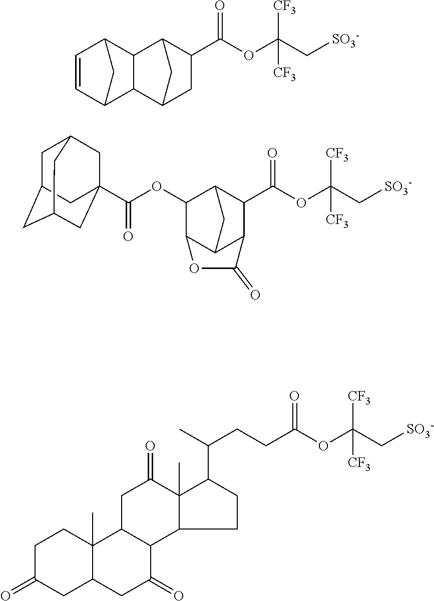

The photoacid generator containing the anion represented by the general formula (3D) does not have a fluorine atom at the α-position of the sulfo group, but has two trifluoromethyl groups at the β-position, and therefore has sufficient acidity to cleave acid-labile groups in the base polymer. Therefore, it can be used as a photoacid generator.

As the photoacid generator, a compound represented by the following general formula (4) can also be suitably used.

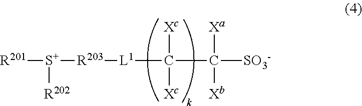

In the general formula (4), R²⁰¹ and R²⁰² are each independently a hydrocarbyl group having 1 to 30 carbon atoms and optionally containing a heteroatom. R²⁰³ is a hydrocarbylene group having 1 to 30 carbon atoms and optionally containing a heteroatom. Furthermore, any two of R²⁰¹, R²⁰², and R²⁰³ may be bonded to each other to form a ring together with the sulfur atom to which they are bonded. In this case, specific examples of the ring include ones similar to those exemplified as the ring that can be formed with the sulfur atom to which two of the three substituents bonded to S⁺ are bonded while being bonded to each other in the description of the general formula (a).

The hydrocarbyl group having 1 to 30 carbon atoms represented by R²⁰¹ and R²⁰² may be saturated or unsaturated, and may be linear, branched, or cyclic. Specific examples thereof include alkyl groups having 1 to 30 carbon atoms, such as a methyl group, an ethyl group, an n-propyl group, an isopropyl group, an n-butyl group, an isobutyl group, a sec-butyl group, a tert-butyl group, an n-pentyl group, a tert-pentyl group, an n-hexyl group, an n-octyl group, a 2-ethylhexyl group, an n-nonyl group, and an n-decyl group; cyclic saturated hydrocarbyl groups having 3 to 30 carbon atoms, such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, an oxanorbornyl group, a tricyclo[5.2.1.0^{2,6}]decyl group, and an adamantyl group; aryl groups having 6 to 30 carbon atoms, such as a phenyl group, a methylphenyl group, an ethylphenyl group, an n-propylphenyl group, an isopropylphenyl group, an n-butylphenyl group, an isobutylphenyl group, a sec-butylphenyl group, a tert-butylphenyl group, a naphthyl group, a methylnaphthyl group, an ethylnaphthyl group, an n-propylnaphthyl group, an isopropylnaphthyl group, an n-butylnaphthyl group, an isobutylnaphthyl group, a sec-butylnaphthyl group, a tert-butylnaphthyl group, and an anthracenyl group; and groups obtained by combining these. Furthermore, some or all of the hydrogen atoms of the hydrocarbyl group may be substituted with a group containing a heteroatom such as an oxygen atom, a sulfur atom, a nitrogen atom, or a halogen atom, and some of the —CH₂— of the hydrocarbyl group may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc.

The hydrocarbylene group having 1 to 30 carbon atoms represented by R²⁰³ may be saturated or unsaturated, and may be linear, branched, or cyclic. Specific examples thereof include alkanediyl groups having 1 to 30 carbon atoms, such as a methanediyl group, an ethane-1,1-diyl group, an ethane-1,2-diyl group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, a heptadecane-1,17-diyl group, etc.; cyclic saturated hydrocarbylene groups having 3 to 30 carbon atoms, such as a cyclopentanediyl group, a cyclohexanediyl group, a norbornanediyl group, an adamanthyldiyl group, etc.; arylene groups having 6 to 30 carbon atoms, such as a phenylene group, a methylphenylene group, an ethylphenylene group, an n-propylphenylene group, an isopropylphenylene group, an n-butylphenylene group, an isobutylphenylene group, a sec-butylphenylene group, a tert-butylphenylene group, a naphthylene group, a methylnaphthylene group, an ethylnaphthylene group, an n-propylnaphthylene group, an isopropylnaphthylene group, an n-butylnaphthylene group, an isobutylnaphthylene group, a sec-butylnaphthylene group, a tert-butylnaphthylene group, etc.; and groups obtained by combining these. Furthermore, some or all of the hydrogen atoms of the hydrocarbylene may be substituted with a group containing a heteroatom such as an oxygen atom, a sulfur atom, a nitrogen atom, or a halogen atom, and some of the —CH₂— of the hydrocarbylene may be substituted with a group containing a heteroatom such as an oxygen atom, a sulfur atom, or a nitrogen atom, and as a result, it may contain a hydroxy group, a cyano group, a fluorine atom, a chlorine atom, a bromine atom, an iodine atom, a carbonyl group, an ether bond, an ester bond, a sulfonate ester bond, a carbonate bond, a lactone ring, a sultone ring, a carboxylic anhydride (—C(═O)—O—C(═O)—), a haloalkyl group, etc. As the heteroatom, an oxygen atom is preferable.

In the general formula (4), L¹ is a single bond, an ether bond, or hydrocarbylene group having 1 to 20 carbon atoms and optionally containing a heteroatom. The hydrocarbylene group may be saturated or unsaturated, and may be linear, branched, or cyclic. Specific examples thereof include ones similar to those exemplified as the hydrocarbylene group represented by R²⁰³.

In the general formula (4), X^{a}, X^{b}, X^{c}, and X^{d} are each independently a hydrogen atom, a fluorine atom or a trifluoromethyl group. However, at least one of X^{a}, X^{b}, X^{c}, and X^{d} is a fluorine atom or a trifluoromethyl group.

In the general formula (4), “k” is an integer from 0 to 3.

As the photoacid generator represented by the general formula (4), one represented by the following general formula (4′) is preferable.

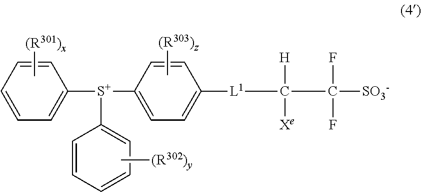

In the general formula (4′), L¹ is as defined above. X^{e} is a hydrogen atom or a trifluoromethyl group, and preferably a trifluoromethyl group. R³⁰¹, R³⁰² and R³⁰³ are each independently a hydrocarbyl group having 1 to 20 carbon atoms and optionally containing a heteroatom. The hydrocarbyl group may be saturated or unsaturated and may be linear, branched, or cyclic. Specific examples thereof include ones similar to those exemplified as the hydrocarbyl group represented by R^{fa1} in the general formula (3A′). “x” and “y” are each independently an integer from 0 to 5. “z” is an integer from 0 to 4.

Specific examples of photoacid generators represented by the general formula (4) include those exemplified as photoacid generators represented by the formula (2) in JP2017-026980A.

Among the photoacid generators, those containing an anion represented by the general formula (3A′) or (3D) are particularly preferable because they have low acid diffusion and excellent solubility in solvents. Furthermore, those represented by the general formula (4′) are particularly preferable because they have extremely low acid diffusion.

Furthermore, as other acid generators, sulfonium salts and iodonium salts containing an anion having an aromatic ring substituted with an iodine atom, represented by the following general formula (5-1) or (5-2), can also be used.

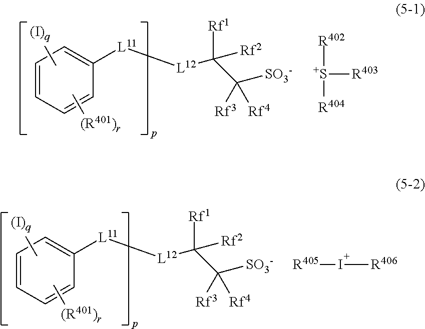

In the general formulae (5-1) and (5-2), “p” is 1, 2 or 3. “q” is an integer from 1 to 5. “r” is an integer from 0 to 3. However, 1≤q+r≤5. “q” is preferably 1, 2 or 3, and more preferably 2 or 3. “r” is preferably 0, 1 or 2.

In the general formulae (5-1) and (5-2), L¹¹ is a single bond, an ether bond or an ester bond, or a saturated hydrocarbylene group having 1 to 6 carbon atoms and optionally containing an ether bond or an ester bond. The saturated hydrocarbylene group may be linear, branched, or cyclic.

In the general formulae (5-1) and (5-2), when “p” is 1, Liz is a single bond or a divalent linking group having 1 to 20 carbon atoms, and when “p” is 2 or 3, it is a (p+1) valent linking group having 1 to 20 carbon atoms, and the linking group may contain an oxygen atom, a sulfur atom, or a nitrogen atom.

In the general formulae (5-1) and (5-2), R⁴⁰¹ is a hydroxy group, a carboxy group, a fluorine atom, a chlorine atom, a bromine atom, or an amino group; a hydrocarbyl group having 1 to 20 carbon atoms, a hydrocarbyloxy group having 1 to 20 carbon atoms, a hydrocarbylcarbonyl group having 2 to 20 carbon atoms, a hydrocarbyloxycarbonyl group having 2 to 20 carbon atoms, a hydrocarbyloxycarbonyl group having 2 to 20 carbon atoms, or a hydrocarbylsulfonyloxy group having 1 to 20 carbon atoms and optionally containing a fluorine atom, a chlorine atom, a bromine atom, a hydroxy group, an amino group, or an ether bond; or —N(R^{401A})(R^{401B}), —N(R^{401C})—C(═O)—R^{401D} or —N(R^{401C})—C(═O)—O—R^{401D}. R^{401A} and R^{401B} are each independently a hydrogen atom or a saturated hydrocarbyl group having 1 to 6 carbon atoms. R^{401C} is a hydrogen atom or a saturated hydrocarbyl group having 1 to 6 carbon atoms, and may contain a halogen atom, a hydroxy group, a saturated hydrocarbyloxy group having 1 to 6 carbon atoms, a saturated hydrocarbylcarbonyl group having 2 to 6 carbon atoms, or a saturated hydrocarbyl group having 2 to 6 carbon atoms. R^{401D} is an aliphatic hydrocarbyl group having 1 to 16 carbon atoms, an aryl group having 6 to 14 carbon atoms, or an aralkyl group having 7 to 15 carbon atoms, and may contain a halogen atom, a hydroxy group, a saturated hydrocarbyloxy group having 1 to 6 carbon atoms, a saturated hydrocarbylcarbonyl group having 2 to 6 carbon atoms, or a saturated hydrocarbylcarbonyloxy group having 2 to 6 carbon atoms. The aliphatic hydrocarbyl group may be saturated or unsaturated and may be linear, branched, or cyclic. The hydrocarbyl group, hydrocarbyloxy group, hydrocarbylcarbonyl group, hydrocarbyloxycarbonyl group, hydrocarbylcarbonyloxy group, and hydrocarbylsulfonyloxy group may be linear, branched, or cyclic. When “p” and/or “r” are 2 or more, each R⁴⁰¹ may be the same or they may be different from each other.

Among these, a hydroxy group, —N(R^{401C})—C(═O)—R^{401D}, —N(R^{401C})—C(═O)—OR^{401D}, a fluorine atom, a chlorine atom, a bromine atom, a methyl group, a methoxy group, etc. are preferable as R⁴⁰¹.

In the general formulae (5-1) and (5-2), Rf¹ to Rf⁴ are each independently a hydrogen atom, a fluorine atom, or a trifluoromethyl group, and at least one of them is a fluorine atom or a trifluoromethyl group. Furthermore, Rf¹ and Rf² may be combined to form a carbonyl group. In particular, it is preferable that both Rf³ and Rf⁴ are fluorine atoms.

In the general formulae (5-1) and (5-2), R⁴⁰² to R⁴⁰⁶ each independently represent a halogen atom, or a hydrocarbyl group having 1 to 20 carbon atoms and optionally containing a heteroatom. The hydrocarbyl group may be saturated or unsaturated and may be linear, branched, or cyclic. Specific examples thereof include, but are not limited to, ones similar to those exemplified as the hydrocarbyl group represented by R² in the description of the general formula (a). In addition, some or all of the hydrogen atoms of the hydrocarbyl group may be substituted with a hydroxy group, a carboxy group, a halogen atom, a cyano group, a nitro group, a mercapto group, a sultone ring, a sulfo group, or a sulfonium salt-containing group, and some of the —CH₂— of the hydrocarbyl group may be substituted with an ether bond, an ester bond, a carbonyl group, an amide bond, a carbonate bond, or a sulfonate ester bond. Furthermore, R⁴⁰² and R⁴⁰³ may be bonded to each other to form a ring together with the sulfur atom to which they are bonded. In this case, specific examples of the ring include ones similar to those exemplified as the ring that can be formed with the sulfur atom to which two of the three substituents bonded to S⁺ are bonded while being bonded to each other in the description of the general formula (a).

Specific examples of the cation of the sulfonium salt represented by the general formula (5-1) include those described in paragraphs [0102] to [0125] of JP2024-003744A, those described in paragraphs [0070] to [0085] of JP2023-169812A, and those represented by the general formula (d3). Furthermore, specific examples of the cation of the iodonium salt represented by the general formula (5-2) include those described in paragraph [0181] of JP2024-000259A.

Specific examples of the anion of the onium salt represented by the general formula (5-1) or (5-2) include, but are not limited to, those shown below.

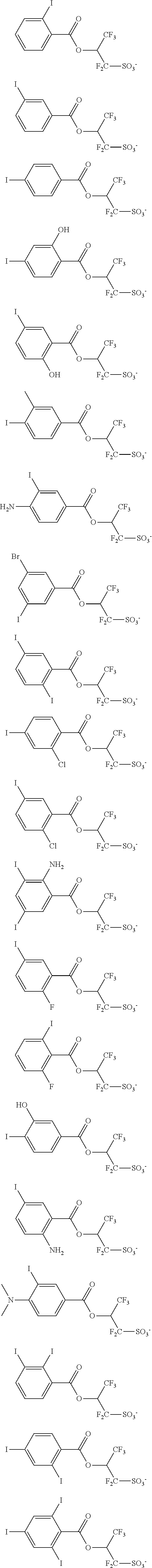

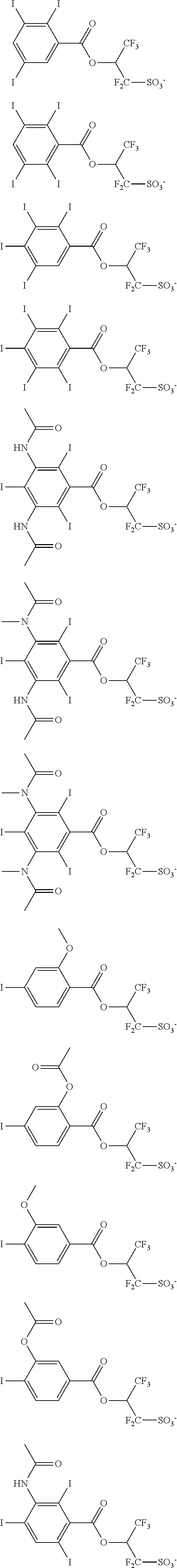

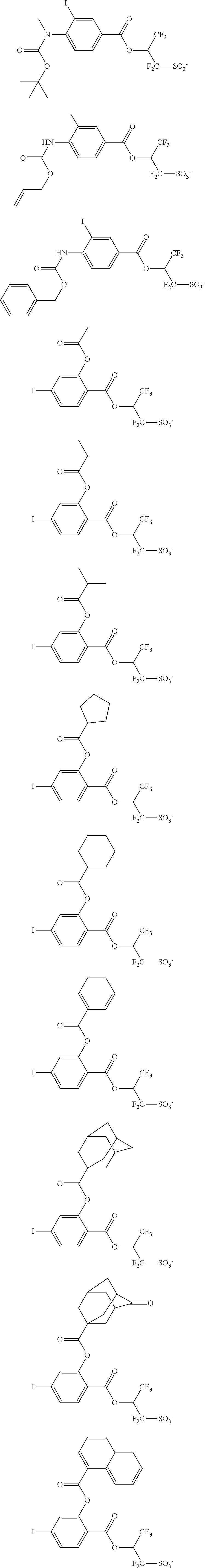

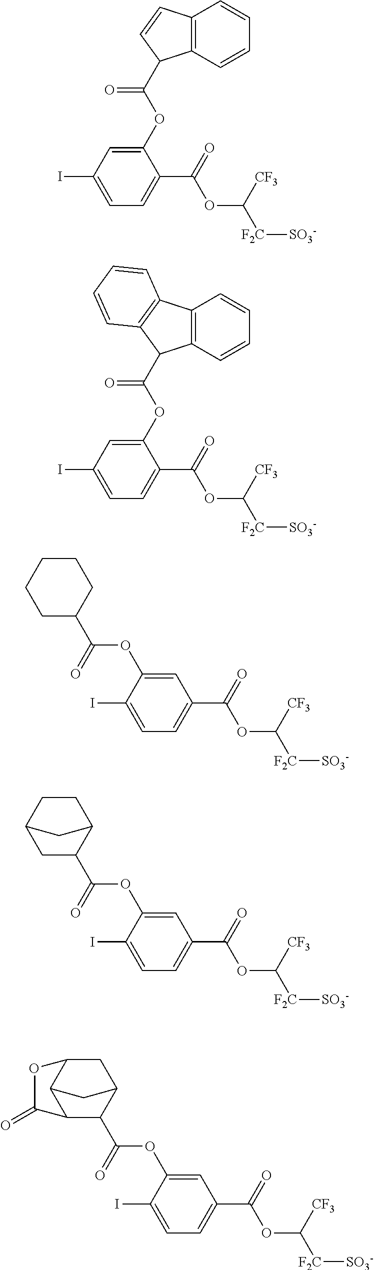

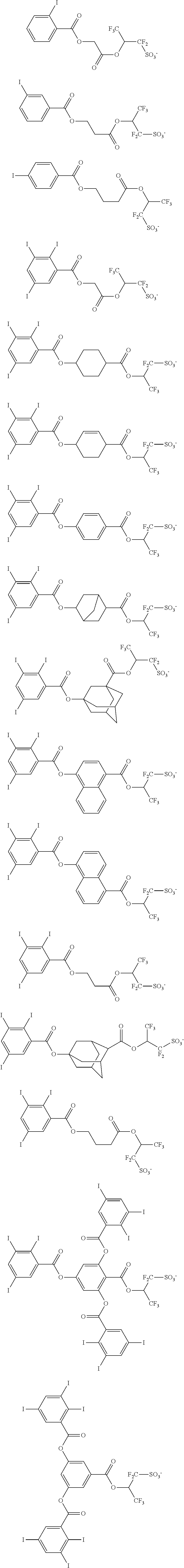

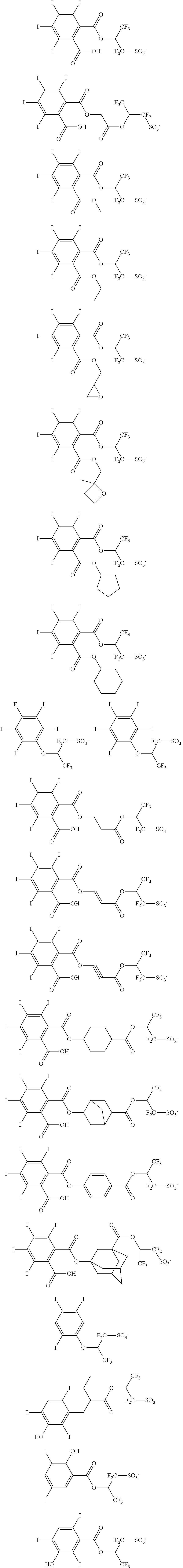

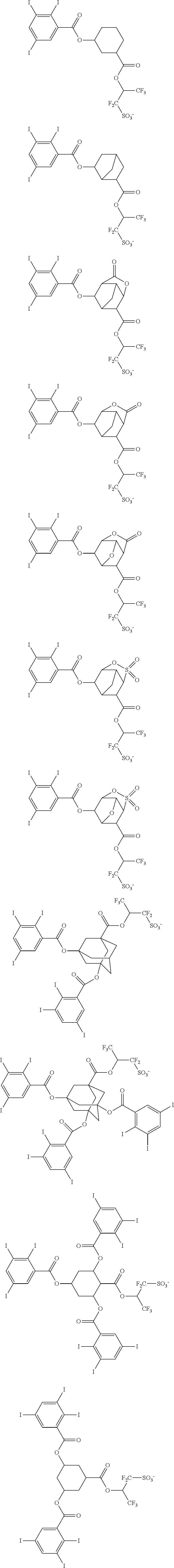

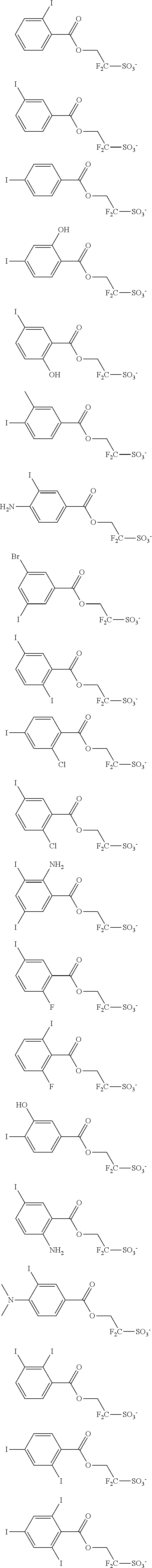

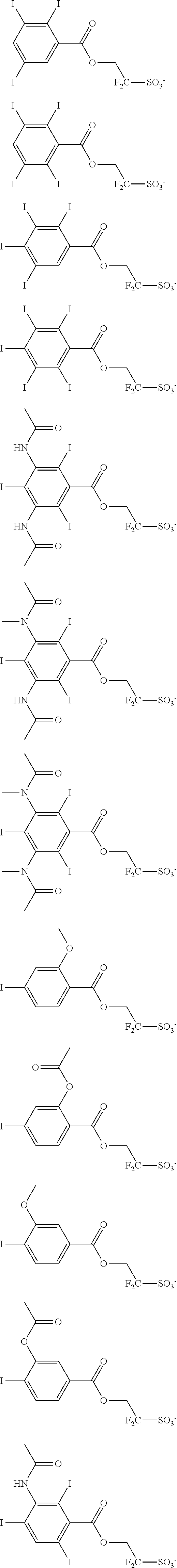

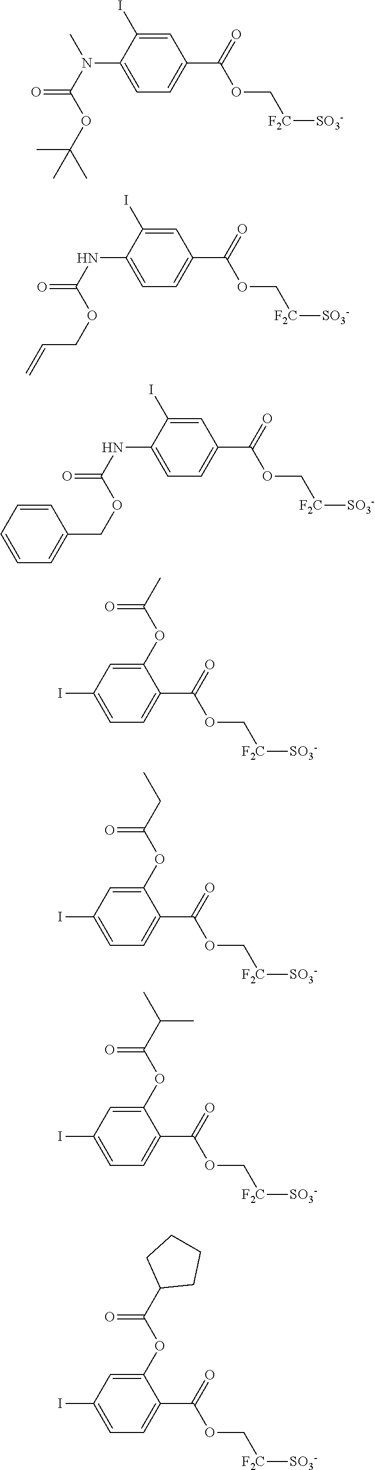

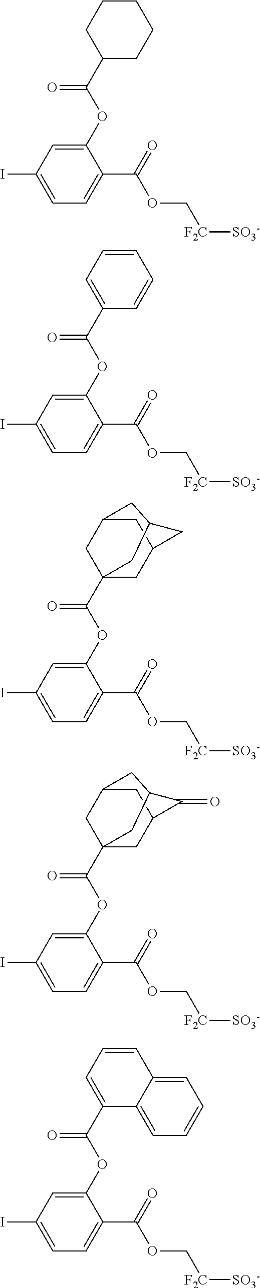

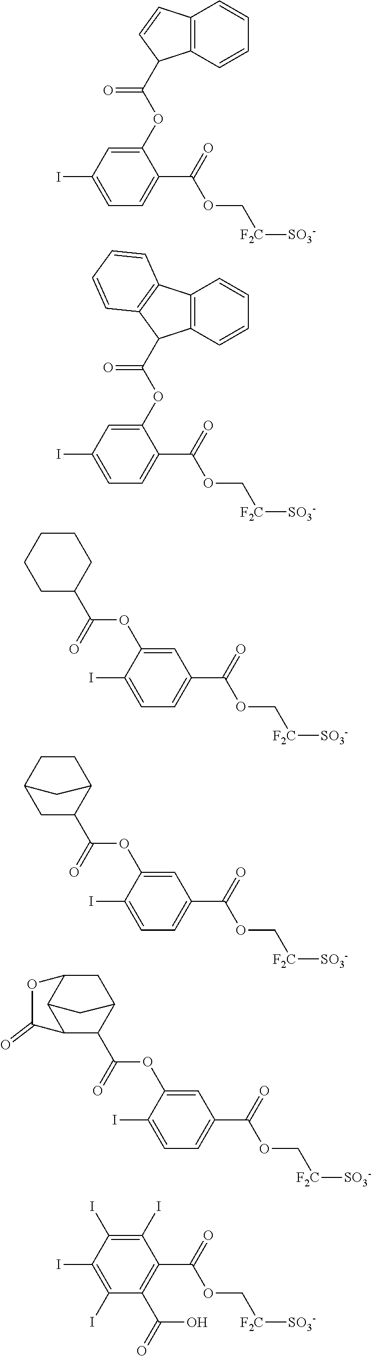

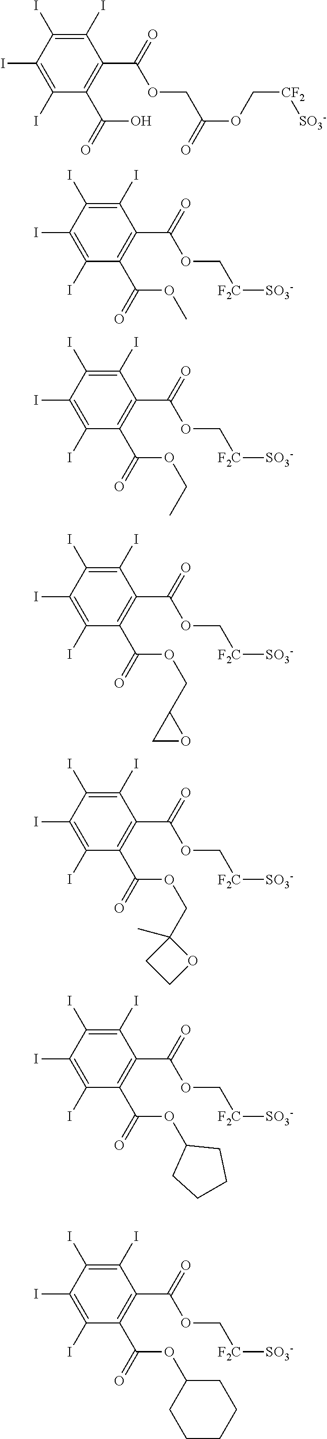

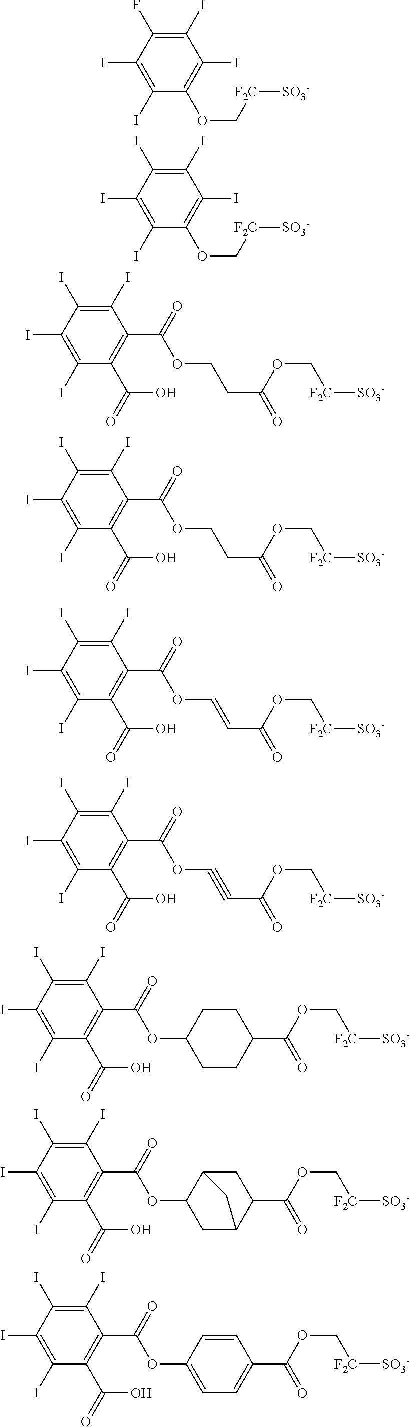

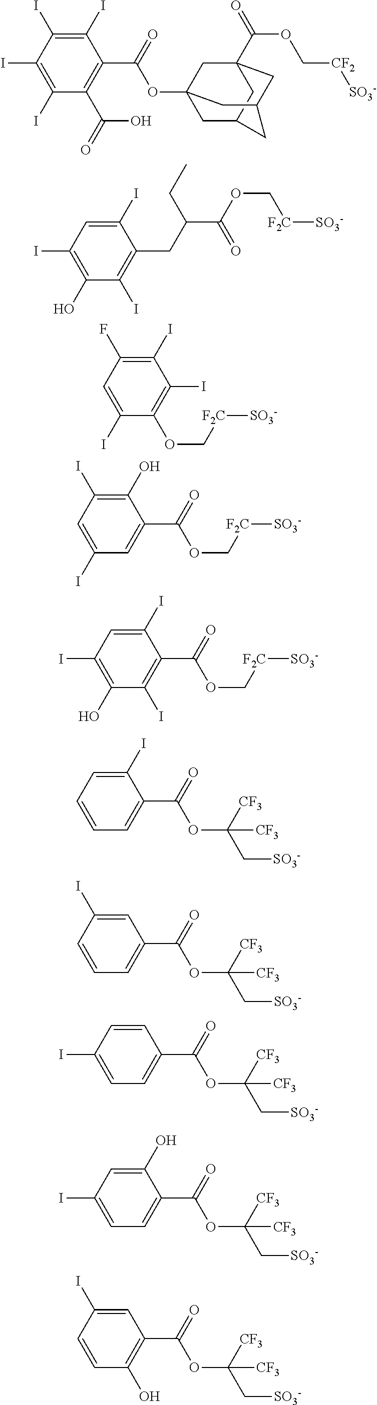

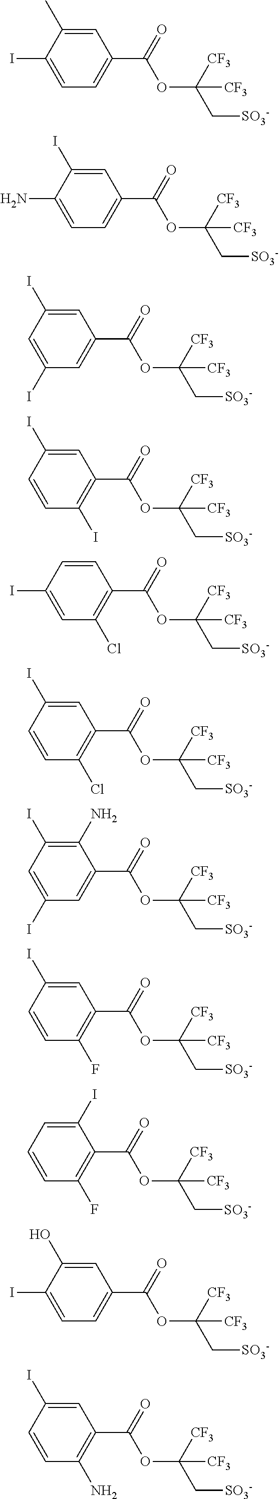

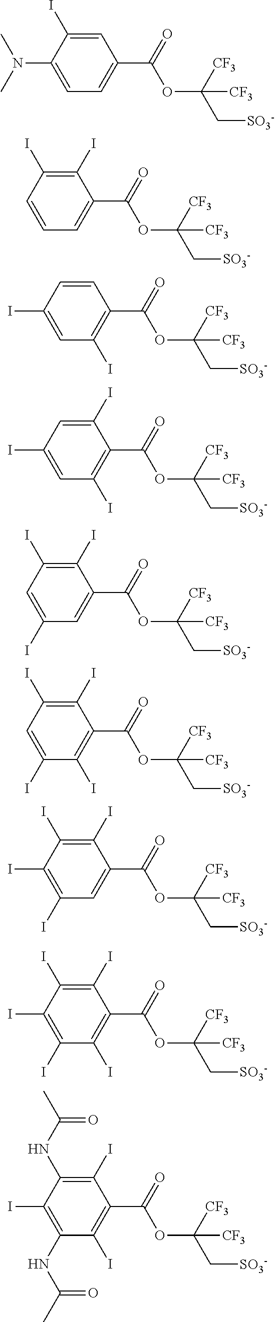

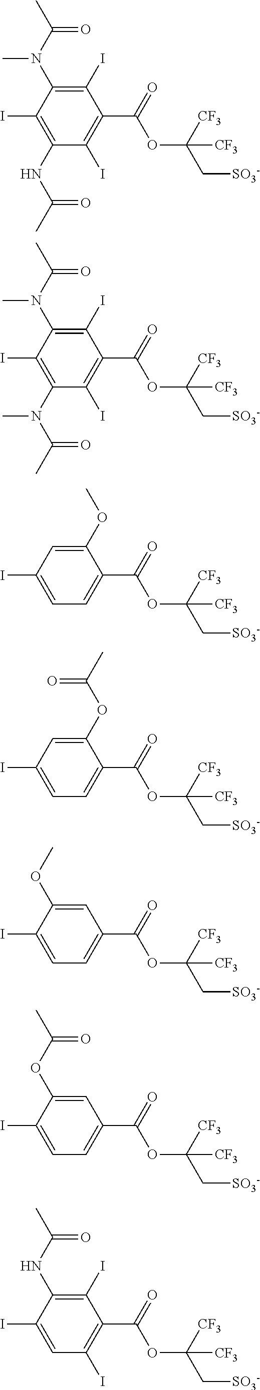

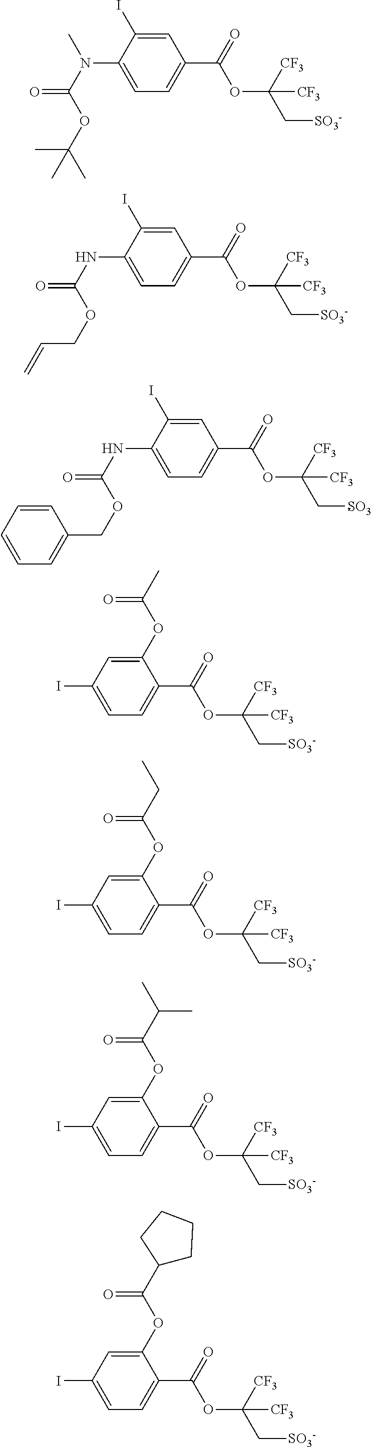

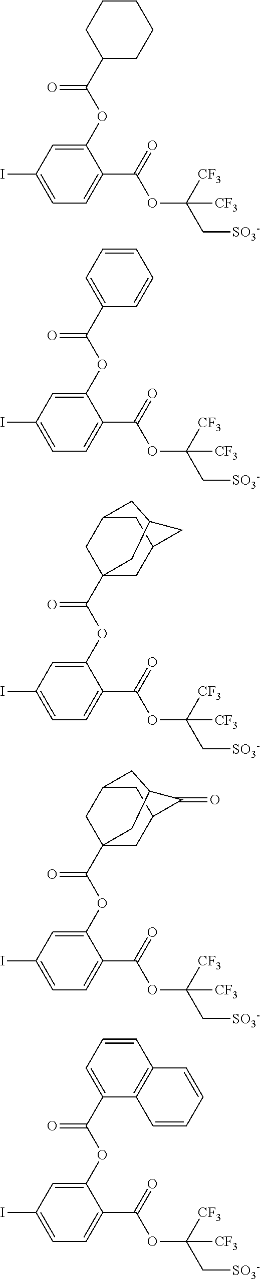

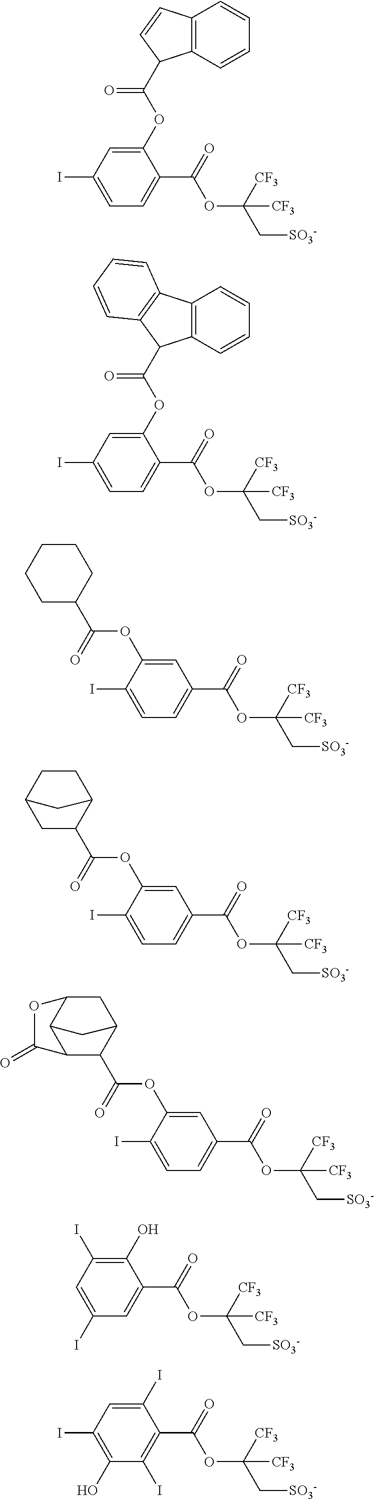

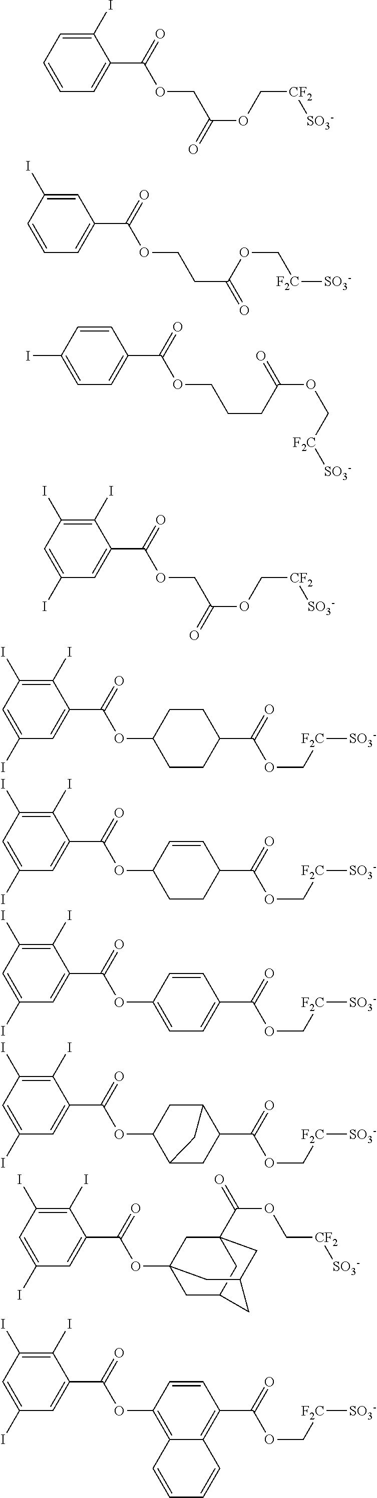

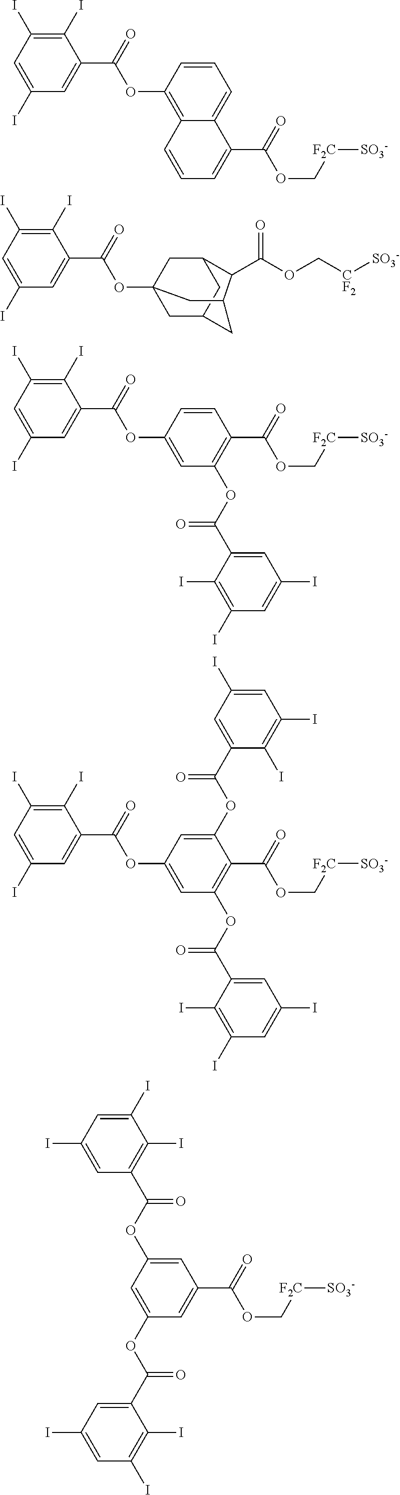

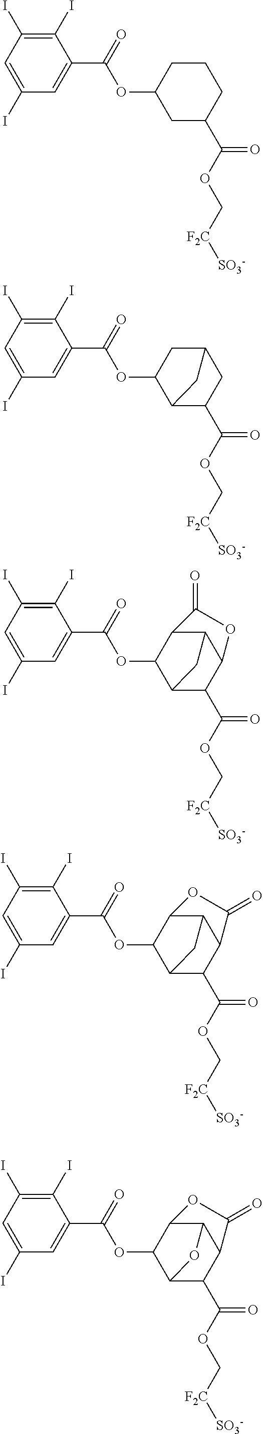

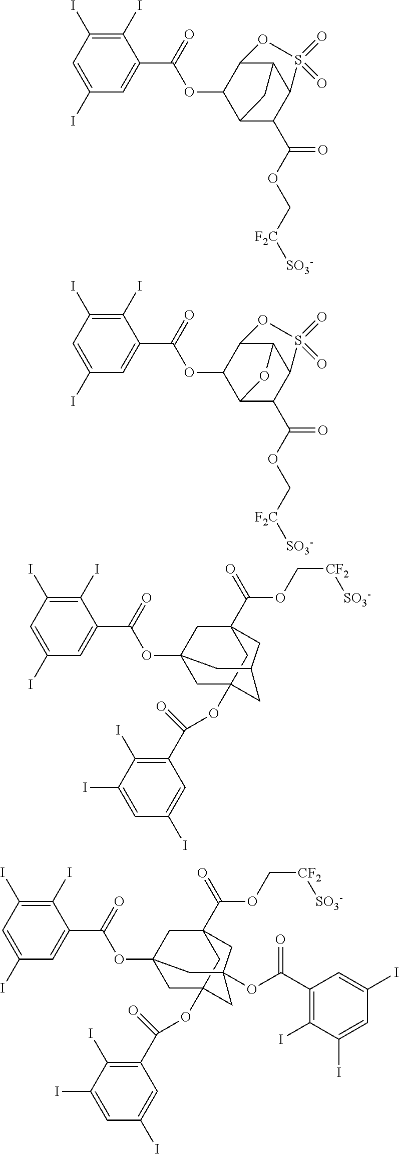

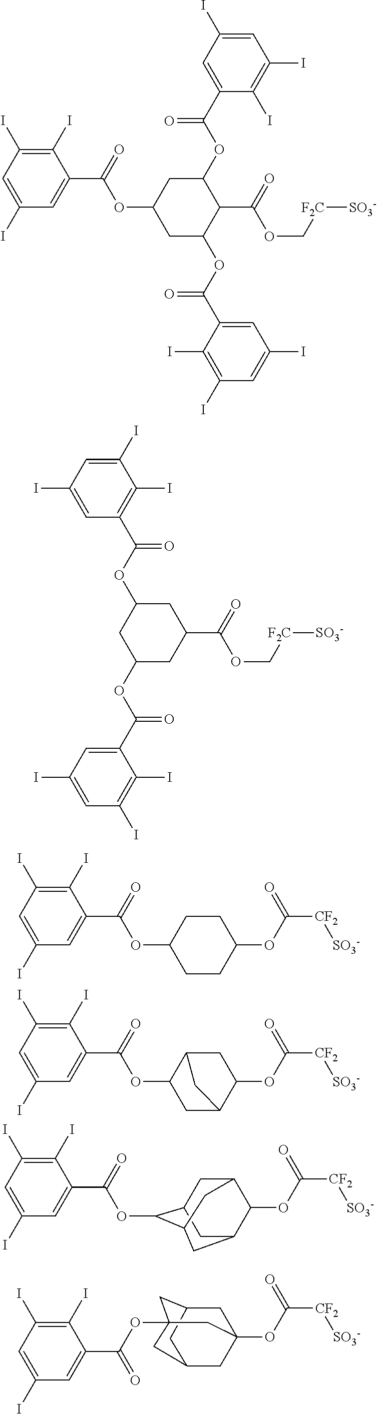

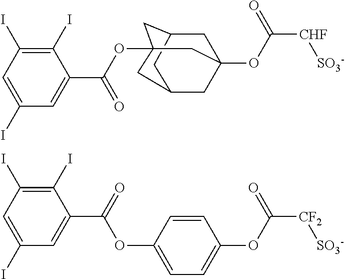

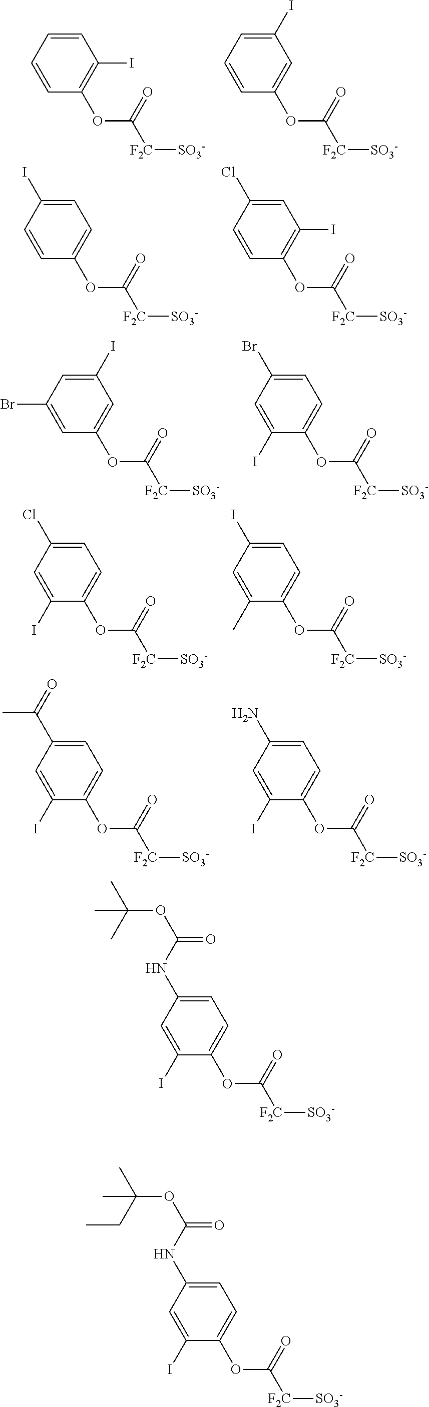

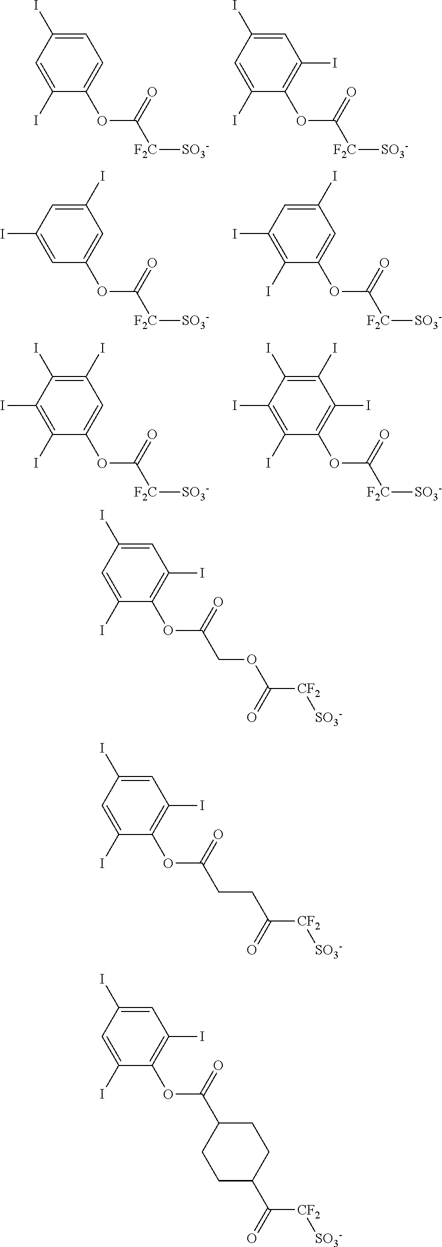

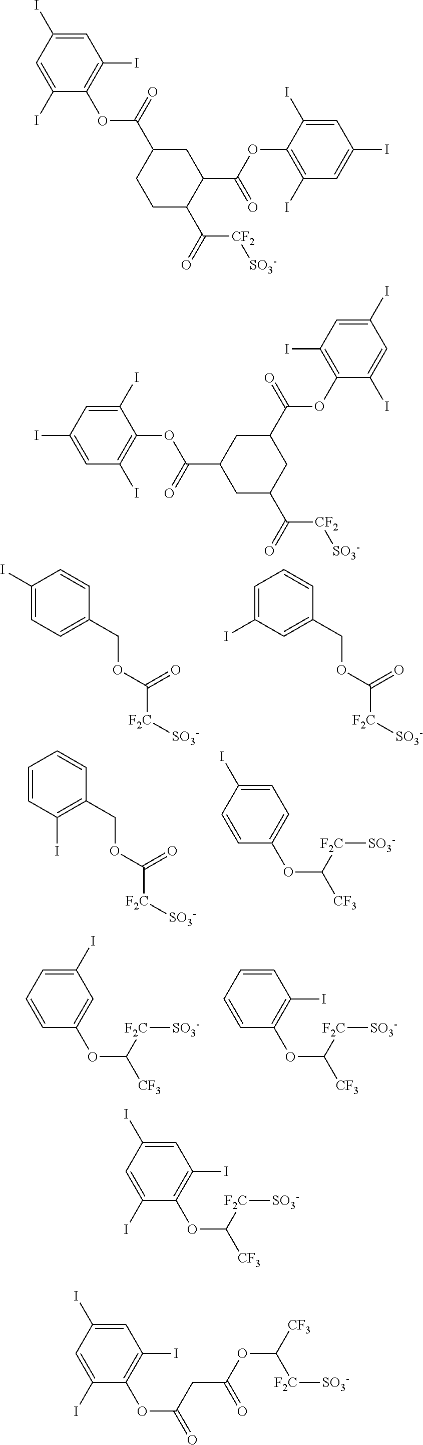

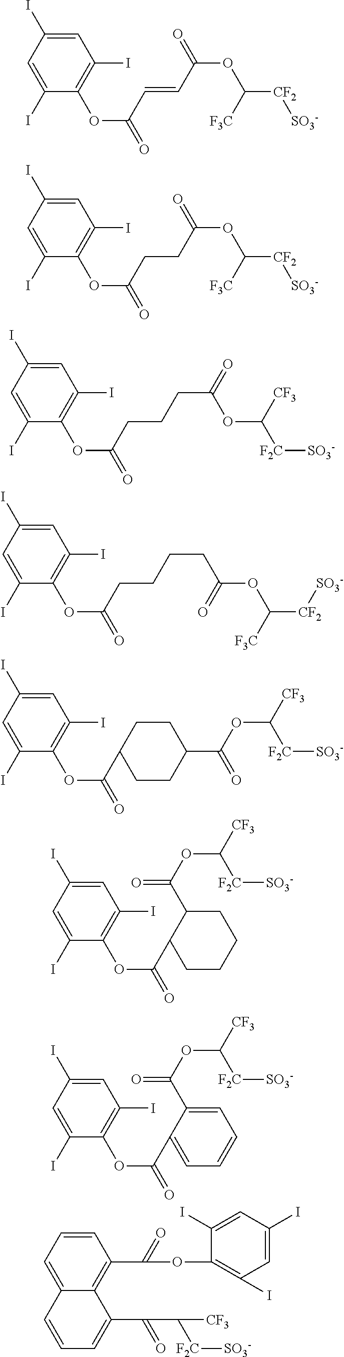

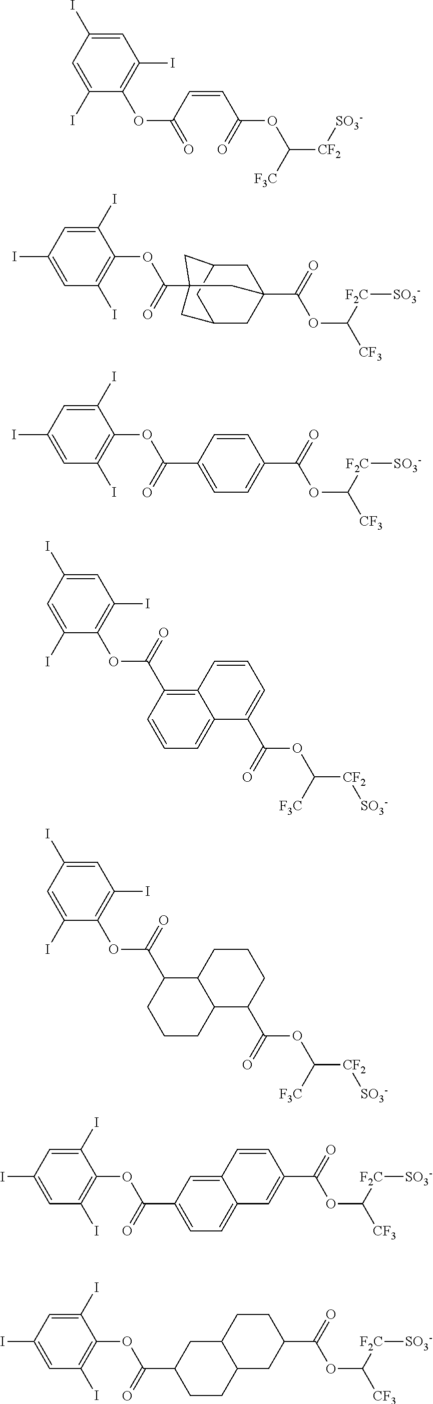

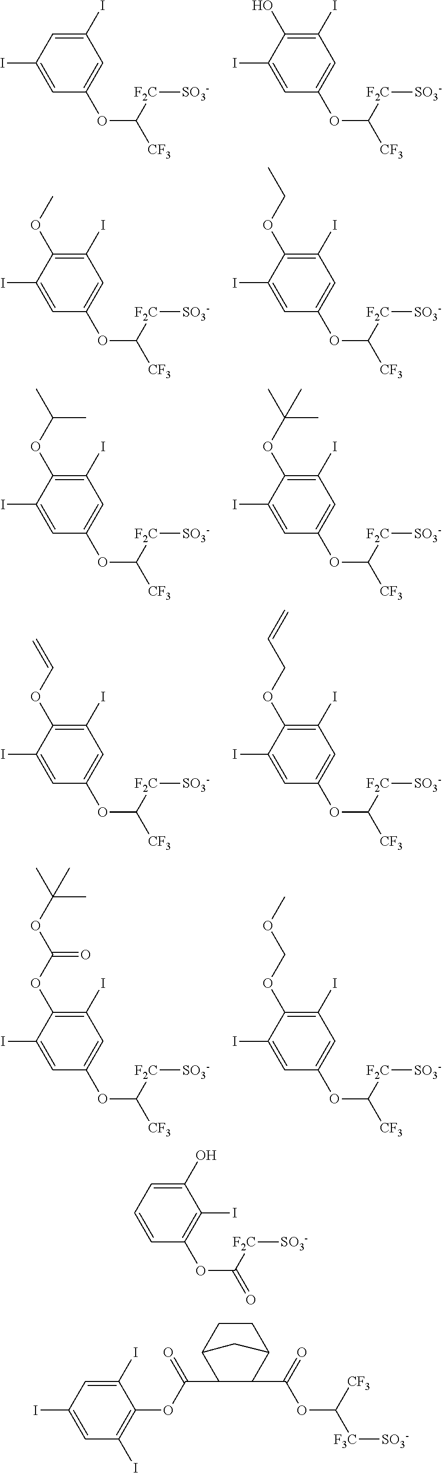

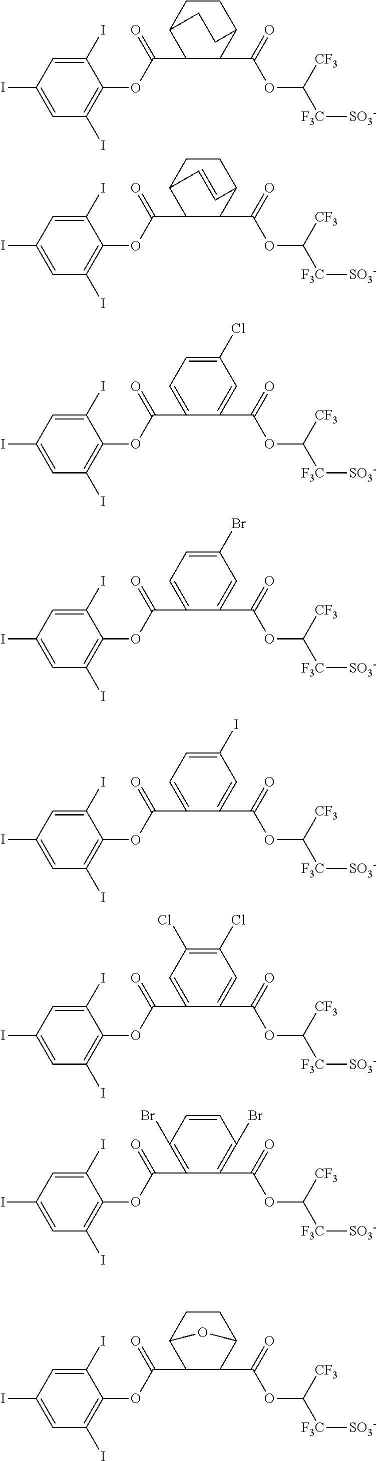

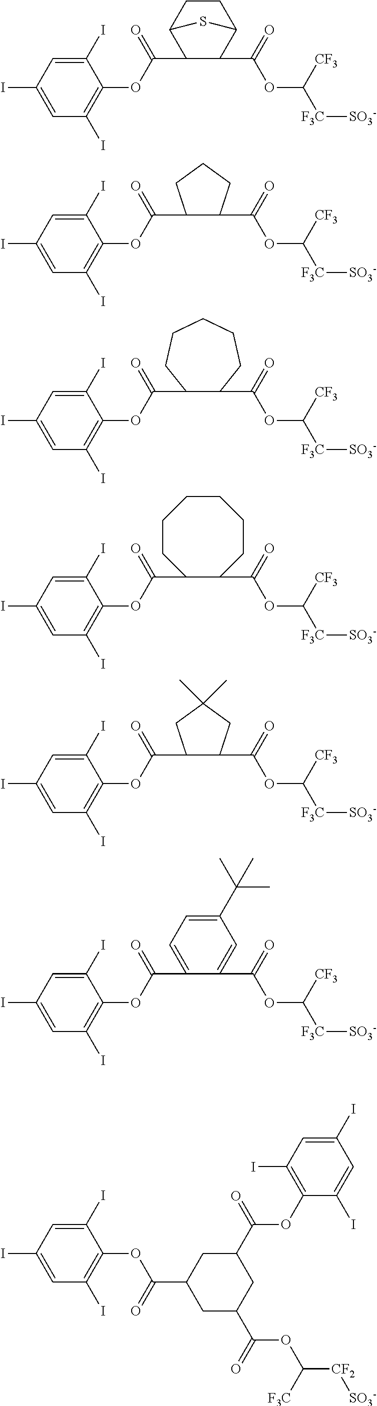

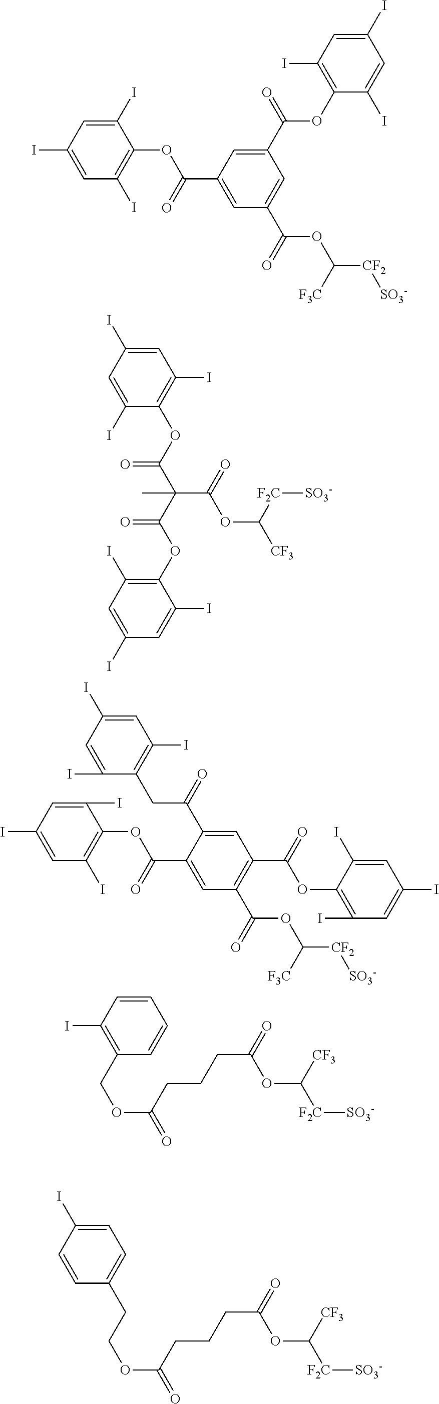

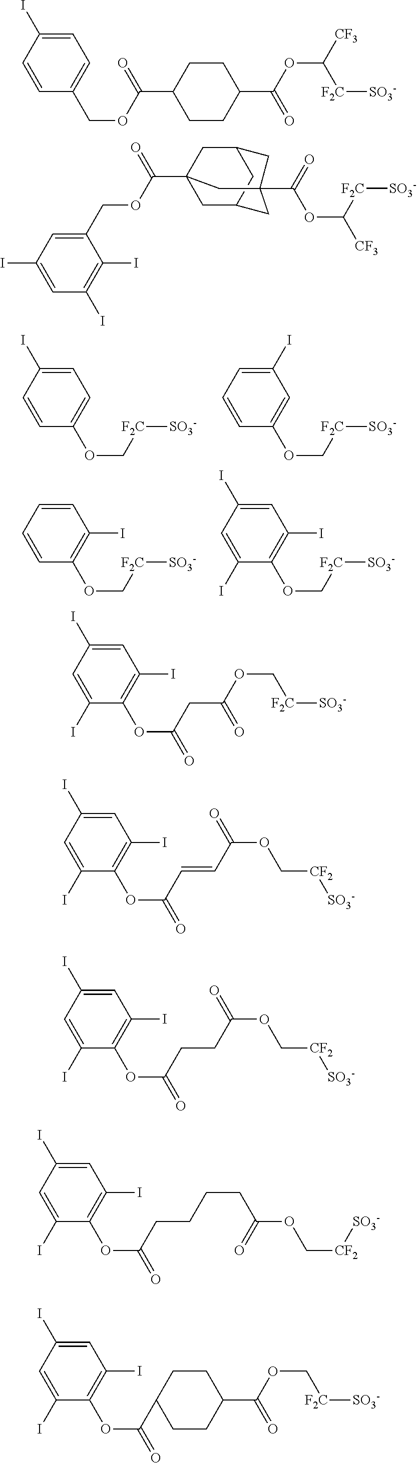

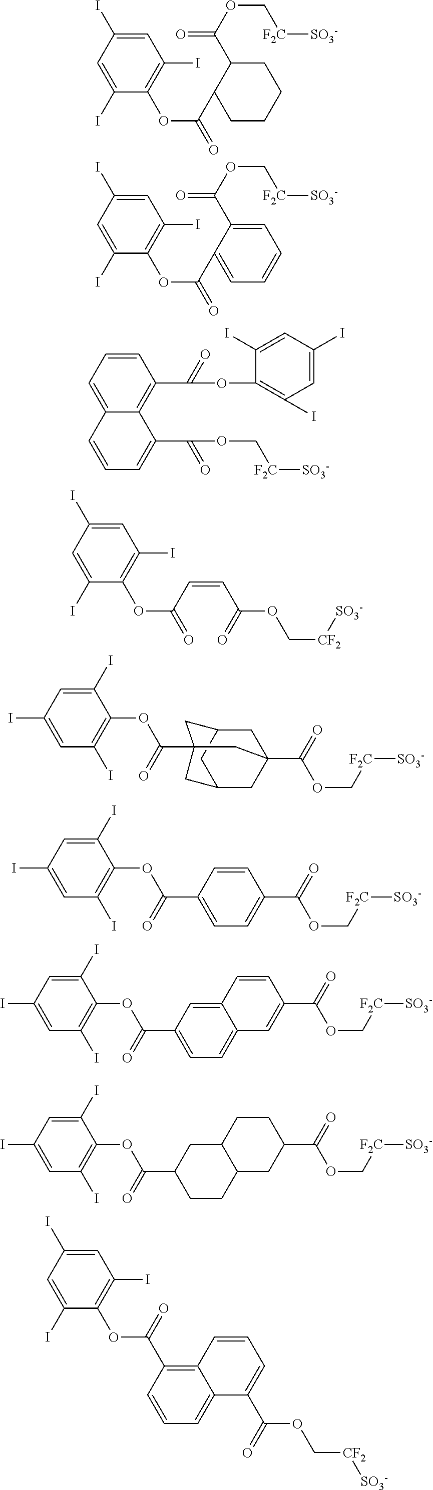

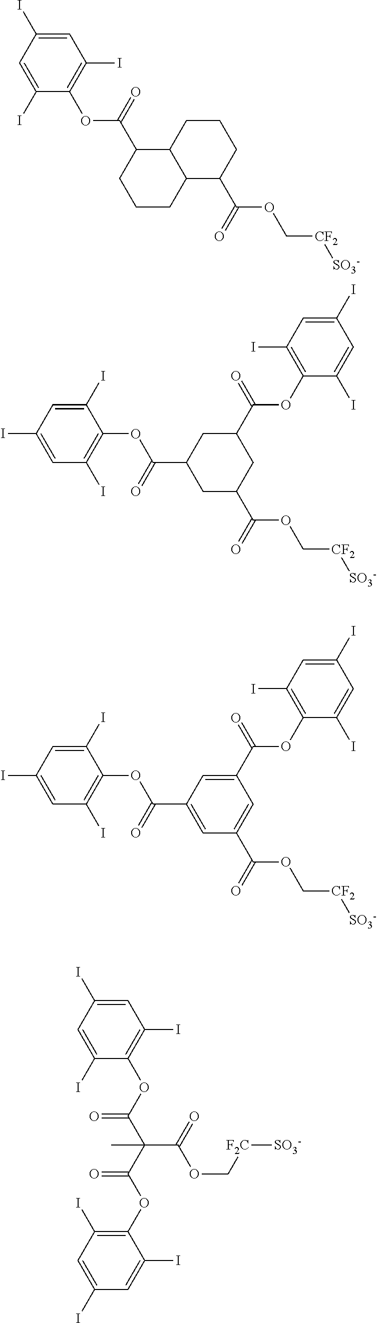

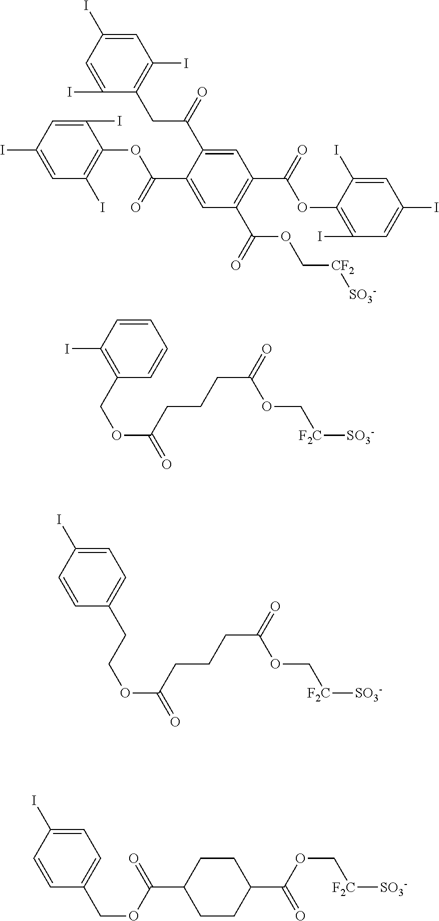

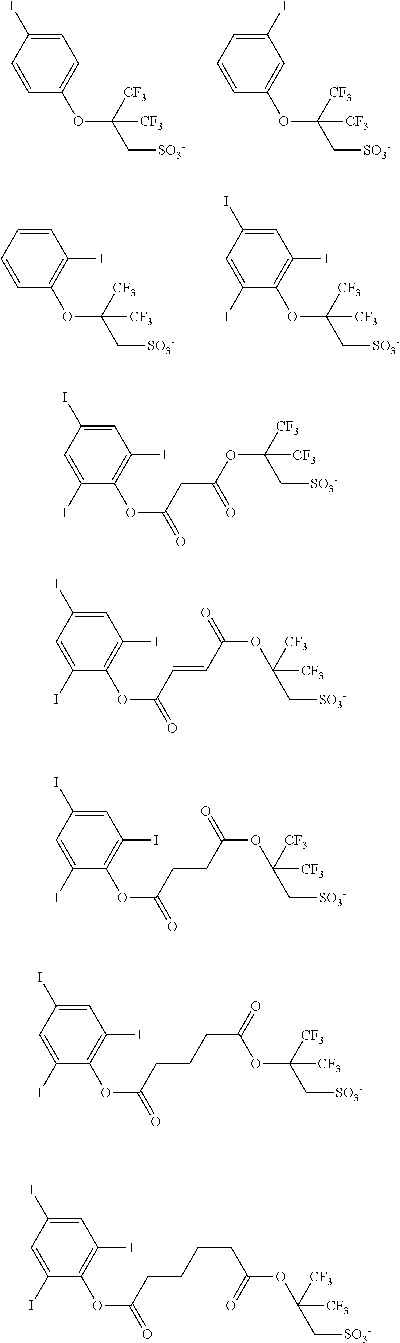

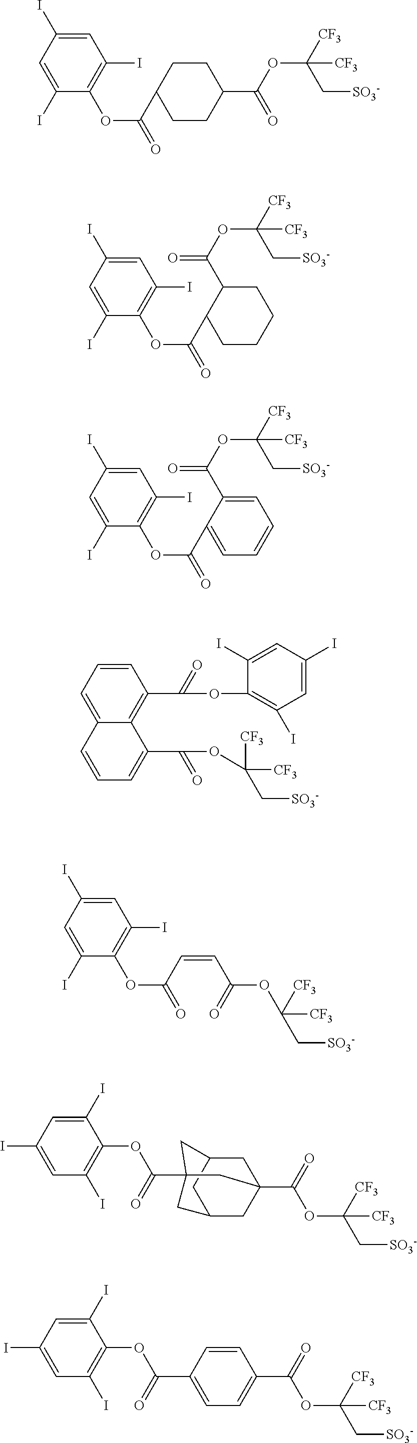

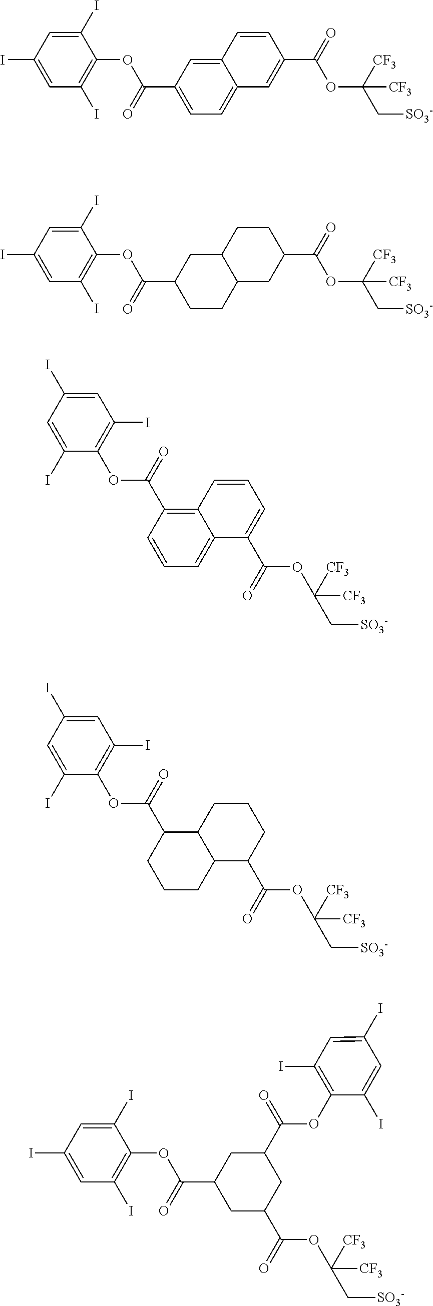

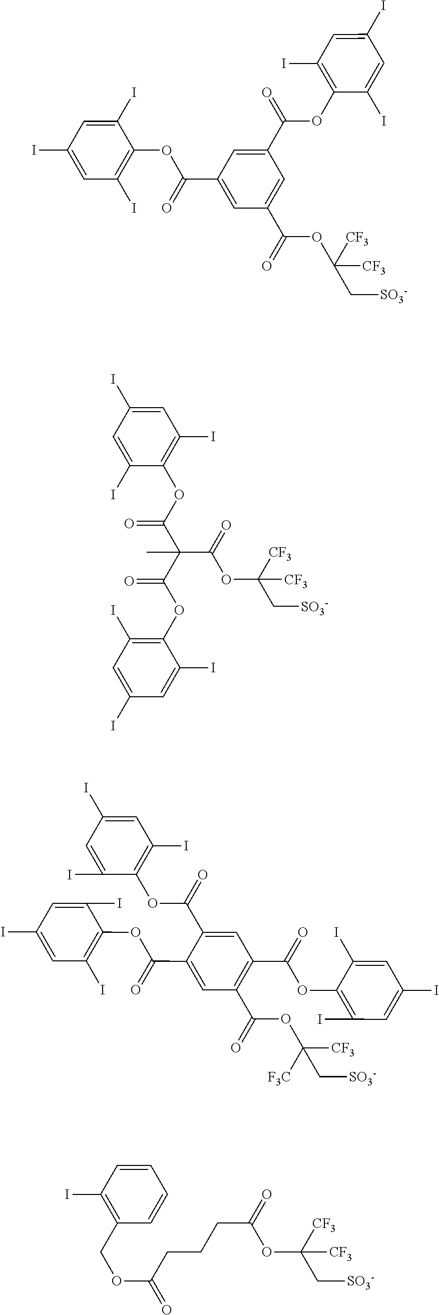

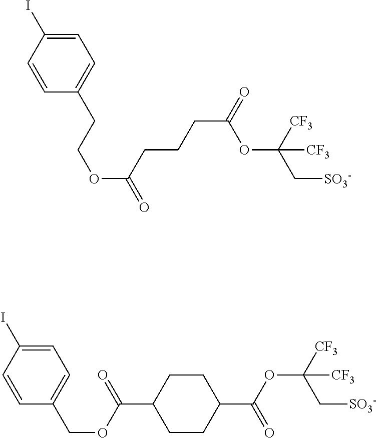

When the chemically amplified resist composition of the present invention contains an acid generator (D), the content thereof is preferably 0.1 to 40 parts by mass, and more preferably 0.5 to 20 parts by mass, based on 80 parts by mass of the base polymer (A). It is preferable that the amount of the acid generator (D) added is within the above range because resolution is good and there is no risk of foreign matter occurring after the resist film is developed or when it is peeled off. The acid generator (D) may be used as one type alone or by combining two or more.

### [Surfactant (E)]

The chemically amplified resist composition of the present invention may further contain a surfactant as a component (E). Preferably, the surfactant (E) is a surfactant that is insoluble or poorly soluble in water and soluble in an alkaline developer, or a surfactant that is insoluble or poorly soluble in water and an alkaline developer. As such surfactants, those described in JP2010-215608A and JP2011-016746A can be referred to.

Among the surfactants described in the above publications, preferable surfactants that are insoluble or poorly soluble in water and alkaline developers include FC-4430 (manufactured by 3M), Surflon (registered trademark) S-381 (manufactured by AGC Seimi Chemical Co., Ltd.), Olfine (registered trademark) E1004 (manufactured by Nissin Chemical Industry Co., Ltd.), KH-20, KH-30 (manufactured by AGC Seimi Chemical Co., Ltd.), and an oxetane ring-opening polymer represented by the following formula (surf-1).

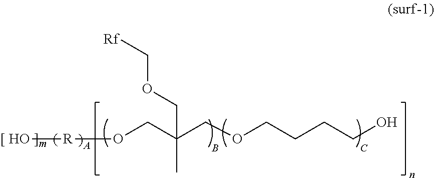

Here, R, Rf, A, B, C, “m”, and “n” apply only to the general formula (surf-1), regardless of the above description. R is a divalent to tetravalent aliphatic group having 2 to 5 carbon atoms. As the aliphatic group, divalent ones include an ethylene group, a 1,4-butylene group, a 1,2-propylene group, a 2,2-dimethyl-1,3-propylene group, a 1,5-pentylene group, etc., and trivalent or tetravalent ones include the following.

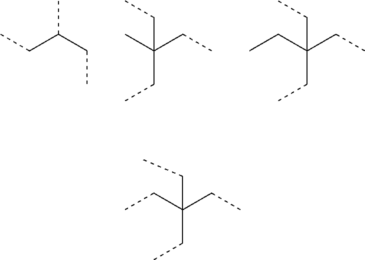

In the formulae, the dashed lines represent bonding points and are partial structures derived from glycerol, trimethylolethane, trimethylolpropane, and pentaerythritol, respectively.

Among these, a 1,4-butylene group, a 2,2-dimethyl-1,3-propylene group, etc. are preferable.

Rf is a trifluoromethyl group or a pentafluoroethyl group, and preferably a trifluoromethyl group. “m” is an integer from 0 to 3, “n” is an integer from 1 to 4, and the sum of “n” and “m” is the valence of R, which is an integer from 2 to 4. A is 1. B is an integer from 2 to 25, and preferably an integer from 4 to 20. C is an integer from 0 to 10, and preferably 0 or 1. Furthermore, the order of the constituent units in the general formula (surf-1) is not specified, and they may be bonded in blocks or randomly. The production of partially fluorinated oxetane ring-opening polymer surfactants is described in detail in U.S. Pat. No. 5,650,483A, etc.

When no resist protective film is used in ArF immersion lithography, surfactants that are insoluble or poorly soluble in water and soluble in alkaline developers have the function of reducing water penetration and leaching by orienting on the surface of the resist film. Therefore, they are useful for suppressing the elution of water-soluble components from the resist film and reducing damage to the exposure device, and are also useful because they are soluble during development with an alkaline aqueous solution after exposure or post-exposure bake (PEB), making them less likely to become foreign matter that can cause defects. Such surfactants are insoluble or poorly soluble in water and soluble in alkaline developers, and are polymer-type surfactants, also known as hydrophobic resins, and are particularly preferable for their high water repellency and improved water slippage.

Such polymer type surfactants include those containing at least one repeating unit selected from those represented by the following general formulae (6A) to (6E).

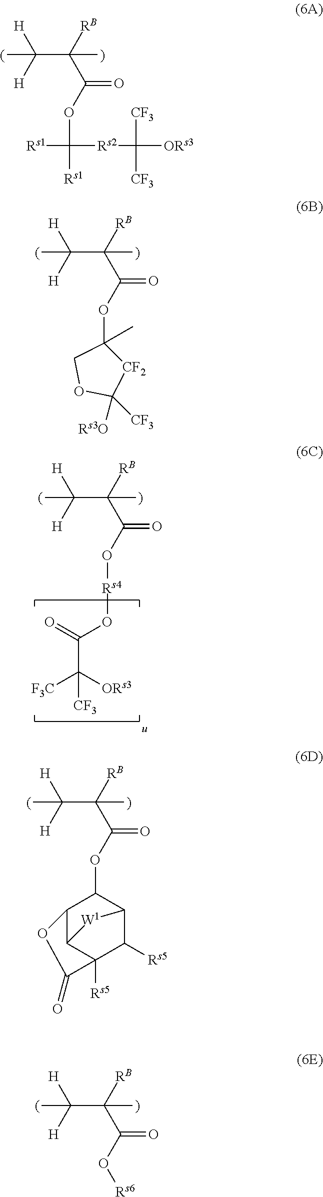

In the general formulae (6A) to (6E), R^{B} is a hydrogen atom, a fluorine atom, a methyl group, or a trifluoromethyl group. W¹ is —CH₂—, —CH₂CH₂—, —O—, or two —H atoms separated from each other. Each R^{s1} is independently a hydrogen atom or a hydrocarbyl group having 1 to 10 carbon atoms. R^{s2} is a single bond or a linear or branched hydrocarbylene group having 1 to 5 carbon atoms. Each R^{s3} is independently a hydrogen atom, a hydrocarbyl group or a fluorinated hydrocarbyl group having 1 to 15 carbon atoms, or an acid-labile group. When R^{s3} is a hydrocarbyl group or a fluorinated hydrocarbyl group, an ether bond or a carbonyl group may be present between the carbon-carbon bonds. R^{s4} is a (u+1)-valent hydrocarbon group or a fluorinated hydrocarbon group having 1 to 20 carbon atoms. “u” is 1, 2 or 3. Each R^{s5} is independently a hydrogen atom or a group represented by —C(═O)—O—R^{sa}. R^{s3} is a fluorinated hydrocarbyl group having 1 to 20 carbon atoms. R^{s6} is a hydrocarbyl group or a fluorinated hydrocarbyl group having 1 to 15 carbon atoms, and an ether bond or a carbonyl group may be present between the carbon-carbon bonds.

The hydrocarbyl group having 1 to 10 carbon atoms represented by R^{s1} is preferably a saturated hydrocarbyl group, and may be linear, branched, or cyclic. Specific examples thereof include alkyl groups having 1 to 10 carbon atoms, such as a methyl group, an ethyl group, an n-propyl group, an isopropyl group, an n-butyl group, an isobutyl group, a sec-butyl group, a tert-butyl group, an n-pentyl group, an n-hexyl group, an n-heptyl group, an n-octyl group, an n-nonyl group, and an n-decyl group; and cyclic saturated hydrocarbyl groups having 3 to 10 carbon atoms, such as a cyclopropyl group, a cyclobutyl group, a cyclopentyl group, a cyclohexyl group, an adamantyl group, and a norbornyl group. Of these, those having 1 to 6 carbon atoms are preferable.

The hydrocarbylene group represented by R^{s2} is preferably a saturated hydrocarbylene group, and may be linear, branched, or cyclic. Specific examples thereof include a methylene group, an ethylene group, a propylene group, a butylene group, a pentylene group, etc.

The hydrocarbyl group represented by R^{s3} and R^{s6} may be saturated or unsaturated, and may be linear, branched, or cyclic. Specific examples thereof include saturated hydrocarbyl groups, aliphatic unsaturated hydrocarbyl groups such as, alkenyl groups and alkynyl groups, with saturated hydrocarbyl groups being preferable. Specific examples of the saturated hydrocarbyl group include, in addition to those exemplified as the hydrocarbyl group represented by R^{s1}, an undecyl group, a dodecyl group, a tridecyl group, a tetradecyl group, a pentadecyl group, etc. Specific examples of the fluorinated hydrocarbyl group represented by R^{s3} and R^{s6} include groups in which some or all of the hydrogen atoms bonded to the carbon atoms of the above-mentioned hydrocarbyl group are substituted with fluorine atoms. As mentioned above, an ether bond or a carbonyl group may be present between these carbon-carbon bonds.

Specific examples of the acid-labile group represented by R^{s3} include the groups represented by the general formulae (AL-1) to (AL-3), trialkylsilyl groups in which each alkyl group has 1 to 6 carbon atoms, and oxo group-containing alkyl groups having 4 to 20 carbon atoms.

The (u+1)-valent hydrocarbon group or fluorinated hydrocarbon group represented by R^{s4} may be linear, branched, or cyclic, and specific examples thereof include groups obtained by further eliminating “u” hydrogen atoms from the above-mentioned hydrocarbyl group or fluorinated hydrocarbyl group.

The fluorinated hydrocarbyl group represented by R^{sa} is preferably saturated, and may be linear, branched, or cyclic. Specific examples thereof include those in which some or all of the hydrogen atoms of the hydrocarbyl groups have been substituted with fluorine atoms such as a trifluoromethyl group, a 2,2,2-trifluoroethyl group, a 3,3,3-trifluoro-1-propyl group, a 3,3,3-trifluoro-2-propyl group, a 2,2,3,3-tetrafluoropropyl group, a 1,1,1,3,3,3-hexafluoroisopropyl group, a 2,2,3,3,4,4,4-heptafluorobutyl group, a 2,2,3,3,4,4,5,5-octafluoropentyl group, a 2,2,3,3,4,4,5,5,6,6,7,7-dodecafluoroheptyl group, a 2-(perfluorobutyl)ethyl group, a 2-(perfluorohexyl)ethyl group, a 2-(perfluorooctyl)ethyl group, and a 2-(perfluorodecyl)ethyl group.

Specific examples of the repeating unit represented by any one of the general formulae (6A) to (6E) include, but are not limited to, those shown below. In the following formulae, R^{B} is as defined above.

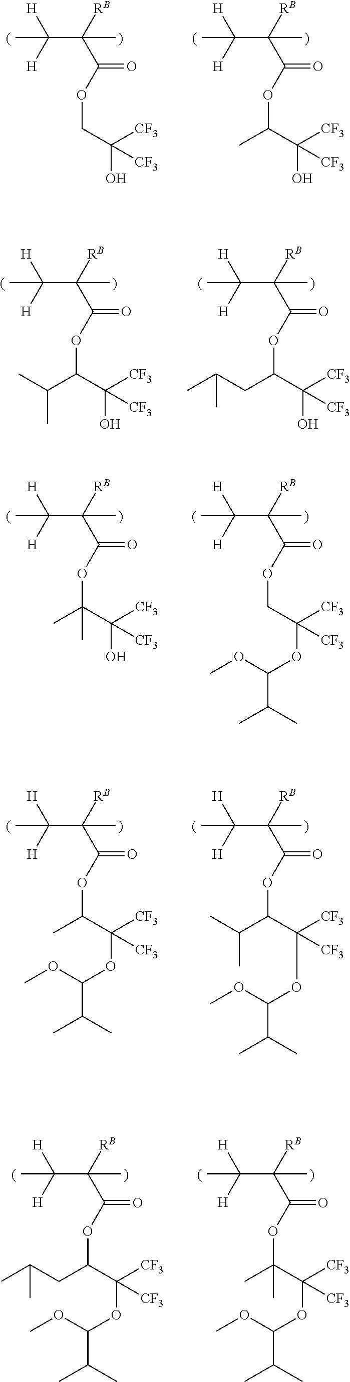

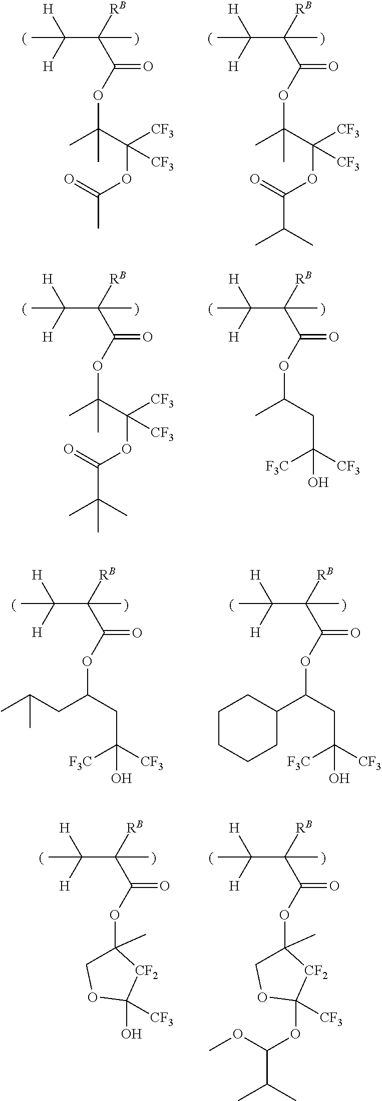

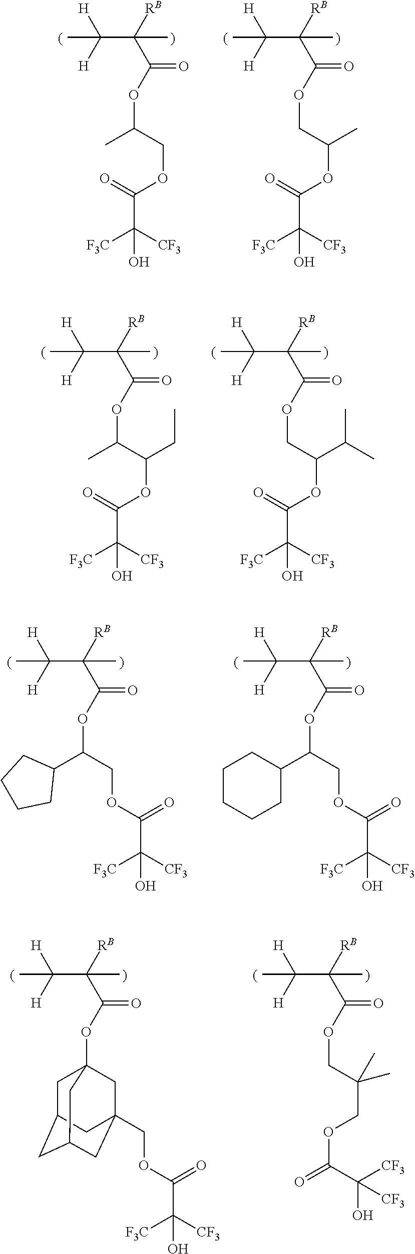

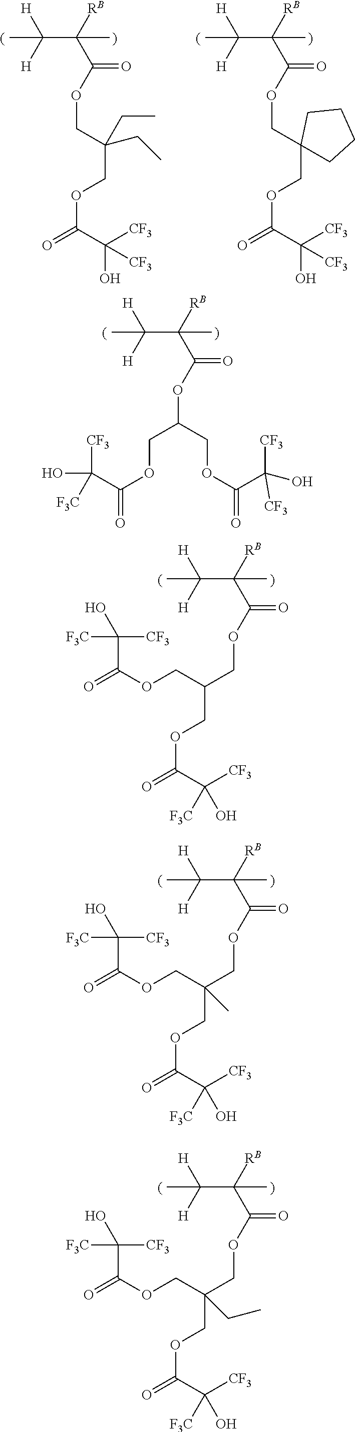

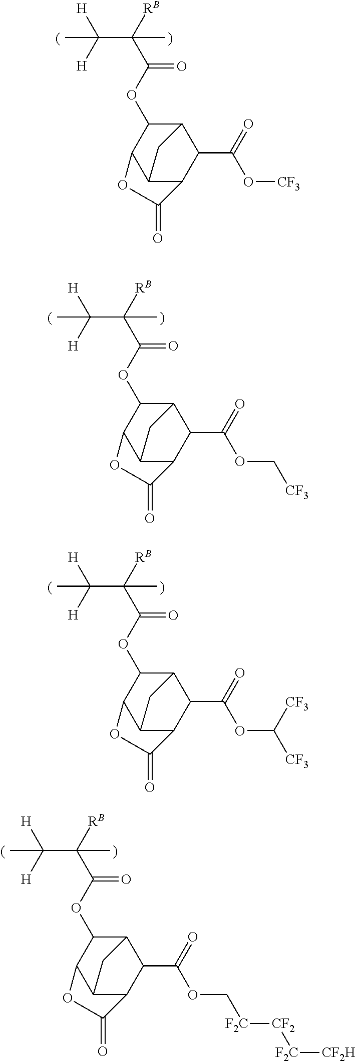

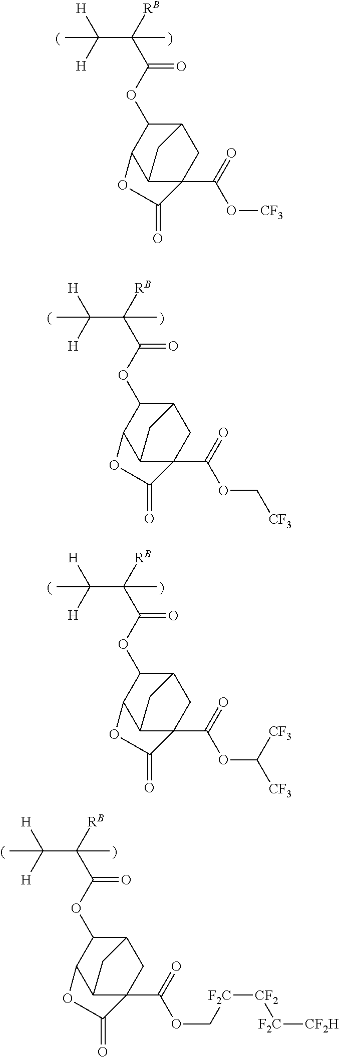

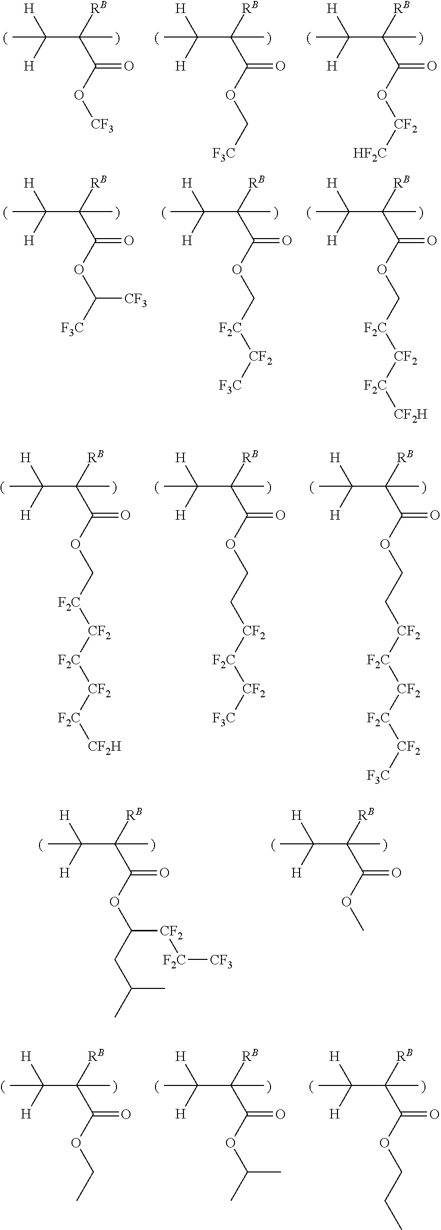

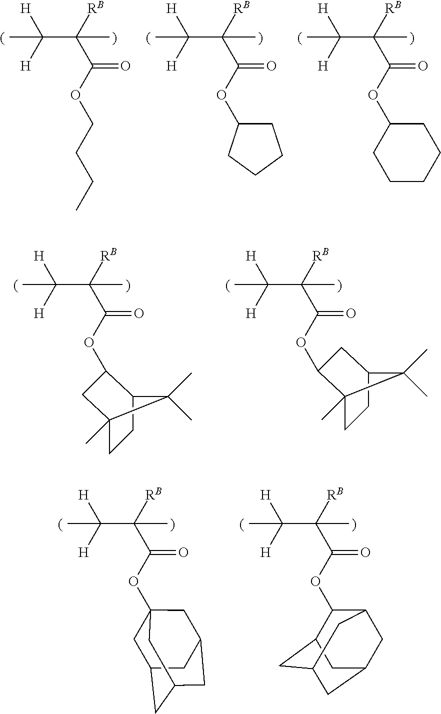

The polymer type surfactant may further contain repeating units other than the repeating units represented by the general formulae (6A) to (6E). Other repeating units include repeating units obtained from methacrylic acid, α-trifluoromethylacrylic acid derivatives, etc. In the polymer type surfactant, the content of repeating units represented by the general formulae (6A) to (6E) is preferably 20 mol % or more, more preferably 60 mol % or more, and further preferably 100 mol % of all repeating units.

The Mw of the polymer type surfactant is preferably 1,000 to 500,000, and more preferably 3,000 to 100,000. The Mw/Mn is preferably 1.0 to 2.0, and more preferably 1.0 to 1.6.

As a method for synthesizing the polymer type surfactant, an example is to mix monomers containing unsaturated bonds that provide repeating units represented by the general formulae (6A) to (6E) and other repeating units as necessary in an organic solvent, add a radical initiator, and heat to polymerize. Specific examples of organic solvents used during polymerization include toluene, benzene, THF, diethyl ether, and dioxane. Specific examples of the polymerization initiator include AIBN, 2,2′-azobis(2,4-dimethylvaleronitrile), dimethyl 2,2-azobis(2-methylpropionate), benzoyl peroxide, lauroyl peroxide, etc. The reaction temperature is preferably 50 to 100° C. The reaction time is preferably 4 to 24 hours. The acid-labile group may be used as is after being introduced into the monomer, or it may be protected or partially protected after polymerization.

When synthesizing the polymer type surfactant, known chain transfer agents such as dodecyl mercaptan and 2-mercaptoethanol may be used to adjust the molecular weight. In this case, the amount of these chain transfer agents added is preferably 0.01 to 10 mol % based on the total number of moles of the monomers to be polymerized.

When the chemically amplified resist composition of the present invention contains surfactant (E), the content thereof is preferably 0.1 to 50 parts by mass, and more preferably 0.5 to 10 parts by mass, based on 80 parts by mass of the base polymer (A). When the content of surfactant (E) is 0.1 parts by mass or more, the receding contact angle between the resist film surface and water is sufficiently improved, and it is 50 parts by mass or less, the dissolution rate of the resist film surface in the developer is small, and the height of the formed fine pattern is sufficiently maintained. The surfactant (E) may be used as one type alone or by combining two or more.

### [Dissolution Inhibitor (F)]

The chemically amplified resist composition of the present invention may further contain a dissolution inhibitor as a component (F). When the chemically amplified resist composition of the present invention is a positive type, the difference in dissolution rate between exposed and unexposed areas can be further increased by blending a dissolution inhibitor, thereby further improving resolution.

Specific examples of the dissolution inhibitor include a compound having a molecular weight preferably of 100 to 1,000, and more preferably of 150 to 800, and containing two or more phenolic hydroxy groups in the molecule, in which a hydrogen atom of the phenolic hydroxy groups has been substituted with an acid-labile group in a proportion of 0 to 100 mol % as a whole, or an compound containing a carboxy group in the molecule, in which a hydrogen atom of the carboxy group has been substituted with an acid-labile group in an average proportion of 50 to 100 mol % as a whole. Specific examples include compounds in which a hydrogen atom of a hydroxy group or carboxy group of bisphenol A, trisphenol, phenolphthalein, cresol novolak, naphthalenecarboxylic acid, adamantanecarboxylic acid, or cholic acid have been substitued with an acid-labile group, for example, those described in paragraphs [0155] to [0178] of JP2008-122932A.

When the chemically amplified resist composition of the present invention contains the dissolution inhibitor (F), the content is preferably 0 to 50 parts by mass, and more preferably 5 to 40 parts by mass, based on 80 parts by mass of the base polymer (A). The dissolution inhibitor (F) may be used as one type alone or by combining two or more.

### [Other Components (G)]

The chemically amplified resist composition of the present invention may contain other components (G) such as a compound that decomposes with an acid to generate an acid (acid multiplying compound), an organic acid derivative, a fluorinated alcohol, a water repellency improver, etc. As the acid multiplying compound, the compounds described in JP2009-269953A or JP2010-215608A can be referred to. When the acid multiplying compound is included, the content thereof is preferably 0 to 5 parts by mass, and more preferably 0 to 3 parts by mass, based on 80 parts by mass of the base polymer (A). When the content is in above range, it is possible to control acid diffusion, deterioration of resolution and pattern shape are not occurred. As the organic acid derivative and fluorinated alcohol, compounds described in JP2009-269953A or JP2010-215608A can be referred to.

The water repellency improver can be used in immersion lithography without using a topcoat. As the water repellency improver, a polymer containing a fluorinated alkyl group, a polymer containing a 1,1,1,3,3,3-hexafluoro-2-propanol residue of a specific structure, etc. are preferable, and those exemplified in JP2007-297590A and JP2008-111103A are more preferable. The water repellency improver needs to be soluble in an alkaline developer or an organic solvent developer. The water repellency improver having the specific 1,1,1,3,3,3-hexafluoro-2-propanol residue mentioned above has good solubility in the developer. As a water repellency improver, a polymer containing a repeating unit containing an amino group or an amine salt is highly effective for preventing the evaporation of acid during PEB and preventing poor opening of the hole pattern after development. When the chemically amplified resist composition of the present invention contains the water repellency improver, the content is preferably 0 to 20 parts by mass, and more preferably 0.5 to 10 parts by mass, based on 80 parts by mass of the base polymer (A).

### [Pattern Forming Method]

When the chemically amplified resist composition of the present invention is used in various integrated circuit manufacturing processes, known lithography techniques can be applied. An example of a pattern forming method is one that includes a step of forming a resist film on a substrate using the chemically amplified resist composition described above, a step of exposing the resist film to high-energy radiation, and a step of developing the exposed resist film using a developer.

First, the chemically amplified resist composition of the present invention is applied onto a substrate of manufacturing for integrated circuit (Si, SiO₂, SiN, SiON, TiN, WSi, BPSG, SOG, organic antireflective film, etc.) or a substrate of manufacturing for mask circuit (Cr, CrO, CrON, MoSi₂, SiO₂, etc.) by a suitable application method such as spin coating, roll coating, flow coating, dip coating, spray coating, doctor coating, etc., so that the applied film has a thickness of 0.01 to 2.0 μm. This is then prebaked on a hot plate, preferably at 60 to 150° C. for 10 seconds to 30 minutes, and more preferably at 80 to 120° C. for 30 seconds to 20 minutes, to form a resist film.

Next, the resist film is exposed to high-energy radiation. Examples of the high-energy radiation include ultraviolet rays, deep ultraviolet rays, electron beam (EB), extreme ultraviolet (EUV) with a wavelength of 3 to 15 nm, X-rays, soft X-rays, excimer laser light, γ-rays, synchrotron radiation, etc. When ultraviolet rays, deep ultraviolet rays, EUV, X-rays, soft X-rays, excimer laser light, γ-rays, synchrotron radiation, etc. are used as the high-energy radiation, irradiation is applied directly or using a mask for forming the desired pattern, and so that the exposure amount is preferably about 1 to 200 mJ/cm², and more preferably about 10 to 100 mJ/cm². When EB is used as the high-energy radiation, drawing is done directly or using a mask for forming the desired pattern, and so that the exposure amount is preferably about 0.1 to 100 μC/cm², and more preferably about 0.5 to 50 μC/cm². The chemically amplified resist composition of the present invention is particularly suitable for high-energy radiation such as ArF excimer laser light with a wavelength of 193 nm, KrF excimer laser light with a wavelength of 248 nm, EB, EUV with a wavelength of 3 to 15 nm, X-rays, soft X-rays, γ-rays, and synchrotron radiation.

After the exposure, PEB may be performed on a hot plate, preferably at 60 to 150° C. for 10 seconds to 30 minutes, and more preferably at 80 to 120° C. for 30 seconds to 20 minutes.

After the exposure or PEB, a developer of alkaline aqueous solution, such as tetramethylammonium hydroxide (TMAH), tetraethylammonium hydroxide, tetrapropylammonium hydroxide, tetrabutylammonium hydroxide, etc. of 0.1 to 10% by mass, preferably 2 to 5% by mass is used for development for 3 seconds to 3 minutes, preferably for 5 seconds to 2 minutes, by a conventional method such as a dip method, a puddle method, or a spray method. The irradiated areas are dissolved in the developer, and the unexposed areas are not dissolved, forming the desired positive pattern on the substrate.

A negative pattern can also be obtained by using an organic solvent developer instead of the alkaline aqueous solution. Specific examples of the developers used in this case include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. These organic solvents may be used as one type alone or by mixing two or more.

Rinsing may be performed at the end of development. The rinsing liquid is preferably a solvent that is mixed with the developer and does not dissolve the resist film. As such a solvent, alcohols having 3 to 10 carbon atoms, ether compounds having 8 to 12 carbon atoms, alkanes, alkenes, and alkynes having 6 to 12 carbon atoms, and aromatic solvents are preferably used.

Specific examples of the alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, 1-octanol, etc.

Specific examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Specific examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, cyclononane, etc. Specific examples of the alkenes having 6 to 12 carbon atoms include hexene, heptene, octene, cyclohexene, methylcyclohexene, dimethylcyclohexene, cycloheptene, cyclooctene, etc. Specific examples of the alkynes having 6 to 12 carbon atoms include hexyne, heptyne, octyne, etc.

Specific examples of the aromatic solvents include toluene, xylene, ethylbenzene, isopropylbenzene, tert-butylbenzene, and mesitylene.

By rinsing, it is possible to reduce the collapse of the resist pattern and the occurrence of defects. Furthermore, rinsing is not necessarily essential, and the amount of solvent used can be reduced by not rinsing.

The hole pattern or trench pattern after development can also be shrunk using thermal flow, RELACS technology, or DSA technology. A shrink agent is applied onto the hole pattern, and the diffusion of acid catalyst from the resist film during baking causes crosslinking of the shrink agent on the surface of the resist film, and the shrink agent adheres to the sidewalls of the hole pattern. The bake temperature is preferably 70 to 180° C., and more preferably 80 to 170° C., and the bake time is preferably 10 to 300 seconds, removing excess shrink agent and shrinking the hole pattern.

### EXAMPLE

The present invention is specifically described below with reference to Examples and Comparative Examples. However, the present invention is not limited to the following Examples. The apparatuses used are as follows.
MALDI TOF-MS: JEOL S3000

### [1] Synthesis of Onium Salt Type Monomer

### [Example 1-1] Synthesis of Onium Salt Type Monomer a1-1

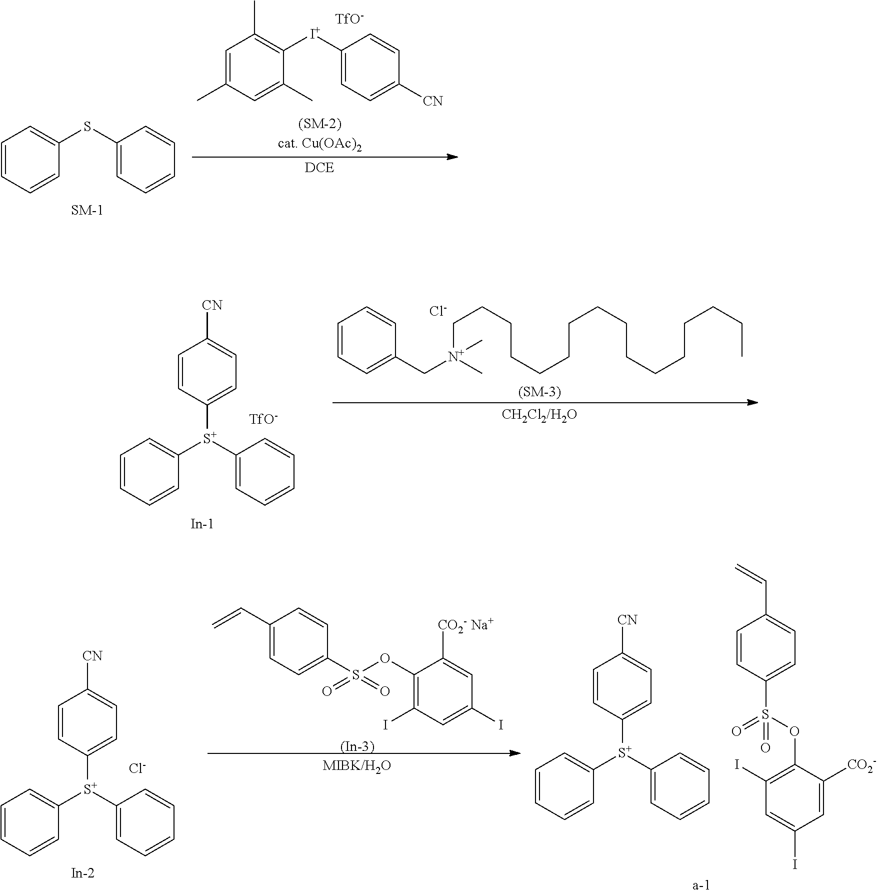

(1) Synthesis of Intermediate in-1

Under a nitrogen atmosphere, SM-1 (27.9 g), SM-2 (89.5 g), and copper acetate (8.24 g) were dissolved in dichloroethane (300 g). The reaction system was then heated to 100° C. and aged for 15 hours. After aging, the reaction system was cooled and water (150 g) was added to stop the reaction. The organic layer was then separated, washed with water, and then concentrated under reduced pressure to remove the solvent. The residue was purified by silica gel chromatography to obtain 53.8 g of the intermediate In-1 as a yellow viscous oily substance (yield: 87%).

(2) Synthesis of Intermediate in-2

Under a nitrogen atmosphere, intermediate In-1 (53.8 g) and SM-3 (53.6 g) were dissolved in a mixed solution of methylene chloride (300 g) and water (300 g). The aqueous layer was separated and washed with diisopropyl ether (100 g) to obtain 340.2 g of an aqueous solution of intermediate In-2 (yield: 100%).

### (3) Synthesis of Sulfonium Salt Type Monomer a-1

Under a nitrogen atmosphere, an aqueous solution of intermediate In-2 (207.4 g), intermediate In-3 (43.4 g), methyl isobutyl ketone (300 g), and water (150 g) was prepared and stirred at room temperature for 30 minutes. The organic layer was separated, washed with water, and then concentrated under reduced pressure. The residue was washed with diisopropyl ether and concentrated to obtain 59.5 g of a-1 as an oily substance (yield: 94%).

The TOF-MS results for the sulfonium salt type monomer a-1 are shown below.
MALDI TOF-MS: POSITIVE M⁺288 (C₁₉H₁₄NS⁺ equivalent)
   NEGATIVE M⁻ 555 (C₁₅H₉I₂O₅S⁻ equivalent)

### [Examples 1-2 to 1-7] Synthesis of Sulfonium Salt Type Monomers a-2 to a-7

Sulfonium salt type monomers a-2 to a-7 represented by the following formulae were synthesized using corresponding raw materials and known organic synthesis reactions.

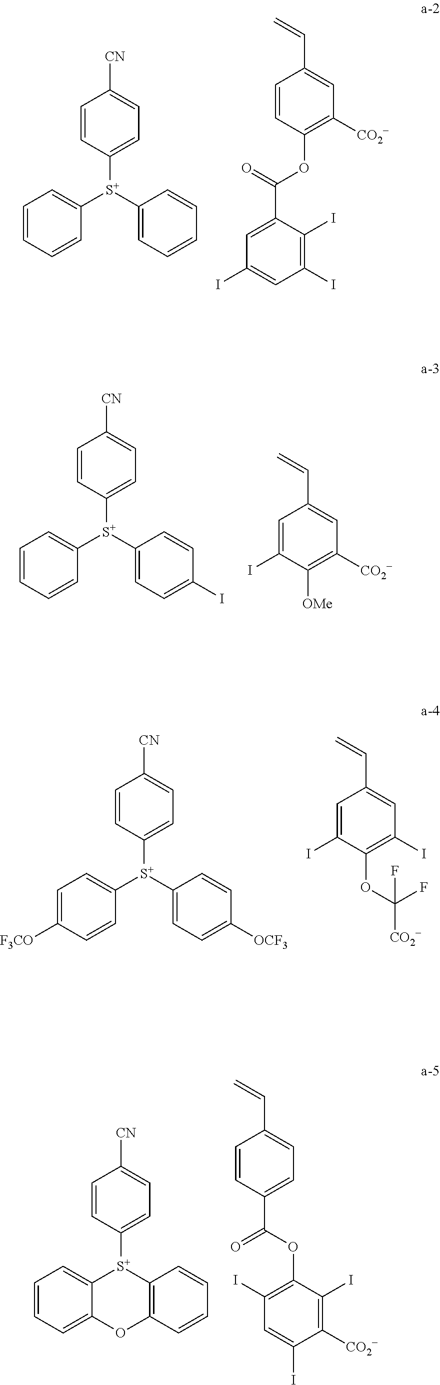

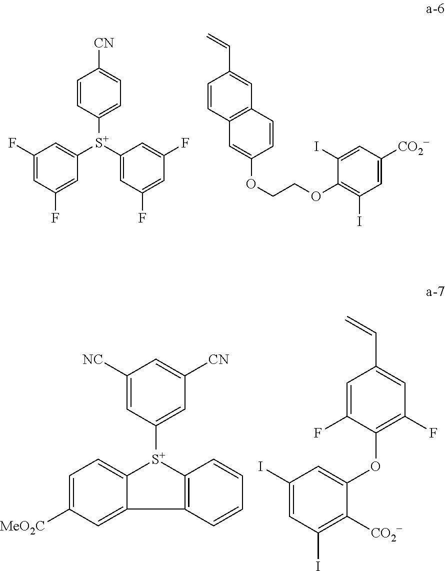

### [Comparative Examples 1-1 to 1-51] Synthesis of Comparative Onium Salt Type Monomers Ca-1 to Ca-5

Comparative onium salt monomers ca-1 to ca-5 represented by the following formulae were synthesized using corresponding raw materials and known organic synthesis reactions.

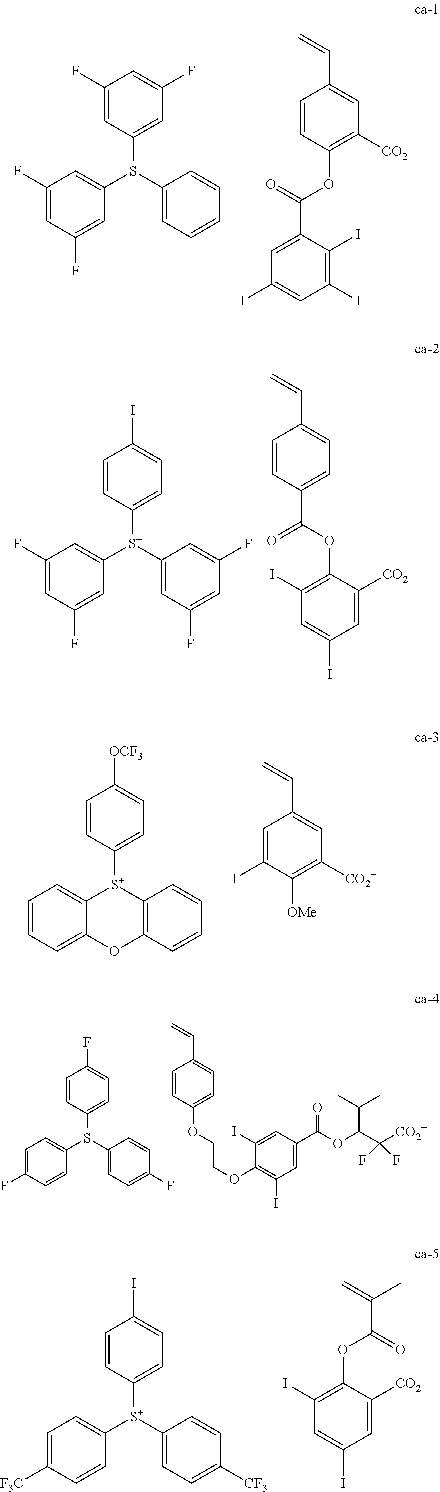

### [2] Synthesis of Base Polymer

Among the monomers used in the synthesis of the base polymer, those other than monomers a-1 to a-7 and comparative monomers ca-1 to ca-5 are as follows.

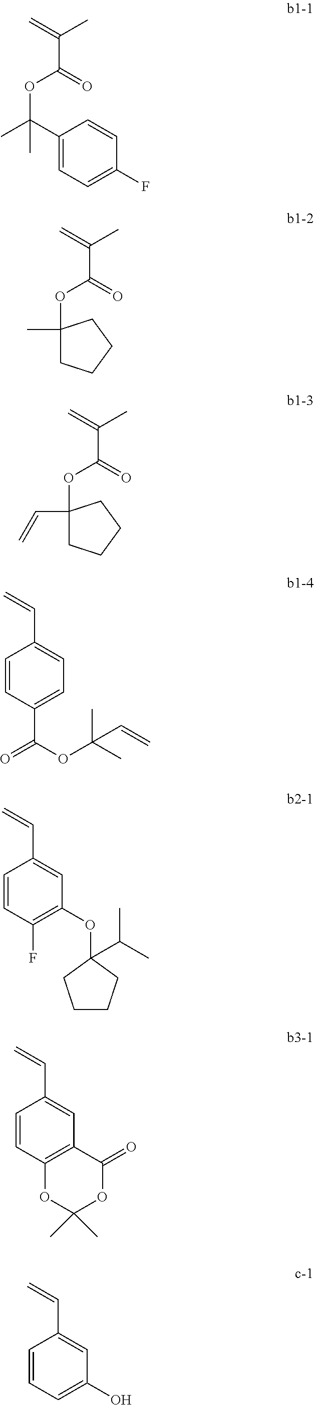

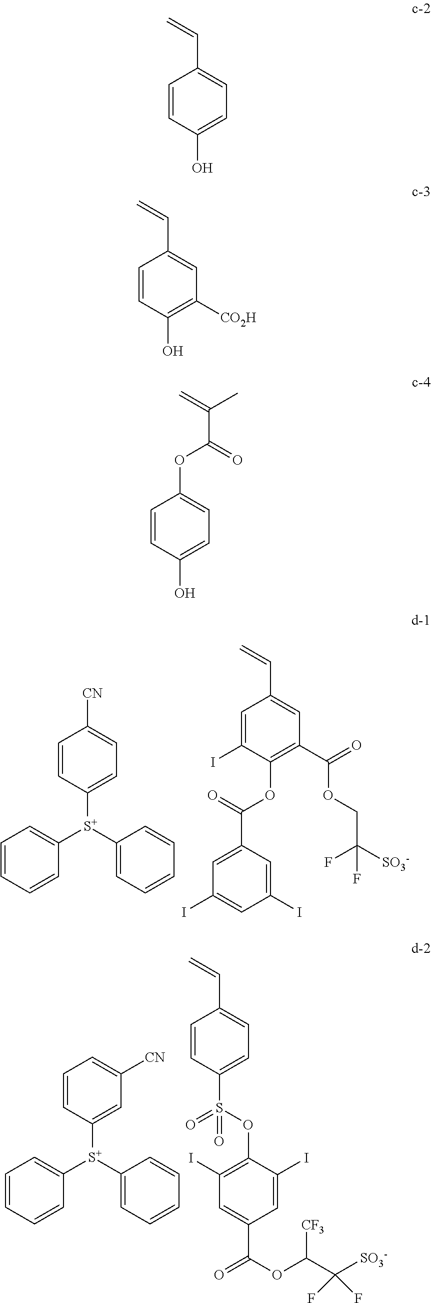

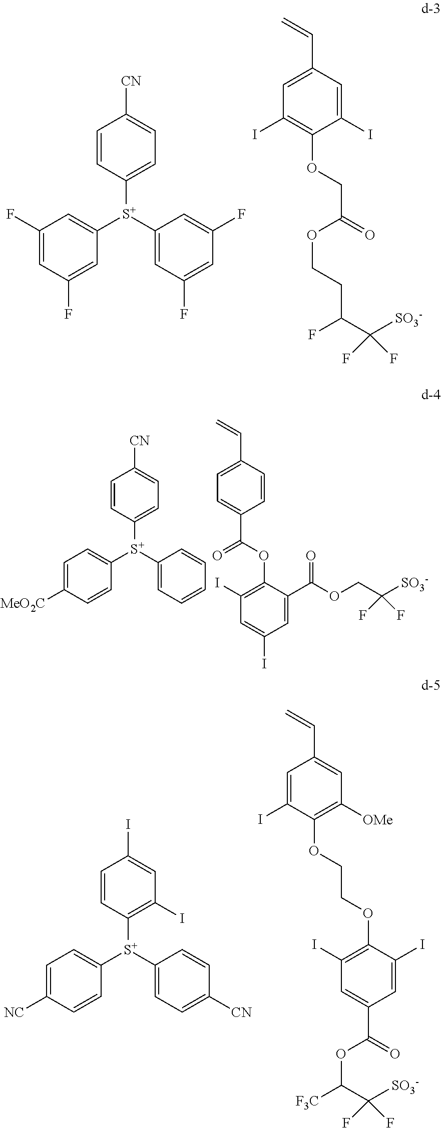

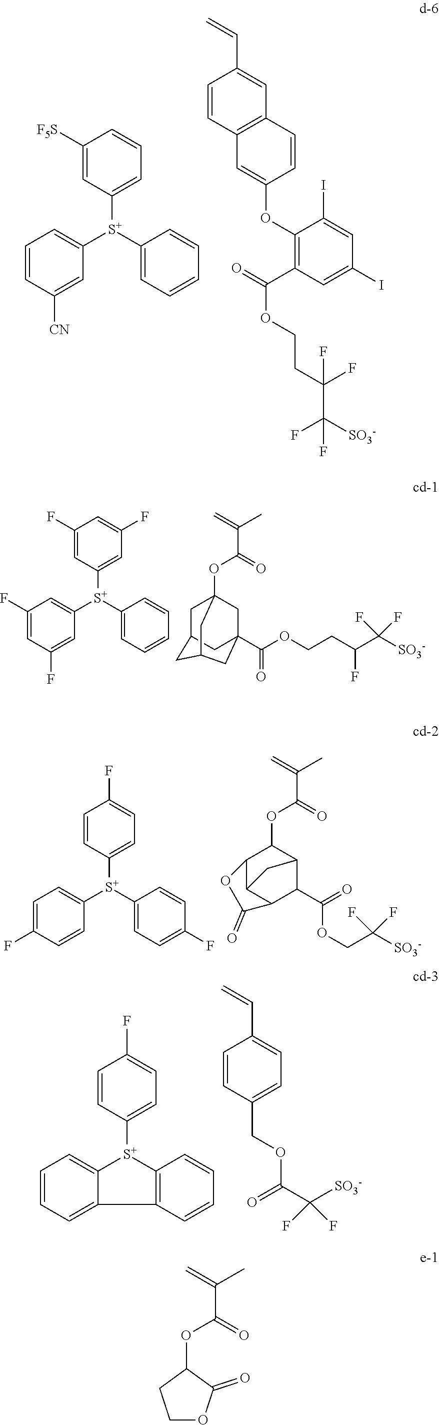

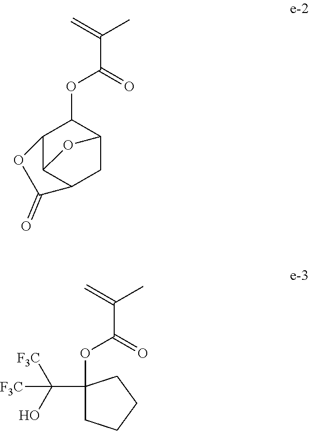 [SMILES: C=C(C)C(=O)OC1C2CC3C(=O)OC1C3O2 ; C=C(C)C(=O)OC1(C(O)(C(F)(F)F)C(F)(F)F)CCCC1]

### [Example 2-1] Synthesis of Polymer P-1

Under a nitrogen atmosphere, monomer a-1 (6.0 g), monomer b1-1 (15.9 g), monomer c-1 (6.1 g), monomer d-1 (23.0 g), 1.64 g of V-601 (manufactured by Fujifilm Wako Pure Chemical Industries, Ltd.), and 70 g of MEK were placed in a flask to prepare a monomer-polymerization initiator solution. 23 g of MEK was placed in another flask under a nitrogen atmosphere and was heated to 80° C. with stirring, and the monomer-polymerization initiator solution was then dropped over 4 hours. After the dropwise addition, the temperature of the polymerization solution was kept at 80° C. and stirring was continued for 2 hours, and then it was cooled to room temperature. The obtained polymerization solution was dropped into 1500 g of vigorously stirred hexane, and the precipitated polymer was filtered off. The obtained polymer was washed twice with 300 g of hexane, and then vacuum dried at 50° C. for 20 hours to obtain a white powdery polymer P-1 (yield: 96.1 g, yield: 96%). Polymer P-1 had an Mw of 10,100 and an Mw/Mn of 1.62. Note that Mw was a value measured in terms of polystyrene by GPC using DMF as a solvent.

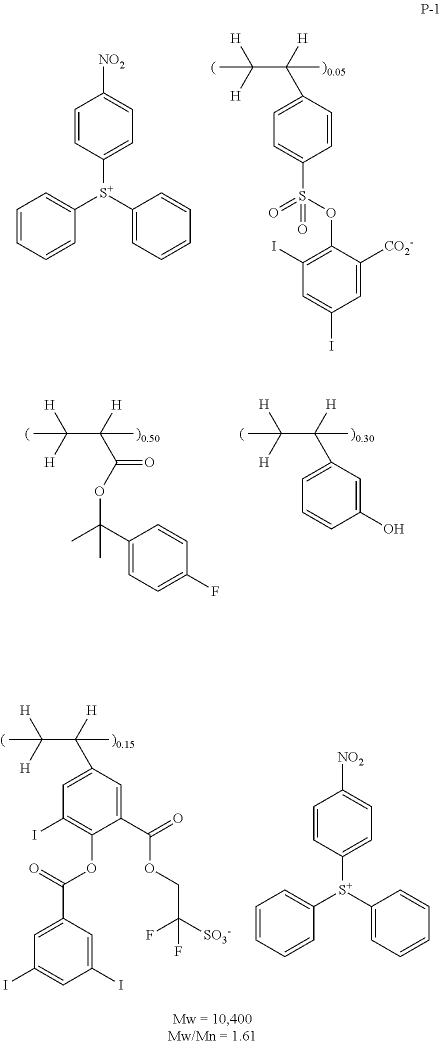

### [Examples 2-2 to 2-50, Comparative Examples 2-1 to 2-38] Synthesis of Polymers P-2 to P-50, and Comparative Polymers CP-1 to CP-38

Polymers shown in Tables 1 to 3 were produced in the same manner as in Synthesis Example 2-1, except that the types and blending ratios of each monomer were changed.

TABLE 1

| | | Incorpo- | | Incorpo- | | Incorpo- | | Incorpo- | | Incorpo- | | |
|---|---|---|---|---|---|---|---|---|---|---|---|---|
| | | ration | | ration | | ration | | ration | | ration | | |
| | | ratio | | ratio | | ratio | | ratio | | ratio | | |
| Polymer | Unit 1 | (mol %) | Unit 2 | (mol %) | Unit 3 | (mol %) | Unit 4 | (mol %) | Unit 5 | (mol %) | Mw | Mw/Mn |
| P-1 | a-1 | 5 | b1-1 | 50 | c-1 | 30 | d-1 | 15 | — | — | 10100 | 1.62 |
| P-2 | a-2 | 5 | b1-1 | 50 | c-1 | 30 | d-1 | 15 | — | — | 10200 | 1.62 |
| P-3 | a-3 | 5 | b1-1 | 50 | c-1 | 30 | d-1 | 15 | — | — | 10100 | 1.61 |
| P-4 | a-4 | 5 | b1-1 | 50 | c-1 | 30 | d-1 | 15 | — | — | 10500 | 1.61 |
| P-5 | a-5 | 5 | b1-1 | 50 | c-1 | 30 | d-1 | 15 | — | — | 10400 | 1.62 |
| P-6 | a-6 | 5 | b1-1 | 50 | c-1 | 30 | d-1 | 15 | — | — | 10400 | 1.63 |
| P-7 | a-7 | 5 | b1-1 | 50 | c-1 | 30 | d-1 | 15 | — | — | 10300 | 1.62 |
| P-8 | a-1 | 5 | b1-2 | 50 | c-1 | 30 | d-1 | 15 | — | — | 10500 | 1.61 |
| P-9 | a-2 | 5 | b1-2 | 50 | c-1 | 30 | d-1 | 15 | — | — | 10200 | 1.60 |
| P-10 | a-3 | 5 | b1-2 | 50 | c-1 | 30 | d-1 | 15 | — | — | 10100 | 1.61 |
| P-11 | a-4 | 5 | b1-2 | 50 | c-1 | 30 | d-1 | 15 | — | — | 10400 | 1.62 |
| P-12 | a-5 | 5 | b1-2 | 50 | c-1 | 30 | d-1 | 15 | — | — | 10500 | 1.63 |
| P-13 | a-6 | 5 | b1-2 | 50 | c-1 | 30 | d-1 | 15 | — | — | 10500 | 1.62 |
| P-14 | a-7 | 5 | b1-2 | 50 | c-1 | 30 | d-1 | 15 | — | — | 10400 | 1.61 |
| P-15 | a-1 | 5 | b1-3 | 50 | c-1 | 30 | d-1 | 15 | — | — | 10300 | 1.62 |
| P-16 | a-2 | 5 | b1-3 | 50 | c-1 | 30 | d-1 | 15 | — | — | 10200 | 1.63 |
| P-17 | a-3 | 5 | b1-3 | 50 | c-1 | 30 | d-1 | 15 | — | — | 10000 | 1.62 |
| P-18 | a-4 | 5 | b1-3 | 50 | c-1 | 30 | d-1 | 15 | — | — | 10400 | 1.62 |
| P-19 | a-5 | 5 | b1-3 | 50 | c-1 | 30 | d-1 | 15 | — | — | 10200 | 1.62 |
| P-20 | a-6 | 5 | b1-3 | 50 | c-1 | 30 | d-1 | 15 | — | — | 10100 | 1.61 |
| P-21 | a-7 | 5 | b1-3 | 50 | c-1 | 30 | d-1 | 15 | — | — | 10600 | 1.62 |
| P-22 | a-1 | 5 | b1-4 | 50 | c-1 | 30 | d-1 | 15 | — | — | 10200 | 1.62 |
| P-23 | a-2 | 5 | b1-4 | 50 | c-1 | 30 | d-1 | 15 | — | — | 10200 | 1.61 |
| P-24 | a-3 | 5 | b1-4 | 50 | c-1 | 30 | d-1 | 15 | — | — | 10100 | 1.63 |
| P-25 | a-4 | 5 | b1-4 | 50 | c-1 | 30 | d-1 | 15 | — | — | 10200 | 1.62 |
| P-26 | a-5 | 5 | b1-4 | 50 | c-1 | 30 | d-1 | 15 | — | — | 10200 | 1.61 |
| P-27 | a-6 | 5 | b1-4 | 50 | c-1 | 30 | d-1 | 15 | — | — | 10300 | 1.61 |
| P-28 | a-7 | 5 | b1-4 | 50 | c-1 | 30 | d-1 | 15 | — | — | 10500 | 1.61 |
| P-29 | a-1 | 5 | b1-1 | 25 | b2-1 | 25 | c-2 | 30 | d-1 | 15 | 10100 | 1.62 |
| P-30 | a-1 | 5 | b1-2 | 25 | b2-1 | 25 | c-2 | 30 | d-1 | 15 | 10400 | 1.63 |

TABLE 2

| | | Incorpo- | | Incorpo- | | Incorpo- | | Incorpo- | | Incorpo- | | |
|---|---|---|---|---|---|---|---|---|---|---|---|---|
| | | ration | | ration | | ration | | ration | | ration | | |
| | | ratio | | ratio | | ratio | | ratio | | ratio | | |
| Polymer | Unit 1 | (mol %) | Unit 2 | (mol %) | Unit 3 | (mol %) | Unit 4 | (mol %) | Unit 5 | (mol %) | Mw | Mw/Mn |
| P-31 | a-1 | 5 | b1-3 | 25 | b2-1 | 25 | c-2 | 30 | d-1 | 15 | 10300 | 1.64 |
| P-32 | a-1 | 5 | b1-3 | 30 | b2-1 | 25 | c-3 | 25 | d-1 | 15 | 10200 | 1.62 |
| P-33 | a-1 | 5 | b1-1 | 25 | b2-1 | 25 | c-4 | 30 | d-2 | 15 | 10400 | 1.61 |
| P-34 | a-2 | 5 | b1-1 | 30 | b3-1 | 15 | c-1 | 30 | d-2 | 15 | 10200 | 1.62 |
| P-35 | a-2 | 5 | b1-1 | 25 | b1-4 | 25 | c-2 | 30 | d-1 | 15 | 10100 | 1.62 |
| P-36 | a-1 | 5 | b1-1 | 50 | c-1 | 30 | d-2 | 15 | — | — | 10000 | 1.62 |
| P-37 | a-1 | 5 | b1-1 | 50 | c-1 | 30 | d-3 | 15 | — | — | 10200 | 1.63 |
| P-38 | a-2 | 5 | b1-1 | 50 | c-1 | 30 | d-4 | 15 | — | — | 10400 | 1.62 |
| P-39 | a-3 | 5 | b1-1 | 50 | c-1 | 30 | d-5 | 15 | — | — | 10200 | 1.63 |
| P-40 | a-4 | 5 | b1-1 | 50 | c-1 | 30 | d-6 | 15 | — | — | 10100 | 1.62 |
| P-41 | a-2 | 5 | b1-1 | 45 | c-2 | 25 | d-1 | 15 | e-1 | 10 | 10500 | 1.62 |
| P-42 | a-3 | 5 | b1-3 | 45 | c-4 | 25 | d-2 | 15 | e-2 | 10 | 10200 | 1.63 |
| P-43 | a-4 | 5 | b1-3 | 50 | c-2 | 30 | d-3 | 10 | e-3 | 5 | 10300 | 1.62 |
| P-44 | a-1 | 7 | b1-1 | 58 | c-1 | 35 | — | — | — | — | 10100 | 1.61 |
| P-45 | a-2 | 7 | b1-1 | 58 | c-1 | 35 | — | — | — | — | 10400 | 1.60 |
| P-46 | a-3 | 7 | b1-2 | 58 | c-2 | 35 | — | — | — | — | 10400 | 1.62 |
| P-47 | a-4 | 7 | b1-3 | 58 | c-3 | 35 | — | — | — | — | 10200 | 1.63 |
| P-48 | a-5 | 7 | b1-4 | 58 | c-4 | 35 | — | — | — | — | 10300 | 1.62 |
| P-49 | a-6 | 7 | b1-1 | 29 | b2-1 | 29 | c-1 | 35 | — | — | 10100 | 1.62 |
| P-50 | a-7 | 7 | b1-1 | 29 | b3-1 | 29 | c-2 | 35 | — | — | 10200 | 1.63 |

TABLE 3

| | | Incorpo- | | Incorpo- | | Incorpo- | | Incorpo- | | Incorpo- | | |
|---|---|---|---|---|---|---|---|---|---|---|---|---|
| | | ration | | ration | | ration | | ration | | ration | | |
| | | ratio | | ratio | | ratio | | ratio | | ratio | | |
| Polymer | Unit 1 | (mol %) | Unit 2 | (mol %) | Unit 3 | (mol %) | Unit 4 | (mol %) | Unit 5 | (mol %) | Mw | Mw/Mn |
| CP-1 | ca-1 | 5 | b1-1 | 50 | c-1 | 30 | d-1 | 15 | — | — | 10200 | 1.61 |
| CP-2 | ca-2 | 5 | b1-1 | 50 | c-1 | 30 | d-1 | 15 | — | — | 10200 | 1.62 |
| CP-3 | ca-3 | 5 | b1-1 | 50 | c-1 | 30 | d-1 | 15 | — | — | 10500 | 1.64 |
| CP-4 | ca-4 | 5 | b1-1 | 50 | c-1 | 30 | d-1 | 15 | — | — | 10300 | 1.63 |
| CP-5 | ca-5 | 5 | b1-1 | 50 | c-1 | 30 | d-1 | 15 | — | — | 10400 | 1.62 |
| CP-6 | ca-1 | 5 | b1-2 | 50 | c-1 | 30 | d-1 | 15 | — | — | 10300 | 1.61 |
| CP-7 | ca-2 | 5 | b1-2 | 50 | c-1 | 30 | d-1 | 15 | — | — | 10200 | 1.62 |
| CP-8 | ca-3 | 5 | b1-2 | 50 | c-1 | 30 | d-1 | 15 | — | — | 10600 | 1.60 |
| CP-9 | ca-4 | 5 | b1-2 | 50 | c-1 | 30 | d-1 | 15 | — | — | 10800 | 1.61 |
| CP-10 | ca-5 | 5 | b1-2 | 50 | c-1 | 30 | d-1 | 15 | — | — | 10500 | 1.62 |
| CP-11 | ca-1 | 5 | b1-3 | 50 | c-1 | 30 | d-1 | 15 | — | — | 10400 | 1.63 |
| CP-12 | ca-2 | 5 | b1-3 | 50 | c-1 | 30 | d-1 | 15 | — | — | 10300 | 1.61 |
| CP-13 | ca-3 | 5 | b1-3 | 50 | c-1 | 30 | d-1 | 15 | — | — | 10600 | 1.62 |
| CP-14 | ca-4 | 5 | b1-3 | 50 | c-1 | 30 | d-1 | 15 | — | — | 10100 | 1.63 |
| CP-15 | ca-5 | 5 | b1-3 | 50 | c-1 | 30 | d-1 | 15 | — | — | 10200 | 1.61 |
| CP-16 | ca-1 | 5 | b1-4 | 50 | c-1 | 30 | d-1 | 15 | — | — | 10400 | 1.63 |
| CP-17 | ca-2 | 5 | b1-4 | 50 | c-1 | 30 | d-1 | 15 | — | — | 10300 | 1.65 |
| CP-18 | ca-3 | 5 | b1-4 | 50 | c-1 | 30 | d-1 | 15 | — | — | 10400 | 1.62 |
| CP-19 | ca-4 | 5 | b1-4 | 50 | c-1 | 30 | d-1 | 15 | — | — | 10600 | 1.62 |
| CP-20 | ca-5 | 5 | b1-4 | 50 | c-1 | 30 | d-1 | 15 | — | — | 10100 | 1.61 |
| CP-21 | ca-1 | 5 | b1-1 | 25 | b2-1 | 25 | c-2 | 30 | d-1 | 15 | 10200 | 1.62 |
| CP-22 | ca-2 | 5 | b1-2 | 25 | b2-1 | 25 | c-2 | 30 | d-2 | 15 | 10000 | 1.63 |
| CP-23 | ca-4 | 5 | b1-3 | 25 | b2-1 | 25 | c-2 | 30 | d-4 | 15 | 10300 | 1.64 |
| CP-24 | ca-1 | 5 | b1-1 | 25 | b2-1 | 25 | c-2 | 30 | cd-1 | 15 | 10200 | 1.62 |
| CP-25 | ca-2 | 5 | b1-2 | 25 | b2-1 | 25 | c-2 | 30 | cd-2 | 15 | 10600 | 1.61 |
| CP-26 | ca-5 | 5 | b1-3 | 25 | b2-1 | 25 | c-2 | 30 | cd-3 | 15 | 10300 | 1.62 |
| CP-27 | ca-1 | 5 | b1-1 | 50 | c-1 | 30 | cd-1 | 15 | — | — | 10100 | 1.63 |
| CP-28 | ca-1 | 5 | b1-1 | 50 | c-1 | 30 | cd-2 | 15 | — | — | 10300 | 1.62 |
| CP-29 | ca-2 | 5 | b1-1 | 50 | c-1 | 30 | cd-3 | 15 | — | — | 10200 | 1.61 |
| CP-30 | ca-1 | 5 | b1-1 | 45 | c-2 | 25 | d-1 | 15 | e-1 | 10 | 10400 | 1.63 |
| CP-31 | ca-2 | 5 | b1-3 | 45 | c-4 | 25 | cd-1 | 15 | e-2 | 10 | 10500 | 1.63 |
| CP-32 | ca-4 | 5 | b1-3 | 50 | c-2 | 30 | cd-2 | 10 | e-3 | 5 | 10300 | 1.62 |
| CP-33 | ca-1 | 7 | b1-1 | 58 | c-1 | 35 | — | — | — | — | 10200 | 1.61 |
| CP-34 | ca-2 | 7 | b1-1 | 58 | c-2 | 35 | — | — | — | — | 10200 | 1.63 |
| CP-35 | ca-4 | 7 | b1-2 | 58 | c-2 | 35 | — | — | — | — | 10400 | 1.62 |
| CP-36 | ca-1 | 7 | b1-1 | 29 | b2-1 | 29 | c-1 | 35 | — | — | 10600 | 1.65 |
| CP-37 | b1-1 | 55 | c-1 | 30 | cd-1 | 15 | — | — | — | — | 10300 | 1.61 |
| CP-38 | b1-2 | 50 | c-2 | 50 | — | — | — | — | — | — | 10100 | 1.64 |

### [3] Preparation of Chemically Amplified Resist Composition

### Examples 3-1 to 3-53, Comparative Examples 3-1 to 3-40

Base polymers of the present invention (P-1 to P-50), comparative base polymers (CP-1 to CP-38), acid generators (PAG-1, PAG-2), and quenchers (SQ-1, AQ-1) with the composition shown in Tables 4 to 6 below were dissolved in a solvent containing 0.0 by mass of 3M FC-4430 as a surfactant. Chemically amplified resist compositions (R-1 to R-53, CR-1 to CR-40) were prepared by filtering the solution through a 0.2 μm Teflon (registered trademark) type filter.

TABLE 4

| | | Base | | Acid | | | |
|---|---|---|---|---|---|---|---|
| | | polymer | Quencher | generator | Solvent | Solvent 2 | Solvent 3 |
| | Resist | (Parts | (Parts | (Parts | (Parts | (Parts | (Parts |
| | composition | by mass) | by mass) | by mass) | by mass) | by mass) | by mass) |
| Example 3-1 | R-1 | P-1(80) | — | — | PGMEA(2250) | EL(2800) | DAA(550) |
| Example 3-2 | R-2 | P-2(80) | — | — | PGMEA(2250) | EL(2800) | DAA(550) |
| Example 3-3 | R-3 | P-3(80) | — | — | PGMEA(2250) | EL(2800) | DAA(550) |
| Example 3-4 | R-4 | P-4(80) | — | — | PGMEA(2250) | EL(2800) | DAA(550) |
| Example 3-5 | R-5 | P-5(80) | — | — | PGMEA(2250) | EL(2800) | DAA(550) |
| Example 3-6 | R-6 | P-6(80) | — | — | PGMEA(2250) | EL(2800) | DAA(550) |
| Example 3-7 | R-7 | P-7(80) | — | — | PGMEA(2250) | EL(2800) | DAA(550) |
| Example 3-8 | R-8 | P-8(80) | — | — | PGMEA(2250) | EL(2800) | DAA(550) |
| Example 3-9 | R-9 | P-9(80) | — | — | PGMEA(2250) | EL(2800) | DAA(550) |
| Example 3-10 | R-10 | P-10(80) | — | — | PGMEA(2250) | EL(2800) | DAA(550) |
| Example 3-11 | R-11 | P-11(80) | — | — | PGMEA(2250) | EL(2800) | DAA(550) |
| Example 3-12 | R-12 | P-12(80) | — | — | PGMEA(2250) | EL(2800) | DAA(550) |
| Example 3-13 | R-13 | P-13(80) | — | — | PGMEA(2250) | EL(2800) | DAA(550) |
| Example 3-14 | R-14 | P-14(80) | — | — | PGMEA(2250) | EL(2800) | DAA(550) |
| Example 3-15 | R-15 | P-15(80) | — | — | PGMEA(2250) | EL(2800) | DAA(550) |
| Example 3-16 | R-16 | P-16(80) | — | — | PGMEA(2250) | EL(2800) | DAA(550) |
| Example 3-17 | R-17 | P-17(80) | — | — | PGMEA(2250) | EL(2800) | DAA(550) |
| Example 3-18 | R-18 | P-18(80) | — | — | PGMEA(2250) | EL(2800) | DAA(550) |
| Example 3-19 | R-19 | P-19(80) | — | — | PGMEA(2250) | EL(2800) | DAA(550) |
| Example 3-20 | R-20 | P-20(80) | — | — | PGMEA(2250) | EL(2800) | DAA(550) |
| Example 3-21 | R-21 | P-21(80) | — | — | PGMEA(2250) | EL(2800) | DAA(550) |
| Example 3-22 | R-22 | P-22(80) | — | — | PGMEA(2250) | EL(2800) | DAA(550) |
| Example 3-23 | R-23 | P-23(80) | — | — | PGMEA(2250) | EL(2800) | DAA(550) |
| Example 3-24 | R-24 | P-24(80) | — | — | PGMEA(2250) | EL(2800) | DAA(550) |
| Example 3-25 | R-25 | P-25(80) | — | — | PGMEA(2250) | EL(2800) | DAA(550) |
| Example 3-26 | R-26 | P-26(80) | — | — | PGMEA(2250) | EL(2800) | DAA(550) |
| Example 3-27 | R-27 | P-27(80) | — | — | PGMEA(2250) | EL(2800) | DAA(550) |
| Example 3-28 | R-28 | P-28(80) | — | — | PGMEA(2250) | EL(2800) | DAA(550) |
| Example 3-29 | R-29 | P-29(80) | — | — | PGMEA(2250) | EL(2800) | DAA(550) |
| Example 3-30 | R-30 | P-30(80) | — | — | PGMEA(2250) | EL(2800) | DAA(550) |

TABLE 5

| | | Base | | Acid | | | |
|---|---|---|---|---|---|---|---|
| | | polymer | Quencher | generator | Solvent | Solvent 2 | Solvent 3 |
| | Resist | (Parts | (Parts | (Parts | (Parts | (Parts | (Parts |
| | composition | by mass) | by mass) | by mass) | by mass) | by mass) | by mass) |
| Example 3-31 | R-31 | P-31(80) | — | PAG-1(10) | PGMEA(2250) | EL(2800) | DAA(550) |
| Example 3-32 | R-32 | P-32(80) | — | — | PGMEA(2250) | EL(2800) | DAA(550) |
| Example 3-33 | R-33 | P-33(80) | — | — | PGMEA(2250) | EL(2800) | DAA(550) |
| Example 3-34 | R-34 | P-34(80) | — | — | PGMEA(2250) | EL(2800) | DAA(550) |
| Example 3-35 | R-35 | P-35(80) | — | — | PGMEA(2250) | EL(2800) | DAA(550) |
| Example 3-36 | R-36 | P-36(80) | — | — | PGMEA(2250) | EL(2800) | DAA(550) |
| Example 3-37 | R-37 | P-37(80) | — | — | PGMEA(2250) | EL(2800) | DAA(550) |
| Example 3-38 | R-38 | P-38(80) | — | — | PGMEA(2250) | EL(2800) | DAA(550) |
| Example 3-39 | R-39 | P-39(80) | — | — | PGMEA(2250) | EL(2800) | DAA(550) |
| Example 3-40 | R-40 | P-40(80) | — | — | PGMEA(2250) | EL(2800) | DAA(550) |
| Example 3-41 | R-41 | P-41(80) | — | — | PGMEA(2250) | EL(2800) | DAA(550) |
| Example 3-42 | R-42 | P-42(80) | — | — | PGMEA(2250) | EL(2800) | DAA(550) |
| Example 3-43 | R-43 | P-43(80) | — | PAG-2(10) | PGMEA(2250) | EL(2800) | DAA(550) |
| Example 3-44 | R-44 | P-44(80) | — | PAG-1(10) | PGMEA(2250) | EL(2800) | DAA(550) |
| Example 3-45 | R-45 | P-45(80) | — | PAG-1(10) | PGMEA(2250) | EL(2800) | DAA(550) |
| Example 3-46 | R-46 | P-46(80) | — | PAG-1(10) | PGMEA(2250) | EL(2800) | DAA(550) |
| Example 3-47 | R-47 | P-47(80) | — | PAG-2(10) | PGMEA(2250) | EL(2800) | DAA(550) |
| Example 3-48 | R-48 | P-48(80) | — | PAG-1(10) | PGMEA(2250) | EL(2800) | DAA(550) |
| Example 3-49 | R-49 | P-49(80) | — | PAG-2(10) | PGMEA(2250) | EL(2800) | DAA(550) |
| Example 3-50 | R-50 | P-50(80) | — | PAG-1(10) | PGMEA(2250) | EL(2800) | DAA(550) |
| Example 3-51 | R-51 | P-1(80) | SQ-1(4) | — | PGMEA(2250) | EL(2800) | DAA(550) |
| Example 3-52 | R-52 | P-1(80) | AQ-1(4) | — | PGMEA(2250) | EL(2800) | DAA(550) |
| Example 3-53 | R-53 | P-1(80) | SQ-1(2) | — | PGMEA(2250) | EL(2800) | DAA(550) |
| | | | AQ-1(2) | | | | |

TABLE 6

| | | Base | | Acid | | | |
|---|---|---|---|---|---|---|---|
| | | polymer | Quencher | generator | Solvent 1 | Solvent 2 | Solvent 3 |
| | Resist | (Parts | (Parts | (Parts | (Parts | (Parts | (Parts |
| | composition | by mass) | by mass) | by mass) | by mass) | by mass) | by mass) |
| Comparative | CR-1 | CP-1(80) | — | — | PGMEA(2250) | EL(2800) | DAA(550) |
| Example 3-1 | | | | | | | |
| Comparative | CR-2 | CP-2(80) | — | — | PGMEA(2250) | EL(2800) | DAA(550) |
| Example 3-2 | | | | | | | |
| Comparative | CR-3 | CP-3(80) | — | — | PGMEA(2250) | EL(2800) | DAA(550) |
| Example 3-3 | | | | | | | |
| Comparative | CR-4 | CP-4(80) | — | — | PGMEA(2250) | EL(2800) | DAA(550) |
| Example 3-4 | | | | | | | |
| Comparative | CR-5 | CP-5(80) | — | — | PGMEA(2250) | EL(2800) | DAA(550) |
| Example 3-5 | | | | | | | |
| Comparative | CR-6 | CP-6(80) | — | — | PGMEA(2250) | EL(2800) | DAA(550) |
| Example 3-6 | | | | | | | |
| Comparative | CR-7 | CP-7(80) | — | — | PGMEA(2250) | EL(2800) | DAA(550) |
| Example 3-7 | | | | | | | |
| Comparative | CR-8 | CP-8(80) | — | — | PGMEA(2250) | EL(2800) | DAA(550) |
| Example 3-8 | | | | | | | |
| Comparative | CR-9 | CP-9(80) | — | — | PGMEA(2250) | EL(2800) | DAA(550) |
| Example 3-9 | | | | | | | |
| Comparative | CR-10 | CP-10(80) | — | — | PGMEA(2250) | EL(2800) | DAA(550) |
| Example 3-10 | | | | | | | |
| Comparative | CR-11 | CP-11(80) | — | — | PGMEA(2250) | EL(2800) | DAA(550) |
| Example 3-11 | | | | | | | |
| Comparative | CR-12 | CP-12(80) | — | — | PGMEA(2250) | EL(2800) | DAA(550) |
| Example 3-12 | | | | | | | |
| Comparative | CR-13 | CP-13(80) | — | — | PGMEA(2250) | EL(2800) | DAA(550) |
| Example 3-13 | | | | | | | |
| Comparative | CR-14 | CP-14(80) | — | — | PGMEA(2250) | EL(2800) | DAA(550) |
| Example 3-14 | | | | | | | |
| Comparative | CR-15 | CP-15(80) | — | — | PGMEA(2250) | EL(2800) | DAA(550) |
| Example 3-15 | | | | | | | |
| Comparative | CR-16 | CP-16(80) | — | — | PGMEA(2250) | EL(2800) | DAA(550) |
| Example 3-16 | | | | | | | |
| Comparative | CR-17 | CP-17(80) | — | — | PGMEA(2250) | EL(2800) | DAA(550) |
| Example 3-17 | | | | | | | |
| Comparative | CR-18 | CP-18(80) | — | — | PGMEA(2250) | EL(2800) | DAA(550) |
| Example 3-18 | | | | | | | |
| Comparative | CR-19 | CP-19(80) | — | — | PGMEA(2250) | EL(2800) | DAA(550) |
| Example 3-19 | | | | | | | |
| Comparative | CR-20 | CP-20(80) | — | — | PGMEA(2250) | EL(2800) | DAA(550) |
| Example 3-20 | | | | | | | |
| Comparative | CR-21 | CP-21(80) | — | — | PGMEA(2250) | EL(2800) | DAA(550) |
| Example 3-21 | | | | | | | |
| Comparative | CR-22 | CP-22(80) | — | — | PGMEA(2250) | EL(2800) | DAA(550) |
| Example 3-22 | | | | | | | |
| Comparative | CR-23 | CP-23(80) | — | PAG-1(10) | PGMEA(2250) | EL(2800) | DAA(550) |
| Example 3-23 | | | | | | | |
| Comparative | CR-24 | CP-24(80) | — | — | PGMEA(2250) | EL(2800) | DAA(550) |
| Example 3-24 | | | | | | | |
| Comparative | CR-25 | CP-25(80) | — | — | PGMEA(2250) | EL(2800) | DAA(550) |
| Example 3-25 | | | | | | | |
| Comparative | CR-26 | CP-26(80) | — | — | PGMEA(2250) | EL(2800) | DAA(550) |
| Example 3-26 | | | | | | | |
| Comparative | CR-27 | CP-27(80) | — | — | PGMEA(2250) | EL(2800) | DAA(550) |
| Example 3-27 | | | | | | | |
| Comparative | CR-28 | CP-28(80) | — | — | PGMEA(2250) | EL(2800) | DAA(550) |
| Example 3-28 | | | | | | | |
| Comparative | CR-29 | CP-29(80) | — | — | PGMEA(2250) | EL(2800) | DAA(550) |
| Example 3-29 | | | | | | | |
| Comparative | CR-30 | CP-30(80) | — | — | PGMEA(2250) | EL(2800) | DAA(550) |
| Example 3-30 | | | | | | | |
| Comparative | CR-31 | CP-31(80) | — | — | PGMEA(2250) | EL(2800) | DAA(550) |
| Example 3-31 | | | | | | | |
| Comparative | CR-32 | CP-32(80) | — | PAG-2(10) | PGMEA(2250) | EL(2800) | DAA(550) |
| Example 3-32 | | | | | | | |
| Comparative | CR-33 | CP-33(80) | — | PAG-1(20) | PGMEA(2250) | EL(2800) | DAA(550) |
| Example 3-33 | | | | | | | |
| Comparative | CR-34 | CP-34(80) | — | PAG-1(20) | PGMEA(2250) | EL(2800) | DAA(550) |
| Example 3-34 | | | | | | | |
| Comparative | CR-35 | CP-35(80) | — | PAG-2(20) | PGMEA(2250) | EL(2800) | DAA(550) |
| Example 3-35 | | | | | | | |
| Comparative | CR-36 | CP-36(80) | — | PAG-1(20) | PGMEA(2250) | EL(2800) | DAA(550) |
| Example 3-36 | | | | | | | |
| Comparative | CR-37 | CP-37(80) | SQ-1(8) | — | PGMEA(2250) | EL(2800) | DAA(550) |
| Example 3-37 | | | | | | | |
| Comparative | CR-38 | CP-38(80) | SQ-1(8) | PAG-1(20) | PGMEA(2250) | EL(2800) | DAA(550) |
| Example 3-38 | | | | | | | |
| Comparative | CR-39 | CP-38(80) | AQ-1(8) | PAG-1(20) | PGMEA(2250) | EL(2800) | DAA(550) |
| Example 3-39 | | | | | | | |
| Comparative | CR-40 | CP-38(80) | SQ-1(4) | PAG-1(20) | PGMEA(2250) | EL(2800) | DAA(550) |
| Example 3-40 | | | AQ-1(4) | | | | |

In Tables 4 to 6, the solvents, quenchers (SQ-1, AQ-1) and acid generators (PAG-1, PAG-2) are as follows.

### Solvent: PGM4EA (Propylene Glycol Monomethyl Ether Acetate)

EL (Ethyl acetate)
DAA (Diacetone alcohol)

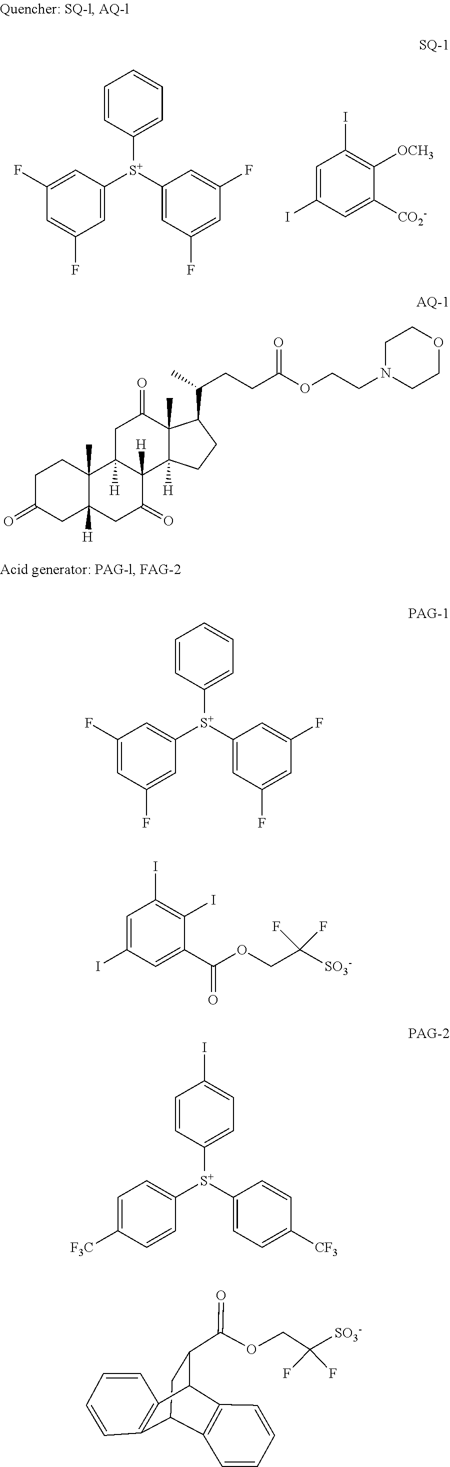

### [4] EUV Lithography Evaluation (1)

### Examples 4-1 to 4-53, Comparative Examples 4-1 to 4-40

Each chemically amplified resist composition (R-1 to R-53, CR-1 to CR-40) shown in Tables 4 to 6 was spin-coated onto a Si substrate on which a silicon-containing spin-on hard mask SHB-A940 (silicon content 43% by mass) manufactured by Shin-Etsu Chemical Co., Ltd. was formed to a thickness of 20 nm, and the substrate was pre-baked at 100° C. for 60 seconds using a hot plate to prepare a resist film with a thickness of 50 nm. This was exposed to an LS pattern with a wafer dimension of 18 nm and a pitch of 36 nm using an EUV scanner NXE3300 (NA 0.33, σ 0.9/0.6, dipole illumination) manufactured by ASML, while varying the exposure dose and focus (exposure dose pitch: 1 mJ/cm², focus pitch: 0.020 μm), and after exposure, PEB was performed for 60 seconds at the temperatures shown in Tables 7 to 9. Thereafter, paddle development was performed with a 2.38% by mass aqueous solution of TMAH for 30 seconds, followed by rinsing with a surfactant-containing rinsing material and spin drying to obtain a positive pattern.

The obtained LS pattern was observed with a critical dimension SEM (CG6300) manufactured by Hitachi High-Technologies Corporation, and the sensitivity, EL, LWR, DOF, and collapse limit were evaluated according to the following methods. In addition, the development defects of the obtained LS patterns were evaluated. The results are shown in Tables 7 to 9.

### [Sensitivity Evaluation]

The optimal exposure dose Eop (mJ/cm²) at which an LS pattern with a line width of 18 nm and a pitch of 36 nm was obtained, and was used as the sensitivity. The smaller this value, the higher the sensitivity.

### [EL Evaluation]

EL (unit: %) was determined from the exposure amount formed within the range of ±10% (16.2 to 19.8 nm) of the 18 nm space width in the LS pattern using the following formula. The larger this value, the better the performance.

$$EL ( \% ) = ( \vert {E}_{1} - {E}_{2} \vert / Eop ) \times 100$$

E₁: Optimal exposure amount to give an LS pattern with a line width of 16.2 nm and a pitch of 36 nm
E₂: Optimal exposure amount to give an LS pattern with a line width of 19.8 nm and a pitch of 36 nm
Eop: Optimal exposure amount to give an LS pattern with a line width of 18 nm and a pitch of 36 nm

### [LWR Evaluation]

The dimensions of the LS pattern obtained by irradiation with Eop were measured at 10 locations in the longitudinal direction of the line, and from the results, the standard deviation (a) was calculated, and triple that value (3σ) was used as the LWR. The smaller this value is, the less roughness and more uniform line width the pattern that can be obtained has.

### [DOF Evaluation]

The depth of focus was evaluated by determining the focus range formed within a range of ±10% (16.2 to 19.8 nm) of the 18 nm dimension of the LS pattern. The larger this value, the wider the depth of focus.

### [Line Pattern Collapse Limit Evaluation]

The line dimension of the LS pattern at each exposure dose at the optimal focus was measured at 10 points in the longitudinal direction. The thinnest line dimension obtained without collapse was used as the collapse limit dimension. The smaller this value, the better the collapse limit.

### [Development Defect Evaluation]

The LS pattern with a line width of 18 nm and a pitch of 36 nm formed with the optimal exposure dose was inspected using a defect inspection device KLA2360 (product name) manufactured by KLA Tencor Corporation. The pixel size of the defect inspection device was set to 0.16 μm and the threshold value was set to 20. The number of defects (number/cm²) extracted from the difference caused by overlaying the comparison image on a pixel-by-pixel basis was counted, and the count number of defects per unit area (number/cm²) was calculated. Thereafter, a defect review was performed to classify and extract development defects from all defects, and the number of development defects per unit area (number/cm²) was calculated. Values less than 0.5 were rated A, values 0.5 or larger and less than 1.0 were rated B, values 1.0 or larger and less than 5.0 were rated C, and values 5.0 or larger were rated D. The smaller the value, the better the performance.

TABLE 7

| | | | Optimal | | | | | |
|---|---|---|---|---|---|---|---|---|
| | | PEB | exposure | | | | Collapse | |
| | Resist | temperature | dose | EL | LWR | DOF | limit | Development |
| | composition | (° C.) | (mJ/cm²) | (%) | (nm) | (nm) | (nm) | defect |
| Example 4-1 | R-1 | 95 | 33 | 18 | 2.2 | 120 | 10.9 | A |
| Example 4-2 | R-2 | 100 | 34 | 19 | 2.3 | 110 | 10.8 | A |
| Example 4-3 | R-3 | 100 | 34 | 17 | 2.4 | 120 | 10.9 | A |
| Example 4-4 | R-4 | 95 | 33 | 18 | 2.5 | 110 | 11.1 | A |
| Example 4-5 | R-5 | 105 | 35 | 18 | 2.3 | 100 | 11.2 | A |
| Example 4-6 | R-6 | 100 | 34 | 17 | 2.3 | 120 | 10.9 | A |
| Example 4-7 | R-7 | 95 | 35 | 19 | 2.3 | 110 | 11.0 | A |
| Example 4-8 | R-8 | 95 | 33 | 17 | 2.2 | 100 | 11.1 | A |
| Example 4-9 | R-9 | 100 | 33 | 17 | 2.4 | 110 | 11.2 | A |
| Example 4-10 | R-10 | 100 | 33 | 18 | 2.3 | 120 | 11.4 | A |
| Example 4-11 | R-11 | 100 | 34 | 16 | 2.4 | 120 | 10.9 | A |
| Example 4-12 | R-12 | 95 | 34 | 18 | 2.5 | 110 | 11.3 | A |
| Example 4-13 | R-13 | 105 | 35 | 17 | 2.5 | 120 | 11.3 | A |
| Example 4-14 | R-14 | 100 | 33 | 18 | 2.3 | 100 | 11.2 | A |
| Example 4-15 | R-15 | 95 | 34 | 17 | 2.4 | 110 | 11.1 | A |
| Example 4-16 | R-16 | 95 | 34 | 19 | 2.3 | 120 | 10.9 | A |
| Example 4-17 | R-17 | 100 | 34 | 17 | 2.2 | 100 | 10.7 | A |
| Example 4-18 | R-18 | 95 | 35 | 16 | 2.3 | 110 | 11.1 | A |
| Example 4-19 | R-19 | 95 | 33 | 18 | 2.4 | 120 | 11.2 | A |
| Example 4-20 | R-20 | 100 | 33 | 17 | 2.4 | 110 | 11.3 | A |
| Example 4-21 | R-21 | 100 | 34 | 17 | 2.3 | 110 | 11.1 | A |
| Example 4-22 | R-22 | 95 | 34 | 16 | 2.4 | 110 | 11.2 | A |
| Example 4-23 | R-23 | 100 | 35 | 18 | 2.3 | 100 | 11.3 | A |
| Example 4-24 | R-24 | 95 | 33 | 17 | 2.5 | 110 | 11.1 | A |
| Example 4-25 | R-25 | 100 | 35 | 19 | 2.4 | 120 | 11.2 | A |
| Example 4-26 | R-26 | 100 | 33 | 17 | 2.4 | 110 | 10.8 | A |
| Example 4-27 | R-27 | 95 | 34 | 19 | 2.5 | 110 | 11.0 | A |
| Example 4-28 | R-28 | 100 | 34 | 18 | 2.3 | 110 | 11.2 | A |
| Example 4-29 | R-29 | 100 | 34 | 16 | 2.4 | 110 | 11.1 | A |
| Example 4-30 | R-30 | 95 | 33 | 17 | 2.5 | 110 | 11.2 | A |

TABLE 8

| | | | Optimal | | | | | |
|---|---|---|---|---|---|---|---|---|
| | | PEB | exposure | | | | Collapse | |
| | Resist | temperature | dose | EL | LWR | DOF | limit | Development |
| | composition | (° C.) | (mJ/cm²) | (%) | (nm) | (nm) | (nm) | defect |
| Example 4-31 | R-31 | 100 | 33 | 19 | 2.4 | 110 | 11.0 | A |
| Example 4-32 | R-32 | 100 | 34 | 17 | 2.4 | 100 | 11.1 | A |
| Example 4-33 | R-33 | 100 | 34 | 18 | 2.4 | 110 | 10.8 | A |
| Example 4-34 | R-34 | 95 | 35 | 17 | 2.3 | 120 | 11.2 | A |
| Example 4-35 | R-35 | 100 | 33 | 16 | 2.5 | 110 | 11.0 | A |
| Example 4-36 | R-36 | 95 | 33 | 19 | 2.4 | 110 | 11.2 | A |
| Example 4-37 | R-37 | 100 | 33 | 18 | 2.5 | 120 | 11.1 | A |
| Example 4-38 | R-38 | 100 | 33 | 18 | 2.3 | 110 | 11.4 | A |
| Example 4-39 | R-39 | 95 | 34 | 17 | 2.4 | 100 | 11.0 | A |
| Example 4-40 | R-40 | 100 | 34 | 16 | 2.4 | 110 | 11.1 | A |
| Example 4-41 | R-41 | 95 | 35 | 18 | 2.3 | 110 | 11.2 | A |
| Example 4-42 | R-42 | 95 | 34 | 17 | 2.4 | 120 | 11.0 | A |
| Example 4-43 | R-43 | 100 | 33 | 19 | 2.5 | 110 | 10.9 | A |
| Example 4-44 | R-44 | 100 | 34 | 17 | 2.3 | 100 | 11.3 | A |
| Example 4-45 | R-45 | 95 | 33 | 18 | 2.4 | 120 | 11.1 | A |
| Example 4-46 | R-46 | 95 | 34 | 17 | 2.5 | 110 | 11.2 | A |
| Example 4-47 | R-47 | 100 | 33 | 17 | 2.5 | 110 | 10.8 | A |
| Example 4-48 | R-48 | 95 | 34 | 18 | 2.6 | 120 | 11.0 | A |
| Example 4-49 | R-49 | 95 | 35 | 18 | 2.4 | 110 | 10.7 | A |
| Example 4-50 | R-50 | 100 | 34 | 18 | 2.5 | 110 | 11.1 | A |
| Example 4-51 | R-51 | 95 | 33 | 17 | 2.4 | 120 | 11.3 | A |
| Example 4-52 | R-52 | 95 | 34 | 16 | 2.5 | 110 | 11.1 | A |
| Example 4-53 | R-53 | 100 | 33 | 18 | 2.3 | 110 | 11.0 | A |

TABLE 9

| | | | Optimal | | | | | |
|---|---|---|---|---|---|---|---|---|
| | | PEB | exposure | | | | Collapse | |
| | Resist | temperature | dose | EL | LWR | DOF | limit | Development |
| | composition | (° C.) | (mJ/cm²) | (%) | (nm) | (nm) | (nm) | defect |
| Comparative | CR-1 | 100 | 37 | 13 | 3 | 90 | 12.3 | B |
| Example 4-1 | | | | | | | | |
| Comparative | CR-2 | 95 | 38 | 12 | 3.2 | 90 | 12.2 | C |
| Example 4-2 | | | | | | | | |
| Comparative | CR-3 | 100 | 37 | 14 | 3.1 | 80 | 12.3 | B |
| Example 4-3 | | | | | | | | |
| Comparative | CR-4 | 105 | 37 | 14 | 3 | 90 | 12.5 | C |
| Example 4-4 | | | | | | | | |
| Comparative | CR-5 | 100 | 37 | 14 | 3.2 | 80 | 12.1 | B |
| Example 4-5 | | | | | | | | |
| Comparative | CR-6 | 95 | 40 | 12 | 2.8 | 90 | 12.5 | C |
| Example 4-6 | | | | | | | | |
| Comparative | CR-7 | 100 | 39 | 12 | 3.1 | 90 | 13.1 | B |
| Example 4-7 | | | | | | | | |
| Comparative | CR-8 | 105 | 38 | 14 | 3.2 | 90 | 12.8 | C |
| Example 4-8 | | | | | | | | |
| Comparative | CR-9 | 95 | 40 | 14 | 3.2 | 80 | 13.1 | B |
| Example 4-9 | | | | | | | | |
| Comparative | CR-10 | 100 | 39 | 12 | 3 | 90 | 13.3 | C |
| Example 4-10 | | | | | | | | |
| Comparative | CR-11 | 95 | 38 | 13 | 3.2 | 90 | 12.7 | B |
| Example 4-11 | | | | | | | | |
| Comparative | CR-12 | 100 | 37 | 14 | 3.1 | 90 | 12.6 | B |
| Example 4-12 | | | | | | | | |
| Comparative | CR-13 | 100 | 40 | 12 | 3.2 | 90 | 13.0 | C |
| Example 4-13 | | | | | | | | |
| Comparative | CR-14 | 95 | 38 | 13 | 3.2 | 90 | 12.3 | B |
| Example 4-14 | | | | | | | | |
| Comparative | CR-15 | 105 | 41 | 12 | 3.1 | 90 | 12.7 | C |
| Example 4-15 | | | | | | | | |
| Comparative | CR-16 | 100 | 38 | 12 | 2.8 | 90 | 12.4 | C |
| Example 4-16 | | | | | | | | |
| Comparative | CR-17 | 100 | 37 | 11 | 3.1 | 80 | 13.1 | B |
| Example 4-17 | | | | | | | | |
| Comparative | CR-18 | 95 | 37 | 13 | 2.9 | 80 | 13.3 | C |
| Example 4-18 | | | | | | | | |
| Comparative | CR-19 | 100 | 38 | 12 | 3.1 | 90 | 12.5 | B |
| Example 4-19 | | | | | | | | |
| Comparative | CR-20 | 95 | 37 | 14 | 3 | 80 | 13.4 | C |
| Example 4-20 | | | | | | | | |
| Comparative | CR-21 | 100 | 41 | 13 | 2.9 | 90 | 12.2 | B |
| Example 4-21 | | | | | | | | |
| Comparative | CR-22 | 100 | 39 | 15 | 3 | 90 | 13.1 | C |
| Example 4-22 | | | | | | | | |
| Comparative | CR-23 | 100 | 39 | 13 | 3.2 | 80 | 12.8 | C |
| Example 4-23 | | | | | | | | |
| Comparative | CR-24 | 95 | 41 | 15 | 3.3 | 90 | 12.6 | C |
| Example 4-24 | | | | | | | | |
| Comparative | CR-25 | 100 | 38 | 12 | 3.1 | 90 | 12.6 | B |
| Example 4-25 | | | | | | | | |
| Comparative | CR-26 | 105 | 38 | 14 | 2.8 | 80 | 13.3 | C |
| Example 4-26 | | | | | | | | |
| Comparative | CR-27 | 100 | 38 | 13 | 3.1 | 90 | 12.6 | B |
| Example 4-27 | | | | | | | | |
| Comparative | CR-28 | 95 | 39 | 15 | 3.3 | 90 | 12.6 | C |
| Example 4-28 | | | | | | | | |
| Comparative | CR-29 | 100 | 40 | 14 | 3.2 | 90 | 12.6 | C |
| Example 4-29 | | | | | | | | |
| Comparative | CR-30 | 95 | 39 | 13 | 3.1 | 90 | 12.3 | B |
| Example 4-30 | | | | | | | | |
| Comparative | CR-31 | 100 | 39 | 12 | 2.8 | 90 | 12.4 | C |
| Example 4-31 | | | | | | | | |
| Comparative | CR-32 | 95 | 41 | 13 | 3.3 | 80 | 13.5 | C |
| Example 4-32 | | | | | | | | |
| Comparative | CR-33 | 95 | 39 | 14 | 3.5 | 90 | 12.7 | C |
| Example 4-33 | | | | | | | | |
| Comparative | CR-34 | 100 | 38 | 13 | 3.2 | 80 | 13.1 | B |
| Example 4-34 | | | | | | | | |
| Comparative | CR-35 | 100 | 38 | 15 | 3.4 | 90 | 12.6 | C |
| Example 4-35 | | | | | | | | |
| Comparative | CR-36 | 105 | 37 | 13 | 2.8 | 70 | 13.3 | C |
| Example 4-36 | | | | | | | | |
| Comparative | CR-37 | 95 | 37 | 14 | 3.6 | 70 | 13.4 | B |
| Example 4-37 | | | | | | | | |
| Comparative | CR-38 | 100 | 40 | 13 | 2.8 | 70 | 13.2 | C |
| Example 4-38 | | | | | | | | |
| Comparative | CR-39 | 95 | 37 | 13 | 3.5 | 70 | 13.2 | C |
| Example 4-39 | | | | | | | | |
| Comparative | CR-40 | 100 | 37 | 14 | 3.6 | 70 | 14.0 | B |
| Example 4-40 | | | | | | | | |

The results shown in Tables 7 to 9 indicate that the chemically amplified resist composition using a base polymer containing repeating unit derived from an onium salt monomer of the present invention has good sensitivity and excellent EL, LWR, and DOF. In addition, it was confirmed that the collapse limit value is small and that the composition is resistant to pattern collapse even in fine pattern formation. Furthermore, it was confirmed that development defects are also suppressed. Therefore, it was demonstrated that the chemically amplified resist composition of the present invention is suitable as a material for EUV lithography.

### [5] EUV Lithography Evaluation (2)

### Examples 5-1 to 5-53, Comparative Examples 5-1 to 5-40

Each chemically amplified resist composition (R-1 to R-53, CR-1 to CR-40) shown in Tables 4 to 6 was spin-coated onto a Si substrate formed with a silicon-containing spin-on hard mask SHB-A940 (silicon content of 43% by mass) manufactured by Shin-Etsu Chemical Co., Ltd. with a film thickness of 20 nm, and the substrate was pre-baked at 105° C. for 60 seconds using a hot plate to prepare a resist film with a film thickness of 50 nm. This was exposed using an ASML EUV scanner NXE3400 (NA 0.33, σ 0.9/0.6, quadruple pole illumination, a hole pattern mask with a pitch of 46 nm on the wafer and a +20% bias), PEB was performed for 60 seconds at the temperatures listed in Tables 10 to 12 using a hot plate, and development was performed for 30 seconds with a 2.38% by mass TMAH aqueous solution to form a hole pattern with a dimension of 23 nm.

Using a critical dimension SEM (CG6300) manufactured by Hitachi High-Technologies Corporation, the amount of exposure when a hole dimension of 23 nm was formed was measured and used as the sensitivity, the dimensions of 50 holes were also measured, and the standard deviation (σ) calculated from the results was tripled (3σ) and used as the dimensional variation (CDU). The results are shown in Tables 10 to 12.

TABLE 10

| | | | Optimal | |
|---|---|---|---|---|
| | | PEB | exposure | |
| | Resist | temperature | dose | CDU |
| | composition | (° C.) | (mJ/cm²) | (nm) |
| Example 5-1 | R-1 | 95 | 23 | 2.3 |
| Example 5-2 | R-2 | 95 | 23 | 2.4 |
| Example 5-3 | R-3 | 90 | 22 | 2.3 |
| Example 5-4 | R-4 | 90 | 23 | 2.5 |
| Example 5-5 | R-5 | 90 | 24 | 2.3 |
| Example 5-6 | R-6 | 95 | 23 | 2.4 |
| Example 5-7 | R-7 | 95 | 24 | 2.2 |
| Example 5-8 | R-8 | 90 | 24 | 2.4 |
| Example 5-9 | R-9 | 95 | 23 | 2.4 |
| Example 5-10 | R-10 | 95 | 24 | 2.5 |
| Example 5-11 | R-11 | 95 | 23 | 2.3 |
| Example 5-12 | R-12 | 90 | 25 | 2.4 |
| Example 5-13 | R-13 | 90 | 24 | 2.3 |
| Example 5-14 | R-14 | 90 | 25 | 2.4 |
| Example 5-15 | R-15 | 90 | 23 | 2.4 |
| Example 5-16 | R-16 | 85 | 24 | 2.4 |
| Example 5-17 | R-17 | 95 | 22 | 2.3 |
| Example 5-18 | R-18 | 95 | 22 | 2.3 |
| Example 5-19 | R-19 | 90 | 24 | 2.3 |
| Example 5-20 | R-20 | 95 | 24 | 2.5 |
| Example 5-21 | R-21 | 95 | 23 | 2.4 |
| Example 5-22 | R-22 | 95 | 24 | 2.5 |
| Example 5-23 | R-23 | 95 | 25 | 2.3 |
| Example 5-24 | R-24 | 95 | 23 | 2.4 |
| Example 5-25 | R-25 | 95 | 22 | 2.4 |
| Example 5-26 | R-26 | 95 | 24 | 2.5 |
| Example 5-27 | R-27 | 95 | 23 | 2.3 |
| Example 5-28 | R-28 | 95 | 23 | 2.3 |
| Example 5-29 | R-29 | 90 | 24 | 2.4 |
| Example 5-30 | R-30 | 95 | 23 | 2.3 |

TABLE 11

| | | | Optimal | |
|---|---|---|---|---|
| | | PEB | exposure | |
| | Resist | temperature | dose | CDU |
| | composition | (° C.) | (mJ/cm²) | (nm) |
| Example 5-31 | R-31 | 95 | 25 | 2.3 |
| Example 5-32 | R-32 | 95 | 23 | 2.4 |
| Example 5-33 | R-33 | 95 | 23 | 2.2 |
| Example 5-34 | R-34 | 90 | 23 | 2.3 |
| Example 5-35 | R-35 | 95 | 24 | 2.5 |
| Example 5-36 | R-36 | 95 | 23 | 2.3 |
| Example 5-37 | R-37 | 90 | 23 | 2.4 |
| Example 5-38 | R-38 | 90 | 25 | 2.3 |
| Example 5-39 | R-39 | 95 | 24 | 2.4 |
| Example 5-40 | R-40 | 95 | 22 | 2.2 |
| Example 5-41 | R-41 | 95 | 23 | 2.3 |
| Example 5-42 | R-42 | 90 | 24 | 2.3 |
| Example 5-43 | R-43 | 95 | 24 | 2.5 |
| Example 5-44 | R-44 | 95 | 24 | 2.5 |
| Example 5-45 | R-45 | 90 | 23 | 2.3 |
| Example 5-46 | R-46 | 95 | 24 | 2.4 |
| Example 5-47 | R-47 | 90 | 24 | 2.3 |
| Example 5-48 | R-48 | 90 | 24 | 2.4 |
| Example 5-49 | R-49 | 95 | 23 | 2.3 |
| Example 5-50 | R-50 | 90 | 24 | 2.4 |
| Example 5-51 | R-51 | 95 | 24 | 2.3 |
| Example 5-52 | R-52 | 95 | 23 | 2.5 |
| Example 5-53 | R-53 | 95 | 24 | 2.3 |

TABLE 12

| | | | Optimal | |
|---|---|---|---|---|
| | | PEB | exposure | |
| | Resist | temperature | dose | CDU |
| | composition | (° C.) | (mJ/cm²) | (nm) |
| Comparative | CR-1 | 95 | 30 | 2.8 |
| Example 5-1 | | | | |
| Comparative | CR-2 | 90 | 29 | 2.9 |
| Example 5-2 | | | | |
| Comparative | CR-3 | 90 | 27 | 2.9 |
| Example 5-3 | | | | |
| Comparative | CR-4 | 95 | 28 | 2.8 |
| Example 5-4 | | | | |
| Comparative | CR-5 | 90 | 29 | 2.9 |
| Example 5-5 | | | | |
| Comparative | CR-6 | 95 | 28 | 2.7 |
| Example 5-6 | | | | |
| Comparative | CR-7 | 95 | 27 | 2.8 |
| Example 5-7 | | | | |
| Comparative | CR-8 | 95 | 28 | 2.9 |
| Example 5-8 | | | | |
| Comparative | CR-9 | 90 | 28 | 2.8 |
| Example 5-9 | | | | |
| Comparative | CR-10 | 95 | 29 | 2.7 |
| Example 5-10 | | | | |
| Comparative | CR-11 | 95 | 29 | 2.9 |
| Example 5-11 | | | | |
| Comparative | CR-12 | 90 | 29 | 2.8 |
| Example 5-12 | | | | |
| Comparative | CR-13 | 90 | 27 | 2.8 |
| Example 5-13 | | | | |
| Comparative | CR-14 | 90 | 29 | 2.9 |
| Example 5-14 | | | | |
| Comparative | CR-15 | 95 | 28 | 3.1 |
| Example 5-15 | | | | |
| Comparative | CR-16 | 85 | 30 | 2.8 |
| Example 5-16 | | | | |
| Comparative | CR-17 | 95 | 29 | 2.8 |
| Example 5-17 | | | | |
| Comparative | CR-18 | 95 | 27 | 2.7 |
| Example 5-18 | | | | |
| Comparative | CR-19 | 90 | 29 | 2.8 |
| Example 5-19 | | | | |
| Comparative | CR-20 | 95 | 28 | 2.9 |
| Example 5-20 | | | | |
| Comparative | CR-21 | 95 | 27 | 2.8 |
| Example 5-21 | | | | |
| Comparative | CR-22 | 95 | 29 | 2.8 |
| Example 5-22 | | | | |
| Comparative | CR-23 | 95 | 27 | 2.9 |
| Example 5-23 | | | | |
| Comparative | CR-24 | 95 | 28 | 2.8 |
| Example 5-24 | | | | |
| Comparative | CR-25 | 95 | 27 | 2.8 |
| Example 5-25 | | | | |
| Comparative | CR-26 | 95 | 27 | 2.8 |
| Example 5-26 | | | | |
| Comparative | CR-27 | 95 | 27 | 2.8 |
| Example 5-27 | | | | |
| Comparative | CR-28 | 95 | 28 | 2.9 |
| Example 5-28 | | | | |
| Comparative | CR-29 | 90 | 29 | 2.8 |
| Example 5-29 | | | | |
| Comparative | CR-30 | 90 | 27 | 2.8 |
| Example 5-30 | | | | |
| Comparative | CR-31 | 95 | 28 | 2.7 |
| Example 5-31 | | | | |
| Comparative | CR-32 | 90 | 30 | 2.8 |
| Example 5-32 | | | | |
| Comparative | CR-33 | 95 | 28 | 2.9 |
| Example 5-33 | | | | |
| Comparative | CR-34 | 95 | 29 | 2.7 |
| Example 5-34 | | | | |
| Comparative | CR-35 | 95 | 28 | 2.9 |
| Example 5-35 | | | | |
| Comparative | CR-36 | 95 | 28 | 2.8 |
| Example 5-36 | | | | |
| Comparative | CR-37 | 90 | 31 | 3.1 |
| Example 5-37 | | | | |
| Comparative | CR-38 | 90 | 31 | 3.2 |
| Example 5-38 | | | | |
| Comparative | CR-39 | 90 | 31 | 3.2 |
| Example 5-39 | | | | |
| Comparative | CR-40 | 90 | 32 | 3.2 |
| Example 5-40 | | | | |

From the results shown in Tables 10 to 12, it was confirmed that the chemically amplified resist composition of the present invention had good sensitivity and excellent CDU.

### [6] Dry Etching Resistance Evaluation

### Examples 6-1 to 6-50, Comparative Examples 6-1 to 6-38

2 g each of the polymers shown in Tables 1 to 3 (polymers P-1 to P-50, comparative polymers CP-1 to CP-38) were dissolved in 10 g of cyclohexanone and filtered through a 0.2 μm size filter, then obtained polymer solutions. By using the polymer solution, a film was formed on a Si substrate by spin coating to a thickness of 300 nm, and evaluated under the following conditions.

Etching test with CHF₃/CF₄-based gas:

Using a dry etching apparatus TE-8500P manufactured by Tokyo Electron Ltd., the difference in film thickness of the polymer film before and after etching was determined.

The etching conditions are as follows.

| | | |
|---|---|---|
| Chamber pressure | 40 | Pa |
| RF power | 1000 | W |
| Gap | 9 | mm |
| CHF₃ gas flow rate | 30 | mL/min |
| CF₄ gas flow rate | 30 | mL/min |
| Ar gas flow rate | 100 | mL/min |
| Time | 60 | sec |

This evaluation shows that a film with a small difference in film thickness, that is, a film with a small reduction in thickness, has high etching resistance.

The results of dry etching resistance are shown in Tables 13 to 15.

TABLE 13

| | | CHF₃/CF₄-based gas |
|---|---|---|
| | Polymer | etching speed (nm/min) |
| Example 6-1 | P-1 | 94 |
| Example 6-2 | P-2 | 95 |
| Example 6-3 | P-3 | 96 |
| Example 6-4 | P-4 | 94 |
| Example 6-5 | P-5 | 95 |
| Example 6-6 | P-6 | 96 |
| Example 6-7 | P-7 | 96 |
| Example 6-8 | P-8 | 94 |
| Example 6-9 | P-9 | 95 |
| Example 6-10 | P-10 | 94 |
| Example 6-11 | P-11 | 95 |
| Example 6-12 | P-12 | 96 |
| Example 6-13 | P-13 | 96 |
| Example 6-14 | P-14 | 96 |
| Example 6-15 | P-15 | 94 |
| Example 6-16 | P-16 | 96 |
| Example 6-17 | P-17 | 96 |
| Example 6-18 | P-18 | 95 |
| Example 6-19 | P-19 | 94 |
| Example 6-20 | P-20 | 95 |
| Example 6-21 | P-21 | 94 |
| Example 6-22 | P-22 | 94 |
| Example 6-23 | P-23 | 96 |
| Example 6-24 | P-24 | 97 |
| Example 6-25 | P-25 | 94 |
| Example 6-26 | P-26 | 94 |
| Example 6-27 | P-27 | 95 |
| Example 6-28 | P-28 | 95 |
| Example 6-29 | P-29 | 97 |
| Example 6-30 | P-30 | 95 |

TABLE 14

| | | CHF₃/CF₄-based gas |
|---|---|---|
| | Polymer | etching speed (nm/min) |
| Example 6-31 | P-31 | 95 |
| Example 6-32 | P-32 | 95 |
| Example 6-33 | P-33 | 96 |
| Example 6-34 | P-34 | 95 |
| Example 6-35 | P-35 | 95 |
| Example 6-36 | P-36 | 95 |
| Example 6-37 | P-37 | 94 |
| Example 6-38 | P-38 | 96 |
| Example 6-39 | P-39 | 97 |
| Example 6-40 | P-40 | 96 |
| Example 6-41 | P-41 | 96 |
| Example 6-42 | P-42 | 95 |
| Example 6-43 | P-43 | 97 |
| Example 6-44 | P-44 | 95 |
| Example 6-45 | P-45 | 95 |
| Example 6-46 | P-46 | 95 |
| Example 6-47 | P-47 | 94 |
| Example 6-48 | P-48 | 96 |
| Example 6-49 | P-49 | 96 |
| Example 6-50 | P-50 | 95 |

TABLE 15

| | | CHF₃/CF₄-based gas |
|---|---|---|
| | Polymer | etching speed (nm/min) |
| Comparative | CP-1 | 102 |
| Example 6-1 | | |
| Comparative | CP-2 | 102 |
| Example 6-2 | | |
| Comparative | CP-3 | 102 |
| Example 6-3 | | |
| Comparative | CP-4 | 104 |
| Example 6-4 | | |
| Comparative | CP-5 | 101 |
| Example 6-5 | | |
| Comparative | CP-6 | 103 |
| Example 6-6 | | |
| Comparative | CP-7 | 105 |
| Example 6-7 | | |
| Comparative | CP-8 | 103 |
| Example 6-8 | | |
| Comparative | CP-9 | 104 |
| Example 6-9 | | |
| Comparative | CP-10 | 101 |
| Example 6-10 | | |
| Comparative | CP-11 | 105 |
| Example 6-11 | | |
| Comparative | CP-12 | 103 |
| Example 6-12 | | |
| Comparative | CP-13 | 104 |
| Example 6-13 | | |
| Comparative | CP-14 | 109 |
| Example 6-14 | | |
| Comparative | CP-15 | 103 |
| Example 6-15 | | |
| Comparative | CP-16 | 107 |
| Example 6-16 | | |
| Comparative | CP-17 | 105 |
| Example 6-17 | | |
| Comparative | CP-18 | 106 |
| Example 6-18 | | |
| Comparative | CP-19 | 103 |
| Example 6-19 | | |
| Comparative | CP-20 | 102 |
| Example 6-20 | | |
| Comparative | CP-21 | 105 |
| Example 6-21 | | |
| Comparative | CP-22 | 102 |
| Example 6-22 | | |
| Comparative | CP-23 | 103 |
| Example 6-23 | | |
| Comparative | CP-24 | 105 |
| Example 6-24 | | |
| Comparative | CP-25 | 101 |
| Example 6-25 | | |
| Comparative | CP-26 | 103 |
| Example 6-26 | | |
| Comparative | CP-27 | 106 |
| Example 6-27 | | |
| Comparative | CP-28 | 102 |
| Example 6-28 | | |
| Comparative | CP-29 | 103 |
| Example 6-29 | | |
| Comparative | CP-30 | 105 |
| Example 6-30 | | |
| Comparative | CP-31 | 107 |
| Example 6-31 | | |
| Comparative | CP-32 | 109 |
| Example 6-32 | | |
| Comparative | CP-33 | 104 |
| Example 6-33 | | |
| Comparative | CP-34 | 106 |
| Example 6-34 | | |
| Comparative | CP-35 | 105 |
| Example 6-35 | | |
| Comparative | CP-36 | 103 |
| Example 6-36 | | |
| Comparative | CP-37 | 107 |
| Example 6-37 | | |
| Comparative | CP-38 | 114 |
| Example 6-38 | | |

From the results shown in Tables 13 to 15, it was confirmed that the polymer of the present invention has excellent dry etching resistance against a CHF₃/CF₄-based gas.

The present description includes the following embodiments.

[1]: A sulfonium salt type monomer, wherein the sulfonium salt type monomer is represented by the following general formula (a),

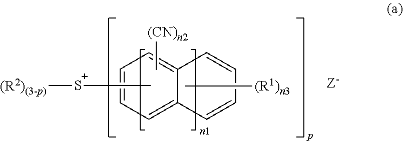

wherein “p” is 1, 2, or 3; n1 is 0 or 1; n2 is 1 or 2; n3 is an integer from 0 to 6; however, when n1 is 0, 1≤n2+n3≤5, and when n1 is 1, 1≤n2+n3≤7;
R¹ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when n3 is 2 to 6, each R¹ may be the same or they may be different from each other, and two R¹ may be bonded to each other to form a ring together with the carbon atoms to which they are bonded;
R² is a halogen atom, or a hydrocarbyl group having 1 to 30 carbon atoms and optionally containing a heteroatom; when “p” is 1, two R² may be the same or they may be different from each other; furthermore, two of the three substituents bonded to S⁺ may be bonded to each other to form a ring together with the sulfur atom to which they are bonded; and
Z⁻ is a carboxylate anion having an aromatic vinyl structure and an iodine atom.

[2]: The sulfonium salt type monomer according to [1], wherein the sulfonium salt type monomer is represented by the following general formula (a1),

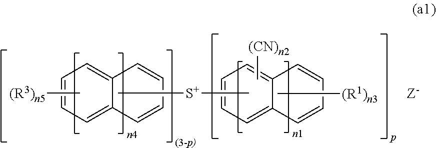

wherein “p”, n1 to n3, R¹, and Z⁻ are the same as above;
n4 is 0 or 1; n5 is an integer from 0 to 5;
R³ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; and when n5 is 2 to 5, each R³ may be the same or they may be different from each other, and two R³ may be bonded to each other to form a ring together with the carbon atoms to which they are bonded.

[3]: The sulfonium salt type monomer according to [1] or [2], wherein Z⁻ is an anion represented by the following general formula (Z),

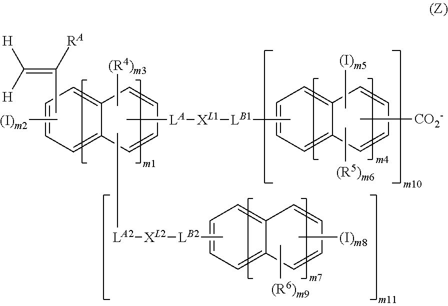

wherein m1 is 0 or 1; m2 is an integer from 0 to 4; m3 is an integer from 0 to 3; m4 is 0 or 1; m5 is an integer from 0 to 4; m6 is an integer from 0 to 3; m7 is 0 or 1; m8 is an integer from 0 to 4; m9 is an integer from 0 to 3; m10 is 0 or 1; m11 is 0 or 1; however, when m1 is 0, 0≤m2+m3+m11≤4, and when m1 is 1, 0≤m2+m3+m11≤6; when m4 is 0, 0≤m5+m6≤4, and when m4 is 1, 0≤m5+m6≤6; when m7 is 0, 0≤m8+m9≤5, and when m7 is 1, 0≤m8+m9≤7; furthermore, 1≤m2+m5+m8≤4;
R^{A} is a hydrogen atom, a fluorine atom, a methyl group, or a trifluoromethyl group;
R⁴, R⁵, and R⁶ are a halogen atom other than an iodine atom, a nitro group, a cyano group, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when m3 is 2 or 3, each R⁴ may be the same or they may be different from each other, and two R⁴ may be bonded to each other to form a ring together with the carbon atoms to which they are bonded; when m6 is 2 or 3, each R⁵ may be the same or they may be different from each other, and two R⁵ may be bonded to each other to form a ring together with the carbon atoms to which they are bonded; when m9 is 2 or 3, each R⁶ may be the same or they may be different from each other, and two R⁶ may be bonded to each other to form a ring together with the carbon atoms to which they are bonded;
L^{A1}, L^{A2}, L^{B1}, and L^{B2} are each independently a single bond, an ether bond, a carbonyl group, an ester bond, a sulfonate ester bond, an amide bond, a sulfonamide bond, a carbonate bond, or a carbamate bond; and
X^{L1} and X^{L2} are each independently a single bond, or a hydrocarbylene group having 1 to 40 carbon atoms and optionally containing a heteroatom.

[4]: A sulfonium salt type quencher, wherein the sulfonium salt type quencher is comprised of the sulfonium salt type monomer according to any one of [1] to [3].

[5]: A polymer, wherein the polymer contains a repeating unit derived from the sulfonium salt type quencher according to [4].

[6]: The polymer according to [5], wherein the polymer further contains a repeating unit represented by either or both of the following general formulae (b1) and (b2),

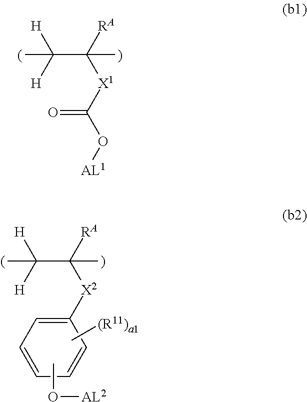

wherein R^{A} is each independently a hydrogen atom, a fluorine atom, a methyl group, or a trifluoromethyl group;
X¹ is a single bond, a phenylene group, a naphthylene group, *—C(═O)—OX¹¹—, or *—C(═O)—NH—X¹¹, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; X¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring;
X² is a single bond, *—C(═O)—O—, or *—C(═O)—NH—;
* indicates a bond to a carbon atom in the main chain;
R¹¹ is a halogen atom, a cyano group, a hydroxy group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom; when a1 is 2 or more, each R¹¹ may be the same or they may be different from each other;
AL¹ and AL² are each independently an acid-labile group; and
a1 is an integer from 0 to 4.

[7]: The polymer according to [5] or [6], wherein the polymer further contains a repeating unit represented by the following general formula (b3),

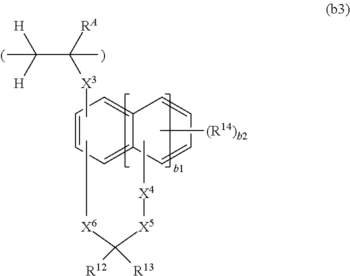

wherein b1 is 0 or 1; b2 is an integer from 0 to 3 when b1 is 0, and is an integer from 0 to 5 when b1 is 1;
R^{A} is a hydrogen atom, a fluorine atom, a methyl group, or a trifluoromethyl group;
X³ is a single bond, *—C(═O)—O—, or *—C(═O)—NH—; * indicates a bond to a carbon atom in the main chain;
R¹² and R¹³ are each independently a hydrogen atom, or a hydrocarbyl group having 1 to 20 carbon atoms and optionally containing a heteroatom; furthermore, R¹² and R¹³ may be bonded to each other to form a ring together with the carbon atom to which they are bonded;
R¹⁴ is a halogen atom, a hydroxy group, a cyano group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbyloxycarbonyl group having 2 to 20 carbon atoms and optionally containing a heteroatom, a hydrocarbylthio group having 1 to 20 carbon atoms and optionally containing a heteroatom, or —N(R^{14A})(R^{14B}); R^{14A} and R^{14B} are each independently a hydrogen atom or a hydrocarbyl group having 1 to 6 carbon atoms; when b2 is 2 or more, each R¹⁴ may be the same or they may be different from each other, and a plurality of R¹⁴ may be bonded to each other to form a ring together with the carbon atoms of the aromatic ring to which they are bonded;
X⁴ is a single bond, an aliphatic hydrocarbylene group having 1 to 4 carbon atoms, a carbonyl group, a sulfonyl group, or a group obtained by combining these; and
X⁵ and X⁶ are each independently an oxygen atom or a sulfur atom; however, X⁴ and X⁶ are bonded to adjacent carbon atoms of an aromatic ring.

[8]: The polymer according to any one of [5] to [7], wherein the polymer further contains a repeating unit represented by the following general formula (c),

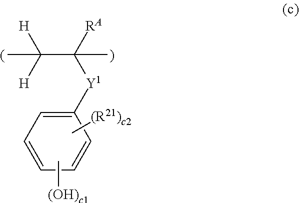

wherein R^{A} is a hydrogen atom, a fluorine atom, a methyl group, or a trifluoromethyl group;
Y¹ is a single bond, *—C(═O)—O—, or *—C(═O)—NH—; * indicates a bond to a carbon atom in the main chain;
R²¹ is a halogen atom, a carboxy group, a nitro group, a cyano group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom;
c1 is an integer from 1 to 4; and c2 is an integer from 0 to 3; however, 1≤c1+c2≤5.

[9]: The polymer according to any one of [5] to [8], wherein the polymer further contains a repeating unit derived from an onium salt type monomer containing a fluorosulfonate anion having a polymerizable group and at least one iodine atom, and a sulfonium cation.

[10]: The polymer according to any one of [5] to [9], wherein the polymer further contains a repeating unit represented by the following general formula (e),

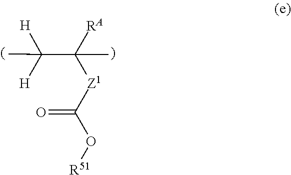

wherein R^{A} is a hydrogen atom, a fluorine atom, a methyl group, or a trifluoromethyl group;
Z¹ is a single bond, a phenylene group, a naphthylene group, *—C(═O)—O—Z¹¹—, or *—C(═O)—NH—Z¹¹—, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; * indicates a bond to a carbon atom in the main chain; Z¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring; and
R⁵¹ is a hydrogen atom, or a group having 1 to 20 carbon atoms containing at least one structure selected from a hydroxy group other than a phenolic hydroxy group, a cyano group, a carbonyl group, a carboxy group, an ether bond, an ester bond, a sulfonate ester bond, a carbonate bond, a lactone ring, a sultone ring, and a carboxylic anhydride (—C(═O)—O—C(═O)—).

[11]: A chemically amplified resist composition, wherein the chemically amplified resist composition contains a base polymer (A) containing the polymer according to any one of [5] to [10].

[12]: The chemically amplified resist composition according to [11], wherein the chemically amplified resist composition further contains at least one type selected from an organic solvent (B), a quencher (C) other than the sulfonium salt type quencher, an acid generator (D), and a surfactant (E).

[13]: A pattern forming method, wherein the pattern forming method contains a step of forming a resist film on a substrate using the chemically amplified resist composition according to [11] or [12], a step of exposing the resist film to high-energy radiation, and a step of developing the exposed resist film using a developer.

[14]: The pattern formation method according to [13], wherein the high-energy radiation is ArF excimer laser light with a wavelength of 193 nm, KrF excimer laser light with a wavelength of 248 nm, an electron beam, or extreme ultraviolet rays with a wavelength of 3 to 15 nm.

It should be noted that the present invention is not limited to the above-described embodiments. The embodiments are just examples, and any examples that have substantially the same features and demonstrate the same functions and effects as those in the technical concepts disclosed in the claims of the present invention are included in the technical scope of the present invention.

1. A sulfonium salt type monomer, wherein the sulfonium salt type monomer is represented by the following general formula (a), 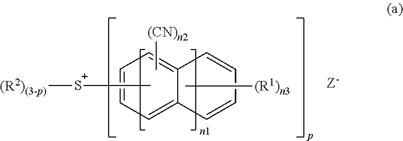
wherein “p” is 1, 2, or 3; n1 is 0 or 1; n2 is 1 or 2; n3 is an integer from 0 to 6; however, when n1 is 0, 1≤n2+n3≤5, and when n1 is 1, 1≤n2+n3≤7;
R¹ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when n3 is 2 to 6, each R¹ may be the same or they may be different from each other, and two R¹ may be bonded to each other to form a ring together with the carbon atoms to which they are bonded;
R² is a halogen atom, or a hydrocarbyl group having 1 to 30 carbon atoms and optionally containing a heteroatom; when “p” is 1, two R² may be the same or they may be different from each other; furthermore, two of the three substituents bonded to S⁺ may be bonded to each other to form a ring together with the sulfur atom to which they are bonded; and
Z⁻ is a carboxylate anion having an aromatic vinyl structure and an iodine atom.

2. The sulfonium salt type monomer according to claim 1, wherein the sulfonium salt type monomer is represented by the following general formula (a1), 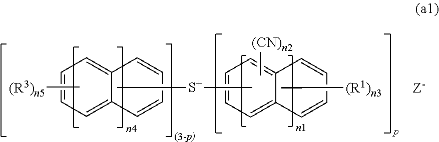
wherein “p”, n1 to n3, R¹, and Z⁻ are the same as above;
n4 is 0 or 1; n5 is an integer from 0 to 5;
R³ is a halogen atom, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; and when n5 is 2 to 5, each R³ may be the same or they may be different from each other, and two R³ may be bonded to each other to form a ring together with the carbon atoms to which they are bonded.

3. The sulfonium salt type monomer according to claim 1, wherein Z⁻ is an anion represented by the following general formula (Z), 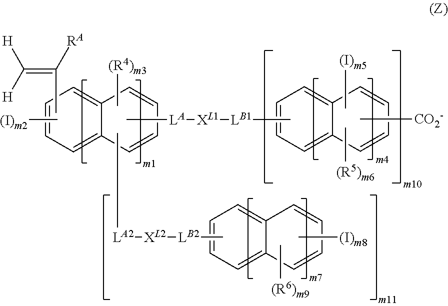
wherein m1 is 0 or 1; m2 is an integer from 0 to 4; m3 is an integer from 0 to 3; m4 is 0 or 1; m5 is an integer from 0 to 4; m6 is an integer from 0 to 3; m7 is 0 or 1; m8 is an integer from 0 to 4; m9 is an integer from 0 to 3; m10 is 0 or 1; m11 is 0 or 1; however, when m1 is 0, 0≤m2+m3+m11≤4, and when m1 is 1, 0≤m2+m3+m11≤6; when m4 is 0, 0≤m5+m6≤4, and when m4 is 1, 0≤m5+m6≤6; when m7 is 0, 0≤m8+m9≤5, and when m7 is 1, 0≤m8+m9≤7; furthermore, 1≤m2+m5+m8≤4;
R^{A} is a hydrogen atom, a fluorine atom, a methyl group, or a trifluoromethyl group;
R⁴, R⁵, and R⁶ are a halogen atom other than an iodine atom, a nitro group, a cyano group, a hydroxy group, a carboxy group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, or a hydrocarbylthio group having 1 to 20 carbon atoms and optionally containing a heteroatom; when m3 is 2 or 3, each R⁴ may be the same or they may be different from each other, and two R⁴ may be bonded to each other to form a ring together with the carbon atoms to which they are bonded; when m6 is 2 or 3, each R⁵ may be the same or they may be different from each other, and two R⁵ may be bonded to each other to form a ring together with the carbon atoms to which they are bonded; when m9 is 2 or 3, each R⁶ may be the same or they may be different from each other, and two R⁶ may be bonded to each other to form a ring together with the carbon atoms to which they are bonded;
L^{A1}, L^{A2}, L^{B1}, and L^{B2} are each independently a single bond, an ether bond, a carbonyl group, an ester bond, a sulfonate ester bond, an amide bond, a sulfonamide bond, a carbonate bond, or a carbamate bond; and
X^{L1} and X^{L2} are each independently a single bond, or a hydrocarbylene group having 1 to 40 carbon atoms and optionally containing a heteroatom.

4. A sulfonium salt type quencher, wherein the sulfonium salt type quencher is comprised of the sulfonium salt type monomer according to claim 1.

5. A polymer, wherein the polymer contains a repeating unit derived from the sulfonium salt type quencher according to claim 4.

6. The polymer according to claim 5, wherein the polymer further contains a repeating unit represented by either or both of the following general formulae (b1) and (b2), 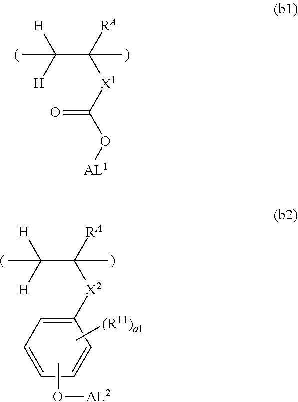
wherein R^{A} is each independently a hydrogen atom, a fluorine atom, a methyl group, or a trifluoromethyl group;
X¹ is a single bond, a phenylene group, a naphthylene group, *—C(═O)—OX¹¹—, or *—C(═O)—NH—X¹¹, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; X¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring;
X² is a single bond, *—C(═O)—O—, or *—C(═O)—NH—;
* indicates a bond to a carbon atom in the main chain;
R¹¹ is a halogen atom, a cyano group, a hydroxy group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom; when a1 is 2 or more, each R¹¹ may be the same or they may be different from each other;
AL¹ and AL² are each independently an acid-labile group; and
a1 is an integer from 0 to 4.

7. The polymer according to claim 5, wherein the polymer further contains a repeating unit represented by the following general formula (b3), 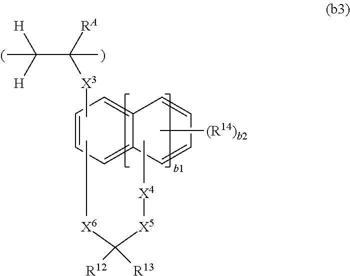
wherein b1 is 0 or 1; b2 is an integer from 0 to 3 when b1 is 0, and is an integer from 0 to 5 when b1 is 1;
R^{A} is a hydrogen atom, a fluorine atom, a methyl group, or a trifluoromethyl group;
X³ is a single bond, *—C(═O)—O—, or *—C(═O)—NH—; * indicates a bond to a carbon atom in the main chain;
R¹² and R¹³ are each independently a hydrogen atom, or a hydrocarbyl group having 1 to 20 carbon atoms and optionally containing a heteroatom; furthermore, R¹² and R¹³ may be bonded to each other to form a ring together with the carbon atom to which they are bonded;
R¹⁴ is a halogen atom, a hydroxy group, a cyano group, a nitro group, a hydrocarbyl group having 1 to 20 carbon atoms and optionally containing a heteroatom, a hydrocarbyloxy group having 1 to 20 carbon atoms and optionally containing a heteroatom, a hydrocarbyloxycarbonyl group having 2 to 20 carbon atoms and optionally containing a heteroatom, a hydrocarbylthio group having 1 to 20 carbon atoms and optionally containing a heteroatom, or —N(R^{14A})(R^{14B}); R¹⁴ and R^{14B} are each independently a hydrogen atom or a hydrocarbyl group having 1 to 6 carbon atoms; when b2 is 2 or more, each R¹⁴ may be the same or they may be different from each other, and a plurality of R¹⁴ may be bonded to each other to form a ring together with the carbon atoms of the aromatic ring to which they are bonded;
X⁴ is a single bond, an aliphatic hydrocarbylene group having 1 to 4 carbon atoms, a carbonyl group, a sulfonyl group, or a group obtained by combining these; and
X⁵ and X⁶ are each independently an oxygen atom or a sulfur atom; however, X⁴ and X⁶ are bonded to adjacent carbon atoms of an aromatic ring.

8. The polymer according to claim 5, wherein the polymer further contains a repeating unit represented by the following general formula (c), 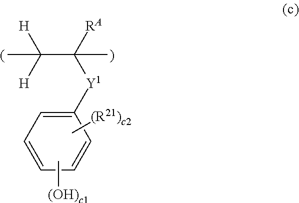
wherein R^{A} is a hydrogen atom, a fluorine atom, a methyl group, or a trifluoromethyl group;
Y¹ is a single bond, *—C(═O)—O—, or *—C(═O)—NH—; * indicates a bond to a carbon atom in the main chain;
R²¹ is a halogen atom, a carboxy group, a nitro group, a cyano group, an alkoxycarbonyl group, a hydrocarbyl group having 1 to 20 carbon atoms and optionally containing a heteroatom, a hydrocarbyloxy group having 1 to 20 carbon atoms and optionally containing a heteroatom, a hydrocarbylcarbonyl group having 2 to 20 carbon atoms and optionally containing a heteroatom, a hydrocarbylcarbonyloxy group having 2 to 20 carbon atoms and optionally containing a heteroatom, or a hydrocarbyloxycarbonyl group having 2 to 20 carbon atoms and optionally containing a heteroatom;
c1 is an integer from 1 to 4; and c2 is an integer from 0 to 3; however, 1≤c1+c2≤5.

9. The polymer according to claim 5, wherein the polymer further contains a repeating unit derived from an onium salt type monomer containing a fluorosulfonate anion having a polymerizable group and at least one iodine atom, and a sulfonium cation.

10. The polymer according to claim 5, wherein the polymer further contains a repeating unit represented by the following general formula (e), 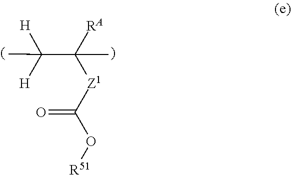
wherein R^{A} is a hydrogen atom, a fluorine atom, a methyl group, or a trifluoromethyl group;
Z¹ is a single bond, a phenylene group, a naphthylene group, *—C(═O)—O—Z¹¹—, or *—C(═O)—NH—Z¹¹—, and the phenylene group or naphthylene group may be substituted with a hydroxy group, a nitro group, a cyano group, a saturated hydrocarbyl group having 1 to 10 carbon atoms and optionally containing a fluorine atom, a saturated hydrocarbyloxy group having 1 to 10 carbon atoms and optionally containing a fluorine atom, or a halogen atom; * indicates a bond to a carbon atom in the main chain; Z¹¹ is a saturated hydrocarbylene group having 1 to 10 carbon atoms, a phenylene group, or a naphthylene group, and the saturated hydrocarbylene group may contain a hydroxy group, an ether bond, an ester bond, or a lactone ring; and
R⁵¹ is a hydrogen atom, or a group having 1 to 20 carbon atoms containing at least one structure selected from a hydroxy group other than a phenolic hydroxy group, a cyano group, a carbonyl group, a carboxy group, an ether bond, an ester bond, a sulfonate ester bond, a carbonate bond, a lactone ring, a sultone ring, and a carboxylic anhydride (—C(═O)—O—C(═O)—).

11. A chemically amplified resist composition, wherein the chemically amplified resist composition contains a base polymer (A) containing the polymer according to claim 5.

12. The chemically amplified resist composition according to claim 11, wherein the chemically amplified resist composition further contains at least one type selected from an organic solvent (B), a quencher (C) other than the sulfonium salt type quencher, an acid generator (D), and a surfactant (E).

13. A pattern forming method, wherein the pattern forming method contains a step of forming a resist film on a substrate using the chemically amplified resist composition according to claim 11, a step of exposing the resist film to high-energy radiation, and a step of developing the exposed resist film using a developer.

14. The pattern formation method according to claim 13, wherein the high-energy radiation is ArF excimer laser light with a wavelength of 193 nm, KrF excimer laser light with a wavelength of 248 nm, an electron beam, or extreme ultraviolet rays with a wavelength of 3 to 15 nm.
